(19) United States
(12) Patent Application Publication
(10) Pub. No.: US 2024/0247008 A1
(43) Pub. Date: Jul. 25, 2024

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Renjie Zheng, Beijing (CN); Zhihao Cui, Beijing (CN); Hualong Ding, Beijing (CN); Xingxing Chai, Beijing (CN); Yushuai Cao, Beijing (CN); Guanghong Ma, Beijing (CN); Chi Yuen Raymond Kwong, Hong Kong (CN); Chuanjun Xia, Beijing (CN)

(73) Assignee: BEIJING SUMMER SPROUT TECHNOLOGY CO., LTD., Beijing (CN)

(21) Appl. No.: 18/523,524

(22) Filed: Nov. 29, 2023

(30) Foreign Application Priority Data
Nov. 30, 2022 (CN) 202211515538.7
Jun. 27, 2023 (CN) 202310767967.1

(51) Int. Cl. C07F 7/08; C07B 59/00; H10K 85/40; H10K 85/60

(52) U.S. Cl. CPC C07F 7/0816; C07B 59/004; H10K 85/40; H10K 85/615; H10K 85/633; H10K 85/6572; H10K 85/6574; H10K 85/6576; C07B 2200/05

(57) ABSTRACT

Provided are an organic electroluminescent material and a device comprising the same. The organic electroluminescent material is a compound having a structure of Formula 1, and the compound can be used as an electron blocking material, a hole transporting material or a host material in an organic electroluminescent device. The compound enables the organic electroluminescent device to maintain a low voltage level or further reduce the voltage, have higher device efficiency and/or a longer device lifetime, and provide better overall performance of the device. Further provided are an organic electroluminescent device comprising the compound and a compound composition comprising the compound.

### CROSS-REFERENCE TO RELATED APPLICATION(S)

This application claims priority to Chinese Patent Application No. 202211515538.7 filed on Nov. 30, 2022 and Chinese Patent Application No. 202310767967.1 filed on Jun. 27, 2023, the disclosure of which are incorporated herein by reference in their entireties.

### TECHNICAL FIELD

The present disclosure relates to compounds for organic electronic devices such as organic electroluminescent devices. In particular, the present disclosure relates to a compound having a structure of Formula 1, an organic electroluminescent device comprising the compound and a compound composition comprising the compound.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

Organic small-molecule materials used in OLEDs must pass through a sublimation process before these materials are used for commercially preparing devices. Thus, the sublimation temperatures of the organic small-molecule materials will directly affect the power consumption and relate to the costs of production and application. In addition, generally, if the thermal stability of the organic small-molecule materials is poor, the small-molecule materials will deteriorate under conditions of a high temperature and heating, resulting in a decrease in the purity of the compounds. Therefore, the thermal stability of OLED materials is also a focus of research and development.

An important relationship is between the performance of organic electroluminescent devices such as efficiency and lifetime and a balance of a carrier concentration of a light-emitting layer. Molecular structure designs of charge transporting materials and carrier blocking materials can more reasonably adjust the balance of the carrier concentration of the light-emitting layer. Compounds having structures of triarylamine and silafluorene can be used as hole transporting materials and electron blocking materials (auxiliary light-emitting materials) in electroluminescent devices, and at present, some triarylamine-silafluorene compounds have been reported.

CN111196822A has disclosed a compound having a structure of

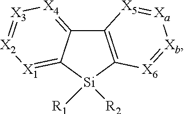

where one of Xₐ and X_{b} must be CR, a structure of R is

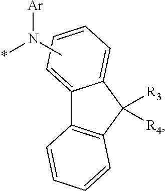

and in a specific structure, the compound

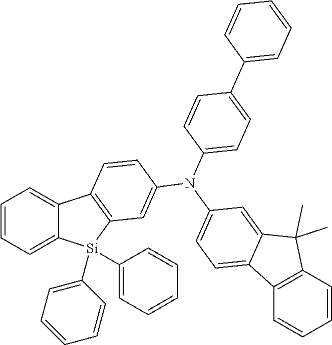 [SMILES: CC1(C)c2ccccc2-c2ccc(N(c3ccc(-c4ccccc4)cc3)c3ccc4c(c3)[Si](c3ccccc3)(c3ccccc3)c3ccccc3-4)cc21]

is disclosed. However, this application has not disclosed or taught a compound where R₁ or R₂ is joined to a triarylamine-fluorene/silafluorene structure and an effect thereof on device performance.

KR20170100698A has disclosed a compound having a structure of

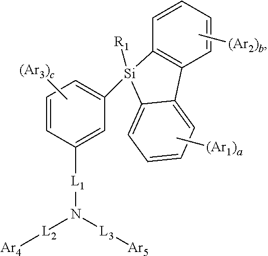

which records that at least one of Ar₄ and Ar₅ is substituted or unsubstituted naphthyl, and in a specific structure, the compound

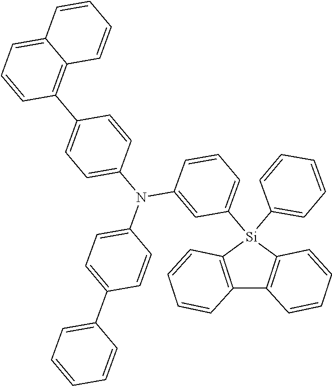 [SMILES: c1ccc(-c2ccc(N(c3ccc(-c4cccc5ccccc45)cc3)c3cccc([Si]4(c5ccccc5)c5ccccc5-c5ccccc54)c3)cc2)cc1]

is disclosed. The compound is applied to an electroluminescent device as a hole transporting material. However, this application has not disclosed or taught a compound where Ar₄ or Ar₅ is fluorenyl or silafluorenyl, nor has this application disclosed or taught that the compound has an effect on device performance as another material (such as an electron blocking material).

With an increasing demand in the industry for the performance of the organic electroluminescent devices, OLED materials with excellent performance such as lower voltage and higher efficiency and high thermal stability still need in-depth research and development.

### SUMMARY

The present disclosure aims to provide a series of new compounds each having a structure of Formula 1 where triarylamine and silafluorene are joined at a particular position according to the present disclosure to solve at least part of the above-mentioned problems. The compounds can be used in organic electroluminescent devices, for example, used as electron blocking materials. These new compounds have low sublimation temperatures and very excellent thermal stability. When used in the organic electroluminescent devices, these new compounds can maintain low voltage levels or reduce the device voltages, improve device efficiency and lifetimes, and provide better overall performance of the devices.

According to an embodiment of the present disclosure, disclosed is a compound, which has a structure represented by Formula 1:

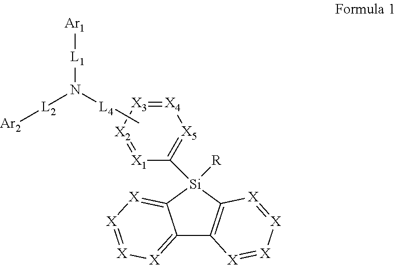

wherein in Formula 1, Ar₁ has a structure represented by Formula 2 or Formula 3:

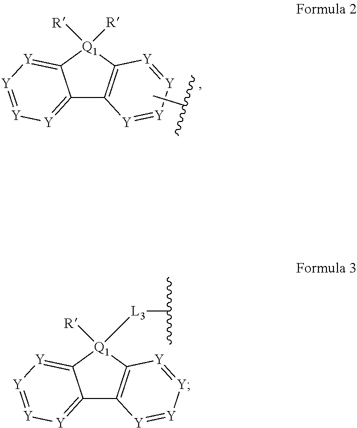

wherein Ar₂ is selected from substituted or unsubstituted aryl having 6 to 30 carbon atoms, substituted or unsubstituted heteroaryl having 3 to 30 carbon atoms or a combination thereof;
Q₁ is, at each occurrence identically or differently, selected from C or Si;
X is, at each occurrence identically or differently, selected from CR₁ or N;
Y is, at each occurrence identically or differently, selected from C, CR₂ or N;
X₄ is selected from C and joined to L₄, and X₁ to X₃ and X₅ are, at each occurrence identically or differently, selected from CRₓ;
L₁, L₂, L₃ and L₄ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
R, R′, R₁, R₂ and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R, R′, R₁, R₂ and Rₓ can be optionally joined to form a ring; and
[symbol] represents a position where Formula 2 or Formula 3 is joined to L₁ in Formula 1.

According to another embodiment of the present disclosure, disclosed is an organic electroluminescent device, which comprises an anode, a cathode and an organic layer disposed between the anode and the cathode, wherein the organic layer comprises the compound in the preceding embodiment.

According to another embodiment of the present disclosure, further disclosed is a compound composition, which comprises the compound in the preceding embodiment.

The present disclosure discloses the series of compounds each having the structure of Formula 1 where triarylamine and silafluorene are joined at the particular position according to the present disclosure. The compounds have the low sublimation temperatures and very excellent thermal stability. Moreover, the compounds can be used in the organic electroluminescent devices, for example, used as the electron blocking materials, hole transporting materials or host materials, and can improve the performance of the organic electroluminescent devices, for example, reduce the device voltages, improve the device efficiency and lifetimes, and improve the overall performance of the devices.

### BRIEF DESCRIPTION OF DRAWINGS

FIG. 1 is a schematic diagram of an organic light-emitting apparatus that may comprise a compound and a compound composition disclosed herein.

FIG. 2 is a schematic diagram of another organic light-emitting apparatus that may comprise a compound and a compound composition disclosed herein.

FIG. 3 is a structure diagram of a typical top-emitting OLED that may comprise a compound and a compound composition disclosed herein.

### DETAILED DESCRIPTION

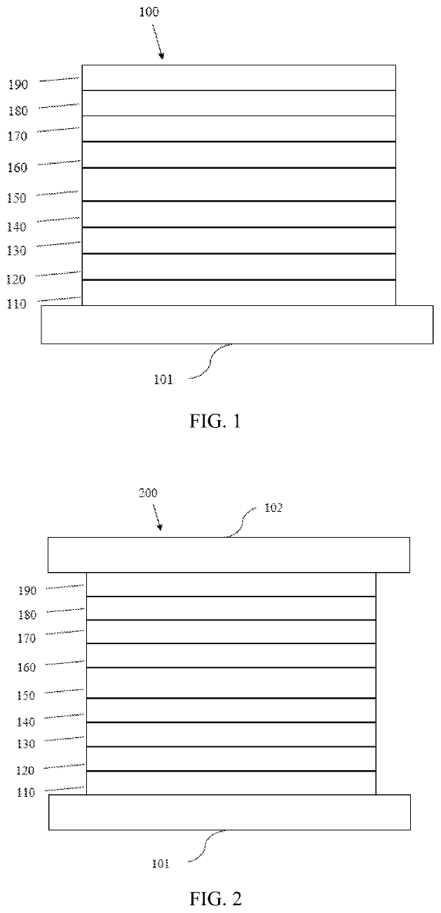

OLEDs can be fabricated on various types of substrates such as glass, plastic, and metal foil. FIG. 1 schematically shows an organic light emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may comprise a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

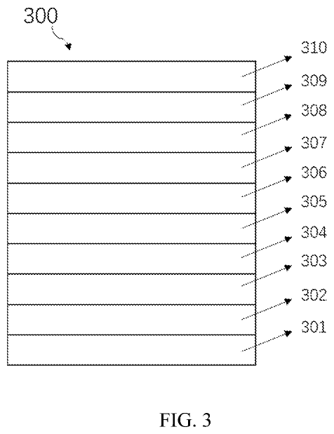

A structure of a typical top-emitting OLED device is shown in FIG. 3. An OLED device 300 comprises an anode layer 301, a hole injection layer (HIL) 302, a hole transporting layer (HTL) 303, an electron blocking layer (EBL) 304 (also referred to as an auxiliary light-emitting layer or a prime layer), an emissive layer (EML) 305, a hole blocking layer (HBL) 306 (as an optional layer), an electron transporting layer (ETL) 307, an electron injection layer (EIL) 308, a cathode layer 309 and a capping layer 310. The anode layer 301 is a material or a combination of materials having a high reflectivity, including but not limited to Ag, Al, Ti, Cr, Pt, Ni, TiN and a combination of the above materials with ITO and/or MoOx (molybdenum oxide). Generally, the reflectivity of the anode is greater than 50%; preferably, the reflectivity of the anode is greater than 70%; more preferably, the reflectivity of the anode is greater than 80%. The cathode layer 309 should be a translucent or transparent conductive material, including but not limited to a MgAg alloy, MoOx, Yb, Ca, ITO, IZO or a combination thereof and having an average transmittance of greater than 15% for light having a wavelength in a visible region; preferably, the average transmittance for the light having the wavelength in the visible region is greater than 20%; more preferably, the average transmittance for the light having the wavelength in the visible region is greater than 25%.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups includes saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl having 3 to 20 carbon atoms, unsubstituted arylgermanyl having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

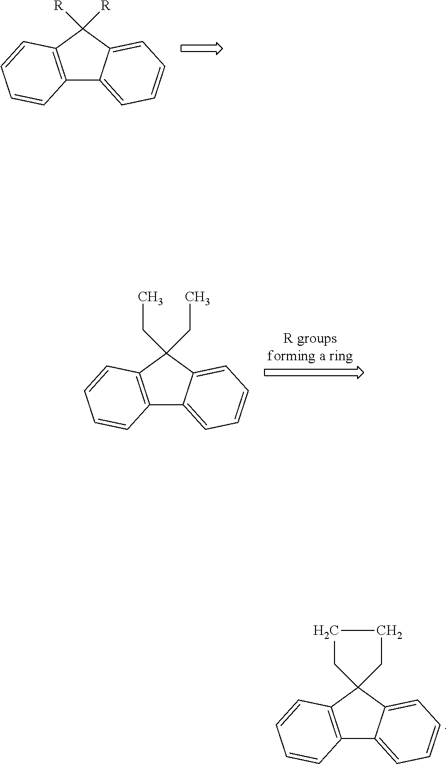

The expression that adjacent substituents can be optionally joined to form a ring is also intended to mean that two substituents bonded to carbon atoms which are directly bonded to each other are joined to each other via a chemical bond to form a ring, which can be exemplified by the following formula:

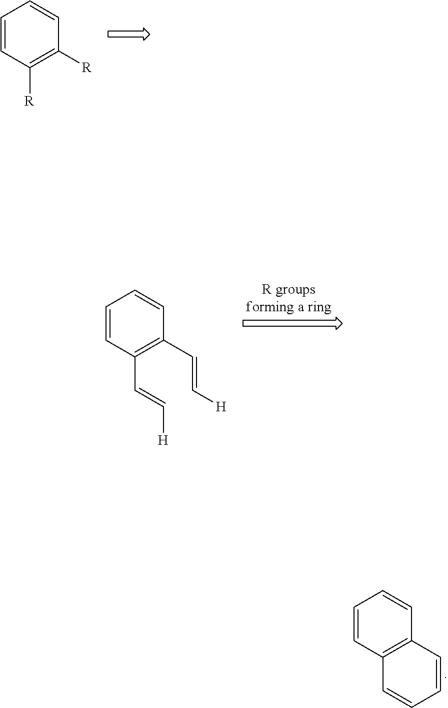

The expression that adjacent substituents can be optionally joined to form a ring is also intended to mean that two substituents bonded to a further distant carbon atom are joined to each other via a chemical bond to form a ring, which can be exemplified by the following formula:

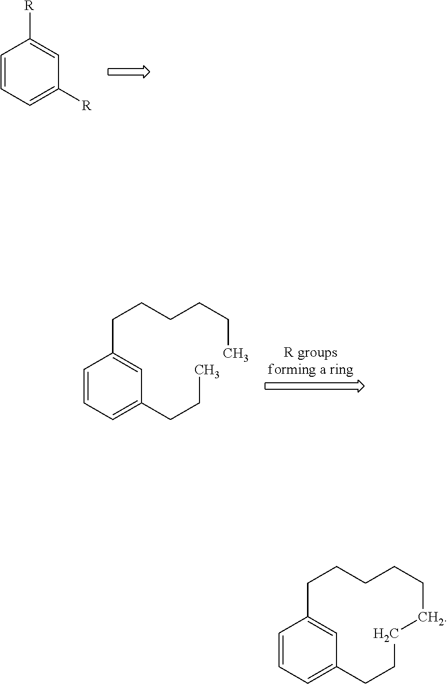

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

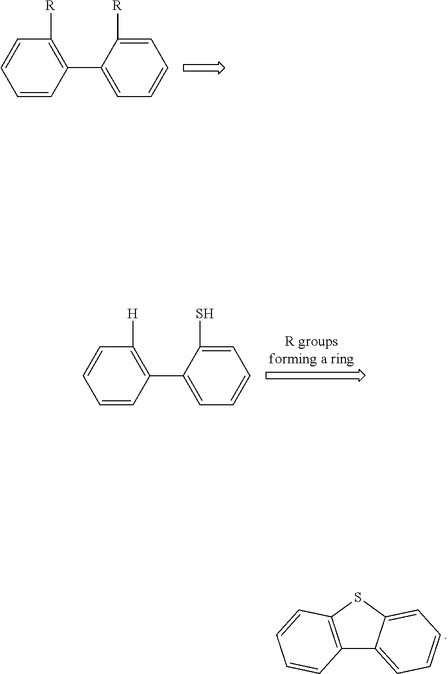

According to an embodiment of the present disclosure, disclosed is a compound, which has a structure represented by Formula 1:

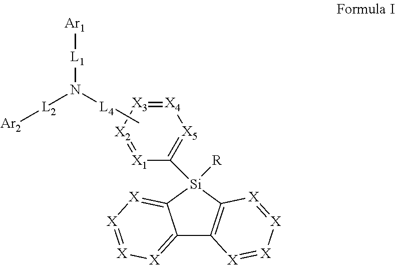

wherein in Formula 1, Ar₁ has a structure represented by Formula 2 or Formula 3:

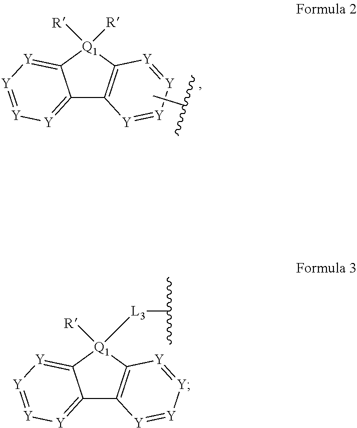

wherein Ar₂ is selected from substituted or unsubstituted aryl having 6 to 30 carbon atoms, substituted or unsubstituted heteroaryl having 3 to 30 carbon atoms or a combination thereof;
Q₁ is, at each occurrence identically or differently, selected from C or Si;
X is, at each occurrence identically or differently, selected from CR₁ or N;
Y is, at each occurrence identically or differently, selected from C, CR₂ or N;
X₄ is selected from C and joined to L₄, and X₁ to X₃ and X₅ are, at each occurrence identically or differently, selected from CRₓ;
L₁, L₂, L₃ and L₄ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
R, R′, R₁, R₂ and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R, R′, R₁, R₂ and Rₓ can be optionally joined to form a ring; and
[symbol] represents a position where Formula 2 or Formula 3 is joined to L₁ in Formula 1.

In the present disclosure, the expression that “adjacent substituents R, R′, R₁, R₂ and Rₓ can be optionally joined to form a ring” is intended to mean that any one or more of groups of adjacent substituents, such as two adjacent substituents R′, two adjacent substituents R₁, two adjacent substituents R₂, two adjacent substituents Rₓ, and two adjacent substituents R and Rₓ, can be joined to form a ring. Obviously, it is also possible that none of these substituents are joined to form a ring. When two adjacent substituents R₁ are joined to form a heteroaromatic ring, the formed heteroaromatic ring comprises only one heteroatom, which is O, S or N.

According to an embodiment of the present disclosure, R does not comprise amino.

According to an embodiment of the present disclosure, in Formula 1, L₁, L₂, L₃ and L₄ are, at each occurrence identically or differently, selected from a single bond, substituted or unsubstituted arylene having 6 to 20 carbon atoms, substituted or unsubstituted heteroarylene having 3 to 20 carbon atoms or a combination thereof.

According to an embodiment of the present disclosure, in Formula 1, L₁, L₂ and L₃ are, at each occurrence identically or differently, selected from a single bond, substituted or unsubstituted phenylene, substituted or unsubstituted biphenylylene, substituted or unsubstituted terphenylene, substituted or unsubstituted naphthylene, substituted or unsubstituted fluorenylidene, substituted or unsubstituted silafluorenylidene, substituted or unsubstituted carbazolylene, substituted or unsubstituted dibenzofuranylene, substituted or unsubstituted dibenzothienylene, substituted or unsubstituted dibenzoselenophenylene, substituted or unsubstituted phenanthrylene, substituted or unsubstituted triphenylenylene, substituted or unsubstituted pyridylene, substituted or unsubstituted spirobifluorenylene, substituted or unsubstituted anthrylene, substituted or unsubstituted pyrenylene or a combination thereof; L₄ is, at each occurrence identically or differently, selected from a single bond, substituted or unsubstituted phenylene or substituted or unsubstituted biphenylylene.

According to an embodiment of the present disclosure, L₃ is, at each occurrence identically or differently, selected from substituted or unsubstituted phenylene or substituted or unsubstituted biphenylylene.

According to an embodiment of the present disclosure, the compound has a structure represented by any one of Formula 4-1 to Formula 4-4:

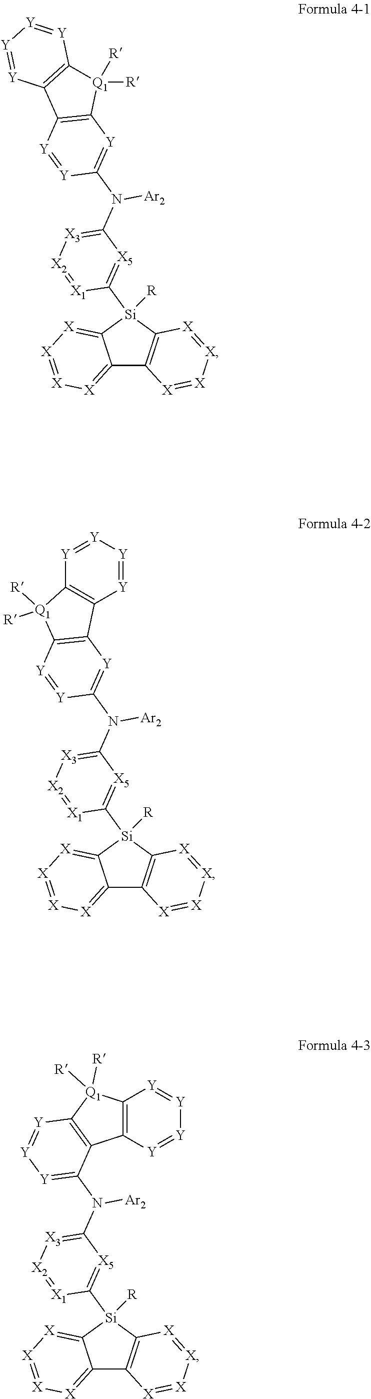

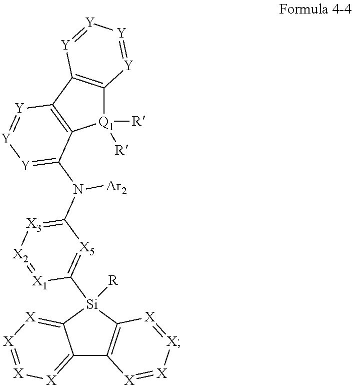

wherein in Formula 4-1 to Formula 4-4, X is, at each occurrence identically or differently, selected from CR₁;
Y is, at each occurrence identically or differently, selected from CR₂;
X₁ to X₃ and X₅ are, at each occurrence identically or differently, selected from CRₓ;
Q₁ is, at each occurrence identically or differently, selected from C or Si;
Ar₂ is selected from substituted or unsubstituted aryl having 6 to 30 carbon atoms, substituted or unsubstituted heteroaryl having 3 to 30 carbon atoms or a combination thereof;
R is, at each occurrence identically or differently, selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms or a combination thereof;
R′, R₁, R₂ and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R′, R₁, R₂ and Rₓ can be optionally joined to form a ring.

In the present disclosure, the expression that “adjacent substituents R′, R₁, R₂ and Rₓ can be optionally joined to form a ring” is intended to mean that any one or more of groups of adjacent substituents, such as two adjacent substituents R′, two adjacent substituents R₁, two adjacent substituents R₂, and two adjacent substituents Rₓ, can be joined to form a ring. Obviously, it is also possible that none of these substituents are joined to form a ring. When two adjacent substituents R₁ are joined to form a ring, the formed ring is an aliphatic ring, an aromatic ring or a heteroaromatic ring comprises only one heteroatom, which is O, S or N.

According to an embodiment of the present disclosure, the compound has a structure represented by Formula 4-1 or Formula 4-3.

According to an embodiment of the present disclosure, substituents R and Rₓ are not joined to form a ring.

According to an embodiment of the present disclosure, substituents R₁ are not joined to form a ring.

According to an embodiment of the present disclosure, R is, at each occurrence identically or differently, selected from substituted or unsubstituted alkyl having 1 to 20 carbon atoms, substituted or unsubstituted aryl having 6 to 30 carbon atoms, substituted or unsubstituted heteroaryl having 3 to 30 carbon atoms or a combination thereof.

According to an embodiment of the present disclosure, R is, at each occurrence identically or differently, selected from substituted or unsubstituted aryl having 6 to 30 carbon atoms or substituted or unsubstituted heteroaryl having 3 to 30 carbon atoms.

According to an embodiment of the present disclosure, R is, at each occurrence identically or differently, selected from substituted or unsubstituted phenyl, substituted or unsubstituted biphenyl, substituted or unsubstituted naphthyl, substituted or unsubstituted fluorenyl, substituted or unsubstituted dibenzofuran or substituted or unsubstituted dibenzothiophene.

According to an embodiment of the present disclosure, R′, R₁, R₂ and Rₓ are, at each occurrence identically or differently, selected from hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms or a combination thereof; and adjacent substituents R′, R₁, R₂ and Rₓ can be optionally joined to form a ring.

According to an embodiment of the present disclosure, R′, R₁, R₂ and Rₓ are, at each occurrence identically or differently, selected from hydrogen, deuterium, substituted or unsubstituted alkyl having 1 to 20 carbon atoms, substituted or unsubstituted aryl having 6 to 30 carbon atoms or a combination thereof.

According to an embodiment of the present disclosure, X₂ is selected from CRₓ, and Rₓ is, at each occurrence identically or differently, selected from deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group or a combination thereof.

According to an embodiment of the present disclosure, X₂ is selected from CRₓ, and Rₓ is, at each occurrence identically or differently, selected from deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, a cyano group or a combination thereof.

According to an embodiment of the present disclosure, Q₁ is C.

According to an embodiment of the present disclosure, Ar₂ is selected from substituted or unsubstituted aryl having 6 to 20 carbon atoms, substituted or unsubstituted heteroaryl having 3 to 20 carbon atoms or a combination thereof.

According to an embodiment of the present disclosure, Ar₂ is selected from substituted or unsubstituted aryl having 12 to 30 carbon atoms, substituted or unsubstituted heteroaryl having 12 to 20 carbon atoms or a combination thereof.

According to an embodiment of the present disclosure, Ar₂ is selected from substituted or unsubstituted aryl having 18 to 30 carbon atoms.

According to an embodiment of the present disclosure, Ar₂ is, at each occurrence identically or differently, selected from substituted or unsubstituted phenyl, substituted or unsubstituted biphenyl, substituted or unsubstituted terphenyl, substituted or unsubstituted naphthyl, substituted or unsubstituted fluorenyl, substituted or unsubstituted spirofluorenyl, substituted or unsubstituted silafluorenyl, substituted or unsubstituted dibenzofuranyl, substituted or unsubstituted dibenzothienyl, substituted or unsubstituted dibenzoselenophenyl, substituted or unsubstituted phenanthryl, substituted or unsubstituted triphenylenyl, substituted or unsubstituted pyridyl, substituted or unsubstituted carbazolyl, substituted or unsubstituted anthryl, substituted or unsubstituted pyrenyl or a combination thereof.

According to an embodiment of the present disclosure, Ar₂ is, at each occurrence identically or differently, selected from substituted or unsubstituted phenyl, substituted or unsubstituted biphenyl, substituted or unsubstituted fluorenyl, substituted or unsubstituted spirofluorenyl, substituted or unsubstituted dibenzofuranyl or substituted or unsubstituted dibenzothienyl.

According to an embodiment of the present disclosure, Ar₂ is, at each occurrence identically or differently, selected from the group consisting of G1 to G75:

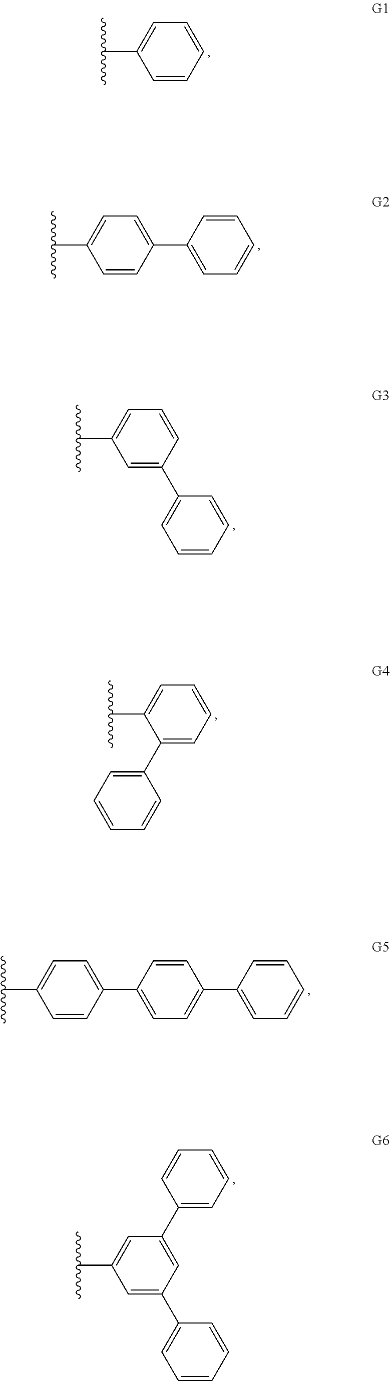 [SMILES: *c1ccccc1 ; *c1ccc(-c2ccccc2)cc1 ; *c1cccc(-c2ccccc2)c1 ; *c1ccccc1-c1ccccc1 ; *c1ccc(-c2ccc(-c3ccccc3)cc2)cc1 ; *c1cc(-c2ccccc2)cc(-c2ccccc2)c1]

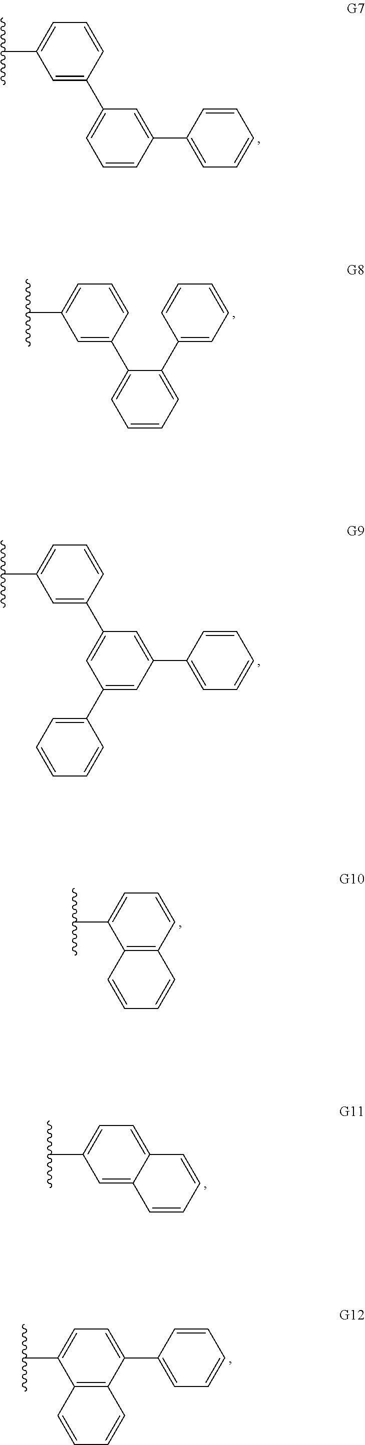 [SMILES: *c1cccc(-c2cccc(-c3ccccc3)c2)c1 ; *c1cccc(-c2ccccc2-c2ccccc2)c1 ; *c1cccc(-c2cc(-c3ccccc3)cc(-c3ccccc3)c2)c1 ; *c1cccc2ccccc12 ; *c1ccc2ccccc2c1 ; *c1ccc(-c2ccccc2)c2ccccc12]

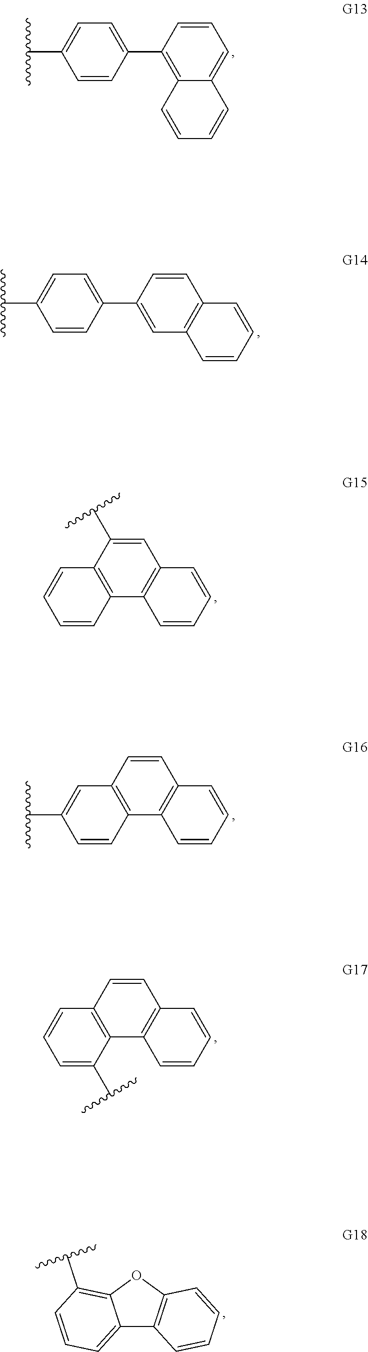 [SMILES: *c1ccc(-c2cccc3ccccc23)cc1 ; *c1ccc(-c2ccc3ccccc3c2)cc1 ; *c1cc2ccccc2c2ccccc12 ; *c1ccc2c(ccc3ccccc32)c1 ; *c1cccc2ccc3ccccc3c12 ; *c1cccc2c1oc1ccccc12]

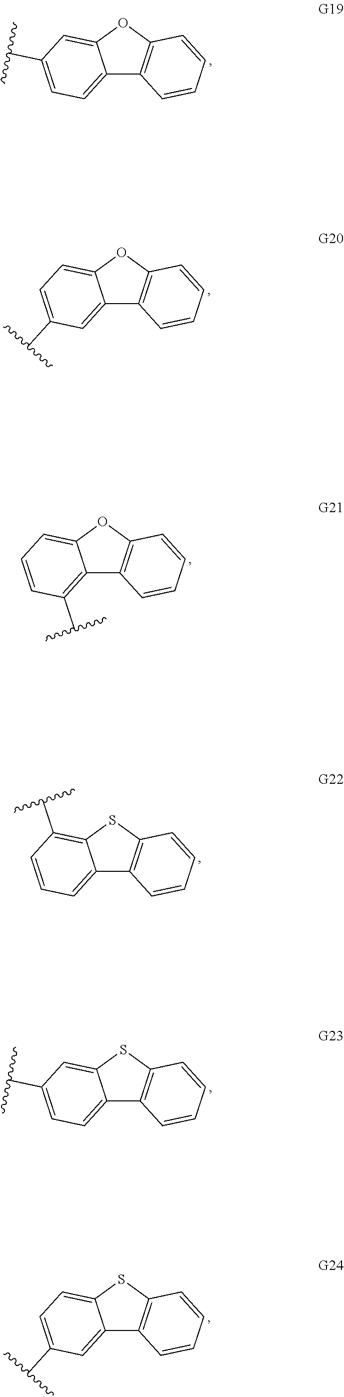 [SMILES: *c1ccc2c(c1)oc1ccccc12 ; *c1ccc2oc3ccccc3c2c1 ; *c1cccc2oc3ccccc3c12 ; *c1cccc2c1sc1ccccc12 ; *c1ccc2c(c1)sc1ccccc12 ; *c1ccc2sc3ccccc3c2c1]

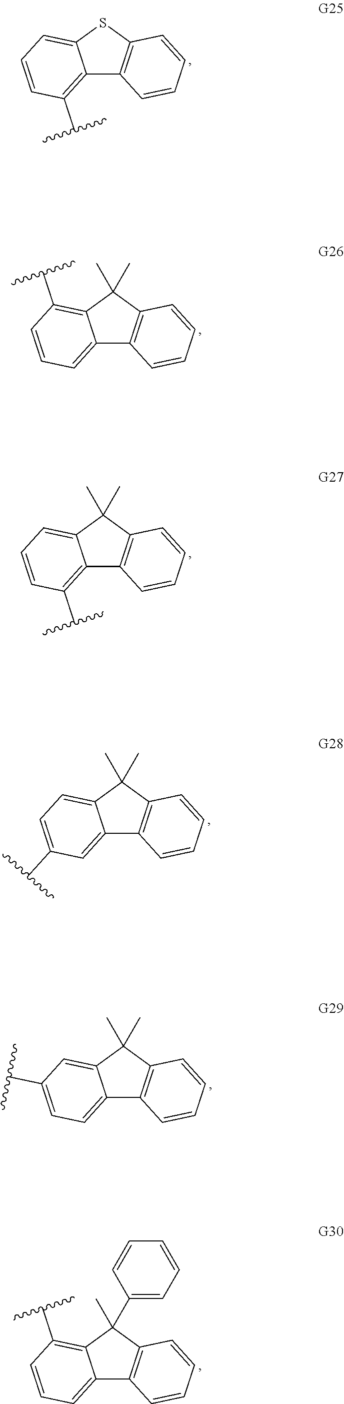 [SMILES: *c1cccc2sc3ccccc3c12 ; *c1cccc2c1C(C)(C)c1ccccc1-2 ; *c1cccc2c1-c1ccccc1C2(C)C ; *c1ccc2c(c1)-c1ccccc1C2(C)C ; *c1ccc2c(c1)C(C)(C)c1ccccc1-2 ; *c1cccc2c1C(C)(c1ccccc1)c1ccccc1-2]

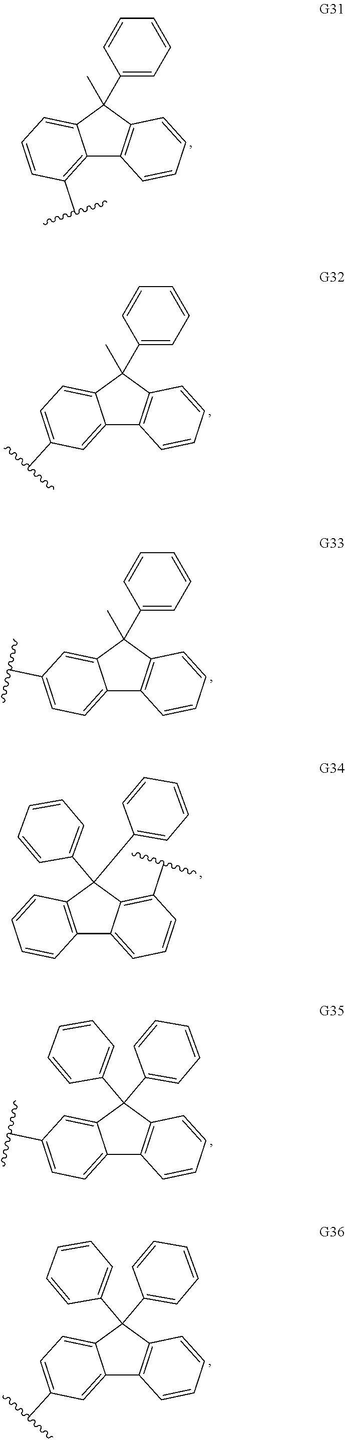 [SMILES: *c1cccc2c1-c1ccccc1C2(C)c1ccccc1 ; *c1ccc2c(c1)-c1ccccc1C2(C)c1ccccc1 ; *c1ccc2c(c1)C(C)(c1ccccc1)c1ccccc1-2 ; *c1cccc2c1C(c1ccccc1)(c1ccccc1)c1ccccc1-2 ; *c1ccc2c(c1)C(c1ccccc1)(c1ccccc1)c1ccccc1-2 ; *c1ccc2c(c1)-c1ccccc1C2(c1ccccc1)c1ccccc1]

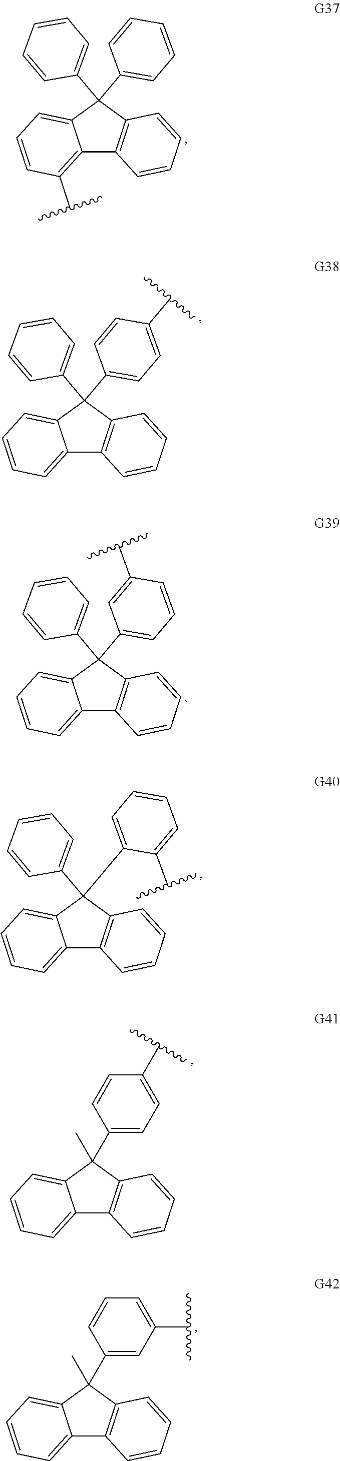 [SMILES: *c1cccc2c1-c1ccccc1C2(c1ccccc1)c1ccccc1 ; *c1ccc(C2(c3ccccc3)c3ccccc3-c3ccccc32)cc1 ; *c1cccc(C2(c3ccccc3)c3ccccc3-c3ccccc32)c1 ; *c1ccccc1C1(c2ccccc2)c2ccccc2-c2ccccc21 ; *c1ccc(C2(C)c3ccccc3-c3ccccc32)cc1 ; *c1cccc(C2(C)c3ccccc3-c3ccccc32)c1]

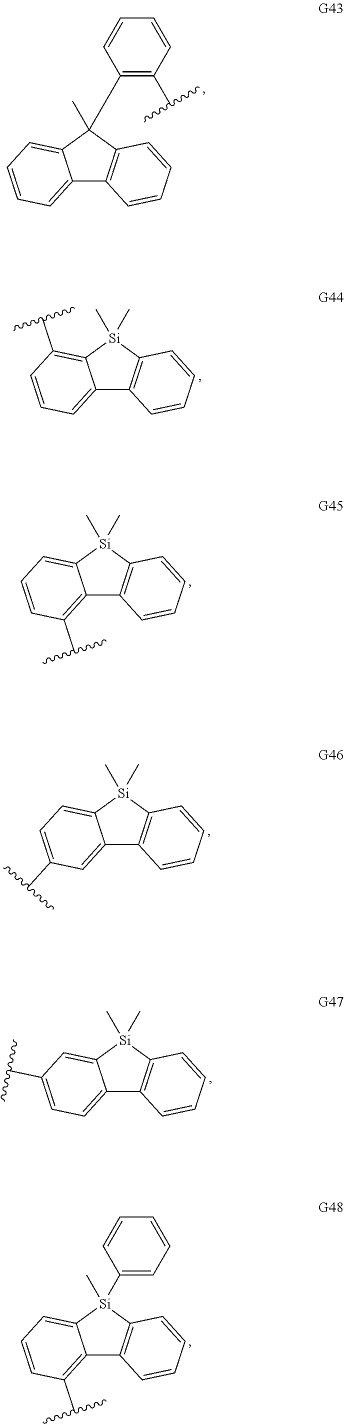 [SMILES: *c1ccccc1C1(C)c2ccccc2-c2ccccc21 ; *c1cccc2c1[Si](C)(C)c1ccccc1-2 ; *c1cccc2c1-c1ccccc1[Si]2(C)C ; *c1ccc2c(c1)-c1ccccc1[Si]2(C)C ; *c1ccc2c(c1)[Si](C)(C)c1ccccc1-2 ; *c1cccc2c1-c1ccccc1[Si]2(C)c1ccccc1]

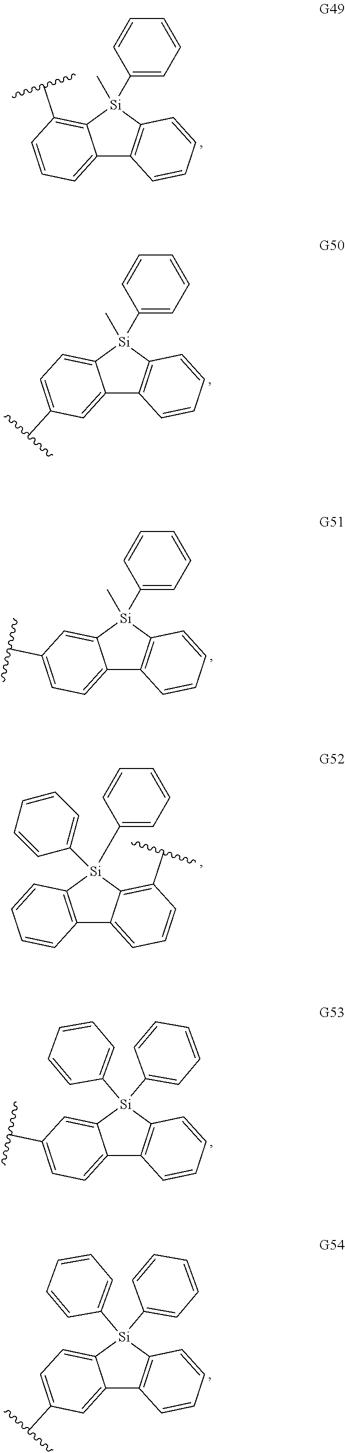 [SMILES: *c1cccc2c1[Si](C)(c1ccccc1)c1ccccc1-2 ; *c1ccc2c(c1)-c1ccccc1[Si]2(C)c1ccccc1 ; *c1ccc2c(c1)[Si](C)(c1ccccc1)c1ccccc1-2 ; *c1cccc2c1[Si](c1ccccc1)(c1ccccc1)c1ccccc1-2 ; *c1ccc2c(c1)[Si](c1ccccc1)(c1ccccc1)c1ccccc1-2 ; *c1ccc2c(c1)-c1ccccc1[Si]2(c1ccccc1)c1ccccc1]

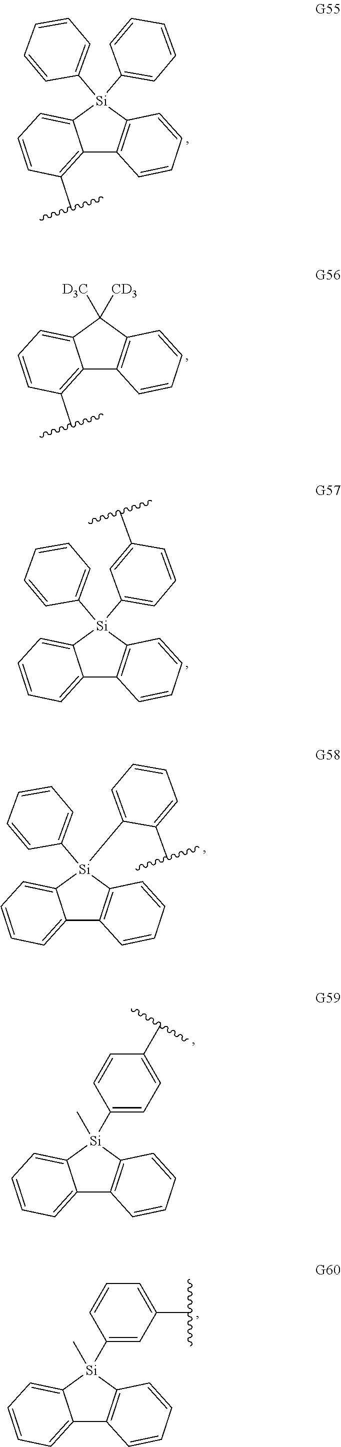 [SMILES: *c1cccc2c1-c1ccccc1[Si]2(c1ccccc1)c1ccccc1 ; *c1cccc2c1-c1ccccc1C2(C([2H])([2H])[2H])C([2H])([2H])[2H] ; *c1cccc([Si]2(c3ccccc3)c3ccccc3-c3ccccc32)c1 ; *c1ccccc1[Si]1(c2ccccc2)c2ccccc2-c2ccccc21 ; *c1ccc([Si]2(C)c3ccccc3-c3ccccc32)cc1 ; *c1cccc([Si]2(C)c3ccccc3-c3ccccc32)c1]

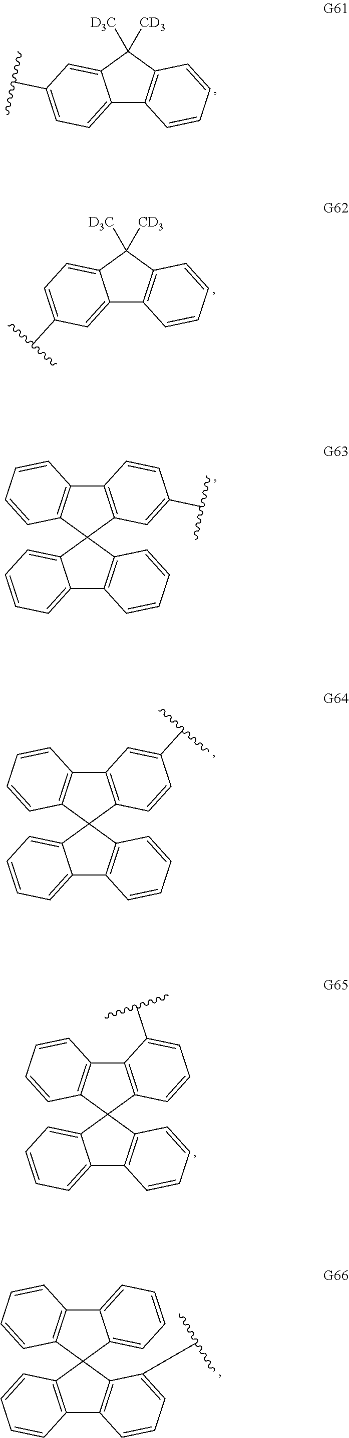 [SMILES: *c1ccc2c(c1)C(C([2H])([2H])[2H])(C([2H])([2H])[2H])c1ccccc1-2 ; *c1ccc2c(c1)-c1ccccc1C2(C([2H])([2H])[2H])C([2H])([2H])[2H] ; *c1ccc2c(c1)C1(c3ccccc3-c3ccccc31)c1ccccc1-2 ; *c1ccc2c(c1)-c1ccccc1C21c2ccccc2-c2ccccc21 ; *c1cccc2c1-c1ccccc1C21c2ccccc2-c2ccccc21 ; *c1cccc2c1C1(c3ccccc3-c3ccccc31)c1ccccc1-2]

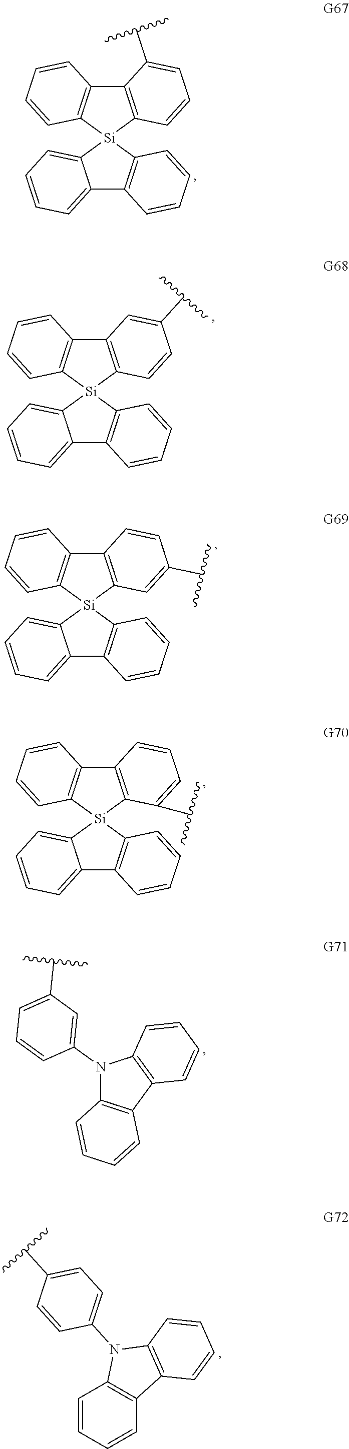 [SMILES: *c1cccc2c1-c1ccccc1[Si]21c2ccccc2-c2ccccc21 ; *c1ccc2c(c1)-c1ccccc1[Si]21c2ccccc2-c2ccccc21 ; *c1ccc2c(c1)[Si]1(c3ccccc3-c3ccccc31)c1ccccc1-2 ; *c1cccc2c1[Si]1(c3ccccc3-c3ccccc31)c1ccccc1-2 ; *c1cccc(-n2c3ccccc3c3ccccc32)c1 ; *c1ccc(-n2c3ccccc3c3ccccc32)cc1]

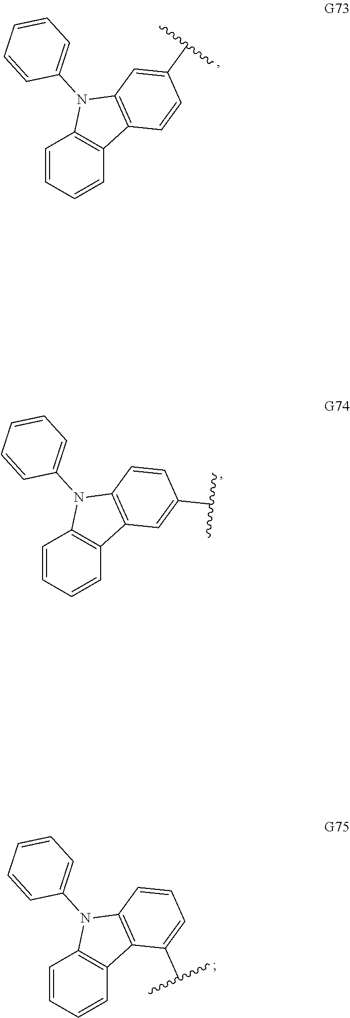 [SMILES: *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

and/or Ar₁ is, at each occurrence identically or differently, selected from the group consisting of G26 to G70.

According to an embodiment of the present disclosure, Ar₂ is, at each occurrence identically or differently, selected from the group consisting of G1 to G102, wherein the structures of G1 to G75 are as described in the preceding embodiment, and G76 to G102 are selected from the group consisting of the following structures:

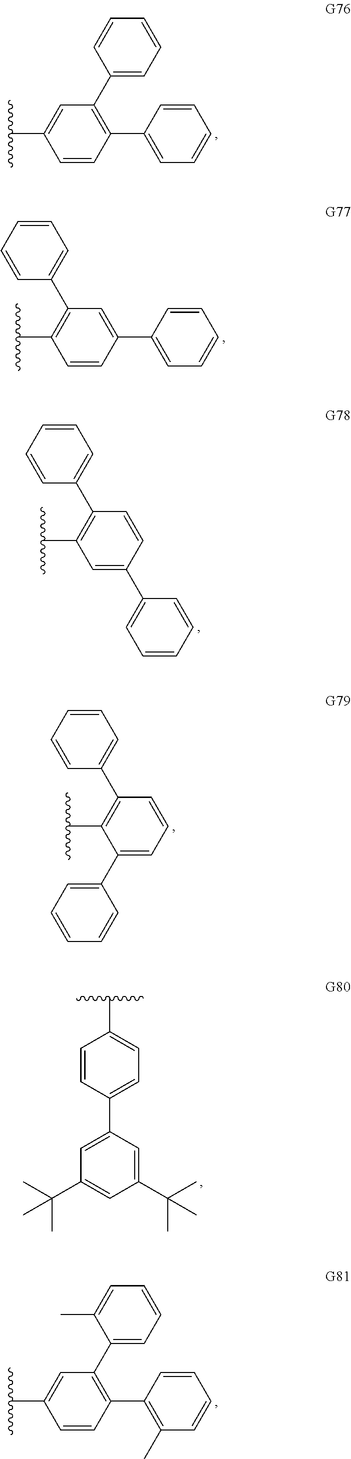 [SMILES: *c1ccc(-c2ccccc2)c(-c2ccccc2)c1 ; *c1ccc(-c2ccccc2)cc1-c1ccccc1 ; *c1cc(-c2ccccc2)ccc1-c1ccccc1 ; *c1c(-c2ccccc2)cccc1-c1ccccc1 ; *c1ccc(-c2cc(C(C)(C)C)cc(C(C)(C)C)c2)cc1 ; *c1ccc(-c2ccccc2C)c(-c2ccccc2C)c1]

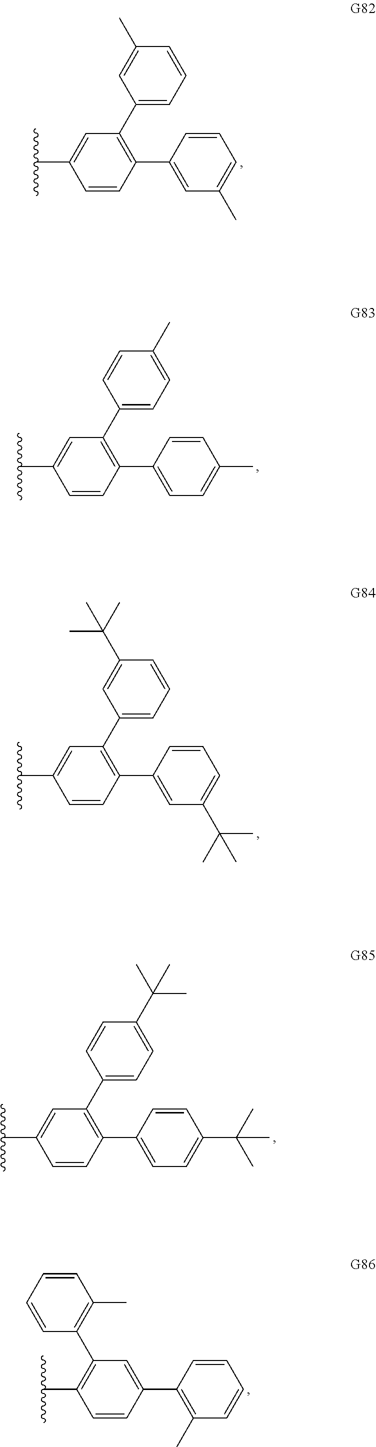 [SMILES: *c1ccc(-c2cccc(C)c2)c(-c2cccc(C)c2)c1 ; *c1ccc(-c2ccc(C)cc2)c(-c2ccc(C)cc2)c1 ; *c1ccc(-c2cccc(C(C)(C)C)c2)c(-c2cccc(C(C)(C)C)c2)c1 ; *c1ccc(-c2ccc(C(C)(C)C)cc2)c(-c2ccc(C(C)(C)C)cc2)c1 ; *c1ccc(-c2ccccc2C)cc1-c1ccccc1C]

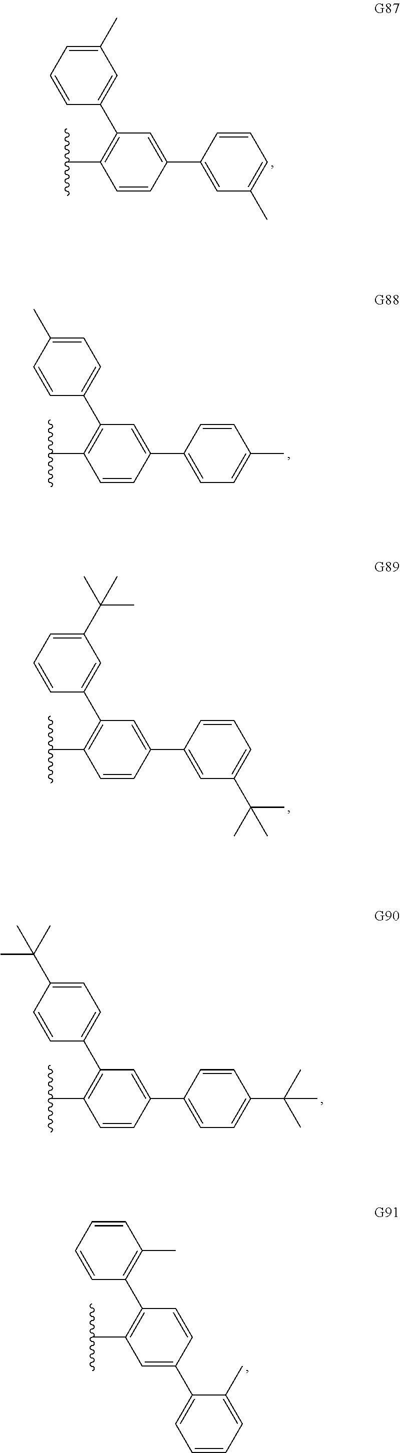

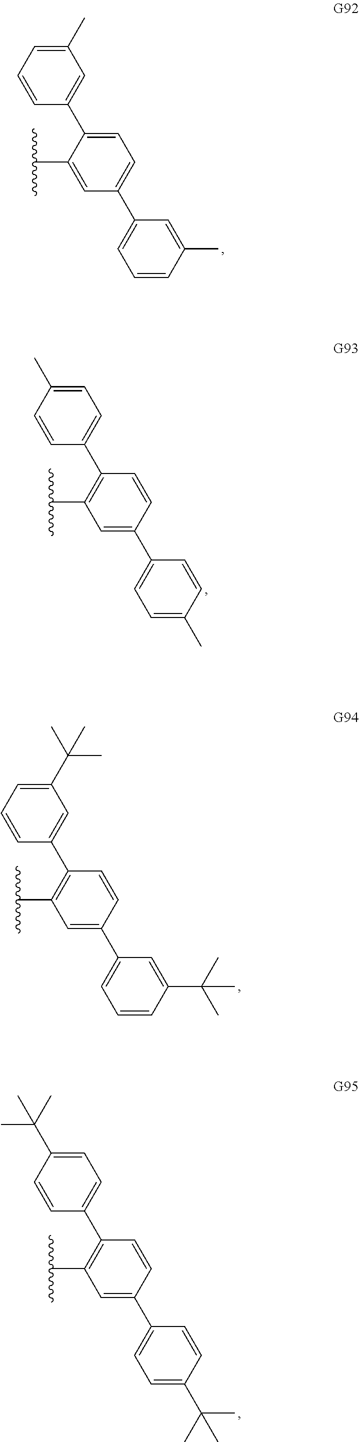

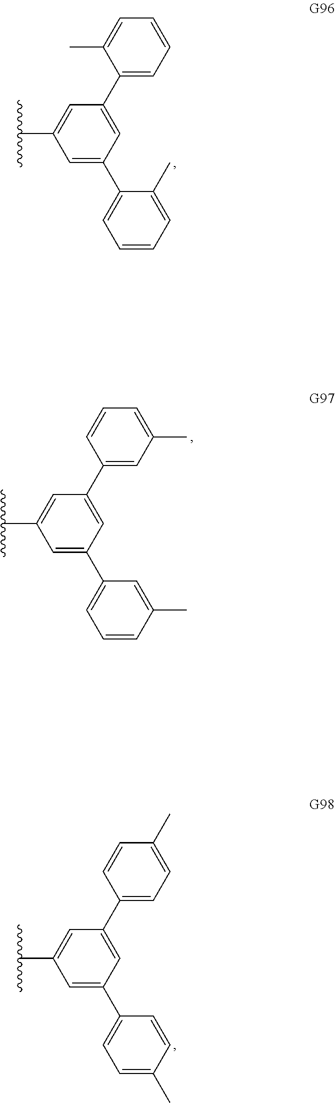 [SMILES: *c1cc(-c2ccccc2C)cc(-c2ccccc2C)c1 ; *c1cc(-c2cccc(C)c2)cc(-c2cccc(C)c2)c1 ; *c1cc(-c2ccc(C)cc2)cc(-c2ccc(C)cc2)c1]

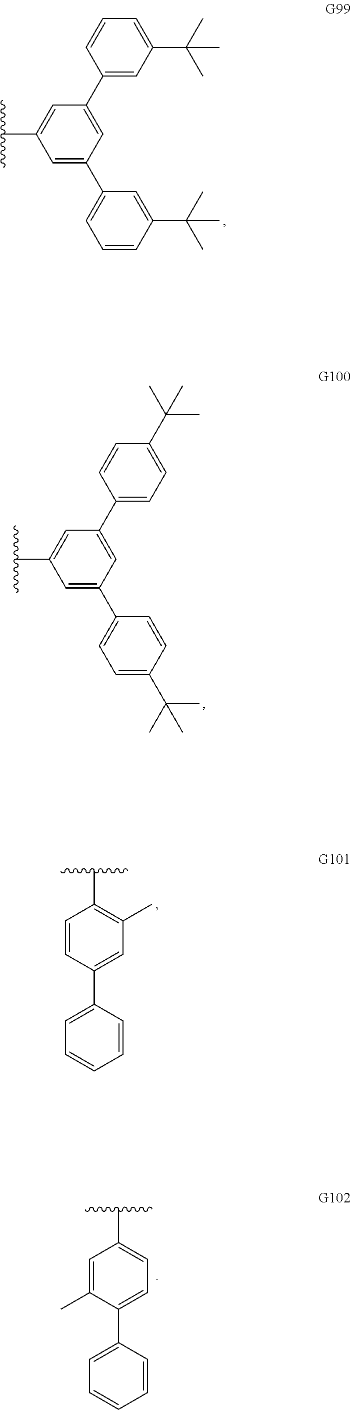

According to an embodiment of the present disclosure, the compound is selected from the group consisting of Compound 1 to Compound 3816 and Compound H1 to Compound H604, wherein the specific structures of Compound 1 to Compound 3816 and Compound H1 to Compound H604 are referred to claim 9.

According to an embodiment of the present disclosure, the compound is selected from the group consisting of Compound 1 to Compound 3816 and Compound H1 to Compound H605, wherein the specific structures of Compound 1 to Compound 3816 and Compound H1 to Compound H605 are referred to claim 9.

According to an embodiment of the present disclosure, hydrogens in the structures of Compound 1 to Compound 3816, Compound H1 to Compound H416 and Compound H451 to Compound H604 can be partially or fully substituted with deuterium.

According to an embodiment of the present disclosure, hydrogens in the structures of Compound 1 to Compound 3816, Compound H1 to Compound H416 and Compound H451 to Compound H605 can be partially or fully substituted with deuterium.

According to an embodiment of the present disclosure, disclosed is an organic electroluminescent device, which comprises an anode, a cathode and an organic layer disposed between the anode and the cathode, wherein the organic layer comprises the compound in any one of the preceding embodiments.

According to an embodiment of the present disclosure, in the organic electroluminescent device, the organic layer is an electron blocking layer, a hole transporting layer or a light-emitting layer.

According to an embodiment of the present disclosure, the organic layer is an electron blocking layer, and the compound is an electron blocking material.

According to an embodiment of the present disclosure, the electron blocking layer has a thickness of 1-500 nm.

According to an embodiment of the present disclosure, the organic layer is a light-emitting layer, and the compound is a host material.

According to an embodiment of the present disclosure, the organic layer comprises a light-emitting layer, wherein the light-emitting layer comprises a phosphorescent material.

According to an embodiment of the present disclosure, disclosed is an organic electroluminescent device, which comprises an anode, a cathode, a hole injection layer, a hole transporting layer, an electron blocking layer and a light-emitting layer, wherein the electron blocking layer comprises the compound in any one of the preceding embodiments.

According to an embodiment of the present disclosure, the electron blocking layer is in direct contact with the hole transporting layer, and the electron blocking layer is in direct contact with the light-emitting layer.

According to an embodiment of the present disclosure, the hole transporting layer comprises a hole transporting material, wherein the hole transporting material comprises a mono-triarylamine compound or a bis-triarylamine compound.

According to an embodiment of the present disclosure, the light-emitting layer comprises a red phosphorescent material.

According to an embodiment of the present disclosure, the phosphorescent material is a metal complex having a general formula of M(Lₐ)ₘ(L_{b})ₙ(L_{c})_{q};
wherein the metal M is selected from a metal with a relative atomic mass greater than 40;
Lₐ, L_{b} and L_{c} are a first ligand, a second ligand and a third ligand coordinated to the metal M, respectively; Lₐ, L_{b} and L_{c} may be the same or different;
Lₐ, L_{b} and L_{c} can be optionally joined to form a multidentate ligand;
m is 1, 2 or 3, n is 0, 1 or 2, q is 0, 1 or 2, and m+n+q is equal to an oxidation state of the metal M; when m is greater than or equal to 2, multiple Lₐ may be the same or different; when n is 2, two L_{b} may be the same or different; when q is 2, two L_{c} may be the same or different;
the ligand Lₐ has a structure represented by Formula 9:

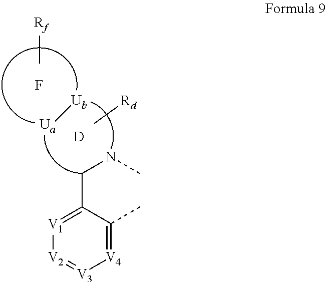

wherein,
the ring D is selected from a five-membered heteroaromatic ring or a six-membered heteroaromatic ring;
the ring F is selected from a five-membered unsaturated carbocyclic ring, a benzene ring, a five-membered heteroaromatic ring or a six-membered heteroaromatic ring;
the ring D and the ring F are fused via Uₐ and U_{b};
Uₐ and U_{b} are, at each occurrence identically or differently, selected from C or N;
R_{d} and R_{f} represent, at each occurrence identically or differently, mono-substitution, multiple substitutions or non-substitution;
V₁ to V₄ are, at each occurrence identically or differently, selected from CRᵥ or N;
R_{d}, R_{f} and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{d}, R_{f} and Rᵥ can be optionally joined to form a ring;
the ligands L_{b} and L_{c} are, at each occurrence identically or differently, selected from the group consisting of the following structures:

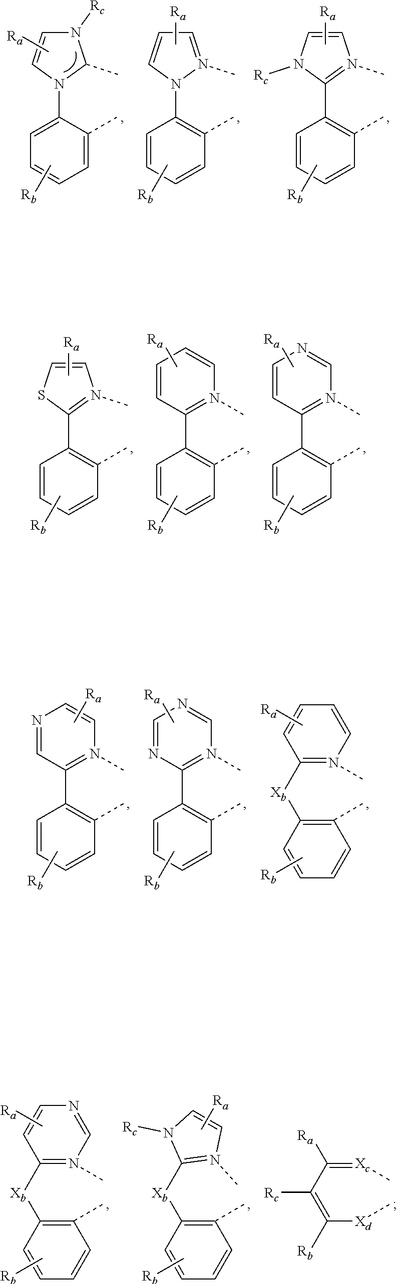

wherein,
Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of: O, S, Se and NR_{N2};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{N2}, R_{C1} and R_{C2} can be optionally joined to form a ring.

In the present disclosure, the expression that adjacent substituents R_{d}, R_{f} and Rᵥ can be optionally joined to form a ring is intended to mean that in the presence of substituents R_{d}, R_{f} and Rᵥ, any one or more of groups of adjacent substituents, such as adjacent substituents R_{d}, adjacent substituents R_{f}, adjacent substituents Rᵥ, adjacent substituents R_{d} and R_{f}, adjacent substituents R_{d} and Rᵥ, and adjacent substituents R_{f} and Rᵥ, can be joined to form a ring. Obviously, in the presence of substituents R_{d}, R_{f} and Rᵥ, it is also possible that none of these groups of substituents are joined to form a ring.

In this embodiment, the expression that adjacent substituents Rₐ, R_{b}, R_{c}, R_{N1}, R_{N2}, R_{C1} and R_{C2} can be optionally joined to form a ring is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, can be joined to form a ring. For example, adjacent substituents Rₐ and R_{b} in

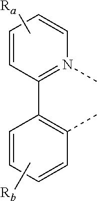

can be optionally joined to form a ring, which can form one or more of the following structures including, but not limited to,

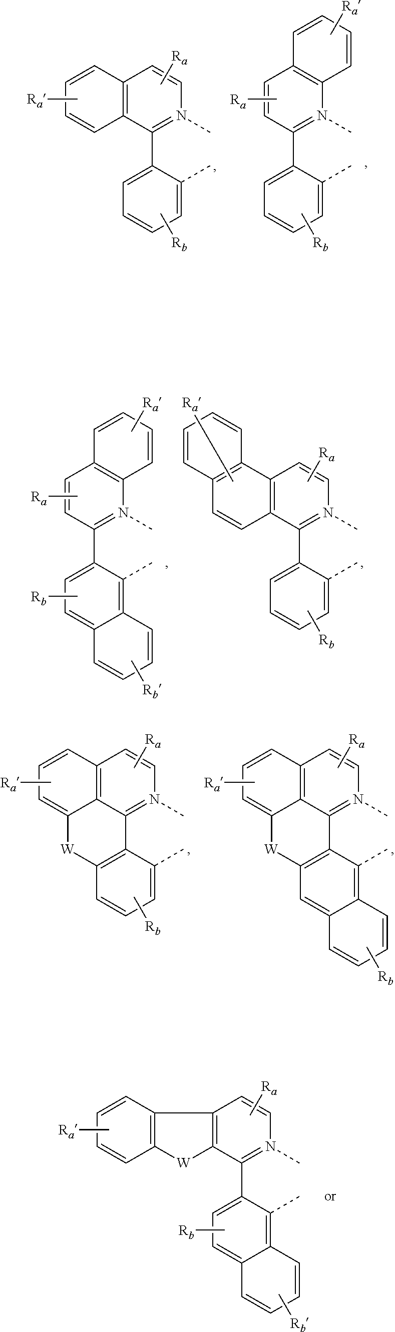

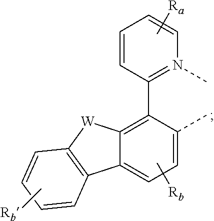

wherein W is selected from O, S, Se, NR_{w} or CR_{w}R_{w}, and R_{w}, Rₐ′ and R_{b}′ are defined the same as Rₐ. Obviously, it is also possible that none of these substituents are joined to form a ring.

According to an embodiment of the present disclosure, in Formula 9, two R_{f} are joined to form a ring.

According to an embodiment of the present disclosure, in Formula 9, two R_{f} are joined to form a five-membered unsaturated carbocyclic ring, a five-membered heteroaromatic ring or a six-membered aromatic ring.

According to an embodiment of the present disclosure, in Formula 9, the ring D is a six-membered heteroaromatic ring, and the ring F is a benzene ring or a six-membered heteroaromatic ring.

According to an embodiment of the present disclosure, in Formula 9, the ring D is a six-membered heteroaromatic ring, and the ring F is a five-membered heteroaromatic ring or a five-membered unsaturated carbocyclic ring.

According to an embodiment of the present disclosure, in Formula 9, the ring D is a six-membered heteroaromatic ring, the ring F is a benzene ring or a six-membered heteroaromatic ring, and two R_{f} are joined to form a six-membered aromatic ring or a six-membered heteroaromatic ring.

According to an embodiment of the present disclosure, in Formula 9, the ring D is a six-membered heteroaromatic ring, the ring F is a five-membered heteroaromatic ring or a five-membered unsaturated carbocyclic ring, and two R_{f} are joined to form a six-membered aromatic ring or a six-membered heteroaromatic ring.

According to an embodiment of the present disclosure, in Formula 9, at least two of V₁ to V₄ are selected from CRᵥ, and the two Rᵥ are joined to form a ring.

According to an embodiment of the present disclosure, in Formula 9, V₃ and V₄ are selected from CRᵥ, and the two Rᵥ are joined to form a ring.

According to an embodiment of the present disclosure, in Formula 9, V₃ and V₄ are selected from CRᵥ, and the two Rᵥ are joined to form a six-membered aromatic ring or a six-membered heteroaromatic ring.

According to an embodiment of the present disclosure, in Formula 9, at least one or two of adjacent substituents among R_{d}, R_{f} and Rᵥ are joined to form a ring. For example, two substituents R_{d} are joined to form a ring, or two substituents R_{f} are joined to form a ring, or two substituents Rᵥ are joined to form a ring, or substituents R_{d} and R_{f} are joined to form a ring, or substituents R_{d} and Rᵥ are joined to form a ring, or substituents R_{f} and Rᵥ are joined to form a ring, or two substituents R_{f} are joined to form a ring while two substituents R_{d} are joined to form a ring, or two substituents Rᵥ are joined to form a ring while two substituents R_{d} are joined to form a ring, or two substituents Rᵥ are joined to form a ring while two substituents R_{f} are joined to form a ring, or two substituents Rᵥ are joined to form a ring while substituents R_{f} and Rᵥ are joined to form a ring, or two substituents Rᵥ are joined to form a ring while substituents R_{d} and Rᵥ are joined to form a ring; more groups of adjacent substituents of R_{d}, R_{f} and Rᵥ are joined to form a ring with a similar case.

According to an embodiment of the present disclosure, the ligand L_{b} has the following structure:

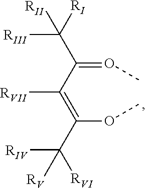

wherein R_{I} to R_{VII} are each independently selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group and combinations thereof.

According to an embodiment of the present disclosure, at least one of R_{I} to R_{III} are selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least one of R_{IV} to R_{VI} are selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof.

According to an embodiment of the present disclosure, at least two of R_{I} to R_{III} are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least two of R_{IV} to R_{VI} are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof.

According to an embodiment of the present disclosure, at least two of R_{I} to R_{III} are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof; and/or at least two of R_{IV} to R_{VI} are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof.

According to an embodiment of the present disclosure, in the organic electroluminescent device, the phosphorescent material is an Ir complex, a Pt complex or an Os complex.

According to an embodiment of the present disclosure, in the organic electroluminescent device, the phosphorescent material is an Ir complex and has a structure represented by any one of Ir(Lₐ)(L_{b})(L_{c}), Ir(Lₐ)₂(L_{b}), Ir(Lₐ)(L_{b})₂, Ir(Lₐ)₂(L_{c}) or Ir(Lₐ)(L_{c})₂.

According to an embodiment of the present disclosure, the ligand Lₐ has a structure represented by Formula 9 and comprises at least one structural unit selected from the group consisting of an aromatic ring formed by fusing a six-membered ring to a six-membered ring, a heteroaromatic ring formed by fusing a six-membered ring to a six-membered ring, an aromatic ring formed by fusing a six-membered ring to a five-membered ring and a heteroaromatic ring formed by fusing a six-membered ring to a five-membered ring.

According to an embodiment of the present disclosure, in the organic electroluminescent device, the ligand Lₐ has the structure represented by Formula 9 and comprises at least one structural unit selected from the group consisting of naphthalene, phenanthrene, quinoline, isoquinoline and azaphenanthrene.

According to an embodiment of the present disclosure, in the electroluminescent device, the ligand Lₐ is, at each occurrence identically or differently, selected from any one of the group consisting of the following structures:

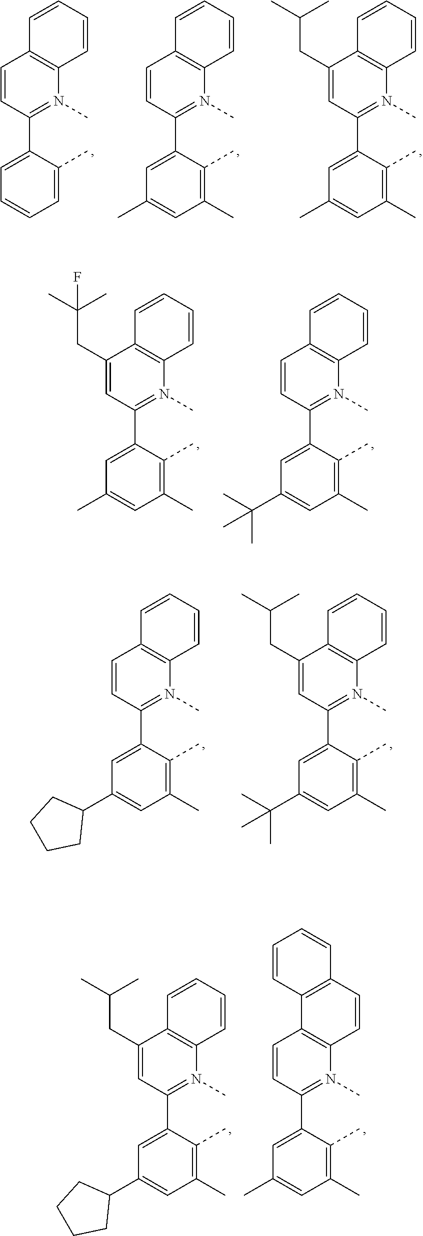

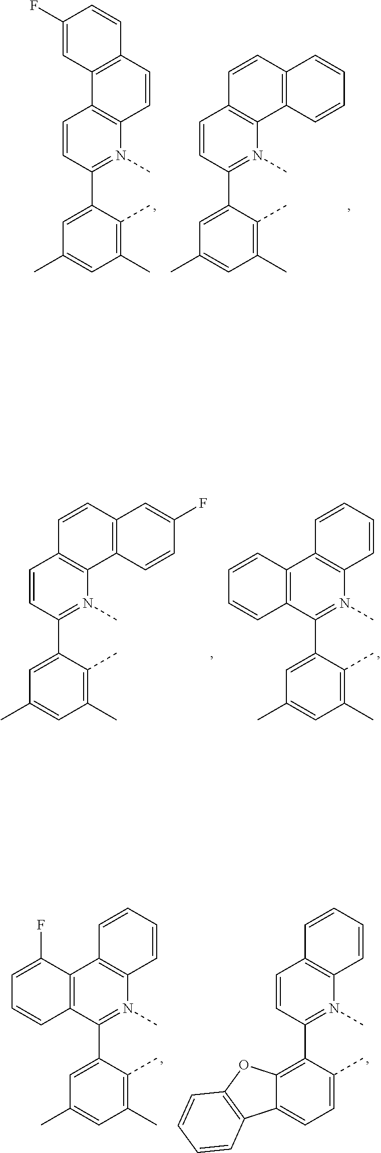

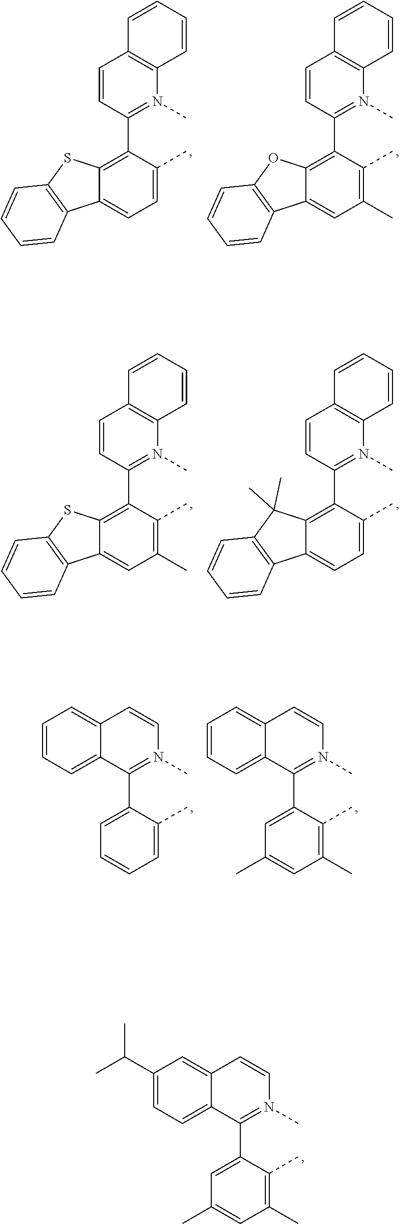

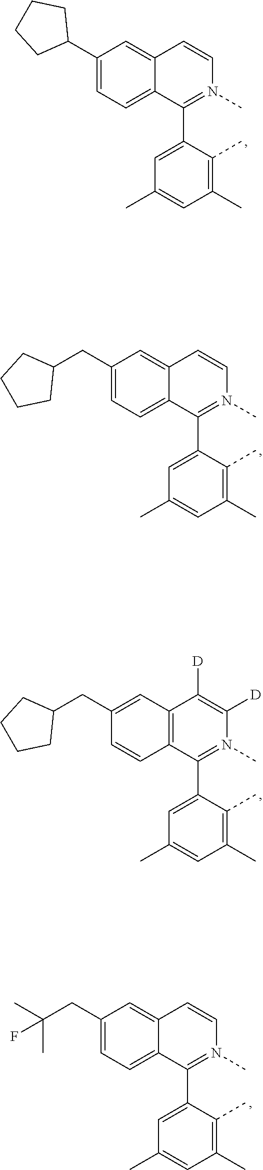

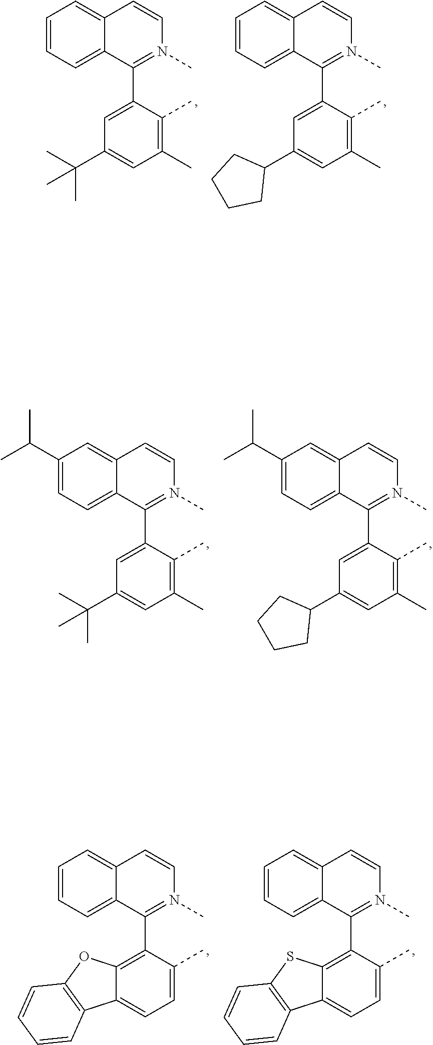

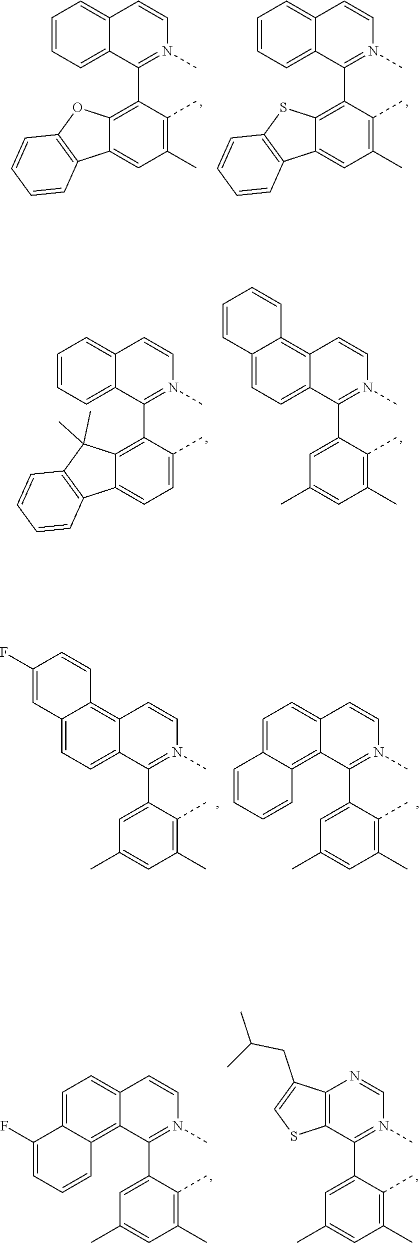

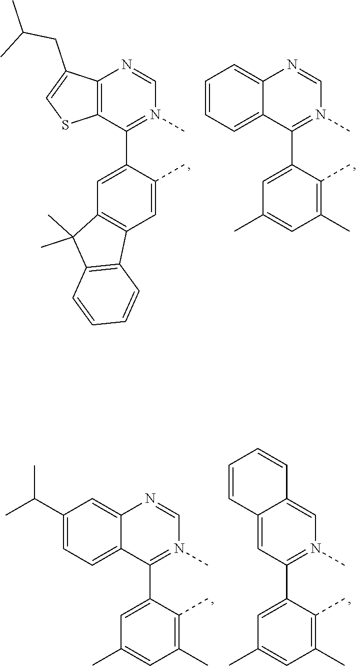

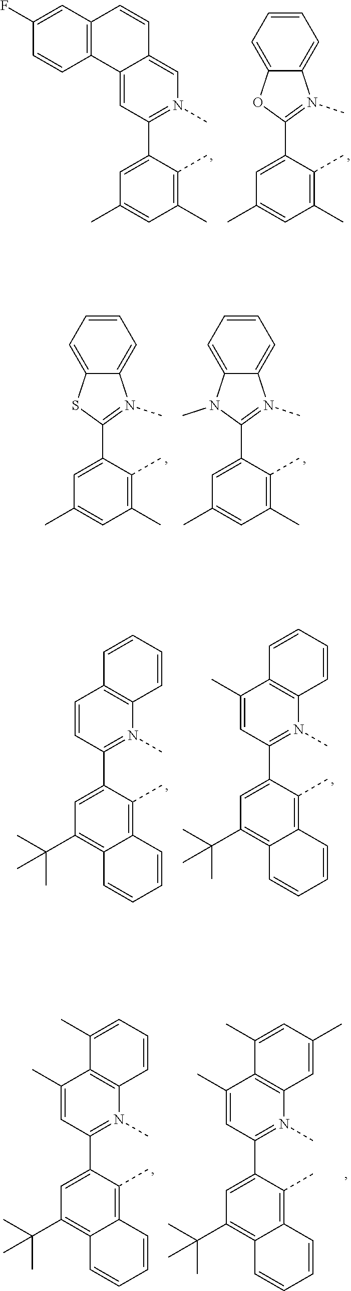

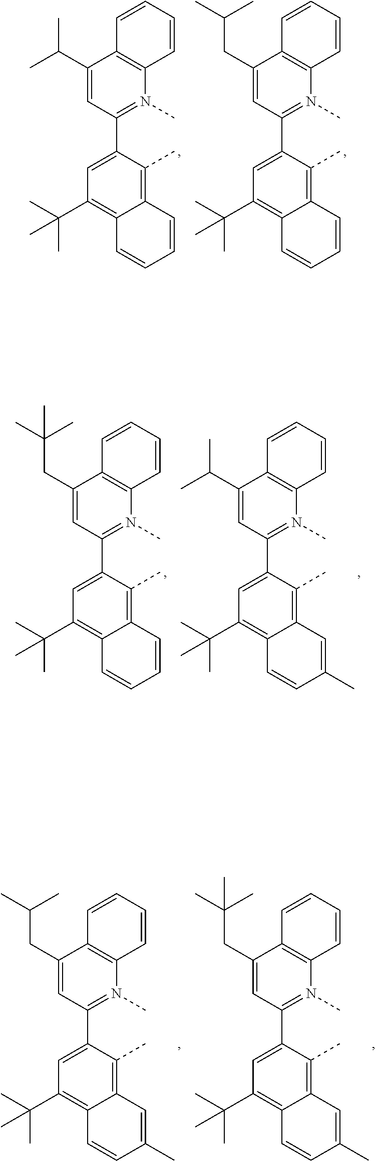

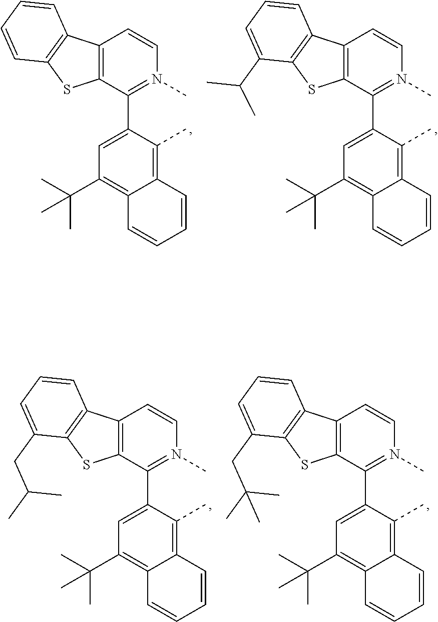

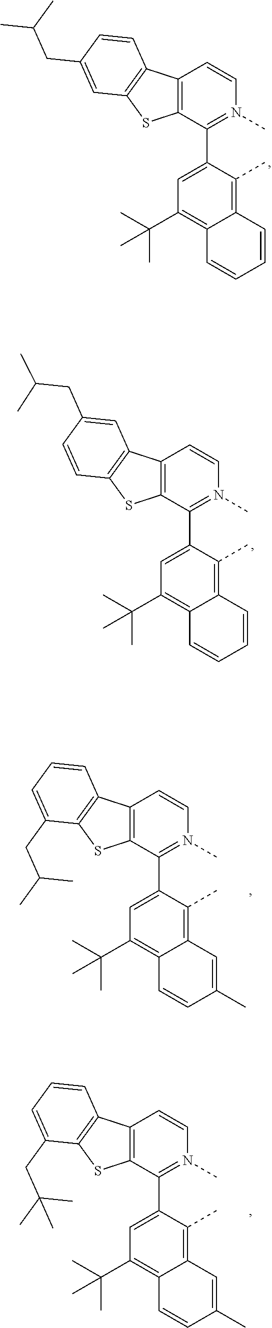

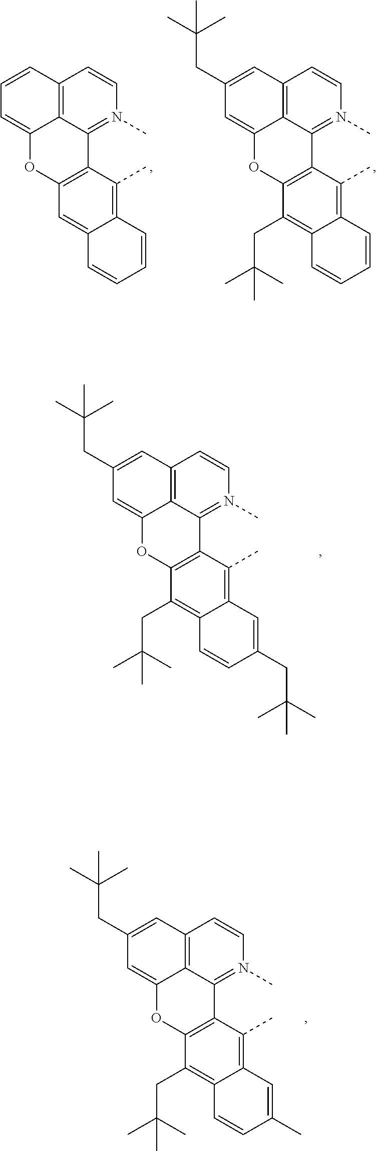

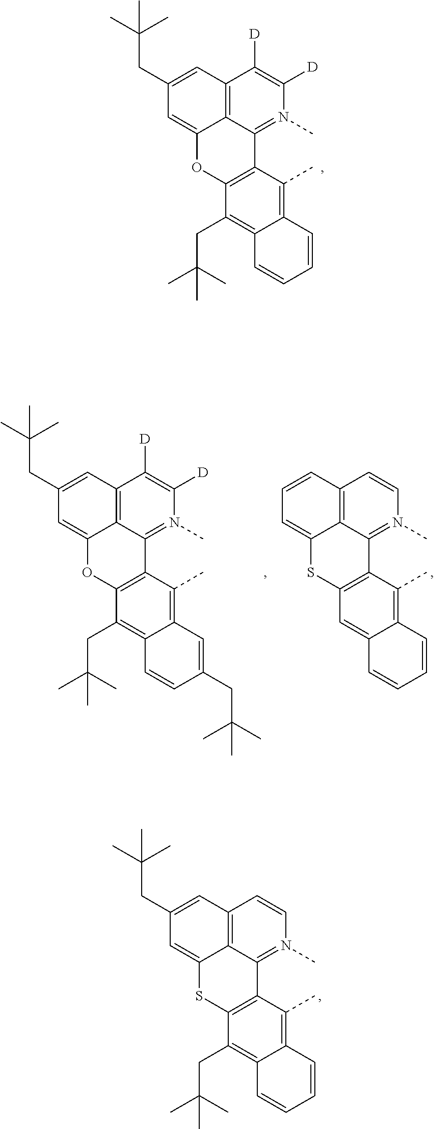

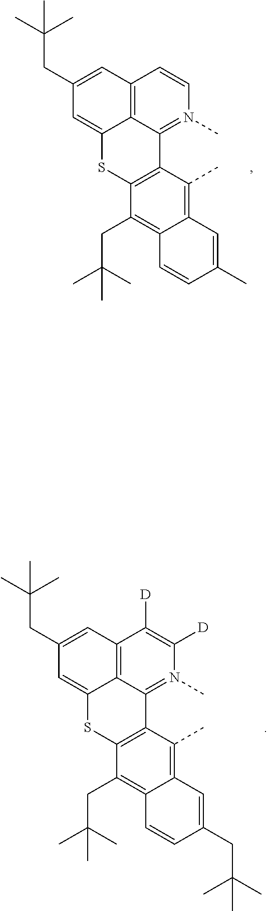

According to an embodiment of the present disclosure, in the electroluminescent device, the ligand L_{b} is, at each occurrence identically or differently, selected from any one of the group consisting of the following structures:

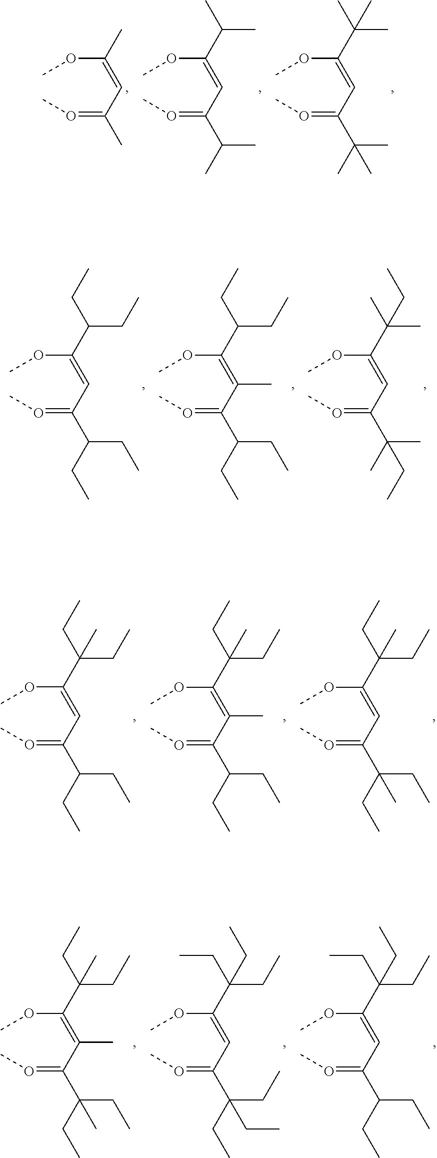

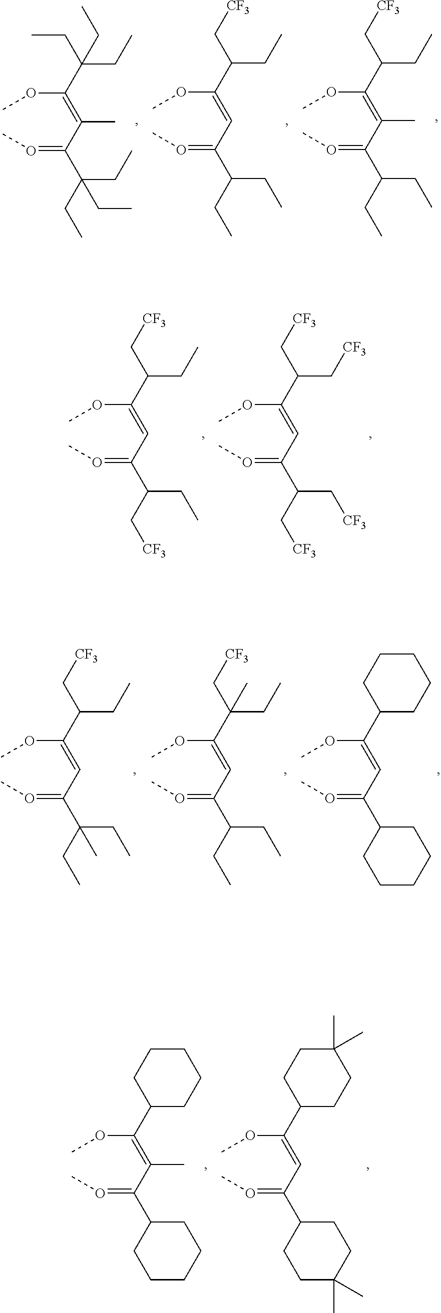

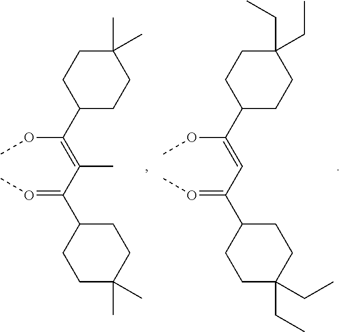

According to an embodiment of the present disclosure, in the electroluminescent device, the phosphorescent material is selected from the group consisting of the following structures:

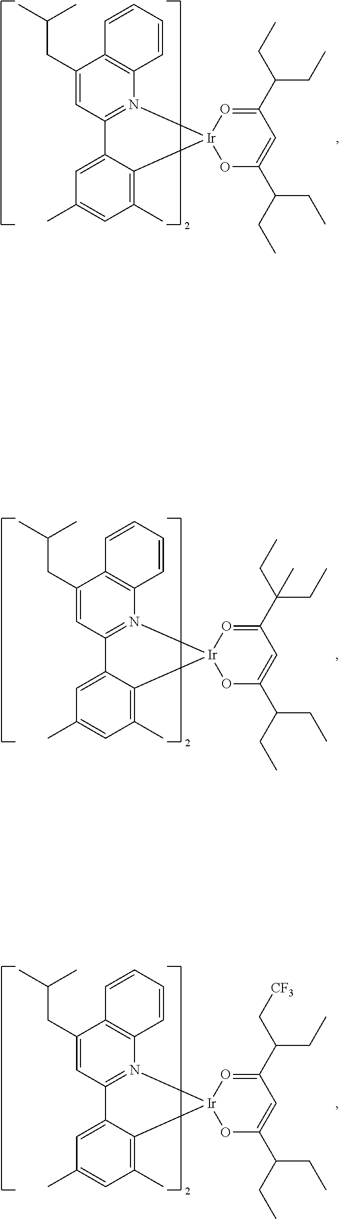

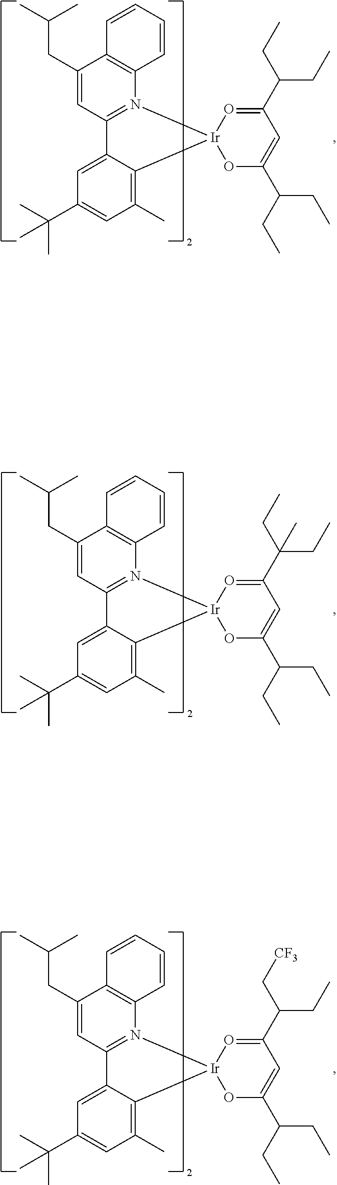

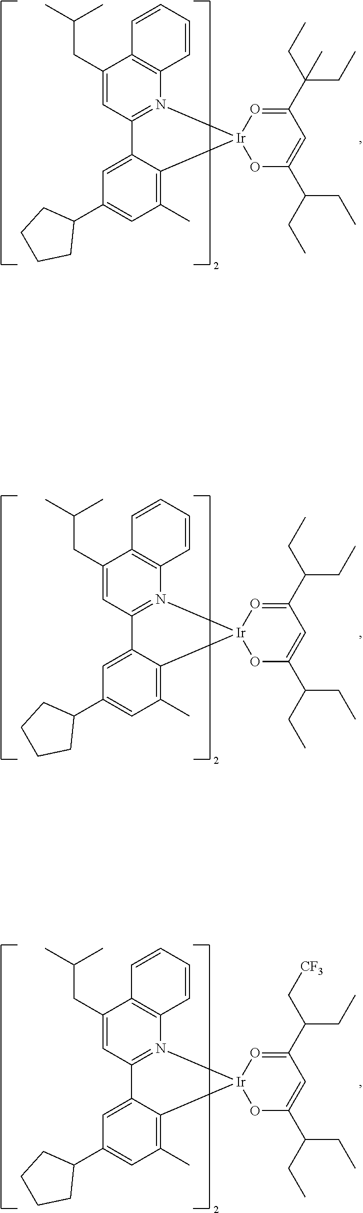

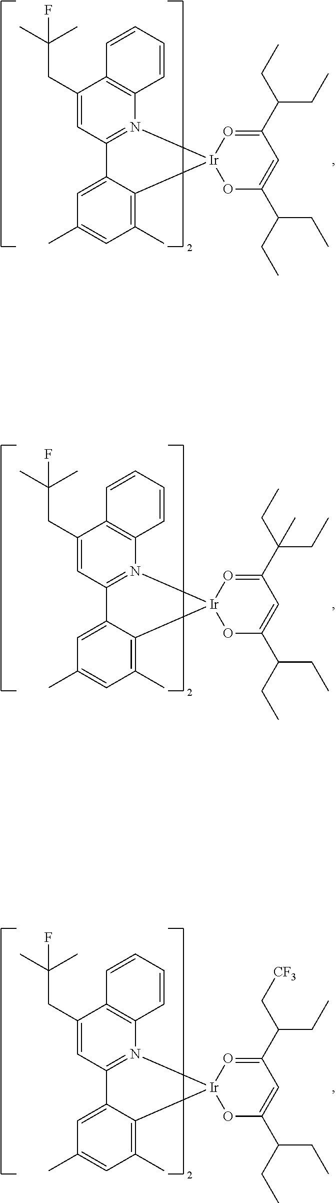

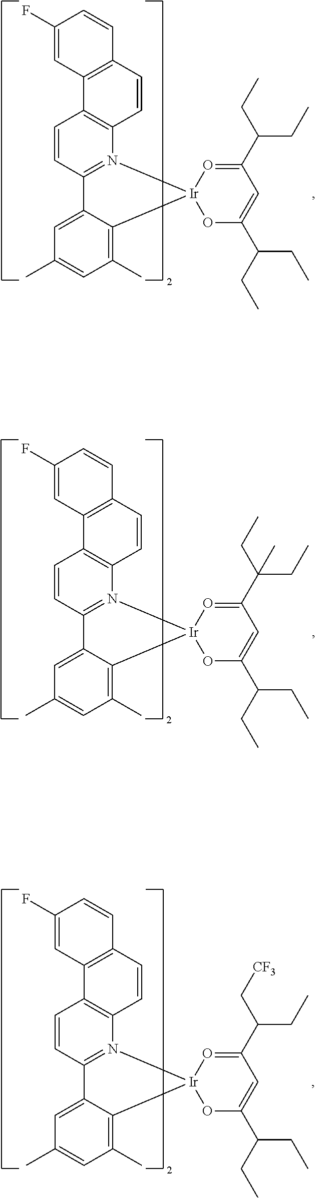

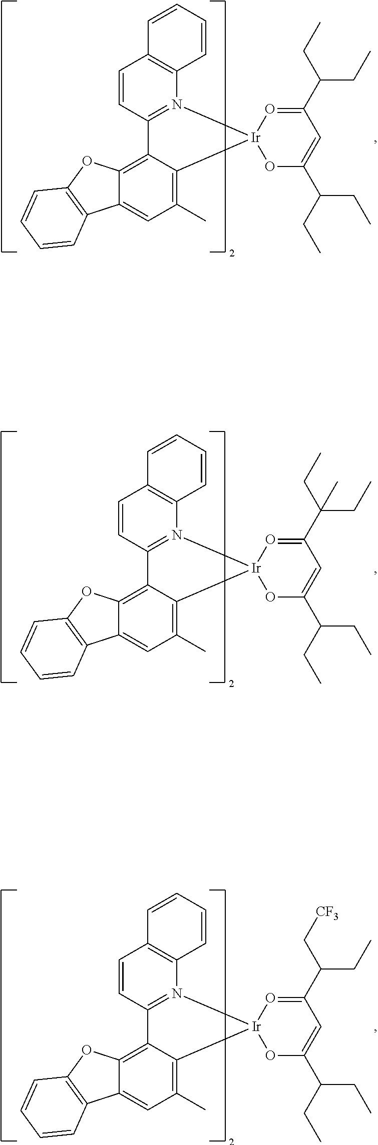

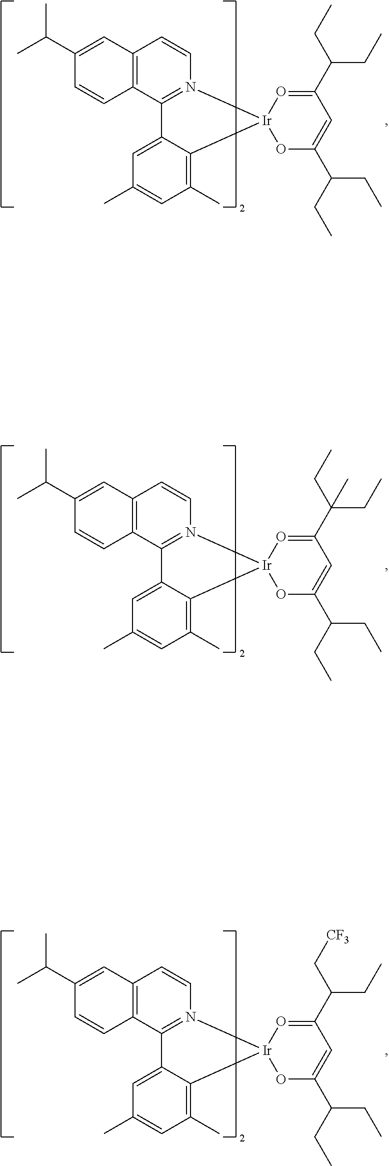

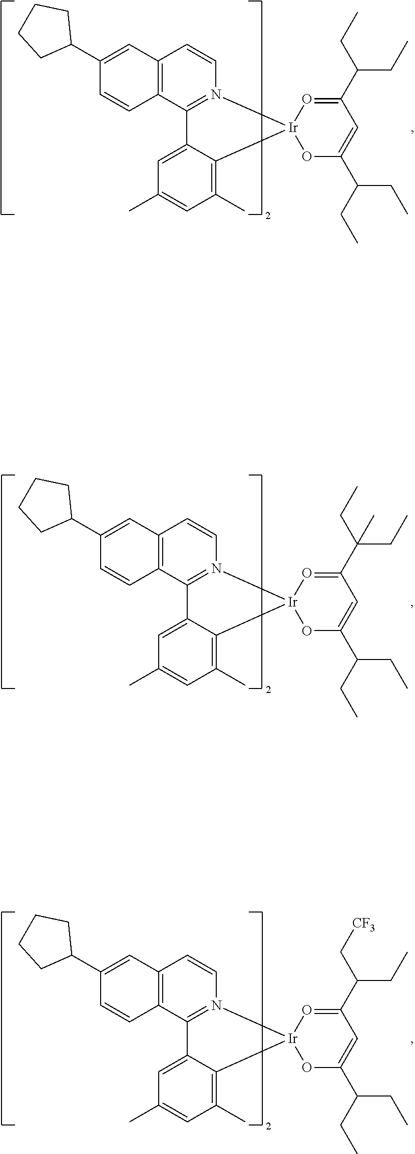

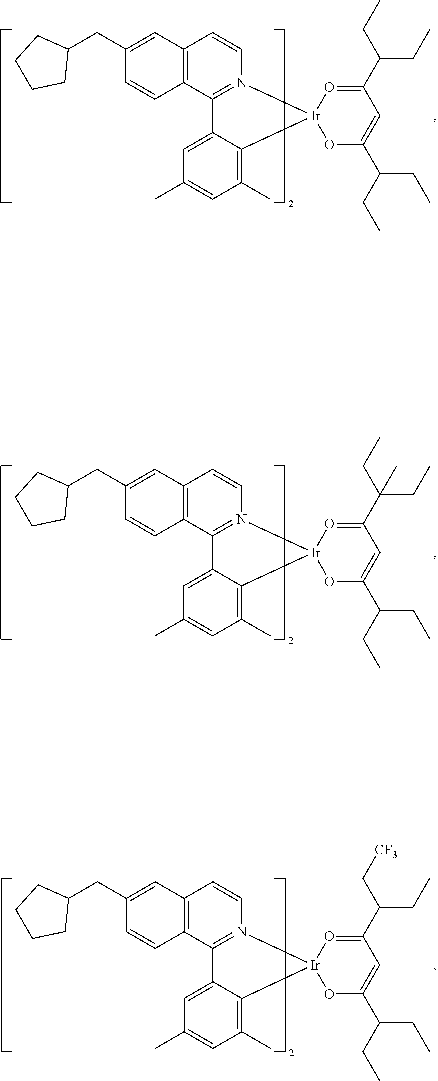

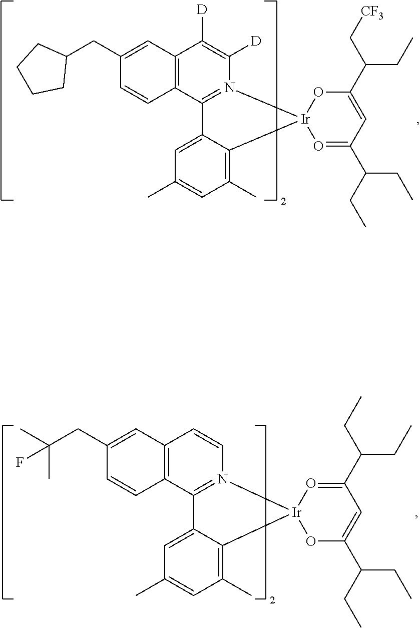

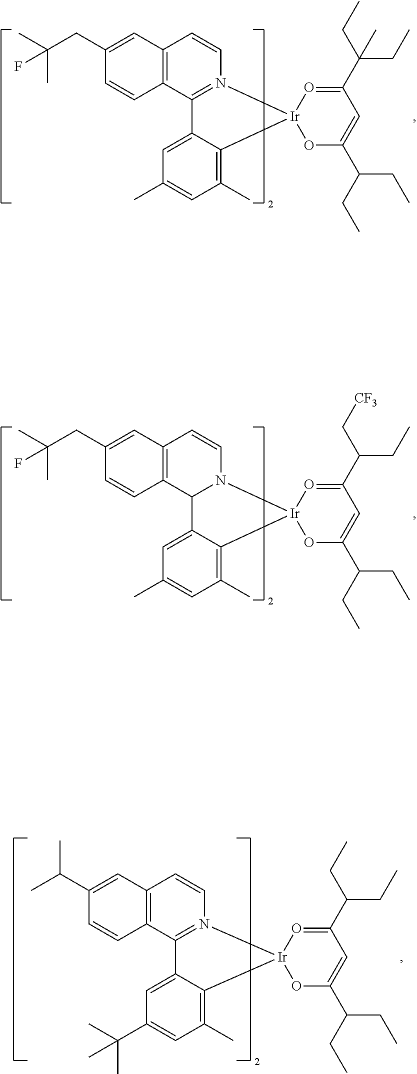

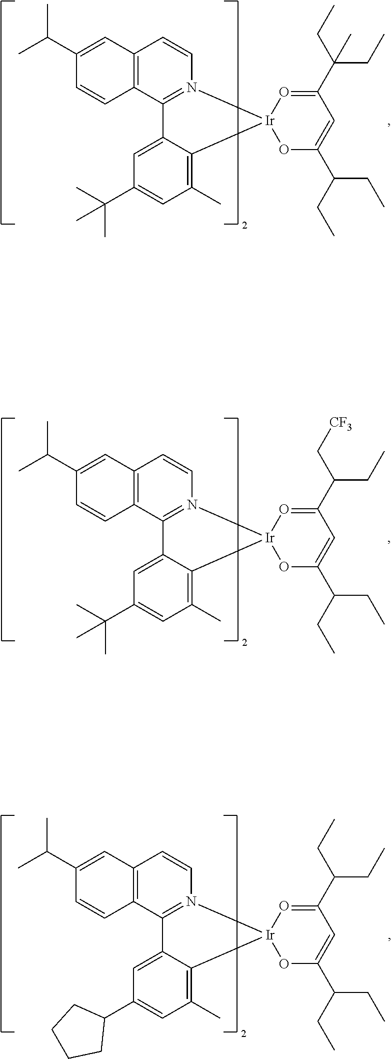

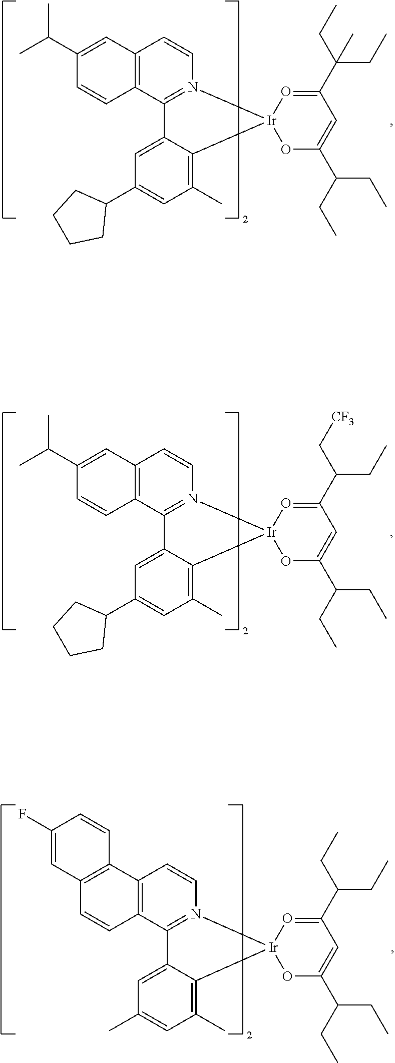

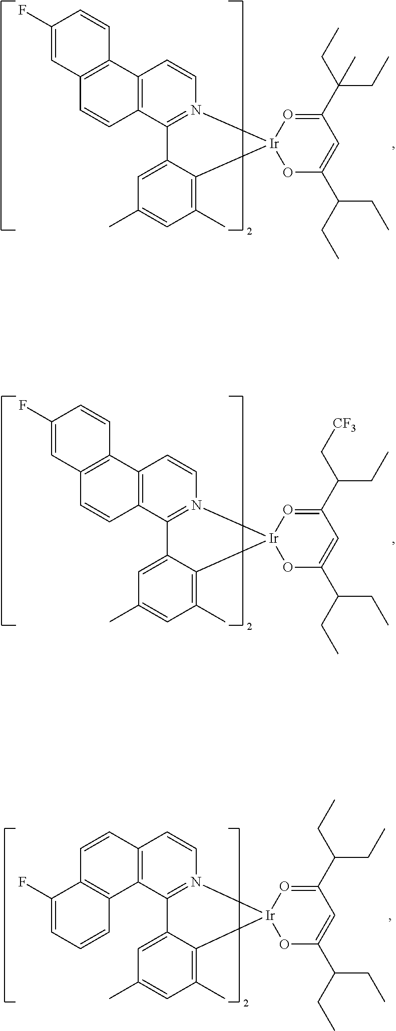

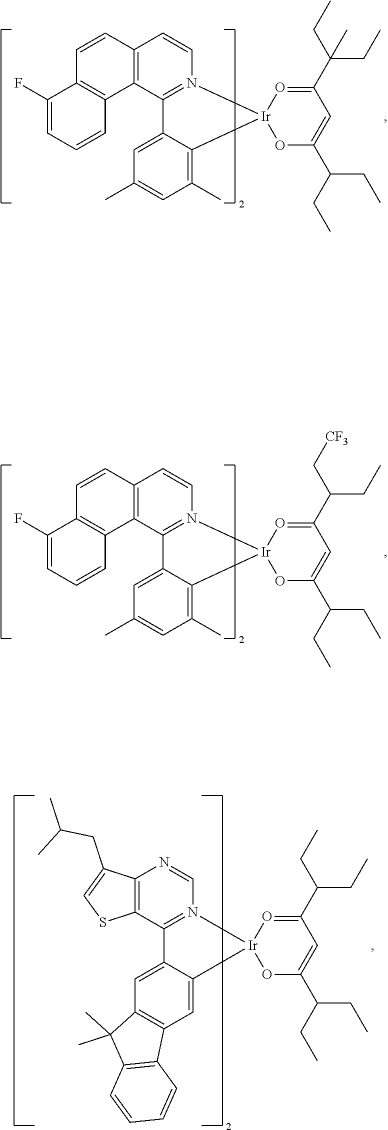

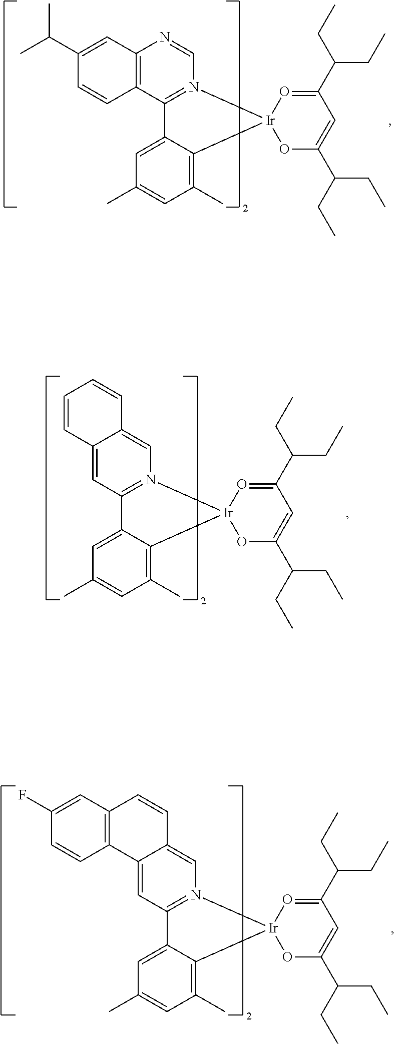

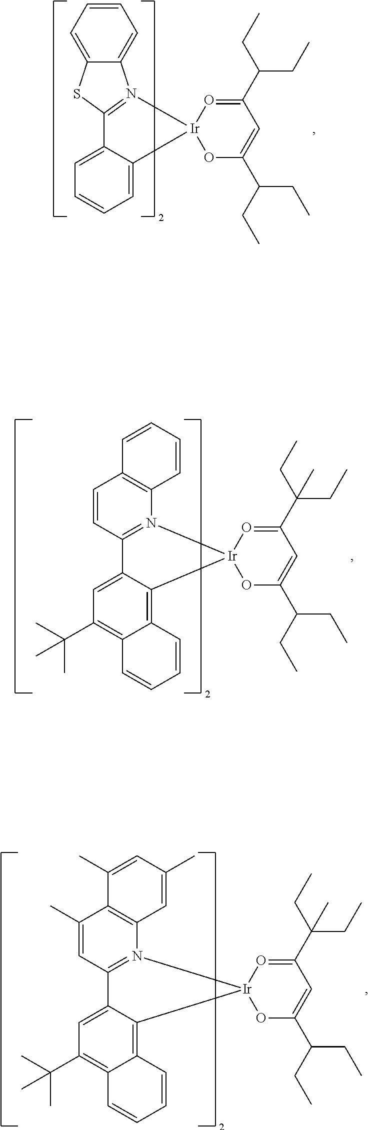

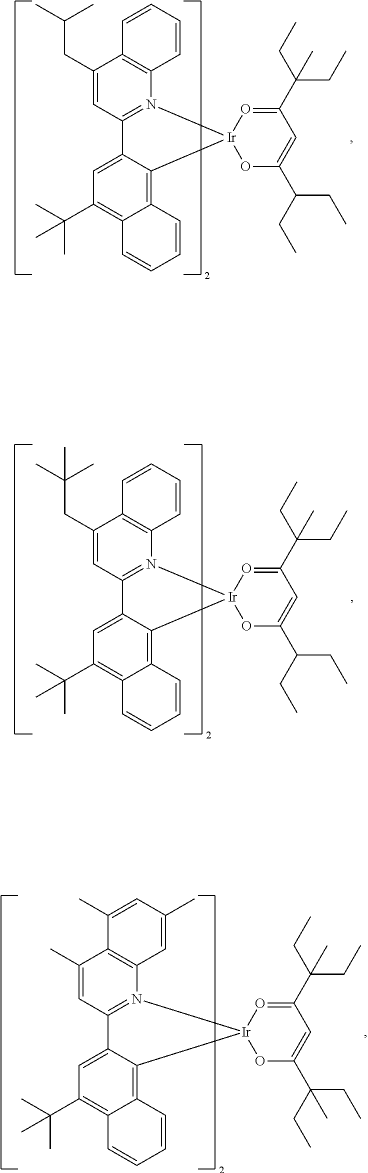

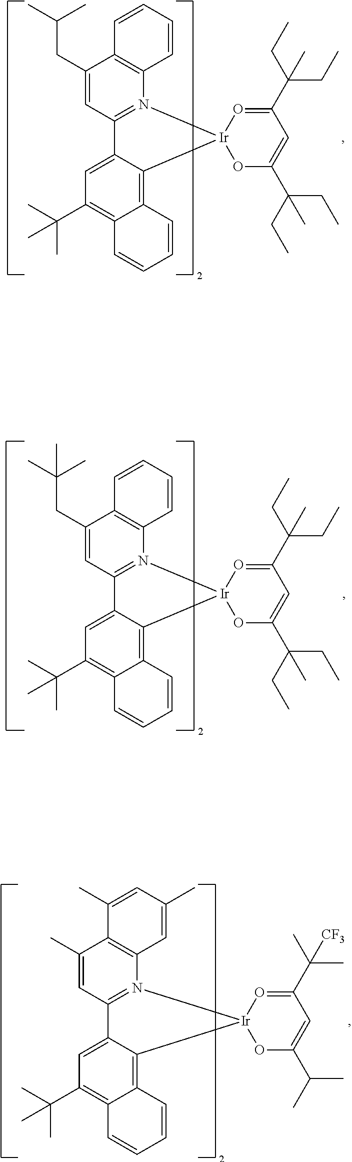

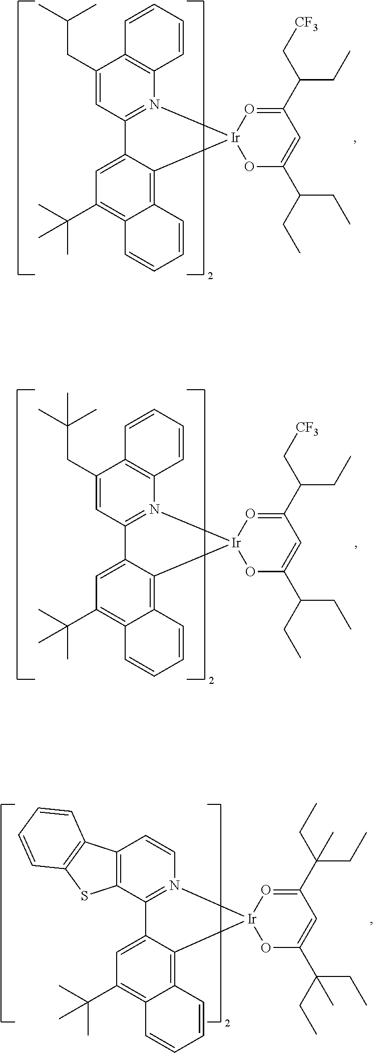

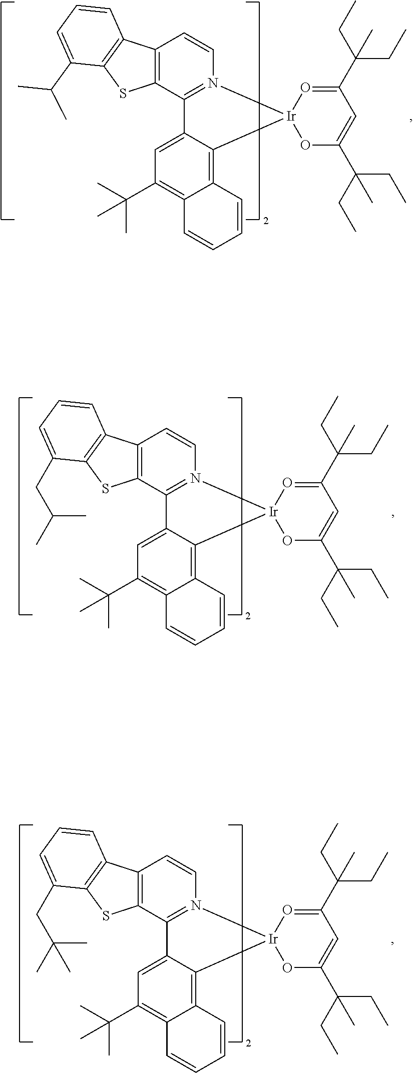

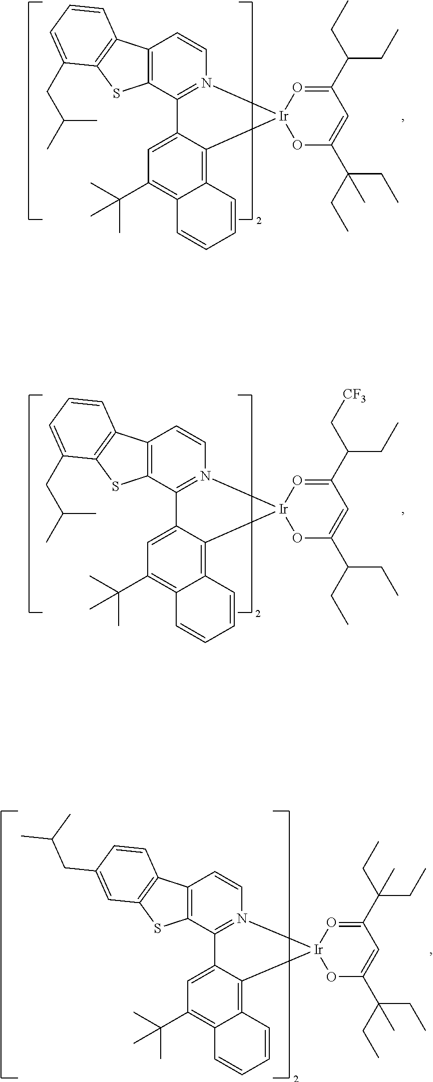

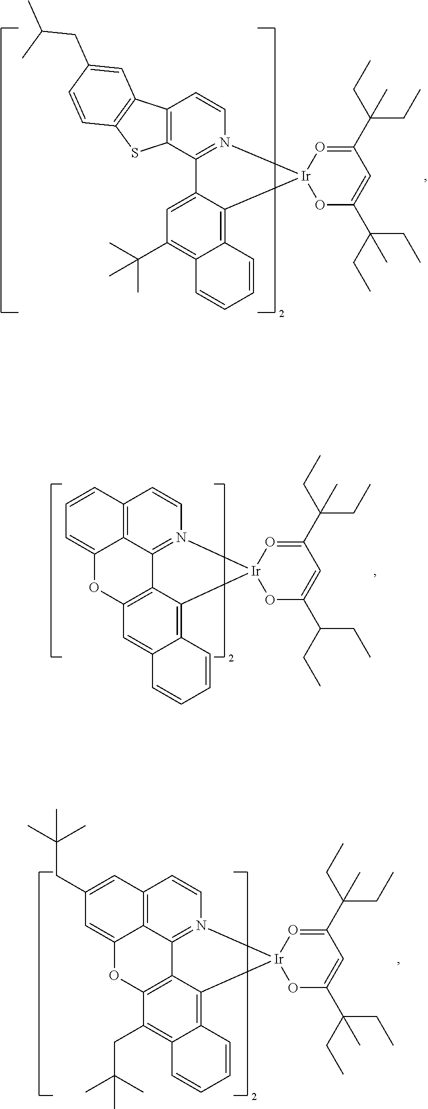

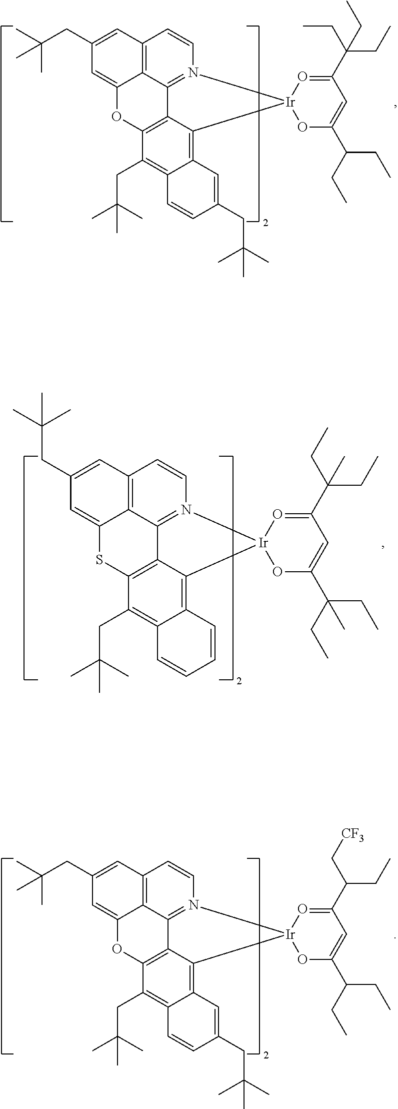

According to an embodiment of the present disclosure, the organic electroluminescent device is a stacked device.

According to an embodiment of the present disclosure, disclosed is a compound composition, which comprises the compound in any one of the preceding embodiments.

### Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

The method for preparing a compound of the present disclosure is not limited herein. Typically, the following compounds are used as examples without limitation, and synthesis routes and preparation methods thereof are described below.

### Synthesis Example 1: Synthesis of Compound 382

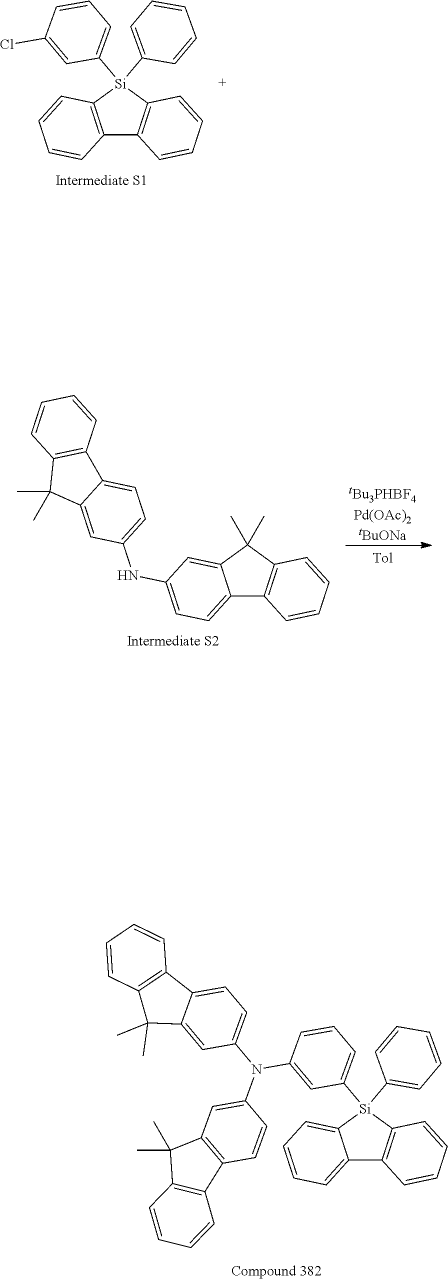

Toluene (150 mL), Intermediate S1 (4.0 g, 10.8 mmol), Intermediate S2 (4.3 g, 14.1 mmol) and NaO^{t}Bu (2.5 g, 27 mmol) were added to a 500 mL three-necked round-bottom flask in sequence, N₂ was introduced for 30 min, Pd(OAc)₂ (0.22 g, 0.97 mmol) and ^{t}Bu₃PHBF₄ (tri-tert-butylphosphine tetrafluoroborate, 1.41 g, 4.86 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 382 (880 mg, with a yield of 11.1%). The product was confirmed as the target product with a molecular weight of 733.32.

### Synthesis Example 2: Synthesis of Compound 1018

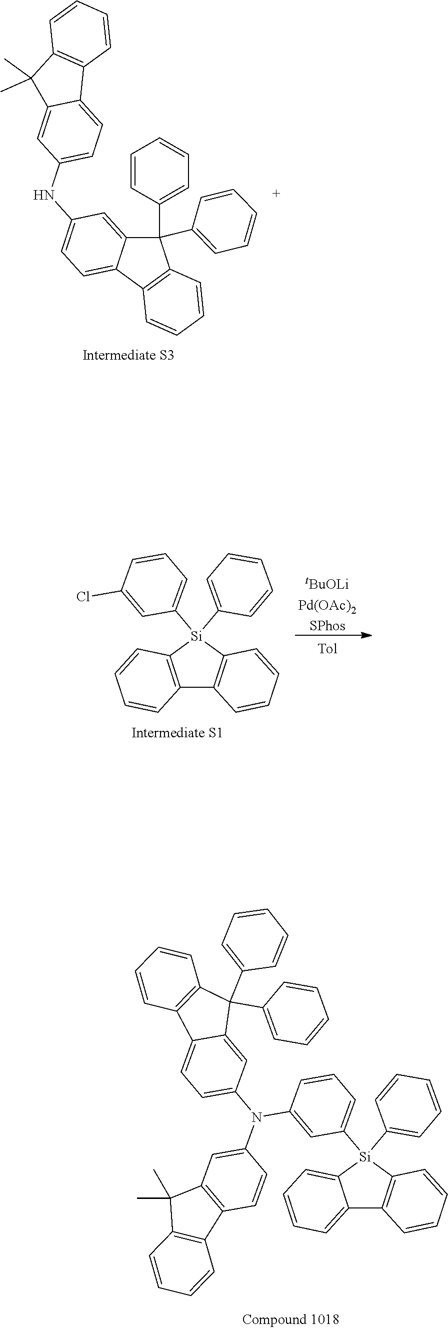

Toluene (55 mL), Intermediate S3 (3 g, 5.7 mmol), Intermediate S1 (2 g, 5.4 mmol) and LiO^{t}Bu (0.9 g, 10.8 mmol) were added to a 250 mL three-necked round-bottom flask in sequence, N₂ was introduced for 20 min, Pd(OAc)₂ (24 mg, 0.108 mmol) and SPhos (2-dicyclohexylphosphino-2′,6′-dimethoxybiphenyl, 222 mg, 0.54 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 1018 (1.86 g, with a yield of 40.2%). The product was confirmed as the target product with a molecular weight of 857.35.

### Synthesis Example 3: Synthesis of Compound 304

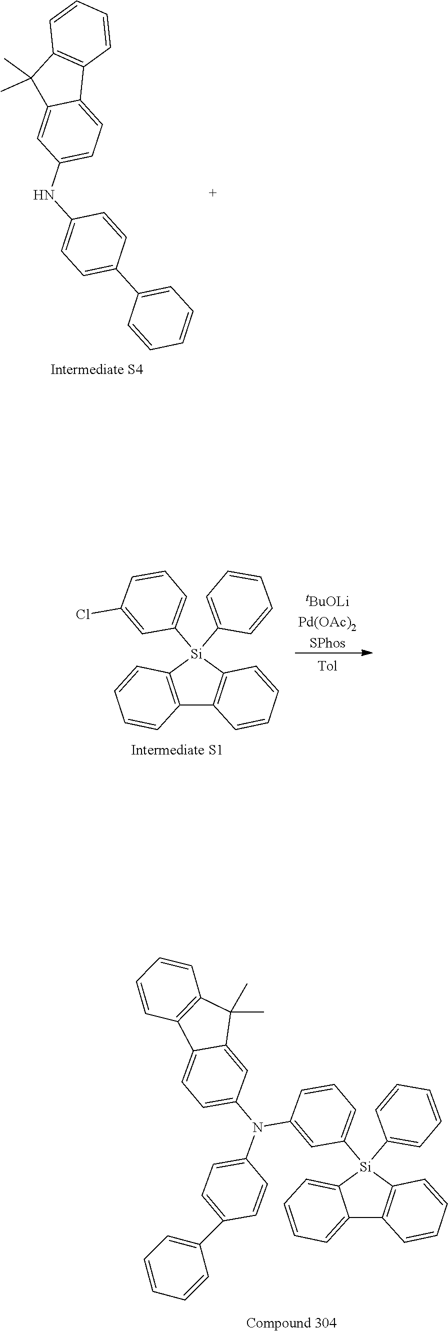

Toluene (85 mL), Intermediate S4 (3 g, 8.3 mmol), Intermediate S1 (3.215 g, 8.71 mmol) and LiO^{t}Bu (1.33 g, 16.6 mmol) were added to a 250 mL three-necked round-bottom flask in sequence, N₂ was introduced for 20 min, Pd(OAc)₂ (37 mg, 0.166 mmol) and SPhos (341 mg, 0.83 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 304 (5.5 g, with a yield of 96%). The product was confirmed as the target product with a molecular weight of 693.29.

### Synthesis Example 4: Synthesis of Compound H557

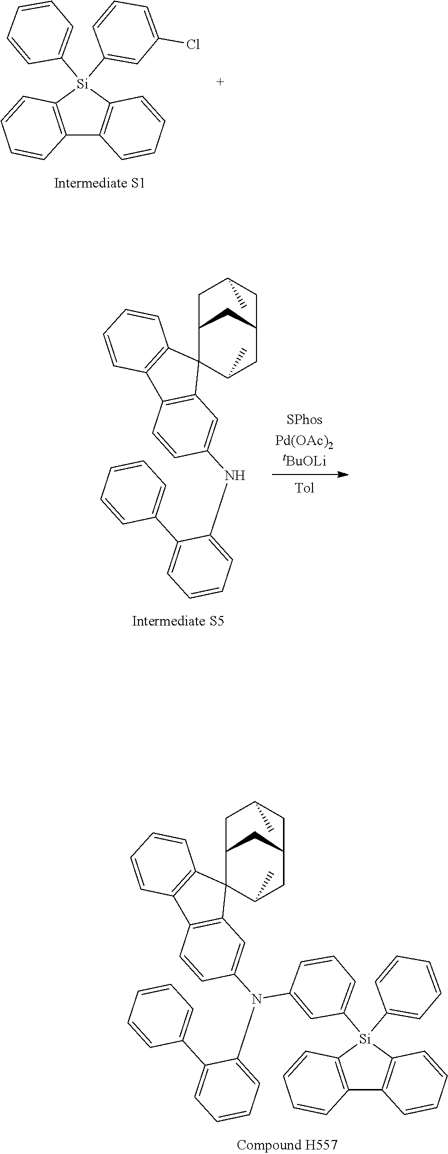 [SMILES: Clc1cccc([Si]2(c3ccccc3)c3ccccc3-c3ccccc32)c1 ; C[C@@H]1C[C@H]2C[C@@H](C1)C1(c3ccccc3-c3ccc(Nc4ccccc4-c4ccccc4)cc31)[C@@H](C)C2 ; C[C@@H]1C[C@H]2C[C@@H](C1)C1(c3ccccc3-c3ccc(N(c4cccc([Si]5(c6ccccc6)c6ccccc6-c6ccccc65)c4)c4ccccc4-c4ccccc4)cc31)[C@@H](C)C2]

Toluene (85 mL), Intermediate S5 (3.58 g, 7.9 mmol), Intermediate S1 (4.0 g, 10.84 mmol) and LiO^{t}Bu (1.33 g, 16.6 mmol) were added to a 250 mL three-necked round-bottom flask in sequence, N₂ was introduced for 20 min, Pd(OAc)₂ (37 mg, 0.166 mmol) and SPhos (341 mg, 0.83 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound H557 (1.9 g, with a yield of 27.3%). The product was confirmed as the target product with a molecular weight of 785.35.

### Synthesis Example 5: Synthesis of Compound H599

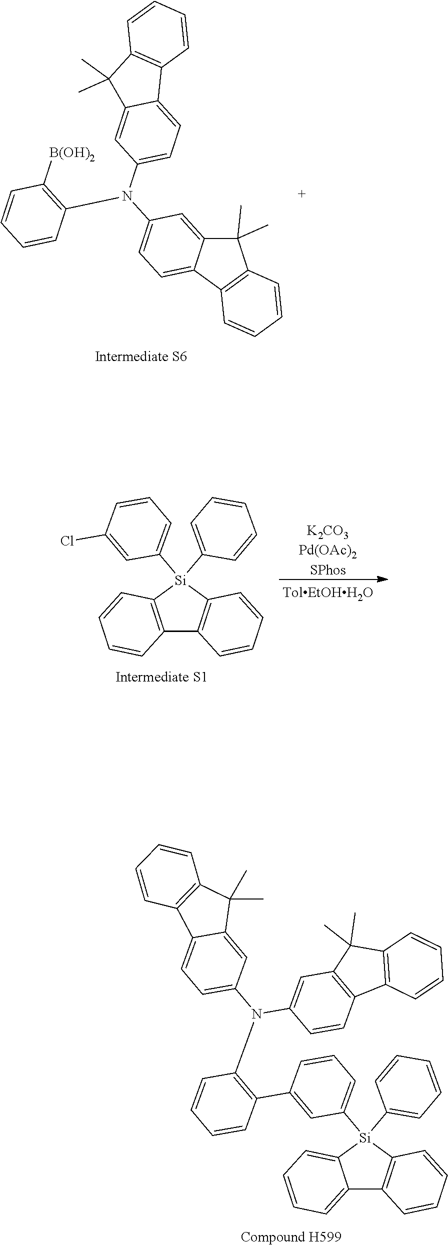

Toluene (100 mL), ethanol (20 mL), water (20 mL), Intermediate S1 (3.1 g, 8.4 mmol), Intermediate S6 (5.3 g, 10.1 mmol) and K₂CO₃ (2.32 g, 16.8 mmol) were added to a 250 mL three-necked round-bottom flask in sequence, N₂ was introduced for 20 min, Pd(OAc)₂ (48 mg, 0.216 mmol) and SPhos (222 mg, 0.54 mmol) were added, and the reaction was carried out overnight at 120° C. It was monitored through TLC that the reaction was complete. The temperature of the reaction solution was lowered to room temperature, the reaction solution stood still to separate layers, the aqueous phase was extracted once with DCM, the organic phases were combined and subjected to rotary evaporation to dryness, and the reaction solution is purified through column chromatography to obtain a white solid Compound H599 (4 g, with a yield of 58.7%). The product was confirmed as the target product with a molecular weight of 809.35.

### Synthesis Example 6: Synthesis of Compound H284

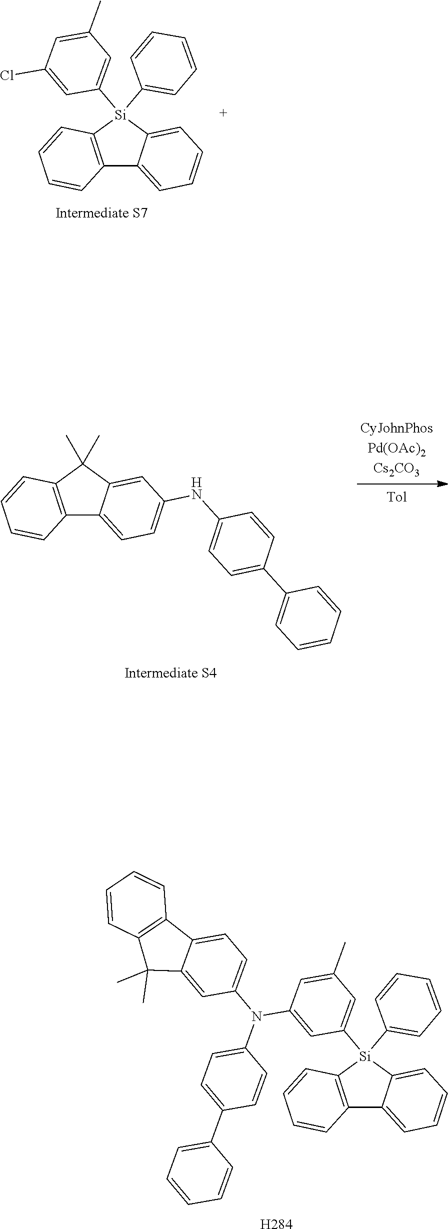

Toluene (240 mL), Intermediate S7 (8 g, 20.89 mmol), Intermediate S4 (7.92 g, 21.91 mmol) and Cs₂CO₃ (13.58 g, 41.78 mmol) were added to a 500 mL three-necked round-bottom flask in sequence, N₂ was introduced for 20 min, Pd(OAc)₂ (140 mg, 0.624 mmol) and CyJohnPhos (2-(dicyclohexylphosphino)biphenyl, 732 mg, 2.09 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound H284 (2.34 g, with a yield of 15.8%). The product was confirmed as the target product with a molecular weight of 707.3.

### Synthesis Example 7: Synthesis of Compound 1996

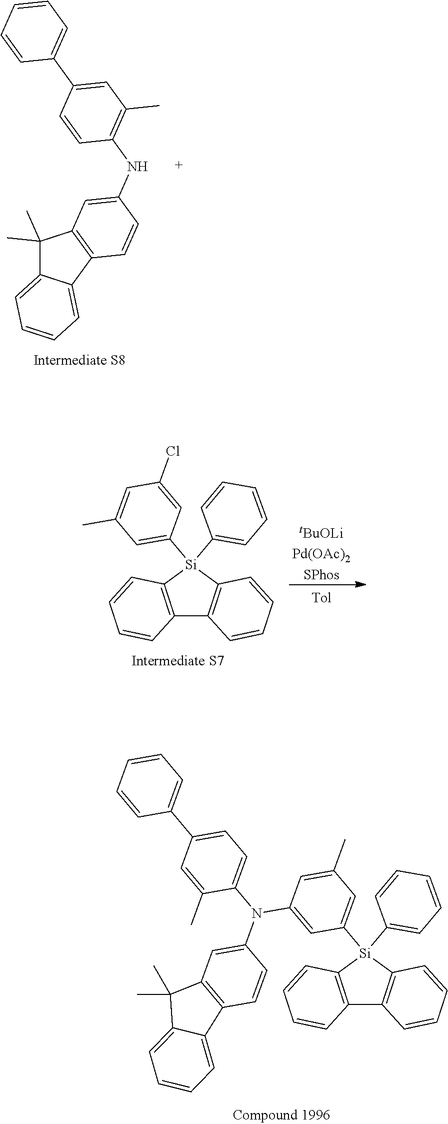

Toluene (100 mL), Intermediate S8 (2.9 g, 7.8 mmol), Intermediate S7 (3 g, 7.8 mmol) and LiO^{t}Bu (1.25 g, 15.6 mmol) were added to a 250 mL three-necked round-bottom flask in sequence, N₂ was introduced for 20 min, Pd(OAc)₂ (48 mg, 0.216 mmol) and SPhos (222 mg, 0.54 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 1996 (2.6 g, with a yield of 46.2%). The product was confirmed as the target product with a molecular weight of 721.32.

### Synthesis Example 8: Synthesis of Compound 1999

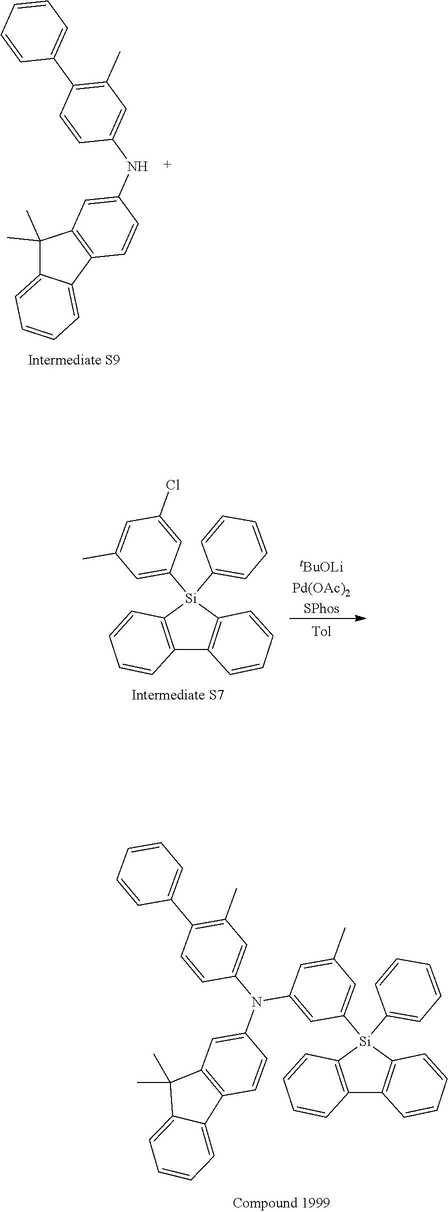

Toluene (100 mL), Intermediate S9 (2.9 g, 7.8 mmol), Intermediate S7 (3 g, 7.8 mmol) and LiO^{t}Bu (1.25 g, 15.6 mmol) were added to a 250 mL three-necked round-bottom flask in sequence, N₂ was introduced for 20 min, Pd(OAc)₂ (48 mg, 0.216 mmol) and SPhos (222 mg, 0.54 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 1999 (4.4 g, with a yield of 78.2%). The product was confirmed as the target product with a molecular weight of 721.32.

### Synthesis Example 9: Synthesis of Compound 1924

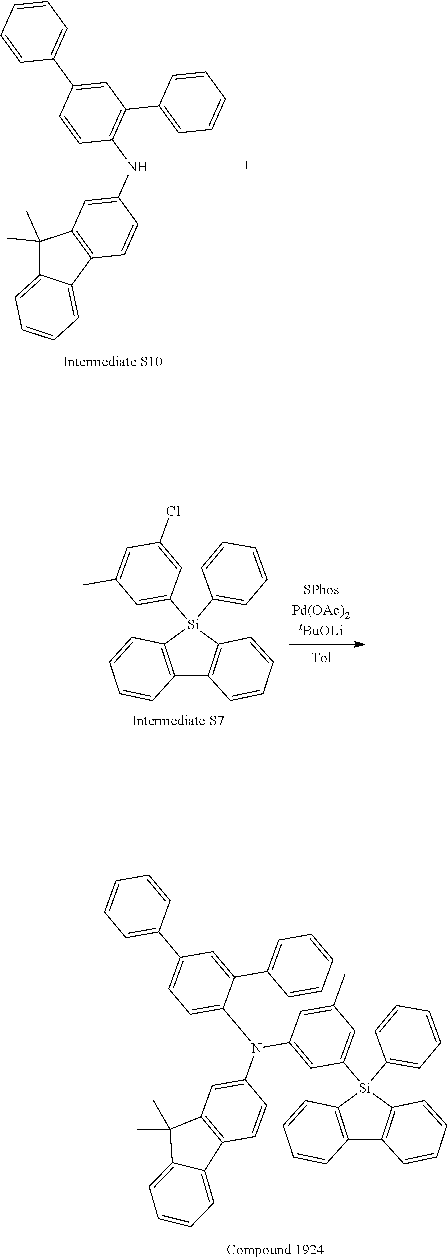

Toluene (100 mL), Intermediate S10 (3.4 g, 7.8 mmol), Intermediate S7 (3 g, 7.8 mmol) and LiO^{t}Bu (1.25 g, 15.6 mmol) were added to a 250 mL three-necked round-bottom flask in sequence, N₂ was introduced for 20 min, Pd(OAc)₂ (48 mg, 0.216 mmol) and SPhos (222 mg, 0.54 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 1924 (1.96 g, with a yield of 32.1%). The product was confirmed as the target product with a molecular weight of 783.33.

### Synthesis Example 10: Synthesis of Compound 1927

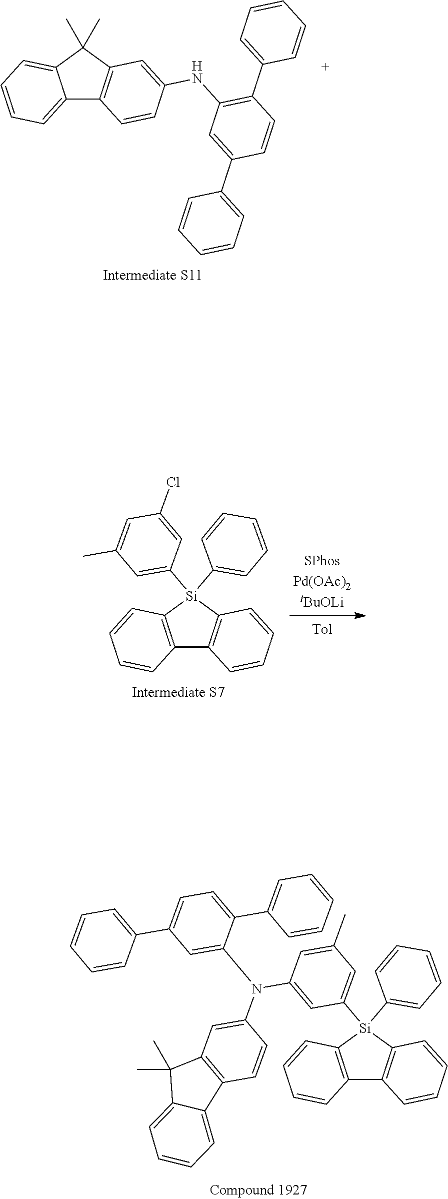

Toluene (100 mL), Intermediate S11 (3.4 g, 7.8 mmol), Intermediate S7 (3 g, 7.8 mmol) and LiO^{t}Bu (1.25 g, 15.6 mmol) were added to a 250 mL three-necked round-bottom flask in sequence, N₂ was introduced for 20 min, Pd(OAc)₂ (48 mg, 0.216 mmol) and SPhos (222 mg, 0.54 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 1927 (3.68 g, with a yield of 60.3%). The product was confirmed as the target product with a molecular weight of 783.33.

### Synthesis Example 11: Synthesis of Compound 385

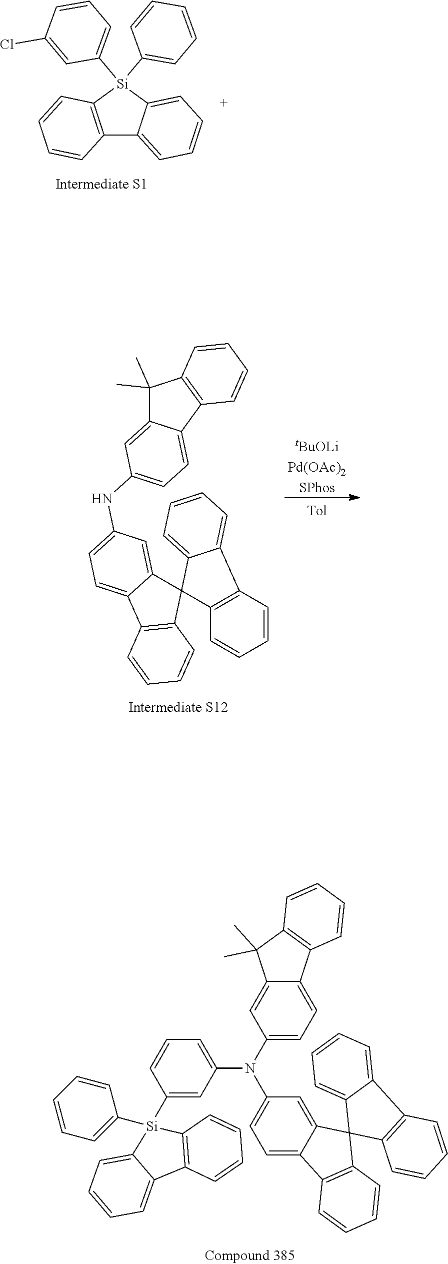 [SMILES: Clc1cccc([Si]2(c3ccccc3)c3ccccc3-c3ccccc32)c1 ; CC1(C)c2ccccc2-c2ccc(Nc3ccc4c(c3)C3(c5ccccc5-c5ccccc53)c3ccccc3-4)cc21 ; "tBuOLiPd(OAc)2SPhos" ; CC1(C)c2ccccc2-c2ccc(N(c3cccc([Si]4(c5ccccc5)c5ccccc5-c5ccccc54)c3)c3ccc4c(c3)C3(c5ccccc5-c5ccccc53)c3ccccc3-4)cc21]

Toluene (100 mL), Intermediate S1 (4 g, 10.8 mmol), Intermediate S12 (2.94 g, 5.6 mmol) and LiO^{t}Bu (1.25 g, 15.6 mmol) were added to a 250 mL three-necked round-bottom flask in sequence, N₂ was introduced for 20 min, Pd(OAc)₂ (48 mg, 0.216 mmol) and SPhos (222 mg, 0.54 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 385 (3.27 g, with a yield of 68.1%). The product was confirmed as the target product with a molecular weight of 855.33.

### Synthesis Example 12: Synthesis of Compound 2727

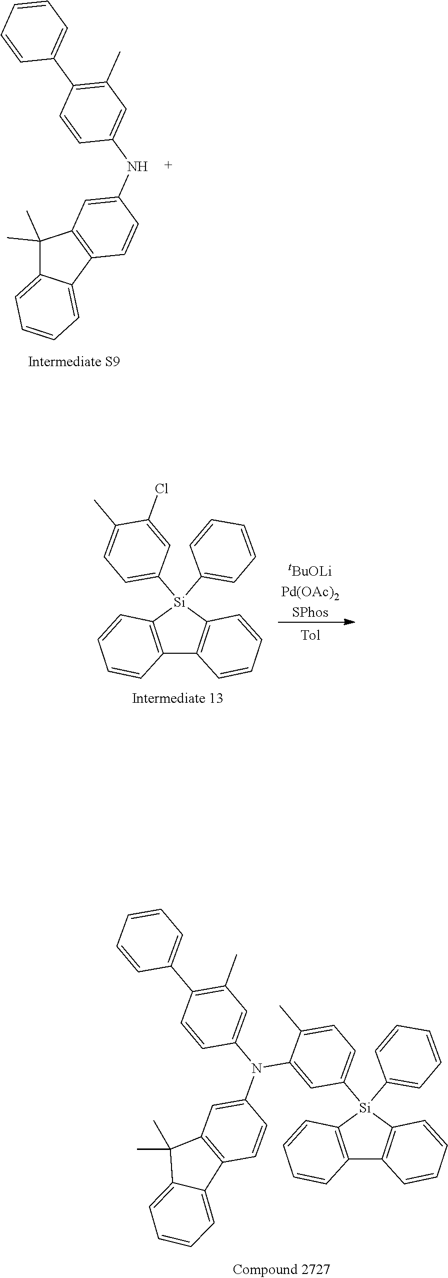

Toluene (100 mL), Intermediate S9 (2.9 g, 7.8 mmol), Intermediate S13 (3 g, 7.8 mmol) and LiO^{t}Bu (1.25 g, 15.6 mmol) were added to a 250 mL three-necked round-bottom flask in sequence, N₂ was introduced for 20 min, Pd(OAc)₂ (48 mg, 0.216 mmol) and SPhos (222 mg, 0.54 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 2727 (4.4 g, with a yield of 78.2%). The product was confirmed as the target product with a molecular weight of 721.32.

### Synthesis Example 13: Synthesis of Compound 391

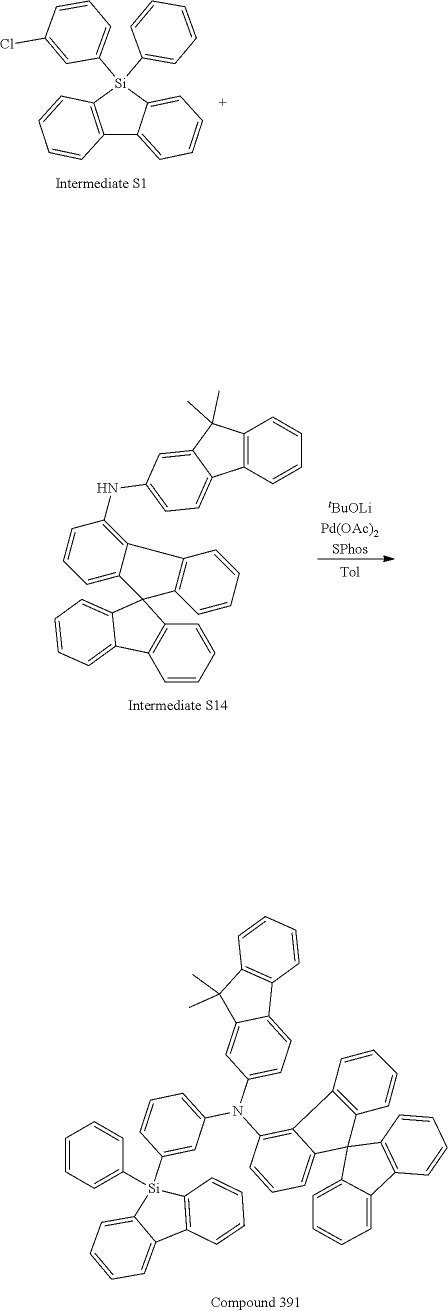 [SMILES: Clc1cccc([Si]2(c3ccccc3)c3ccccc3-c3ccccc32)c1 ; CC1(C)c2ccccc2-c2ccc(Nc3cccc4c3-c3ccccc3C43c4ccccc4-c4ccccc43)cc21 ; "tBuOLiPd(OAc)2SPhos" ; CC1(C)c2ccccc2-c2ccc(N(c3cccc([Si]4(c5ccccc5)c5ccccc5-c5ccccc54)c3)c3cccc4c3-c3ccccc3C43c4ccccc4-c4ccccc43)cc21]

Toluene (100 mL), Intermediate S1 (4 g, 10.8 mmol), Intermediate S14 (2.94 g, 5.6 mmol) and LiO^{t}Bu (1.25 g, 15.6 mmol) were added to a 250 mL three-necked round-bottom flask in sequence, N₂ was introduced for 20 min, Pd(OAc)₂ (48 mg, 0.216 mmol) and SPhos (222 mg, 0.54 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 391 (2.7 g, with a yield of 56.8%). The product was confirmed as the target product with a molecular weight of 855.33.

### Synthesis Example 14: Synthesis of Compound 1888

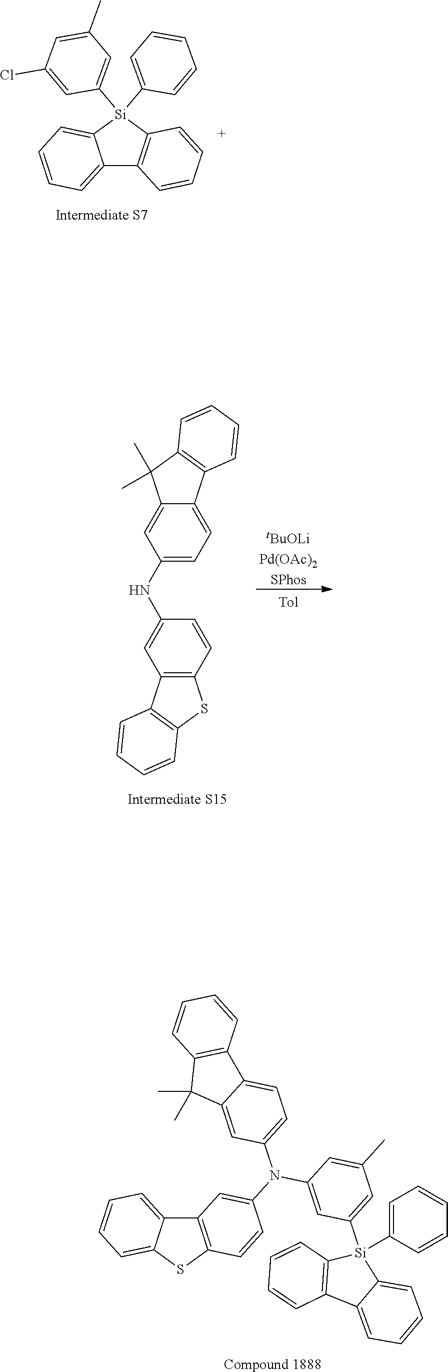 [SMILES: Cc1cc(Cl)cc([Si]2(c3ccccc3)c3ccccc3-c3ccccc32)c1 ; CC1(C)c2ccccc2-c2ccc(Nc3ccc4sc5ccccc5c4c3)cc21 ; "tBuOLiPd(OAc)2SPhos" ; Cc1cc(N(c2ccc3c(c2)C(C)(C)c2ccccc2-3)c2ccc3sc4ccccc4c3c2)cc([Si]2(c3ccccc3)c3ccccc3-c3ccccc32)c1 ; "Compound 1888"]

Toluene (100 mL), Intermediate S7 (4.1 g, 10.7 mmol), Intermediate S15 (4 g, 10.2 mmol) and LiO^{t}Bu (1.64 g, 20.5 mmol) were added to a 250 mL three-necked round-bottom flask in sequence, N₂ was introduced for 20 min, Pd(OAc)₂ (0.046 g, 0.21 mmol) and SPhos (0.42 g, 1.02 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 1888 (4.3 g, with a yield of 57%). The product was confirmed as the target product with a molecular weight of 737.26.

### Synthesis Example 15: Synthesis of Compound 1963

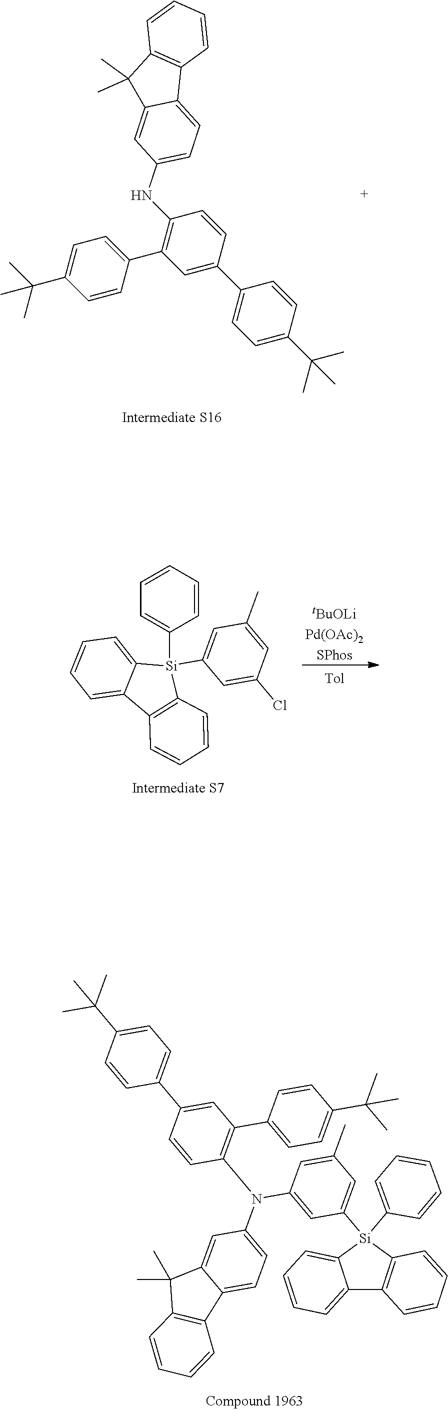

Toluene (100 mL), Intermediate S7 (3.16 g, 8.25 mmol), Intermediate S16 (4.12 g, 7.49 mmol) and LiO^{t}Bu (1.64 g, 20.5 mmol) were added to a 250 mL three-necked round-bottom flask in sequence, N₂ was introduced for 20 min, Pd(OAc)₂ (0.046 g, 0.21 mmol) and SPhos (0.42 g, 1.02 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound 1963 (3.2 g, with a yield of 43.3%). The product was confirmed as the target product with a molecular weight of 895.46.

### Synthesis Example 16: Synthesis of Compound H605

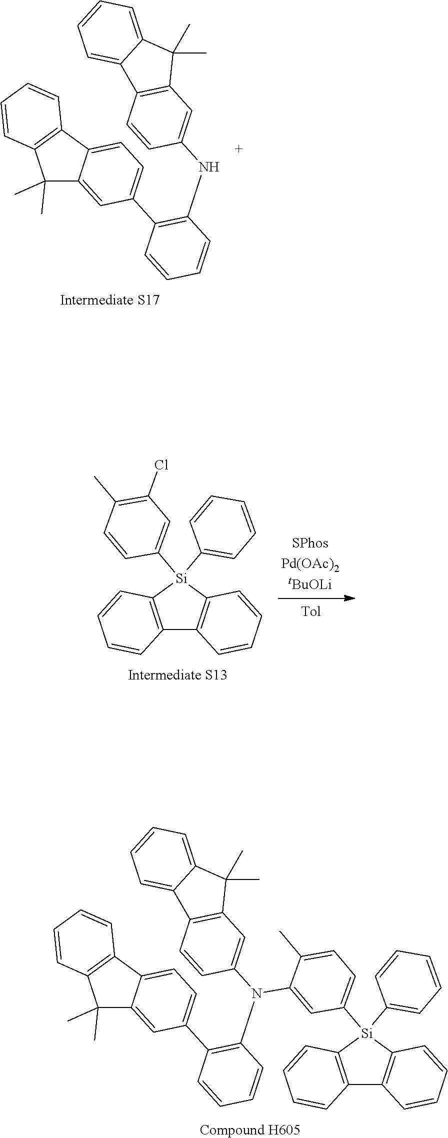

Toluene (100 mL), Intermediate S13 (3.97 g, 10.4 mmol), Intermediate S17 (4.106 g, 8.6 mmol) and LiO^{t}Bu (1.64 g, 20.5 mmol) were added to a 250 mL three-necked round-bottom flask in sequence, N₂ was introduced for 20 min, Pd(OAc)₂ (0.046 g, 0.21 mmol) and SPhos (0.42 g, 1.02 mmol) were added, and the reaction was carried out overnight at 120° C. It was monitored through TLC that the reaction was complete. The temperature of the reaction solution was lowered to room temperature, and the reaction solution is filtered through Celite, subjected to rotary evaporation to dry the filtrate and purified through column chromatography to obtain a white solid Compound H605 (4.6 g, with a yield of 65.0%). The product was confirmed as the target product with a molecular weight of 823.36.

Those skilled in the art will appreciate that the above preparation methods are merely exemplary. Those skilled in the art can obtain other compound structures of the present disclosure through the modifications of the preparation methods.

### Sublimation Characteristics and Thermal Stability of Compounds

Sublimation characteristics are one of the very important parameters of compounds. Materials must pass through a sublimation process before these materials are used for preparing devices. Thus, the sublimation temperatures of the materials will directly affect the power consumption and relate to the costs of production and application.

In the present disclosure, sublimation characteristics of the compounds and comparative compounds of the present disclosure were evaluated according to sublimation temperatures, where sublimation temperatures of the compounds were detected at a vacuum degree of about 2×10⁻⁴ Pa using an apophorometer BOF-A-3-100 of Anhui BEQ Equipment Technology Co., Ltd. (with rated power of 11 KW, a highest heating temperature of 800° C. and a K-type thermocouple).

Thermal stability is also one of the very important parameters of the compounds in that the compounds need to be heated for a long time at an evaporation temperature when devices are prepared for mass production. If the thermal stability of the compounds is poor, the compounds will deteriorate when heated for a long time under a condition of a high temperature, resulting in a decrease in the purity of the compounds and a relatively large difference in performance of devices prepared before, during and after the mass production.

In the present disclosure, the thermal stability of the compounds and the comparative compounds of the present disclosure was evaluated by using an aging experimental method commonly used in the industry. A specific method is as follows: a heating experiment was performed for 100 h by using an apophorometer BOF-8-300 of Anhui BEQ Equipment Technology Co., Ltd. (with rated power of 22 KW, a highest heating temperature of 800° C. and a K-type thermocouple) under conditions of a vacuum degree of 2×10⁻⁴ Pa and an aging temperature that was the sublimation temperature of the compound plus 60° C., the HPLC purity of residual compounds in the apophorometer was measured, and the thermal stability of the compounds was determined through a comparison between purity decrease values before and after the experiment.

The HPLC test conditions and methods are as follows: the instrument brand was SHIMADZU, the instrument model was Prominence-I LC-2030C 3D, the chromatography column was SHIMADZU-GL Inertsil ODS-3 3 μm 4.6*150 mm, the detection wavelength was 254 nm, the acquisition time was 30 min, and the mobile phase was a water:acetonitrile mixed solvent (with a ratio of 10:90).

The thermal stability of the following compounds and comparative compounds of the present disclosure was tested by using the above method:

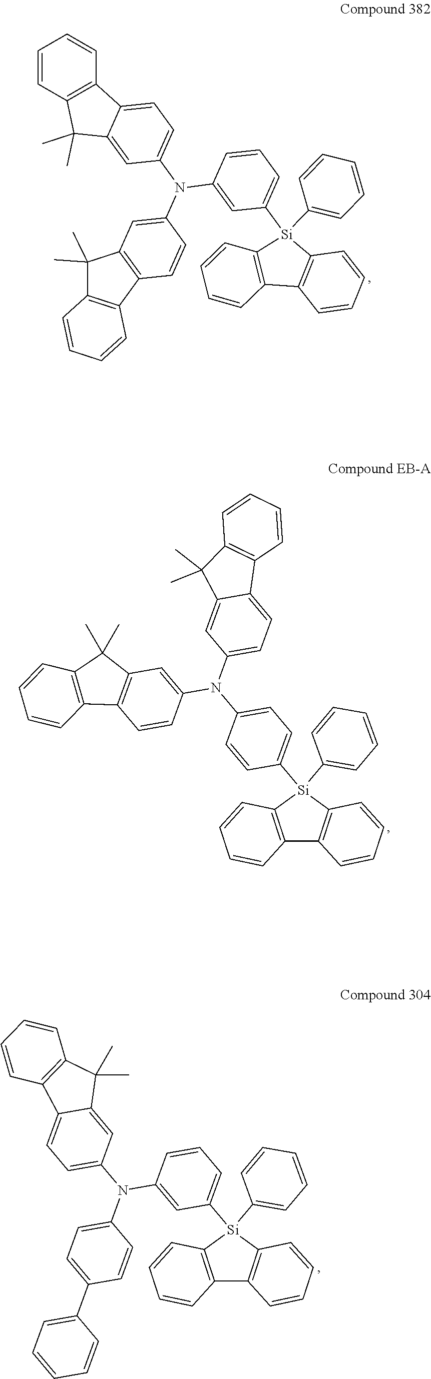 [SMILES: CC1(C)c2ccccc2-c2ccc(N(c3cccc([Si]4(c5ccccc5)c5ccccc5-c5ccccc54)c3)c3ccc4c(c3)C(C)(C)c3ccccc3-4)cc21 ; CC1(C)c2ccccc2-c2ccc(N(c3ccc([Si]4(c5ccccc5)c5ccccc5-c5ccccc54)cc3)c3ccc4c(c3)C(C)(C)c3ccccc3-4)cc21 ; CC1(C)c2ccccc2-c2ccc(N(c3ccc(-c4ccccc4)cc3)c3cccc([Si]4(c5ccccc5)c5ccccc5-c5ccccc54)c3)cc21]

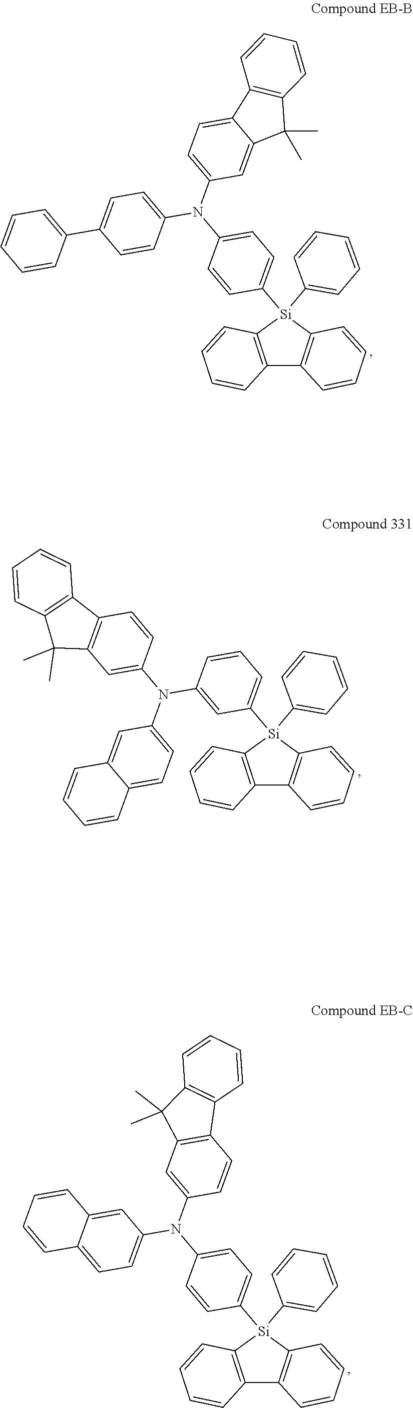 [SMILES: CC1(C)c2ccccc2-c2ccc(N(c3ccc(-c4ccccc4)cc3)c3ccc([Si]4(c5ccccc5)c5ccccc5-c5ccccc54)cc3)cc21 ; CC1(C)c2ccccc2-c2ccc(N(c3cccc([Si]4(c5ccccc5)c5ccccc5-c5ccccc54)c3)c3ccc4ccccc4c3)cc21 ; CC1(C)c2ccccc2-c2ccc(N(c3ccc([Si]4(c5ccccc5)c5ccccc5-c5ccccc54)cc3)c3ccc4ccccc4c3)cc21]

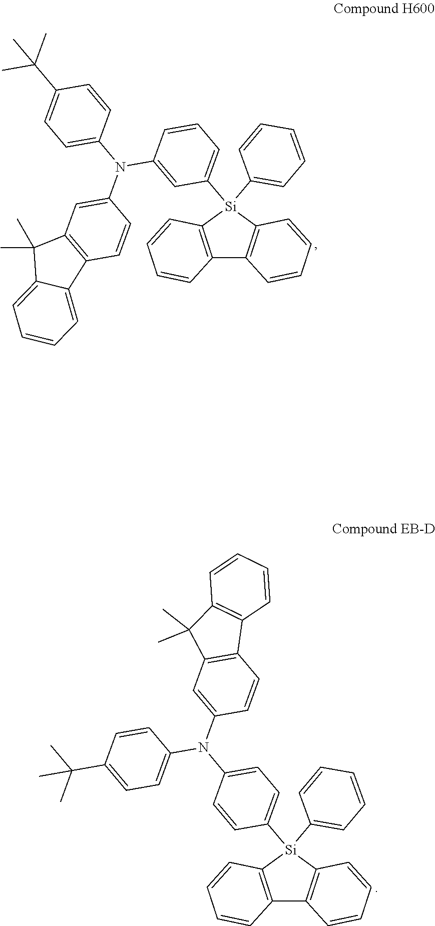 [SMILES: CC(C)(C)c1ccc(N(c2cccc([Si]3(c4ccccc4)c4ccccc4-c4ccccc43)c2)c2ccc3c(c2)C(C)(C)c2ccccc2-3)cc1 ; CC(C)(C)c1ccc(N(c2ccc([Si]3(c4ccccc4)c4ccccc4-c4ccccc43)cc2)c2ccc3c(c2)C(C)(C)c2ccccc2-3)cc1]

The results of the molecular weights, sublimation temperatures, aging temperatures and purity decrease values of the compounds of the present disclosure and comparative compounds are shown in Table 1:

TABLE 1
The molecular weights, sublimation temperatures, aging
temperatures and purity decrease values of the compounds
of the present disclosure and comparative compounds

| | | Sublimation | Aging | HPLC Purity |
|---|---|---|---|---|
| | Molecular | Temperature | Temperature | Decrease |
| Compound | Weight | (° C.) | (° C.) | Value (%) |
| Compound 382 | 733.32 | 260 | 320 | 0.89 |
| Compound EB-A | 733.32 | 310 | 370 | 75.87 |
| Compound 304 | 693.29 | 270 | 330 | 1.45 |
| Compound EB-B | 693.29 | 310 | 370 | 79.99 |
| Compound 331 | 667.27 | 270 | 330 | 0.28 |
| Compound EB-C | 667.27 | 300 | 360 | 10.82 |
| Compound H600 | 673.32 | 280 | 340 | 1.83 |
| Compound EB-D | 673.32 | 310 | 370 | 78.99 |

As can be seen from the data in Table 1, the sublimation temperatures of Compound 382, Compound 304, Compound 331 and Compound H600 of the present disclosure are relatively low, among which the maximum is 280° C., while the sublimation temperatures of Compound EB-A, Compound EB-B, Compound EB-C and Compound EB-D are relatively high, which are all 300° C. or higher.

Compound 382 of the present disclosure and Comparative Compound EB-A, which have the same molecular weight, are typical isomers and differ only in that the arylamine nitrogen atom of Compound 382 of the present disclosure is located at the meta position of silafluorene phenyl while the arylamine nitrogen atom of Comparative Compound EB-A is located at the para position of silafluorene phenyl. However, the sublimation temperature of Compound 382 of the present disclosure is significantly reduced by 50° C. compared with that of Compound EB-A. Similarly, Compound 304 of the present disclosure and Comparative Compound EB-B, Compound 331 of the present disclosure and Comparative Compound EB-C, and Compound H600 of the present disclosure and Comparative Compound EB-D, which have the same molecular weight, are typical isomers and differ only in that the arylamine nitrogen atom of the compound of the present disclosure is located at the meta position of silafluorene phenyl while the arylamine nitrogen atom of the comparative compound is located at the para position of silafluorene phenyl. However, it can be seen from the data in Table 1 that the sublimation temperature of Compound 304 of the present disclosure is significantly reduced by 40° C. compared with that of Comparative Compound EB-B, the sublimation temperature of Compound 331 of the present disclosure is significantly reduced by 30° C. compared with that of Comparative Compound EB-C, and the sublimation temperature of Compound H600 of the present disclosure is significantly reduced by 30° C. compared with that of Comparative Compound EB-D.

Generally, isomers with exactly the same parent core structure and only different substituent positions have the same or very similar thermal stability. However, in the compound of the present disclosure, the arylamine nitrogen atom is joined at the particular meta position of silafluorene phenyl, and the sublimation temperature is unexpectedly reduced by at least 30° C. compared with the comparative compound with the arylamine nitrogen atom located at the para position of silafluorene phenyl, which can significantly reduce the energy consumption and cost in the industrial scale production of OLEDs, proving that the compound of the present disclosure has unexpectedly excellent characteristics and great application prospects due to the unique structural design of joining at the meta position.

What deserves more attention is the problem of the thermal stability of the compound. As can be seen from the data in Table 1, the HPLC purity of Compound 382 of the present disclosure after aging is decreased by only 0.89% while the HPLC purity of Comparative Compound EB-A after aging is significantly decreased by 75.87%. The HPLC purity of Compound 304 of the present disclosure after aging is decreased by only 1.45% while the HPLC purity of Comparative Compound EB-B after aging is significantly decreased by 79.99%. The HPLC purity of Compound 331 of the present disclosure after aging is decreased by only 0.28% while the HPLC purity of Comparative Compound EB-C after aging is significantly decreased by 10.82%. The HPLC purity of Compound H600 of the present disclosure after aging is decreased by only 1.83% while the HPLC purity of Comparative Compound EB-D after aging is significantly decreased by 78.99%. Generally, when the purity of the compound is decreased by more than 2%, device performance such as efficiency and lifetime is significantly reduced, which ultimately leads to deterioration of device product performance during mass production and seriously affects a device yield. However, the purity decrease of the compounds of the present disclosure can all be controlled to be within 2% after the aging experiment, proving that the compound of the present disclosure has excellent thermal stability due to the unique structural design of joining at the meta position.

The compound and corresponding comparative compound of the present disclosure are isomers with the exactly the same parent core structure and differ only in the position where the arylamine nitrogen atom is joined to silafluorene phenyl. The compound of the present disclosure exhibits unexpectedly excellent thermal stability compared with the comparative compound, indicating that the compound of the present disclosure can fully adapt to the industrial mass production of OLEDs, ensuring that the deterioration of the device performance is not caused by the thermal stability of the compound during the mass production and ensuring the device yield.

### Preparation of Organic Electroluminescent Devices

The method for preparing an electroluminescent device is not limited. The preparation methods in the following device examples are merely examples and are not to be construed as limitations. Those skilled in the art can make reasonable improvements on the preparation methods in the following device examples based on the related art.

### Device Example

### Device Example 1: Preparation of a Top-Emitting Organic Electroluminescent Device

Firstly, a glass substrate having a thickness of 0.7 mm and patterned with an indium tin oxide (ITO)/silver (Ag)/indium tin oxide (ITO) anode with a thickness of 75 Å/1500 Å/150 Å was washed with deionized water and a detergent, and then the ITO surface was treated with oxygen plasma and UV ozone. Then, the substrate was dried in a glovebox to remove moisture and then mounted on a substrate holder and placed in a vacuum chamber. Organic layers specified below were sequentially deposited on the anode layer through vacuum thermal evaporation at a rate of 0.01-10 Å/s and at a vacuum degree of about 10⁻⁶ Torr. Compound HT-1 and Compound HT-2 were co-deposited for use as a hole injection layer (HIL, with a weight ratio of 98:2, 100 Å). Compound HT-1 was deposited for use as a hole transporting layer (HTL, 1300 Å). Compound 382 of the present disclosure was deposited for use as an electron blocking layer (EBL, 660 Å). Compound RH and Compound RD were co-deposited for use as an emissive layer (EML, with a weight ratio of 98:2, 400 Å). Compound HB was deposited for use as a hole blocking layer (HBL, 50 Å). Compound ET and Liq were co-deposited for use as an electron transporting layer (ETL, 40:60, 350 Å). Yb was deposited for use as an electron injection layer (EIL) with a thickness of 10 Å. The metals Mg and Ag were deposited for use as a cathode (with a weight ratio of 2:98, 140 Å). Finally, Material CPL (650 Å) was deposited for use as a capping layer (the CPL material has a refractive index of about 1.68 at 620 nm, and a 30 nm thick CPL material deposited on a silicon wafer was tested using an ES01 ellipsometer from BEIJING ELLITOP to obtain the refractive index). The device was transferred back to the glovebox and encapsulated with a glass lid to complete the device.

### Device Example 2

The preparation method in Device Example 2 was the same as that in Device Example 1, except that in the electron blocking layer (EBL), Compound 382 of the present disclosure was replaced with Compound 304.

### Device Example 3

The preparation method in Device Example 3 was the same as that in Device Example 1, except that in the electron blocking layer (EBL), Compound 382 of the present disclosure was replaced with Compound 1018.

### Device Comparative Example 1

The preparation method in Device Comparative Example 1 was the same as that in Device Example 1, except that in the electron blocking layer (EBL), Compound 382 of the present disclosure was replaced with Compound EB-1.

### Device Comparative Example 2

The preparation method in Device Comparative Example 2 was the same as that in Device Example 1, except that in the electron blocking layer (EBL), Compound 382 of the present disclosure was replaced with Compound EB-2.

### Device Comparative Example 3

The preparation method in Device Comparative Example 3 was the same as that in Device Example 1, except that in the electron blocking layer (EBL), Compound 382 of the present disclosure was replaced with Compound EB-3.

### Device Comparative Example 4

The preparation method in Device Comparative Example 4 was the same as that in Device Example 1, except that in the electron blocking layer (EBL), Compound 382 of the present disclosure was replaced with Compound EB-4.

### Device Comparative Example 5

The preparation method in Device Comparative Example 5 was the same as that in Device Example 1, except that in the electron blocking layer (EBL), Compound 382 of the present disclosure was replaced with Compound EB-5.

### Device Comparative Example 6

The preparation method in Device Comparative Example 6 was the same as that in Device Example 1, except that in the electron blocking layer (EBL), Compound 382 of the present disclosure was replaced with Compound EB-6.

### Device Comparative Example 7

The preparation method in Device Comparative Example 7 was the same as that in Device Example 1, except that in the electron blocking layer (EBL), Compound 382 of the present disclosure was replaced with Compound EB-7.

Detailed structures and thicknesses of layers of the devices are shown in Table 2. A layer using more than one material is obtained by doping different compounds at their weight ratio as recorded.

TABLE 2
Part of device structures in Examples 1 to 3 and Comparative Examples 1 to 7

| Device No. | HIL | HTL | EBL | EML | HBL | ETL |
|---|---|---|---|---|---|---|
| Example 1 | Compound HT- | Compound | Compound | Compound | Compound | Compound |
| | 1:Compound HT- | HT-1 | 382 | RH:Compound | HB | ET:Liq (40:60) |
| | 2 | (1300 Å) | (660 Å) | RD | (50 Å) | (350 Å) |
| | (98:2) (100 Å) | | | (98:2) (400 Å) | | |
| Example 2 | Compound HT- | Compound | Compound | Compound | Compound | Compound |
| | 1:Compound HT- | HT-1 | 304 | RH:Compound | HB | ET:Liq (40:60) |
| | 2 | (1300 Å) | (660 Å) | RD | (50 Å) | (350 Å) |
| | (98:2)(100 Å) | | | (98:2) (400 Å) | | |
| Example 3 | Compound HT- | Compound | Compound | Compound | Compound | Compound |
| | 1: Compound HT- | HT-1 | 1018 | RH:Compound | HB | ET:Liq (40:60) |
| | 2 | (1300 Å) | (660 Å) | RD | (50 Å) | (350 Å) |
| | (98:2)(100 Å) | | | (98:2) (400 Å) | | |
| Comparative | Compound HT- | Compound | Compound | Compound | Compound | Compound |
| Example 1 | 1:Compound HT- | HT-1 | EB-1 | RH:Compound | HB | ET:Liq (40:60) |
| | 2 | (1300 Å) | (660 Å) | RD (98:2) (400 | (50 Å) | (350 Å) |
| | (98:2)(100 Å) | | | Å) | | |
| Comparative | Compound HT- | Compound | Compound | Compound | Compound | Compound |
| Example 2 | 1: Compound HT- | HT-1 | EB-2 | RH:Compound | HB | ET:Liq (40:60) |
| | 2 | (1300 Å) | (660 Å) | RD | (50 Å) | (350 Å) |
| | (98:2) (100 Å) | | | (98:2) (400 Å) | | |
| Comparative | Compound HT- | Compound | Compound | Compound | Compound | Compound |
| Example 3 | 1: Compound HT- | HT-1 | EB-3 | RH:Compound | HB | ET:Liq (40:60) |
| | 2 | (1300 Å) | (660 Å) | RD | (50 Å) | (350 Å) |
| | (98:2) (100 Å) | | | (98:2) (400 Å) | | |
| Comparative | Compound HT- | Compound | Compound | Compound | Compound | Compound |
| Example 4 | 1: Compound HT- | HT-1 | EB-4 | RH:Compound | HB | ET:Liq (40:60) |
| | 2 | (1300 Å) | (660 Å) | RD | (50 Å) | (350 Å) |
| | (98:2) (100 Å) | | | (98:2) (400 Å) | | |
| Comparative | Compound HT- | Compound | Compound | Compound | Compound | Compound |
| Example 5 | 1:Compound HT- | HT-1 | EB-5 | RH:Compound | HB | ET:Liq (40:60) |
| | 2 | (1300 Å) | (660 Å) | RD | (50 Å) | (350 Å) |
| | (98:2) (100 Å) | | | (98:2) (400 Å) | | |
| Comparative | Compound HT- | Compound | Compound | Compound | Compound | Compound |
| Example 6 | 1:Compound HT- | HT-1 | EB-6 | RH:Compound | HB | ET:Liq (40:60) |
| | 2 | (1300 Å) | (600 Å) | RD | (50 Å) | (350 Å) |
| | (98:2) (100 Å) | | | (98:2) (400 Å) | | |
| | Compound HT- | Compound | Compound | Compound | Compound | Compound |
| Comparative | 1:Compound HT- | HT-1 | EB-7 | RH:Compound | HB | ET:Liq (40:60) |
| Example 7 | 2 | (1300 Å) | (660 Å) | RD | (50 Å) | (350 Å) |
| | (98:2) (100 Å) | | | (98:2) (400 Å) | | |

The materials used in the devices have the following structures:

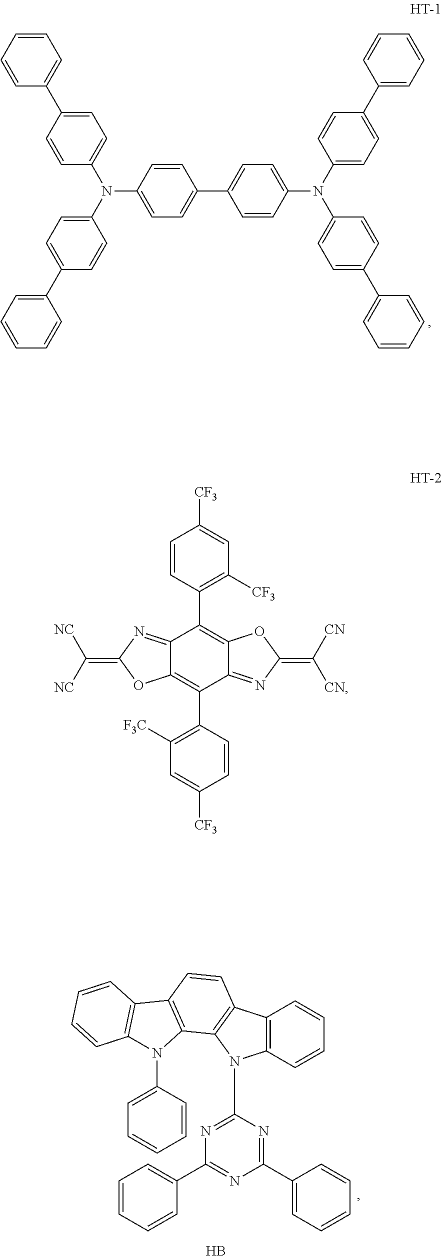

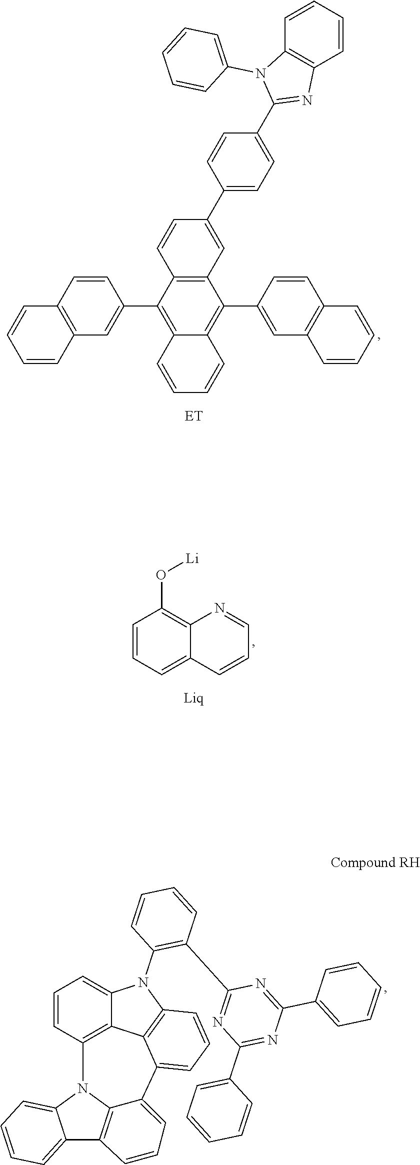

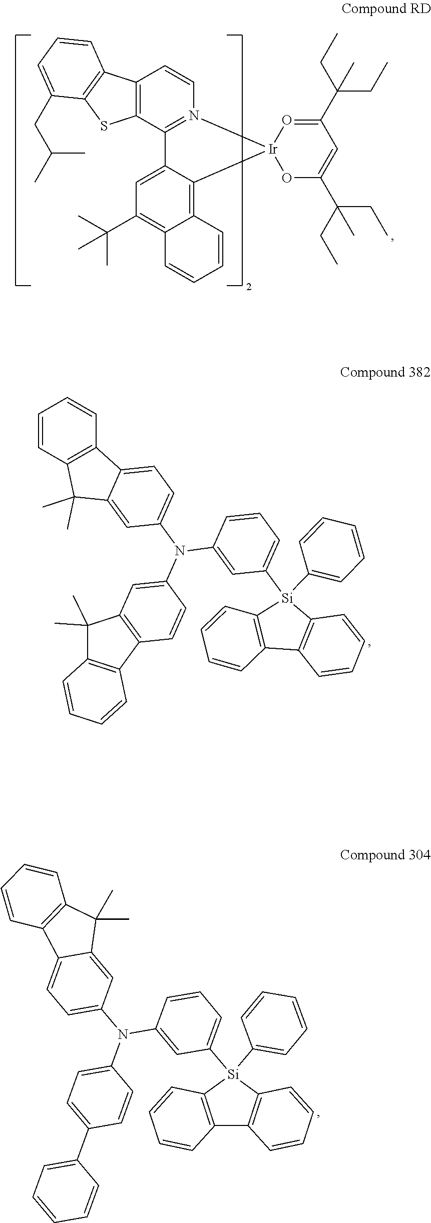

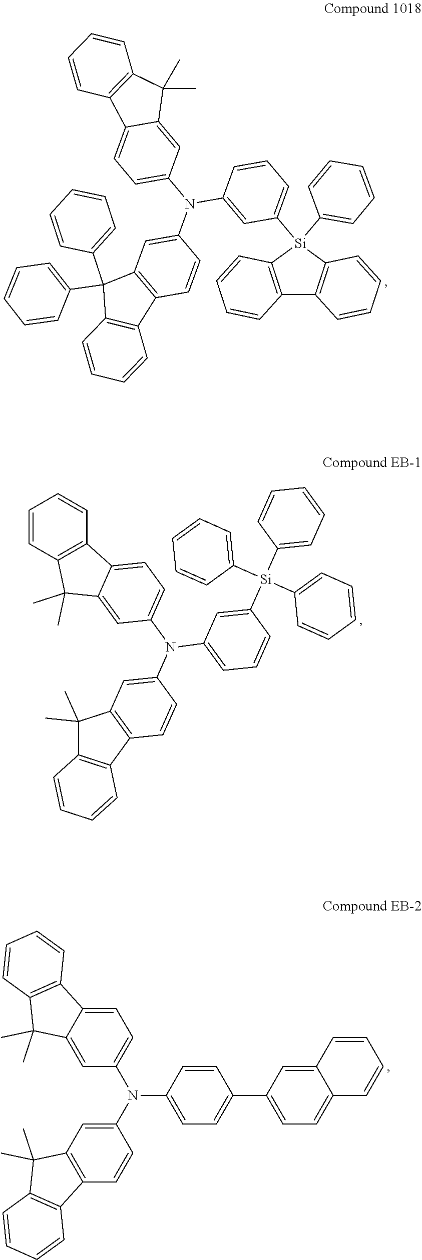 [SMILES: CC1(C)c2ccccc2-c2ccc(N(c3cccc([Si]4(c5ccccc5)c5ccccc5-c5ccccc54)c3)c3ccc4c(c3)C(c3ccccc3)(c3ccccc3)c3ccccc3-4)cc21 ; CC1(C)c2ccccc2-c2ccc(N(c3cccc([Si](c4ccccc4)(c4ccccc4)c4ccccc4)c3)c3ccc4c(c3)C(C)(C)c3ccccc3-4)cc21 ; CC1(C)c2ccccc2-c2ccc(N(c3ccc(-c4ccc5ccccc5c4)cc3)c3ccc4c(c3)C(C)(C)c3ccccc3-4)cc21]

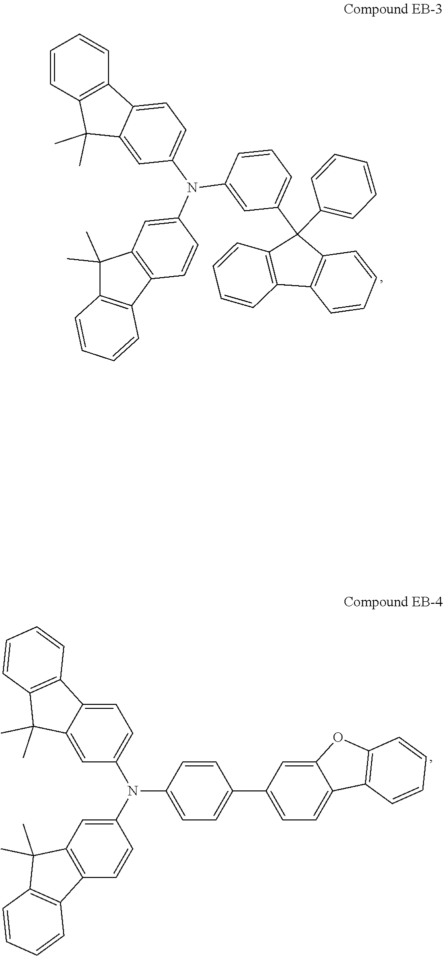 [SMILES: CC1(C)c2ccccc2-c2ccc(N(c3cccc(C4(c5ccccc5)c5ccccc5-c5ccccc54)c3)c3ccc4c(c3)C(C)(C)c3ccccc3-4)cc21 ; CC1(C)c2ccccc2-c2ccc(N(c3ccc(-c4ccc5c(c4)oc4ccccc45)cc3)c3ccc4c(c3)C(C)(C)c3ccccc3-4)cc21]

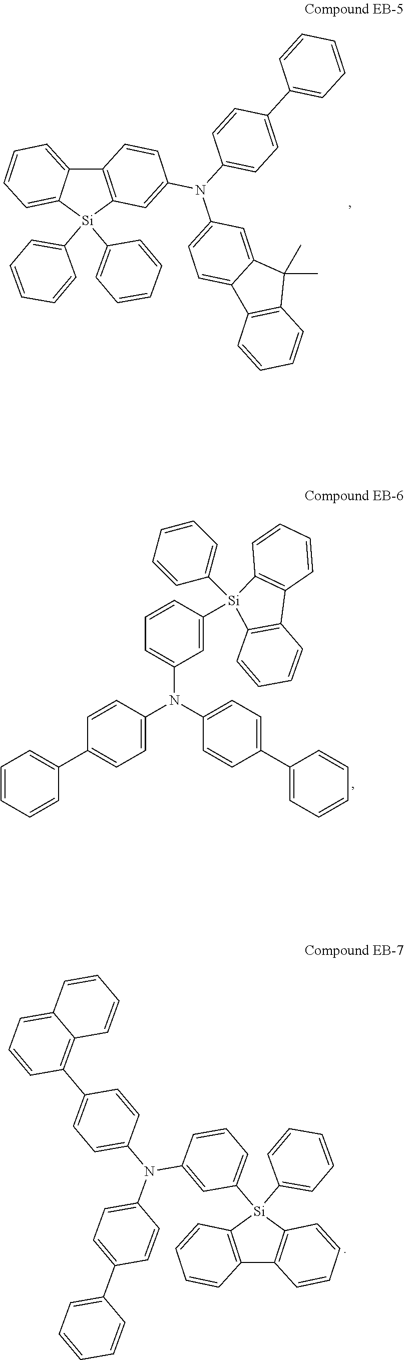 [SMILES: CC1(C)c2ccccc2-c2ccc(N(c3ccc(-c4ccccc4)cc3)c3ccc4c(c3)[Si](c3ccccc3)(c3ccccc3)c3ccccc3-4)cc21 ; c1ccc(-c2ccc(N(c3ccc(-c4ccccc4)cc3)c3cccc([Si]4(c5ccccc5)c5ccccc5-c5ccccc54)c3)cc2)cc1 ; c1ccc(-c2ccc(N(c3ccc(-c4cccc5ccccc45)cc3)c3cccc([Si]4(c5ccccc5)c5ccccc5-c5ccccc54)c3)cc2)cc1]

The current efficiency (CE), power efficiency (PE), external quantum efficiency (EQE) and voltage (V) of Examples 1 to 3 and Comparative Examples 1 to 7 were measured at a current density of 10 mA/cm². These data was recorded and shown in Table 3.

TABLE 3
Device data in Examples 1 to 3 and Comparative Examples 1 to 7

| | | Current | Power | External |
|---|---|---|---|---|
| | Voltage | Efficiency | Efficiency | Quantum |
| Device No. | (V) | (cd/A) | (lm/W) | Efficiency (%) |
| Example 1 | 3.62 | 82.0 | 71.1 | 59.6 |
| Example 2 | 3.91 | 83.5 | 67.1 | 59.2 |
| Example 3 | 3.82 | 82.5 | 67.8 | 59.3 |
| Comparative | 3.61 | 81.5 | 70.9 | 59.9 |
| Example 1 | | | | |
| Comparative | 3.63 | 78.7 | 68.1 | 53.1 |
| Example 2 | | | | |
| Comparative | 3.67 | 82.4 | 70.5 | 59.3 |
| Example 3 | | | | |
| Comparative | 3.54 | 75.7 | 67.1 | 53.3 |
| Example 4 | | | | |
| Comparative | 3.52 | 77.2 | 68.9 | 55.7 |
| Example 5 | | | | |
| Comparative | 5.08 | 82.0 | 50.7 | 59.3 |
| Example 6 | | | | |
| Comparative | 5.13 | 83.5 | 51.1 | 58.6 |
| Example 7 | | | | |

### Discussion

As can be seen from the data in Table 3, compared with Comparative Example 1, the low voltage level that is the same as that in Comparative Example 1 is maintained in Example 1, and the current efficiency and the power efficiency are further improved based on already very high efficiency levels; compared with Comparative Example 2, the current efficiency is improved by 4.200, the power efficiency is improved by 4.400 and the external quantum efficiency is significantly improved by 12.2% while the low voltage level that is the same as that in Comparative Example 2 is maintained in Example 1; compared with Comparative Example 3, the power efficiency and the external quantum efficiency are slightly improved based on the high efficiency levels in Comparative Example 3 while the voltage in Example 1 is further reduced based on low voltage level in Comparative Example 3. In addition, the LT97 lifetimes in Example 1, Comparative Example 1, Comparative Example 2 and Comparative Example 3 measured at a current density of 80 mA/cm² are 195 h, 174 h, 170 h and 166 h, respectively. Compared with Comparative Example 1, Comparative Example 2, and Comparative Example 3, the lifetime in Example 1 is significantly improved by 12.1%, 14.7% and 17.5%, respectively. Compared with Comparative Example 4, the current efficiency, the power efficiency and the external quantum efficiency are improved by 8.3%, 6.0% and 11.8%, respectively, while the low voltage level that is substantially the same as that in Comparative Example 4 is maintained in Example 1. The above results indicate that the compound of the present disclosure comprises the silafluorenyl group has better device performance than the compound of the comparative example does not comprise the silafluorenyl group, can significantly improve the device efficiency and/or the lifetime while maintaining a low voltage level, and provides better overall performance in the device.

Compared with Comparative Example 5, the power efficiency in Example 2 is basically maintained to be consistent with that in Comparative Example 5. It is to be noted that although the voltage in Example 2 is slightly higher than that in Comparative Example 5, the voltage in Example 2 is still at a very low voltage level. More notably, the current efficiency in Example 2 is improved by 8.2%. In addition, the LT97 lifetimes in Example 2 and Comparative Example 5 measured at a current density of 80 mA/cm² are 199 h and 174 h, respectively, and the lifetime in Example 2 is significantly improved by 10.9%. It indicates that the compound of the present disclosure, since the arylamine is joined at the particular position on the silafluorene phenyl (the arylamine is joined to the silicon atom of the silafluorene via meta-positions of the phenyl), can significantly improve the current efficiency and lifetime of the device while maintaining a low voltage level and can provide better overall performance of the device.

Compared with Comparative Example 6 and Comparative Example 7, the current efficiency and the external quantum efficiency in Example 2 are basically maintained to be consistent, which are both at a relatively high level, the power efficiency is improved by 32.3% and 31.3%, respectively, and the voltage is significantly reduced by 1.17 V and 1.22 V, respectively, which is very rare. It indicates that when fluorenyl is introduced into the substituent Ar₁ or Ar₂ of the compound of the present disclosure, the transport balance of holes and electrons in the device can be effectively adjusted, and the device voltage is further significantly reduced while high efficiency is maintained.

As can be seen from the above, Compound 382 and Compound 304 of the present disclosure in Example 1 and Example 2 can provide relatively excellent device performance, the structure of the compound is further improved based on this to obtain Compound 1018 of the present disclosure used in Example 3, and Example 3 has the same low voltage level and relatively high device efficiency (EQE, PE and CE) as those in Example 1 and Example 2, again proving the excellence of the compound of the present disclosure.

### Device Example 4: Preparation of a Bottom-Emitting Organic Electroluminescent Device

Firstly, a glass substrate having a thickness of 0.7 mm and patterned with an indium tin oxide (ITO) anode with a thickness of 1200 Å was washed with deionized water and a detergent, and then the ITO surface was treated with oxygen plasma and UV ozone. Then, the substrate was dried in a glovebox to remove moisture, mounted on a support and transferred into a vacuum chamber. Organic layers specified below were sequentially deposited on the anode layer through vacuum thermal evaporation at a rate of 0.01-10 Å/s and at a vacuum degree of about 10⁻⁶ Torr. Compound HT-1 and Compound HT-2 were co-deposited for use as a hole injection layer (HIL, with a weight ratio of 98:2, 100 Å). Compound HT-1 was deposited for use as a hole transporting layer (HTL, 1300 Å). Compound 1018 of the present disclosure was deposited for use as an electron blocking layer (EBL, 700 Å). Compound RH and Compound RD2 were co-deposited for use as an emissive layer (EML, with a weight ratio of 98:2, 400 Å). Compound HB was deposited for use as a hole blocking layer (HBL, 50 Å). Compound ET and Liq were co-deposited for use as an electron transporting layer (ETL, 40:60, 350 Å). Liq was deposited for use as an electron injection layer (EIL) with a thickness of 10 Å. Finally, the metal aluminum was deposited for use as a cathode (1200 Å). The device was transferred back to the glovebox and encapsulated with a glass lid to complete the device.

### Device Example 5

The preparation method in Device Example 5 was the same as that in Device Example 4, except that in the electron blocking layer (EBL), Compound 1018 of the present disclosure was replaced with Compound H284 of the present disclosure.

### Device Example 6

The preparation method in Device Example 6 was the same as that in Device Example 4, except that in the electron blocking layer (EBL), Compound 1018 of the present disclosure was replaced with Compound 385 of the present disclosure.

### Device Example 7

The preparation method in Device Example 7 was the same as that in Device Example 4, except that in the electron blocking layer (EBL), Compound 1018 of the present disclosure was replaced with Compound H557 of the present disclosure.

### Device Example 8

The preparation method in Device Example 8 was the same as that in Device Example 4, except that in the electron blocking layer (EBL), Compound 1018 of the present disclosure was replaced with Compound 1924 of the present disclosure.

### Device Example 9

The preparation method in Device Example 9 was the same as that in Device Example 4, except that in the electron blocking layer (EBL), Compound 1018 of the present disclosure was replaced with Compound 1996 of the present disclosure.

### Device Example 10

The preparation method in Device Example 10 was the same as that in Device Example 4, except that in the electron blocking layer (EBL), Compound 1018 of the present disclosure was replaced with Compound 1999 of the present disclosure.

### Device Example 11

The preparation method in Device Example 11 was the same as that in Device Example 4, except that in the electron blocking layer (EBL), Compound 1018 of the present disclosure was replaced with Compound 304 of the present disclosure.

### Device Example 12

The preparation method in Device Example 12 was the same as that in Device Example 4, except that in the electron blocking layer (EBL), Compound 1018 of the present disclosure was replaced with Compound 1888 of the present disclosure.

### Device Example 13

The preparation method in Device Example 13 was the same as that in Device Example 4, except that in the electron blocking layer (EBL), Compound 1018 of the present disclosure was replaced with Compound 1963 of the present disclosure.

### Device Example 14

The preparation method in Device Example 14 was the same as that in Device Example 4, except that in the electron blocking layer (EBL), Compound 1018 of the present disclosure was replaced with Compound H605 of the present disclosure.

### Device Comparative Example 8

The preparation method in Device Comparative Example 8 was the same as that in Device Example 4, except that in the electron blocking layer (EBL), Compound 1018 of the present disclosure was replaced with Compound EB-B.

Detailed structures and thicknesses of layers of the devices are shown in Table 4. A layer using more than one material is obtained by doping different compounds at their weight ratio as recorded.

TABLE 4
Part of device structures in Examples 4 to 14 and Comparative Example 8

| Device No. | HIL | HTL | EBL | EML | HBL | ETL |
|---|---|---|---|---|---|---|
| Example 4 | Compound HT- | Compound | Compound | Compound | Compound | Compound |
| | 1:Compound HT- | HT-1 | 1018 | RH:Compound | HB | ET:Liq (40:60) |
| | 2 | (1300 Å) | (700 Å) | RD2 | (50 Å ) | (350 Å) |
| | (98:2) (100 Å) | | | (98:2) (400 Å) | | |
| Example 5 | Compound HT- | Compound | Compound | Compound | Compound | Compound |
| | 1:Compound HT- | HT-1 | H284 | RH:Compound | HB | ET:Liq (40:60) |
| | 2 | (1300 Å) | (700 Å) | RD2 | (50 Å) | (350 Å) |
| | (98:2) (100 Å) | | | (98:2) (400 Å) | | |
| Example 6 | Compound HT- | Compound | Compound | Compound | Compound | Compound |
| | 1:Compound HT- | HT-1 | 385 | RH:Compound | HB | ET:Liq (40:60) |
| | 2 | (1300 Å) | (700 Å) | RD2 | (50 Å) | (350 Å) |
| | (98:2) (100 Å) | | | (98:2) (400 Å) | | |
| Example 7 | Compound HT- | Compound | Compound | Compound | Compound | Compound |
| | 1:Compound HT- | HT-1 | H557 | RH:Compound | HB | ET:Liq (40:60) |
| | 2 | (1300 Å) | (700 Å) | RD2 | (50 Å) | (350 Å) |
| | (98:2) (100 Å ) | | | (98:2) (400 Å) | | |
| Example 8 | Compound HT- | Compound | Compound | Compound | Compound | Compound |
| | 1:Compound HT- | HT-1 | 1924 | RH:Compound | HB | ET:Liq (40:60) |
| | 2 | (1300 Å) | (700 Å) | RD2 | (50 Å ) | (350 Å) |
| | (98:2) (100 Å) | | | (98:2) (400 Å) | | |
| Example 9 | Compound HT- | Compound | Compound | Compound | Compound | Compound |
| | 1:Compound HT- | HT-1 | 1996 | RH:Compound | HB | ET:Liq (40:60) |
| | 2 | (1300 Å) | (700 Å) | RD2 | (50 Å ) | (350 Å) |
| | (98:2) (100 Å) | | | (98:2) (400 Å) | | |
| Example 10 | Compound HT- | Compound | Compound | Compound | Compound | Compound |
| | 1:Compound HT- | HT-1 | 1999 | RH:Compound | HB | ET:Liq (40:60) |
| | 2 | (1300 Å) | (700 Å) | RD2 | (50 Å) | (350 Å) |
| | (98:2) (100 Å) | | | (98:2) (400 Å) | | |
| Example 11 | Compound HT- | Compound | Compound | Compound | Compound | Compound |
| | 1:Compound HT- | HT-1 | 304 | RH:Compound | HB | ET:Liq (40:60) |
| | 2 | (1300 Å) | (700 Å) | RD2 | (50 Å ) | (350 Å) |
| | (98:2) (100 Å) | | | (98:2) (400 Å) | | |
| Example 12 | Compound HT- | Compound | Compound | Compound | Compound | Compound |
| | 1:Compound HT- | HT-1 | 1888 | RH:Compound | HB | ET:Liq (40:60) |
| | 2 | (1300 Å) | (700 Å) | RD2 | (50 Å) | (350 Å) |
| | (98:2) (100 Å) | | | (98:2) (400 Å) | | |
| Example 13 | Compound HT- | Compound | Compound | Compound | Compound | Compound |
| | 1:Compound HT- | HT-1 | 1963 | RH:Compound | HB | ET:Liq (40:60) |
| | 2 | (1300 Å) | (700 Å) | RD2 | (50 Å) | (350 Å) |
| | (98:2) (100 Å ) | | | (98:2) (400 Å) | | |
| Example 14 | Compound HT- | Compound | Compound | Compound | Compound | Compound |
| | 1:Compound HT- | HT-1 | H605 | RH:Compound | HB | ET:Liq (40:60) |
| | 2 | (1300 Å) | (700 Å) | RD2 | (50 Å ) | (350 Å) |
| | (98:2) (100 Å ) | | | (98:2) (400 Å) | | |
| Comparative | Compound HT- | Compound | Compound | Compound | Compound | Compound |
| Example 8 | 1:Compound HT- | HT-1 | EB-B | RH:Compound | HB | ET:Liq (40:60) |
| | 2 | (1300 Å) | (700 Å) | RD2 | (50 Å ) | (350 Å) |
| | (98:2) (100 Å) | | | (98:2) (400 Å) | | |

The new materials used in the devices have the following structures:

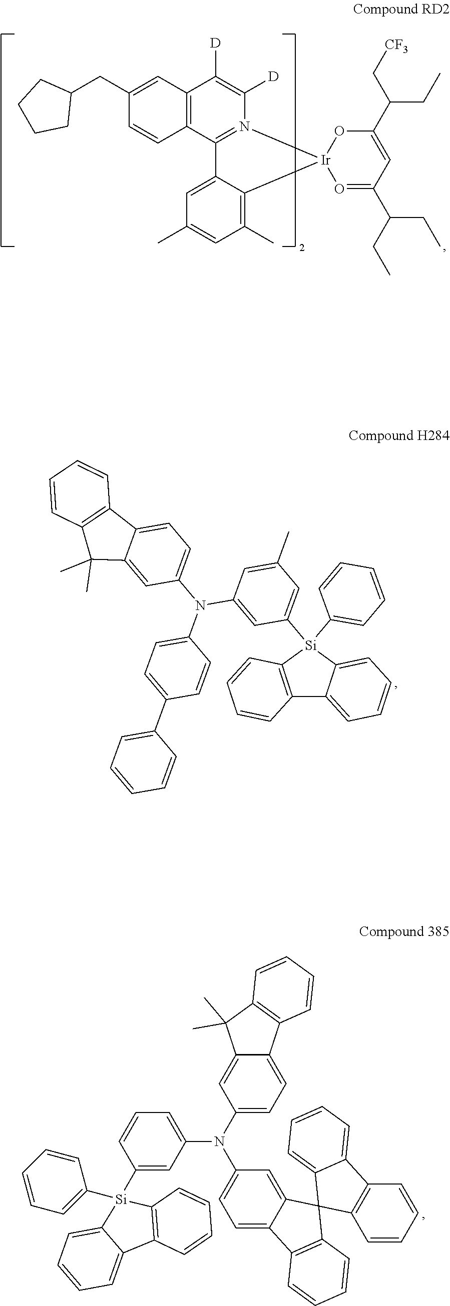

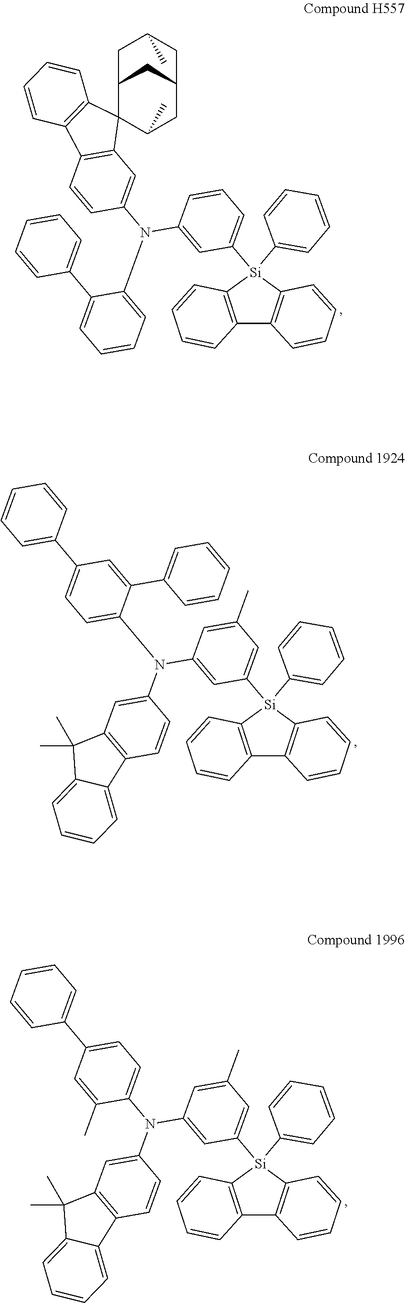 [SMILES: C[C@@H]1C[C@H]2C[C@@H](C1)C1(c3ccccc3-c3ccc(N(c4cccc([Si]5(c6ccccc6)c6ccccc6-c6ccccc65)c4)c4ccccc4-c4ccccc4)cc31)[C@@H](C)C2 ; Cc1cc(N(c2ccc3c(c2)C(C)(C)c2ccccc2-3)c2ccc(-c3ccccc3)cc2-c2ccccc2)cc([Si]2(c3ccccc3)c3ccccc3-c3ccccc32)c1 ; Cc1cc(N(c2ccc3c(c2)C(C)(C)c2ccccc2-3)c2ccc(-c3ccccc3)cc2C)cc([Si]2(c3ccccc3)c3ccccc3-c3ccccc32)c1]

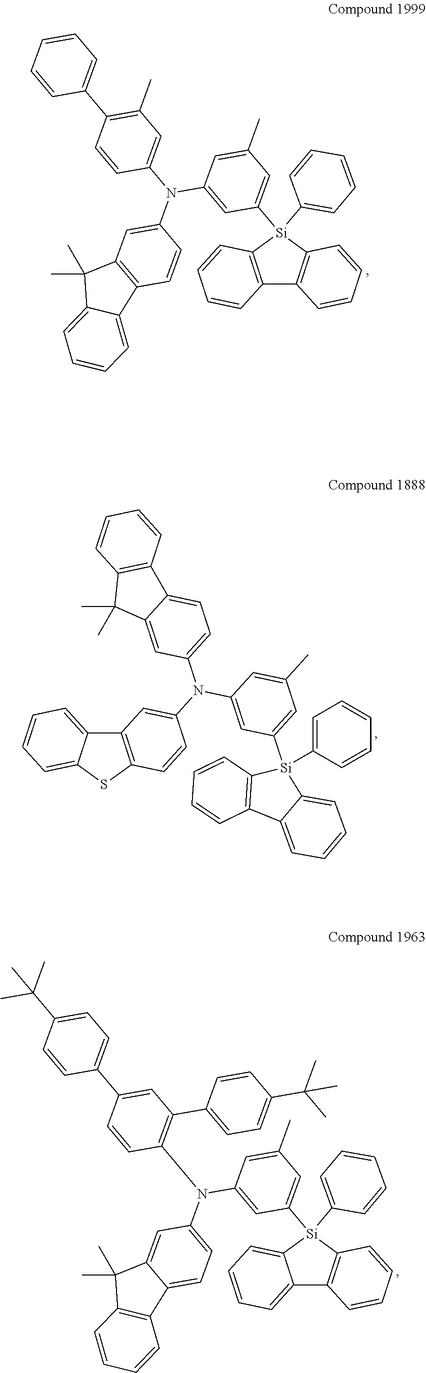 [SMILES: Cc1cc(N(c2ccc(-c3ccccc3)c(C)c2)c2ccc3c(c2)C(C)(C)c2ccccc2-3)cc([Si]2(c3ccccc3)c3ccccc3-c3ccccc32)c1 ; Cc1cc(N(c2ccc3c(c2)C(C)(C)c2ccccc2-3)c2ccc3sc4ccccc4c3c2)cc([Si]2(c3ccccc3)c3ccccc3-c3ccccc32)c1 ; Cc1cc(N(c2ccc3c(c2)C(C)(C)c2ccccc2-3)c2ccc(-c3ccc(C(C)(C)C)cc3)cc2-c2ccc(C(C)(C)C)cc2)cc([Si]2(c3ccccc3)c3ccccc3-c3ccccc32)c1]

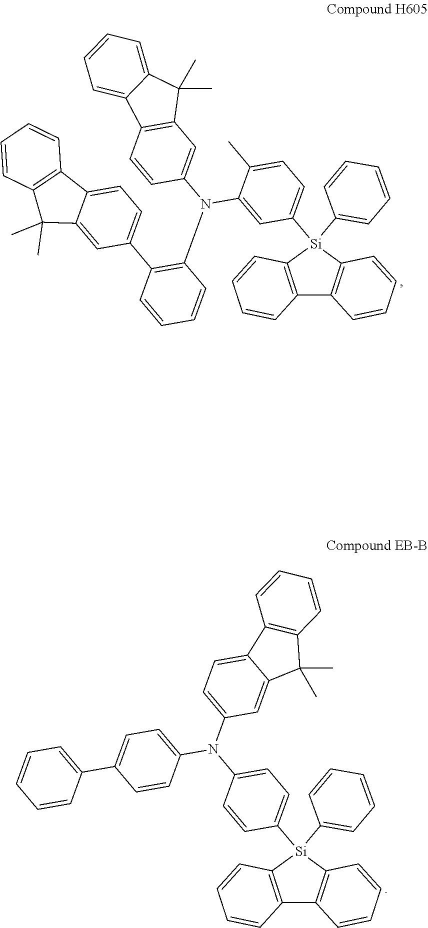 [SMILES: Cc1ccc([Si]2(c3ccccc3)c3ccccc3-c3ccccc32)cc1N(c1ccc2c(c1)C(C)(C)c1ccccc1-2)c1ccccc1-c1ccc2c(c1)C(C)(C)c1ccccc1-2 ; CC1(C)c2ccccc2-c2ccc(N(c3ccc(-c4ccccc4)cc3)c3ccc([Si]4(c5ccccc5)c5ccccc5-c5ccccc54)cc3)cc21]

The current efficiency (CE), power efficiency (PE), external quantum efficiency (EQE) and voltage (V) of Examples 4 to 14 and Comparative Example 8 were measured at a current density of 10 mA/cm². These data was recorded and shown in Table 5.

TABLE 5
Device data in Examples 4 to 14 and Comparative Example 8

| | | Current | Power | External |
|---|---|---|---|---|
| | Voltage | Efficiency | Efficiency | Quantum |
| Device No. | (V) | (cd/A) | (lm/W) | Efficiency (%) |
| Example 4 | 3.81 | 27.6 | 22.8 | 29.1 |
| Example 5 | 3.79 | 28.0 | 23.2 | 29.5 |
| Example 6 | 3.74 | 27.7 | 23.2 | 28.9 |
| Example 7 | 3.90 | 29.3 | 23.6 | 30.3 |
| Example 8 | 3.85 | 28.3 | 23.1 | 29.3 |
| Example 9 | 3.95 | 28.5 | 22.7 | 29.7 |
| Example 10 | 3.77 | 28.5 | 23.7 | 29.5 |
| Example 11 | 3.83 | 27.9 | 22.9 | 29.3 |
| Example 12 | 3.71 | 28.0 | 23.8 | 29.4 |
| Example 13 | 3.77 | 29.0 | 24.1 | 29.0 |
| Example 14 | 4.12 | 29.0 | 22.1 | 29.4 |
| Comparative | 4.01 | 28.0 | 22.0 | 29.2 |
| Example 8 | | | | |

### Discussion

In Example 3 and Example 4, Compound 1018 is also used as an electron blocking material, and a significant difference is in device efficiency (CE, PE and EQE) data. Although the RD materials used in the two examples are different, the difference in device efficiency is mainly due to the difference in device structure in the two examples. Example 3 is a top-emitting device, Example 4 is a bottom-emitting device, and the top-emitting device is significantly higher in device efficiency than the bottom-emitting device mainly due to the microcavity effect and the additional light extraction effect. As can be seen from the data in Table 5, Example 4, as a bottom-emitting device, has very excellent device performance and can have extremely high device efficiency (CE, PE and EQE) while maintaining a very low voltage level.

The performance of the bottom-emitting devices using Compound H284, Compound 385, Compound H557, Compound 1924, Compound 1996, Compound 1999, Compound 304, Compound 1888, Compound 1963 and compound H605 of the present disclosure was further tested. As can be seen from the data in Table 5, although an Ar₁/Ar₂ structure different from that of Compound 1018 is used in these compounds, Examples 5 to 14 using these compounds as an electron blocking material still achieve device performance similar to or more excellent than that in Example 4, which can maintain the same low voltage as that in Example 4 or further reduce the voltage, and can maintain the same high efficiency as that in Example 4 or further improve the device efficiency.

In addition, Compound 304 of the present disclosure in Example 11 and Compound EB-B in Comparative Example 8 are isomers with the same parent core structure and differ only in the substitution position of arylamine on silafluorene phenyl, but the difference in device performance is very apparent. Compared with Comparative Example 8, the voltage in Example 11 is reduced by 0.18 V, the current efficiency, the power efficiency and the external quantum efficiency are maintained at high levels that are substantially the same as those in Comparative Example 8, but importantly, the LT97 lifetimes in Example 11 and Comparative Example 8 measured at a current density of 80 mA/cm² are 130.0 h and 53.7 h, respectively, and the lifetime in Example 11 is significantly improved by 142%, which is unexpected. Again, the unique advantages of the compound having the structure of Formula 1 disclosed in the present disclosure are proved.

In summary, when used in the organic electroluminescent device, the compound having the particular structure represented by Formula 1 of the present disclosure can maintain the low voltage level or reduce the device voltage, improve the device efficiency and the lifetime, and provide better overall performance of the device, which has a very broad application prospect.

It should be understood that various embodiments described herein are merely examples and not intended to limit the scope of the present disclosure. Therefore, it is apparent to those skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A compound, which has a structure represented by Formula 1: 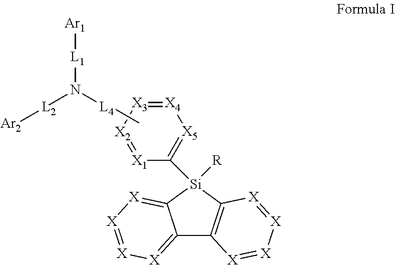
wherein in Formula 1, Ar₁ has a structure represented by Formula 2 or Formula 3: 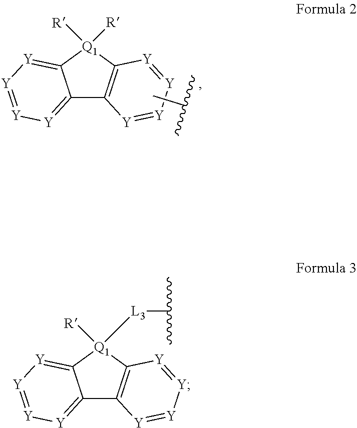
wherein Ar₂ is selected from substituted or unsubstituted aryl having 6 to 30 carbon atoms, substituted or unsubstituted heteroaryl having 3 to 30 carbon atoms or a combination thereof;
Q₁ is, at each occurrence identically or differently, selected from C or Si;
X is, at each occurrence identically or differently, selected from CR₁ or N;
Y is, at each occurrence identically or differently, selected from C, CR₂ or N;
X₄ is selected from C and joined to L₄, and X₁ to X₃ and X₅ are, at each occurrence identically or differently, selected from CRₓ;
L₁, L₂, L₃ and L₄ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
R, R′, R₁, R₂ and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R, R′, R₁, R₂ and Rₓ can be optionally joined to form a ring.

2. The compound according to claim 1, wherein L₁, L₂, L₃ and L₄ are, at each occurrence identically or differently, selected from a single bond, substituted or unsubstituted arylene having 6 to 20 carbon atoms, substituted or unsubstituted heteroarylene having 3 to 20 carbon atoms or a combination thereof;
preferably, L₁, L₂ and L₃ are, at each occurrence identically or differently, selected from a single bond, substituted or unsubstituted phenylene, substituted or unsubstituted biphenylylene, substituted or unsubstituted terphenylene, substituted or unsubstituted naphthylene, substituted or unsubstituted fluorenylidene, substituted or unsubstituted silafluorenylidene, substituted or unsubstituted carbazolylene, substituted or unsubstituted dibenzofuranylene, substituted or unsubstituted dibenzothienylene, substituted or unsubstituted dibenzoselenophenylene, substituted or unsubstituted phenanthrylene, substituted or unsubstituted triphenylenylene, substituted or unsubstituted pyridylene, substituted or unsubstituted spirobifluorenylene, substituted or unsubstituted anthrylene, substituted or unsubstituted pyrenylene or a combination thereof; L₄ is, at each occurrence identically or differently, selected from a single bond, substituted or unsubstituted phenylene or substituted or unsubstituted biphenylylene; and
more preferably, L₃ is, at each occurrence identically or differently, selected from substituted or unsubstituted phenylene or substituted or unsubstituted biphenylylene.

3. The compound according to claim 1, wherein the compound has a structure represented by any one of Formula 4-1 to Formula 4-4: 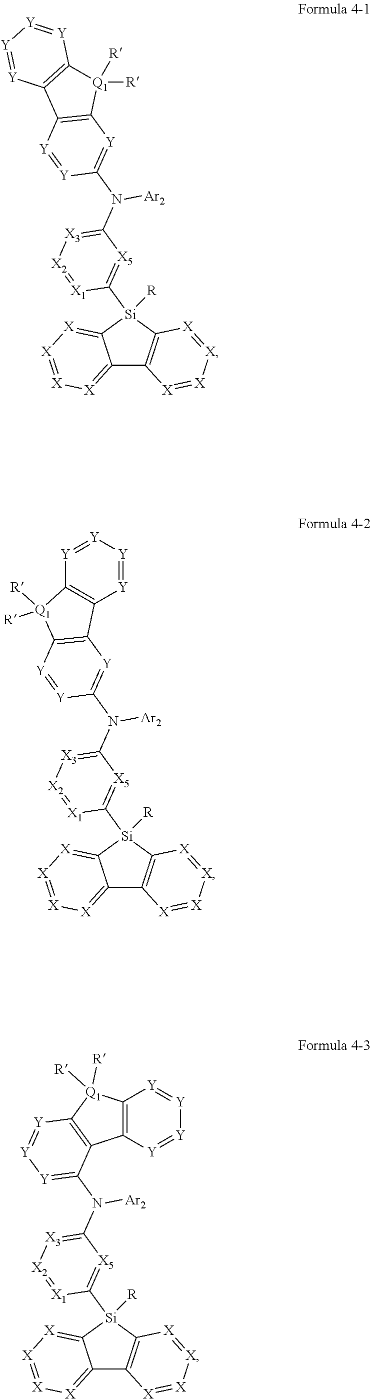 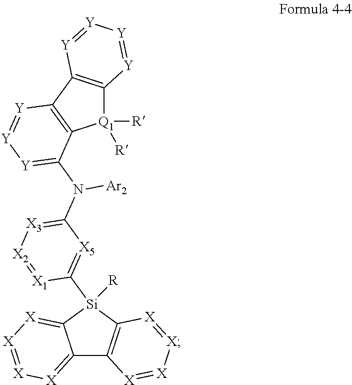
wherein in Formula 4-1 to Formula 4-4, X is, at each occurrence identically or differently, selected from CR₁;
Y is, at each occurrence identically or differently, selected from CR₂;
X₁ to X₃ and X₅ are, at each occurrence identically or differently, selected from CRₓ;
Q₁ is, at each occurrence identically or differently, selected from C or Si;
Ar₂ is selected from substituted or unsubstituted aryl having 6 to 30 carbon atoms, substituted or unsubstituted heteroaryl having 3 to 30 carbon atoms or a combination thereof;
R is, at each occurrence identically or differently, selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms or a combination thereof;
R′, R₁, R₂ and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R′, R₁, R₂ and Rₓ can be optionally joined to form a ring; and
preferably, the compound has a structure represented by Formula 4-1 or Formula 4-3.

4. The compound according to claim 1, wherein R is, at each occurrence identically or differently, selected from substituted or unsubstituted alkyl having 1 to 20 carbon atoms, substituted or unsubstituted aryl having 6 to 30 carbon atoms, substituted or unsubstituted heteroaryl having 3 to 30 carbon atoms or a combination thereof;
preferably, R is, at each occurrence identically or differently, selected from substituted or unsubstituted aryl having 6 to 30 carbon atoms or substituted or unsubstituted heteroaryl having 3 to 30 carbon atoms; and
more preferably, R is, at each occurrence identically or differently, selected from substituted or unsubstituted phenyl, substituted or unsubstituted biphenyl, substituted or unsubstituted naphthyl, substituted or unsubstituted fluorenyl, substituted or unsubstituted dibenzofuran or substituted or unsubstituted dibenzothiophene.

5. The compound according to claim 3, wherein R′, R₁, R₂ and Rₓ are, at each occurrence identically or differently, selected from hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms or a combination thereof; adjacent substituents R′, R₁, R₂ and Rₓ can be optionally joined to form a ring; and
preferably, R′, R₁, R₂ and Rₓ are, at each occurrence identically or differently, selected from hydrogen, deuterium, substituted or unsubstituted alkyl having 1 to 20 carbon atoms, substituted or unsubstituted aryl having 6 to 30 carbon atoms or a combination thereof.

6. The compound according to claim 1, wherein Q₁ is C.

7. The compound according to claim 1, wherein Ar₂ is selected from substituted or unsubstituted aryl having 6 to 20 carbon atoms, substituted or unsubstituted heteroaryl having 3 to 20 carbon atoms or a combination thereof;
preferably, Ar₂ is, at each occurrence identically or differently, selected from substituted or unsubstituted phenyl, substituted or unsubstituted biphenyl, substituted or unsubstituted terphenyl, substituted or unsubstituted naphthyl, substituted or unsubstituted fluorenyl, substituted or unsubstituted spirofluorenyl, substituted or unsubstituted silafluorenyl, substituted or unsubstituted dibenzofuranyl, substituted or unsubstituted dibenzothienyl, substituted or unsubstituted dibenzoselenophenyl, substituted or unsubstituted phenanthryl, substituted or unsubstituted triphenylenyl, substituted or unsubstituted pyridyl, substituted or unsubstituted carbazolyl, substituted or unsubstituted anthryl, substituted or unsubstituted pyrenyl or a combination thereof; and
more preferably, Ar₂ is, at each occurrence identically or differently, selected from substituted or unsubstituted phenyl, substituted or unsubstituted biphenyl, substituted or unsubstituted fluorenyl, substituted or unsubstituted spirofluorenyl, substituted or unsubstituted dibenzofuranyl or substituted or unsubstituted dibenzothienyl.

8. The compound according to claim 1, wherein Ar₂ is, at each occurrence identically or differently, selected from the group consisting of G1 to G102: 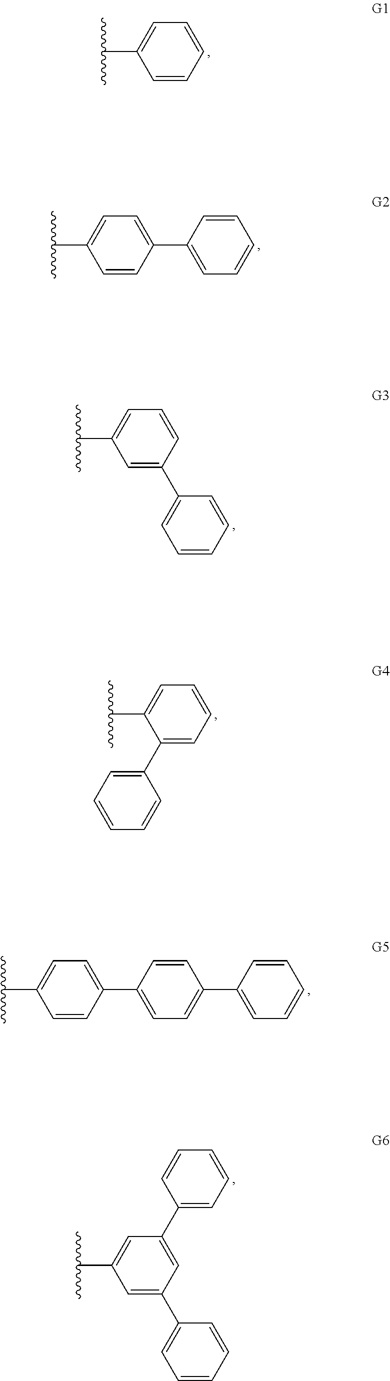 [SMILES: *c1ccccc1 ; *c1ccc(-c2ccccc2)cc1 ; *c1cccc(-c2ccccc2)c1 ; *c1ccccc1-c1ccccc1 ; *c1ccc(-c2ccc(-c3ccccc3)cc2)cc1 ; *c1cc(-c2ccccc2)cc(-c2ccccc2)c1] 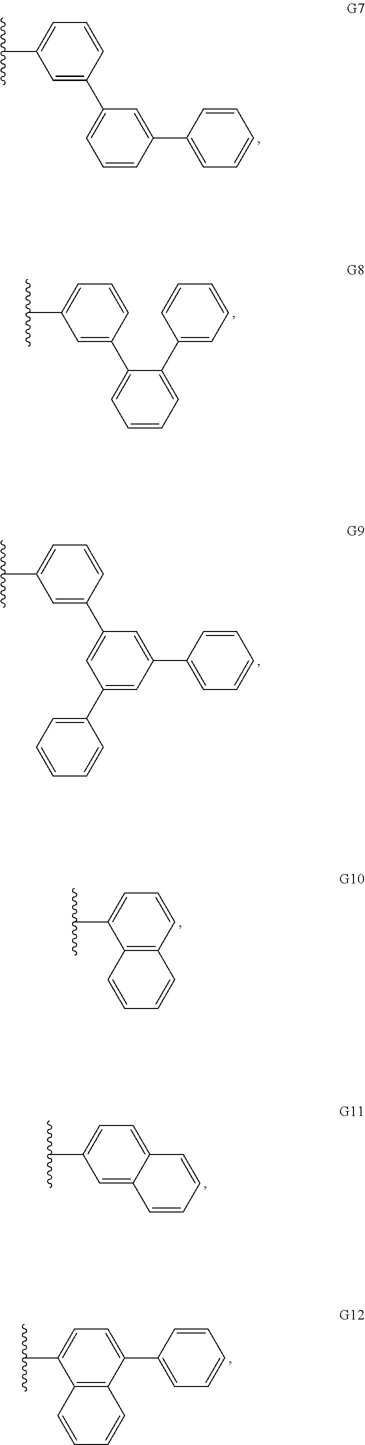 [SMILES: *c1cccc(-c2cccc(-c3ccccc3)c2)c1 ; *c1cccc(-c2ccccc2-c2ccccc2)c1 ; *c1cccc(-c2cc(-c3ccccc3)cc(-c3ccccc3)c2)c1 ; *c1cccc2ccccc12 ; *c1ccc2ccccc2c1 ; *c1ccc(-c2ccccc2)c2ccccc12] 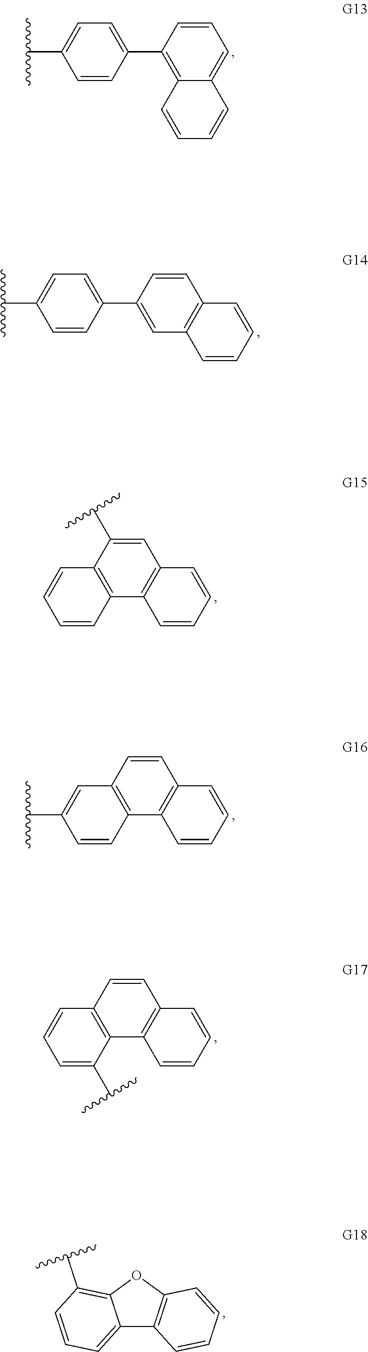 [SMILES: *c1ccc(-c2cccc3ccccc23)cc1 ; *c1ccc(-c2ccc3ccccc3c2)cc1 ; *c1cc2ccccc2c2ccccc12 ; *c1ccc2c(ccc3ccccc32)c1 ; *c1cccc2ccc3ccccc3c12 ; *c1cccc2c1oc1ccccc12] 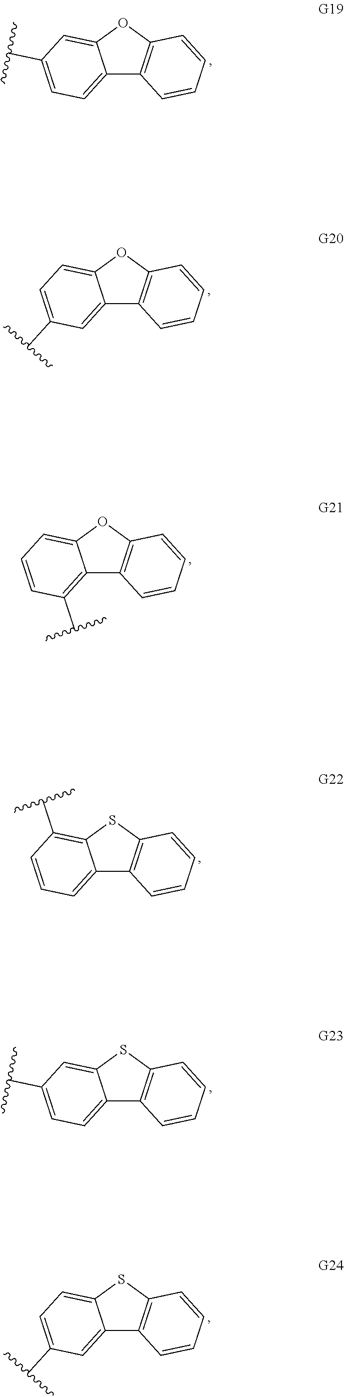 [SMILES: *c1ccc2c(c1)oc1ccccc12 ; *c1ccc2oc3ccccc3c2c1 ; *c1cccc2oc3ccccc3c12 ; *c1cccc2c1sc1ccccc12 ; *c1ccc2c(c1)sc1ccccc12 ; *c1ccc2sc3ccccc3c2c1] 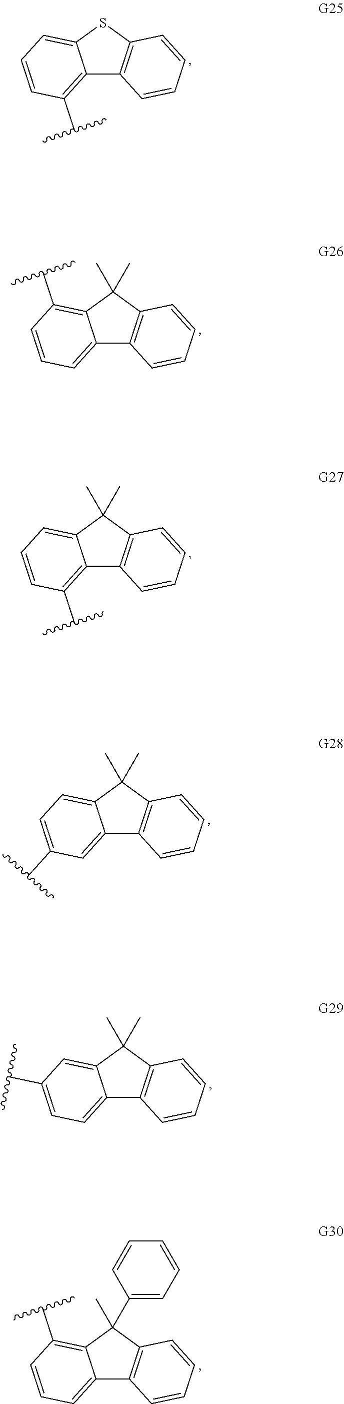 [SMILES: *c1cccc2sc3ccccc3c12 ; *c1cccc2c1C(C)(C)c1ccccc1-2 ; *c1cccc2c1-c1ccccc1C2(C)C ; *c1ccc2c(c1)-c1ccccc1C2(C)C ; *c1ccc2c(c1)C(C)(C)c1ccccc1-2 ; *c1cccc2c1C(C)(c1ccccc1)c1ccccc1-2] 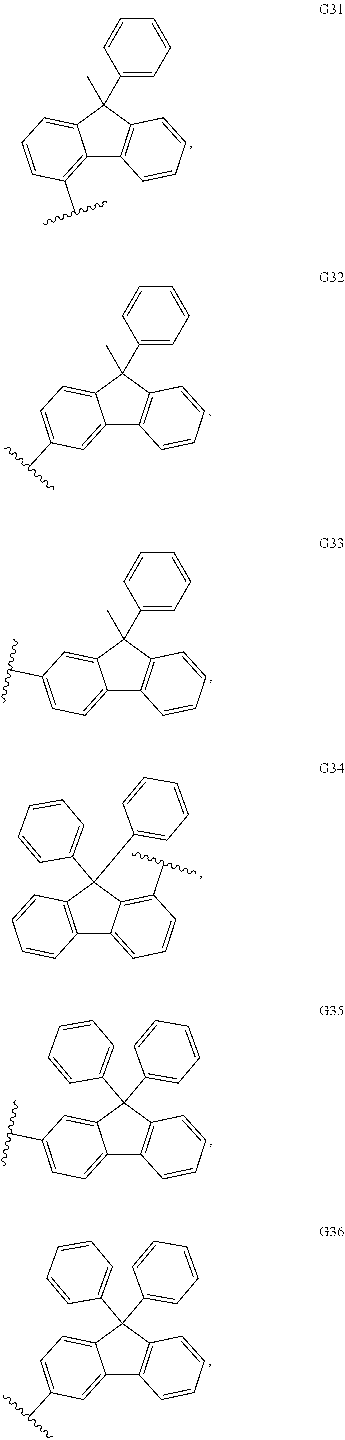 [SMILES: *c1cccc2c1-c1ccccc1C2(C)c1ccccc1 ; *c1ccc2c(c1)-c1ccccc1C2(C)c1ccccc1 ; *c1ccc2c(c1)C(C)(c1ccccc1)c1ccccc1-2 ; *c1cccc2c1C(c1ccccc1)(c1ccccc1)c1ccccc1-2 ; *c1ccc2c(c1)C(c1ccccc1)(c1ccccc1)c1ccccc1-2 ; *c1ccc2c(c1)-c1ccccc1C2(c1ccccc1)c1ccccc1] 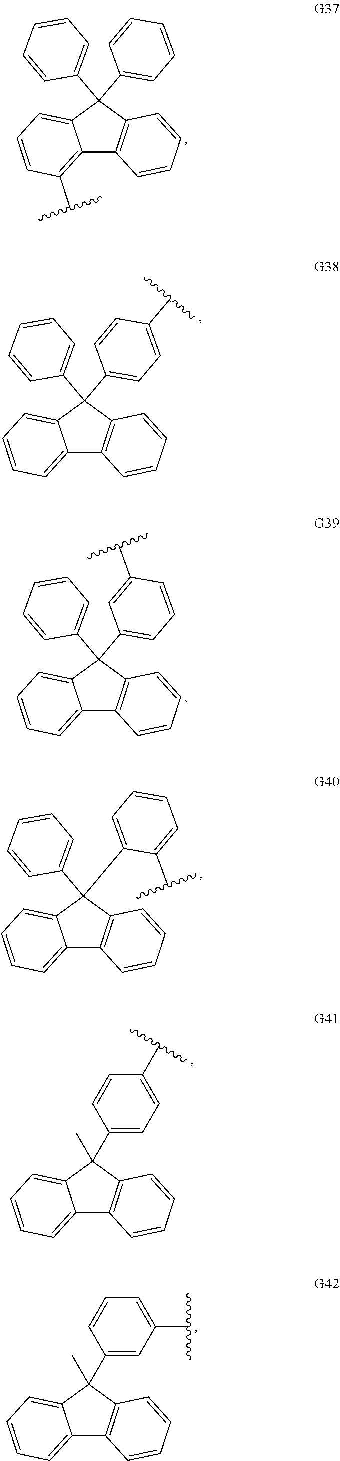 [SMILES: *c1cccc2c1-c1ccccc1C2(c1ccccc1)c1ccccc1 ; *c1ccc(C2(c3ccccc3)c3ccccc3-c3ccccc32)cc1 ; *c1cccc(C2(c3ccccc3)c3ccccc3-c3ccccc32)c1 ; *c1ccccc1C1(c2ccccc2)c2ccccc2-c2ccccc21 ; *c1ccc(C2(C)c3ccccc3-c3ccccc32)cc1 ; *c1cccc(C2(C)c3ccccc3-c3ccccc32)c1] 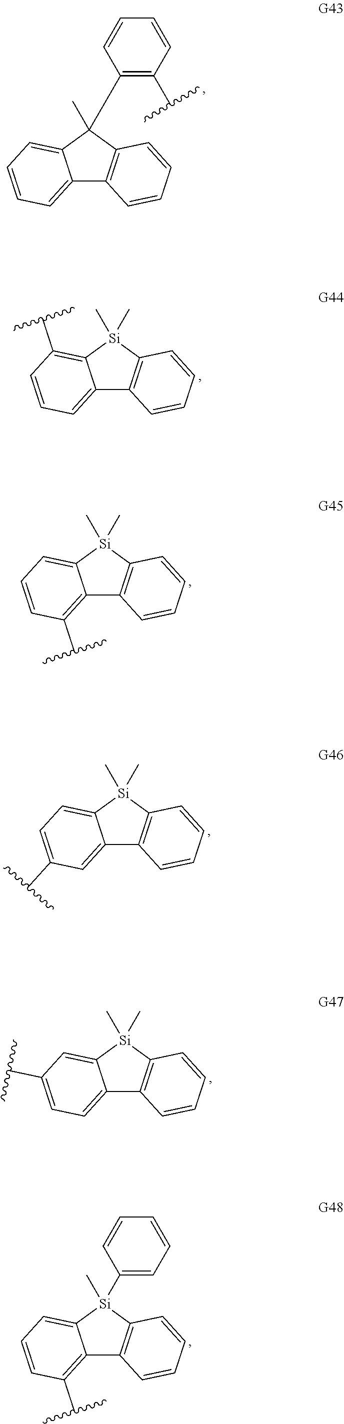 [SMILES: *c1ccccc1C1(C)c2ccccc2-c2ccccc21 ; *c1cccc2c1[Si](C)(C)c1ccccc1-2 ; *c1cccc2c1-c1ccccc1[Si]2(C)C ; *c1ccc2c(c1)-c1ccccc1[Si]2(C)C ; *c1ccc2c(c1)[Si](C)(C)c1ccccc1-2 ; *c1cccc2c1-c1ccccc1[Si]2(C)c1ccccc1] 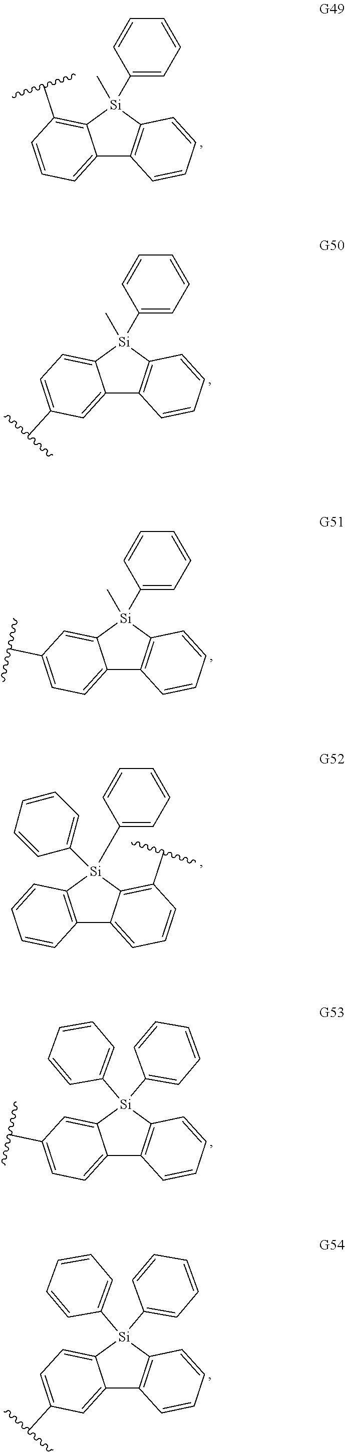 [SMILES: *c1cccc2c1[Si](C)(c1ccccc1)c1ccccc1-2 ; *c1ccc2c(c1)-c1ccccc1[Si]2(C)c1ccccc1 ; *c1ccc2c(c1)[Si](C)(c1ccccc1)c1ccccc1-2 ; *c1cccc2c1[Si](c1ccccc1)(c1ccccc1)c1ccccc1-2 ; *c1ccc2c(c1)[Si](c1ccccc1)(c1ccccc1)c1ccccc1-2 ; *c1ccc2c(c1)-c1ccccc1[Si]2(c1ccccc1)c1ccccc1] 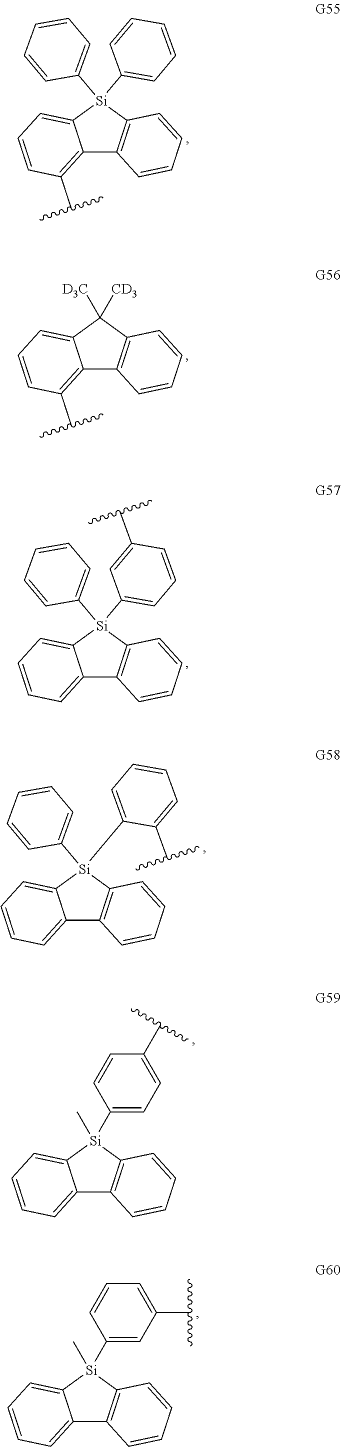 [SMILES: *c1cccc2c1-c1ccccc1[Si]2(c1ccccc1)c1ccccc1 ; *c1cccc2c1-c1ccccc1C2(C([2H])([2H])[2H])C([2H])([2H])[2H] ; *c1cccc([Si]2(c3ccccc3)c3ccccc3-c3ccccc32)c1 ; *c1ccccc1[Si]1(c2ccccc2)c2ccccc2-c2ccccc21 ; *c1ccc([Si]2(C)c3ccccc3-c3ccccc32)cc1 ; *c1cccc([Si]2(C)c3ccccc3-c3ccccc32)c1] 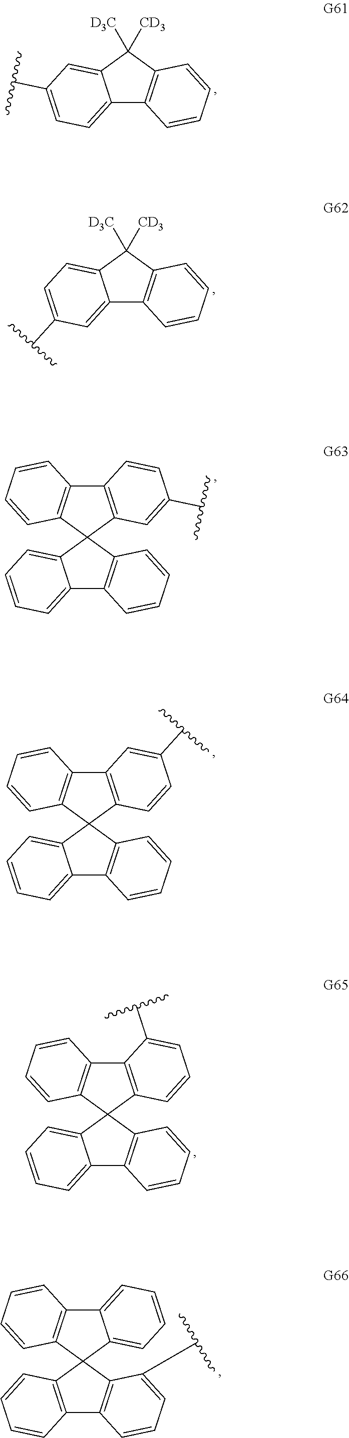 [SMILES: *c1ccc2c(c1)C(C([2H])([2H])[2H])(C([2H])([2H])[2H])c1ccccc1-2 ; *c1ccc2c(c1)-c1ccccc1C2(C([2H])([2H])[2H])C([2H])([2H])[2H] ; *c1ccc2c(c1)C1(c3ccccc3-c3ccccc31)c1ccccc1-2 ; *c1ccc2c(c1)-c1ccccc1C21c2ccccc2-c2ccccc21 ; *c1cccc2c1-c1ccccc1C21c2ccccc2-c2ccccc21 ; *c1cccc2c1C1(c3ccccc3-c3ccccc31)c1ccccc1-2] 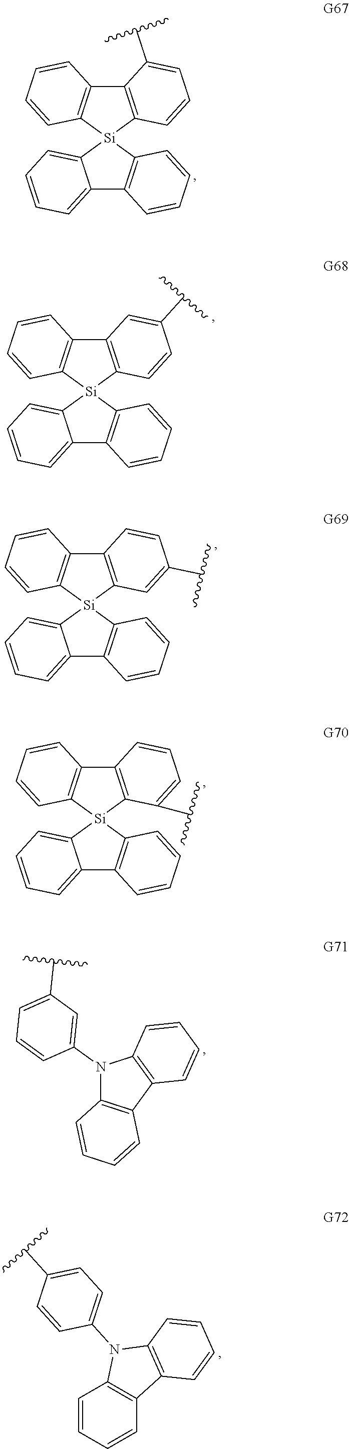 [SMILES: *c1cccc2c1-c1ccccc1[Si]21c2ccccc2-c2ccccc21 ; *c1ccc2c(c1)-c1ccccc1[Si]21c2ccccc2-c2ccccc21 ; *c1ccc2c(c1)[Si]1(c3ccccc3-c3ccccc31)c1ccccc1-2 ; *c1cccc2c1[Si]1(c3ccccc3-c3ccccc31)c1ccccc1-2 ; *c1cccc(-n2c3ccccc3c3ccccc32)c1 ; *c1ccc(-n2c3ccccc3c3ccccc32)cc1] 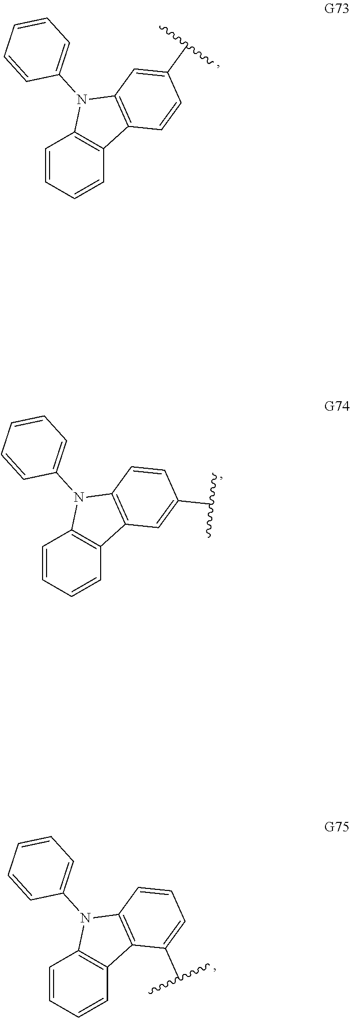 [SMILES: *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1] 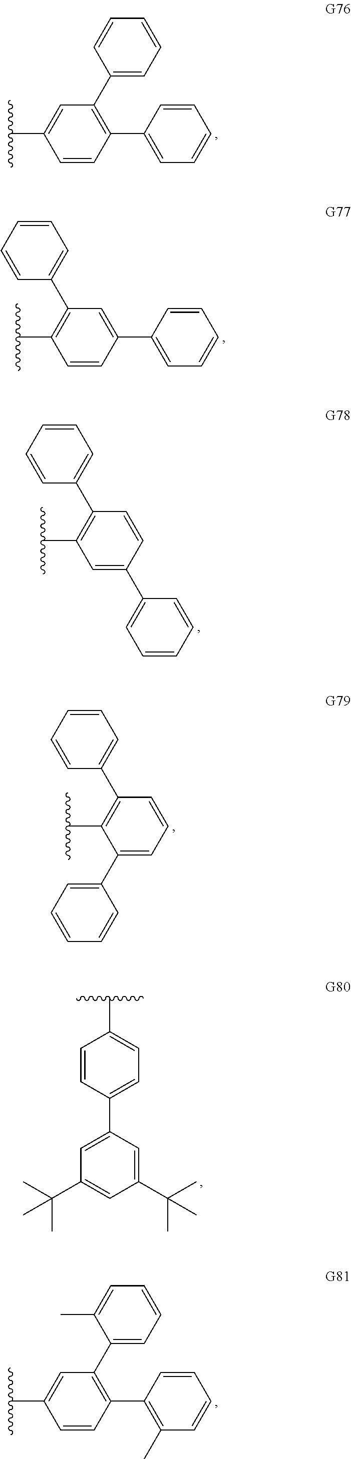 [SMILES: *c1ccc(-c2ccccc2)c(-c2ccccc2)c1 ; *c1ccc(-c2ccccc2)cc1-c1ccccc1 ; *c1cc(-c2ccccc2)ccc1-c1ccccc1 ; *c1c(-c2ccccc2)cccc1-c1ccccc1 ; *c1ccc(-c2cc(C(C)(C)C)cc(C(C)(C)C)c2)cc1 ; *c1ccc(-c2ccccc2C)c(-c2ccccc2C)c1] 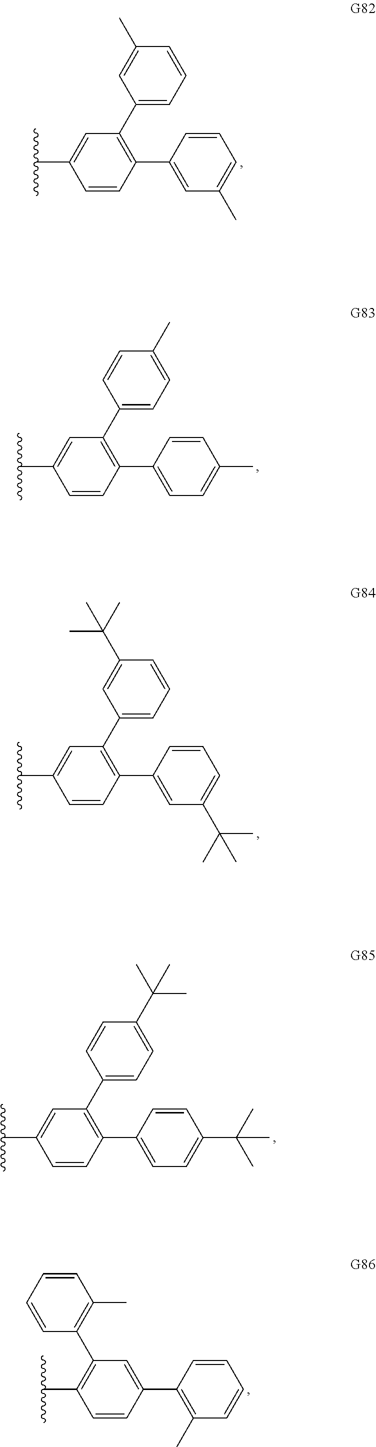 [SMILES: *c1ccc(-c2cccc(C)c2)c(-c2cccc(C)c2)c1 ; *c1ccc(-c2ccc(C)cc2)c(-c2ccc(C)cc2)c1 ; *c1ccc(-c2cccc(C(C)(C)C)c2)c(-c2cccc(C(C)(C)C)c2)c1 ; *c1ccc(-c2ccc(C(C)(C)C)cc2)c(-c2ccc(C(C)(C)C)cc2)c1 ; *c1ccc(-c2ccccc2C)cc1-c1ccccc1C] 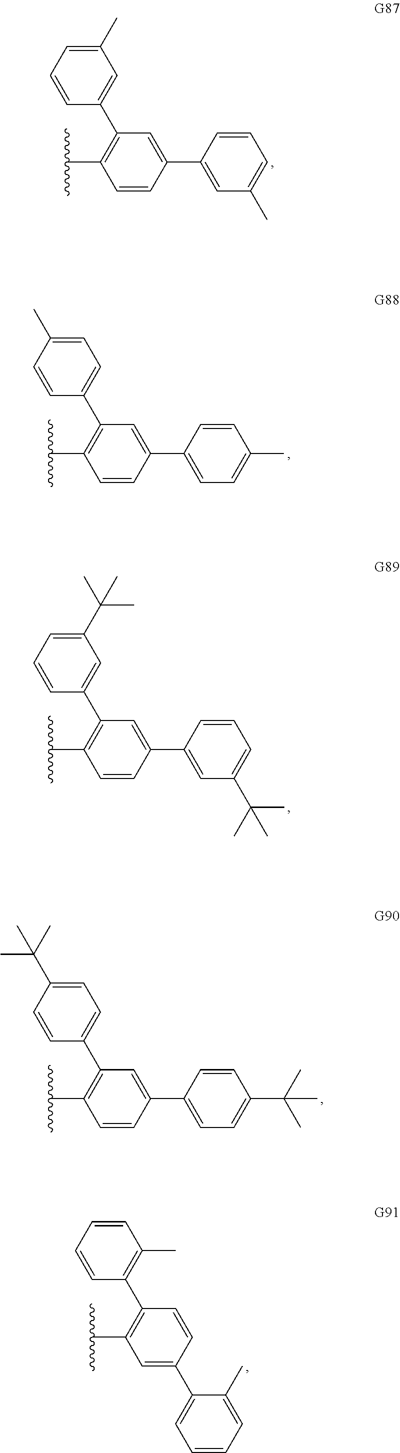 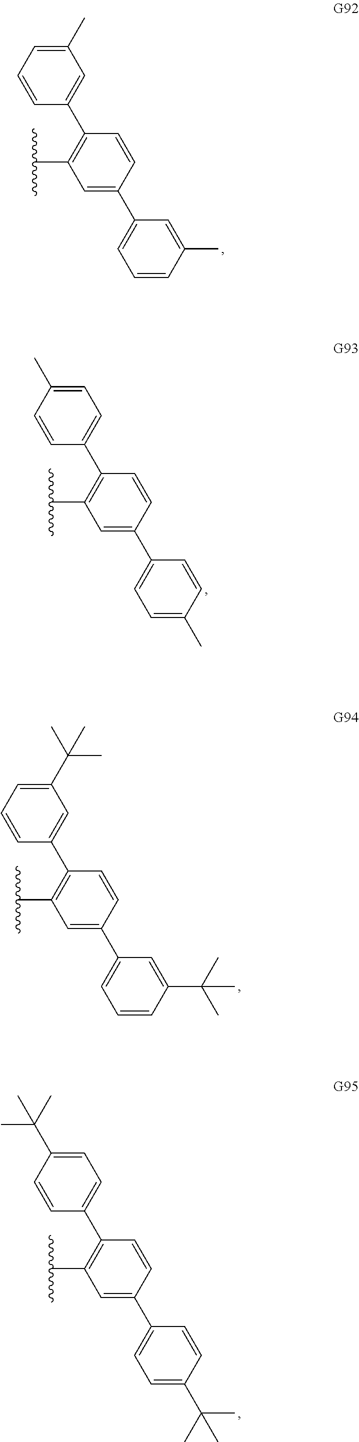 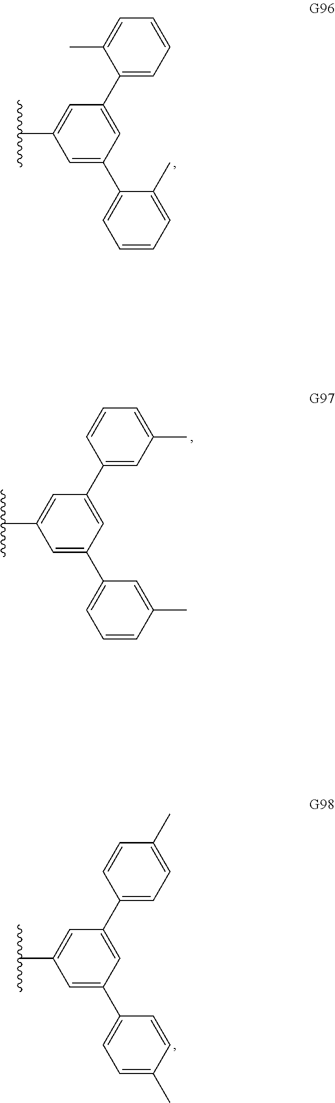 [SMILES: *c1cc(-c2ccccc2C)cc(-c2ccccc2C)c1 ; *c1cc(-c2cccc(C)c2)cc(-c2cccc(C)c2)c1 ; *c1cc(-c2ccc(C)cc2)cc(-c2ccc(C)cc2)c1] 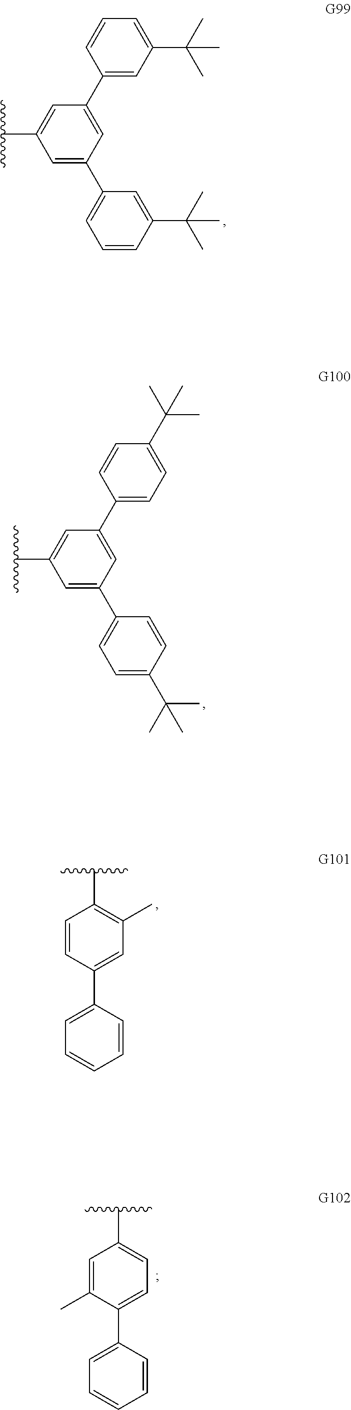
and/or Ar₁ is, at each occurrence identically or differently, selected from the group consisting of G26 to G70.

9. The compound according to claim 1, wherein the compound is selected from the group consisting of Compound 1 to Compound 3816 and Compound H1 to Compound H605:
wherein Compound 1 to Compound 1659 each have a structure represented by Formula 5: 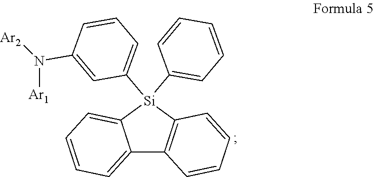
wherein Ar₁ and Ar₂ are selected from the groups listed in the following table, respectively:

| Com- | | | Com- | | | Com- | | |
|---|---|---|---|---|---|---|---|---|
| pound | | | pound | | | pound | | |
| No. | Ar₂ | Ar₁ | No. | Ar₂ | Ar₁ | No. | Ar₂ | Ar₁ |
| 1 | G1 | G26 | 2 | G19 | G40 | 3 | G25 | G53 |
| 4 | G2 | G26 | 5 | G23 | G40 | 6 | G27 | G53 |
| 7 | G3 | G26 | 8 | G29 | G40 | 9 | G28 | G53 |
| 10 | G5 | G26 | 11 | G33 | G40 | 12 | G29 | G53 |
| 13 | G13 | G26 | 14 | G35 | G40 | 15 | G31 | G53 |
| 16 | G19 | G26 | 17 | G38 | G40 | 18 | G32 | G53 |
| 19 | G23 | G26 | 20 | G47 | G40 | 21 | G33 | G53 |
| 22 | G29 | G26 | 23 | G51 | G40 | 24 | G35 | G53 |
| 25 | G33 | G26 | 26 | G53 | G40 | 27 | G36 | G53 |
| 28 | G35 | G26 | 29 | G54 | G40 | 30 | G37 | G53 |
| 31 | G38 | G26 | 32 | G55 | G40 | 33 | G38 | G53 |
| 34 | G47 | G26 | 35 | G56 | G40 | 36 | G39 | G53 |
| 37 | G51 | G26 | 38 | G59 | G40 | 39 | G41 | G53 |
| 40 | G53 | G26 | 41 | G61 | G40 | 42 | G42 | G53 |
| 43 | G54 | G26 | 44 | G62 | G40 | 45 | G45 | G53 |
| 46 | G55 | G26 | 47 | G63 | G40 | 48 | G46 | G53 |
| 49 | G56 | G26 | 50 | G1 | G41 | 51 | G47 | G53 |
| 52 | G59 | G26 | 53 | G2 | G41 | 54 | G48 | G53 |
| 55 | G61 | G26 | 56 | G3 | G41 | 57 | G50 | G53 |
| 58 | G62 | G26 | 59 | G4 | G41 | 60 | G51 | G53 |
| 61 | G63 | G26 | 62 | G5 | G41 | 63 | G53 | G53 |
| 64 | G1 | G27 | 65 | G6 | G41 | 66 | G63 | G53 |
| 67 | G2 | G27 | 68 | G7 | G41 | 69 | G64 | G53 |
| 70 | G3 | G27 | 71 | G8 | G41 | 72 | G65 | G53 |
| 73 | G4 | G27 | 74 | G9 | G41 | 75 | G66 | G53 |
| 76 | G5 | G27 | 77 | G10 | G41 | 78 | G67 | G53 |
| 79 | G6 | G27 | 80 | G11 | G41 | 81 | G68 | G53 |
| 82 | G7 | G27 | 83 | G12 | G41 | 84 | G69 | G53 |
| 85 | G8 | G27 | 86 | G13 | G41 | 87 | G70 | G53 |
| 88 | G9 | G27 | 89 | G14 | G41 | 90 | G71 | G53 |
| 91 | G10 | G27 | 92 | G15 | G41 | 93 | G72 | G53 |
| 94 | G11 | G27 | 95 | G16 | G41 | 96 | G73 | G53 |
| 97 | G12 | G27 | 98 | G17 | G41 | 99 | G74 | G53 |
| 100 | G13 | G27 | 101 | G18 | G41 | 102 | G75 | G53 |
| 103 | G14 | G27 | 104 | G19 | G41 | 105 | G1 | G54 |
| 106 | G15 | G27 | 107 | G20 | G41 | 108 | G2 | G54 |
| 109 | G16 | G27 | 110 | G21 | G41 | 111 | G3 | G54 |
| 112 | G17 | G27 | 113 | G22 | G41 | 114 | G4 | G54 |
| 115 | G18 | G27 | 116 | G23 | G41 | 117 | G5 | G54 |
| 118 | G19 | G27 | 119 | G24 | G41 | 120 | G6 | G54 |
| 121 | G20 | G27 | 122 | G25 | G41 | 123 | G7 | G54 |
| 124 | G21 | G27 | 125 | G27 | G41 | 126 | G8 | G54 |
| 127 | G22 | G27 | 128 | G28 | G41 | 129 | G9 | G54 |
| 130 | G23 | G27 | 131 | G29 | G41 | 132 | G10 | G54 |
| 133 | G24 | G27 | 134 | G31 | G41 | 135 | G11 | G54 |
| 136 | G25 | G27 | 137 | G32 | G41 | 138 | G12 | G54 |
| 139 | G27 | G27 | 140 | G33 | G41 | 141 | G13 | G54 |
| 142 | G63 | G27 | 143 | G35 | G41 | 144 | G14 | G54 |
| 145 | G64 | G27 | 146 | G36 | G41 | 147 | G15 | G54 |
| 148 | G65 | G27 | 149 | G37 | G41 | 150 | G16 | G54 |
| 151 | G66 | G27 | 152 | G38 | G41 | 153 | G17 | G54 |
| 154 | G67 | G27 | 155 | G39 | G41 | 156 | G18 | G54 |
| 157 | G68 | G27 | 158 | G41 | G41 | 159 | G19 | G54 |
| 160 | G69 | G27 | 161 | G63 | G41 | 162 | G20 | G54 |
| 163 | G70 | G27 | 164 | G64 | G41 | 165 | G21 | G54 |
| 166 | G71 | G27 | 167 | G65 | G41 | 168 | G22 | G54 |
| 169 | G72 | G27 | 170 | G66 | G41 | 171 | G23 | G54 |
| 172 | G73 | G27 | 173 | G67 | G41 | 174 | G24 | G54 |
| 175 | G74 | G27 | 176 | G68 | G41 | 177 | G25 | G54 |
| 178 | G75 | G27 | 179 | G69 | G41 | 180 | G27 | G54 |
| 181 | G1 | G28 | 182 | G70 | G41 | 183 | G28 | G54 |
| 184 | G2 | G28 | 185 | G71 | G41 | 186 | G29 | G54 |
| 187 | G3 | G28 | 188 | G72 | G41 | 189 | G31 | G54 |
| 190 | G4 | G28 | 191 | G73 | G41 | 192 | G32 | G54 |
| 193 | G5 | G28 | 194 | G74 | G41 | 195 | G33 | G54 |
| 196 | G6 | G28 | 197 | G75 | G41 | 198 | G35 | G54 |
| 199 | G7 | G28 | 200 | G1 | G42 | 201 | G36 | G54 |
| 202 | G8 | G28 | 203 | G2 | G42 | 204 | G37 | G54 |
| 205 | G9 | G28 | 206 | G3 | G42 | 207 | G38 | G54 |
| 208 | G10 | G28 | 209 | G4 | G42 | 210 | G39 | G54 |
| 211 | G11 | G28 | 212 | G5 | G42 | 213 | G41 | G54 |
| 214 | G12 | G28 | 215 | G6 | G42 | 216 | G42 | G54 |
| 217 | G13 | G28 | 218 | G7 | G42 | 219 | G45 | G54 |
| 220 | G14 | G28 | 221 | G8 | G42 | 222 | G46 | G54 |
| 223 | G15 | G28 | 224 | G9 | G42 | 225 | G47 | G54 |
| 226 | G16 | G28 | 227 | G10 | G42 | 228 | G48 | G54 |
| 229 | G17 | G28 | 230 | G11 | G42 | 231 | G50 | G54 |
| 232 | G18 | G28 | 233 | G12 | G42 | 234 | G51 | G54 |
| 235 | G19 | G28 | 236 | G13 | G42 | 237 | G53 | G54 |
| 238 | G20 | G28 | 239 | G14 | G42 | 240 | G54 | G54 |
| 241 | G21 | G28 | 242 | G15 | G42 | 243 | G63 | G54 |
| 244 | G22 | G28 | 245 | G16 | G42 | 246 | G64 | G54 |
| 247 | G23 | G28 | 248 | G17 | G42 | 249 | G65 | G54 |
| 250 | G24 | G28 | 251 | G18 | G42 | 252 | G66 | G54 |
| 253 | G25 | G28 | 254 | G19 | G42 | 255 | G67 | G54 |
| 256 | G27 | G28 | 257 | G20 | G42 | 258 | G68 | G54 |
| 259 | G28 | G28 | 260 | G21 | G42 | 261 | G69 | G54 |
| 262 | G63 | G28 | 263 | G22 | G42 | 264 | G70 | G54 |
| 265 | G64 | G28 | 266 | G23 | G42 | 267 | G71 | G54 |
| 268 | G65 | G28 | 269 | G24 | G42 | 270 | G72 | G54 |
| 271 | G66 | G28 | 272 | G25 | G42 | 273 | G73 | G54 |
| 274 | G67 | G28 | 275 | G27 | G42 | 276 | G74 | G54 |
| 277 | G68 | G28 | 278 | G28 | G42 | 279 | G75 | G54 |
| 280 | G69 | G28 | 281 | G29 | G42 | 282 | G1 | G55 |
| 283 | G70 | G28 | 284 | G31 | G42 | 285 | G2 | G55 |
| 286 | G71 | G28 | 287 | G32 | G42 | 288 | G3 | G55 |
| 289 | G72 | G28 | 290 | G33 | G42 | 291 | G4 | G55 |
| 292 | G73 | G28 | 293 | G35 | G42 | 294 | G5 | G55 |
| 295 | G74 | G28 | 296 | G36 | G42 | 297 | G6 | G55 |
| 298 | G75 | G28 | 299 | G37 | G42 | 300 | G7 | G55 |
| 301 | G1 | G29 | 302 | G38 | G42 | 303 | G8 | G55 |
| 304 | G2 | G29 | 305 | G39 | G42 | 306 | G9 | G55 |
| 307 | G3 | G29 | 308 | G41 | G42 | 309 | G10 | G55 |
| 310 | G4 | G29 | 311 | G42 | G42 | 312 | G11 | G55 |
| 313 | G5 | G29 | 314 | G63 | G42 | 315 | G12 | G55 |
| 316 | G6 | G29 | 317 | G64 | G42 | 318 | G13 | G55 |
| 319 | G7 | G29 | 320 | G65 | G42 | 321 | G14 | G55 |
| 322 | G8 | G29 | 323 | G66 | G42 | 324 | G15 | G55 |
| 325 | G9 | G29 | 326 | G67 | G42 | 327 | G16 | G55 |
| 328 | G10 | G29 | 329 | G68 | G42 | 330 | G17 | G55 |
| 331 | G11 | G29 | 332 | G69 | G42 | 333 | G18 | G55 |
| 334 | G12 | G29 | 335 | G70 | G42 | 336 | G19 | G55 |
| 337 | G13 | G29 | 338 | G71 | G42 | 339 | G20 | G55 |
| 340 | G14 | G29 | 341 | G72 | G42 | 342 | G21 | G55 |
| 343 | G15 | G29 | 344 | G73 | G42 | 345 | G22 | G55 |
| 346 | G16 | G29 | 347 | G74 | G42 | 348 | G23 | G55 |
| 349 | G17 | G29 | 350 | G75 | G42 | 351 | G24 | G55 |
| 352 | G18 | G29 | 353 | G1 | G43 | 354 | G25 | G55 |
| 355 | G19 | G29 | 356 | G2 | G43 | 357 | G27 | G55 |
| 358 | G20 | G29 | 359 | G3 | G43 | 360 | G28 | G55 |
| 361 | G21 | G29 | 362 | G5 | G43 | 363 | G29 | G55 |
| 364 | G22 | G29 | 365 | G13 | G43 | 366 | G31 | G55 |
| 367 | G23 | G29 | 368 | G19 | G43 | 369 | G32 | G55 |
| 370 | G24 | G29 | 371 | G23 | G43 | 372 | G33 | G55 |
| 373 | G25 | G29 | 374 | G29 | G43 | 375 | G35 | G55 |
| 376 | G27 | G29 | 377 | G33 | G43 | 378 | G36 | G55 |
| 379 | G28 | G29 | 380 | G35 | G43 | 381 | G37 | G55 |
| 382 | G29 | G29 | 383 | G38 | G43 | 384 | G38 | G55 |
| 385 | G63 | G29 | 386 | G47 | G43 | 387 | G39 | G55 |
| 388 | G64 | G29 | 389 | G51 | G43 | 390 | G41 | G55 |
| 391 | G65 | G29 | 392 | G53 | G43 | 393 | G42 | G55 |
| 394 | G66 | G29 | 395 | G54 | G43 | 396 | G45 | G55 |
| 397 | G67 | G29 | 398 | G55 | G43 | 399 | G46 | G55 |
| 400 | G68 | G29 | 401 | G56 | G43 | 402 | G47 | G55 |
| 403 | G69 | G29 | 404 | G59 | G43 | 405 | G48 | G55 |
| 406 | G70 | G29 | 407 | G61 | G43 | 408 | G50 | G55 |
| 409 | G71 | G29 | 410 | G62 | G43 | 411 | G51 | G55 |
| 412 | G72 | G29 | 413 | G63 | G43 | 414 | G53 | G55 |
| 415 | G73 | G29 | 416 | G1 | G44 | 417 | G54 | G55 |
| 418 | G74 | G29 | 419 | G2 | G44 | 420 | G55 | G55 |
| 421 | G75 | G29 | 422 | G3 | G44 | 423 | G63 | G55 |
| 424 | G1 | G30 | 425 | G5 | G44 | 426 | G64 | G55 |
| 427 | G2 | G30 | 428 | G13 | G44 | 429 | G65 | G55 |
| 430 | G3 | G30 | 431 | G19 | G44 | 432 | G66 | G55 |
| 433 | G5 | G30 | 434 | G23 | G44 | 435 | G67 | G55 |
| 436 | G13 | G30 | 437 | G29 | G44 | 438 | G68 | G55 |
| 439 | G19 | G30 | 440 | G33 | G44 | 441 | G69 | G55 |
| 442 | G23 | G30 | 443 | G35 | G44 | 444 | G70 | G55 |
| 445 | G29 | G30 | 446 | G38 | G44 | 447 | G71 | G55 |
| 448 | G33 | G30 | 449 | G47 | G44 | 450 | G72 | G55 |
| 451 | G35 | G30 | 452 | G51 | G44 | 453 | G73 | G55 |
| 454 | G38 | G30 | 455 | G53 | G44 | 456 | G74 | G55 |
| 457 | G47 | G30 | 458 | G54 | G44 | 459 | G75 | G55 |
| 460 | G51 | G30 | 461 | G55 | G44 | 462 | G1 | G56 |
| 463 | G53 | G30 | 464 | G56 | G44 | 465 | G2 | G56 |
| 466 | G54 | G30 | 467 | G59 | G44 | 468 | G3 | G56 |
| 469 | G55 | G30 | 470 | G61 | G44 | 471 | G4 | G56 |
| 472 | G56 | G30 | 473 | G62 | G44 | 474 | G5 | G56 |
| 475 | G59 | G30 | 476 | G63 | G44 | 477 | G6 | G56 |
| 478 | G61 | G30 | 479 | G1 | G45 | 480 | G7 | G56 |
| 481 | G62 | G30 | 482 | G2 | G45 | 483 | G8 | G56 |
| 484 | G63 | G30 | 485 | G3 | G45 | 486 | G9 | G56 |
| 487 | G1 | G31 | 488 | G4 | G45 | 489 | G10 | G56 |
| 490 | G2 | G31 | 491 | G5 | G45 | 492 | G11 | G56 |
| 493 | G3 | G31 | 494 | G6 | G45 | 495 | G12 | G56 |
| 496 | G4 | G31 | 497 | G7 | G45 | 498 | G13 | G56 |
| 499 | G5 | G31 | 500 | G8 | G45 | 501 | G14 | G56 |
| 502 | G6 | G31 | 503 | G9 | G45 | 504 | G15 | G56 |
| 505 | G7 | G31 | 506 | G10 | G45 | 507 | G16 | G56 |
| 508 | G8 | G31 | 509 | G11 | G45 | 510 | G17 | G56 |
| 511 | G9 | G31 | 512 | G12 | G45 | 513 | G18 | G56 |
| 514 | G10 | G31 | 515 | G13 | G45 | 516 | G19 | G56 |
| 517 | G11 | G31 | 518 | G14 | G45 | 519 | G20 | G56 |
| 520 | G12 | G31 | 521 | G15 | G45 | 522 | G21 | G56 |
| 523 | G13 | G31 | 524 | G16 | G45 | 525 | G22 | G56 |
| 526 | G14 | G31 | 527 | G17 | G45 | 528 | G23 | G56 |
| 529 | G15 | G31 | 530 | G18 | G45 | 531 | G24 | G56 |
| 532 | G16 | G31 | 533 | G19 | G45 | 534 | G25 | G56 |
| 535 | G17 | G31 | 536 | G20 | G45 | 537 | G27 | G56 |
| 538 | G18 | G31 | 539 | G21 | G45 | 540 | G28 | G56 |
| 541 | G19 | G31 | 542 | G22 | G45 | 543 | G29 | G56 |
| 544 | G20 | G31 | 545 | G23 | G45 | 546 | G31 | G56 |
| 547 | G21 | G31 | 548 | G24 | G45 | 549 | G32 | G56 |
| 550 | G22 | G31 | 551 | G25 | G45 | 552 | G33 | G56 |
| 553 | G23 | G31 | 554 | G27 | G45 | 555 | G35 | G56 |
| 556 | G24 | G31 | 557 | G28 | G45 | 558 | G36 | G56 |
| 559 | G25 | G31 | 560 | G29 | G45 | 561 | G37 | G56 |
| 562 | G27 | G31 | 563 | G31 | G45 | 564 | G38 | G56 |
| 565 | G28 | G31 | 566 | G32 | G45 | 567 | G39 | G56 |
| 568 | G29 | G31 | 569 | G33 | G45 | 570 | G41 | G56 |
| 571 | G31 | G31 | 572 | G35 | G45 | 573 | G42 | G56 |
| 574 | G63 | G31 | 575 | G36 | G45 | 576 | G45 | G56 |
| 577 | G64 | G31 | 578 | G37 | G45 | 579 | G46 | G56 |
| 580 | G65 | G31 | 581 | G38 | G45 | 582 | G47 | G56 |
| 583 | G66 | G31 | 584 | G39 | G45 | 585 | G48 | G56 |
| 586 | G67 | G31 | 587 | G41 | G45 | 588 | G50 | G56 |
| 589 | G68 | G31 | 590 | G42 | G45 | 591 | G51 | G56 |
| 592 | G69 | G31 | 593 | G45 | G45 | 594 | G53 | G56 |
| 595 | G70 | G31 | 596 | G63 | G45 | 597 | G54 | G56 |
| 598 | G71 | G31 | 599 | G64 | G45 | 600 | G55 | G56 |
| 601 | G72 | G31 | 602 | G65 | G45 | 603 | G56 | G56 |
| 604 | G73 | G31 | 605 | G66 | G45 | 606 | G63 | G56 |
| 607 | G74 | G31 | 608 | G67 | G45 | 609 | G64 | G56 |
| 610 | G75 | G31 | 611 | G68 | G45 | 612 | G65 | G56 |
| 613 | G1 | G32 | 614 | G69 | G45 | 615 | G66 | G56 |
| 616 | G2 | G32 | 617 | G70 | G45 | 618 | G67 | G56 |
| 619 | G3 | G32 | 620 | G71 | G45 | 621 | G68 | G56 |
| 622 | G4 | G32 | 623 | G72 | G45 | 624 | G69 | G56 |
| 625 | G5 | G32 | 626 | G73 | G45 | 627 | G70 | G56 |
| 628 | G6 | G32 | 629 | G74 | G45 | 630 | G71 | G56 |
| 631 | G7 | G32 | 632 | G75 | G45 | 633 | G72 | G56 |
| 634 | G8 | G32 | 635 | G1 | G46 | 636 | G73 | G56 |
| 637 | G9 | G32 | 638 | G2 | G46 | 639 | G74 | G56 |
| 640 | G10 | G32 | 641 | G3 | G46 | 642 | G75 | G56 |
| 643 | G11 | G32 | 644 | G4 | G46 | 645 | G1 | G57 |
| 646 | G12 | G32 | 647 | G5 | G46 | 648 | G2 | G57 |
| 649 | G13 | G32 | 650 | G6 | G46 | 651 | G3 | G57 |
| 652 | G14 | G32 | 653 | G7 | G46 | 654 | G4 | G57 |
| 655 | G15 | G32 | 656 | G8 | G46 | 657 | G5 | G57 |
| 658 | G16 | G32 | 659 | G9 | G46 | 660 | G6 | G57 |
| 661 | G17 | G32 | 662 | G10 | G46 | 663 | G7 | G57 |
| 664 | G18 | G32 | 665 | G11 | G46 | 666 | G8 | G57 |
| 667 | G19 | G32 | 668 | G12 | G46 | 669 | G9 | G57 |
| 670 | G20 | G32 | 671 | G13 | G46 | 672 | G10 | G57 |
| 673 | G21 | G32 | 674 | G14 | G46 | 675 | G11 | G57 |
| 676 | G22 | G32 | 677 | G15 | G46 | 678 | G12 | G57 |
| 679 | G23 | G32 | 680 | G16 | G46 | 681 | G13 | G57 |
| 682 | G24 | G32 | 683 | G17 | G46 | 684 | G14 | G57 |
| 685 | G25 | G32 | 686 | G18 | G46 | 687 | G15 | G57 |
| 688 | G27 | G32 | 689 | G19 | G46 | 690 | G16 | G57 |
| 691 | G28 | G32 | 692 | G20 | G46 | 693 | G17 | G57 |
| 694 | G29 | G32 | 695 | G21 | G46 | 696 | G18 | G57 |
| 697 | G31 | G32 | 698 | G22 | G46 | 699 | G19 | G57 |
| 700 | G32 | G32 | 701 | G23 | G46 | 702 | G20 | G57 |
| 703 | G63 | G32 | 704 | G24 | G46 | 705 | G21 | G57 |
| 706 | G64 | G32 | 707 | G25 | G46 | 708 | G22 | G57 |
| 709 | G65 | G32 | 710 | G27 | G46 | 711 | G23 | G57 |
| 712 | G66 | G32 | 713 | G28 | G46 | 714 | G24 | G57 |
| 715 | G67 | G32 | 716 | G29 | G46 | 717 | G25 | G57 |
| 718 | G68 | G32 | 719 | G31 | G46 | 720 | G27 | G57 |
| 721 | G69 | G32 | 722 | G32 | G46 | 723 | G28 | G57 |
| 724 | G70 | G32 | 725 | G33 | G46 | 726 | G29 | G57 |
| 727 | G71 | G32 | 728 | G35 | G46 | 729 | G31 | G57 |
| 730 | G72 | G32 | 731 | G36 | G46 | 732 | G32 | G57 |
| 733 | G73 | G32 | 734 | G37 | G46 | 735 | G33 | G57 |
| 736 | G74 | G32 | 737 | G38 | G46 | 738 | G35 | G57 |
| 739 | G75 | G32 | 740 | G39 | G46 | 741 | G36 | G57 |
| 742 | G1 | G33 | 743 | G41 | G46 | 744 | G37 | G57 |
| 745 | G2 | G33 | 746 | G42 | G46 | 747 | G38 | G57 |
| 748 | G3 | G33 | 749 | G45 | G46 | 750 | G39 | G57 |
| 751 | G4 | G33 | 752 | G46 | G46 | 753 | G41 | G57 |
| 754 | G5 | G33 | 755 | G63 | G46 | 756 | G42 | G57 |
| 757 | G6 | G33 | 758 | G64 | G46 | 759 | G45 | G57 |
| 760 | G7 | G33 | 761 | G65 | G46 | 762 | G46 | G57 |
| 763 | G8 | G33 | 764 | G66 | G46 | 765 | G47 | G57 |
| 766 | G9 | G33 | 767 | G67 | G46 | 768 | G48 | G57 |
| 769 | G10 | G33 | 770 | G68 | G46 | 771 | G50 | G57 |
| 772 | G11 | G33 | 773 | G69 | G46 | 774 | G51 | G57 |
| 775 | G12 | G33 | 776 | G70 | G46 | 777 | G53 | G57 |
| 778 | G13 | G33 | 779 | G71 | G46 | 780 | G54 | G57 |
| 781 | G14 | G33 | 782 | G72 | G46 | 783 | G55 | G57 |
| 784 | G15 | G33 | 785 | G73 | G46 | 786 | G56 | G57 |
| 787 | G16 | G33 | 788 | G74 | G46 | 789 | G57 | G57 |
| 790 | G17 | G33 | 791 | G75 | G46 | 792 | G63 | G57 |
| 793 | G18 | G33 | 794 | G1 | G47 | 795 | G64 | G57 |
| 796 | G19 | G33 | 797 | G2 | G47 | 798 | G65 | G57 |
| 799 | G20 | G33 | 800 | G3 | G47 | 801 | G66 | G57 |
| 802 | G21 | G33 | 803 | G4 | G47 | 804 | G67 | G57 |
| 805 | G22 | G33 | 806 | G5 | G47 | 807 | G68 | G57 |
| 808 | G23 | G33 | 809 | G6 | G47 | 810 | G69 | G57 |
| 811 | G24 | G33 | 812 | G7 | G47 | 813 | G70 | G57 |
| 814 | G25 | G33 | 815 | G8 | G47 | 816 | G71 | G57 |
| 817 | G27 | G33 | 818 | G9 | G47 | 819 | G72 | G57 |
| 820 | G28 | G33 | 821 | G10 | G47 | 822 | G73 | G57 |
| 823 | G29 | G33 | 824 | G11 | G47 | 825 | G74 | G57 |
| 826 | G31 | G33 | 827 | G12 | G47 | 828 | G75 | G57 |
| 829 | G32 | G33 | 830 | G13 | G47 | 831 | G1 | G58 |
| 832 | G33 | G33 | 833 | G14 | G47 | 834 | G2 | G58 |
| 835 | G63 | G33 | 836 | G15 | G47 | 837 | G3 | G58 |
| 838 | G64 | G33 | 839 | G16 | G47 | 840 | G5 | G58 |
| 841 | G65 | G33 | 842 | G17 | G47 | 843 | G13 | G58 |
| 844 | G66 | G33 | 845 | G18 | G47 | 846 | G19 | G58 |
| 847 | G67 | G33 | 848 | G19 | G47 | 849 | G23 | G58 |
| 850 | G68 | G33 | 851 | G20 | G47 | 852 | G29 | G58 |
| 853 | G69 | G33 | 854 | G21 | G47 | 855 | G33 | G58 |
| 856 | G70 | G33 | 857 | G22 | G47 | 858 | G35 | G58 |
| 859 | G71 | G33 | 860 | G23 | G47 | 861 | G38 | G58 |
| 862 | G72 | G33 | 863 | G24 | G47 | 864 | G47 | G58 |
| 865 | G73 | G33 | 866 | G25 | G47 | 867 | G51 | G58 |
| 868 | G74 | G33 | 869 | G27 | G47 | 870 | G53 | G58 |
| 871 | G75 | G33 | 872 | G28 | G47 | 873 | G54 | G58 |
| 874 | G1 | G34 | 875 | G29 | G47 | 876 | G55 | G58 |
| 877 | G2 | G34 | 878 | G31 | G47 | 879 | G56 | G58 |
| 880 | G3 | G34 | 881 | G32 | G47 | 882 | G59 | G58 |
| 883 | G5 | G34 | 884 | G33 | G47 | 885 | G61 | G58 |
| 886 | G13 | G34 | 887 | G35 | G47 | 888 | G62 | G58 |
| 889 | G19 | G34 | 890 | G36 | G47 | 891 | G63 | G58 |
| 892 | G23 | G34 | 893 | G37 | G47 | 894 | G1 | G59 |
| 895 | G29 | G34 | 896 | G38 | G47 | 897 | G2 | G59 |
| 898 | G33 | G34 | 899 | G39 | G47 | 900 | G3 | G59 |
| 901 | G35 | G34 | 902 | G41 | G47 | 903 | G4 | G59 |
| 904 | G38 | G34 | 905 | G42 | G47 | 906 | G5 | G59 |
| 907 | G47 | G34 | 908 | G45 | G47 | 909 | G6 | G59 |
| 910 | G51 | G34 | 911 | G46 | G47 | 912 | G7 | G59 |
| 913 | G53 | G34 | 914 | G47 | G47 | 915 | G8 | G59 |
| 916 | G54 | G34 | 917 | G63 | G47 | 918 | G9 | G59 |
| 919 | G55 | G34 | 920 | G64 | G47 | 921 | G10 | G59 |
| 922 | G56 | G34 | 923 | G65 | G47 | 924 | G11 | G59 |
| 925 | G59 | G34 | 926 | G66 | G47 | 927 | G12 | G59 |
| 928 | G61 | G34 | 929 | G67 | G47 | 930 | G13 | G59 |
| 931 | G62 | G34 | 932 | G68 | G47 | 933 | G14 | G59 |
| 934 | G63 | G34 | 935 | G69 | G47 | 936 | G15 | G59 |
| 937 | G1 | G35 | 938 | G70 | G47 | 939 | G16 | G59 |
| 940 | G2 | G35 | 941 | G71 | G47 | 942 | G17 | G59 |
| 943 | G3 | G35 | 944 | G72 | G47 | 945 | G18 | G59 |
| 946 | G4 | G35 | 947 | G73 | G47 | 948 | G19 | G59 |
| 949 | G5 | G35 | 950 | G74 | G47 | 951 | G20 | G59 |
| 952 | G6 | G35 | 953 | G75 | G47 | 954 | G21 | G59 |
| 955 | G7 | G35 | 956 | G1 | G48 | 957 | G22 | G59 |
| 958 | G8 | G35 | 959 | G2 | G48 | 960 | G23 | G59 |
| 961 | G9 | G35 | 962 | G3 | G48 | 963 | G24 | G59 |
| 964 | G10 | G35 | 965 | G4 | G48 | 966 | G25 | G59 |
| 967 | G11 | G35 | 968 | G5 | G48 | 969 | G27 | G59 |
| 970 | G12 | G35 | 971 | G6 | G48 | 972 | G28 | G59 |
| 973 | G13 | G35 | 974 | G7 | G48 | 975 | G29 | G59 |
| 976 | G14 | G35 | 977 | G8 | G48 | 978 | G31 | G59 |
| 979 | G15 | G35 | 980 | G9 | G48 | 981 | G32 | G59 |
| 982 | G16 | G35 | 983 | G10 | G48 | 984 | G33 | G59 |
| 985 | G17 | G35 | 986 | G11 | G48 | 987 | G35 | G59 |
| 988 | G18 | G35 | 989 | G12 | G48 | 990 | G36 | G59 |
| 991 | G19 | G35 | 992 | G13 | G48 | 993 | G37 | G59 |
| 994 | G20 | G35 | 995 | G14 | G48 | 996 | G38 | G59 |
| 997 | G21 | G35 | 998 | G15 | G48 | 999 | G39 | G59 |
| 1000 | G22 | G35 | 1001 | G16 | G48 | 1002 | G41 | G59 |
| 1003 | G23 | G35 | 1004 | G17 | G48 | 1005 | G42 | G59 |
| 1006 | G24 | G35 | 1007 | G18 | G48 | 1008 | G45 | G59 |
| 1009 | G25 | G35 | 1010 | G19 | G48 | 1011 | G46 | G59 |
| 1012 | G27 | G35 | 1013 | G20 | G48 | 1014 | G47 | G59 |
| 1015 | G28 | G35 | 1016 | G21 | G48 | 1017 | G48 | G59 |
| 1018 | G29 | G35 | 1019 | G22 | G48 | 1020 | G50 | G59 |
| 1021 | G31 | G35 | 1022 | G23 | G48 | 1023 | G51 | G59 |
| 1024 | G32 | G35 | 1025 | G24 | G48 | 1026 | G53 | G59 |
| 1027 | G33 | G35 | 1028 | G25 | G48 | 1029 | G54 | G59 |
| 1030 | G35 | G35 | 1031 | G27 | G48 | 1032 | G55 | G59 |
| 1033 | G63 | G35 | 1034 | G28 | G48 | 1035 | G56 | G59 |
| 1036 | G64 | G35 | 1037 | G29 | G48 | 1038 | G57 | G59 |
| 1039 | G65 | G35 | 1040 | G31 | G48 | 1041 | G59 | G59 |
| 1042 | G66 | G35 | 1043 | G32 | G48 | 1044 | G63 | G59 |
| 1045 | G67 | G35 | 1046 | G33 | G48 | 1047 | G64 | G59 |
| 1048 | G68 | G35 | 1049 | G35 | G48 | 1050 | G65 | G59 |
| 1051 | G69 | G35 | 1052 | G36 | G48 | 1053 | G66 | G59 |
| 1054 | G70 | G35 | 1055 | G37 | G48 | 1056 | G67 | G59 |
| 1057 | G71 | G35 | 1058 | G38 | G48 | 1059 | G68 | G59 |
| 1060 | G72 | G35 | 1061 | G39 | G48 | 1062 | G69 | G59 |
| 1063 | G73 | G35 | 1064 | G41 | G48 | 1065 | G70 | G59 |
| 1066 | G74 | G35 | 1067 | G42 | G48 | 1068 | G71 | G59 |
| 1069 | G75 | G35 | 1070 | G45 | G48 | 1071 | G72 | G59 |
| 1072 | G1 | G36 | 1073 | G46 | G48 | 1074 | G73 | G59 |
| 1075 | G2 | G36 | 1076 | G47 | G48 | 1077 | G74 | G59 |
| 1078 | G3 | G36 | 1079 | G48 | G48 | 1080 | G75 | G59 |
| 1081 | G4 | G36 | 1082 | G63 | G48 | 1083 | G1 | G60 |
| 1084 | G5 | G36 | 1085 | G64 | G48 | 1086 | G2 | G60 |
| 1087 | G6 | G36 | 1088 | G65 | G48 | 1089 | G3 | G60 |
| 1090 | G7 | G36 | 1091 | G66 | G48 | 1092 | G4 | G60 |
| 1093 | G8 | G36 | 1094 | G67 | G48 | 1095 | G5 | G60 |
| 1096 | G9 | G36 | 1097 | G68 | G48 | 1098 | G6 | G60 |
| 1099 | G10 | G36 | 1100 | G69 | G48 | 1101 | G7 | G60 |
| 1102 | G11 | G36 | 1103 | G70 | G48 | 1104 | G8 | G60 |
| 1105 | G12 | G36 | 1106 | G71 | G48 | 1107 | G9 | G60 |
| 1108 | G13 | G36 | 1109 | G72 | G48 | 1110 | G10 | G60 |
| 1111 | G14 | G36 | 1112 | G73 | G48 | 1113 | G11 | G60 |
| 1114 | G15 | G36 | 1115 | G74 | G48 | 1116 | G12 | G60 |
| 1117 | G16 | G36 | 1118 | G75 | G48 | 1119 | G13 | G60 |
| 1120 | G17 | G36 | 1121 | G1 | G49 | 1122 | G14 | G60 |
| 1123 | G18 | G36 | 1124 | G2 | G49 | 1125 | G15 | G60 |
| 1126 | G19 | G36 | 1127 | G3 | G49 | 1128 | G16 | G60 |
| 1129 | G20 | G36 | 1130 | G5 | G49 | 1131 | G17 | G60 |
| 1132 | G21 | G36 | 1133 | G13 | G49 | 1134 | G18 | G60 |
| 1135 | G22 | G36 | 1136 | G19 | G49 | 1137 | G19 | G60 |
| 1138 | G23 | G36 | 1139 | G23 | G49 | 1140 | G20 | G60 |
| 1141 | G24 | G36 | 1142 | G29 | G49 | 1143 | G21 | G60 |
| 1144 | G25 | G36 | 1145 | G33 | G49 | 1146 | G22 | G60 |
| 1147 | G27 | G36 | 1148 | G35 | G49 | 1149 | G23 | G60 |
| 1150 | G28 | G36 | 1151 | G38 | G49 | 1152 | G24 | G60 |
| 1153 | G29 | G36 | 1154 | G47 | G49 | 1155 | G25 | G60 |
| 1156 | G31 | G36 | 1157 | G51 | G49 | 1158 | G27 | G60 |
| 1159 | G32 | G36 | 1160 | G53 | G49 | 1161 | G28 | G60 |
| 1162 | G33 | G36 | 1163 | G54 | G49 | 1164 | G29 | G60 |
| 1165 | G35 | G36 | 1166 | G55 | G49 | 1167 | G31 | G60 |
| 1168 | G36 | G36 | 1169 | G56 | G49 | 1170 | G32 | G60 |
| 1171 | G63 | G36 | 1172 | G59 | G49 | 1173 | G33 | G60 |
| 1174 | G64 | G36 | 1175 | G61 | G49 | 1176 | G35 | G60 |
| 1177 | G65 | G36 | 1178 | G62 | G49 | 1179 | G36 | G60 |
| 1180 | G66 | G36 | 1181 | G63 | G49 | 1182 | G37 | G60 |
| 1183 | G67 | G36 | 1184 | G1 | G50 | 1185 | G38 | G60 |
| 1186 | G68 | G36 | 1187 | G2 | G50 | 1188 | G39 | G60 |
| 1189 | G69 | G36 | 1190 | G3 | G50 | 1191 | G41 | G60 |
| 1192 | G70 | G36 | 1193 | G4 | G50 | 1194 | G42 | G60 |
| 1195 | G71 | G36 | 1196 | G5 | G50 | 1197 | G45 | G60 |
| 1198 | G72 | G36 | 1199 | G6 | G50 | 1200 | G46 | G60 |
| 1201 | G73 | G36 | 1202 | G7 | G50 | 1203 | G47 | G60 |
| 1204 | G74 | G36 | 1205 | G8 | G50 | 1206 | G48 | G60 |
| 1207 | G75 | G36 | 1208 | G9 | G50 | 1209 | G50 | G60 |
| 1210 | G1 | G37 | 1211 | G10 | G50 | 1212 | G51 | G60 |
| 1213 | G2 | G37 | 1214 | G11 | G50 | 1215 | G53 | G60 |
| 1216 | G3 | G37 | 1217 | G12 | G50 | 1218 | G54 | G60 |
| 1219 | G4 | G37 | 1220 | G13 | G50 | 1221 | G55 | G60 |
| 1222 | G5 | G37 | 1223 | G14 | G50 | 1224 | G56 | G60 |
| 1225 | G6 | G37 | 1226 | G15 | G50 | 1227 | G57 | G60 |
| 1228 | G7 | G37 | 1229 | G16 | G50 | 1230 | G59 | G60 |
| 1231 | G8 | G37 | 1232 | G17 | G50 | 1233 | G60 | G60 |
| 1234 | G9 | G37 | 1235 | G18 | G50 | 1236 | G63 | G60 |
| 1237 | G10 | G37 | 1238 | G19 | G50 | 1239 | G64 | G60 |
| 1240 | G11 | G37 | 1241 | G20 | G50 | 1242 | G65 | G60 |
| 1243 | G12 | G37 | 1244 | G21 | G50 | 1245 | G66 | G60 |
| 1246 | G13 | G37 | 1247 | G22 | G50 | 1248 | G67 | G60 |
| 1249 | G14 | G37 | 1250 | G23 | G50 | 1251 | G68 | G60 |
| 1252 | G15 | G37 | 1253 | G24 | G50 | 1254 | G69 | G60 |
| 1255 | G16 | G37 | 1256 | G25 | G50 | 1257 | G70 | G60 |
| 1258 | G17 | G37 | 1259 | G27 | G50 | 1260 | G71 | G60 |
| 1261 | G18 | G37 | 1262 | G28 | G50 | 1263 | G72 | G60 |
| 1264 | G19 | G37 | 1265 | G29 | G50 | 1266 | G73 | G60 |
| 1267 | G20 | G37 | 1268 | G31 | G50 | 1269 | G74 | G60 |
| 1270 | G21 | G37 | 1271 | G32 | G50 | 1272 | G75 | G60 |
| 1273 | G22 | G37 | 1274 | G33 | G50 | 1275 | G1 | G61 |
| 1276 | G23 | G37 | 1277 | G35 | G50 | 1278 | G2 | G61 |
| 1279 | G24 | G37 | 1280 | G36 | G50 | 1281 | G3 | G61 |
| 1282 | G25 | G37 | 1283 | G37 | G50 | 1284 | G4 | G61 |
| 1285 | G27 | G37 | 1286 | G38 | G50 | 1287 | G5 | G61 |
| 1288 | G28 | G37 | 1289 | G39 | G50 | 1290 | G6 | G61 |
| 1291 | G29 | G37 | 1292 | G41 | G50 | 1293 | G7 | G61 |
| 1294 | G31 | G37 | 1295 | G42 | G50 | 1296 | G8 | G61 |
| 1297 | G32 | G37 | 1298 | G45 | G50 | 1299 | G9 | G61 |
| 1300 | G33 | G37 | 1301 | G46 | G50 | 1302 | G10 | G61 |
| 1303 | G35 | G37 | 1304 | G47 | G50 | 1305 | G11 | G61 |
| 1306 | G36 | G37 | 1307 | G48 | G50 | 1308 | G12 | G61 |
| 1309 | G37 | G37 | 1310 | G50 | G50 | 1311 | G13 | G61 |
| 1312 | G63 | G37 | 1313 | G63 | G50 | 1314 | G14 | G61 |
| 1315 | G64 | G37 | 1316 | G64 | G50 | 1317 | G15 | G61 |
| 1318 | G65 | G37 | 1319 | G65 | G50 | 1320 | G16 | G61 |
| 1321 | G66 | G37 | 1322 | G66 | G50 | 1323 | G17 | G61 |
| 1324 | G67 | G37 | 1325 | G67 | G50 | 1326 | G18 | G61 |
| 1327 | G68 | G37 | 1328 | G68 | G50 | 1329 | G19 | G61 |
| 1330 | G69 | G37 | 1331 | G69 | G50 | 1332 | G20 | G61 |
| 1333 | G70 | G37 | 1334 | G70 | G50 | 1335 | G21 | G61 |
| 1336 | G71 | G37 | 1337 | G71 | G50 | 1338 | G22 | G61 |
| 1339 | G72 | G37 | 1340 | G72 | G50 | 1341 | G23 | G61 |
| 1342 | G73 | G37 | 1343 | G73 | G50 | 1344 | G24 | G61 |
| 1345 | G74 | G37 | 1346 | G74 | G50 | 1347 | G25 | G61 |
| 1348 | G75 | G37 | 1349 | G75 | G50 | 1350 | G27 | G61 |
| 1351 | G1 | G38 | 1352 | G1 | G51 | 1353 | G28 | G61 |
| 1354 | G2 | G38 | 1355 | G2 | G51 | 1356 | G29 | G61 |
| 1357 | G3 | G38 | 1358 | G3 | G51 | 1359 | G31 | G61 |
| 1360 | G4 | G38 | 1361 | G4 | G51 | 1362 | G32 | G61 |
| 1363 | G5 | G38 | 1364 | G5 | G51 | 1365 | G33 | G61 |
| 1366 | G6 | G38 | 1367 | G6 | G51 | 1368 | G35 | G61 |
| 1369 | G7 | G38 | 1370 | G7 | G51 | 1371 | G36 | G61 |
| 1372 | G8 | G38 | 1373 | G8 | G51 | 1374 | G37 | G61 |
| 1375 | G9 | G38 | 1376 | G9 | G51 | 1377 | G38 | G61 |
| 1378 | G10 | G38 | 1379 | G10 | G51 | 1380 | G39 | G61 |
| 1381 | G11 | G38 | 1382 | G11 | G51 | 1383 | G41 | G61 |
| 1384 | G12 | G38 | 1385 | G12 | G51 | 1386 | G42 | G61 |
| 1387 | G13 | G38 | 1388 | G13 | G51 | 1389 | G45 | G61 |
| 1390 | G14 | G38 | 1391 | G14 | G51 | 1392 | G46 | G61 |
| 1393 | G15 | G38 | 1394 | G15 | G51 | 1395 | G47 | G61 |
| 1396 | G16 | G38 | 1397 | G16 | G51 | 1398 | G48 | G61 |
| 1399 | G17 | G38 | 1400 | G17 | G51 | 1401 | G50 | G61 |
| 1402 | G18 | G38 | 1403 | G18 | G51 | 1404 | G51 | G61 |
| 1405 | G19 | G38 | 1406 | G19 | G51 | 1407 | G53 | G61 |
| 1408 | G20 | G38 | 1409 | G20 | G51 | 1410 | G54 | G61 |
| 1411 | G21 | G38 | 1412 | G21 | G51 | 1413 | G55 | G61 |
| 1414 | G22 | G38 | 1415 | G22 | G51 | 1416 | G56 | G61 |
| 1417 | G23 | G38 | 1418 | G23 | G51 | 1419 | G57 | G61 |
| 1420 | G24 | G38 | 1421 | G24 | G51 | 1422 | G59 | G61 |
| 1423 | G25 | G38 | 1424 | G25 | G51 | 1425 | G60 | G61 |
| 1426 | G27 | G38 | 1427 | G27 | G51 | 1428 | G61 | G61 |
| 1429 | G28 | G38 | 1430 | G28 | G51 | 1431 | G63 | G61 |
| 1432 | G29 | G38 | 1433 | G29 | G51 | 1434 | G64 | G61 |
| 1435 | G31 | G38 | 1436 | G31 | G51 | 1437 | G65 | G61 |
| 1438 | G32 | G38 | 1439 | G32 | G51 | 1440 | G66 | G61 |
| 1441 | G33 | G38 | 1442 | G33 | G51 | 1443 | G67 | G61 |
| 1444 | G35 | G38 | 1445 | G35 | G51 | 1446 | G68 | G61 |
| 1447 | G36 | G38 | 1448 | G36 | G51 | 1449 | G69 | G61 |
| 1450 | G37 | G38 | 1451 | G37 | G51 | 1452 | G70 | G61 |
| 1453 | G38 | G38 | 1454 | G38 | G51 | 1455 | G71 | G61 |
| 1456 | G63 | G38 | 1457 | G39 | G51 | 1458 | G72 | G61 |
| 1459 | G64 | G38 | 1460 | G41 | G51 | 1461 | G73 | G61 |
| 1462 | G65 | G38 | 1463 | G42 | G51 | 1464 | G74 | G61 |
| 1465 | G66 | G38 | 1466 | G45 | G51 | 1467 | G75 | G61 |
| 1468 | G67 | G38 | 1469 | G46 | G51 | 1470 | G1 | G62 |
| 1471 | G68 | G38 | 1472 | G47 | G51 | 1473 | G2 | G62 |
| 1474 | G69 | G38 | 1475 | G48 | G51 | 1476 | G3 | G62 |
| 1477 | G70 | G38 | 1478 | G50 | G51 | 1479 | G4 | G62 |
| 1480 | G71 | G38 | 1481 | G51 | G51 | 1482 | G5 | G62 |
| 1483 | G72 | G38 | 1484 | G63 | G51 | 1485 | G6 | G62 |
| 1486 | G73 | G38 | 1487 | G64 | G51 | 1488 | G7 | G62 |
| 1489 | G74 | G38 | 1490 | G65 | G51 | 1491 | G8 | G62 |
| 1492 | G75 | G38 | 1493 | G66 | G51 | 1494 | G9 | G62 |
| 1495 | G1 | G39 | 1496 | G67 | G51 | 1497 | G10 | G62 |
| 1498 | G2 | G39 | 1499 | G68 | G51 | 1500 | G11 | G62 |
| 1501 | G3 | G39 | 1502 | G69 | G51 | 1503 | G12 | G62 |
| 1504 | G4 | G39 | 1505 | G70 | G51 | 1506 | G13 | G62 |
| 1507 | G5 | G39 | 1508 | G71 | G51 | 1509 | G14 | G62 |
| 1510 | G6 | G39 | 1511 | G72 | G51 | 1512 | G15 | G62 |
| 1513 | G7 | G39 | 1514 | G73 | G51 | 1515 | G16 | G62 |
| 1516 | G8 | G39 | 1517 | G74 | G51 | 1518 | G17 | G62 |
| 1519 | G9 | G39 | 1520 | G75 | G51 | 1521 | G18 | G62 |
| 1522 | G10 | G39 | 1523 | G1 | G52 | 1524 | G19 | G62 |
| 1525 | G11 | G39 | 1526 | G2 | G52 | 1527 | G20 | G62 |
| 1528 | G12 | G39 | 1529 | G3 | G52 | 1530 | G21 | G62 |
| 1531 | G13 | G39 | 1532 | G5 | G52 | 1533 | G22 | G62 |
| 1534 | G14 | G39 | 1535 | G13 | G52 | 1536 | G23 | G62 |
| 1537 | G15 | G39 | 1538 | G19 | G52 | 1539 | G24 | G62 |
| 1540 | G16 | G39 | 1541 | G23 | G52 | 1542 | G25 | G62 |
| 1543 | G17 | G39 | 1544 | G29 | G52 | 1545 | G27 | G62 |
| 1546 | G18 | G39 | 1547 | G33 | G52 | 1548 | G28 | G62 |
| 1549 | G19 | G39 | 1550 | G35 | G52 | 1551 | G29 | G62 |
| 1552 | G20 | G39 | 1553 | G38 | G52 | 1554 | G31 | G62 |
| 1555 | G21 | G39 | 1556 | G47 | G52 | 1557 | G32 | G62 |
| 1558 | G22 | G39 | 1559 | G51 | G52 | 1560 | G33 | G62 |
| 1561 | G23 | G39 | 1562 | G53 | G52 | 1563 | G35 | G62 |
| 1564 | G24 | G39 | 1565 | G54 | G52 | 1566 | G36 | G62 |
| 1567 | G25 | G39 | 1568 | G55 | G52 | 1569 | G37 | G62 |
| 1570 | G27 | G39 | 1571 | G56 | G52 | 1572 | G38 | G62 |
| 1573 | G28 | G39 | 1574 | G59 | G52 | 1575 | G39 | G62 |
| 1576 | G29 | G39 | 1577 | G61 | G52 | 1578 | G41 | G62 |
| 1579 | G31 | G39 | 1580 | G62 | G52 | 1581 | G42 | G62 |
| 1582 | G32 | G39 | 1583 | G63 | G52 | 1584 | G45 | G62 |
| 1585 | G33 | G39 | 1586 | G1 | G53 | 1587 | G46 | G62 |
| 1588 | G35 | G39 | 1589 | G2 | G53 | 1590 | G47 | G62 |
| 1591 | G36 | G39 | 1592 | G3 | G53 | 1593 | G48 | G62 |
| 1594 | G37 | G39 | 1595 | G4 | G53 | 1596 | G50 | G62 |
| 1597 | G38 | G39 | 1598 | G5 | G53 | 1599 | G51 | G62 |
| 1600 | G39 | G39 | 1601 | G6 | G53 | 1602 | G53 | G62 |
| 1603 | G63 | G39 | 1604 | G7 | G53 | 1605 | G54 | G62 |
| 1606 | G64 | G39 | 1607 | G8 | G53 | 1608 | G55 | G62 |
| 1609 | G65 | G39 | 1610 | G9 | G53 | 1611 | G56 | G62 |
| 1612 | G66 | G39 | 1613 | G10 | G53 | 1614 | G57 | G62 |
| 1615 | G67 | G39 | 1616 | G11 | G53 | 1617 | G59 | G62 |
| 1618 | G68 | G39 | 1619 | G12 | G53 | 1620 | G60 | G62 |
| 1621 | G69 | G39 | 1622 | G13 | G53 | 1623 | G61 | G62 |
| 1624 | G70 | G39 | 1625 | G14 | G53 | 1626 | G62 | G62 |
| 1627 | G71 | G39 | 1628 | G15 | G53 | 1629 | G63 | G62 |
| 1630 | G72 | G39 | 1631 | G16 | G53 | 1632 | G64 | G62 |
| 1633 | G73 | G39 | 1634 | G17 | G53 | 1635 | G65 | G62 |
| 1636 | G74 | G39 | 1637 | G18 | G53 | 1638 | G66 | G62 |
| 1639 | G75 | G39 | 1640 | G19 | G53 | 1641 | G67 | G62 |
| 1642 | G1 | G40 | 1643 | G20 | G53 | 1644 | G68 | G62 |
| 1645 | G2 | G40 | 1646 | G21 | G53 | 1647 | G69 | G62 |
| 1648 | G3 | G40 | 1649 | G22 | G53 | 1650 | G70 | G62 |
| 1651 | G5 | G40 | 1652 | G23 | G53 | 1653 | G71 | G62 |
| 1654 | G13 | G40 | 1655 | G24 | G53 | 1656 | G72 | G62 |
| 1657 | G73 | G62 | 1658 | G74 | G62 | 1659 | G75 | G62 |

wherein Compound 1660 to Compound 2360 each have a structure represented by Formula 6: 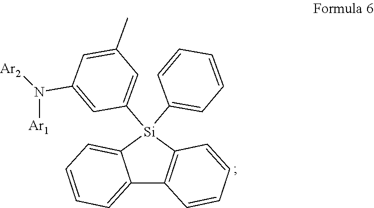
wherein Ar₁ and Ar₂ are selected from the groups listed in the following table, respectively:

| Compound No. | Ar₂ | Ar₁ |
|---|---|---|
| 1660 | G1 | G27 |
| 1661 | G11 | G34 |
| 1662 | G76 | G55 |
| 1663 | G2 | G27 |
| 1664 | G12 | G34 |
| 1665 | G77 | G55 |
| 1666 | G3 | G27 |
| 1667 | G13 | G34 |
| 1668 | G78 | G55 |
| 1669 | G4 | G27 |
| 1670 | G14 | G34 |
| 1671 | G79 | G55 |
| 1672 | G5 | G27 |
| 1673 | G18 | G34 |
| 1674 | G80 | G55 |
| 1675 | G6 | G27 |
| 1676 | G19 | G34 |
| 1677 | G81 | G55 |
| 1678 | G7 | G27 |
| 1679 | G20 | G34 |
| 1680 | G82 | G55 |
| 1681 | G8 | G27 |
| 1682 | G21 | G34 |
| 1683 | G83 | G55 |
| 1684 | G9 | G27 |
| 1685 | G22 | G34 |
| 1686 | G84 | G55 |
| 1687 | G10 | G27 |
| 1688 | G23 | G34 |
| 1689 | G85 | G55 |
| 1690 | G11 | G27 |
| 1691 | G24 | G34 |
| 1692 | G86 | G55 |
| 1693 | G12 | G27 |
| 1694 | G25 | G34 |
| 1695 | G87 | G55 |
| 1696 | G13 | G27 |
| 1697 | G34 | G34 |
| 1698 | G88 | G55 |
| 1699 | G14 | G27 |
| 1700 | G35 | G34 |
| 1701 | G89 | G55 |
| 1702 | G18 | G27 |
| 1703 | G37 | G34 |
| 1704 | G90 | G55 |
| 1705 | G19 | G27 |
| 1706 | G53 | G34 |
| 1707 | G91 | G55 |
| 1708 | G20 | G27 |
| 1709 | G55 | G34 |
| 1710 | G92 | G55 |
| 1711 | G21 | G27 |
| 1712 | G61 | G34 |
| 1713 | G93 | G55 |
| 1714 | G22 | G27 |
| 1715 | G63 | G34 |
| 1716 | G94 | G55 |
| 1717 | G23 | G27 |
| 1718 | G65 | G34 |
| 1719 | G95 | G55 |
| 1720 | G24 | G27 |
| 1721 | G66 | G34 |
| 1722 | G96 | G55 |
| 1723 | G25 | G27 |
| 1724 | G76 | G34 |
| 1725 | G97 | G55 |
| 1726 | G27 | G27 |
| 1727 | G77 | G34 |
| 1728 | G98 | G55 |
| 1729 | G29 | G27 |
| 1730 | G78 | G34 |
| 1731 | G99 | G55 |
| 1732 | G31 | G27 |
| 1733 | G79 | G34 |
| 1734 | G100 | G55 |
| 1735 | G33 | G27 |
| 1736 | G80 | G34 |
| 1737 | G101 | G55 |
| 1738 | G34 | G27 |
| 1739 | G81 | G34 |
| 1740 | G102 | G55 |
| 1741 | G35 | G27 |
| 1742 | G82 | G34 |
| 1743 | G1 | G61 |
| 1744 | G37 | G27 |
| 1745 | G83 | G34 |
| 1746 | G2 | G61 |
| 1747 | G53 | G27 |
| 1748 | G84 | G34 |
| 1749 | G3 | G61 |
| 1750 | G55 | G27 |
| 1751 | G85 | G34 |
| 1752 | G4 | G61 |
| 1753 | G61 | G27 |
| 1754 | G86 | G34 |
| 1755 | G5 | G61 |
| 1756 | G63 | G27 |
| 1757 | G87 | G34 |
| 1758 | G6 | G61 |
| 1759 | G65 | G27 |
| 1760 | G88 | G34 |
| 1761 | G7 | G61 |
| 1762 | G66 | G27 |
| 1763 | G89 | G34 |
| 1764 | G8 | G61 |
| 1765 | G76 | G27 |
| 1766 | G90 | G34 |
| 1767 | G9 | G61 |
| 1768 | G77 | G27 |
| 1769 | G91 | G34 |
| 1770 | G10 | G61 |
| 1771 | G78 | G27 |
| 1772 | G92 | G34 |
| 1773 | G11 | G61 |
| 1774 | G79 | G27 |
| 1775 | G93 | G34 |
| 1776 | G12 | G61 |
| 1777 | G80 | G27 |
| 1778 | G94 | G34 |
| 1779 | G13 | G61 |
| 1780 | G81 | G27 |
| 1781 | G95 | G34 |
| 1782 | G14 | G61 |
| 1783 | G82 | G27 |
| 1784 | G96 | G34 |
| 1785 | G18 | G61 |
| 1786 | G83 | G27 |
| 1787 | G97 | G34 |
| 1788 | G19 | G61 |
| 1789 | G84 | G27 |
| 1790 | G98 | G34 |
| 1791 | G20 | G61 |
| 1792 | G85 | G27 |
| 1793 | G99 | G34 |
| 1794 | G21 | G61 |
| 1795 | G86 | G27 |
| 1796 | G100 | G34 |
| 1797 | G22 | G61 |
| 1798 | G87 | G27 |
| 1799 | G101 | G34 |
| 1800 | G23 | G61 |
| 1801 | G88 | G27 |
| 1802 | G102 | G34 |
| 1803 | G24 | G61 |
| 1804 | G89 | G27 |
| 1805 | G1 | G35 |
| 1806 | G25 | G61 |
| 1807 | G90 | G27 |
| 1808 | G3 | G35 |
| 1809 | G61 | G61 |
| 1810 | G91 | G27 |
| 1811 | G4 | G35 |
| 1812 | G63 | G61 |
| 1813 | G92 | G27 |
| 1814 | G5 | G35 |
| 1815 | G65 | G61 |
| 1816 | G93 | G27 |
| 1817 | G7 | G35 |
| 1818 | G66 | G61 |
| 1819 | G94 | G27 |
| 1820 | G8 | G35 |
| 1821 | G76 | G61 |
| 1822 | G95 | G27 |
| 1823 | G9 | G35 |
| 1824 | G77 | G61 |
| 1825 | G96 | G27 |
| 1826 | G10 | G35 |
| 1827 | G78 | G61 |
| 1828 | G97 | G27 |
| 1829 | G12 | G35 |
| 1830 | G79 | G61 |
| 1831 | G98 | G27 |
| 1832 | G13 | G35 |
| 1833 | G80 | G61 |
| 1834 | G99 | G27 |
| 1835 | G18 | G35 |
| 1836 | G81 | G61 |
| 1837 | G100 | G27 |
| 1838 | G21 | G35 |
| 1839 | G82 | G61 |
| 1840 | G101 | G27 |
| 1841 | G22 | G35 |
| 1842 | G83 | G61 |
| 1843 | G102 | G27 |
| 1844 | G24 | G35 |
| 1845 | G84 | G61 |
| 1846 | G1 | G29 |
| 1847 | G25 | G35 |
| 1848 | G85 | G61 |
| 1849 | G3 | G29 |
| 1850 | G37 | G35 |
| 1851 | G86 | G61 |
| 1852 | G4 | G29 |
| 1853 | G53 | G35 |
| 1854 | G87 | G61 |
| 1855 | G5 | G29 |
| 1856 | G55 | G35 |
| 1857 | G88 | G61 |
| 1858 | G7 | G29 |
| 1859 | G61 | G35 |
| 1860 | G89 | G61 |
| 1861 | G8 | G29 |
| 1862 | G65 | G35 |
| 1863 | G90 | G61 |
| 1864 | G9 | G29 |
| 1865 | G66 | G35 |
| 1866 | G91 | G61 |
| 1867 | G10 | G29 |
| 1868 | G76 | G35 |
| 1869 | G92 | G61 |
| 1870 | G12 | G29 |
| 1871 | G77 | G35 |
| 1872 | G93 | G61 |
| 1873 | G13 | G29 |
| 1874 | G78 | G35 |
| 1875 | G94 | G61 |
| 1876 | G18 | G29 |
| 1877 | G79 | G35 |
| 1878 | G95 | G61 |
| 1879 | G20 | G29 |
| 1880 | G80 | G35 |
| 1881 | G96 | G61 |
| 1882 | G21 | G29 |
| 1883 | G81 | G35 |
| 1884 | G97 | G61 |
| 1885 | G22 | G29 |
| 1886 | G82 | G35 |
| 1887 | G98 | G61 |
| 1888 | G24 | G29 |
| 1889 | G83 | G35 |
| 1890 | G99 | G61 |
| 1891 | G25 | G29 |
| 1892 | G84 | G35 |
| 1893 | G100 | G61 |
| 1894 | G31 | G29 |
| 1895 | G85 | G35 |
| 1896 | G101 | G61 |
| 1897 | G34 | G29 |
| 1898 | G86 | G35 |
| 1899 | G102 | G61 |
| 1900 | G37 | G29 |
| 1901 | G87 | G35 |
| 1902 | G1 | G63 |
| 1903 | G53 | G29 |
| 1904 | G88 | G35 |
| 1905 | G2 | G63 |
| 1906 | G55 | G29 |
| 1907 | G89 | G35 |
| 1908 | G3 | G63 |
| 1909 | G61 | G29 |
| 1910 | G90 | G35 |
| 1911 | G4 | G63 |
| 1912 | G63 | G29 |
| 1913 | G91 | G35 |
| 1914 | G5 | G63 |
| 1915 | G65 | G29 |
| 1916 | G92 | G35 |
| 1917 | G6 | G63 |
| 1918 | G66 | G29 |
| 1919 | G93 | G35 |
| 1920 | G7 | G63 |
| 1921 | G76 | G29 |
| 1922 | G94 | G35 |
| 1923 | G8 | G63 |
| 1924 | G77 | G29 |
| 1925 | G95 | G35 |
| 1926 | G9 | G63 |
| 1927 | G78 | G29 |
| 1928 | G96 | G35 |
| 1929 | G10 | G63 |
| 1930 | G79 | G29 |
| 1931 | G97 | G35 |
| 1932 | G11 | G63 |
| 1933 | G80 | G29 |
| 1934 | G98 | G35 |
| 1935 | G12 | G63 |
| 1936 | G81 | G29 |
| 1937 | G99 | G35 |
| 1938 | G13 | G63 |
| 1939 | G82 | G29 |
| 1940 | G100 | G35 |
| 1941 | G14 | G63 |
| 1942 | G83 | G29 |
| 1943 | G101 | G35 |
| 1944 | G18 | G63 |
| 1945 | G84 | G29 |
| 1946 | G102 | G35 |
| 1947 | G19 | G63 |
| 1948 | G85 | G29 |
| 1949 | G1 | G37 |
| 1950 | G20 | G63 |
| 1951 | G86 | G29 |
| 1952 | G2 | G37 |
| 1953 | G21 | G63 |
| 1954 | G87 | G29 |
| 1955 | G3 | G37 |
| 1956 | G22 | G63 |
| 1957 | G88 | G29 |
| 1958 | G4 | G37 |
| 1959 | G23 | G63 |
| 1960 | G89 | G29 |
| 1961 | G5 | G37 |
| 1962 | G24 | G63 |
| 1963 | G90 | G29 |
| 1964 | G6 | G37 |
| 1965 | G25 | G63 |
| 1966 | G91 | G29 |
| 1967 | G7 | G37 |
| 1968 | G63 | G63 |
| 1969 | G92 | G29 |
| 1970 | G8 | G37 |
| 1971 | G65 | G63 |
| 1972 | G93 | G29 |
| 1973 | G9 | G37 |
| 1974 | G66 | G63 |
| 1975 | G94 | G29 |
| 1976 | G10 | G37 |
| 1977 | G76 | G63 |
| 1978 | G95 | G29 |
| 1979 | G11 | G37 |
| 1980 | G77 | G63 |
| 1981 | G96 | G29 |
| 1982 | G12 | G37 |
| 1983 | G78 | G63 |
| 1984 | G97 | G29 |
| 1985 | G13 | G37 |
| 1986 | G79 | G63 |
| 1987 | G98 | G29 |
| 1988 | G14 | G37 |
| 1989 | G80 | G63 |
| 1990 | G99 | G29 |
| 1991 | G18 | G37 |
| 1992 | G81 | G63 |
| 1993 | G100 | G29 |
| 1994 | G19 | G37 |
| 1995 | G82 | G63 |
| 1996 | G101 | G29 |
| 1997 | G20 | G37 |
| 1998 | G83 | G63 |
| 1999 | G102 | G29 |
| 2000 | G21 | G37 |
| 2001 | G84 | G63 |
| 2002 | G1 | G31 |
| 2003 | G22 | G37 |
| 2004 | G85 | G63 |
| 2005 | G2 | G31 |
| 2006 | G23 | G37 |
| 2007 | G86 | G63 |
| 2008 | G3 | G31 |
| 2009 | G24 | G37 |
| 2010 | G87 | G63 |
| 2011 | G4 | G31 |
| 2012 | G25 | G37 |
| 2013 | G88 | G63 |
| 2014 | G5 | G31 |
| 2015 | G37 | G37 |
| 2016 | G89 | G63 |
| 2017 | G6 | G31 |
| 2018 | G53 | G37 |
| 2019 | G90 | G63 |
| 2020 | G7 | G31 |
| 2021 | G55 | G37 |
| 2022 | G91 | G63 |
| 2023 | G8 | G31 |
| 2024 | G61 | G37 |
| 2025 | G92 | G63 |
| 2026 | G9 | G31 |
| 2027 | G63 | G37 |
| 2028 | G93 | G63 |
| 2029 | G10 | G31 |
| 2030 | G65 | G37 |
| 2031 | G94 | G63 |
| 2032 | G11 | G31 |
| 2033 | G66 | G37 |
| 2034 | G95 | G63 |
| 2035 | G12 | G31 |
| 2036 | G76 | G37 |
| 2037 | G96 | G63 |
| 2038 | G13 | G31 |
| 2039 | G77 | G37 |
| 2040 | G97 | G63 |
| 2041 | G14 | G31 |
| 2042 | G78 | G37 |
| 2043 | G98 | G63 |
| 2044 | G18 | G31 |
| 2045 | G79 | G37 |
| 2046 | G99 | G63 |
| 2047 | G19 | G31 |
| 2048 | G80 | G37 |
| 2049 | G100 | G63 |
| 2050 | G20 | G31 |
| 2051 | G81 | G37 |
| 2052 | G101 | G63 |
| 2053 | G21 | G31 |
| 2054 | G82 | G37 |
| 2055 | G102 | G63 |
| 2056 | G22 | G31 |
| 2057 | G83 | G37 |
| 2058 | G1 | G65 |
| 2059 | G23 | G31 |
| 2060 | G84 | G37 |
| 2061 | G2 | G65 |
| 2062 | G24 | G31 |
| 2063 | G85 | G37 |
| 2064 | G3 | G65 |
| 2065 | G25 | G31 |
| 2066 | G86 | G37 |
| 2067 | G4 | G65 |
| 2068 | G31 | G31 |
| 2069 | G87 | G37 |
| 2070 | G5 | G65 |
| 2071 | G33 | G31 |
| 2072 | G88 | G37 |
| 2073 | G6 | G65 |
| 2074 | G34 | G31 |
| 2075 | G89 | G37 |
| 2076 | G7 | G65 |
| 2077 | G35 | G31 |
| 2078 | G90 | G37 |
| 2079 | G8 | G65 |
| 2080 | G37 | G31 |
| 2081 | G91 | G37 |
| 2082 | G9 | G65 |
| 2083 | G53 | G31 |
| 2084 | G92 | G37 |
| 2085 | G10 | G65 |
| 2086 | G55 | G31 |
| 2087 | G93 | G37 |
| 2088 | G11 | G65 |
| 2089 | G61 | G31 |
| 2090 | G94 | G37 |
| 2091 | G12 | G65 |
| 2092 | G63 | G31 |
| 2093 | G95 | G37 |
| 2094 | G13 | G65 |
| 2095 | G65 | G31 |
| 2096 | G96 | G37 |
| 2097 | G14 | G65 |
| 2098 | G66 | G31 |
| 2099 | G97 | G37 |
| 2100 | G18 | G65 |
| 2101 | G76 | G31 |
| 2102 | G98 | G37 |
| 2103 | G19 | G65 |
| 2104 | G77 | G31 |
| 2105 | G99 | G37 |
| 2106 | G20 | G65 |
| 2107 | G78 | G31 |
| 2108 | G100 | G37 |
| 2109 | G21 | G65 |
| 2110 | G79 | G31 |
| 2111 | G101 | G37 |
| 2112 | G22 | G65 |
| 2113 | G80 | G31 |
| 2114 | G102 | G37 |
| 2115 | G23 | G65 |
| 2116 | G81 | G31 |
| 2117 | G1 | G53 |
| 2118 | G24 | G65 |
| 2119 | G82 | G31 |
| 2120 | G2 | G53 |
| 2121 | G25 | G65 |
| 2122 | G83 | G31 |
| 2123 | G3 | G53 |
| 2124 | G65 | G65 |
| 2125 | G84 | G31 |
| 2126 | G4 | G53 |
| 2127 | G66 | G65 |
| 2128 | G85 | G31 |
| 2129 | G5 | G53 |
| 2130 | G76 | G65 |
| 2131 | G86 | G31 |
| 2132 | G6 | G53 |
| 2133 | G77 | G65 |
| 2134 | G87 | G31 |
| 2135 | G7 | G53 |
| 2136 | G78 | G65 |
| 2137 | G88 | G31 |
| 2138 | G8 | G53 |
| 2139 | G79 | G65 |
| 2140 | G89 | G31 |
| 2141 | G9 | G53 |
| 2142 | G80 | G65 |
| 2143 | G90 | G31 |
| 2144 | G10 | G53 |
| 2145 | G81 | G65 |
| 2146 | G91 | G31 |
| 2147 | G11 | G53 |
| 2148 | G82 | G65 |
| 2149 | G92 | G31 |
| 2150 | G12 | G53 |
| 2151 | G83 | G65 |
| 2152 | G93 | G31 |
| 2153 | G13 | G53 |
| 2154 | G84 | G65 |
| 2155 | G94 | G31 |
| 2156 | G14 | G53 |
| 2157 | G85 | G65 |
| 2158 | G95 | G31 |
| 2159 | G18 | G53 |
| 2160 | G86 | G65 |
| 2161 | G96 | G31 |
| 2162 | G19 | G53 |
| 2163 | G87 | G65 |
| 2164 | G97 | G31 |
| 2165 | G20 | G53 |
| 2166 | G88 | G65 |
| 2167 | G98 | G31 |
| 2168 | G21 | G53 |
| 2169 | G89 | G65 |
| 2170 | G99 | G31 |
| 2171 | G22 | G53 |
| 2172 | G90 | G65 |
| 2173 | G100 | G31 |
| 2174 | G23 | G53 |
| 2175 | G91 | G65 |
| 2176 | G101 | G31 |
| 2177 | G24 | G53 |
| 2178 | G92 | G65 |
| 2179 | G102 | G31 |
| 2180 | G25 | G53 |
| 2181 | G93 | G65 |
| 2182 | G1 | G33 |
| 2183 | G53 | G53 |
| 2184 | G94 | G65 |
| 2185 | G3 | G33 |
| 2186 | G55 | G53 |
| 2187 | G95 | G65 |
| 2188 | G4 | G33 |
| 2189 | G61 | G53 |
| 2190 | G96 | G65 |
| 2191 | G5 | G33 |
| 2192 | G63 | G53 |
| 2193 | G97 | G65 |
| 2194 | G7 | G33 |
| 2195 | G65 | G53 |
| 2196 | G98 | G65 |
| 2197 | G8 | G33 |
| 2198 | G66 | G53 |
| 2199 | G99 | G65 |
| 2200 | G9 | G33 |
| 2201 | G76 | G53 |
| 2202 | G100 | G65 |
| 2203 | G10 | G33 |
| 2204 | G77 | G53 |
| 2205 | G101 | G65 |
| 2206 | G12 | G33 |
| 2207 | G78 | G53 |
| 2208 | G102 | G65 |
| 2209 | G13 | G33 |
| 2210 | G79 | G53 |
| 2211 | G1 | G66 |
| 2212 | G18 | G33 |
| 2213 | G80 | G53 |
| 2214 | G2 | G66 |
| 2215 | G21 | G33 |
| 2216 | G81 | G53 |
| 2217 | G3 | G66 |
| 2218 | G22 | G33 |
| 2219 | G82 | G53 |
| 2220 | G4 | G66 |
| 2221 | G24 | G33 |
| 2222 | G83 | G53 |
| 2223 | G5 | G66 |
| 2224 | G25 | G33 |
| 2225 | G84 | G53 |
| 2226 | G6 | G66 |
| 2227 | G34 | G33 |
| 2228 | G85 | G53 |
| 2229 | G7 | G66 |
| 2230 | G37 | G33 |
| 2231 | G86 | G53 |
| 2232 | G8 | G66 |
| 2233 | G53 | G33 |
| 2234 | G87 | G53 |
| 2235 | G9 | G66 |
| 2236 | G55 | G33 |
| 2237 | G88 | G53 |
| 2238 | G10 | G66 |
| 2239 | G61 | G33 |
| 2240 | G89 | G53 |
| 2241 | G11 | G66 |
| 2242 | G63 | G33 |
| 2243 | G90 | G53 |
| 2244 | G12 | G66 |
| 2245 | G65 | G33 |
| 2246 | G91 | G53 |
| 2247 | G13 | G66 |
| 2248 | G66 | G33 |
| 2249 | G92 | G53 |
| 2250 | G14 | G66 |
| 2251 | G76 | G33 |
| 2252 | G93 | G53 |
| 2253 | G18 | G66 |
| 2254 | G77 | G33 |
| 2255 | G94 | G53 |
| 2256 | G19 | G66 |
| 2257 | G78 | G33 |
| 2258 | G95 | G53 |
| 2259 | G20 | G66 |
| 2260 | G79 | G33 |
| 2261 | G96 | G53 |
| 2262 | G21 | G66 |
| 2263 | G80 | G33 |
| 2264 | G97 | G53 |
| 2265 | G22 | G66 |
| 2266 | G81 | G33 |
| 2267 | G98 | G53 |
| 2268 | G23 | G66 |
| 2269 | G82 | G33 |
| 2270 | G99 | G53 |
| 2271 | G24 | G66 |
| 2272 | G83 | G33 |
| 2273 | G100 | G53 |
| 2274 | G25 | G66 |
| 2275 | G84 | G33 |
| 2276 | G101 | G53 |
| 2277 | G66 | G66 |
| 2278 | G85 | G33 |
| 2279 | G102 | G53 |
| 2280 | G76 | G66 |
| 2281 | G86 | G33 |
| 2282 | G1 | G55 |
| 2283 | G77 | G66 |
| 2284 | G87 | G33 |
| 2285 | G2 | G55 |
| 2286 | G78 | G66 |
| 2287 | G88 | G33 |
| 2288 | G3 | G55 |
| 2289 | G79 | G66 |
| 2290 | G89 | G33 |
| 2291 | G4 | G55 |
| 2292 | G80 | G66 |
| 2293 | G90 | G33 |
| 2294 | G5 | G55 |
| 2295 | G81 | G66 |
| 2296 | G91 | G33 |
| 2297 | G6 | G55 |
| 2298 | G82 | G66 |
| 2299 | G92 | G33 |
| 2300 | G7 | G55 |
| 2301 | G83 | G66 |
| 2302 | G93 | G33 |
| 2303 | G8 | G55 |
| 2304 | G84 | G66 |
| 2305 | G94 | G33 |
| 2306 | G9 | G55 |
| 2307 | G85 | G66 |
| 2308 | G95 | G33 |
| 2309 | G10 | G55 |
| 2310 | G86 | G66 |
| 2311 | G9 | G33 |
| 2312 | G11 | G55 |
| 2313 | G87 | G66 |
| 2314 | G97 | G33 |
| 2315 | G12 | G55 |
| 2316 | G88 | G66 |
| 2317 | G98 | G33 |
| 2318 | G13 | G55 |
| 2319 | G89 | G66 |
| 2320 | G99 | G33 |
| 2321 | G14 | G55 |
| 2322 | G90 | G66 |
| 2323 | G100 | G33 |
| 2324 | G18 | G55 |
| 2325 | G91 | G66 |
| 2326 | G101 | G33 |
| 2327 | G19 | G55 |
| 2328 | G92 | G66 |
| 2329 | G102 | G33 |
| 2330 | G20 | G55 |
| 2331 | G93 | G66 |
| 2332 | G1 | G34 |
| 2333 | G21 | G55 |
| 2334 | G94 | G66 |
| 2335 | G2 | G34 |
| 2336 | G22 | G55 |
| 2337 | G95 | G66 |
| 2338 | G3 | G34 |
| 2339 | G23 | G55 |
| 2340 | G96 | G66 |
| 2341 | G4 | G34 |
| 2342 | G24 | G55 |
| 2343 | G97 | G66 |
| 2344 | G5 | G34 |
| 2345 | G25 | G55 |
| 2346 | G98 | G66 |
| 2347 | G6 | G34 |
| 2348 | G55 | G55 |
| 2349 | G99 | G66 |
| 2350 | G7 | G34 |
| 2351 | G61 | G55 |
| 2352 | G100 | G66 |
| 2353 | G8 | G34 |
| 2354 | G63 | G55 |
| 2355 | G101 | G66 |
| 2356 | G9 | G34 |
| 2357 | G65 | G55 |
| 2358 | G102 | G66 |
| 2359 | G10 | G34 |
| 2360 | G66 | G55 |

wherein Compound 2361 to Compound 3088 each have a structure represented by Formula 7: 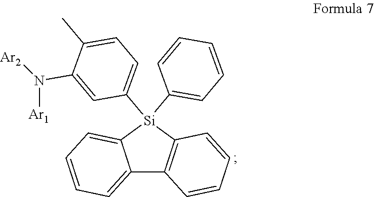
wherein Ar₁ and Ar₂ are selected from the groups listed in the following table, respectively:

| Compound No. | Ar₂ | Ar₁ |
|---|---|---|
| 2361 | G1 | G27 |
| 2362 | G2 | G34 |
| 2363 | G22 | G55 |
| 2364 | G2 | G27 |
| 2365 | G3 | G34 |
| 2366 | G23 | G55 |
| 2367 | G3 | G27 |
| 2368 | G4 | G34 |
| 2369 | G24 | G55 |
| 2370 | G4 | G27 |
| 2371 | G5 | G34 |
| 2372 | G25 | G55 |
| 2373 | G5 | G27 |
| 2374 | G6 | G34 |
| 2375 | G55 | G55 |
| 2376 | G6 | G27 |
| 2377 | G7 | G34 |
| 2378 | G61 | G55 |
| 2379 | G7 | G27 |
| 2380 | G8 | G34 |
| 2381 | G63 | G55 |
| 2382 | G8 | G27 |
| 2383 | G9 | G34 |
| 2384 | G65 | G55 |
| 2385 | G9 | G27 |
| 2386 | G10 | G34 |
| 2387 | G66 | G55 |
| 2388 | G10 | G27 |
| 2389 | G11 | G34 |
| 2390 | G76 | G55 |
| 2391 | G11 | G27 |
| 2392 | G12 | G34 |
| 2393 | G77 | G55 |
| 2394 | G12 | G27 |
| 2395 | G13 | G34 |
| 2396 | G78 | G55 |
| 2397 | G13 | G27 |
| 2398 | G14 | G34 |
| 2399 | G79 | G55 |
| 2400 | G14 | G27 |
| 2401 | G18 | G34 |
| 2402 | G80 | G55 |
| 2403 | G18 | G27 |
| 2404 | G19 | G34 |
| 2405 | G81 | G55 |
| 2406 | G19 | G27 |
| 2407 | G20 | G34 |
| 2408 | G82 | G55 |
| 2409 | G20 | G27 |
| 2410 | G21 | G34 |
| 2411 | G83 | G55 |
| 2412 | G21 | G27 |
| 2413 | G22 | G34 |
| 2414 | G84 | G55 |
| 2415 | G22 | G27 |
| 2416 | G23 | G34 |
| 2417 | G85 | G55 |
| 2418 | G23 | G27 |
| 2419 | G24 | G34 |
| 2420 | G86 | G55 |
| 2421 | G24 | G27 |
| 2422 | G25 | G34 |
| 2423 | G87 | G55 |
| 2424 | G25 | G27 |
| 2425 | G34 | G34 |
| 2426 | G88 | G55 |
| 2427 | G27 | G27 |
| 2428 | G35 | G34 |
| 2429 | G89 | G55 |
| 2430 | G29 | G27 |
| 2431 | G37 | G34 |
| 2432 | G90 | G55 |
| 2433 | G31 | G27 |
| 2434 | G53 | G34 |
| 2435 | G91 | G55 |
| 2436 | G33 | G27 |
| 2437 | G55 | G34 |
| 2438 | G92 | G55 |
| 2439 | G34 | G27 |
| 2440 | G61 | G34 |
| 2441 | G93 | G55 |
| 2442 | G35 | G27 |
| 2443 | G63 | G34 |
| 2444 | G94 | G55 |
| 2445 | G37 | G27 |
| 2446 | G65 | G34 |
| 2447 | G95 | G55 |
| 2448 | G53 | G27 |
| 2449 | G66 | G34 |
| 2450 | G96 | G55 |
| 2451 | G55 | G27 |
| 2452 | G76 | G34 |
| 2453 | G97 | G55 |
| 2454 | G61 | G27 |
| 2455 | G77 | G34 |
| 2456 | G98 | G55 |
| 2457 | G63 | G27 |
| 2458 | G78 | G34 |
| 2459 | G99 | G55 |
| 2460 | G65 | G27 |
| 2461 | G79 | G34 |
| 2462 | G100 | G55 |
| 2463 | G66 | G27 |
| 2464 | G80 | G34 |
| 2465 | G101 | G55 |
| 2466 | G76 | G27 |
| 2467 | G81 | G34 |
| 2468 | G102 | G55 |
| 2469 | G77 | G27 |
| 2470 | G82 | G34 |
| 2471 | G1 | G61 |
| 2472 | G78 | G27 |
| 2473 | G83 | G34 |
| 2474 | G2 | G61 |
| 2475 | G79 | G27 |
| 2476 | G84 | G34 |
| 2477 | G3 | G61 |
| 2478 | G80 | G27 |
| 2479 | G85 | G34 |
| 2480 | G4 | G61 |
| 2481 | G81 | G27 |
| 2482 | G86 | G34 |
| 2483 | G5 | G61 |
| 2484 | G82 | G27 |
| 2485 | G87 | G34 |
| 2486 | G6 | G61 |
| 2487 | G83 | G27 |
| 2488 | G88 | G34 |
| 2489 | G7 | G61 |
| 2490 | G84 | G27 |
| 2491 | G89 | G34 |
| 2492 | G8 | G61 |
| 2493 | G85 | G27 |
| 2494 | G90 | G34 |
| 2495 | G9 | G61 |
| 2496 | G86 | G27 |
| 2497 | G91 | G34 |
| 2498 | G10 | G61 |
| 2499 | G87 | G27 |
| 2500 | G92 | G34 |
| 2501 | G11 | G61 |
| 2502 | G88 | G27 |
| 2503 | G93 | G34 |
| 2504 | G12 | G61 |
| 2505 | G89 | G27 |
| 2506 | G94 | G34 |
| 2507 | G13 | G61 |
| 2508 | G90 | G27 |
| 2509 | G95 | G34 |
| 2510 | G14 | G61 |
| 2511 | G91 | G27 |
| 2512 | G96 | G34 |
| 2513 | G18 | G61 |
| 2514 | G92 | G27 |
| 2515 | G97 | G34 |
| 2516 | G19 | G61 |
| 2517 | G93 | G27 |
| 2518 | G98 | G34 |
| 2519 | G20 | G61 |
| 2520 | G94 | G27 |
| 2521 | G99 | G34 |
| 2522 | G21 | G61 |
| 2523 | G95 | G27 |
| 2524 | G100 | G34 |
| 2525 | G22 | G61 |
| 2526 | G96 | G27 |
| 2527 | G101 | G34 |
| 2528 | G23 | G61 |
| 2529 | G97 | G27 |
| 2530 | G102 | G34 |
| 2531 | G24 | G61 |
| 2532 | G98 | G27 |
| 2533 | G1 | G35 |
| 2534 | G25 | G61 |
| 2535 | G99 | G27 |
| 2536 | G2 | G35 |
| 2537 | G61 | G61 |
| 2538 | G100 | G27 |
| 2539 | G3 | G35 |
| 2540 | G63 | G61 |
| 2541 | G101 | G27 |
| 2542 | G4 | G35 |
| 2543 | G65 | G61 |
| 2544 | G102 | G27 |
| 2545 | G5 | G35 |
| 2546 | G66 | G61 |
| 2547 | G1 | G29 |
| 2548 | G6 | G35 |
| 2549 | G76 | G61 |
| 2550 | G2 | G29 |
| 2551 | G7 | G35 |
| 2552 | G77 | G61 |
| 2553 | G3 | G29 |
| 2554 | G8 | G35 |
| 2555 | G78 | G61 |
| 2556 | G4 | G29 |
| 2557 | G9 | G35 |
| 2558 | G79 | G61 |
| 2559 | G5 | G29 |
| 2560 | G10 | G35 |
| 2561 | G80 | G61 |
| 2562 | G6 | G29 |
| 2563 | G11 | G35 |
| 2564 | G81 | G61 |
| 2565 | G7 | G29 |
| 2566 | G12 | G35 |
| 2567 | G82 | G61 |
| 2568 | G8 | G29 |
| 2569 | G13 | G35 |
| 2570 | G83 | G61 |
| 2571 | G9 | G29 |
| 2572 | G14 | G35 |
| 2573 | G84 | G61 |
| 2574 | G10 | G29 |
| 2575 | G18 | G35 |
| 2576 | G85 | G61 |
| 2577 | G11 | G29 |
| 2578 | G19 | G35 |
| 2579 | G86 | G61 |
| 2580 | G12 | G29 |
| 2581 | G20 | G35 |
| 2582 | G87 | G61 |
| 2583 | G13 | G29 |
| 2584 | G21 | G35 |
| 2585 | G88 | G61 |
| 2586 | G14 | G29 |
| 2587 | G22 | G35 |
| 2588 | G89 | G61 |
| 2589 | G18 | G29 |
| 2590 | G23 | G35 |
| 2591 | G90 | G61 |
| 2592 | G19 | G29 |
| 2593 | G24 | G35 |
| 2594 | G91 | G61 |
| 2595 | G20 | G29 |
| 2596 | G25 | G35 |
| 2597 | G92 | G61 |
| 2598 | G21 | G29 |
| 2599 | G35 | G35 |
| 2600 | G93 | G61 |
| 2601 | G22 | G29 |
| 2602 | G37 | G35 |
| 2603 | G94 | G61 |
| 2604 | G23 | G29 |
| 2605 | G53 | G35 |
| 2606 | G95 | G61 |
| 2607 | G24 | G29 |
| 2608 | G55 | G35 |
| 2609 | G96 | G61 |
| 2610 | G25 | G29 |
| 2611 | G61 | G35 |
| 2612 | G97 | G61 |
| 2613 | G29 | G29 |
| 2614 | G63 | G35 |
| 2615 | G98 | G61 |
| 2616 | G31 | G29 |
| 2617 | G65 | G35 |
| 2618 | G99 | G61 |
| 2619 | G33 | G29 |
| 2620 | G66 | G35 |
| 2621 | G100 | G61 |
| 2622 | G34 | G29 |
| 2623 | G76 | G35 |
| 2624 | G101 | G61 |
| 2625 | G35 | G29 |
| 2626 | G77 | G35 |
| 2627 | G102 | G61 |
| 2628 | G37 | G29 |
| 2629 | G78 | G35 |
| 2630 | G1 | G63 |
| 2631 | G53 | G29 |
| 2632 | G79 | G35 |
| 2633 | G2 | G63 |
| 2634 | G55 | G29 |
| 2635 | G80 | G35 |
| 2636 | G3 | G63 |
| 2637 | G61 | G29 |
| 2638 | G81 | G35 |
| 2639 | G4 | G63 |
| 2640 | G63 | G29 |
| 2641 | G82 | G35 |
| 2642 | G5 | G63 |
| 2643 | G65 | G29 |
| 2644 | G83 | G35 |
| 2645 | G6 | G63 |
| 2646 | G66 | G29 |
| 2647 | G84 | G35 |
| 2648 | G7 | G63 |
| 2649 | G76 | G29 |
| 2650 | G85 | G35 |
| 2651 | G8 | G63 |
| 2652 | G77 | G29 |
| 2653 | G86 | G35 |
| 2654 | G9 | G63 |
| 2655 | G78 | G29 |
| 2656 | G87 | G35 |
| 2657 | G10 | G63 |
| 2658 | G79 | G29 |
| 2659 | G88 | G35 |
| 2660 | G11 | G63 |
| 2661 | G80 | G29 |
| 2662 | G89 | G35 |
| 2663 | G12 | G63 |
| 2664 | G81 | G29 |
| 2665 | G90 | G35 |
| 2666 | G13 | G63 |
| 2667 | G82 | G29 |
| 2668 | G91 | G35 |
| 2669 | G14 | G63 |
| 2670 | G83 | G29 |
| 2671 | G92 | G35 |
| 2672 | G18 | G63 |
| 2673 | G84 | G29 |
| 2674 | G93 | G35 |
| 2675 | G19 | G63 |
| 2676 | G85 | G29 |
| 2677 | G94 | G35 |
| 2678 | G20 | G63 |
| 2679 | G86 | G29 |
| 2680 | G95 | G35 |
| 2681 | G21 | G63 |
| 2682 | G87 | G29 |
| 2683 | G96 | G35 |
| 2684 | G22 | G63 |
| 2685 | G88 | G29 |
| 2686 | G97 | G35 |
| 2687 | G23 | G63 |
| 2688 | G89 | G29 |
| 2689 | G98 | G35 |
| 2690 | G24 | G63 |
| 2691 | G90 | G29 |
| 2692 | G99 | G35 |
| 2693 | G25 | G63 |
| 2694 | G91 | G29 |
| 2695 | G100 | G35 |
| 2696 | G63 | G63 |
| 2697 | G92 | G29 |
| 2698 | G101 | G35 |
| 2699 | G65 | G63 |
| 2700 | G93 | G29 |
| 2701 | G102 | G35 |
| 2702 | G66 | G63 |
| 2703 | G94 | G29 |
| 2704 | G1 | G37 |
| 2705 | G76 | G63 |
| 2706 | G95 | G29 |
| 2707 | G2 | G37 |
| 2708 | G77 | G63 |
| 2709 | G96 | G29 |
| 2710 | G3 | G37 |
| 2711 | G78 | G63 |
| 2712 | G97 | G29 |
| 2713 | G4 | G37 |
| 2714 | G79 | G63 |
| 2715 | G98 | G29 |
| 2716 | G5 | G37 |
| 2717 | G80 | G63 |
| 2718 | G99 | G29 |
| 2719 | G6 | G37 |
| 2720 | G81 | G63 |
| 2721 | G100 | G29 |
| 2722 | G7 | G37 |
| 2723 | G82 | G63 |
| 2724 | G101 | G29 |
| 2725 | G8 | G37 |
| 2726 | G83 | G63 |
| 2727 | G102 | G29 |
| 2728 | G9 | G37 |
| 2729 | G84 | G63 |
| 2730 | G1 | G31 |
| 2731 | G10 | G37 |
| 2732 | G85 | G63 |
| 2733 | G2 | G31 |
| 2734 | G11 | G37 |
| 2735 | G86 | G63 |
| 2736 | G3 | G31 |
| 2737 | G12 | G37 |
| 2738 | G87 | G63 |
| 2739 | G4 | G31 |
| 2740 | G13 | G37 |
| 2741 | G88 | G63 |
| 2742 | G5 | G31 |
| 2743 | G14 | G37 |
| 2744 | G89 | G63 |
| 2745 | G6 | G31 |
| 2746 | G18 | G37 |
| 2747 | G90 | G63 |
| 2748 | G7 | G31 |
| 2749 | G19 | G37 |
| 2750 | G91 | G63 |
| 2751 | G8 | G31 |
| 2752 | G20 | G37 |
| 2753 | G92 | G63 |
| 2754 | G9 | G31 |
| 2755 | G21 | G37 |
| 2756 | G93 | G63 |
| 2757 | G10 | G31 |
| 2758 | G22 | G37 |
| 2759 | G94 | G63 |
| 2760 | G11 | G31 |
| 2761 | G23 | G37 |
| 2762 | G95 | G63 |
| 2763 | G12 | G31 |
| 2764 | G24 | G37 |
| 2765 | G96 | G63 |
| 2766 | G13 | G31 |
| 2767 | G25 | G37 |
| 2768 | G97 | G63 |
| 2769 | G14 | G31 |
| 2770 | G37 | G37 |
| 2771 | G98 | G63 |
| 2772 | G18 | G31 |
| 2773 | G53 | G37 |
| 2774 | G99 | G63 |
| 2775 | G19 | G31 |
| 2776 | G55 | G37 |
| 2777 | G100 | G63 |
| 2778 | G20 | G31 |
| 2779 | G61 | G37 |
| 2780 | G101 | G63 |
| 2781 | G21 | G31 |
| 2782 | G63 | G37 |
| 2783 | G102 | G63 |
| 2784 | G22 | G31 |
| 2785 | G65 | G37 |
| 2786 | G1 | G65 |
| 2787 | G23 | G31 |
| 2788 | G66 | G37 |
| 2789 | G2 | G65 |
| 2790 | G24 | G31 |
| 2791 | G76 | G37 |
| 2792 | G3 | G65 |
| 2793 | G25 | G31 |
| 2794 | G77 | G37 |
| 2795 | G4 | G65 |
| 2796 | G31 | G31 |
| 2797 | G78 | G37 |
| 2798 | G5 | G65 |
| 2799 | G33 | G31 |
| 2800 | G79 | G37 |
| 2801 | G6 | G65 |
| 2802 | G34 | G31 |
| 2803 | G80 | G37 |
| 2804 | G7 | G65 |
| 2805 | G35 | G31 |
| 2806 | G81 | G37 |
| 2807 | G8 | G65 |
| 2808 | G37 | G31 |
| 2809 | G82 | G37 |
| 2810 | G9 | G65 |
| 2811 | G53 | G31 |
| 2812 | G83 | G37 |
| 2813 | G10 | G65 |
| 2814 | G55 | G31 |
| 2815 | G84 | G37 |
| 2816 | G11 | G65 |
| 2817 | G61 | G31 |
| 2818 | G85 | G37 |
| 2819 | G12 | G65 |
| 2820 | G63 | G31 |
| 2821 | G86 | G37 |
| 2822 | G13 | G65 |
| 2823 | G65 | G31 |
| 2824 | G87 | G37 |
| 2825 | G14 | G65 |
| 2826 | G66 | G31 |
| 2827 | G88 | G37 |
| 2828 | G18 | G65 |
| 2829 | G76 | G31 |
| 2830 | G89 | G37 |
| 2831 | G19 | G65 |
| 2832 | G77 | G31 |
| 2833 | G90 | G37 |
| 2834 | G20 | G65 |
| 2835 | G78 | G31 |
| 2836 | G91 | G37 |
| 2837 | G21 | G65 |
| 2838 | G79 | G31 |
| 2839 | G92 | G37 |
| 2840 | G22 | G65 |
| 2841 | G80 | G31 |
| 2842 | G93 | G37 |
| 2843 | G23 | G65 |
| 2844 | G81 | G31 |
| 2845 | G94 | G37 |
| 2846 | G24 | G65 |
| 2847 | G82 | G31 |
| 2848 | G95 | G37 |
| 2849 | G25 | G65 |
| 2850 | G83 | G31 |
| 2851 | G96 | G37 |
| 2852 | G65 | G65 |
| 2853 | G84 | G31 |
| 2854 | G97 | G37 |
| 2855 | G66 | G65 |
| 2856 | G85 | G31 |
| 2857 | G98 | G37 |
| 2858 | G76 | G65 |
| 2859 | G86 | G31 |
| 2860 | G99 | G37 |
| 2861 | G77 | G65 |
| 2862 | G87 | G31 |
| 2863 | G100 | G37 |
| 2864 | G78 | G65 |
| 2865 | G88 | G31 |
| 2866 | G101 | G37 |
| 2867 | G79 | G65 |
| 2868 | G89 | G31 |
| 2869 | G102 | G37 |
| 2870 | G80 | G65 |
| 2871 | G90 | G31 |
| 2872 | G1 | G53 |
| 2873 | G81 | G65 |
| 2874 | G91 | G31 |
| 2875 | G2 | G53 |
| 2876 | G82 | G65 |
| 2877 | G92 | G31 |
| 2878 | G3 | G53 |
| 2879 | G83 | G65 |
| 2880 | G93 | G31 |
| 2881 | G4 | G53 |
| 2882 | G84 | G65 |
| 2883 | G94 | G31 |
| 2884 | G5 | G53 |
| 2885 | G85 | G65 |
| 2886 | G95 | G31 |
| 2887 | G6 | G53 |
| 2888 | G86 | G65 |
| 2889 | G96 | G31 |
| 2890 | G7 | G53 |
| 2891 | G87 | G65 |
| 2892 | G97 | G31 |
| 2893 | G8 | G53 |
| 2894 | G88 | G65 |
| 2895 | G98 | G31 |
| 2896 | G9 | G53 |
| 2897 | G89 | G65 |
| 2898 | G99 | G31 |
| 2899 | G10 | G53 |
| 2900 | G90 | G65 |
| 2901 | G100 | G31 |
| 2902 | G11 | G53 |
| 2903 | G91 | G65 |
| 2904 | G101 | G31 |
| 2905 | G12 | G53 |
| 2906 | G92 | G65 |
| 2907 | G102 | G31 |
| 2908 | G13 | G53 |
| 2909 | G93 | G65 |
| 2910 | G1 | G33 |
| 2911 | G14 | G53 |
| 2912 | G94 | G65 |
| 2913 | G2 | G33 |
| 2914 | G18 | G53 |
| 2915 | G95 | G65 |
| 2916 | G3 | G33 |
| 2917 | G19 | G53 |
| 2918 | G96 | G65 |
| 2919 | G4 | G33 |
| 2920 | G20 | G53 |
| 2921 | G97 | G65 |
| 2922 | G5 | G33 |
| 2923 | G21 | G53 |
| 2924 | G98 | G65 |
| 2925 | G6 | G33 |
| 2926 | G22 | G53 |
| 2927 | G99 | G65 |
| 2928 | G7 | G33 |
| 2929 | G23 | G53 |
| 2930 | G100 | G65 |
| 2931 | G8 | G33 |
| 2932 | G24 | G53 |
| 2933 | G101 | G65 |
| 2934 | G9 | G33 |
| 2935 | G25 | G53 |
| 2936 | G102 | G65 |
| 2937 | G10 | G33 |
| 2938 | G53 | G53 |
| 2939 | G1 | G66 |
| 2940 | G11 | G33 |
| 2941 | G55 | G53 |
| 2942 | G2 | G66 |
| 2943 | G12 | G33 |
| 2944 | G61 | G53 |
| 2945 | G3 | G66 |
| 2946 | G13 | G33 |
| 2947 | G63 | G53 |
| 2948 | G4 | G66 |
| 2949 | G14 | G33 |
| 2950 | G65 | G53 |
| 2951 | G5 | G66 |
| 2952 | G18 | G33 |
| 2953 | G66 | G53 |
| 2954 | G6 | G66 |
| 2955 | G19 | G33 |
| 2956 | G76 | G53 |
| 2957 | G7 | G66 |
| 2958 | G20 | G33 |
| 2959 | G77 | G53 |
| 2960 | G8 | G66 |
| 2961 | G21 | G33 |
| 2962 | G78 | G53 |
| 2963 | G9 | G66 |
| 2964 | G22 | G33 |
| 2965 | G79 | G53 |
| 2966 | G10 | G66 |
| 2967 | G23 | G33 |
| 2968 | G80 | G53 |
| 2969 | G11 | G66 |
| 2970 | G24 | G33 |
| 2971 | G81 | G53 |
| 2972 | G12 | G66 |
| 2973 | G25 | G33 |
| 2974 | G82 | G53 |
| 2975 | G13 | G66 |
| 2976 | G33 | G33 |
| 2977 | G83 | G53 |
| 2978 | G14 | G66 |
| 2979 | G34 | G33 |
| 2980 | G84 | G53 |
| 2981 | G18 | G66 |
| 2982 | G35 | G33 |
| 2983 | G85 | G53 |
| 2984 | G19 | G66 |
| 2985 | G37 | G33 |
| 2986 | G86 | G53 |
| 2987 | G20 | G66 |
| 2988 | G53 | G33 |
| 2989 | G87 | G53 |
| 2990 | G21 | G66 |
| 2991 | G55 | G33 |
| 2992 | G88 | G53 |
| 2993 | G22 | G66 |
| 2994 | G61 | G33 |
| 2995 | G89 | G53 |
| 2996 | G23 | G66 |
| 2997 | G63 | G33 |
| 2998 | G90 | G53 |
| 2999 | G24 | G66 |
| 3000 | G65 | G33 |
| 3001 | G91 | G53 |
| 3002 | G25 | G66 |
| 3003 | G66 | G33 |
| 3004 | G92 | G53 |
| 3005 | G66 | G66 |
| 3006 | G76 | G33 |
| 3007 | G93 | G53 |
| 3008 | G76 | G66 |
| 3009 | G77 | G33 |
| 3010 | G94 | G53 |
| 3011 | G77 | G66 |
| 3012 | G78 | G33 |
| 3013 | G95 | G53 |
| 3014 | G78 | G66 |
| 3015 | G79 | G33 |
| 3016 | G96 | G53 |
| 3017 | G79 | G66 |
| 3018 | G80 | G33 |
| 3019 | G97 | G53 |
| 3020 | G80 | G66 |
| 3021 | G81 | G33 |
| 3022 | G98 | G53 |
| 3023 | G81 | G66 |
| 3024 | G82 | G33 |
| 3025 | G99 | G53 |
| 3026 | G82 | G66 |
| 3027 | G83 | G33 |
| 3028 | G100 | G53 |
| 3029 | G83 | G66 |
| 3030 | G84 | G33 |
| 3031 | G101 | G53 |
| 3032 | G84 | G66 |
| 3033 | G85 | G33 |
| 3034 | G102 | G53 |
| 3035 | G85 | G66 |
| 3036 | G86 | G33 |
| 3037 | G1 | G55 |
| 3038 | G86 | G66 |
| 3039 | G87 | G33 |
| 3040 | G2 | G55 |
| 3041 | G87 | G66 |
| 3042 | G88 | G33 |
| 3043 | G3 | G55 |
| 3044 | G88 | G66 |
| 3045 | G89 | G33 |
| 3046 | G4 | G55 |
| 3047 | G89 | G66 |
| 3048 | G90 | G33 |
| 3049 | G5 | G55 |
| 3050 | G90 | G66 |
| 3051 | G91 | G33 |
| 3052 | G6 | G55 |
| 3053 | G91 | G66 |
| 3054 | G92 | G33 |
| 3055 | G7 | G55 |
| 3056 | G92 | G66 |
| 3057 | G93 | G33 |
| 3058 | G8 | G55 |
| 3059 | G93 | G66 |
| 3060 | G94 | G33 |
| 3061 | G9 | G55 |
| 3062 | G94 | G66 |
| 3063 | G95 | G33 |
| 3064 | G10 | G55 |
| 3065 | G95 | G66 |
| 3066 | G96 | G33 |
| 3067 | G11 | G55 |
| 3068 | G96 | G66 |
| 3069 | G97 | G33 |
| 3070 | G12 | G55 |
| 3071 | G97 | G66 |
| 3072 | G98 | G33 |
| 3073 | G13 | G55 |
| 3074 | G98 | G66 |
| 3075 | G99 | G33 |
| 3076 | G14 | G55 |
| 3077 | G99 | G66 |
| 3078 | G100 | G33 |
| 3079 | G18 | G55 |
| 3080 | G100 | G66 |
| 3081 | G101 | G33 |
| 3082 | G19 | G55 |
| 3083 | G101 | G66 |
| 3084 | G102 | G33 |
| 3085 | G20 | G55 |
| 3086 | G102 | G66 |
| 3087 | G1 | G34 |
| 3088 | G21 | G55 |

wherein Compound 3089 to Compound 3816 each have a structure represented by Formula 8: 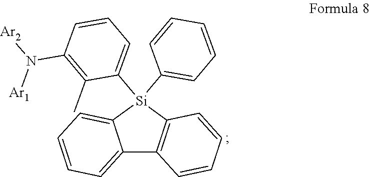
wherein Ar₁ and Ar₂ are selected from the groups listed in the following table, respectively

| Compound No. | Ar₂ | Ar₁ |
|---|---|---|
| 3089 | G1 | G27 |
| 3090 | G2 | G34 |
| 3091 | G22 | G55 |
| 3092 | G2 | G27 |
| 3093 | G3 | G34 |
| 3094 | G23 | G55 |
| 3095 | G3 | G27 |
| 3096 | G4 | G34 |
| 3097 | G24 | G55 |
| 3098 | G4 | G27 |
| 3099 | G5 | G34 |
| 3100 | G25 | G55 |
| 3101 | G5 | G27 |
| 3102 | G6 | G34 |
| 3103 | G55 | G55 |
| 3104 | G6 | G27 |
| 3105 | G7 | G34 |
| 3106 | G61 | G55 |
| 3107 | G7 | G27 |
| 3108 | G8 | G34 |
| 3109 | G63 | G55 |
| 3110 | G8 | G27 |
| 3111 | G9 | G34 |
| 3112 | G65 | G55 |
| 3113 | G9 | G27 |
| 3114 | G10 | G34 |
| 3115 | G66 | G55 |
| 3116 | G10 | G27 |
| 3117 | G11 | G34 |
| 3118 | G76 | G55 |
| 3119 | G11 | G27 |
| 3120 | G12 | G34 |
| 3121 | G77 | G55 |
| 3122 | G12 | G27 |
| 3123 | G13 | G34 |
| 3124 | G78 | G55 |
| 3125 | G13 | G27 |
| 3126 | G14 | G34 |
| 3127 | G79 | G55 |
| 3128 | G14 | G27 |
| 3129 | G18 | G34 |
| 3130 | G80 | G55 |
| 3131 | G18 | G27 |
| 3132 | G19 | G34 |
| 3133 | G81 | G55 |
| 3134 | G19 | G27 |
| 3135 | G20 | G34 |
| 3136 | G82 | G55 |
| 3137 | G20 | G27 |
| 3138 | G21 | G34 |
| 3139 | G83 | G55 |
| 3140 | G21 | G27 |
| 3141 | G22 | G34 |
| 3142 | G84 | G55 |
| 3143 | G22 | G27 |
| 3144 | G23 | G34 |
| 3145 | G85 | G55 |
| 3146 | G23 | G27 |
| 3147 | G24 | G34 |
| 3148 | G86 | G55 |
| 3149 | G24 | G27 |
| 3150 | G25 | G34 |
| 3151 | G87 | G55 |
| 3152 | G25 | G27 |
| 3153 | G34 | G34 |
| 3154 | G88 | G55 |
| 3155 | G27 | G27 |
| 3156 | G35 | G34 |
| 3157 | G89 | G55 |
| 3158 | G29 | G27 |
| 3159 | G37 | G34 |
| 3160 | G90 | G55 |
| 3161 | G31 | G27 |
| 3162 | G53 | G34 |
| 3163 | G91 | G55 |
| 3164 | G33 | G27 |
| 3165 | G55 | G34 |
| 3166 | G92 | G55 |
| 3167 | G34 | G27 |
| 3168 | G61 | G34 |
| 3169 | G93 | G55 |
| 3170 | G35 | G27 |
| 3171 | G63 | G34 |
| 3172 | G94 | G55 |
| 3173 | G37 | G27 |
| 3174 | G65 | G34 |
| 3175 | G95 | G55 |
| 3176 | G53 | G27 |
| 3177 | G66 | G34 |
| 3178 | G96 | G55 |
| 3179 | G55 | G27 |
| 3180 | G76 | G34 |
| 3181 | G97 | G55 |
| 3182 | G61 | G27 |
| 3183 | G77 | G34 |
| 3184 | G98 | G55 |
| 3185 | G63 | G27 |
| 3186 | G78 | G34 |
| 3187 | G99 | G55 |
| 3188 | G65 | G27 |
| 3189 | G79 | G34 |
| 3190 | G100 | G55 |
| 3191 | G66 | G27 |
| 3192 | G80 | G34 |
| 3193 | G101 | G55 |
| 3194 | G76 | G27 |
| 3195 | G81 | G34 |
| 3196 | G102 | G55 |
| 3197 | G77 | G27 |
| 3198 | G82 | G34 |
| 3199 | G1 | G61 |
| 3200 | G78 | G27 |
| 3201 | G83 | G34 |
| 3202 | G2 | G61 |
| 3203 | G79 | G27 |
| 3204 | G84 | G34 |
| 3205 | G3 | G61 |
| 3206 | G80 | G27 |
| 3207 | G85 | G34 |
| 3208 | G4 | G61 |
| 3209 | G81 | G27 |
| 3210 | G86 | G34 |
| 3211 | G5 | G61 |
| 3212 | G82 | G27 |
| 3213 | G87 | G34 |
| 3214 | G6 | G61 |
| 3215 | G83 | G27 |
| 3216 | G88 | G34 |
| 3217 | G7 | G61 |
| 3218 | G84 | G27 |
| 3219 | G89 | G34 |
| 3220 | G8 | G61 |
| 3221 | G85 | G27 |
| 3222 | G90 | G34 |
| 3223 | G9 | G61 |
| 3224 | G86 | G27 |
| 3225 | G91 | G34 |
| 3226 | G10 | G61 |
| 3227 | G87 | G27 |
| 3228 | G92 | G34 |
| 3229 | G11 | G61 |
| 3230 | G88 | G27 |
| 3231 | G93 | G34 |
| 3232 | G12 | G61 |
| 3233 | G89 | G27 |
| 3234 | G94 | G34 |
| 3235 | G13 | G61 |
| 3236 | G90 | G27 |
| 3237 | G95 | G34 |
| 3238 | G14 | G61 |
| 3239 | G91 | G27 |
| 3240 | G96 | G34 |
| 3241 | G18 | G61 |
| 3242 | G92 | G27 |
| 3243 | G97 | G34 |
| 3244 | G19 | G61 |
| 3245 | G93 | G27 |
| 3246 | G98 | G34 |
| 3247 | G20 | G61 |
| 3248 | G94 | G27 |
| 3249 | G99 | G34 |
| 3250 | G21 | G61 |
| 3251 | G95 | G27 |
| 3252 | G100 | G34 |
| 3253 | G22 | G61 |
| 3254 | G96 | G27 |
| 3255 | G101 | G34 |
| 3256 | G23 | G61 |
| 3257 | G97 | G27 |
| 3258 | G102 | G34 |
| 3259 | G24 | G61 |
| 3260 | G98 | G27 |
| 3261 | G1 | G35 |
| 3262 | G25 | G61 |
| 3263 | G99 | G27 |
| 3264 | G2 | G35 |
| 3265 | G61 | G61 |
| 3266 | G100 | G27 |
| 3267 | G3 | G35 |
| 3268 | G63 | G61 |
| 3269 | G101 | G27 |
| 3270 | G4 | G35 |
| 3271 | G65 | G61 |
| 3272 | G102 | G27 |
| 3273 | G5 | G35 |
| 3274 | G66 | G61 |
| 3275 | G1 | G29 |
| 3276 | G6 | G35 |
| 3277 | G76 | G61 |
| 3278 | G2 | G29 |
| 3279 | G7 | G35 |
| 3280 | G77 | G61 |
| 3281 | G3 | G29 |
| 3282 | G8 | G35 |
| 3283 | G78 | G61 |
| 3284 | G4 | G29 |
| 3285 | G9 | G35 |
| 3286 | G79 | G61 |
| 3287 | G5 | G29 |
| 3288 | G10 | G35 |
| 3289 | G80 | G61 |
| 3290 | G6 | G29 |
| 3291 | G11 | G35 |
| 3292 | G81 | G61 |
| 3293 | G7 | G29 |
| 3294 | G12 | G35 |
| 3295 | G82 | G61 |
| 3296 | G8 | G29 |
| 3297 | G13 | G35 |
| 3298 | G83 | G61 |
| 3299 | G9 | G29 |
| 3300 | G14 | G35 |
| 3301 | G84 | G61 |
| 3302 | G10 | G29 |
| 3303 | G18 | G35 |
| 3304 | G85 | G61 |
| 3305 | G11 | G29 |
| 3306 | G19 | G35 |
| 3307 | G86 | G61 |
| 3308 | G12 | G29 |
| 3309 | G20 | G35 |
| 3310 | G87 | G61 |
| 3311 | G13 | G29 |
| 3312 | G21 | G35 |
| 3313 | G88 | G61 |
| 3314 | G14 | G29 |
| 3315 | G22 | G35 |
| 3316 | G89 | G61 |
| 3317 | G18 | G29 |
| 3318 | G23 | G35 |
| 3319 | G90 | G61 |
| 3320 | G19 | G29 |
| 3321 | G24 | G35 |
| 3322 | G91 | G61 |
| 3323 | G20 | G29 |
| 3324 | G25 | G35 |
| 3325 | G92 | G61 |
| 3326 | G21 | G29 |
| 3327 | G35 | G35 |
| 3328 | G93 | G61 |
| 3329 | G22 | G29 |
| 3330 | G37 | G35 |
| 3331 | G94 | G61 |
| 3332 | G23 | G29 |
| 3333 | G53 | G35 |
| 3334 | G95 | G61 |
| 3335 | G24 | G29 |
| 3336 | G55 | G35 |
| 3337 | G96 | G61 |
| 3338 | G25 | G29 |
| 3339 | G61 | G35 |
| 3340 | G97 | G61 |
| 3341 | G29 | G29 |
| 3342 | G63 | G35 |
| 3343 | G98 | G61 |
| 3344 | G31 | G29 |
| 3345 | G65 | G35 |
| 3346 | G99 | G61 |
| 3347 | G33 | G29 |
| 3348 | G66 | G35 |
| 3349 | G100 | G61 |
| 3350 | G34 | G29 |
| 3351 | G76 | G35 |
| 3352 | G101 | G61 |
| 3353 | G35 | G29 |
| 3354 | G77 | G35 |
| 3355 | G102 | G61 |
| 3356 | G37 | G29 |
| 3357 | G78 | G35 |
| 3358 | G1 | G63 |
| 3359 | G53 | G29 |
| 3360 | G79 | G35 |
| 3361 | G2 | G63 |
| 3362 | G55 | G29 |
| 3363 | G80 | G35 |
| 3364 | G3 | G63 |
| 3365 | G61 | G29 |
| 3366 | G81 | G35 |
| 3367 | G4 | G63 |
| 3368 | G63 | G29 |
| 3369 | G82 | G35 |
| 3370 | G5 | G63 |
| 3371 | G65 | G29 |
| 3372 | G83 | G35 |
| 3373 | G6 | G63 |
| 3374 | G66 | G29 |
| 3375 | G84 | G35 |
| 3376 | G7 | G63 |
| 3377 | G76 | G29 |
| 3378 | G85 | G35 |
| 3379 | G8 | G63 |
| 3380 | G77 | G29 |
| 3381 | G86 | G35 |
| 3382 | G9 | G63 |
| 3383 | G78 | G29 |
| 3384 | G87 | G35 |
| 3385 | G10 | G63 |
| 3386 | G79 | G29 |
| 3387 | G88 | G35 |
| 3388 | G11 | G63 |
| 3389 | G80 | G29 |
| 3390 | G89 | G35 |
| 3391 | G12 | G63 |
| 3392 | G81 | G29 |
| 3393 | G90 | G35 |
| 3394 | G13 | G63 |
| 3395 | G82 | G29 |
| 3396 | G91 | G35 |
| 3397 | G14 | G63 |
| 3398 | G83 | G29 |
| 3399 | G92 | G35 |
| 3400 | G18 | G63 |
| 3401 | G84 | G29 |
| 3402 | G93 | G35 |
| 3403 | G19 | G63 |
| 3404 | G85 | G29 |
| 3405 | G94 | G35 |
| 3406 | G20 | G63 |
| 3407 | G86 | G29 |
| 3408 | G95 | G35 |
| 3409 | G21 | G63 |
| 3410 | G87 | G29 |
| 3411 | G96 | G35 |
| 3412 | G22 | G63 |
| 3413 | G88 | G29 |
| 3414 | G97 | G35 |
| 3415 | G23 | G63 |
| 3416 | G89 | G29 |
| 3417 | G98 | G35 |
| 3418 | G24 | G63 |
| 3419 | G90 | G29 |
| 3420 | G99 | G35 |
| 3421 | G25 | G63 |
| 3422 | G91 | G29 |
| 3423 | G100 | G35 |
| 3424 | G63 | G63 |
| 3425 | G92 | G29 |
| 3426 | G101 | G35 |
| 3427 | G65 | G63 |
| 3428 | G93 | G29 |
| 3429 | G102 | G35 |
| 3430 | G66 | G63 |
| 3431 | G94 | G29 |
| 3432 | G1 | G37 |
| 3433 | G76 | G63 |
| 3434 | G95 | G29 |
| 3435 | G2 | G37 |
| 3436 | G77 | G63 |
| 3437 | G96 | G29 |
| 3438 | G3 | G37 |
| 3439 | G78 | G63 |
| 3440 | G97 | G29 |
| 3441 | G4 | G37 |
| 3442 | G79 | G63 |
| 3443 | G98 | G29 |
| 3444 | G5 | G37 |
| 3445 | G80 | G63 |
| 3446 | G99 | G29 |
| 3447 | G6 | G37 |
| 3448 | G81 | G63 |
| 3449 | G100 | G29 |
| 3450 | G7 | G37 |
| 3451 | G82 | G63 |
| 3452 | G101 | G29 |
| 3453 | G8 | G37 |
| 3454 | G83 | G63 |
| 3455 | G102 | G29 |
| 3456 | G9 | G37 |
| 3457 | G84 | G63 |
| 3458 | G1 | G31 |
| 3459 | G10 | G37 |
| 3460 | G85 | G63 |
| 3461 | G2 | G31 |
| 3462 | G11 | G37 |
| 3463 | G86 | G63 |
| 3464 | G3 | G31 |
| 3465 | G12 | G37 |
| 3466 | G87 | G63 |
| 3467 | G4 | G31 |
| 3468 | G13 | G37 |
| 3469 | G88 | G63 |
| 3470 | G5 | G31 |
| 3471 | G14 | G37 |
| 3472 | G89 | G63 |
| 3473 | G6 | G31 |
| 3474 | G18 | G37 |
| 3475 | G90 | G63 |
| 3476 | G7 | G31 |
| 3477 | G19 | G37 |
| 3478 | G91 | G63 |
| 3479 | G8 | G31 |
| 3480 | G20 | G37 |
| 3481 | G92 | G63 |
| 3482 | G9 | G31 |
| 3483 | G21 | G37 |
| 3484 | G93 | G63 |
| 3485 | G10 | G31 |
| 3486 | G22 | G37 |
| 3487 | G94 | G63 |
| 3488 | G11 | G31 |
| 3489 | G23 | G37 |
| 3490 | G95 | G63 |
| 3491 | G12 | G31 |
| 3492 | G24 | G37 |
| 3493 | G96 | G63 |
| 3494 | G13 | G31 |
| 3495 | G25 | G37 |
| 3496 | G97 | G63 |
| 3497 | G14 | G31 |
| 3498 | G37 | G37 |
| 3499 | G98 | G63 |
| 3500 | G18 | G31 |
| 3501 | G53 | G37 |
| 3502 | G99 | G63 |
| 3503 | G19 | G31 |
| 3504 | G55 | G37 |
| 3505 | G100 | G63 |
| 3506 | G20 | G31 |
| 3507 | G61 | G37 |
| 3508 | G101 | G63 |
| 3509 | G21 | G31 |
| 3510 | G63 | G37 |
| 3511 | G102 | G63 |
| 3512 | G22 | G31 |
| 3513 | G65 | G37 |
| 3514 | G1 | G65 |
| 3515 | G23 | G31 |
| 3516 | G66 | G37 |
| 3517 | G2 | G65 |
| 3518 | G24 | G31 |
| 3519 | G76 | G37 |
| 3520 | G3 | G65 |
| 3521 | G25 | G31 |
| 3522 | G77 | G37 |
| 3523 | G4 | G65 |
| 3524 | G31 | G31 |
| 3525 | G78 | G37 |
| 3526 | G5 | G65 |
| 3527 | G33 | G31 |
| 3528 | G79 | G37 |
| 3529 | G6 | G65 |
| 3530 | G34 | G31 |
| 3531 | G80 | G37 |
| 3532 | G7 | G65 |
| 3533 | G35 | G31 |
| 3534 | G81 | G37 |
| 3535 | G8 | G65 |
| 3536 | G37 | G31 |
| 3537 | G82 | G37 |
| 3538 | G9 | G65 |
| 3539 | G53 | G31 |
| 3540 | G83 | G37 |
| 3541 | G10 | G65 |
| 3542 | G55 | G31 |
| 3543 | G84 | G37 |
| 3544 | G11 | G65 |
| 3545 | G61 | G31 |
| 3546 | G85 | G37 |
| 3547 | G12 | G65 |
| 3548 | G63 | G31 |
| 3549 | G86 | G37 |
| 3550 | G13 | G65 |
| 3551 | G65 | G31 |
| 3552 | G87 | G37 |
| 3553 | G14 | G65 |
| 3554 | G66 | G31 |
| 3555 | G88 | G37 |
| 3556 | G18 | G65 |
| 3557 | G76 | G31 |
| 3558 | G89 | G37 |
| 3559 | G19 | G65 |
| 3560 | G77 | G31 |
| 3561 | G90 | G37 |
| 3562 | G20 | G65 |
| 3563 | G78 | G31 |
| 3564 | G91 | G37 |
| 3565 | G21 | G65 |
| 3566 | G79 | G31 |
| 3567 | G92 | G37 |
| 3568 | G22 | G65 |
| 3569 | G80 | G31 |
| 3570 | G93 | G37 |
| 3571 | G23 | G65 |
| 3572 | G81 | G31 |
| 3573 | G94 | G37 |
| 3574 | G24 | G65 |
| 3575 | G82 | G31 |
| 3576 | G95 | G37 |
| 3577 | G25 | G65 |
| 3578 | G83 | G31 |
| 3579 | G96 | G37 |
| 3580 | G65 | G65 |
| 3581 | G84 | G31 |
| 3582 | G97 | G37 |
| 3583 | G66 | G65 |
| 3584 | G85 | G31 |
| 3585 | G98 | G37 |
| 3586 | G76 | G65 |
| 3587 | G86 | G31 |
| 3588 | G99 | G37 |
| 3589 | G77 | G65 |
| 3590 | G87 | G31 |
| 3591 | G100 | G37 |
| 3592 | G78 | G65 |
| 3593 | G88 | G31 |
| 3594 | G101 | G37 |
| 3595 | G79 | G65 |
| 3596 | G89 | G31 |
| 3597 | G102 | G37 |
| 3598 | G80 | G65 |
| 3599 | G90 | G31 |
| 3600 | G1 | G53 |
| 3601 | G81 | G65 |
| 3602 | G91 | G31 |
| 3603 | G2 | G53 |
| 3604 | G82 | G65 |
| 3605 | G92 | G31 |
| 3606 | G3 | G53 |
| 3607 | G83 | G65 |
| 3608 | G93 | G31 |
| 3609 | G4 | G53 |
| 3610 | G84 | G65 |
| 3611 | G94 | G31 |
| 3612 | G5 | G53 |
| 3613 | G85 | G65 |
| 3614 | G95 | G31 |
| 3615 | G6 | G53 |
| 3616 | G86 | G65 |
| 3617 | G96 | G31 |
| 3618 | G7 | G53 |
| 3619 | G87 | G65 |
| 3620 | G97 | G31 |
| 3621 | G8 | G53 |
| 3622 | G88 | G65 |
| 3623 | G98 | G31 |
| 3624 | G9 | G53 |
| 3625 | G89 | G65 |
| 3626 | G99 | G31 |
| 3627 | G10 | G53 |
| 3628 | G90 | G65 |
| 3629 | G100 | G31 |
| 3630 | G11 | G53 |
| 3631 | G91 | G65 |
| 3632 | G101 | G31 |
| 3633 | G12 | G53 |
| 3634 | G92 | G65 |
| 3635 | G102 | G31 |
| 3636 | G13 | G53 |
| 3637 | G93 | G65 |
| 3638 | G1 | G33 |
| 3639 | G14 | G53 |
| 3640 | G94 | G65 |
| 3641 | G2 | G33 |
| 3642 | G18 | G53 |
| 3643 | G95 | G65 |
| 3644 | G3 | G33 |
| 3645 | G19 | G53 |
| 3646 | G96 | G65 |
| 3647 | G4 | G33 |
| 3648 | G20 | G53 |
| 3649 | G97 | G65 |
| 3650 | G5 | G33 |
| 3651 | G21 | G53 |
| 3652 | G98 | G65 |
| 3653 | G6 | G33 |
| 3654 | G22 | G53 |
| 3655 | G99 | G65 |
| 3656 | G7 | G33 |
| 3657 | G23 | G53 |
| 3658 | G100 | G65 |
| 3659 | G8 | G33 |
| 3660 | G24 | G53 |
| 3661 | G101 | G65 |
| 3662 | G9 | G33 |
| 3663 | G25 | G53 |
| 3664 | G102 | G65 |
| 3665 | G10 | G33 |
| 3666 | G53 | G53 |
| 3667 | G1 | G66 |
| 3668 | G11 | G33 |
| 3669 | G55 | G53 |
| 3670 | G2 | G66 |
| 3671 | G12 | G33 |
| 3672 | G61 | G53 |
| 3673 | G3 | G66 |
| 3674 | G13 | G33 |
| 3675 | G63 | G53 |
| 3676 | G4 | G66 |
| 3677 | G14 | G33 |
| 3678 | G65 | G53 |
| 3679 | G5 | G66 |
| 3680 | G18 | G33 |
| 3681 | G66 | G53 |
| 3682 | G6 | G66 |
| 3683 | G19 | G33 |
| 3684 | G76 | G53 |
| 3685 | G7 | G66 |
| 3686 | G20 | G33 |
| 3687 | G77 | G53 |
| 3688 | G8 | G66 |
| 3689 | G21 | G33 |
| 3690 | G78 | G53 |
| 3691 | G9 | G66 |
| 3692 | G22 | G33 |
| 3693 | G79 | G53 |
| 3694 | G10 | G66 |
| 3695 | G23 | G33 |
| 3696 | G80 | G53 |
| 3697 | G11 | G66 |
| 3698 | G24 | G33 |
| 3699 | G81 | G53 |
| 3700 | G12 | G66 |
| 3701 | G25 | G33 |
| 3702 | G82 | G53 |
| 3703 | G13 | G66 |
| 3704 | G33 | G33 |
| 3705 | G83 | G53 |
| 3706 | G14 | G66 |
| 3707 | G34 | G33 |
| 3708 | G84 | G53 |
| 3709 | G18 | G66 |
| 3710 | G35 | G33 |
| 3711 | G85 | G53 |
| 3712 | G19 | G66 |
| 3713 | G37 | G33 |
| 3714 | G86 | G53 |
| 3715 | G20 | G66 |
| 3716 | G53 | G33 |
| 3717 | G87 | G53 |
| 3718 | G21 | G66 |
| 3719 | G55 | G33 |
| 3720 | G88 | G53 |
| 3721 | G22 | G66 |
| 3722 | G61 | G33 |
| 3723 | G89 | G53 |
| 3724 | G23 | G66 |
| 3725 | G63 | G33 |
| 3726 | G90 | G53 |
| 3727 | G24 | G66 |
| 3728 | G65 | G33 |
| 3729 | G91 | G53 |
| 3730 | G25 | G66 |
| 3731 | G66 | G33 |
| 3732 | G92 | G53 |
| 3733 | G66 | G66 |
| 3734 | G76 | G33 |
| 3735 | G93 | G53 |
| 3736 | G76 | G66 |
| 3737 | G77 | G33 |
| 3738 | G94 | G53 |
| 3739 | G77 | G66 |
| 3740 | G78 | G33 |
| 3741 | G95 | G53 |
| 3742 | G78 | G66 |
| 3743 | G79 | G33 |
| 3744 | G96 | G53 |
| 3745 | G79 | G66 |
| 3746 | G80 | G33 |
| 3747 | G97 | G53 |
| 3748 | G80 | G66 |
| 3749 | G81 | G33 |
| 3750 | G98 | G53 |
| 3751 | G81 | G66 |
| 3752 | G82 | G33 |
| 3753 | G99 | G53 |
| 3754 | G82 | G66 |
| 3755 | G83 | G33 |
| 3756 | G100 | G53 |
| 3757 | G83 | G66 |
| 3758 | G84 | G33 |
| 3759 | G101 | G53 |
| 3760 | G84 | G66 |
| 3761 | G85 | G33 |
| 3762 | G102 | G53 |
| 3763 | G85 | G66 |
| 3764 | G86 | G33 |
| 3765 | G1 | G55 |
| 3766 | G86 | G66 |
| 3767 | G87 | G33 |
| 3768 | G2 | G55 |
| 3769 | G87 | G66 |
| 3770 | G88 | G33 |
| 3771 | G3 | G55 |
| 3772 | G88 | G66 |
| 3773 | G89 | G33 |
| 3774 | G4 | G55 |
| 3775 | G89 | G66 |
| 3776 | G90 | G33 |
| 3777 | G5 | G55 |
| 3778 | G90 | G66 |
| 3779 | G91 | G33 |
| 3780 | G6 | G55 |
| 3781 | G91 | G66 |
| 3782 | G92 | G33 |
| 3783 | G7 | G55 |
| 3784 | G92 | G66 |
| 3785 | G93 | G33 |
| 3786 | G8 | G55 |
| 3787 | G93 | G66 |
| 3788 | G94 | G33 |
| 3789 | G9 | G55 |
| 3790 | G94 | G66 |
| 3791 | G95 | G33 |
| 3792 | G10 | G55 |
| 3793 | G95 | G66 |
| 3794 | G96 | G33 |
| 3795 | G11 | G55 |
| 3796 | G96 | G66 |
| 3797 | G97 | G33 |
| 3798 | G12 | G55 |
| 3799 | G97 | G66 |
| 3800 | G98 | G33 |
| 3801 | G13 | G55 |
| 3802 | G98 | G66 |
| 3803 | G99 | G33 |
| 3804 | G14 | G55 |
| 3805 | G99 | G66 |
| 3806 | G100 | G33 |
| 3807 | G18 | G55 |
| 3808 | G100 | G66 |
| 3809 | G101 | G33 |
| 3810 | G19 | G55 |
| 3811 | G101 | G66 |
| 3812 | G102 | G33 |
| 3813 | G20 | G55 |
| 3814 | G102 | G66 |
| 3815 | G1 | G34 |
| 3816 | G21 | G55 |

wherein Compound H1 to Compound H605 have the following specific structures: 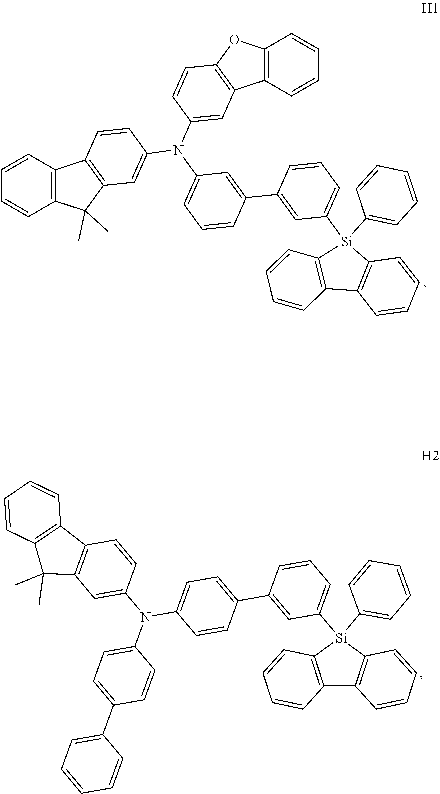 [SMILES: CC1(C)c2ccccc2-c2ccc(N(c3cccc(-c4cccc([Si]5(c6ccccc6)c6ccccc6-c6ccccc65)c4)c3)c3ccc4oc5ccccc5c4c3)cc21 ; CC1(C)c2ccccc2-c2ccc(N(c3ccc(-c4ccccc4)cc3)c3ccc(-c4cccc([Si]5(c6ccccc6)c6ccccc6-c6ccccc65)c4)cc3)cc21] 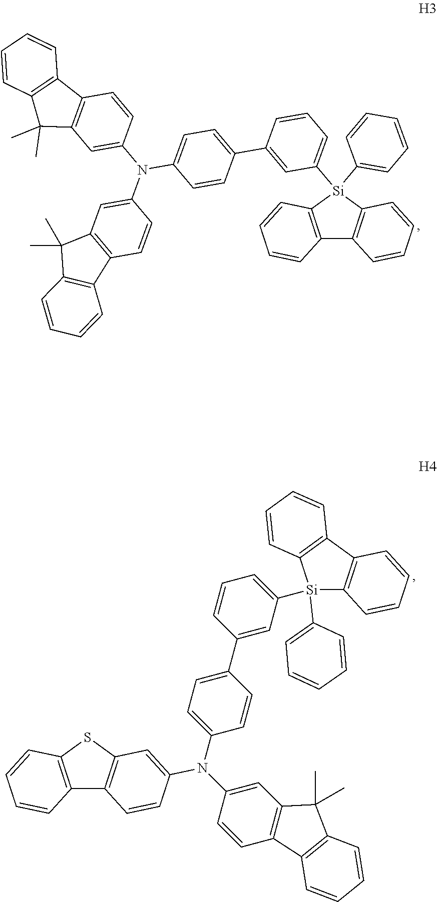 [SMILES: CC1(C)c2ccccc2-c2ccc(N(c3ccc(-c4cccc([Si]5(c6ccccc6)c6ccccc6-c6ccccc65)c4)cc3)c3ccc4c(c3)C(C)(C)c3ccccc3-4)cc21 ; CC1(C)c2ccccc2-c2ccc(N(c3ccc(-c4cccc([Si]5(c6ccccc6)c6ccccc6-c6ccccc65)c4)cc3)c3ccc4c(c3)sc3ccccc34)cc21] 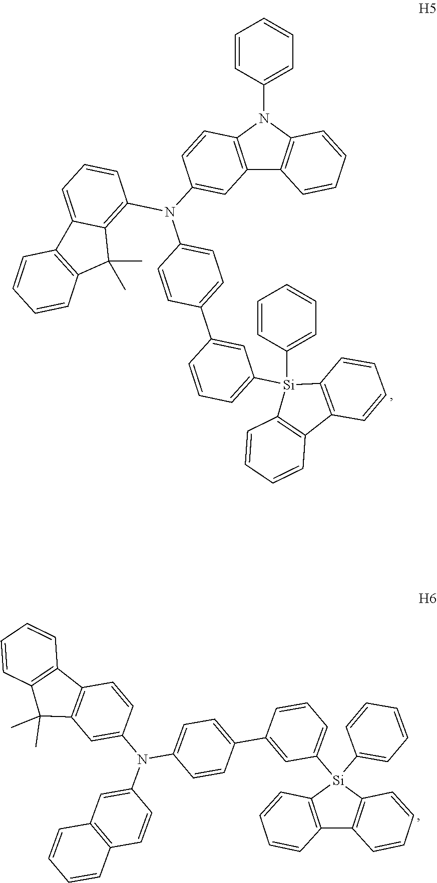 [SMILES: CC1(C)c2ccccc2-c2cccc(N(c3ccc(-c4cccc([Si]5(c6ccccc6)c6ccccc6-c6ccccc65)c4)cc3)c3ccc4c(c3)c3ccccc3n4-c3ccccc3)c21 ; CC1(C)c2ccccc2-c2ccc(N(c3ccc(-c4cccc([Si]5(c6ccccc6)c6ccccc6-c6ccccc65)c4)cc3)c3ccc4ccccc4c3)cc21] 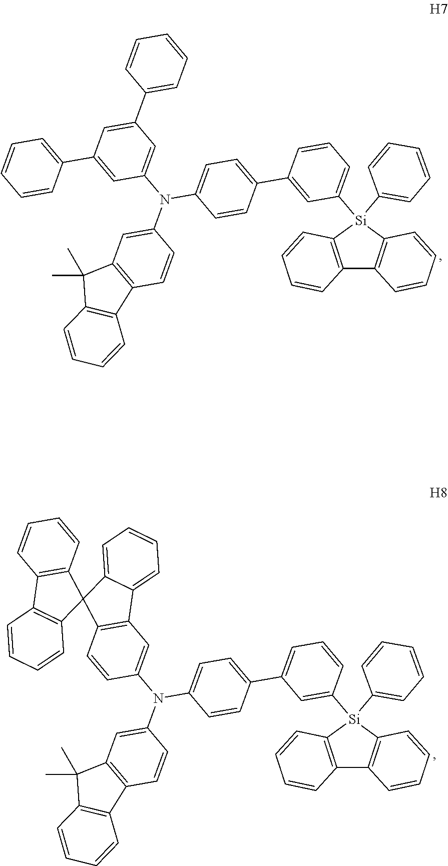 [SMILES: CC1(C)c2ccccc2-c2ccc(N(c3ccc(-c4cccc([Si]5(c6ccccc6)c6ccccc6-c6ccccc65)c4)cc3)c3cc(-c4ccccc4)cc(-c4ccccc4)c3)cc21 ; CC1(C)c2ccccc2-c2ccc(N(c3ccc(-c4cccc([Si]5(c6ccccc6)c6ccccc6-c6ccccc65)c4)cc3)c3ccc4c(c3)-c3ccccc3C43c4ccccc4-c4ccccc43)cc21] 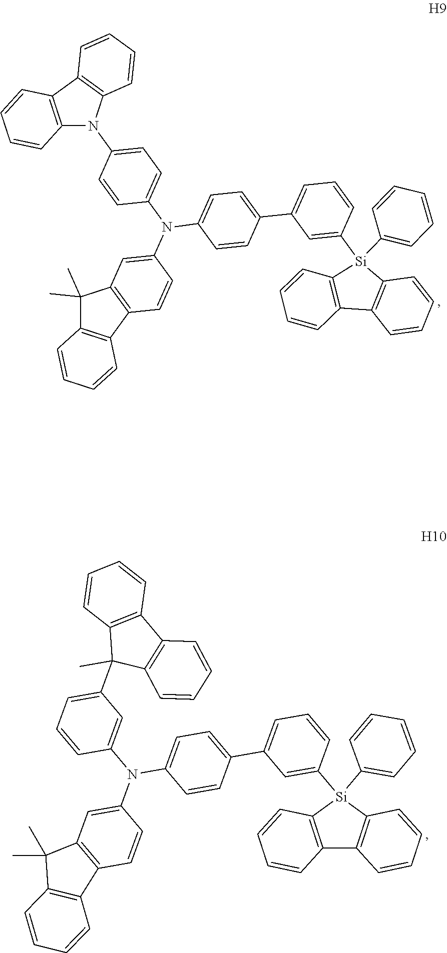 [SMILES: CC1(C)c2ccccc2-c2ccc(N(c3ccc(-c4cccc([Si]5(c6ccccc6)c6ccccc6-c6ccccc65)c4)cc3)c3ccc(-n4c5ccccc5c5ccccc54)cc3)cc21 ; CC1(C)c2ccccc2-c2ccc(N(c3ccc(-c4cccc([Si]5(c6ccccc6)c6ccccc6-c6ccccc65)c4)cc3)c3cccc(C4(C)c5ccccc5-c5ccccc54)c3)cc21] 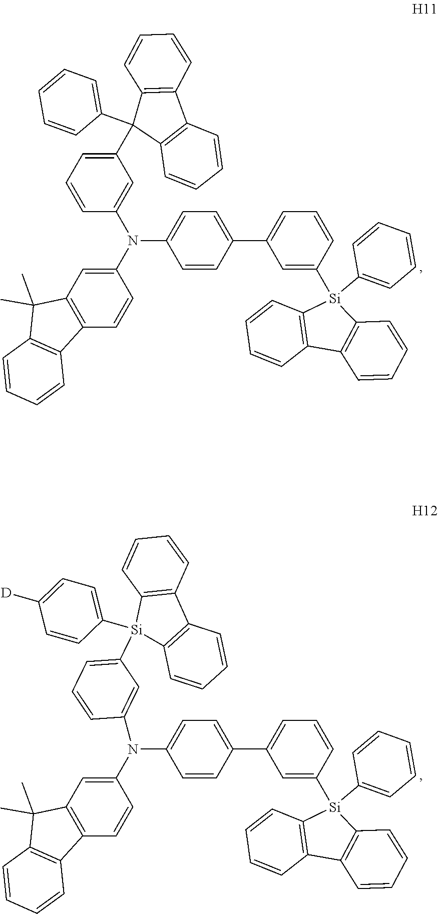 [SMILES: CC1(C)c2ccccc2-c2ccc(N(c3ccc(-c4cccc([Si]5(c6ccccc6)c6ccccc6-c6ccccc65)c4)cc3)c3cccc(C4(c5ccccc5)c5ccccc5-c5ccccc54)c3)cc21 ; [2H]c1ccc([Si]2(c3cccc(N(c4ccc(-c5cccc([Si]6(c7ccccc7)c7ccccc7-c7ccccc76)c5)cc4)c4ccc5c(c4)C(C)(C)c4ccccc4-5)c3)c3ccccc3-c3ccccc32)cc1] 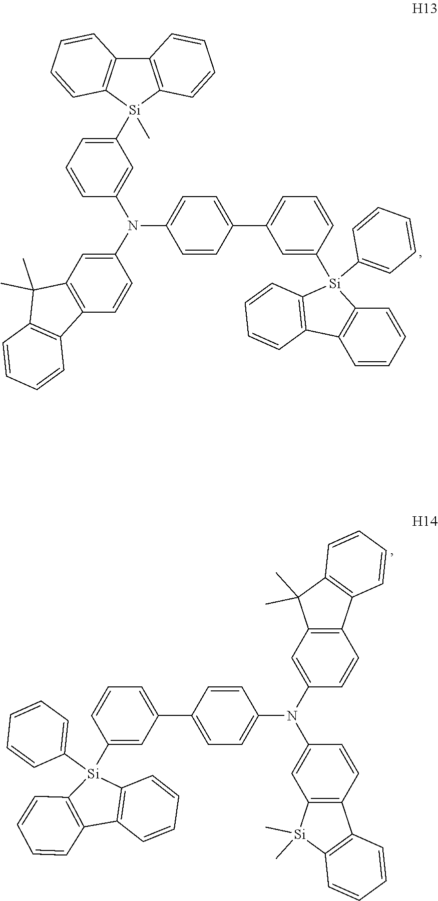 [SMILES: CC1(C)c2ccccc2-c2ccc(N(c3ccc(-c4cccc([Si]5(c6ccccc6)c6ccccc6-c6ccccc65)c4)cc3)c3cccc([Si]4(C)c5ccccc5-c5ccccc54)c3)cc21 ; CC1(C)c2ccccc2-c2ccc(N(c3ccc(-c4cccc([Si]5(c6ccccc6)c6ccccc6-c6ccccc65)c4)cc3)c3ccc4c(c3)[Si](C)(C)c3ccccc3-4)cc21] 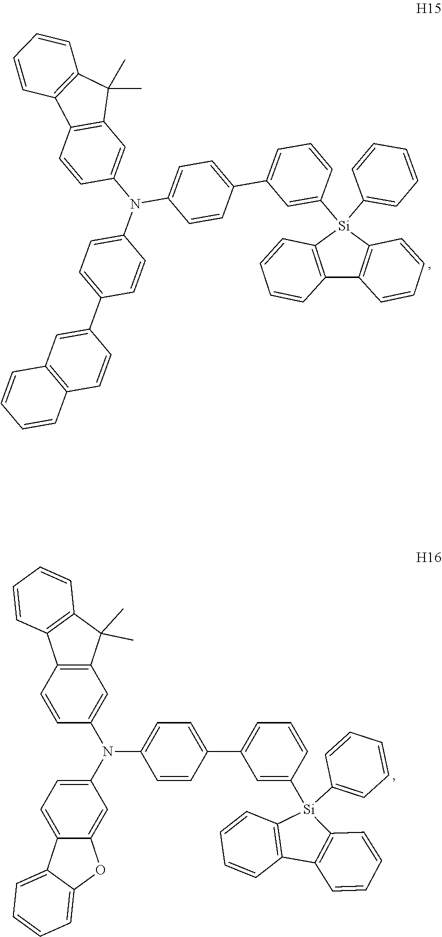 [SMILES: CC1(C)c2ccccc2-c2ccc(N(c3ccc(-c4cccc([Si]5(c6ccccc6)c6ccccc6-c6ccccc65)c4)cc3)c3ccc(-c4ccc5ccccc5c4)cc3)cc21 ; CC1(C)c2ccccc2-c2ccc(N(c3ccc(-c4cccc([Si]5(c6ccccc6)c6ccccc6-c6ccccc65)c4)cc3)c3ccc4c(c3)oc3ccccc34)cc21] 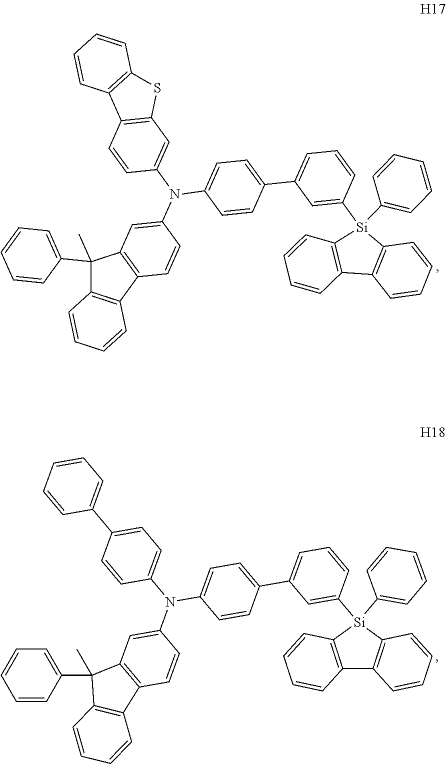 [SMILES: CC1(c2ccccc2)c2ccccc2-c2ccc(N(c3ccc(-c4cccc([Si]5(c6ccccc6)c6ccccc6-c6ccccc65)c4)cc3)c3ccc4c(c3)sc3ccccc34)cc21 ; CC1(c2ccccc2)c2ccccc2-c2ccc(N(c3ccc(-c4ccccc4)cc3)c3ccc(-c4cccc([Si]5(c6ccccc6)c6ccccc6-c6ccccc65)c4)cc3)cc21] 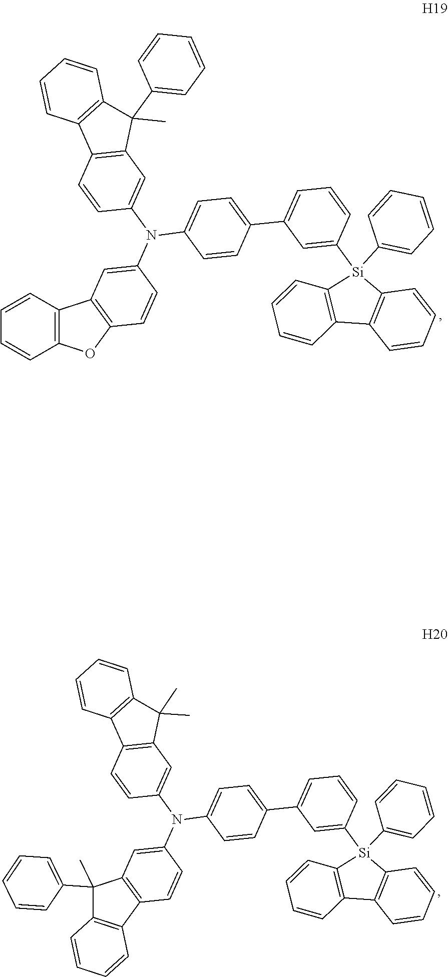 [SMILES: CC1(c2ccccc2)c2ccccc2-c2ccc(N(c3ccc(-c4cccc([Si]5(c6ccccc6)c6ccccc6-c6ccccc65)c4)cc3)c3ccc4oc5ccccc5c4c3)cc21 ; CC1(C)c2ccccc2-c2ccc(N(c3ccc(-c4cccc([Si]5(c6ccccc6)c6ccccc6-c6ccccc65)c4)cc3)c3ccc4c(c3)C(C)(c3ccccc3)c3ccccc3-4)cc21] 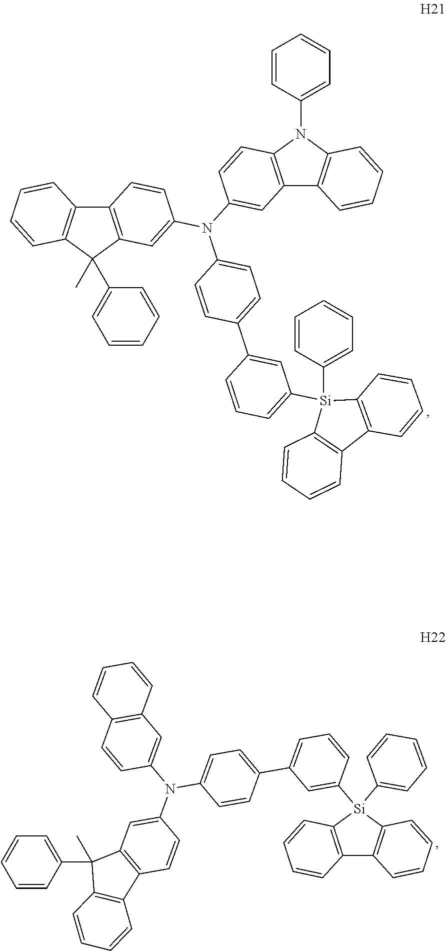 [SMILES: CC1(c2ccccc2)c2ccccc2-c2ccc(N(c3ccc(-c4cccc([Si]5(c6ccccc6)c6ccccc6-c6ccccc65)c4)cc3)c3ccc4c(c3)c3ccccc3n4-c3ccccc3)cc21 ; CC1(c2ccccc2)c2ccccc2-c2ccc(N(c3ccc(-c4cccc([Si]5(c6ccccc6)c6ccccc6-c6ccccc65)c4)cc3)c3ccc4ccccc4c3)cc21] 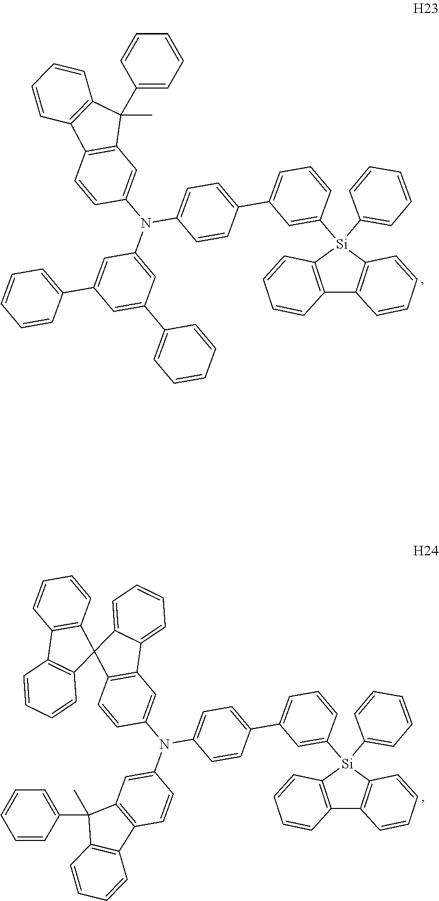 [SMILES: CC1(c2ccccc2)c2ccccc2-c2ccc(N(c3ccc(-c4cccc([Si]5(c6ccccc6)c6ccccc6-c6ccccc65)c4)cc3)c3cc(-c4ccccc4)cc(-c4ccccc4)c3)cc21 ; CC1(c2ccccc2)c2ccccc2-c2ccc(N(c3ccc(-c4cccc([Si]5(c6ccccc6)c6ccccc6-c6ccccc65)c4)cc3)c3ccc4c(c3)-c3ccccc3C43c4ccccc4-c4ccccc43)cc21] 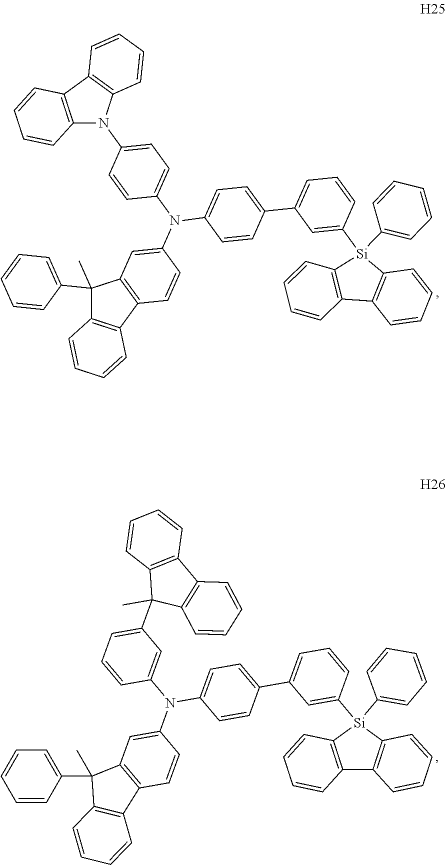 [SMILES: CC1(c2ccccc2)c2ccccc2-c2ccc(N(c3ccc(-c4cccc([Si]5(c6ccccc6)c6ccccc6-c6ccccc65)c4)cc3)c3ccc(-n4c5ccccc5c5ccccc54)cc3)cc21 ; CC1(c2cccc(N(c3ccc(-c4cccc([Si]5(c6ccccc6)c6ccccc6-c6ccccc65)c4)cc3)c3ccc4c(c3)C(C)(c3ccccc3)c3ccccc3-4)c2)c2ccccc2-c2ccccc21] 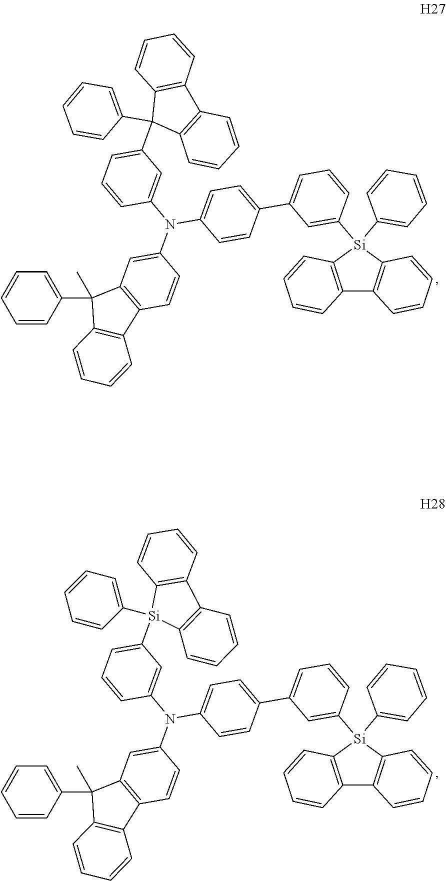 [SMILES: CC1(c2ccccc2)c2ccccc2-c2ccc(N(c3ccc(-c4cccc([Si]5(c6ccccc6)c6ccccc6-c6ccccc65)c4)cc3)c3cccc(C4(c5ccccc5)c5ccccc5-c5ccccc54)c3)cc21 ; CC1(c2ccccc2)c2ccccc2-c2ccc(N(c3ccc(-c4cccc([Si]5(c6ccccc6)c6ccccc6-c6ccccc65)c4)cc3)c3cccc([Si]4(c5ccccc5)c5ccccc5-c5ccccc54)c3)cc21] 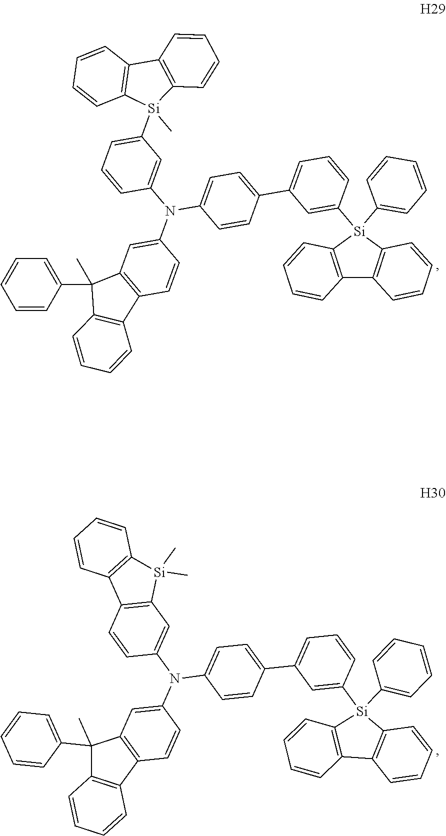 [SMILES: CC1(c2ccccc2)c2ccccc2-c2ccc(N(c3ccc(-c4cccc([Si]5(c6ccccc6)c6ccccc6-c6ccccc65)c4)cc3)c3cccc([Si]4(C)c5ccccc5-c5ccccc54)c3)cc21 ; CC1(c2ccccc2)c2ccccc2-c2ccc(N(c3ccc(-c4cccc([Si]5(c6ccccc6)c6ccccc6-c6ccccc65)c4)cc3)c3ccc4c(c3)[Si](C)(C)c3ccccc3-4)cc21] 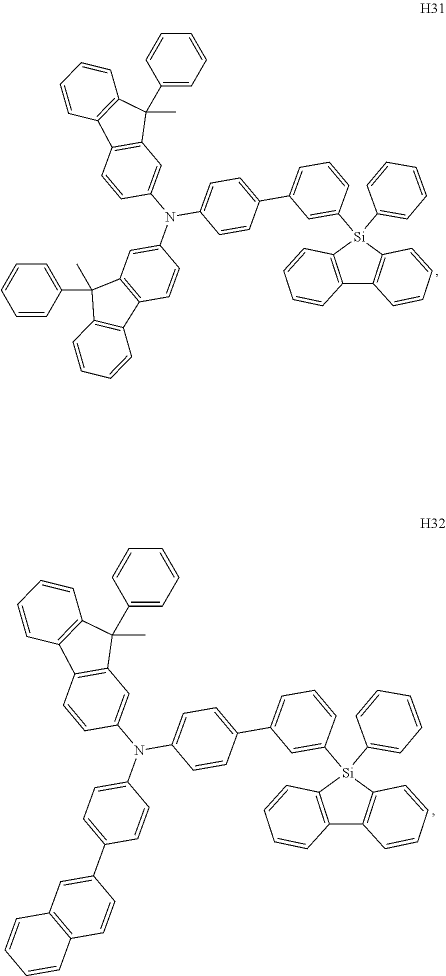 [SMILES: CC1(c2ccccc2)c2ccccc2-c2ccc(N(c3ccc(-c4cccc([Si]5(c6ccccc6)c6ccccc6-c6ccccc65)c4)cc3)c3ccc4c(c3)C(C)(c3ccccc3)c3ccccc3-4)cc21 ; CC1(c2ccccc2)c2ccccc2-c2ccc(N(c3ccc(-c4cccc([Si]5(c6ccccc6)c6ccccc6-c6ccccc65)c4)cc3)c3ccc(-c4ccc5ccccc5c4)cc3)cc21] 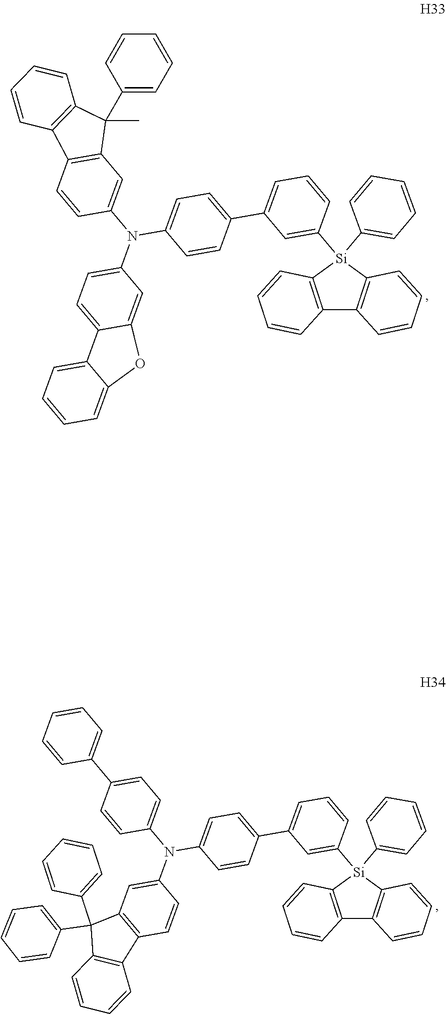 [SMILES: CC1(c2ccccc2)c2ccccc2-c2ccc(N(c3ccc(-c4cccc([Si]5(c6ccccc6)c6ccccc6-c6ccccc65)c4)cc3)c3ccc4c(c3)oc3ccccc34)cc21 ; c1ccc(-c2ccc(N(c3ccc(-c4cccc([Si]5(c6ccccc6)c6ccccc6-c6ccccc65)c4)cc3)c3ccc4c(c3)C(c3ccccc3)(c3ccccc3)c3ccccc3-4)cc2)cc1] 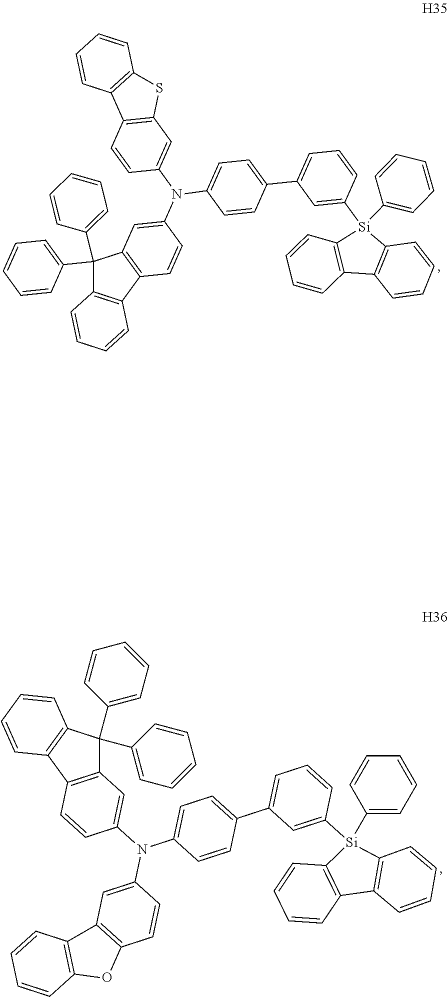 [SMILES: c1ccc(C2(c3ccccc3)c3ccccc3-c3ccc(N(c4ccc(-c5cccc([Si]6(c7ccccc7)c7ccccc7-c7ccccc76)c5)cc4)c4ccc5c(c4)sc4ccccc45)cc32)cc1 ; c1ccc(C2(c3ccccc3)c3ccccc3-c3ccc(N(c4ccc(-c5cccc([Si]6(c7ccccc7)c7ccccc7-c7ccccc76)c5)cc4)c4ccc5oc6ccccc6c5c4)cc32)cc1] 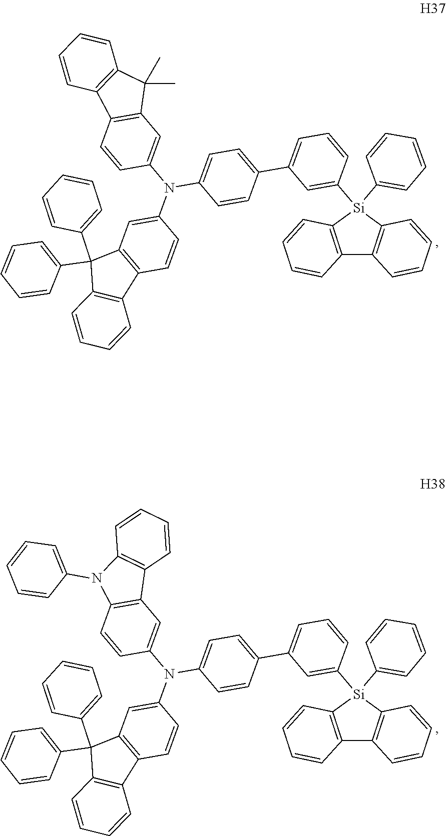 [SMILES: CC1(C)c2ccccc2-c2ccc(N(c3ccc(-c4cccc([Si]5(c6ccccc6)c6ccccc6-c6ccccc65)c4)cc3)c3ccc4c(c3)C(c3ccccc3)(c3ccccc3)c3ccccc3-4)cc21 ; c1ccc(-n2c3ccccc3c3cc(N(c4ccc(-c5cccc([Si]6(c7ccccc7)c7ccccc7-c7ccccc76)c5)cc4)c4ccc5c(c4)C(c4ccccc4)(c4ccccc4)c4ccccc4-5)ccc32)cc1] 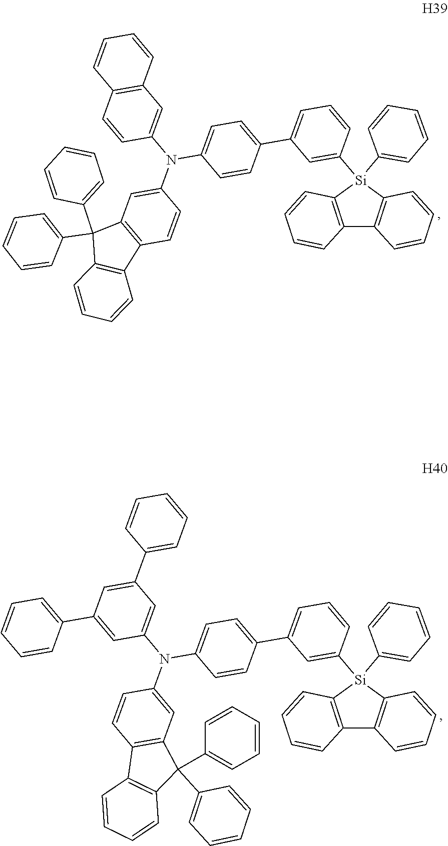 [SMILES: c1ccc(C2(c3ccccc3)c3ccccc3-c3ccc(N(c4ccc(-c5cccc([Si]6(c7ccccc7)c7ccccc7-c7ccccc76)c5)cc4)c4ccc5ccccc5c4)cc32)cc1 ; c1ccc(-c2cc(-c3ccccc3)cc(N(c3ccc(-c4cccc([Si]5(c6ccccc6)c6ccccc6-c6ccccc65)c4)cc3)c3ccc4c(c3)C(c3ccccc3)(c3ccccc3)c3ccccc3-4)c2)cc1] 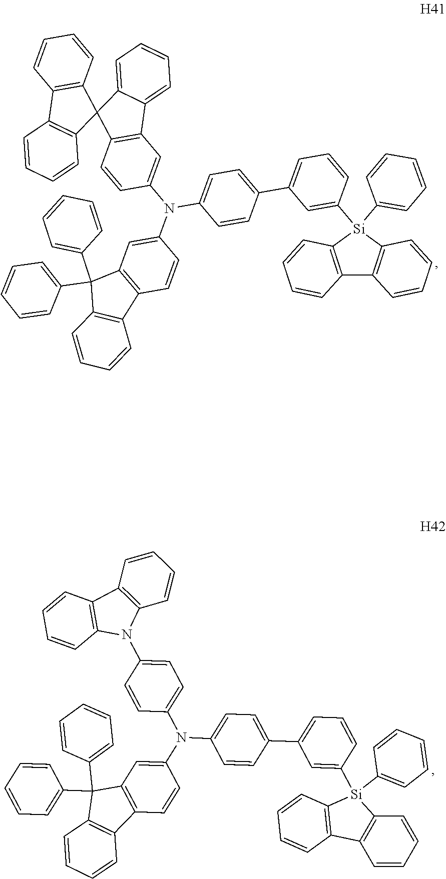 [SMILES: c1ccc(C2(c3ccccc3)c3ccccc3-c3ccc(N(c4ccc(-c5cccc([Si]6(c7ccccc7)c7ccccc7-c7ccccc76)c5)cc4)c4ccc5c(c4)-c4ccccc4C54c5ccccc5-c5ccccc54)cc32)cc1 ; c1ccc(C2(c3ccccc3)c3ccccc3-c3ccc(N(c4ccc(-c5cccc([Si]6(c7ccccc7)c7ccccc7-c7ccccc76)c5)cc4)c4ccc(-n5c6ccccc6c6ccccc65)cc4)cc32)cc1] 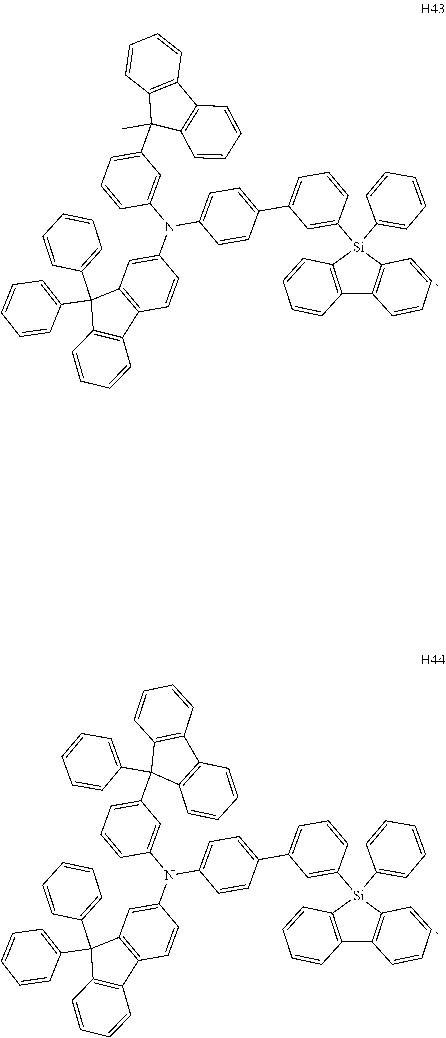 [SMILES: CC1(c2cccc(N(c3ccc(-c4cccc([Si]5(c6ccccc6)c6ccccc6-c6ccccc65)c4)cc3)c3ccc4c(c3)C(c3ccccc3)(c3ccccc3)c3ccccc3-4)c2)c2ccccc2-c2ccccc21 ; c1ccc(C2(c3cccc(N(c4ccc(-c5cccc([Si]6(c7ccccc7)c7ccccc7-c7ccccc76)c5)cc4)c4ccc5c(c4)C(c4ccccc4)(c4ccccc4)c4ccccc4-5)c3)c3ccccc3-c3ccccc32)cc1] 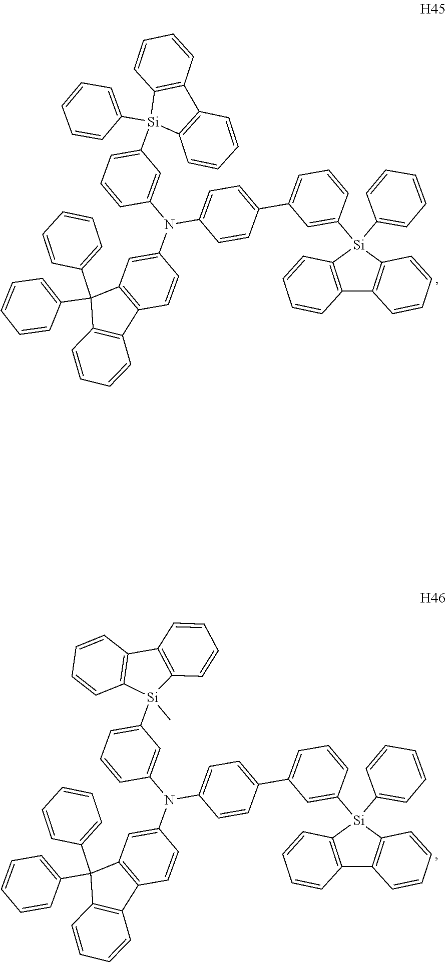 [SMILES: c1ccc(C2(c3ccccc3)c3ccccc3-c3ccc(N(c4ccc(-c5cccc([Si]6(c7ccccc7)c7ccccc7-c7ccccc76)c5)cc4)c4cccc([Si]5(c6ccccc6)c6ccccc6-c6ccccc65)c4)cc32)cc1 ; C[Si]1(c2cccc(N(c3ccc(-c4cccc([Si]5(c6ccccc6)c6ccccc6-c6ccccc65)c4)cc3)c3ccc4c(c3)C(c3ccccc3)(c3ccccc3)c3ccccc3-4)c2)c2ccccc2-c2ccccc21] 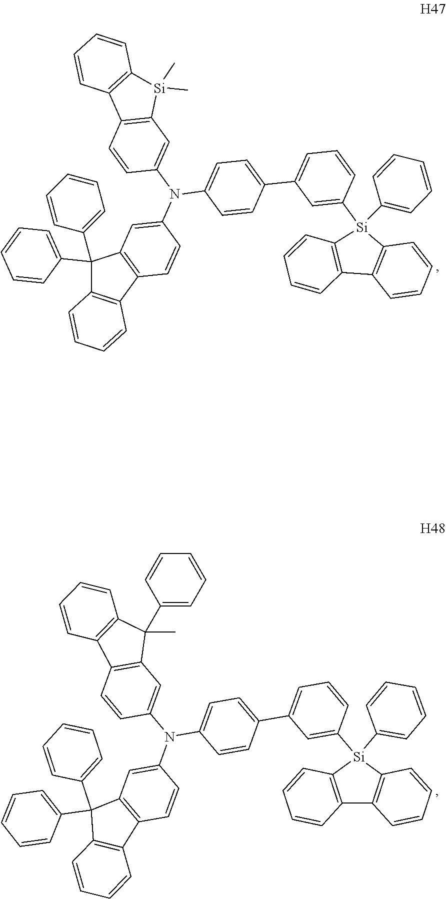 [SMILES: C[Si]1(C)c2ccccc2-c2ccc(N(c3ccc(-c4cccc([Si]5(c6ccccc6)c6ccccc6-c6ccccc65)c4)cc3)c3ccc4c(c3)C(c3ccccc3)(c3ccccc3)c3ccccc3-4)cc21 ; CC1(c2ccccc2)c2ccccc2-c2ccc(N(c3ccc(-c4cccc([Si]5(c6ccccc6)c6ccccc6-c6ccccc65)c4)cc3)c3ccc4c(c3)C(c3ccccc3)(c3ccccc3)c3ccccc3-4)cc21] 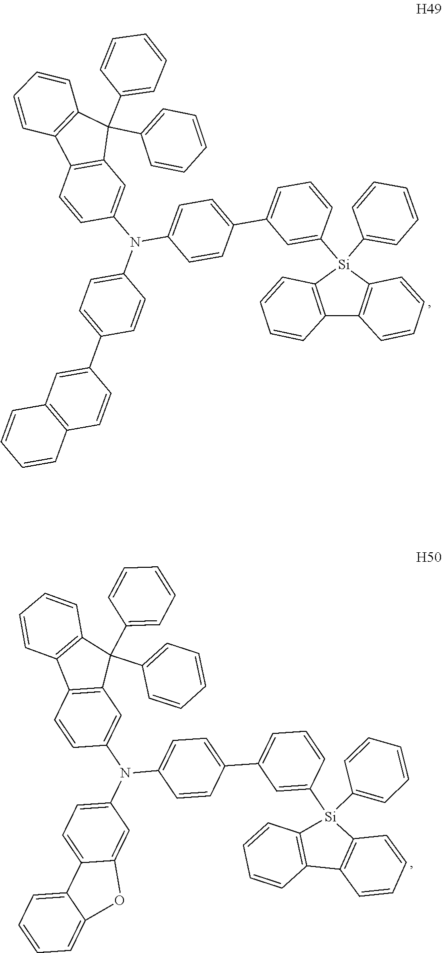 [SMILES: c1ccc(C2(c3ccccc3)c3ccccc3-c3ccc(N(c4ccc(-c5cccc([Si]6(c7ccccc7)c7ccccc7-c7ccccc76)c5)cc4)c4ccc(-c5ccc6ccccc6c5)cc4)cc32)cc1 ; c1ccc(C2(c3ccccc3)c3ccccc3-c3ccc(N(c4ccc(-c5cccc([Si]6(c7ccccc7)c7ccccc7-c7ccccc76)c5)cc4)c4ccc5c(c4)oc4ccccc45)cc32)cc1] 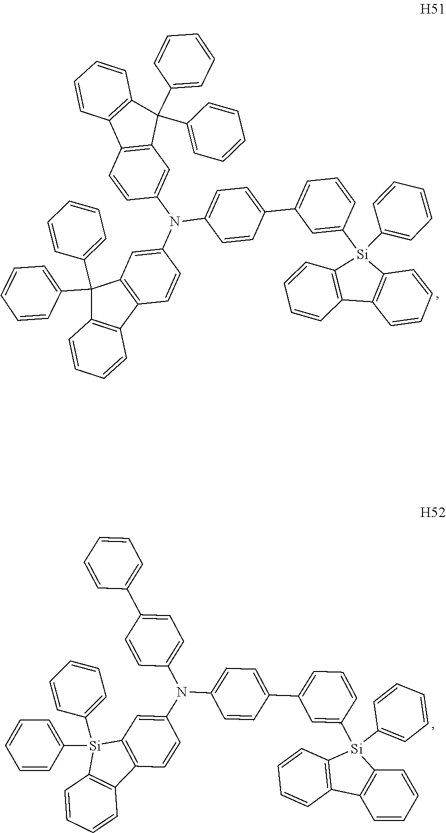 [SMILES: c1ccc(C2(c3ccccc3)c3ccccc3-c3ccc(N(c4ccc(-c5cccc([Si]6(c7ccccc7)c7ccccc7-c7ccccc76)c5)cc4)c4ccc5c(c4)C(c4ccccc4)(c4ccccc4)c4ccccc4-5)cc32)cc1 ; c1ccc(-c2ccc(N(c3ccc(-c4cccc([Si]5(c6ccccc6)c6ccccc6-c6ccccc65)c4)cc3)c3ccc4c(c3)[Si](c3ccccc3)(c3ccccc3)c3ccccc3-4)cc2)cc1] 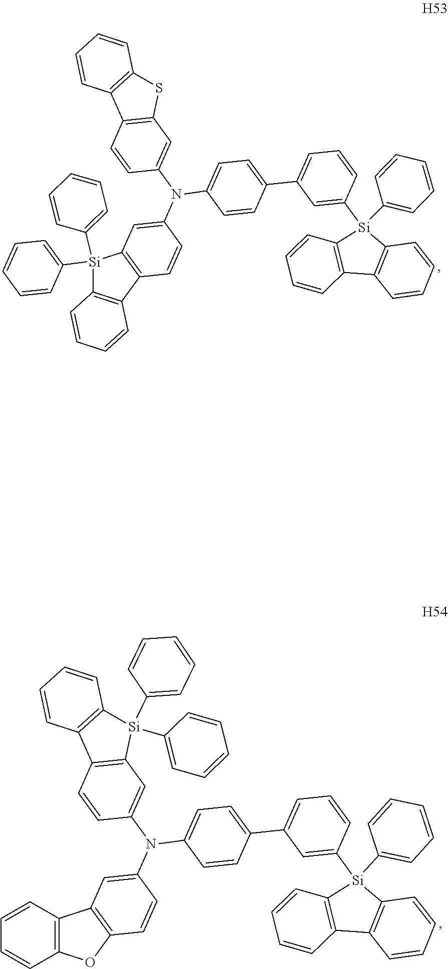 [SMILES: c1ccc([Si]2(c3cccc(-c4ccc(N(c5ccc6c(c5)[Si](c5ccccc5)(c5ccccc5)c5ccccc5-6)c5ccc6c(c5)sc5ccccc56)cc4)c3)c3ccccc3-c3ccccc32)cc1 ; c1ccc([Si]2(c3cccc(-c4ccc(N(c5ccc6c(c5)[Si](c5ccccc5)(c5ccccc5)c5ccccc5-6)c5ccc6oc7ccccc7c6c5)cc4)c3)c3ccccc3-c3ccccc32)cc1] 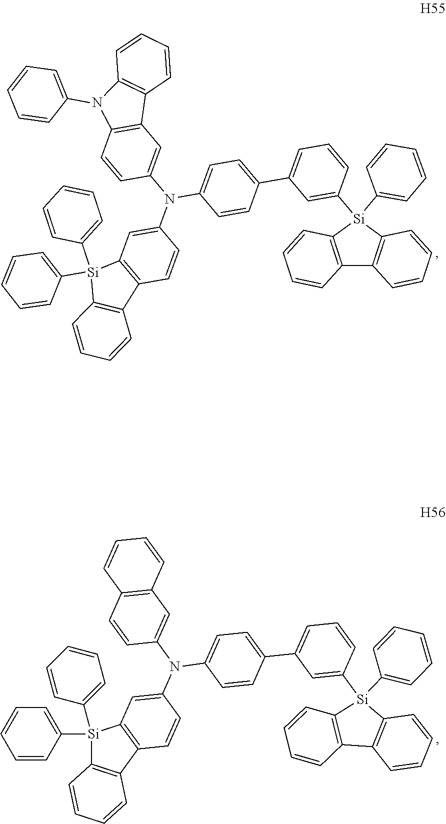 [SMILES: c1ccc(-n2c3ccccc3c3cc(N(c4ccc(-c5cccc([Si]6(c7ccccc7)c7ccccc7-c7ccccc76)c5)cc4)c4ccc5c(c4)[Si](c4ccccc4)(c4ccccc4)c4ccccc4-5)ccc32)cc1 ; c1ccc([Si]2(c3cccc(-c4ccc(N(c5ccc6c(c5)[Si](c5ccccc5)(c5ccccc5)c5ccccc5-6)c5ccc6ccccc6c5)cc4)c3)c3ccccc3-c3ccccc32)cc1] 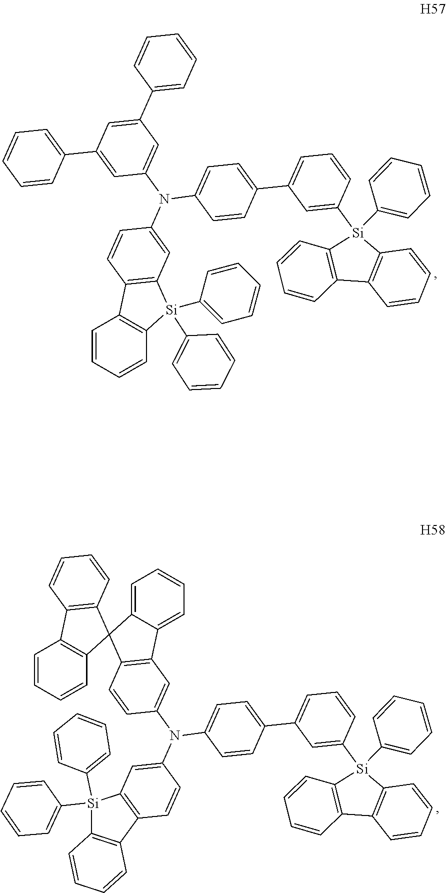 [SMILES: c1ccc(-c2cc(-c3ccccc3)cc(N(c3ccc(-c4cccc([Si]5(c6ccccc6)c6ccccc6-c6ccccc65)c4)cc3)c3ccc4c(c3)[Si](c3ccccc3)(c3ccccc3)c3ccccc3-4)c2)cc1 ; c1ccc([Si]2(c3cccc(-c4ccc(N(c5ccc6c(c5)-c5ccccc5C65c6ccccc6-c6ccccc65)c5ccc6c(c5)[Si](c5ccccc5)(c5ccccc5)c5ccccc5-6)cc4)c3)c3ccccc3-c3ccccc32)cc1] 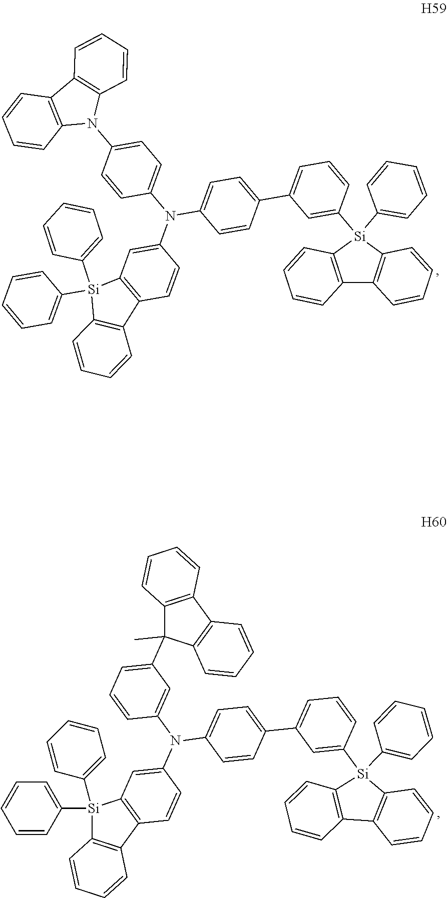 [SMILES: c1ccc([Si]2(c3cccc(-c4ccc(N(c5ccc(-n6c7ccccc7c7ccccc76)cc5)c5ccc6c(c5)[Si](c5ccccc5)(c5ccccc5)c5ccccc5-6)cc4)c3)c3ccccc3-c3ccccc32)cc1 ; CC1(c2cccc(N(c3ccc(-c4cccc([Si]5(c6ccccc6)c6ccccc6-c6ccccc65)c4)cc3)c3ccc4c(c3)[Si](c3ccccc3)(c3ccccc3)c3ccccc3-4)c2)c2ccccc2-c2ccccc21] 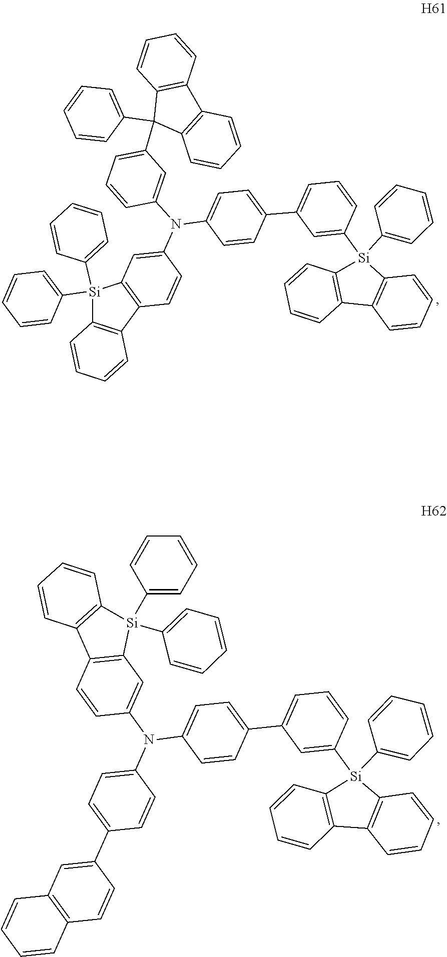 [SMILES: c1ccc(C2(c3cccc(N(c4ccc(-c5cccc([Si]6(c7ccccc7)c7ccccc7-c7ccccc76)c5)cc4)c4ccc5c(c4)[Si](c4ccccc4)(c4ccccc4)c4ccccc4-5)c3)c3ccccc3-c3ccccc32)cc1 ; c1ccc([Si]2(c3cccc(-c4ccc(N(c5ccc(-c6ccc7ccccc7c6)cc5)c5ccc6c(c5)[Si](c5ccccc5)(c5ccccc5)c5ccccc5-6)cc4)c3)c3ccccc3-c3ccccc32)cc1] 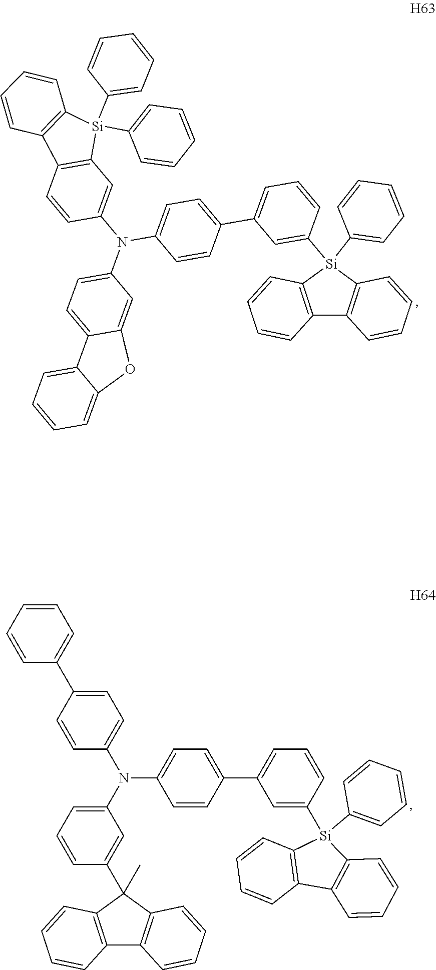 [SMILES: c1ccc([Si]2(c3cccc(-c4ccc(N(c5ccc6c(c5)[Si](c5ccccc5)(c5ccccc5)c5ccccc5-6)c5ccc6c(c5)oc5ccccc56)cc4)c3)c3ccccc3-c3ccccc32)cc1 ; CC1(c2cccc(N(c3ccc(-c4ccccc4)cc3)c3ccc(-c4cccc([Si]5(c6ccccc6)c6ccccc6-c6ccccc65)c4)cc3)c2)c2ccccc2-c2ccccc21] 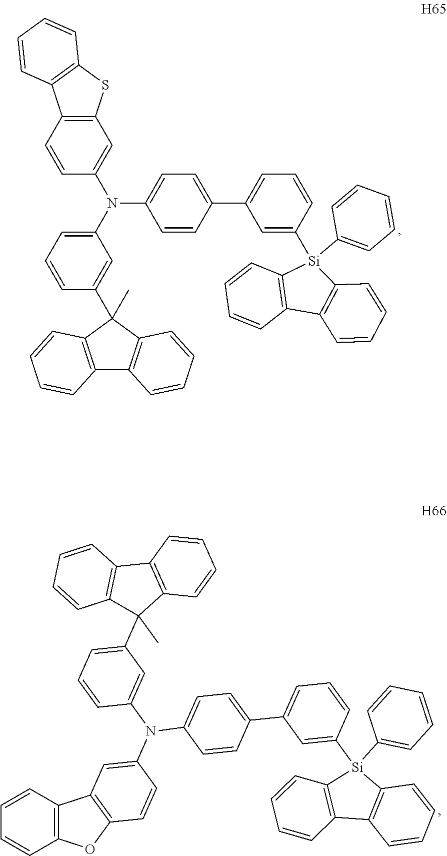 [SMILES: CC1(c2cccc(N(c3ccc(-c4cccc([Si]5(c6ccccc6)c6ccccc6-c6ccccc65)c4)cc3)c3ccc4c(c3)sc3ccccc34)c2)c2ccccc2-c2ccccc21 ; CC1(c2cccc(N(c3ccc(-c4cccc([Si]5(c6ccccc6)c6ccccc6-c6ccccc65)c4)cc3)c3ccc4oc5ccccc5c4c3)c2)c2ccccc2-c2ccccc21] 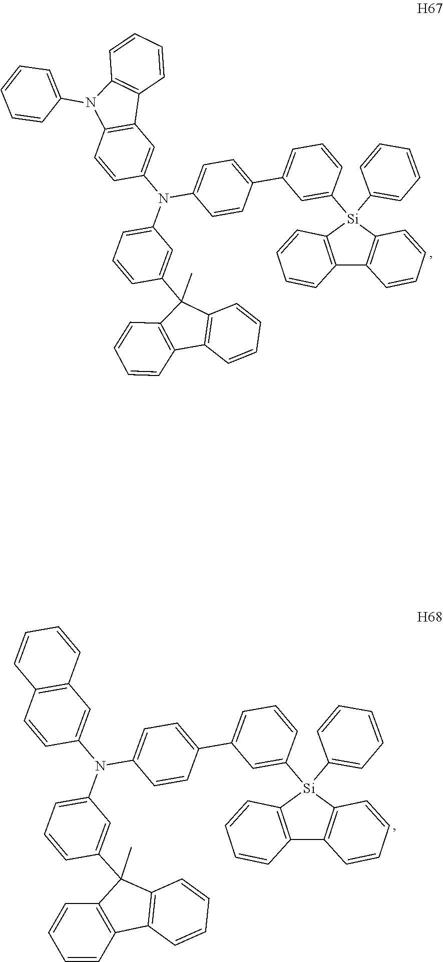 [SMILES: CC1(c2cccc(N(c3ccc(-c4cccc([Si]5(c6ccccc6)c6ccccc6-c6ccccc65)c4)cc3)c3ccc4c(c3)c3ccccc3n4-c3ccccc3)c2)c2ccccc2-c2ccccc21 ; CC1(c2cccc(N(c3ccc(-c4cccc([Si]5(c6ccccc6)c6ccccc6-c6ccccc65)c4)cc3)c3ccc4ccccc4c3)c2)c2ccccc2-c2ccccc21] 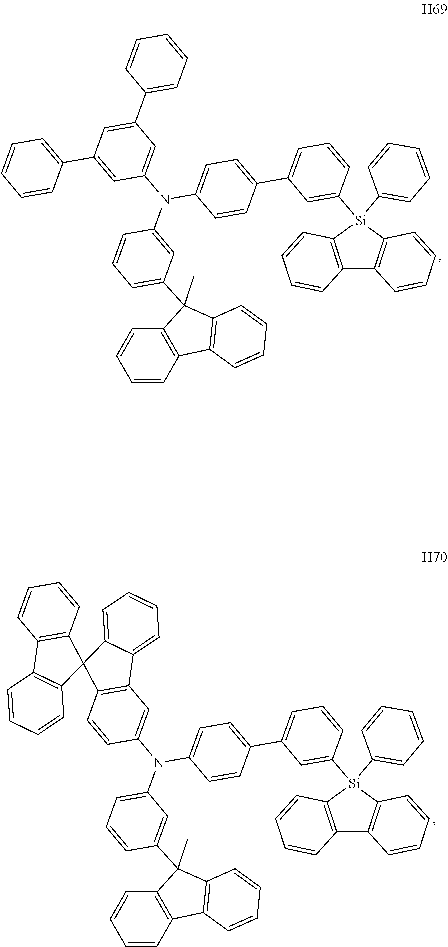 [SMILES: CC1(c2cccc(N(c3ccc(-c4cccc([Si]5(c6ccccc6)c6ccccc6-c6ccccc65)c4)cc3)c3cc(-c4ccccc4)cc(-c4ccccc4)c3)c2)c2ccccc2-c2ccccc21 ; CC1(c2cccc(N(c3ccc(-c4cccc([Si]5(c6ccccc6)c6ccccc6-c6ccccc65)c4)cc3)c3ccc4c(c3)-c3ccccc3C43c4ccccc4-c4ccccc43)c2)c2ccccc2-c2ccccc21] 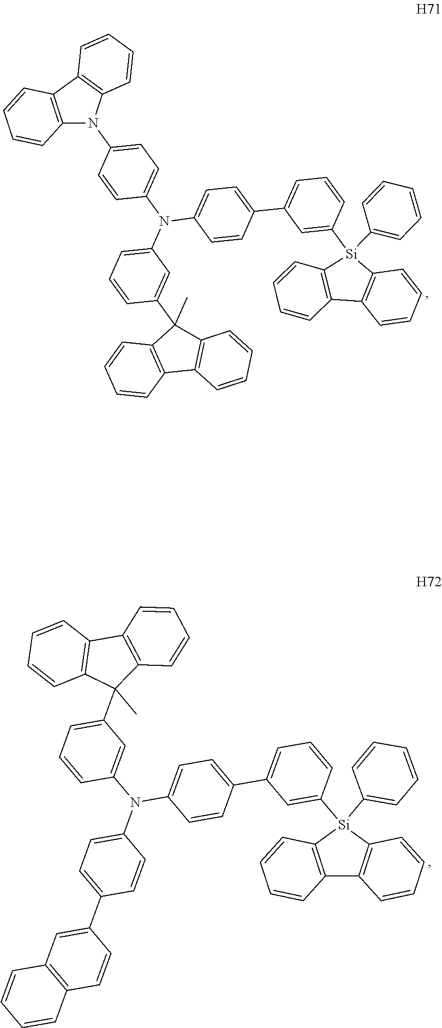 [SMILES: CC1(c2cccc(N(c3ccc(-c4cccc([Si]5(c6ccccc6)c6ccccc6-c6ccccc65)c4)cc3)c3ccc(-n4c5ccccc5c5ccccc54)cc3)c2)c2ccccc2-c2ccccc21 ; CC1(c2cccc(N(c3ccc(-c4cccc([Si]5(c6ccccc6)c6ccccc6-c6ccccc65)c4)cc3)c3ccc(-c4ccc5ccccc5c4)cc3)c2)c2ccccc2-c2ccccc21] 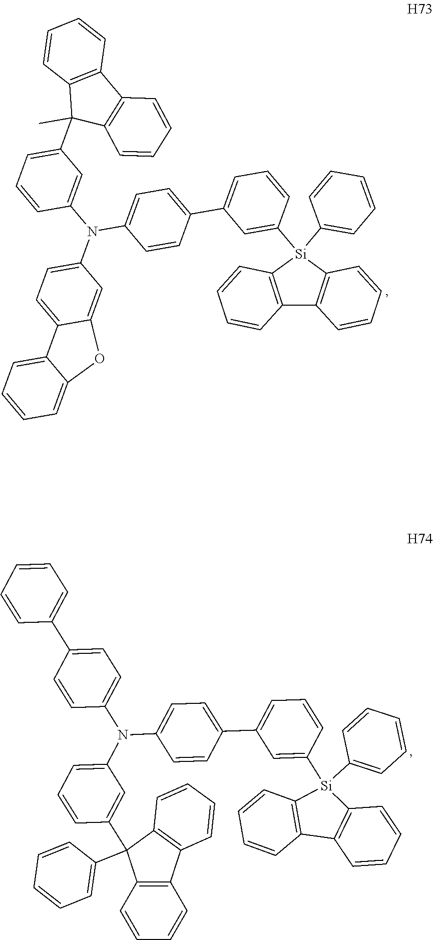 [SMILES: CC1(c2cccc(N(c3ccc(-c4cccc([Si]5(c6ccccc6)c6ccccc6-c6ccccc65)c4)cc3)c3ccc4c(c3)oc3ccccc34)c2)c2ccccc2-c2ccccc21 ; c1ccc(-c2ccc(N(c3ccc(-c4cccc([Si]5(c6ccccc6)c6ccccc6-c6ccccc65)c4)cc3)c3cccc(C4(c5ccccc5)c5ccccc5-c5ccccc54)c3)cc2)cc1] 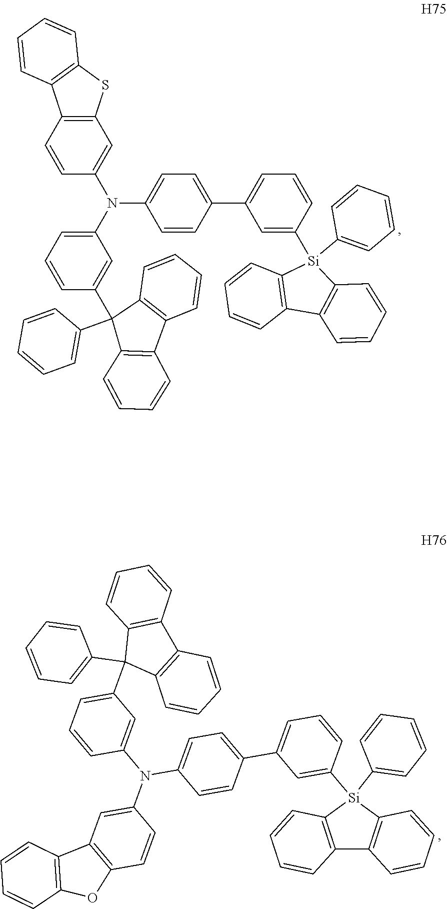 [SMILES: c1ccc(C2(c3cccc(N(c4ccc(-c5cccc([Si]6(c7ccccc7)c7ccccc7-c7ccccc76)c5)cc4)c4ccc5c(c4)sc4ccccc45)c3)c3ccccc3-c3ccccc32)cc1 ; c1ccc(C2(c3cccc(N(c4ccc(-c5cccc([Si]6(c7ccccc7)c7ccccc7-c7ccccc76)c5)cc4)c4ccc5oc6ccccc6c5c4)c3)c3ccccc3-c3ccccc32)cc1] 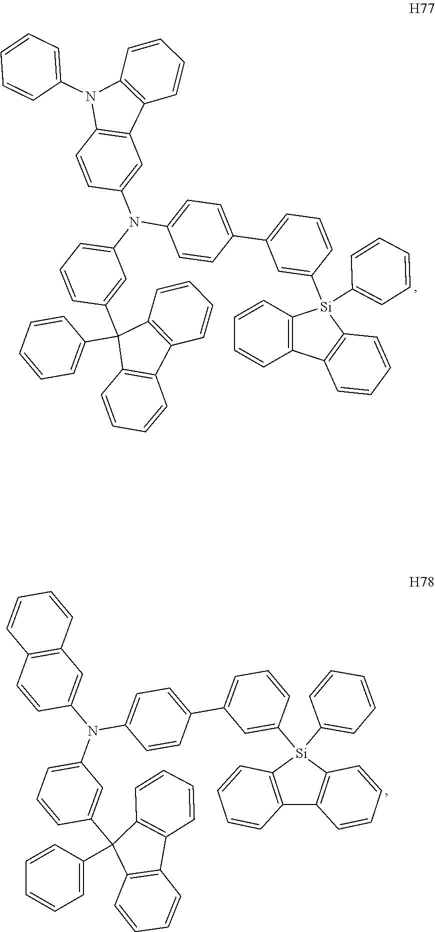 [SMILES: c1ccc(-n2c3ccccc3c3cc(N(c4ccc(-c5cccc([Si]6(c7ccccc7)c7ccccc7-c7ccccc76)c5)cc4)c4cccc(C5(c6ccccc6)c6ccccc6-c6ccccc65)c4)ccc32)cc1 ; c1ccc(C2(c3cccc(N(c4ccc(-c5cccc([Si]6(c7ccccc7)c7ccccc7-c7ccccc76)c5)cc4)c4ccc5ccccc5c4)c3)c3ccccc3-c3ccccc32)cc1] 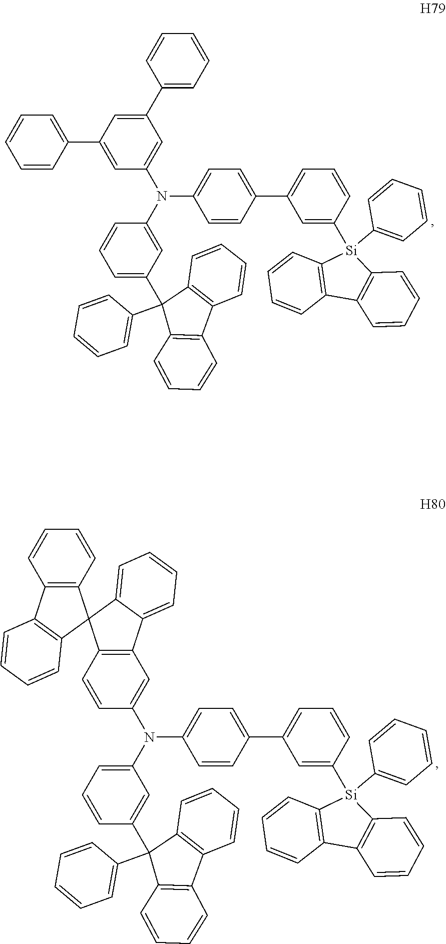 [SMILES: c1ccc(-c2cc(-c3ccccc3)cc(N(c3ccc(-c4cccc([Si]5(c6ccccc6)c6ccccc6-c6ccccc65)c4)cc3)c3cccc(C4(c5ccccc5)c5ccccc5-c5ccccc54)c3)c2)cc1 ; c1ccc(C2(c3cccc(N(c4ccc(-c5cccc([Si]6(c7ccccc7)c7ccccc7-c7ccccc76)c5)cc4)c4ccc5c(c4)-c4ccccc4C54c5ccccc5-c5ccccc54)c3)c3ccccc3-c3ccccc32)cc1] 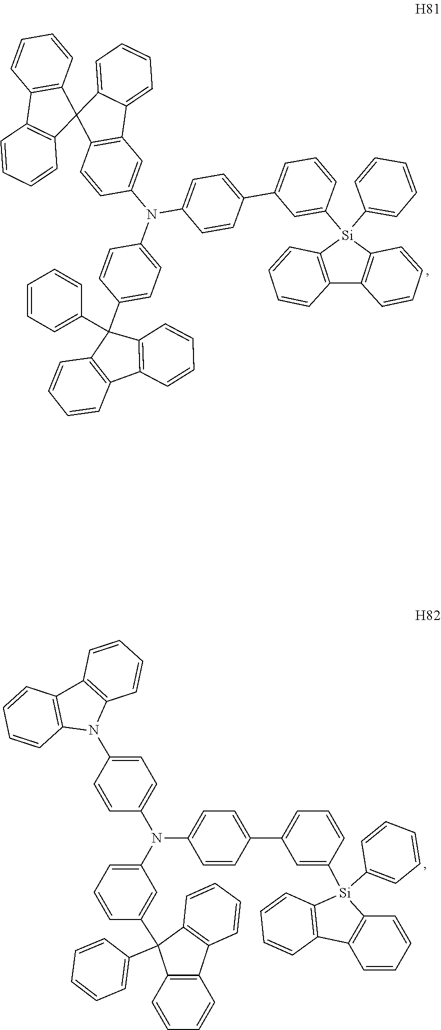 [SMILES: c1ccc(C2(c3ccc(N(c4ccc(-c5cccc([Si]6(c7ccccc7)c7ccccc7-c7ccccc76)c5)cc4)c4ccc5c(c4)-c4ccccc4C54c5ccccc5-c5ccccc54)cc3)c3ccccc3-c3ccccc32)cc1 ; c1ccc(C2(c3cccc(N(c4ccc(-c5cccc([Si]6(c7ccccc7)c7ccccc7-c7ccccc76)c5)cc4)c4ccc(-n5c6ccccc6c6ccccc65)cc4)c3)c3ccccc3-c3ccccc32)cc1] 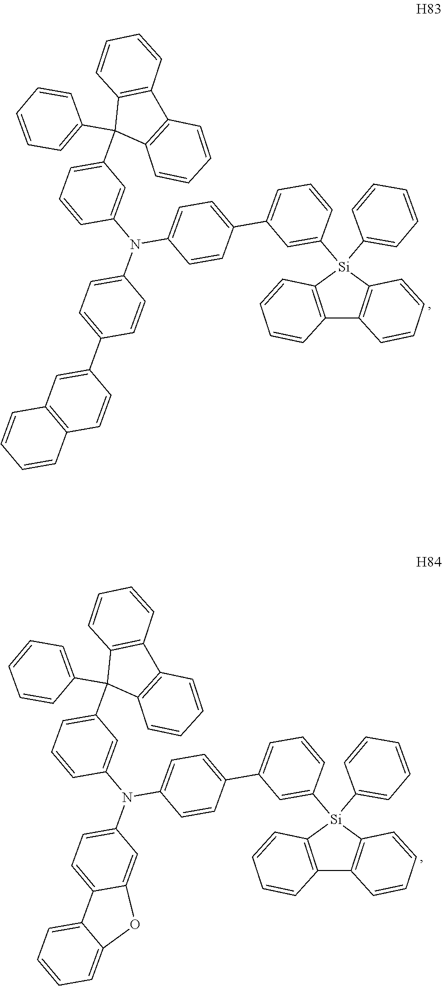 [SMILES: c1ccc(C2(c3cccc(N(c4ccc(-c5cccc([Si]6(c7ccccc7)c7ccccc7-c7ccccc76)c5)cc4)c4ccc(-c5ccc6ccccc6c5)cc4)c3)c3ccccc3-c3ccccc32)cc1 ; c1ccc(C2(c3cccc(N(c4ccc(-c5cccc([Si]6(c7ccccc7)c7ccccc7-c7ccccc76)c5)cc4)c4ccc5c(c4)oc4ccccc45)c3)c3ccccc3-c3ccccc32)cc1] 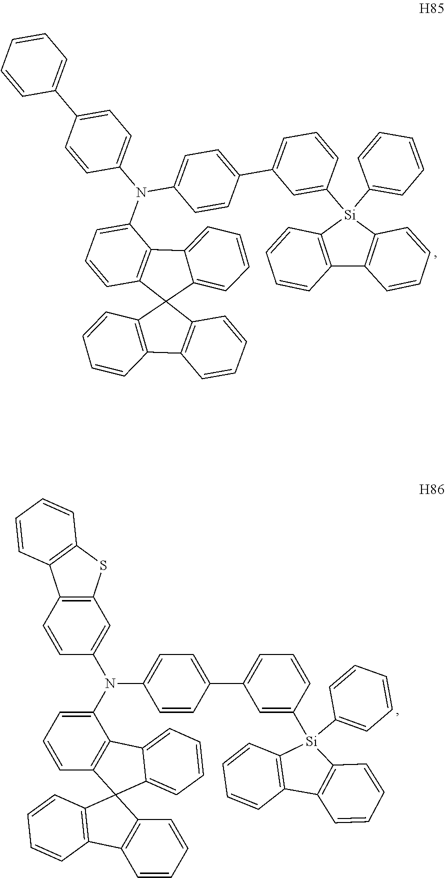 [SMILES: c1ccc(-c2ccc(N(c3ccc(-c4cccc([Si]5(c6ccccc6)c6ccccc6-c6ccccc65)c4)cc3)c3cccc4c3-c3ccccc3C43c4ccccc4-c4ccccc43)cc2)cc1 ; c1ccc([Si]2(c3cccc(-c4ccc(N(c5ccc6c(c5)sc5ccccc56)c5cccc6c5-c5ccccc5C65c6ccccc6-c6ccccc65)cc4)c3)c3ccccc3-c3ccccc32)cc1] 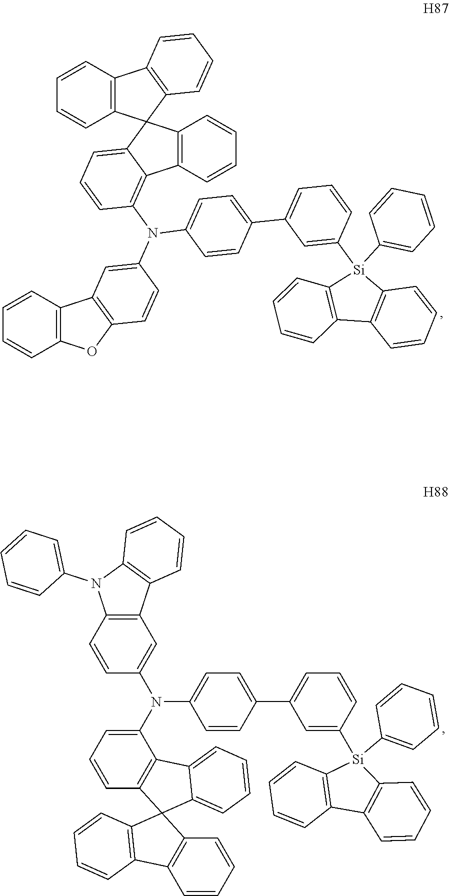 [SMILES: c1ccc([Si]2(c3cccc(-c4ccc(N(c5ccc6oc7ccccc7c6c5)c5cccc6c5-c5ccccc5C65c6ccccc6-c6ccccc65)cc4)c3)c3ccccc3-c3ccccc32)cc1 ; c1ccc(-n2c3ccccc3c3cc(N(c4ccc(-c5cccc([Si]6(c7ccccc7)c7ccccc7-c7ccccc76)c5)cc4)c4cccc5c4-c4ccccc4C54c5ccccc5-c5ccccc54)ccc32)cc1] 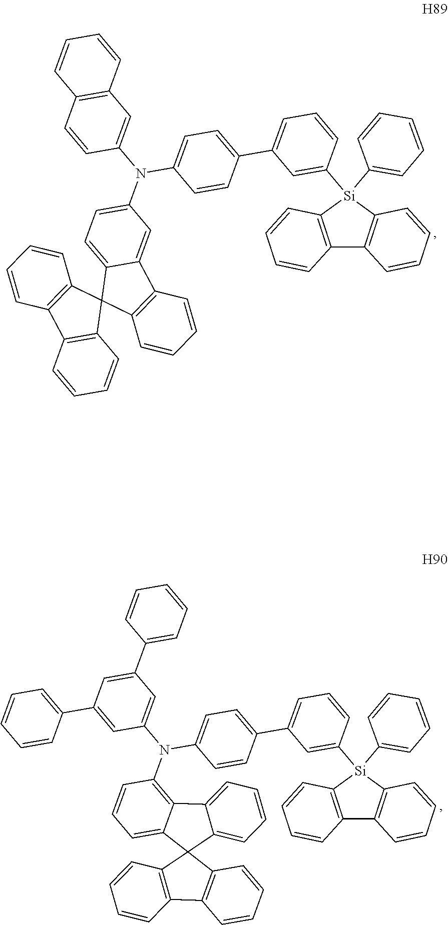 [SMILES: c1ccc([Si]2(c3cccc(-c4ccc(N(c5ccc6c(c5)-c5ccccc5C65c6ccccc6-c6ccccc65)c5ccc6ccccc6c5)cc4)c3)c3ccccc3-c3ccccc32)cc1 ; c1ccc(-c2cc(-c3ccccc3)cc(N(c3ccc(-c4cccc([Si]5(c6ccccc6)c6ccccc6-c6ccccc65)c4)cc3)c3cccc4c3-c3ccccc3C43c4ccccc4-c4ccccc43)c2)cc1] 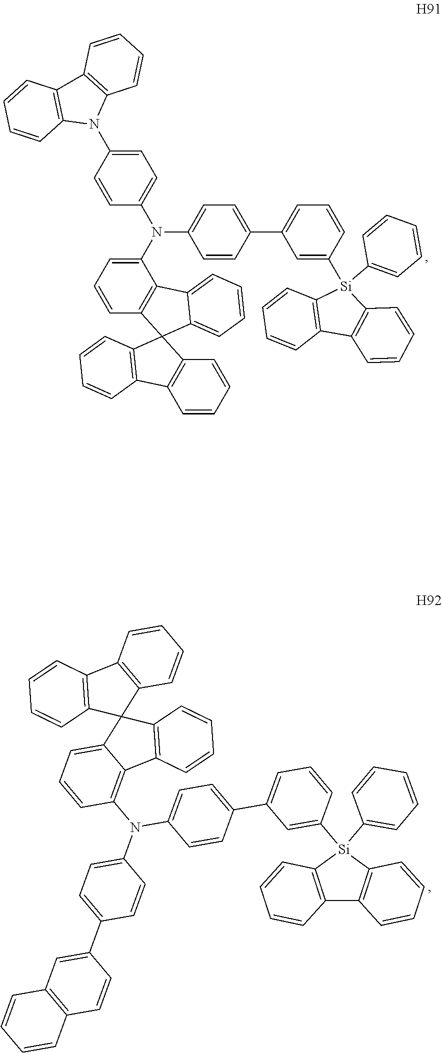 [SMILES: c1ccc([Si]2(c3cccc(-c4ccc(N(c5ccc(-n6c7ccccc7c7ccccc76)cc5)c5cccc6c5-c5ccccc5C65c6ccccc6-c6ccccc65)cc4)c3)c3ccccc3-c3ccccc32)cc1 ; c1ccc([Si]2(c3cccc(-c4ccc(N(c5ccc(-c6ccc7ccccc7c6)cc5)c5cccc6c5-c5ccccc5C65c6ccccc6-c6ccccc65)cc4)c3)c3ccccc3-c3ccccc32)cc1] 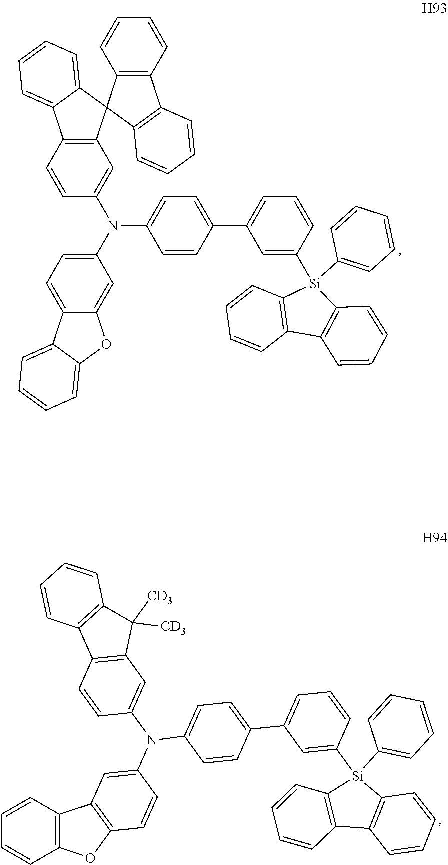 [SMILES: c1ccc([Si]2(c3cccc(-c4ccc(N(c5ccc6c(c5)C5(c7ccccc7-c7ccccc75)c5ccccc5-6)c5ccc6c(c5)oc5ccccc56)cc4)c3)c3ccccc3-c3ccccc32)cc1 ; [2H]C([2H])([2H])C1(C([2H])([2H])[2H])c2ccccc2-c2ccc(N(c3ccc(-c4cccc([Si]5(c6ccccc6)c6ccccc6-c6ccccc65)c4)cc3)c3ccc4oc5ccccc5c4c3)cc21] 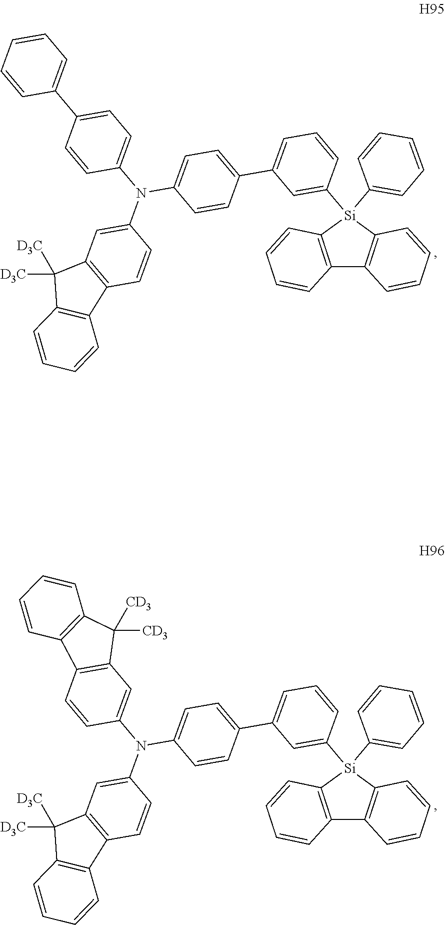 [SMILES: [2H]C([2H])([2H])C1(C([2H])([2H])[2H])c2ccccc2-c2ccc(N(c3ccc(-c4ccccc4)cc3)c3ccc(-c4cccc([Si]5(c6ccccc6)c6ccccc6-c6ccccc65)c4)cc3)cc21 ; [2H]C([2H])([2H])C1(C([2H])([2H])[2H])c2ccccc2-c2ccc(N(c3ccc(-c4cccc([Si]5(c6ccccc6)c6ccccc6-c6ccccc65)c4)cc3)c3ccc4c(c3)C(C([2H])([2H])[2H])(C([2H])([2H])[2H])c3ccccc3-4)cc21] 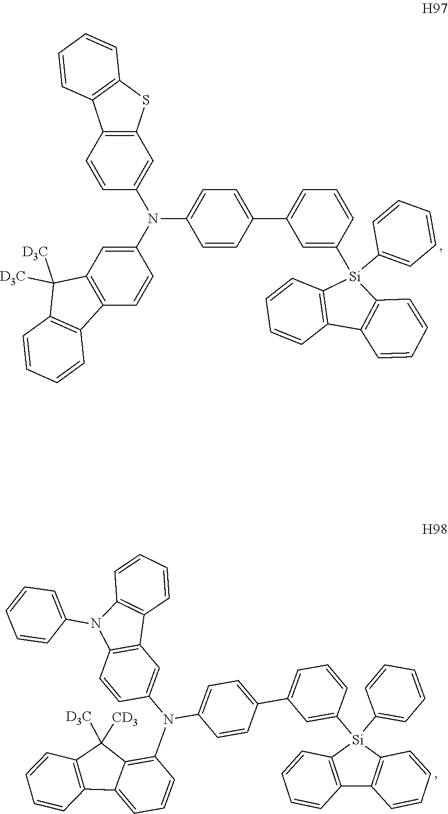 [SMILES: [2H]C([2H])([2H])C1(C([2H])([2H])[2H])c2ccccc2-c2ccc(N(c3ccc(-c4cccc([Si]5(c6ccccc6)c6ccccc6-c6ccccc65)c4)cc3)c3ccc4c(c3)sc3ccccc34)cc21 ; [2H]C([2H])([2H])C1(C([2H])([2H])[2H])c2ccccc2-c2cccc(N(c3ccc(-c4cccc([Si]5(c6ccccc6)c6ccccc6-c6ccccc65)c4)cc3)c3ccc4c(c3)c3ccccc3n4-c3ccccc3)c21] 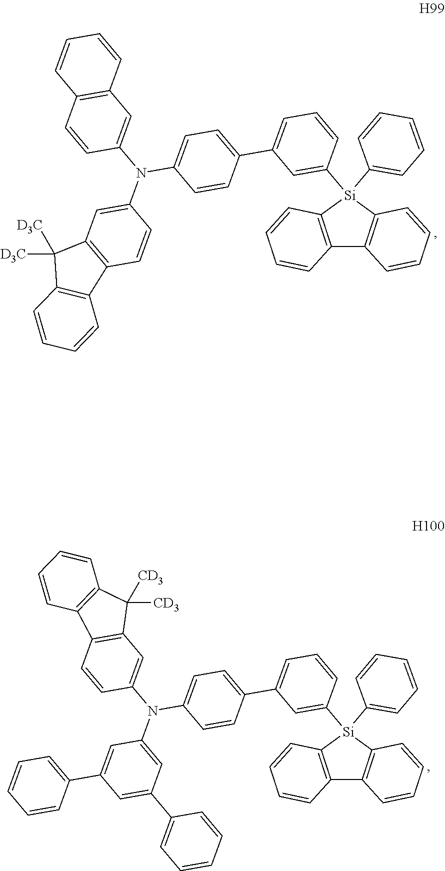 [SMILES: [2H]C([2H])([2H])C1(C([2H])([2H])[2H])c2ccccc2-c2ccc(N(c3ccc(-c4cccc([Si]5(c6ccccc6)c6ccccc6-c6ccccc65)c4)cc3)c3ccc4ccccc4c3)cc21 ; [2H]C([2H])([2H])C1(C([2H])([2H])[2H])c2ccccc2-c2ccc(N(c3ccc(-c4cccc([Si]5(c6ccccc6)c6ccccc6-c6ccccc65)c4)cc3)c3cc(-c4ccccc4)cc(-c4ccccc4)c3)cc21] 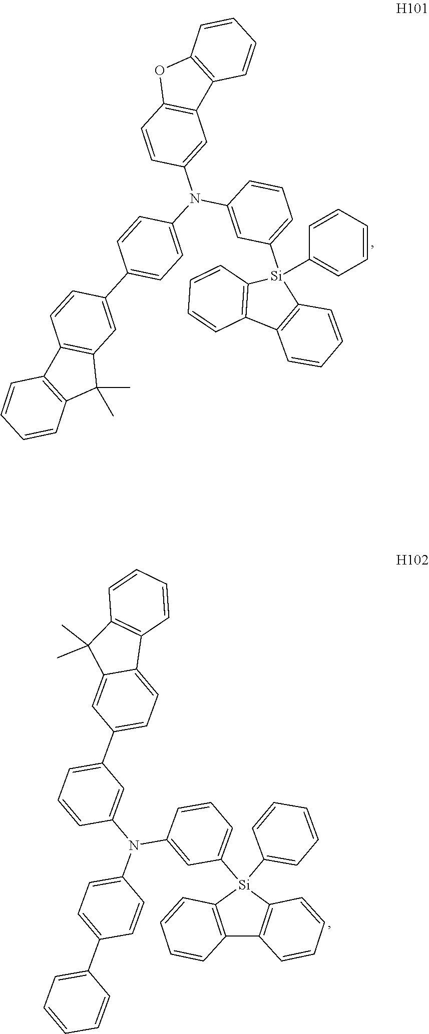 [SMILES: CC1(C)c2ccccc2-c2ccc(-c3ccc(N(c4cccc([Si]5(c6ccccc6)c6ccccc6-c6ccccc65)c4)c4ccc5oc6ccccc6c5c4)cc3)cc21 ; CC1(C)c2ccccc2-c2ccc(-c3cccc(N(c4ccc(-c5ccccc5)cc4)c4cccc([Si]5(c6ccccc6)c6ccccc6-c6ccccc65)c4)c3)cc21] 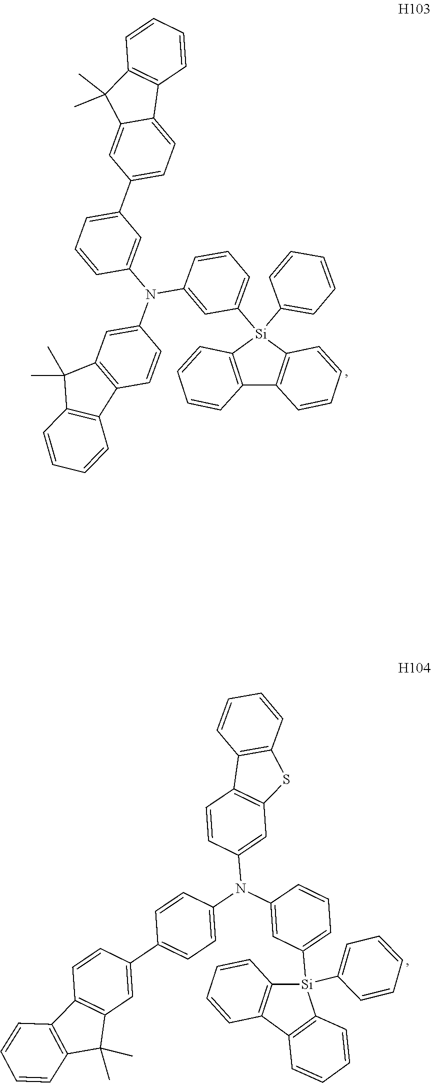 [SMILES: CC1(C)c2ccccc2-c2ccc(-c3cccc(N(c4cccc([Si]5(c6ccccc6)c6ccccc6-c6ccccc65)c4)c4ccc5c(c4)C(C)(C)c4ccccc4-5)c3)cc21 ; CC1(C)c2ccccc2-c2ccc(-c3ccc(N(c4cccc([Si]5(c6ccccc6)c6ccccc6-c6ccccc65)c4)c4ccc5c(c4)sc4ccccc45)cc3)cc21] 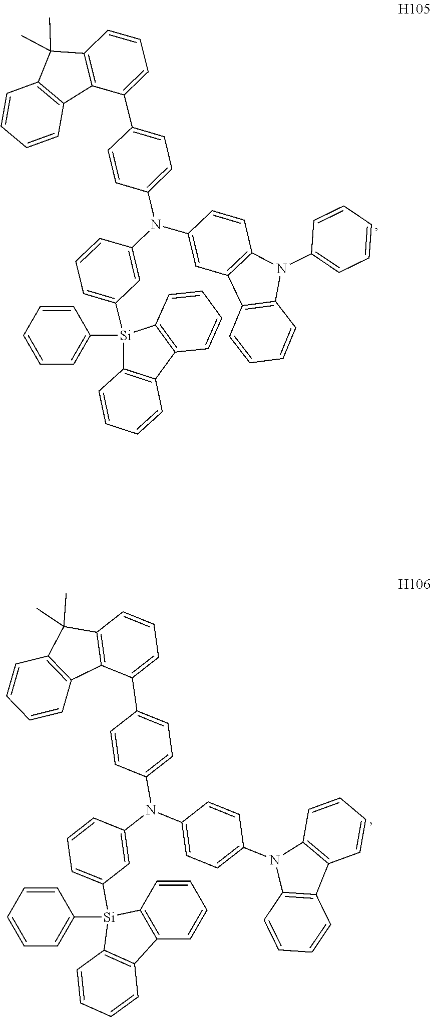 [SMILES: CC1(C)c2ccccc2-c2c(-c3ccc(N(c4cccc([Si]5(c6ccccc6)c6ccccc6-c6ccccc65)c4)c4ccc5c(c4)c4ccccc4n5-c4ccccc4)cc3)cccc21 ; CC1(C)c2ccccc2-c2c(-c3ccc(N(c4ccc(-n5c6ccccc6c6ccccc65)cc4)c4cccc([Si]5(c6ccccc6)c6ccccc6-c6ccccc65)c4)cc3)cccc21] 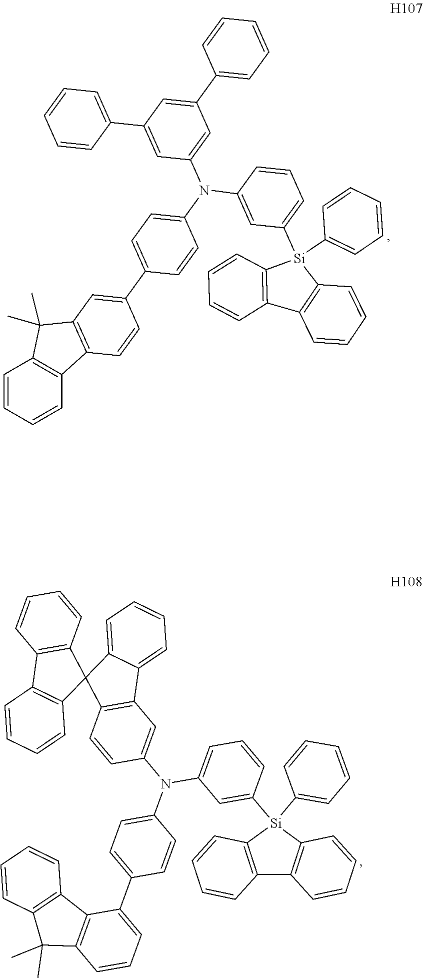 [SMILES: CC1(C)c2ccccc2-c2ccc(-c3ccc(N(c4cc(-c5ccccc5)cc(-c5ccccc5)c4)c4cccc([Si]5(c6ccccc6)c6ccccc6-c6ccccc65)c4)cc3)cc21 ; CC1(C)c2ccccc2-c2c(-c3ccc(N(c4cccc([Si]5(c6ccccc6)c6ccccc6-c6ccccc65)c4)c4ccc5c(c4)-c4ccccc4C54c5ccccc5-c5ccccc54)cc3)cccc21] 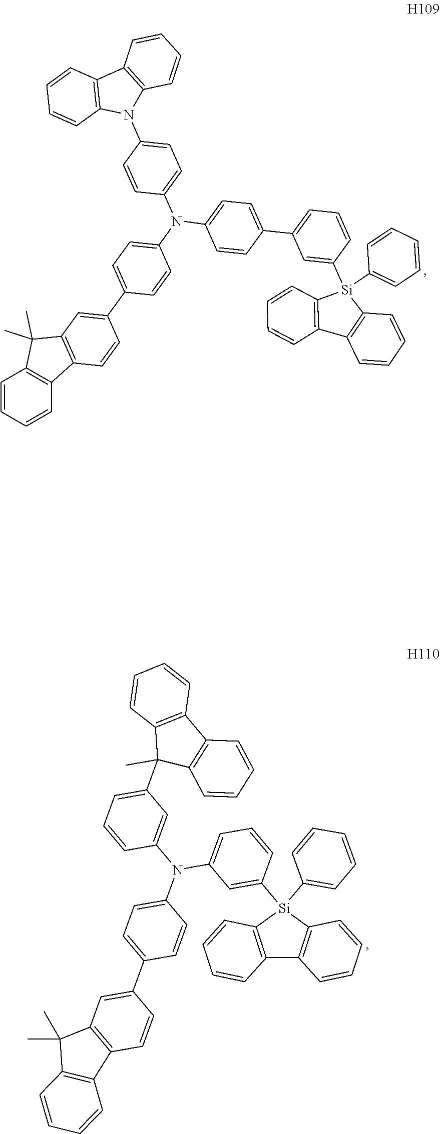 [SMILES: CC1(C)c2ccccc2-c2ccc(-c3ccc(N(c4ccc(-c5cccc([Si]6(c7ccccc7)c7ccccc7-c7ccccc76)c5)cc4)c4ccc(-n5c6ccccc6c6ccccc65)cc4)cc3)cc21 ; CC1(C)c2ccccc2-c2ccc(-c3ccc(N(c4cccc(C5(C)c6ccccc6-c6ccccc65)c4)c4cccc([Si]5(c6ccccc6)c6ccccc6-c6ccccc65)c4)cc3)cc21] 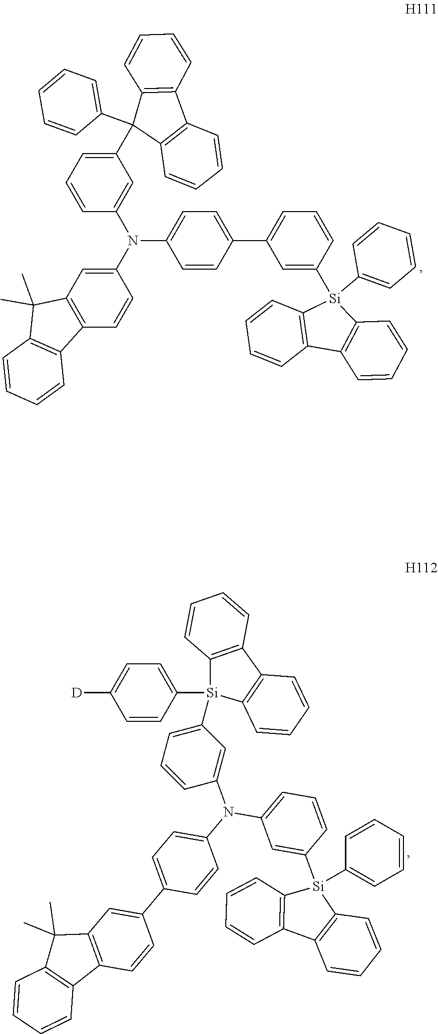 [SMILES: CC1(C)c2ccccc2-c2ccc(N(c3ccc(-c4cccc([Si]5(c6ccccc6)c6ccccc6-c6ccccc65)c4)cc3)c3cccc(C4(c5ccccc5)c5ccccc5-c5ccccc54)c3)cc21 ; [2H]c1ccc([Si]2(c3cccc(N(c4ccc(-c5ccc6c(c5)C(C)(C)c5ccccc5-6)cc4)c4cccc([Si]5(c6ccccc6)c6ccccc6-c6ccccc65)c4)c3)c3ccccc3-c3ccccc32)cc1] 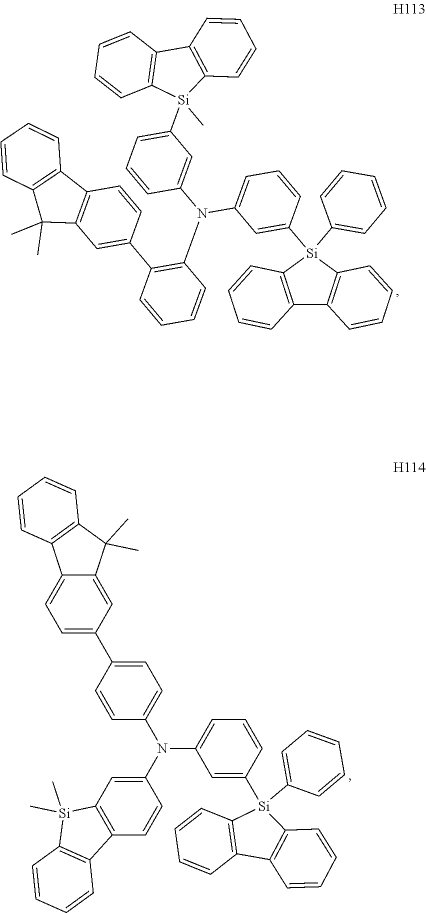 [SMILES: CC1(C)c2ccccc2-c2ccc(-c3ccccc3N(c3cccc([Si]4(C)c5ccccc5-c5ccccc54)c3)c3cccc([Si]4(c5ccccc5)c5ccccc5-c5ccccc54)c3)cc21 ; CC1(C)c2ccccc2-c2ccc(-c3ccc(N(c4cccc([Si]5(c6ccccc6)c6ccccc6-c6ccccc65)c4)c4ccc5c(c4)[Si](C)(C)c4ccccc4-5)cc3)cc21] 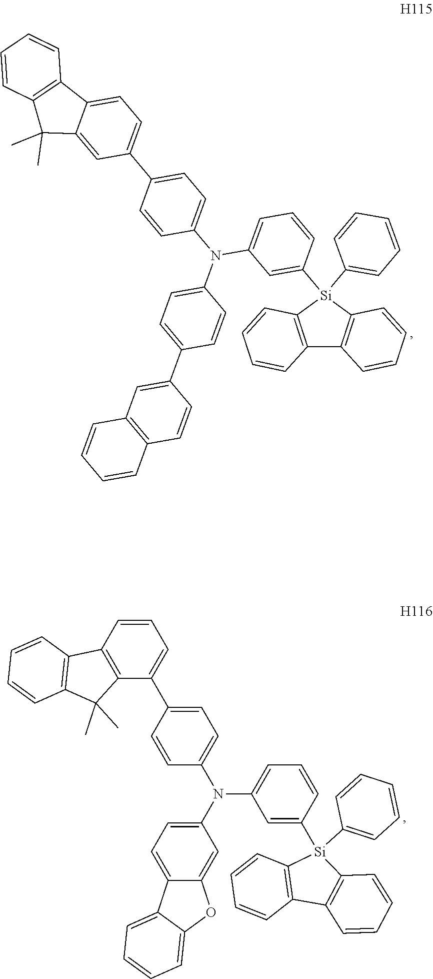 [SMILES: CC1(C)c2ccccc2-c2ccc(-c3ccc(N(c4ccc(-c5ccc6ccccc6c5)cc4)c4cccc([Si]5(c6ccccc6)c6ccccc6-c6ccccc65)c4)cc3)cc21 ; CC1(C)c2ccccc2-c2cccc(-c3ccc(N(c4cccc([Si]5(c6ccccc6)c6ccccc6-c6ccccc65)c4)c4ccc5c(c4)oc4ccccc45)cc3)c21] 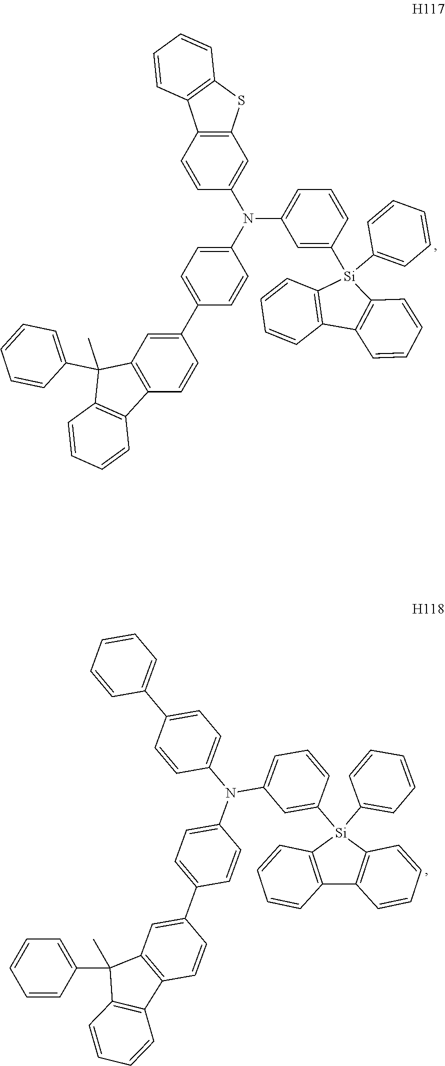 [SMILES: CC1(c2ccccc2)c2ccccc2-c2ccc(-c3ccc(N(c4cccc([Si]5(c6ccccc6)c6ccccc6-c6ccccc65)c4)c4ccc5c(c4)sc4ccccc45)cc3)cc21 ; CC1(c2ccccc2)c2ccccc2-c2ccc(-c3ccc(N(c4ccc(-c5ccccc5)cc4)c4cccc([Si]5(c6ccccc6)c6ccccc6-c6ccccc65)c4)cc3)cc21] 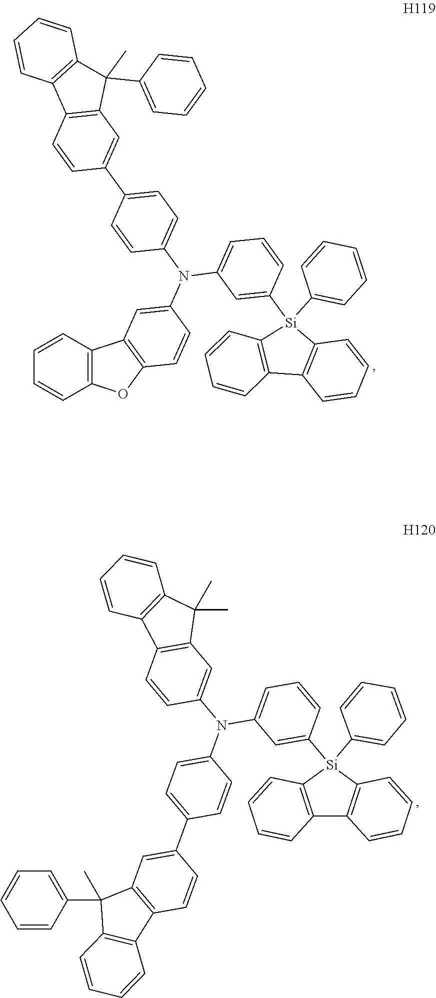 [SMILES: CC1(c2ccccc2)c2ccccc2-c2ccc(-c3ccc(N(c4cccc([Si]5(c6ccccc6)c6ccccc6-c6ccccc65)c4)c4ccc5oc6ccccc6c5c4)cc3)cc21 ; CC1(C)c2ccccc2-c2ccc(N(c3ccc(-c4ccc5c(c4)C(C)(c4ccccc4)c4ccccc4-5)cc3)c3cccc([Si]4(c5ccccc5)c5ccccc5-c5ccccc54)c3)cc21] 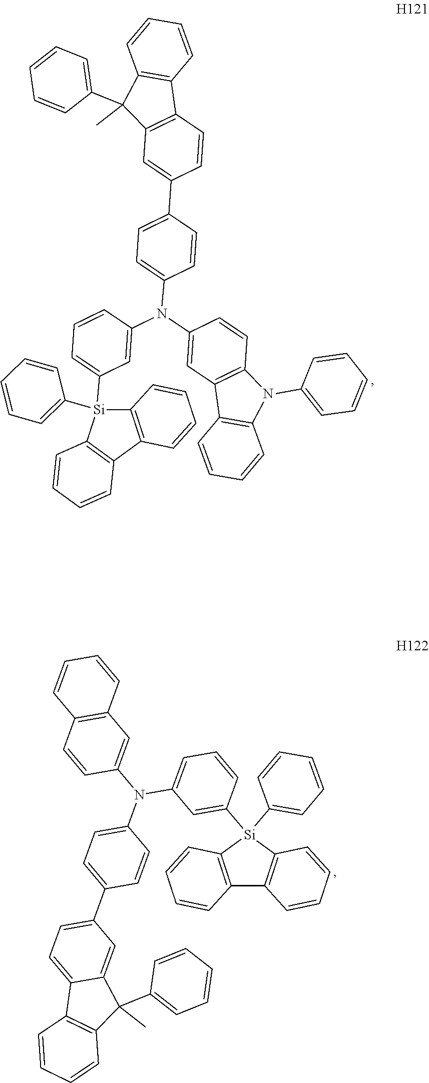 [SMILES: CC1(c2ccccc2)c2ccccc2-c2ccc(-c3ccc(N(c4cccc([Si]5(c6ccccc6)c6ccccc6-c6ccccc65)c4)c4ccc5c(c4)c4ccccc4n5-c4ccccc4)cc3)cc21 ; CC1(c2ccccc2)c2ccccc2-c2ccc(-c3ccc(N(c4cccc([Si]5(c6ccccc6)c6ccccc6-c6ccccc65)c4)c4ccc5ccccc5c4)cc3)cc21] 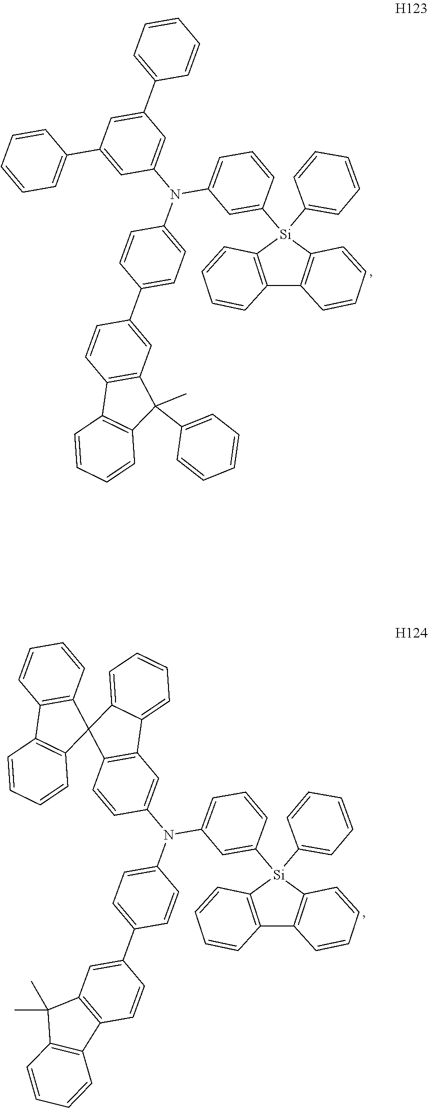 [SMILES: CC1(c2ccccc2)c2ccccc2-c2ccc(-c3ccc(N(c4cc(-c5ccccc5)cc(-c5ccccc5)c4)c4cccc([Si]5(c6ccccc6)c6ccccc6-c6ccccc65)c4)cc3)cc21 ; CC1(C)c2ccccc2-c2ccc(-c3ccc(N(c4cccc([Si]5(c6ccccc6)c6ccccc6-c6ccccc65)c4)c4ccc5c(c4)-c4ccccc4C54c5ccccc5-c5ccccc54)cc3)cc21] 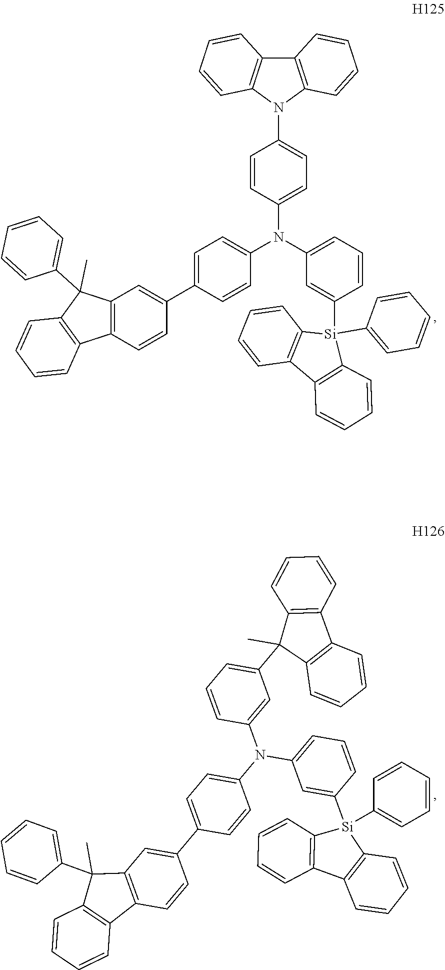 [SMILES: CC1(c2ccccc2)c2ccccc2-c2ccc(-c3ccc(N(c4ccc(-n5c6ccccc6c6ccccc65)cc4)c4cccc([Si]5(c6ccccc6)c6ccccc6-c6ccccc65)c4)cc3)cc21 ; CC1(c2cccc(N(c3ccc(-c4ccc5c(c4)C(C)(c4ccccc4)c4ccccc4-5)cc3)c3cccc([Si]4(c5ccccc5)c5ccccc5-c5ccccc54)c3)c2)c2ccccc2-c2ccccc21] 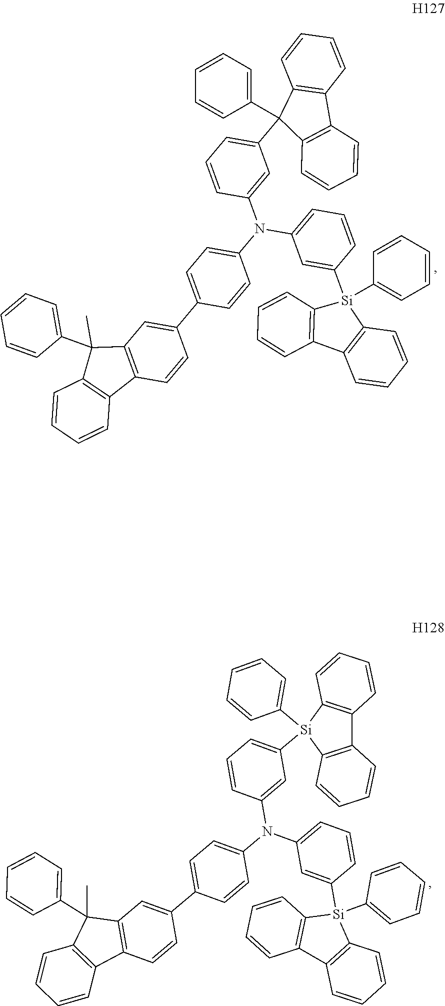 [SMILES: CC1(c2ccccc2)c2ccccc2-c2ccc(-c3ccc(N(c4cccc(C5(c6ccccc6)c6ccccc6-c6ccccc65)c4)c4cccc([Si]5(c6ccccc6)c6ccccc6-c6ccccc65)c4)cc3)cc21 ; CC1(c2ccccc2)c2ccccc2-c2ccc(-c3ccc(N(c4cccc([Si]5(c6ccccc6)c6ccccc6-c6ccccc65)c4)c4cccc([Si]5(c6ccccc6)c6ccccc6-c6ccccc65)c4)cc3)cc21] 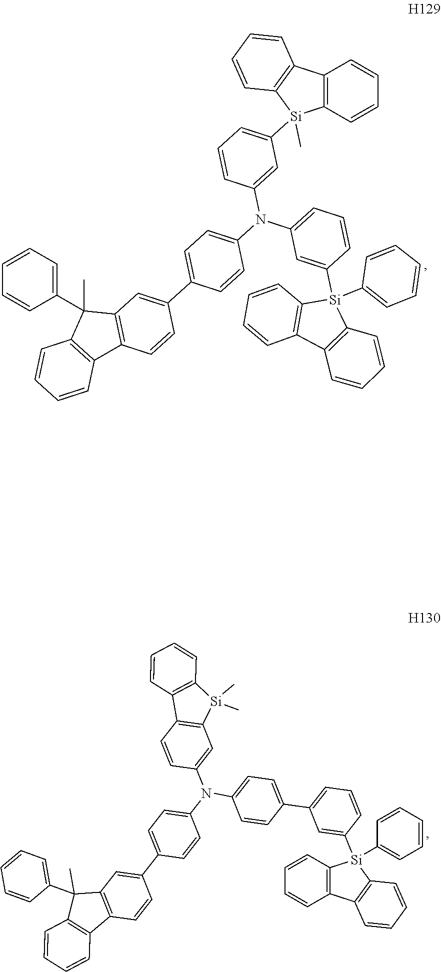 [SMILES: CC1(c2ccccc2)c2ccccc2-c2ccc(-c3ccc(N(c4cccc([Si]5(C)c6ccccc6-c6ccccc65)c4)c4cccc([Si]5(c6ccccc6)c6ccccc6-c6ccccc65)c4)cc3)cc21 ; CC1(c2ccccc2)c2ccccc2-c2ccc(-c3ccc(N(c4ccc(-c5cccc([Si]6(c7ccccc7)c7ccccc7-c7ccccc76)c5)cc4)c4ccc5c(c4)[Si](C)(C)c4ccccc4-5)cc3)cc21] 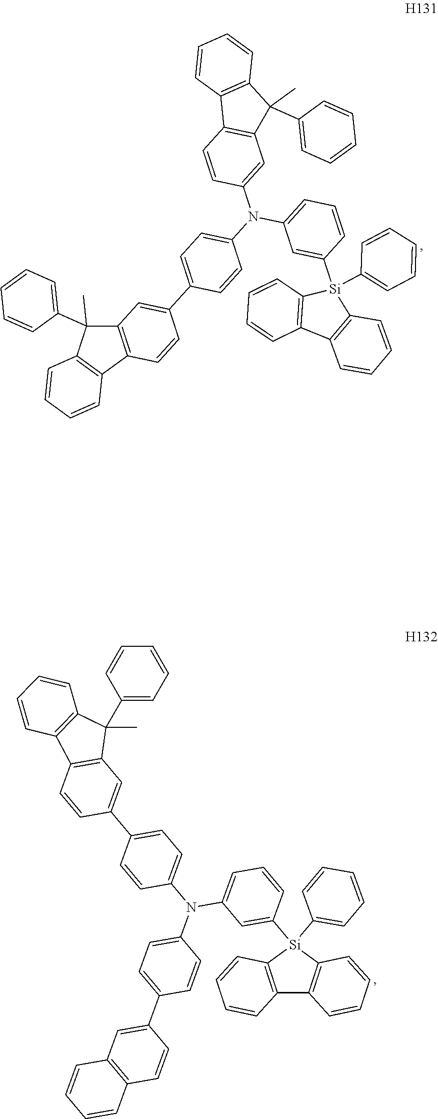 [SMILES: CC1(c2ccccc2)c2ccccc2-c2ccc(-c3ccc(N(c4cccc([Si]5(c6ccccc6)c6ccccc6-c6ccccc65)c4)c4ccc5c(c4)C(C)(c4ccccc4)c4ccccc4-5)cc3)cc21 ; CC1(c2ccccc2)c2ccccc2-c2ccc(-c3ccc(N(c4ccc(-c5ccc6ccccc6c5)cc4)c4cccc([Si]5(c6ccccc6)c6ccccc6-c6ccccc65)c4)cc3)cc21] 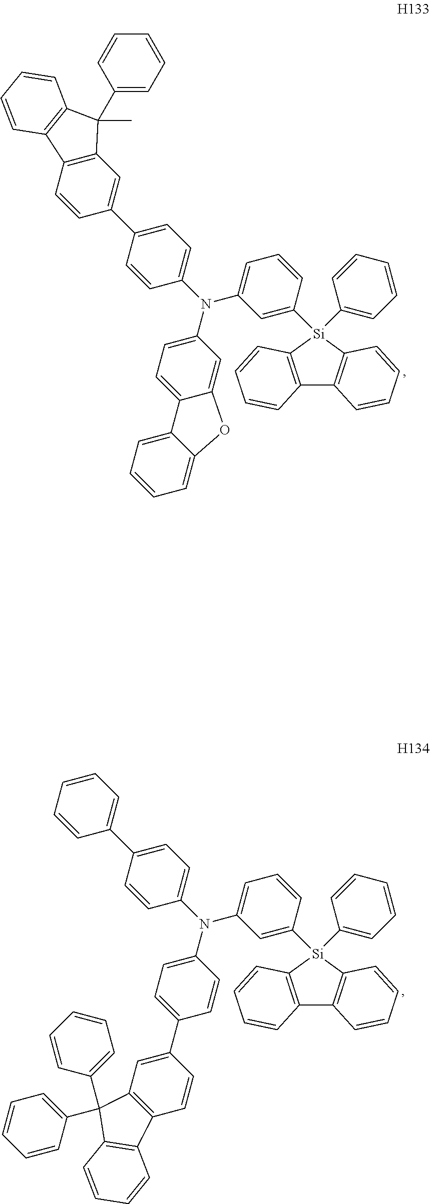 [SMILES: CC1(c2ccccc2)c2ccccc2-c2ccc(-c3ccc(N(c4cccc([Si]5(c6ccccc6)c6ccccc6-c6ccccc65)c4)c4ccc5c(c4)oc4ccccc45)cc3)cc21 ; c1ccc(-c2ccc(N(c3ccc(-c4ccc5c(c4)C(c4ccccc4)(c4ccccc4)c4ccccc4-5)cc3)c3cccc([Si]4(c5ccccc5)c5ccccc5-c5ccccc54)c3)cc2)cc1] 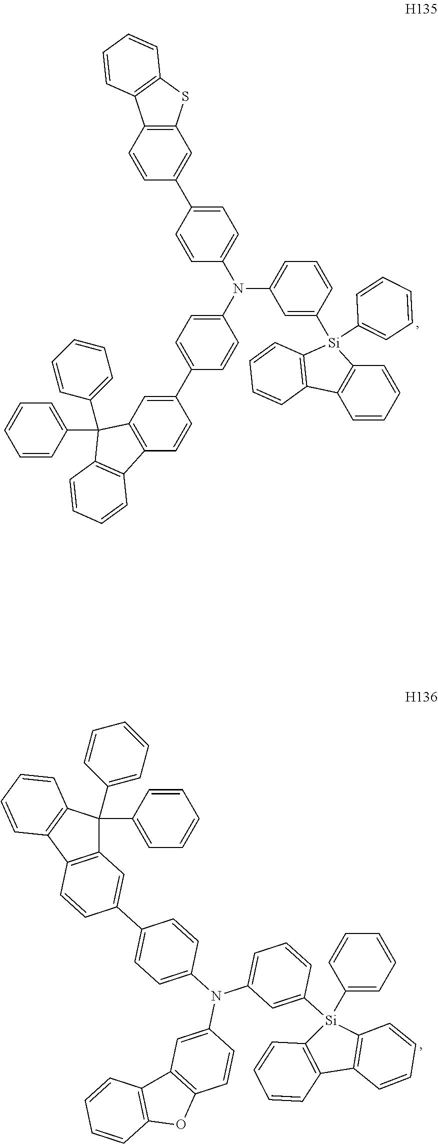 [SMILES: c1ccc(C2(c3ccccc3)c3ccccc3-c3ccc(-c4ccc(N(c5ccc(-c6ccc7c(c6)sc6ccccc67)cc5)c5cccc([Si]6(c7ccccc7)c7ccccc7-c7ccccc76)c5)cc4)cc32)cc1 ; c1ccc(C2(c3ccccc3)c3ccccc3-c3ccc(-c4ccc(N(c5cccc([Si]6(c7ccccc7)c7ccccc7-c7ccccc76)c5)c5ccc6oc7ccccc7c6c5)cc4)cc32)cc1] 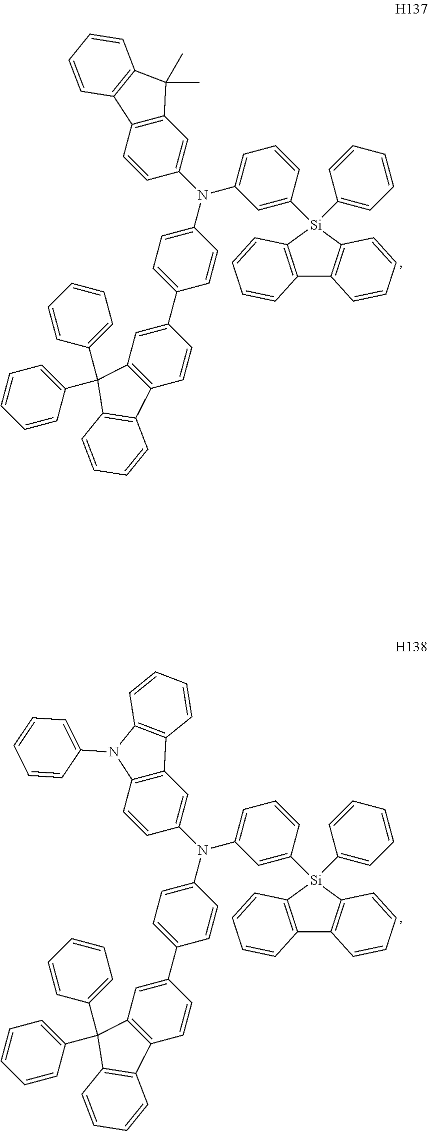 [SMILES: CC1(C)c2ccccc2-c2ccc(N(c3ccc(-c4ccc5c(c4)C(c4ccccc4)(c4ccccc4)c4ccccc4-5)cc3)c3cccc([Si]4(c5ccccc5)c5ccccc5-c5ccccc54)c3)cc21 ; c1ccc(-n2c3ccccc3c3cc(N(c4ccc(-c5ccc6c(c5)C(c5ccccc5)(c5ccccc5)c5ccccc5-6)cc4)c4cccc([Si]5(c6ccccc6)c6ccccc6-c6ccccc65)c4)ccc32)cc1] 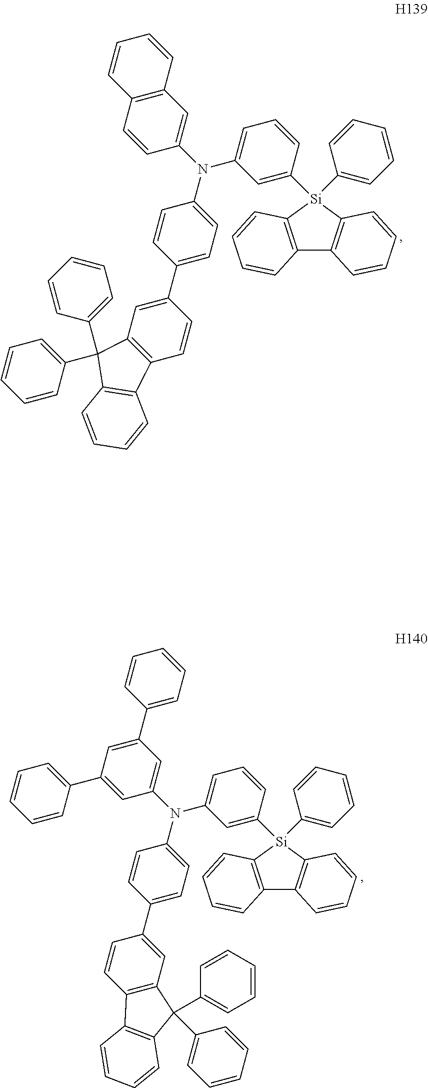 [SMILES: c1ccc(C2(c3ccccc3)c3ccccc3-c3ccc(-c4ccc(N(c5cccc([Si]6(c7ccccc7)c7ccccc7-c7ccccc76)c5)c5ccc6ccccc6c5)cc4)cc32)cc1 ; c1ccc(-c2cc(-c3ccccc3)cc(N(c3ccc(-c4ccc5c(c4)C(c4ccccc4)(c4ccccc4)c4ccccc4-5)cc3)c3cccc([Si]4(c5ccccc5)c5ccccc5-c5ccccc54)c3)c2)cc1] 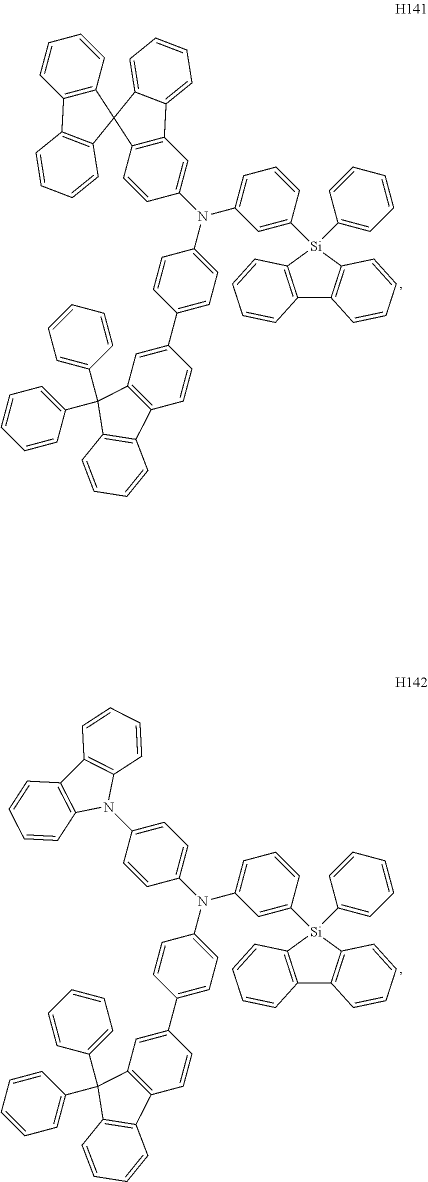 [SMILES: c1ccc(C2(c3ccccc3)c3ccccc3-c3ccc(-c4ccc(N(c5cccc([Si]6(c7ccccc7)c7ccccc7-c7ccccc76)c5)c5ccc6c(c5)-c5ccccc5C65c6ccccc6-c6ccccc65)cc4)cc32)cc1 ; c1ccc(C2(c3ccccc3)c3ccccc3-c3ccc(-c4ccc(N(c5ccc(-n6c7ccccc7c7ccccc76)cc5)c5cccc([Si]6(c7ccccc7)c7ccccc7-c7ccccc76)c5)cc4)cc32)cc1] 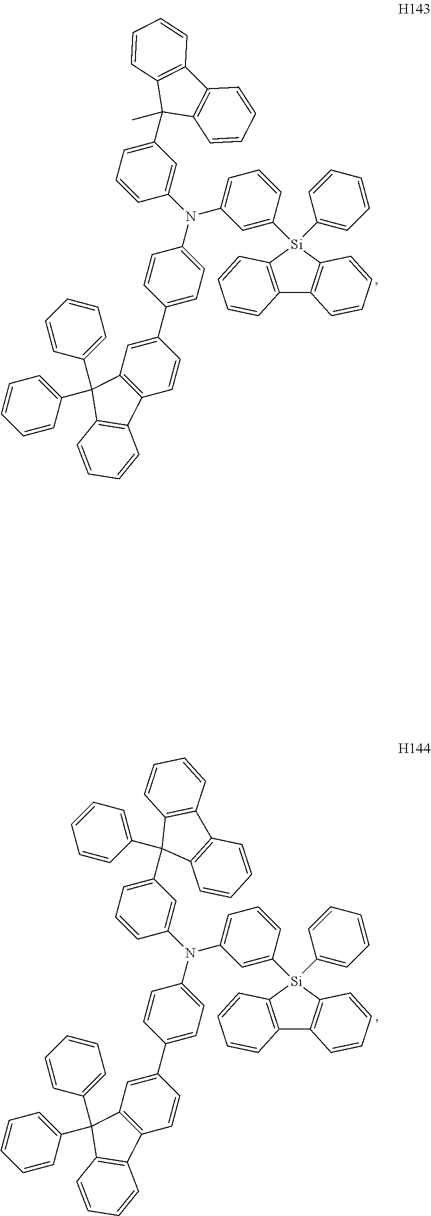 [SMILES: CC1(c2cccc(N(c3ccc(-c4ccc5c(c4)C(c4ccccc4)(c4ccccc4)c4ccccc4-5)cc3)c3cccc([Si]4(c5ccccc5)c5ccccc5-c5ccccc54)c3)c2)c2ccccc2-c2ccccc21 ; c1ccc(C2(c3cccc(N(c4ccc(-c5ccc6c(c5)C(c5ccccc5)(c5ccccc5)c5ccccc5-6)cc4)c4cccc([Si]5(c6ccccc6)c6ccccc6-c6ccccc65)c4)c3)c3ccccc3-c3ccccc32)cc1] 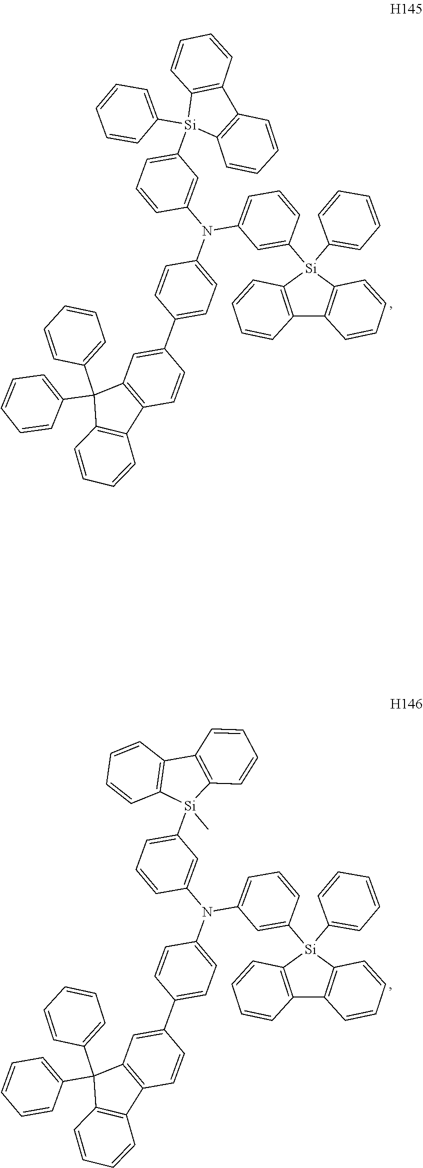 [SMILES: c1ccc(C2(c3ccccc3)c3ccccc3-c3ccc(-c4ccc(N(c5cccc([Si]6(c7ccccc7)c7ccccc7-c7ccccc76)c5)c5cccc([Si]6(c7ccccc7)c7ccccc7-c7ccccc76)c5)cc4)cc32)cc1 ; C[Si]1(c2cccc(N(c3ccc(-c4ccc5c(c4)C(c4ccccc4)(c4ccccc4)c4ccccc4-5)cc3)c3cccc([Si]4(c5ccccc5)c5ccccc5-c5ccccc54)c3)c2)c2ccccc2-c2ccccc21] 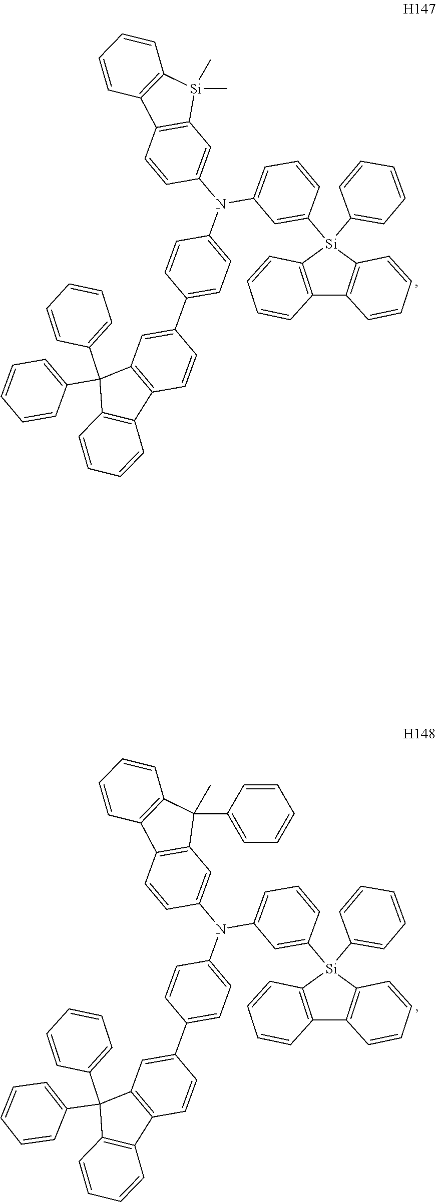 [SMILES: C[Si]1(C)c2ccccc2-c2ccc(N(c3ccc(-c4ccc5c(c4)C(c4ccccc4)(c4ccccc4)c4ccccc4-5)cc3)c3cccc([Si]4(c5ccccc5)c5ccccc5-c5ccccc54)c3)cc21 ; CC1(c2ccccc2)c2ccccc2-c2ccc(N(c3ccc(-c4ccc5c(c4)C(c4ccccc4)(c4ccccc4)c4ccccc4-5)cc3)c3cccc([Si]4(c5ccccc5)c5ccccc5-c5ccccc54)c3)cc21] 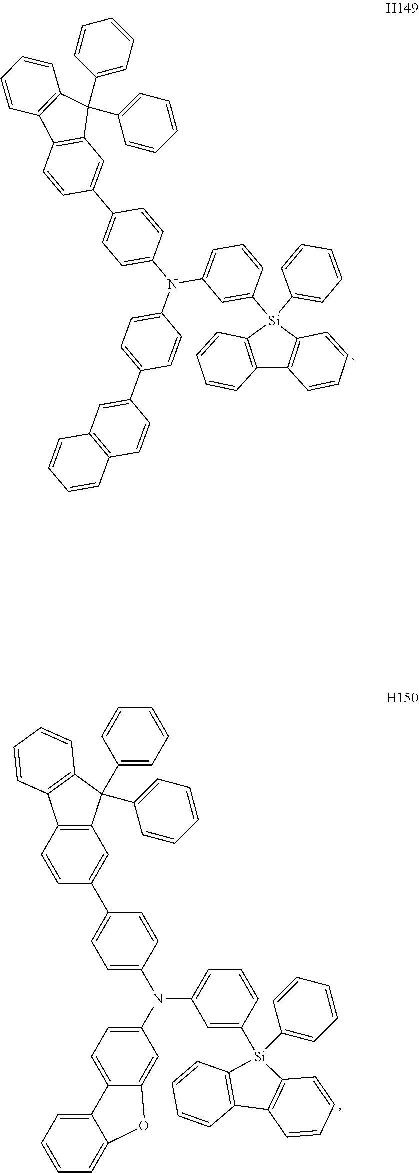 [SMILES: c1ccc(C2(c3ccccc3)c3ccccc3-c3ccc(-c4ccc(N(c5ccc(-c6ccc7ccccc7c6)cc5)c5cccc([Si]6(c7ccccc7)c7ccccc7-c7ccccc76)c5)cc4)cc32)cc1 ; c1ccc(C2(c3ccccc3)c3ccccc3-c3ccc(-c4ccc(N(c5cccc([Si]6(c7ccccc7)c7ccccc7-c7ccccc76)c5)c5ccc6c(c5)oc5ccccc56)cc4)cc32)cc1] 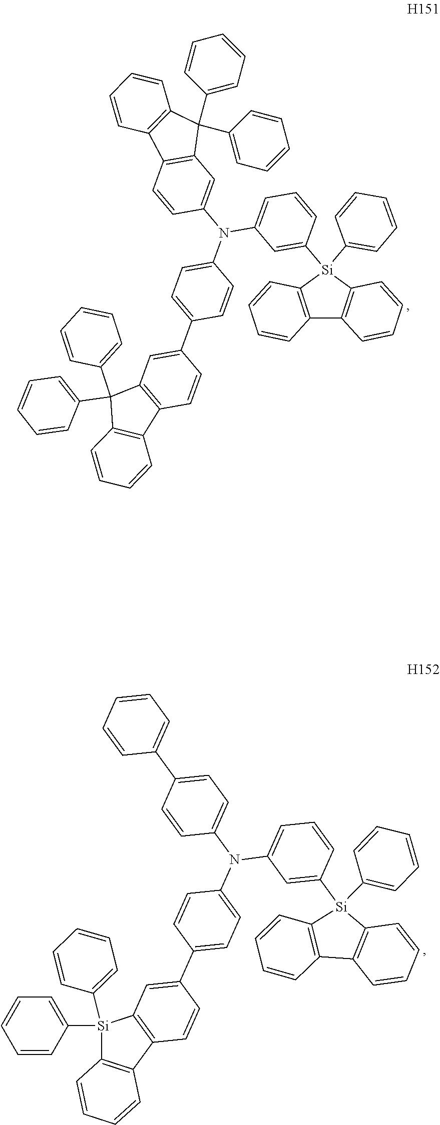 [SMILES: c1ccc(C2(c3ccccc3)c3ccccc3-c3ccc(-c4ccc(N(c5cccc([Si]6(c7ccccc7)c7ccccc7-c7ccccc76)c5)c5ccc6c(c5)C(c5ccccc5)(c5ccccc5)c5ccccc5-6)cc4)cc32)cc1 ; c1ccc(-c2ccc(N(c3ccc(-c4ccc5c(c4)[Si](c4ccccc4)(c4ccccc4)c4ccccc4-5)cc3)c3cccc([Si]4(c5ccccc5)c5ccccc5-c5ccccc54)c3)cc2)cc1] 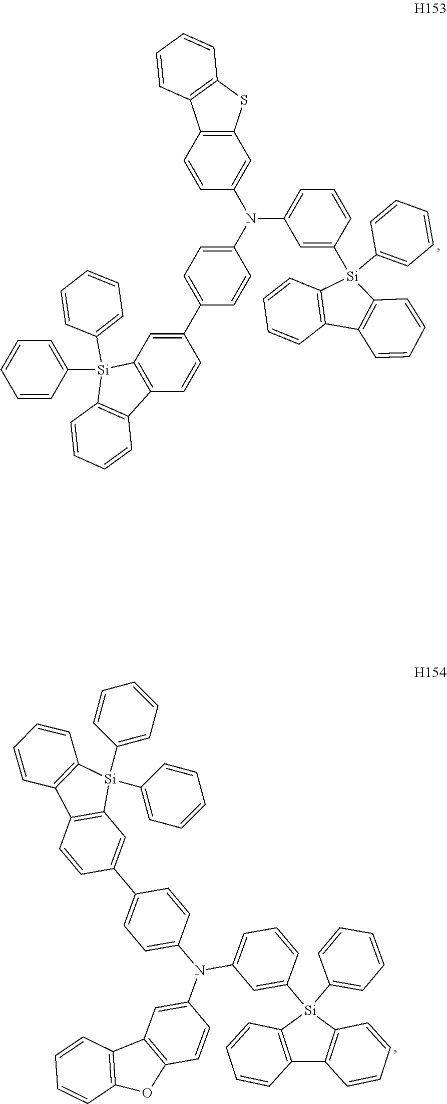 [SMILES: c1ccc([Si]2(c3cccc(N(c4ccc(-c5ccc6c(c5)[Si](c5ccccc5)(c5ccccc5)c5ccccc5-6)cc4)c4ccc5c(c4)sc4ccccc45)c3)c3ccccc3-c3ccccc32)cc1 ; c1ccc([Si]2(c3cccc(N(c4ccc(-c5ccc6c(c5)[Si](c5ccccc5)(c5ccccc5)c5ccccc5-6)cc4)c4ccc5oc6ccccc6c5c4)c3)c3ccccc3-c3ccccc32)cc1] 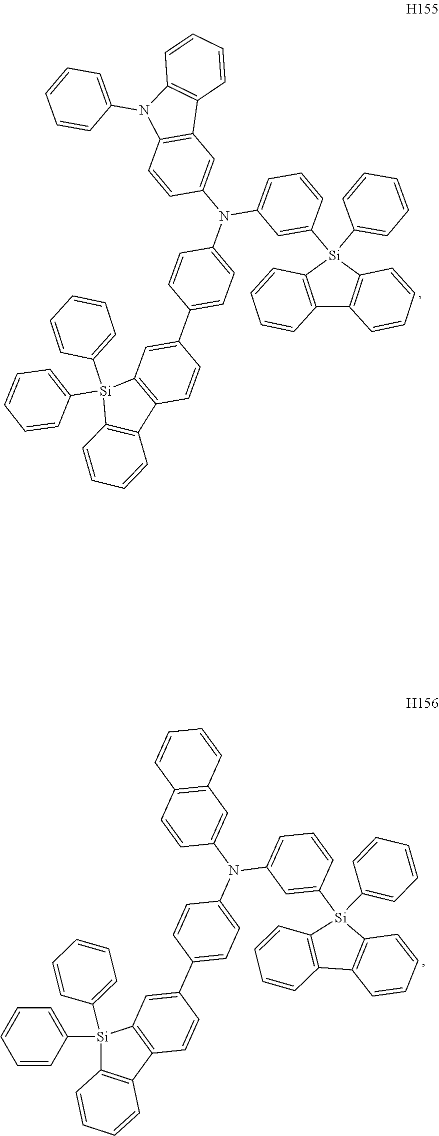 [SMILES: c1ccc(-n2c3ccccc3c3cc(N(c4ccc(-c5ccc6c(c5)[Si](c5ccccc5)(c5ccccc5)c5ccccc5-6)cc4)c4cccc([Si]5(c6ccccc6)c6ccccc6-c6ccccc65)c4)ccc32)cc1 ; c1ccc([Si]2(c3cccc(N(c4ccc(-c5ccc6c(c5)[Si](c5ccccc5)(c5ccccc5)c5ccccc5-6)cc4)c4ccc5ccccc5c4)c3)c3ccccc3-c3ccccc32)cc1] 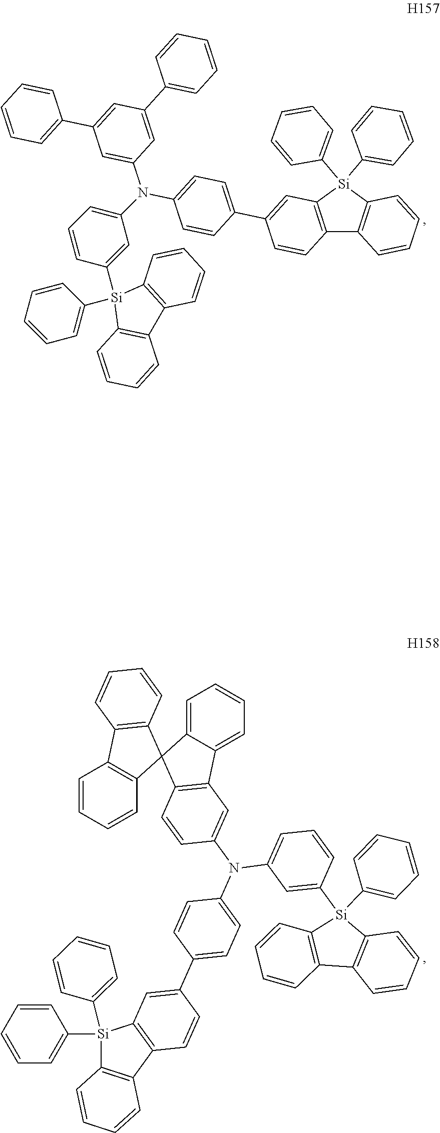 [SMILES: c1ccc(-c2cc(-c3ccccc3)cc(N(c3ccc(-c4ccc5c(c4)[Si](c4ccccc4)(c4ccccc4)c4ccccc4-5)cc3)c3cccc([Si]4(c5ccccc5)c5ccccc5-c5ccccc54)c3)c2)cc1 ; c1ccc([Si]2(c3cccc(N(c4ccc(-c5ccc6c(c5)[Si](c5ccccc5)(c5ccccc5)c5ccccc5-6)cc4)c4ccc5c(c4)-c4ccccc4C54c5ccccc5-c5ccccc54)c3)c3ccccc3-c3ccccc32)cc1] 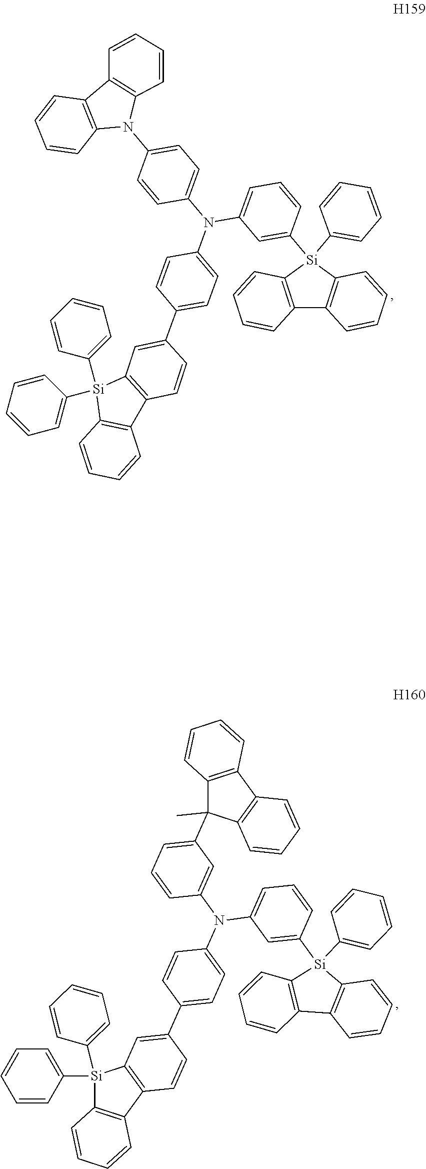 [SMILES: c1ccc([Si]2(c3cccc(N(c4ccc(-c5ccc6c(c5)[Si](c5ccccc5)(c5ccccc5)c5ccccc5-6)cc4)c4ccc(-n5c6ccccc6c6ccccc65)cc4)c3)c3ccccc3-c3ccccc32)cc1 ; CC1(c2cccc(N(c3ccc(-c4ccc5c(c4)[Si](c4ccccc4)(c4ccccc4)c4ccccc4-5)cc3)c3cccc([Si]4(c5ccccc5)c5ccccc5-c5ccccc54)c3)c2)c2ccccc2-c2ccccc21] 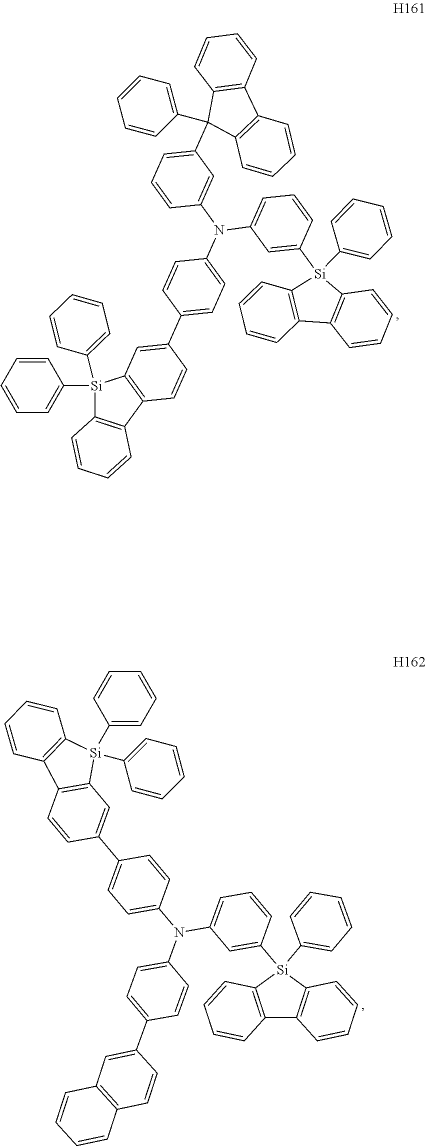 [SMILES: c1ccc(C2(c3cccc(N(c4ccc(-c5ccc6c(c5)[Si](c5ccccc5)(c5ccccc5)c5ccccc5-6)cc4)c4cccc([Si]5(c6ccccc6)c6ccccc6-c6ccccc65)c4)c3)c3ccccc3-c3ccccc32)cc1 ; c1ccc([Si]2(c3cccc(N(c4ccc(-c5ccc6c(c5)[Si](c5ccccc5)(c5ccccc5)c5ccccc5-6)cc4)c4ccc(-c5ccc6ccccc6c5)cc4)c3)c3ccccc3-c3ccccc32)cc1] 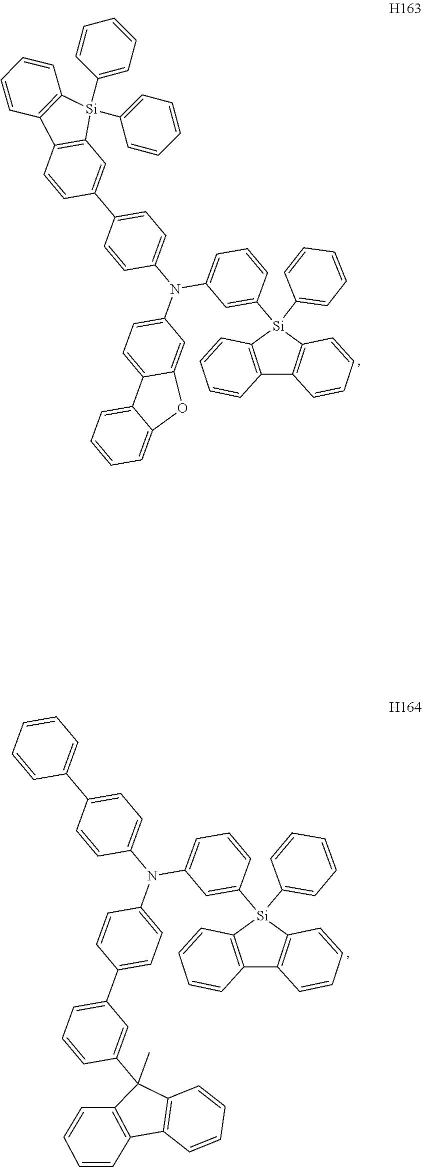 [SMILES: c1ccc([Si]2(c3cccc(N(c4ccc(-c5ccc6c(c5)[Si](c5ccccc5)(c5ccccc5)c5ccccc5-6)cc4)c4ccc5c(c4)oc4ccccc45)c3)c3ccccc3-c3ccccc32)cc1 ; CC1(c2cccc(-c3ccc(N(c4ccc(-c5ccccc5)cc4)c4cccc([Si]5(c6ccccc6)c6ccccc6-c6ccccc65)c4)cc3)c2)c2ccccc2-c2ccccc21] 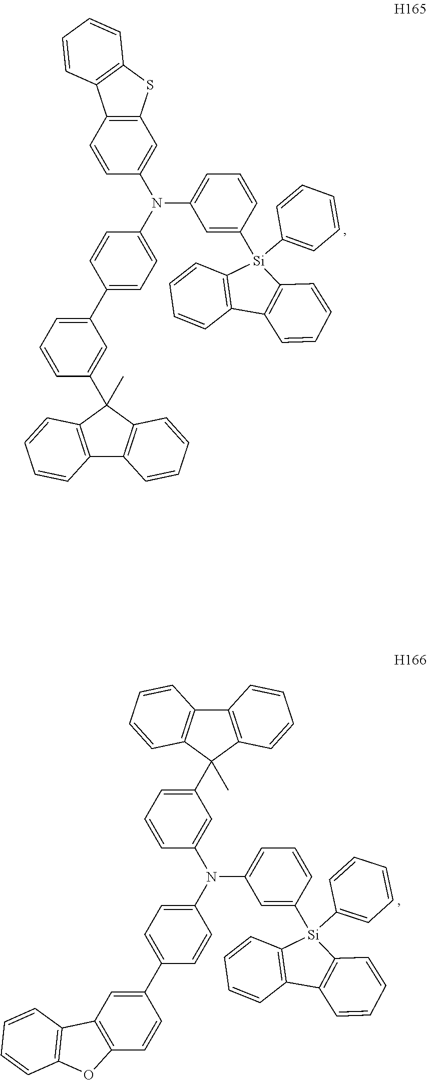 [SMILES: CC1(c2cccc(-c3ccc(N(c4cccc([Si]5(c6ccccc6)c6ccccc6-c6ccccc65)c4)c4ccc5c(c4)sc4ccccc45)cc3)c2)c2ccccc2-c2ccccc21 ; CC1(c2cccc(N(c3ccc(-c4ccc5oc6ccccc6c5c4)cc3)c3cccc([Si]4(c5ccccc5)c5ccccc5-c5ccccc54)c3)c2)c2ccccc2-c2ccccc21] 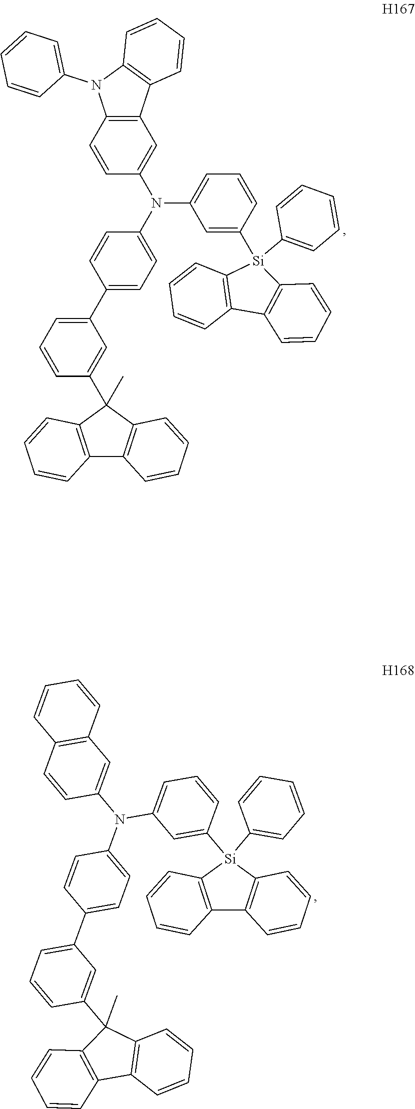 [SMILES: CC1(c2cccc(-c3ccc(N(c4cccc([Si]5(c6ccccc6)c6ccccc6-c6ccccc65)c4)c4ccc5c(c4)c4ccccc4n5-c4ccccc4)cc3)c2)c2ccccc2-c2ccccc21 ; CC1(c2cccc(-c3ccc(N(c4cccc([Si]5(c6ccccc6)c6ccccc6-c6ccccc65)c4)c4ccc5ccccc5c4)cc3)c2)c2ccccc2-c2ccccc21] 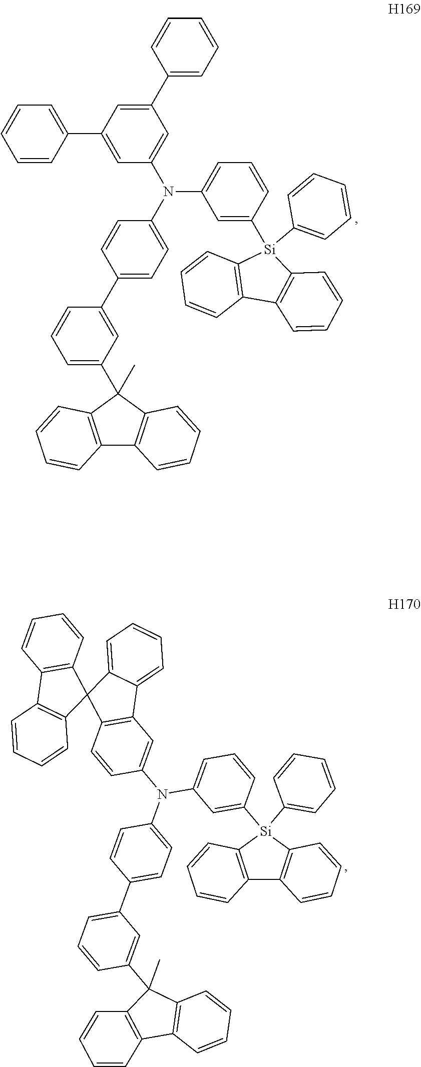 [SMILES: CC1(c2cccc(-c3ccc(N(c4cc(-c5ccccc5)cc(-c5ccccc5)c4)c4cccc([Si]5(c6ccccc6)c6ccccc6-c6ccccc65)c4)cc3)c2)c2ccccc2-c2ccccc21 ; CC1(c2cccc(-c3ccc(N(c4cccc([Si]5(c6ccccc6)c6ccccc6-c6ccccc65)c4)c4ccc5c(c4)-c4ccccc4C54c5ccccc5-c5ccccc54)cc3)c2)c2ccccc2-c2ccccc21] 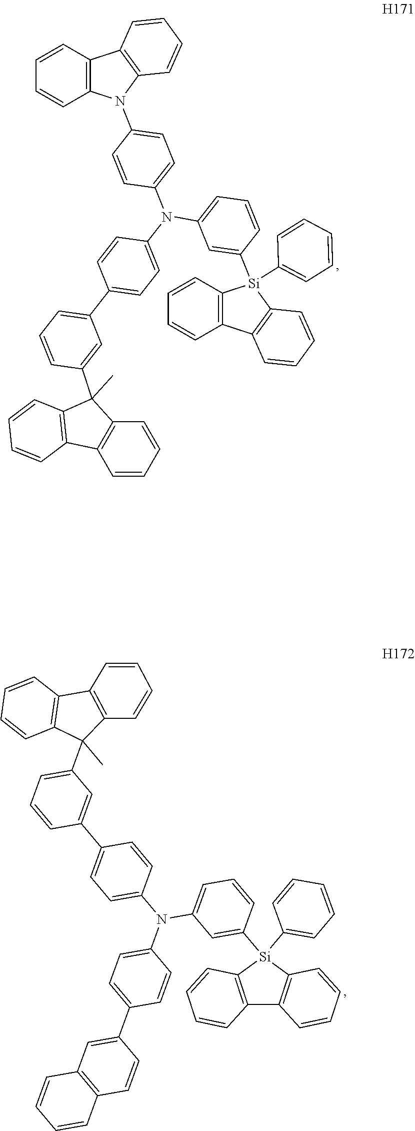 [SMILES: CC1(c2cccc(-c3ccc(N(c4ccc(-n5c6ccccc6c6ccccc65)cc4)c4cccc([Si]5(c6ccccc6)c6ccccc6-c6ccccc65)c4)cc3)c2)c2ccccc2-c2ccccc21 ; CC1(c2cccc(-c3ccc(N(c4ccc(-c5ccc6ccccc6c5)cc4)c4cccc([Si]5(c6ccccc6)c6ccccc6-c6ccccc65)c4)cc3)c2)c2ccccc2-c2ccccc21] 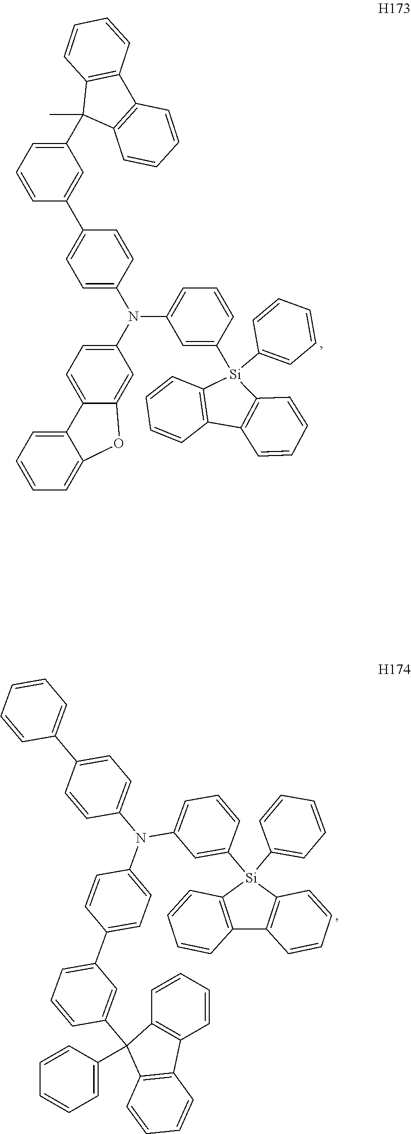 [SMILES: CC1(c2cccc(-c3ccc(N(c4cccc([Si]5(c6ccccc6)c6ccccc6-c6ccccc65)c4)c4ccc5c(c4)oc4ccccc45)cc3)c2)c2ccccc2-c2ccccc21 ; c1ccc(-c2ccc(N(c3ccc(-c4cccc(C5(c6ccccc6)c6ccccc6-c6ccccc65)c4)cc3)c3cccc([Si]4(c5ccccc5)c5ccccc5-c5ccccc54)c3)cc2)cc1] 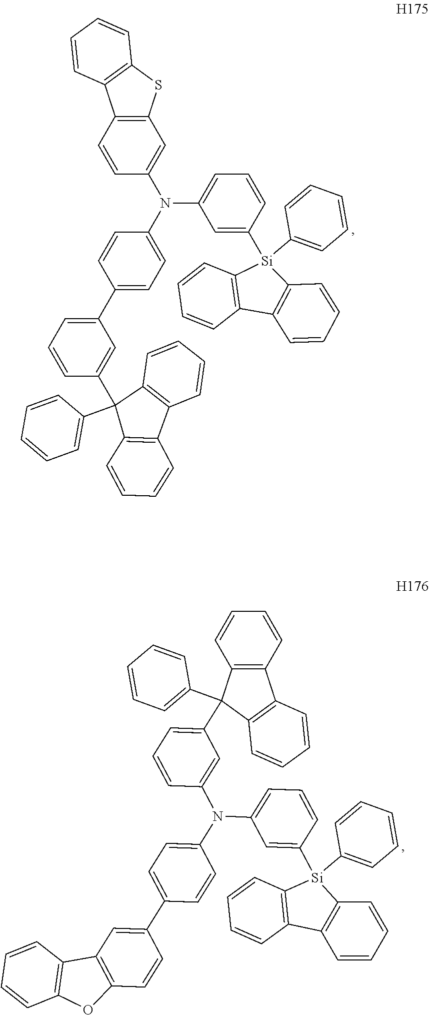 [SMILES: c1ccc(C2(c3cccc(-c4ccc(N(c5cccc([Si]6(c7ccccc7)c7ccccc7-c7ccccc76)c5)c5ccc6c(c5)sc5ccccc56)cc4)c3)c3ccccc3-c3ccccc32)cc1 ; c1ccc(C2(c3cccc(N(c4ccc(-c5ccc6oc7ccccc7c6c5)cc4)c4cccc([Si]5(c6ccccc6)c6ccccc6-c6ccccc65)c4)c3)c3ccccc3-c3ccccc32)cc1] 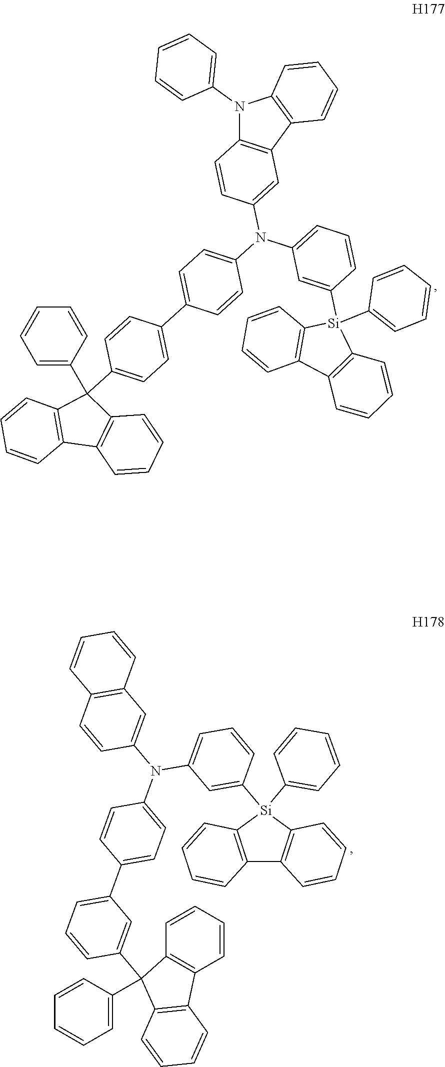 [SMILES: c1ccc(-n2c3ccccc3c3cc(N(c4ccc(-c5ccc(C6(c7ccccc7)c7ccccc7-c7ccccc76)cc5)cc4)c4cccc([Si]5(c6ccccc6)c6ccccc6-c6ccccc65)c4)ccc32)cc1 ; c1ccc(C2(c3cccc(-c4ccc(N(c5cccc([Si]6(c7ccccc7)c7ccccc7-c7ccccc76)c5)c5ccc6ccccc6c5)cc4)c3)c3ccccc3-c3ccccc32)cc1] 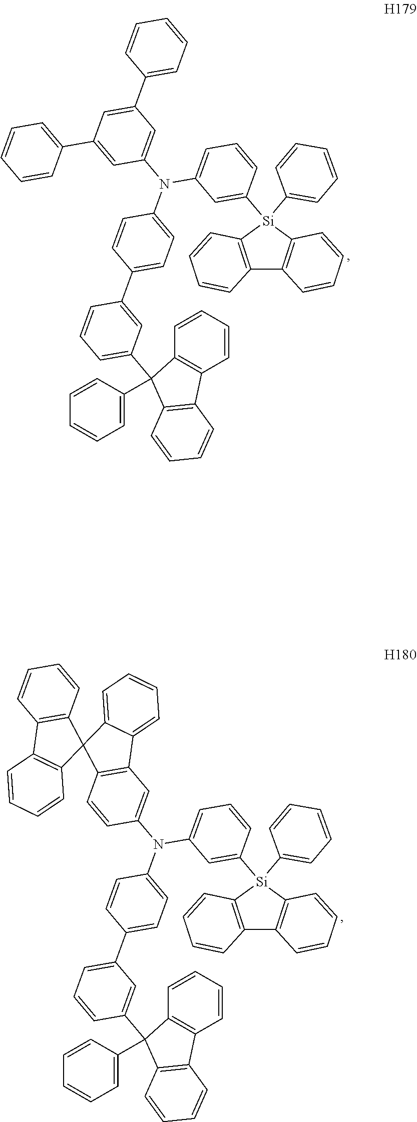 [SMILES: c1ccc(-c2cc(-c3ccccc3)cc(N(c3ccc(-c4cccc(C5(c6ccccc6)c6ccccc6-c6ccccc65)c4)cc3)c3cccc([Si]4(c5ccccc5)c5ccccc5-c5ccccc54)c3)c2)cc1 ; c1ccc(C2(c3cccc(-c4ccc(N(c5cccc([Si]6(c7ccccc7)c7ccccc7-c7ccccc76)c5)c5ccc6c(c5)-c5ccccc5C65c6ccccc6-c6ccccc65)cc4)c3)c3ccccc3-c3ccccc32)cc1] 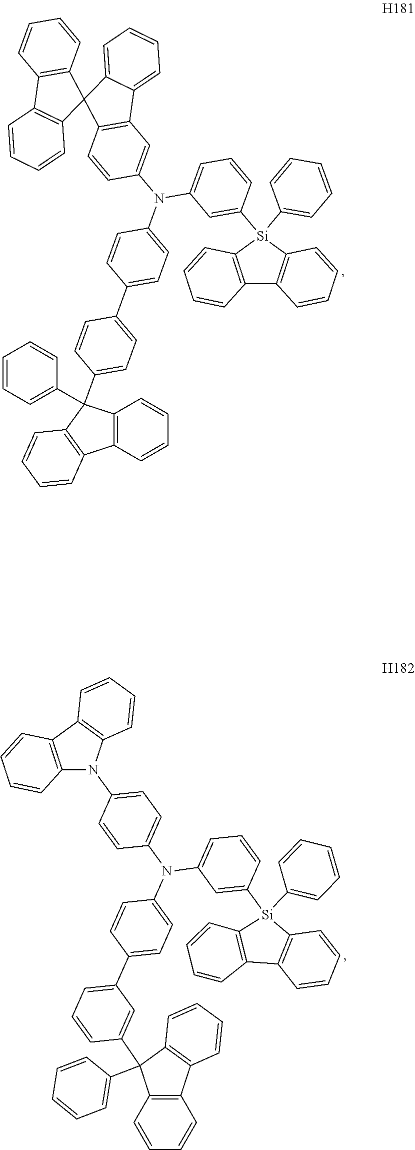 [SMILES: c1ccc(C2(c3ccc(-c4ccc(N(c5cccc([Si]6(c7ccccc7)c7ccccc7-c7ccccc76)c5)c5ccc6c(c5)-c5ccccc5C65c6ccccc6-c6ccccc65)cc4)cc3)c3ccccc3-c3ccccc32)cc1 ; c1ccc(C2(c3cccc(-c4ccc(N(c5ccc(-n6c7ccccc7c7ccccc76)cc5)c5cccc([Si]6(c7ccccc7)c7ccccc7-c7ccccc76)c5)cc4)c3)c3ccccc3-c3ccccc32)cc1] 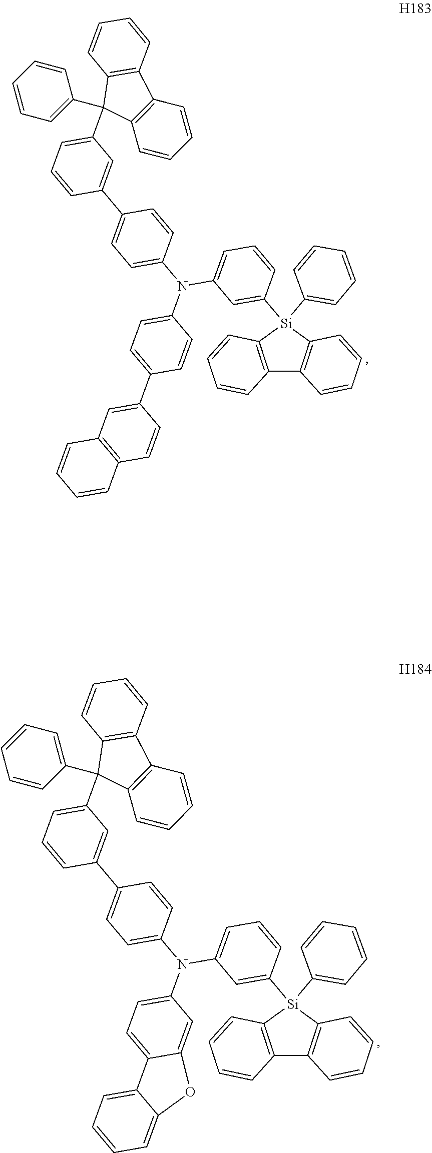 [SMILES: c1ccc(C2(c3cccc(-c4ccc(N(c5ccc(-c6ccc7ccccc7c6)cc5)c5cccc([Si]6(c7ccccc7)c7ccccc7-c7ccccc76)c5)cc4)c3)c3ccccc3-c3ccccc32)cc1 ; c1ccc(C2(c3cccc(-c4ccc(N(c5cccc([Si]6(c7ccccc7)c7ccccc7-c7ccccc76)c5)c5ccc6c(c5)oc5ccccc56)cc4)c3)c3ccccc3-c3ccccc32)cc1] 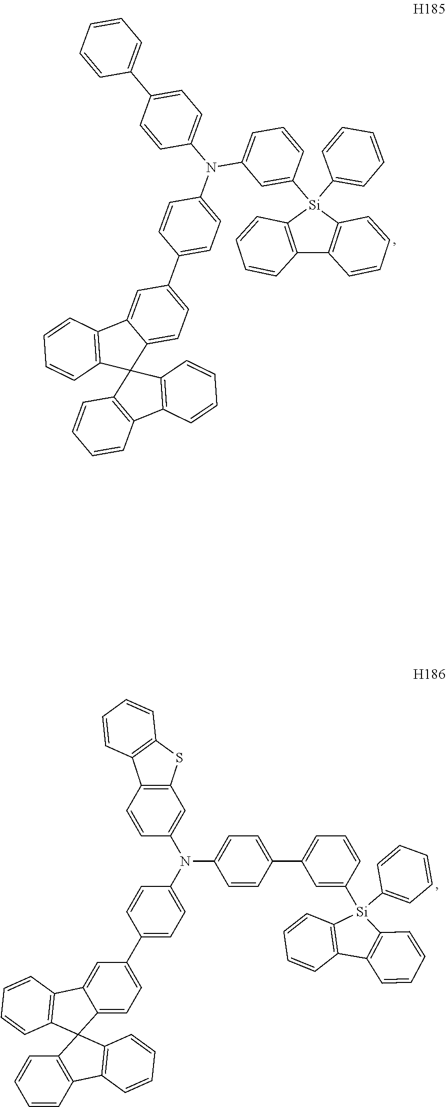 [SMILES: c1ccc(-c2ccc(N(c3ccc(-c4ccc5c(c4)-c4ccccc4C54c5ccccc5-c5ccccc54)cc3)c3cccc([Si]4(c5ccccc5)c5ccccc5-c5ccccc54)c3)cc2)cc1 ; c1ccc([Si]2(c3cccc(-c4ccc(N(c5ccc(-c6ccc7c(c6)-c6ccccc6C76c7ccccc7-c7ccccc76)cc5)c5ccc6c(c5)sc5ccccc56)cc4)c3)c3ccccc3-c3ccccc32)cc1] 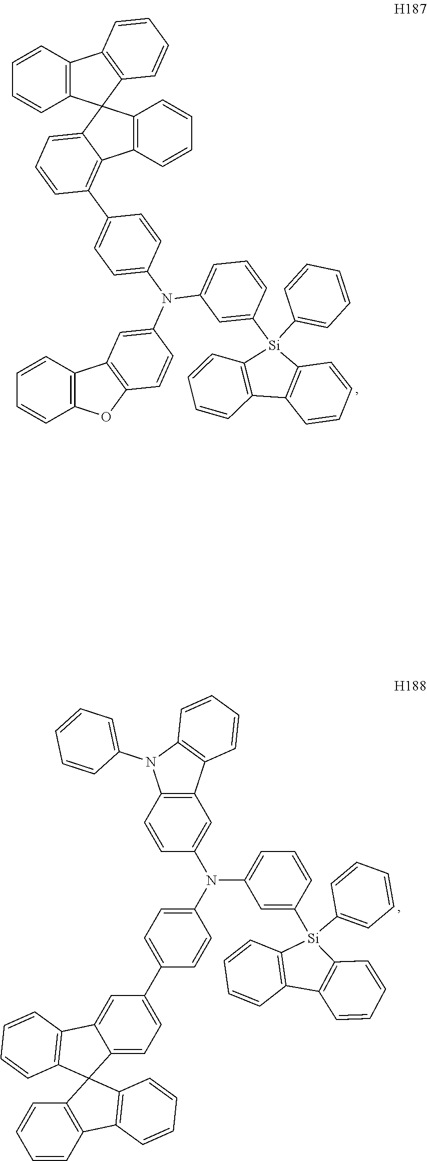 [SMILES: c1ccc([Si]2(c3cccc(N(c4ccc(-c5cccc6c5-c5ccccc5C65c6ccccc6-c6ccccc65)cc4)c4ccc5oc6ccccc6c5c4)c3)c3ccccc3-c3ccccc32)cc1 ; c1ccc(-n2c3ccccc3c3cc(N(c4ccc(-c5ccc6c(c5)-c5ccccc5C65c6ccccc6-c6ccccc65)cc4)c4cccc([Si]5(c6ccccc6)c6ccccc6-c6ccccc65)c4)ccc32)cc1] 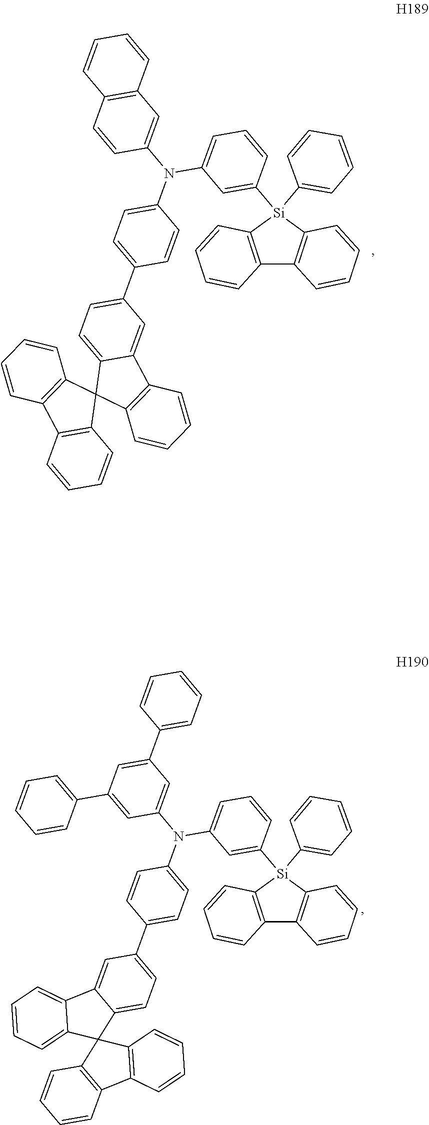 [SMILES: c1ccc([Si]2(c3cccc(N(c4ccc(-c5ccc6c(c5)-c5ccccc5C65c6ccccc6-c6ccccc65)cc4)c4ccc5ccccc5c4)c3)c3ccccc3-c3ccccc32)cc1 ; c1ccc(-c2cc(-c3ccccc3)cc(N(c3ccc(-c4ccc5c(c4)-c4ccccc4C54c5ccccc5-c5ccccc54)cc3)c3cccc([Si]4(c5ccccc5)c5ccccc5-c5ccccc54)c3)c2)cc1] 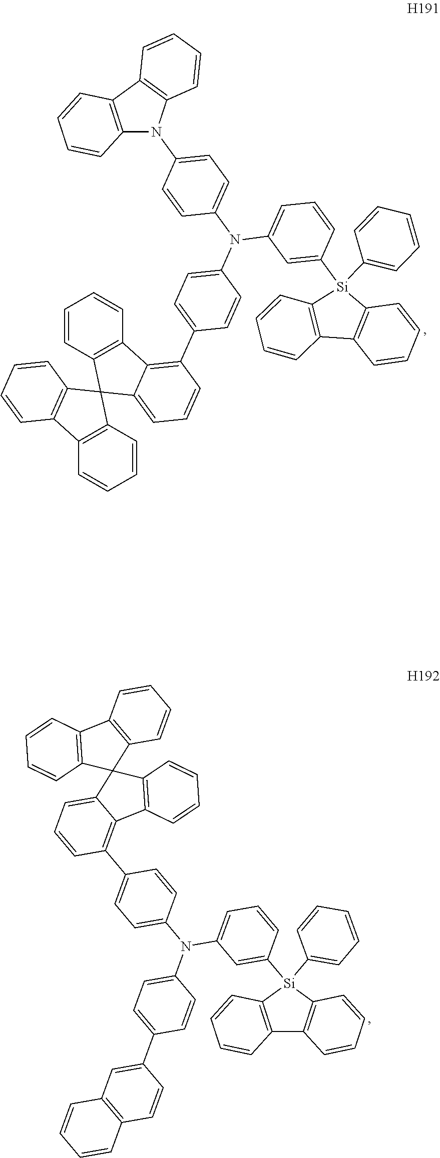 [SMILES: c1ccc([Si]2(c3cccc(N(c4ccc(-c5cccc6c5-c5ccccc5C65c6ccccc6-c6ccccc65)cc4)c4ccc(-n5c6ccccc6c6ccccc65)cc4)c3)c3ccccc3-c3ccccc32)cc1 ; c1ccc([Si]2(c3cccc(N(c4ccc(-c5ccc6ccccc6c5)cc4)c4ccc(-c5cccc6c5-c5ccccc5C65c6ccccc6-c6ccccc65)cc4)c3)c3ccccc3-c3ccccc32)cc1] 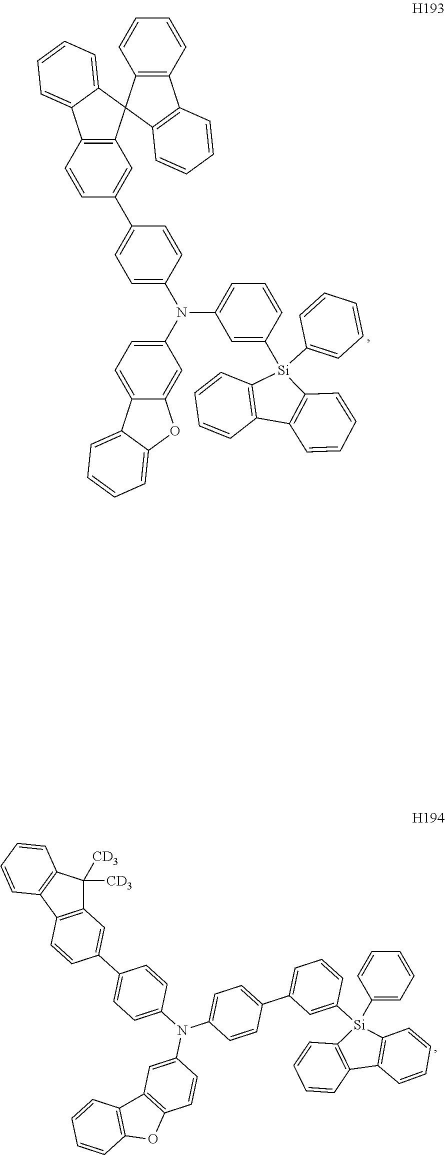 [SMILES: c1ccc([Si]2(c3cccc(N(c4ccc(-c5ccc6c(c5)C5(c7ccccc7-c7ccccc75)c5ccccc5-6)cc4)c4ccc5c(c4)oc4ccccc45)c3)c3ccccc3-c3ccccc32)cc1 ; [2H]C([2H])([2H])C1(C([2H])([2H])[2H])c2ccccc2-c2ccc(-c3ccc(N(c4ccc(-c5cccc([Si]6(c7ccccc7)c7ccccc7-c7ccccc76)c5)cc4)c4ccc5oc6ccccc6c5c4)cc3)cc21] 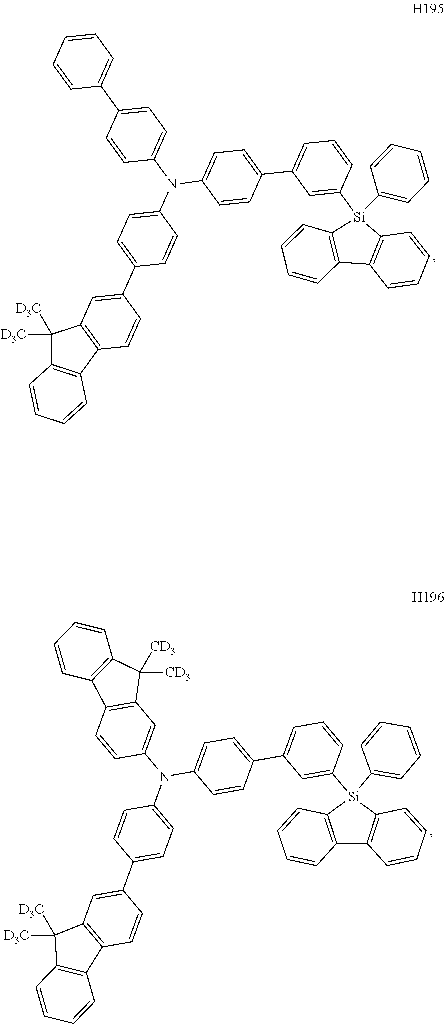 [SMILES: [2H]C([2H])([2H])C1(C([2H])([2H])[2H])c2ccccc2-c2ccc(-c3ccc(N(c4ccc(-c5ccccc5)cc4)c4ccc(-c5cccc([Si]6(c7ccccc7)c7ccccc7-c7ccccc76)c5)cc4)cc3)cc21 ; [2H]C([2H])([2H])C1(C([2H])([2H])[2H])c2ccccc2-c2ccc(-c3ccc(N(c4ccc(-c5cccc([Si]6(c7ccccc7)c7ccccc7-c7ccccc76)c5)cc4)c4ccc5c(c4)C(C([2H])([2H])[2H])(C([2H])([2H])[2H])c4ccccc4-5)cc3)cc21] 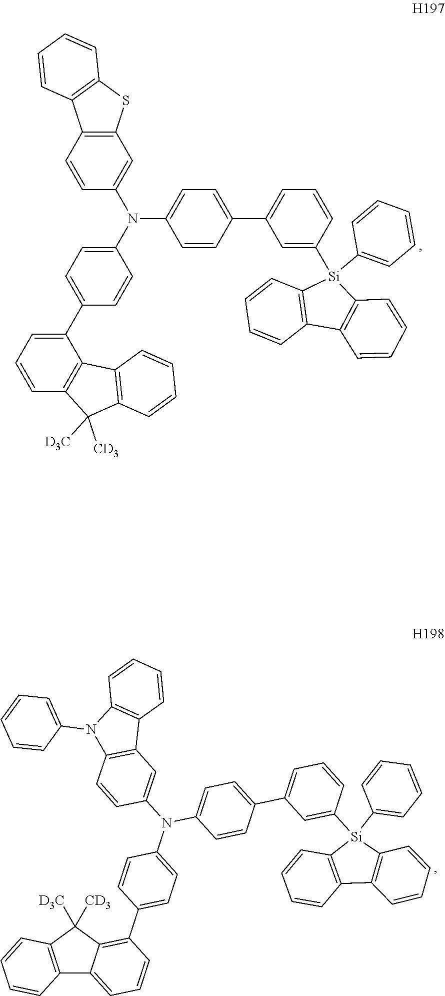 [SMILES: [2H]C([2H])([2H])C1(C([2H])([2H])[2H])c2ccccc2-c2c(-c3ccc(N(c4ccc(-c5cccc([Si]6(c7ccccc7)c7ccccc7-c7ccccc76)c5)cc4)c4ccc5c(c4)sc4ccccc45)cc3)cccc21 ; [2H]C([2H])([2H])C1(C([2H])([2H])[2H])c2ccccc2-c2cccc(-c3ccc(N(c4ccc(-c5cccc([Si]6(c7ccccc7)c7ccccc7-c7ccccc76)c5)cc4)c4ccc5c(c4)c4ccccc4n5-c4ccccc4)cc3)c21] 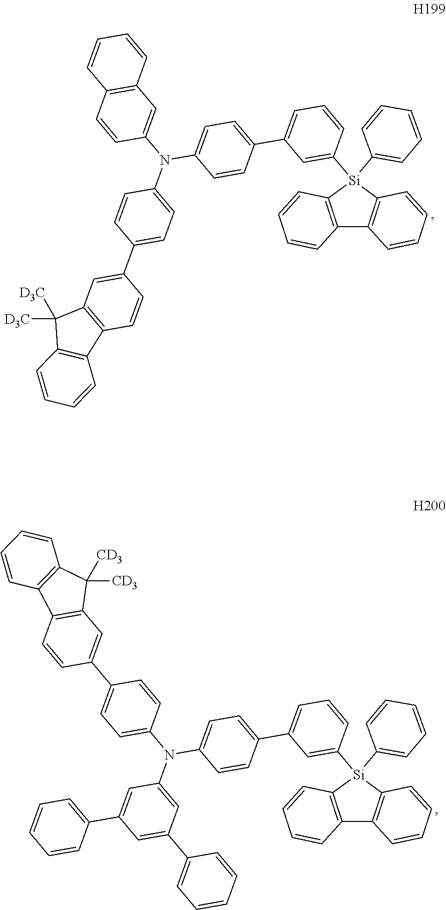 [SMILES: [2H]C([2H])([2H])C1(C([2H])([2H])[2H])c2ccccc2-c2ccc(-c3ccc(N(c4ccc(-c5cccc([Si]6(c7ccccc7)c7ccccc7-c7ccccc76)c5)cc4)c4ccc5ccccc5c4)cc3)cc21 ; [2H]C([2H])([2H])C1(C([2H])([2H])[2H])c2ccccc2-c2ccc(-c3ccc(N(c4ccc(-c5cccc([Si]6(c7ccccc7)c7ccccc7-c7ccccc76)c5)cc4)c4cc(-c5ccccc5)cc(-c5ccccc5)c4)cc3)cc21] 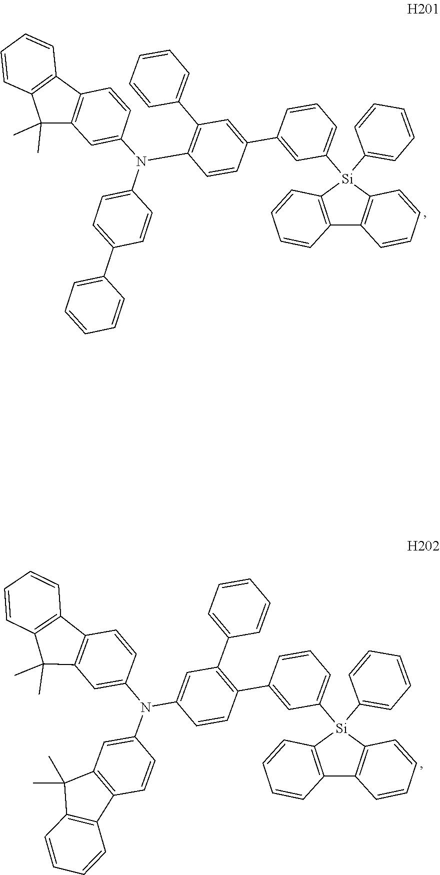 [SMILES: CC1(C)c2ccccc2-c2ccc(N(c3ccc(-c4ccccc4)cc3)c3ccc(-c4cccc([Si]5(c6ccccc6)c6ccccc6-c6ccccc65)c4)cc3-c3ccccc3)cc21 ; CC1(C)c2ccccc2-c2ccc(N(c3ccc(-c4cccc([Si]5(c6ccccc6)c6ccccc6-c6ccccc65)c4)c(-c4ccccc4)c3)c3ccc4c(c3)C(C)(C)c3ccccc3-4)cc21] 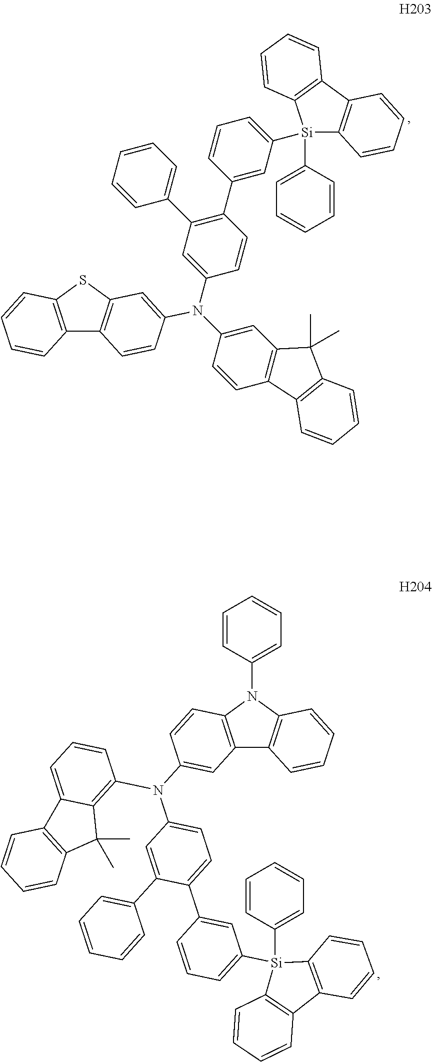 [SMILES: CC1(C)c2ccccc2-c2ccc(N(c3ccc(-c4cccc([Si]5(c6ccccc6)c6ccccc6-c6ccccc65)c4)c(-c4ccccc4)c3)c3ccc4c(c3)sc3ccccc34)cc21 ; CC1(C)c2ccccc2-c2cccc(N(c3ccc(-c4cccc([Si]5(c6ccccc6)c6ccccc6-c6ccccc65)c4)c(-c4ccccc4)c3)c3ccc4c(c3)c3ccccc3n4-c3ccccc3)c21] 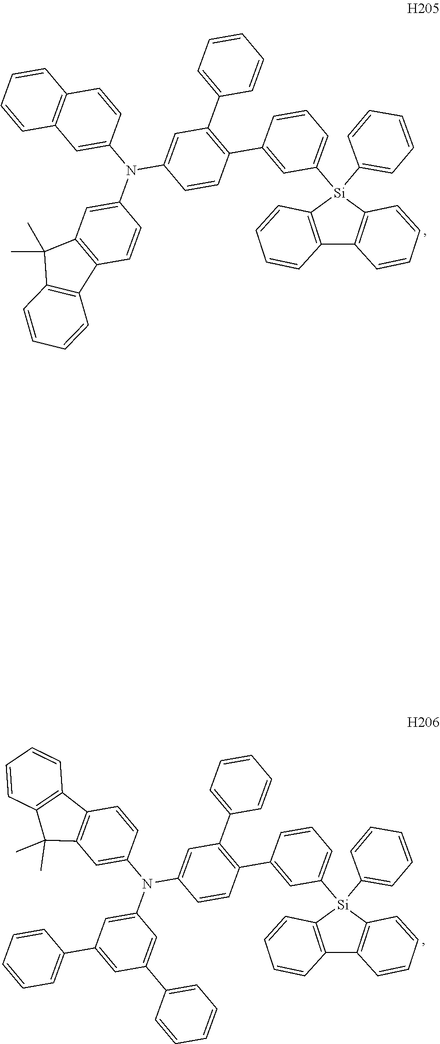 [SMILES: CC1(C)c2ccccc2-c2ccc(N(c3ccc(-c4cccc([Si]5(c6ccccc6)c6ccccc6-c6ccccc65)c4)c(-c4ccccc4)c3)c3ccc4ccccc4c3)cc21 ; CC1(C)c2ccccc2-c2ccc(N(c3cc(-c4ccccc4)cc(-c4ccccc4)c3)c3ccc(-c4cccc([Si]5(c6ccccc6)c6ccccc6-c6ccccc65)c4)c(-c4ccccc4)c3)cc21] 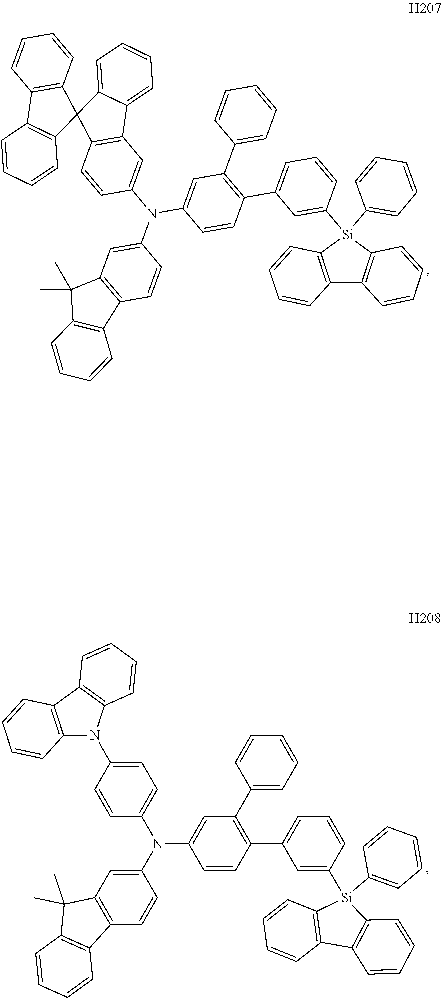 [SMILES: CC1(C)c2ccccc2-c2ccc(N(c3ccc(-c4cccc([Si]5(c6ccccc6)c6ccccc6-c6ccccc65)c4)c(-c4ccccc4)c3)c3ccc4c(c3)-c3ccccc3C43c4ccccc4-c4ccccc43)cc21 ; CC1(C)c2ccccc2-c2ccc(N(c3ccc(-n4c5ccccc5c5ccccc54)cc3)c3ccc(-c4cccc([Si]5(c6ccccc6)c6ccccc6-c6ccccc65)c4)c(-c4ccccc4)c3)cc21] 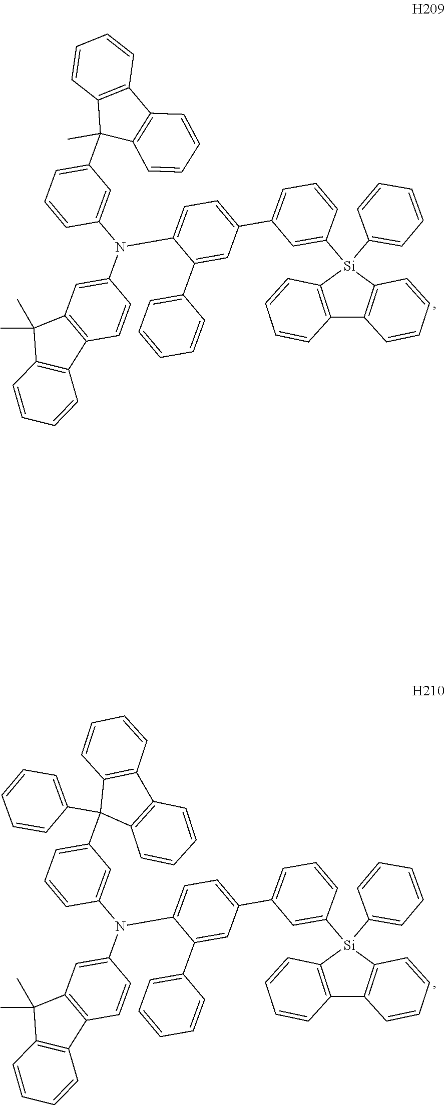 [SMILES: CC1(C)c2ccccc2-c2ccc(N(c3cccc(C4(C)c5ccccc5-c5ccccc54)c3)c3ccc(-c4cccc([Si]5(c6ccccc6)c6ccccc6-c6ccccc65)c4)cc3-c3ccccc3)cc21 ; CC1(C)c2ccccc2-c2ccc(N(c3cccc(C4(c5ccccc5)c5ccccc5-c5ccccc54)c3)c3ccc(-c4cccc([Si]5(c6ccccc6)c6ccccc6-c6ccccc65)c4)cc3-c3ccccc3)cc21] 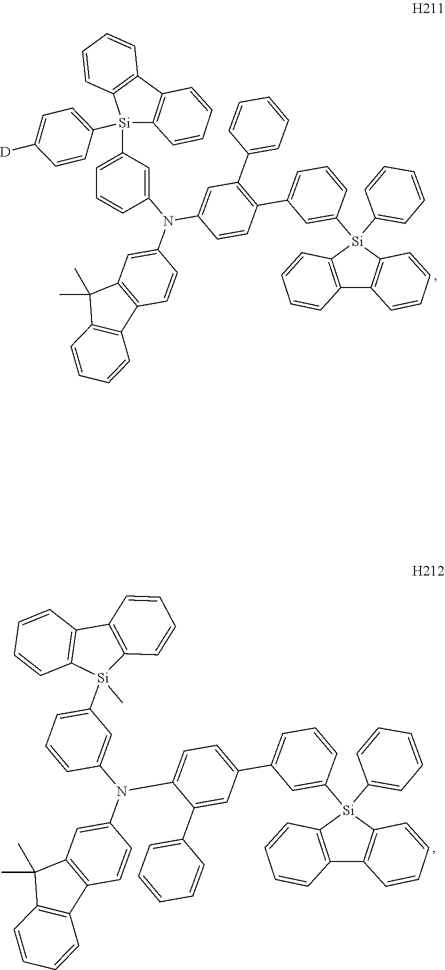 [SMILES: [2H]c1ccc([Si]2(c3cccc(N(c4ccc(-c5cccc([Si]6(c7ccccc7)c7ccccc7-c7ccccc76)c5)c(-c5ccccc5)c4)c4ccc5c(c4)C(C)(C)c4ccccc4-5)c3)c3ccccc3-c3ccccc32)cc1 ; CC1(C)c2ccccc2-c2ccc(N(c3cccc([Si]4(C)c5ccccc5-c5ccccc54)c3)c3ccc(-c4cccc([Si]5(c6ccccc6)c6ccccc6-c6ccccc65)c4)cc3-c3ccccc3)cc21] 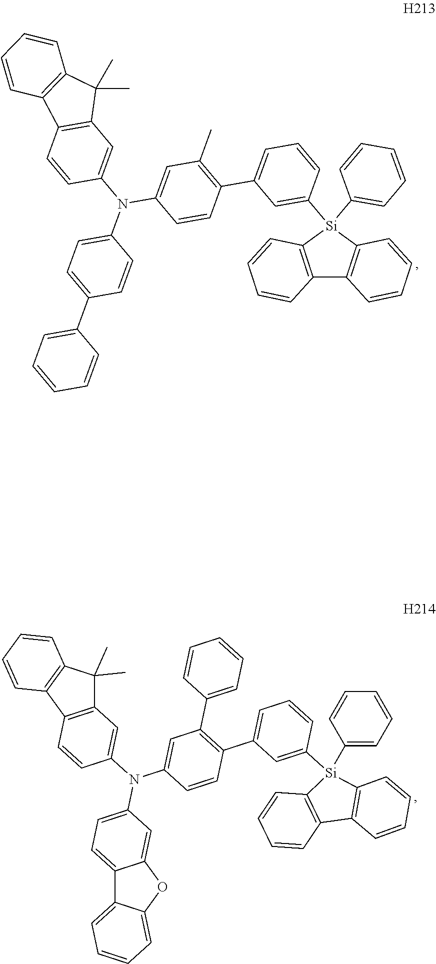 [SMILES: Cc1cc(N(c2ccc(-c3ccccc3)cc2)c2ccc3c(c2)C(C)(C)c2ccccc2-3)ccc1-c1cccc([Si]2(c3ccccc3)c3ccccc3-c3ccccc32)c1 ; CC1(C)c2ccccc2-c2ccc(N(c3ccc(-c4cccc([Si]5(c6ccccc6)c6ccccc6-c6ccccc65)c4)c(-c4ccccc4)c3)c3ccc4c(c3)oc3ccccc34)cc21] 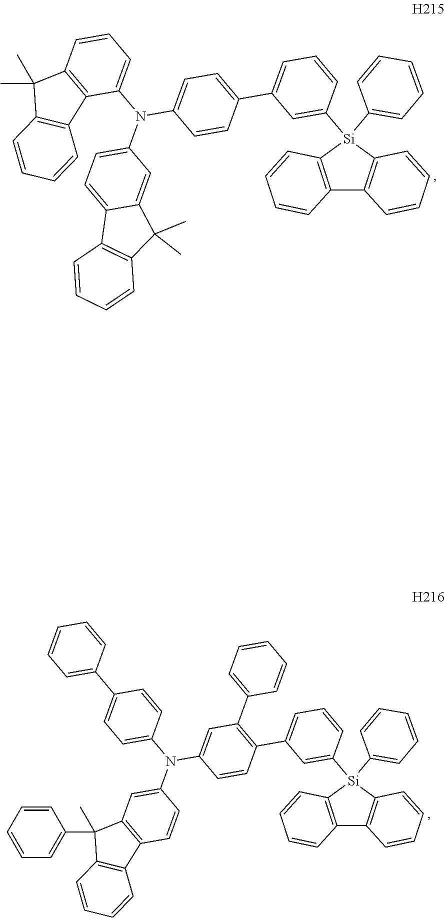 [SMILES: CC1(C)c2ccccc2-c2ccc(N(c3ccc(-c4cccc([Si]5(c6ccccc6)c6ccccc6-c6ccccc65)c4)cc3)c3cccc4c3-c3ccccc3C4(C)C)cc21 ; CC1(c2ccccc2)c2ccccc2-c2ccc(N(c3ccc(-c4ccccc4)cc3)c3ccc(-c4cccc([Si]5(c6ccccc6)c6ccccc6-c6ccccc65)c4)c(-c4ccccc4)c3)cc21] 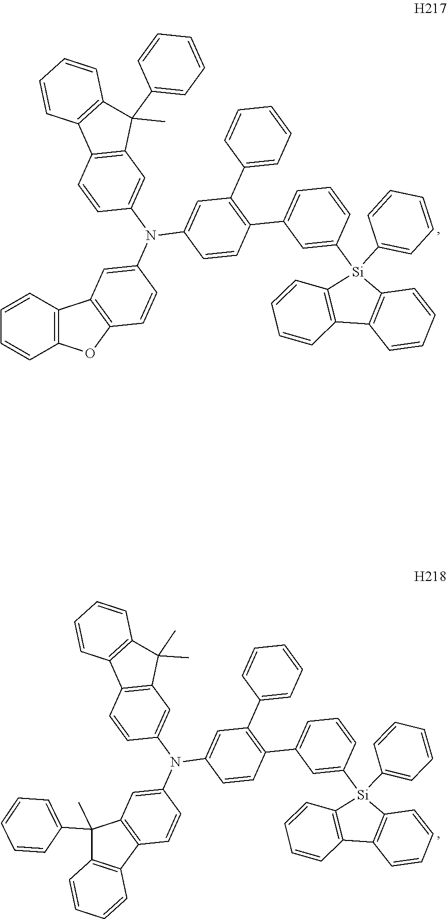 [SMILES: CC1(c2ccccc2)c2ccccc2-c2ccc(N(c3ccc(-c4cccc([Si]5(c6ccccc6)c6ccccc6-c6ccccc65)c4)c(-c4ccccc4)c3)c3ccc4oc5ccccc5c4c3)cc21 ; CC1(C)c2ccccc2-c2ccc(N(c3ccc(-c4cccc([Si]5(c6ccccc6)c6ccccc6-c6ccccc65)c4)c(-c4ccccc4)c3)c3ccc4c(c3)C(C)(c3ccccc3)c3ccccc3-4)cc21] 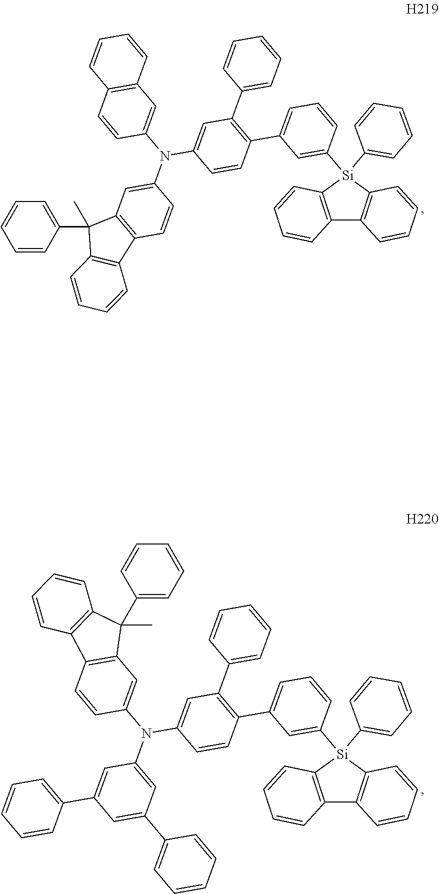 [SMILES: CC1(c2ccccc2)c2ccccc2-c2ccc(N(c3ccc(-c4cccc([Si]5(c6ccccc6)c6ccccc6-c6ccccc65)c4)c(-c4ccccc4)c3)c3ccc4ccccc4c3)cc21 ; CC1(c2ccccc2)c2ccccc2-c2ccc(N(c3cc(-c4ccccc4)cc(-c4ccccc4)c3)c3ccc(-c4cccc([Si]5(c6ccccc6)c6ccccc6-c6ccccc65)c4)c(-c4ccccc4)c3)cc21] 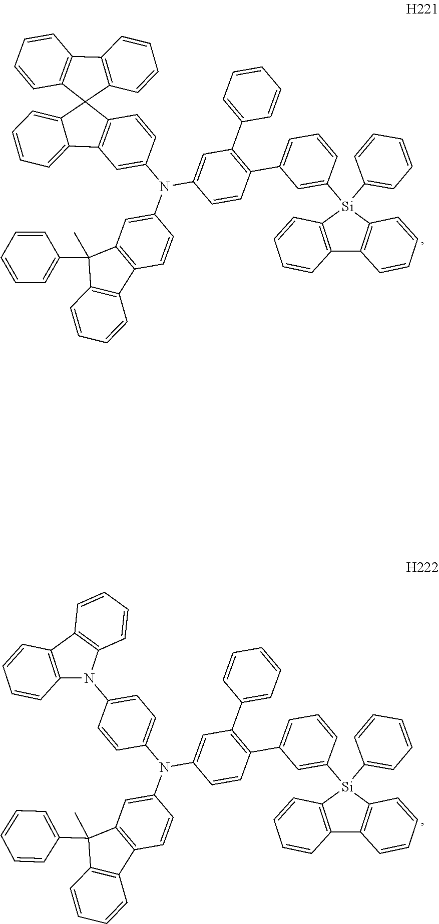 [SMILES: CC1(c2ccccc2)c2ccccc2-c2ccc(N(c3ccc(-c4cccc([Si]5(c6ccccc6)c6ccccc6-c6ccccc65)c4)c(-c4ccccc4)c3)c3ccc4c(c3)-c3ccccc3C43c4ccccc4-c4ccccc43)cc21 ; CC1(c2ccccc2)c2ccccc2-c2ccc(N(c3ccc(-n4c5ccccc5c5ccccc54)cc3)c3ccc(-c4cccc([Si]5(c6ccccc6)c6ccccc6-c6ccccc65)c4)c(-c4ccccc4)c3)cc21] 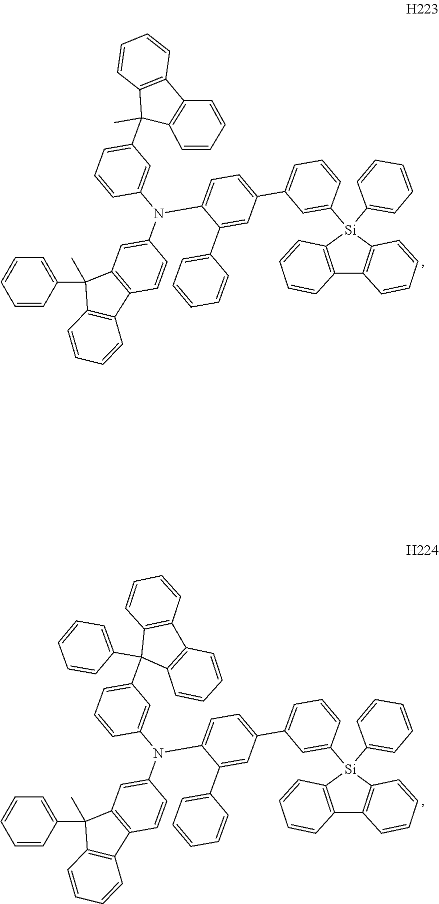 [SMILES: CC1(c2cccc(N(c3ccc4c(c3)C(C)(c3ccccc3)c3ccccc3-4)c3ccc(-c4cccc([Si]5(c6ccccc6)c6ccccc6-c6ccccc65)c4)cc3-c3ccccc3)c2)c2ccccc2-c2ccccc21 ; CC1(c2ccccc2)c2ccccc2-c2ccc(N(c3cccc(C4(c5ccccc5)c5ccccc5-c5ccccc54)c3)c3ccc(-c4cccc([Si]5(c6ccccc6)c6ccccc6-c6ccccc65)c4)cc3-c3ccccc3)cc21] 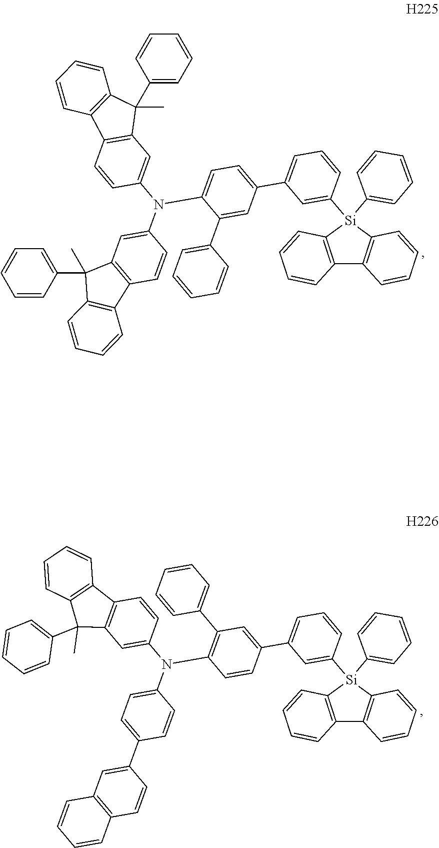 [SMILES: CC1(c2ccccc2)c2ccccc2-c2ccc(N(c3ccc4c(c3)C(C)(c3ccccc3)c3ccccc3-4)c3ccc(-c4cccc([Si]5(c6ccccc6)c6ccccc6-c6ccccc65)c4)cc3-c3ccccc3)cc21 ; CC1(c2ccccc2)c2ccccc2-c2ccc(N(c3ccc(-c4ccc5ccccc5c4)cc3)c3ccc(-c4cccc([Si]5(c6ccccc6)c6ccccc6-c6ccccc65)c4)cc3-c3ccccc3)cc21] 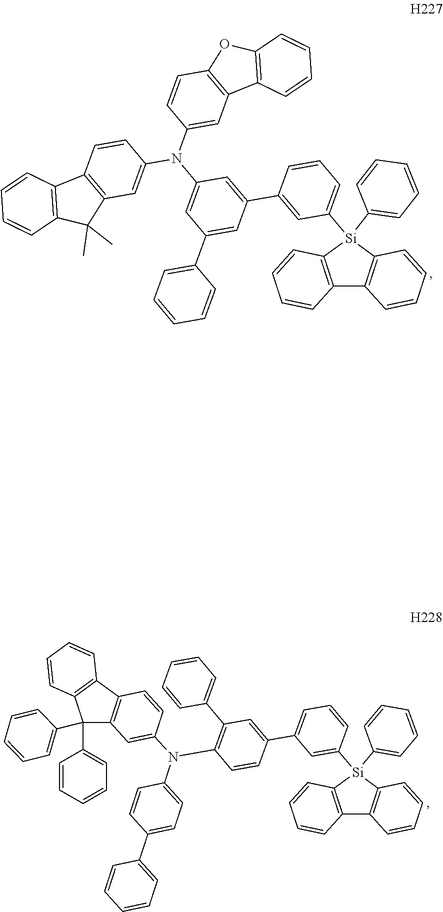 [SMILES: CC1(C)c2ccccc2-c2ccc(N(c3cc(-c4ccccc4)cc(-c4cccc([Si]5(c6ccccc6)c6ccccc6-c6ccccc65)c4)c3)c3ccc4oc5ccccc5c4c3)cc21 ; c1ccc(-c2ccc(N(c3ccc4c(c3)C(c3ccccc3)(c3ccccc3)c3ccccc3-4)c3ccc(-c4cccc([Si]5(c6ccccc6)c6ccccc6-c6ccccc65)c4)cc3-c3ccccc3)cc2)cc1] 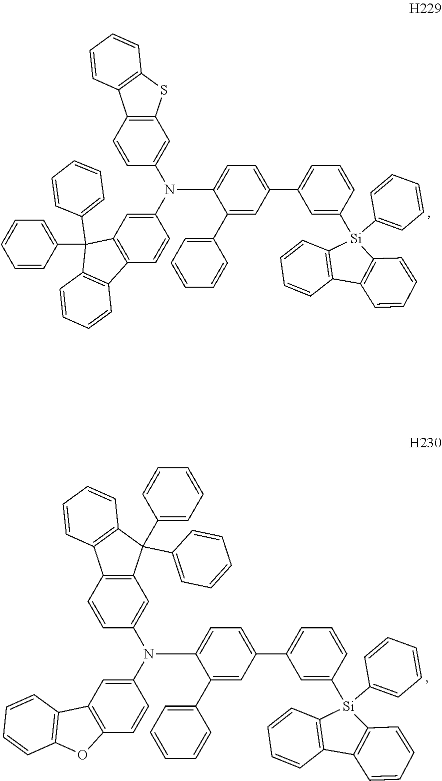 [SMILES: c1ccc(-c2cc(-c3cccc([Si]4(c5ccccc5)c5ccccc5-c5ccccc54)c3)ccc2N(c2ccc3c(c2)C(c2ccccc2)(c2ccccc2)c2ccccc2-3)c2ccc3c(c2)sc2ccccc23)cc1 ; c1ccc(-c2cc(-c3cccc([Si]4(c5ccccc5)c5ccccc5-c5ccccc54)c3)ccc2N(c2ccc3c(c2)C(c2ccccc2)(c2ccccc2)c2ccccc2-3)c2ccc3oc4ccccc4c3c2)cc1] 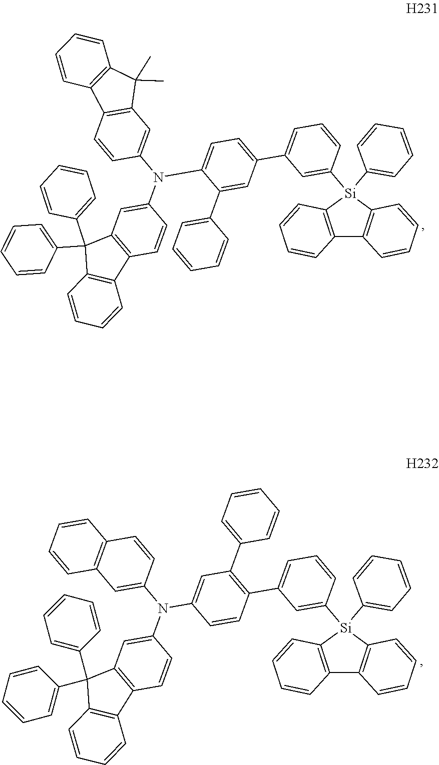 [SMILES: CC1(C)c2ccccc2-c2ccc(N(c3ccc4c(c3)C(c3ccccc3)(c3ccccc3)c3ccccc3-4)c3ccc(-c4cccc([Si]5(c6ccccc6)c6ccccc6-c6ccccc65)c4)cc3-c3ccccc3)cc21 ; c1ccc(-c2cc(N(c3ccc4c(c3)C(c3ccccc3)(c3ccccc3)c3ccccc3-4)c3ccc4ccccc4c3)ccc2-c2cccc([Si]3(c4ccccc4)c4ccccc4-c4ccccc43)c2)cc1] 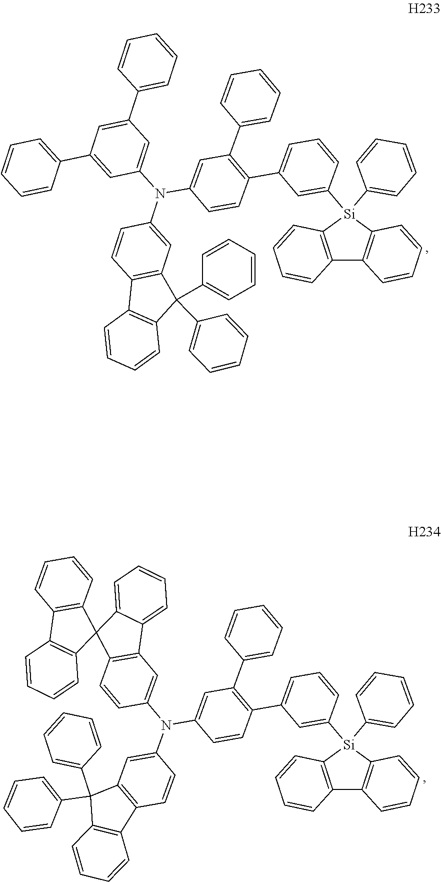 [SMILES: c1ccc(-c2cc(-c3ccccc3)cc(N(c3ccc(-c4cccc([Si]5(c6ccccc6)c6ccccc6-c6ccccc65)c4)c(-c4ccccc4)c3)c3ccc4c(c3)C(c3ccccc3)(c3ccccc3)c3ccccc3-4)c2)cc1 ; c1ccc(-c2cc(N(c3ccc4c(c3)-c3ccccc3C43c4ccccc4-c4ccccc43)c3ccc4c(c3)C(c3ccccc3)(c3ccccc3)c3ccccc3-4)ccc2-c2cccc([Si]3(c4ccccc4)c4ccccc4-c4ccccc43)c2)cc1] 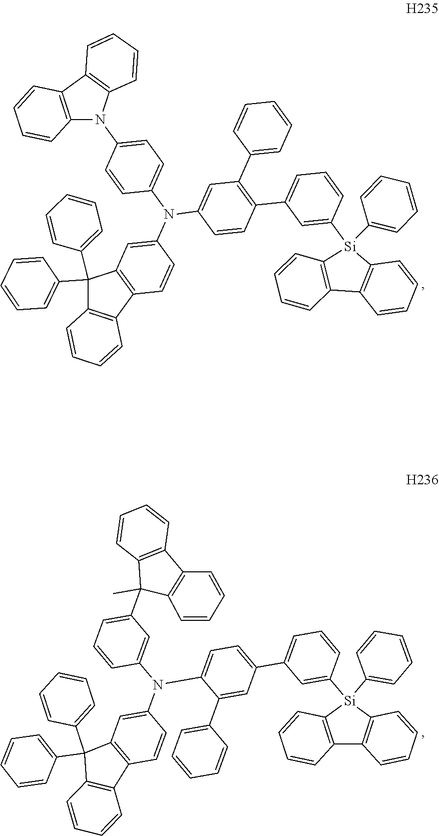 [SMILES: c1ccc(-c2cc(N(c3ccc(-n4c5ccccc5c5ccccc54)cc3)c3ccc4c(c3)C(c3ccccc3)(c3ccccc3)c3ccccc3-4)ccc2-c2cccc([Si]3(c4ccccc4)c4ccccc4-c4ccccc43)c2)cc1 ; CC1(c2cccc(N(c3ccc4c(c3)C(c3ccccc3)(c3ccccc3)c3ccccc3-4)c3ccc(-c4cccc([Si]5(c6ccccc6)c6ccccc6-c6ccccc65)c4)cc3-c3ccccc3)c2)c2ccccc2-c2ccccc21] 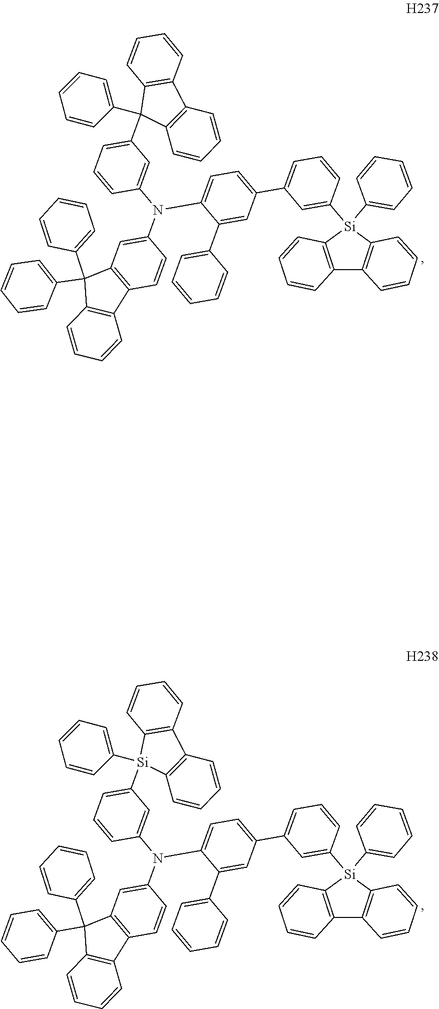 [SMILES: c1ccc(-c2cc(-c3cccc([Si]4(c5ccccc5)c5ccccc5-c5ccccc54)c3)ccc2N(c2cccc(C3(c4ccccc4)c4ccccc4-c4ccccc43)c2)c2ccc3c(c2)C(c2ccccc2)(c2ccccc2)c2ccccc2-3)cc1 ; c1ccc(-c2cc(-c3cccc([Si]4(c5ccccc5)c5ccccc5-c5ccccc54)c3)ccc2N(c2cccc([Si]3(c4ccccc4)c4ccccc4-c4ccccc43)c2)c2ccc3c(c2)C(c2ccccc2)(c2ccccc2)c2ccccc2-3)cc1] 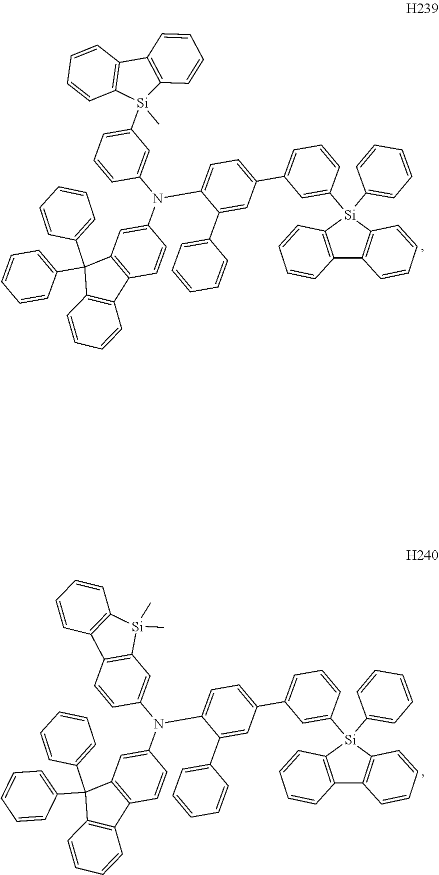 [SMILES: C[Si]1(c2cccc(N(c3ccc4c(c3)C(c3ccccc3)(c3ccccc3)c3ccccc3-4)c3ccc(-c4cccc([Si]5(c6ccccc6)c6ccccc6-c6ccccc65)c4)cc3-c3ccccc3)c2)c2ccccc2-c2ccccc21 ; C[Si]1(C)c2ccccc2-c2ccc(N(c3ccc4c(c3)C(c3ccccc3)(c3ccccc3)c3ccccc3-4)c3ccc(-c4cccc([Si]5(c6ccccc6)c6ccccc6-c6ccccc65)c4)cc3-c3ccccc3)cc21] 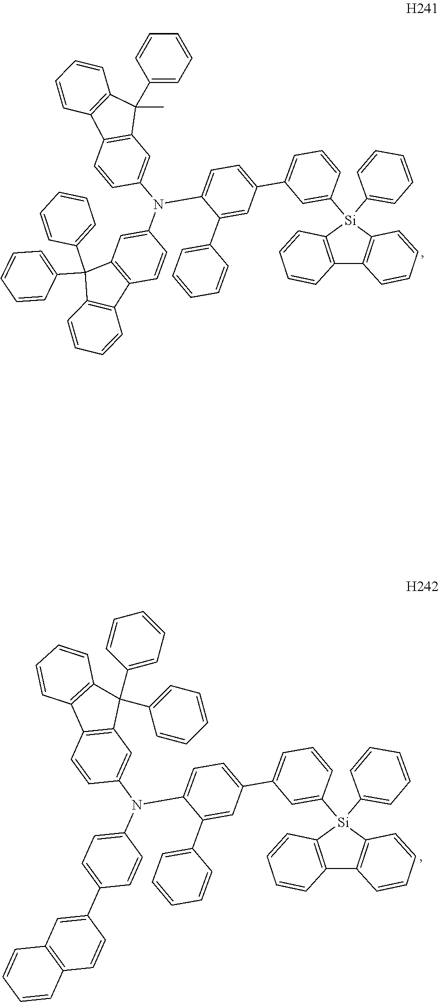 [SMILES: CC1(c2ccccc2)c2ccccc2-c2ccc(N(c3ccc4c(c3)C(c3ccccc3)(c3ccccc3)c3ccccc3-4)c3ccc(-c4cccc([Si]5(c6ccccc6)c6ccccc6-c6ccccc65)c4)cc3-c3ccccc3)cc21 ; c1ccc(-c2cc(-c3cccc([Si]4(c5ccccc5)c5ccccc5-c5ccccc54)c3)ccc2N(c2ccc(-c3ccc4ccccc4c3)cc2)c2ccc3c(c2)C(c2ccccc2)(c2ccccc2)c2ccccc2-3)cc1] 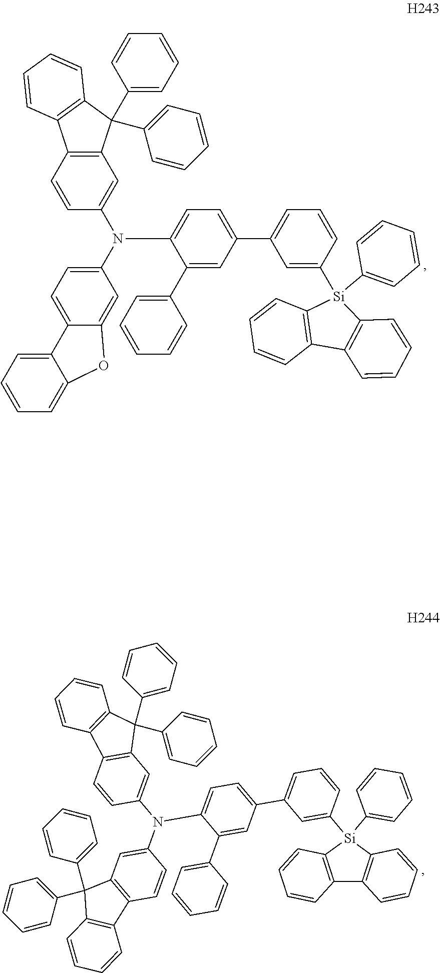 [SMILES: c1ccc(-c2cc(-c3cccc([Si]4(c5ccccc5)c5ccccc5-c5ccccc54)c3)ccc2N(c2ccc3c(c2)C(c2ccccc2)(c2ccccc2)c2ccccc2-3)c2ccc3c(c2)oc2ccccc23)cc1 ; c1ccc(-c2cc(-c3cccc([Si]4(c5ccccc5)c5ccccc5-c5ccccc54)c3)ccc2N(c2ccc3c(c2)C(c2ccccc2)(c2ccccc2)c2ccccc2-3)c2ccc3c(c2)C(c2ccccc2)(c2ccccc2)c2ccccc2-3)cc1] 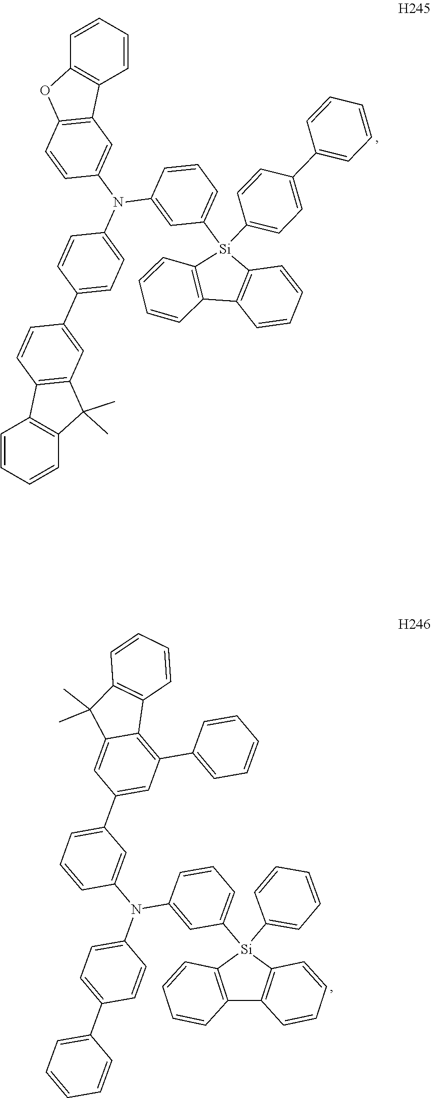 [SMILES: CC1(C)c2ccccc2-c2ccc(-c3ccc(N(c4cccc([Si]5(c6ccc(-c7ccccc7)cc6)c6ccccc6-c6ccccc65)c4)c4ccc5oc6ccccc6c5c4)cc3)cc21 ; CC1(C)c2ccccc2-c2c(-c3ccccc3)cc(-c3cccc(N(c4ccc(-c5ccccc5)cc4)c4cccc([Si]5(c6ccccc6)c6ccccc6-c6ccccc65)c4)c3)cc21] 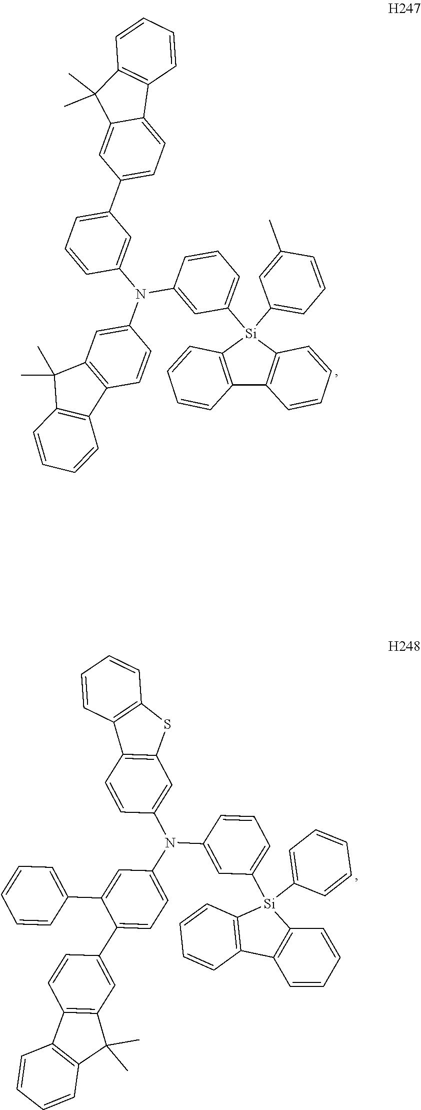 [SMILES: Cc1cccc([Si]2(c3cccc(N(c4cccc(-c5ccc6c(c5)C(C)(C)c5ccccc5-6)c4)c4ccc5c(c4)C(C)(C)c4ccccc4-5)c3)c3ccccc3-c3ccccc32)c1 ; CC1(C)c2ccccc2-c2ccc(-c3ccc(N(c4cccc([Si]5(c6ccccc6)c6ccccc6-c6ccccc65)c4)c4ccc5c(c4)sc4ccccc45)cc3-c3ccccc3)cc21] 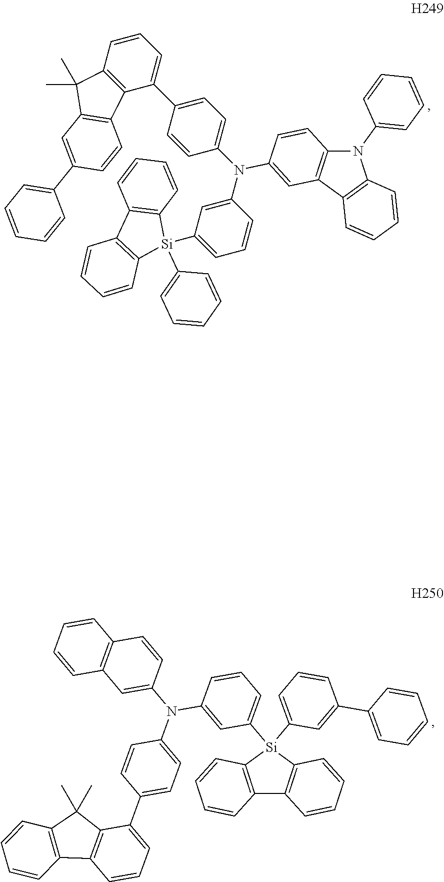 [SMILES: CC1(C)c2cc(-c3ccccc3)ccc2-c2c(-c3ccc(N(c4cccc([Si]5(c6ccccc6)c6ccccc6-c6ccccc65)c4)c4ccc5c(c4)c4ccccc4n5-c4ccccc4)cc3)cccc21 ; CC1(C)c2ccccc2-c2cccc(-c3ccc(N(c4cccc([Si]5(c6cccc(-c7ccccc7)c6)c6ccccc6-c6ccccc65)c4)c4ccc5ccccc5c4)cc3)c21] 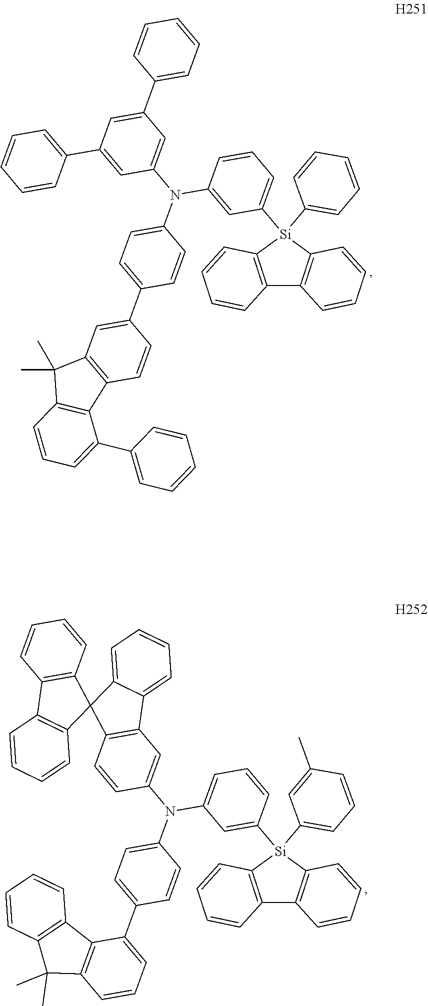 [SMILES: CC1(C)c2cc(-c3ccc(N(c4cc(-c5ccccc5)cc(-c5ccccc5)c4)c4cccc([Si]5(c6ccccc6)c6ccccc6-c6ccccc65)c4)cc3)ccc2-c2c(-c3ccccc3)cccc21 ; Cc1cccc([Si]2(c3cccc(N(c4ccc(-c5cccc6c5-c5ccccc5C6(C)C)cc4)c4ccc5c(c4)-c4ccccc4C54c5ccccc5-c5ccccc54)c3)c3ccccc3-c3ccccc32)c1] 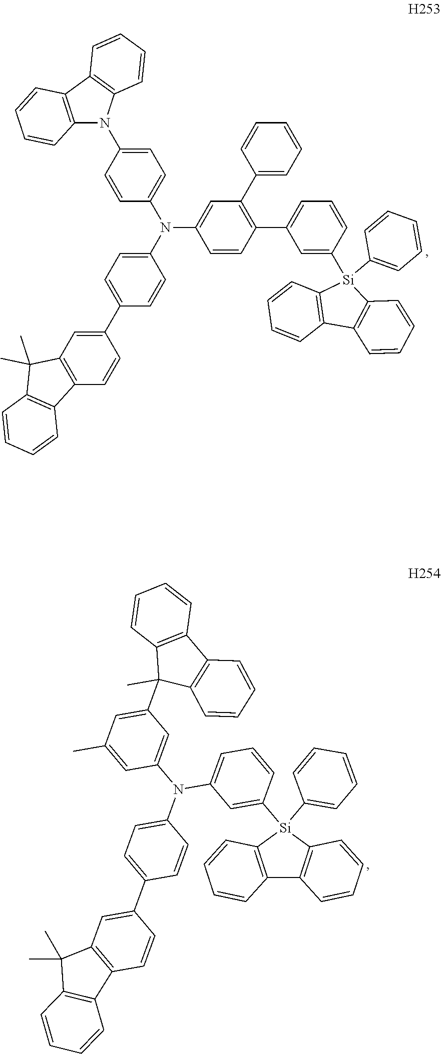 [SMILES: CC1(C)c2ccccc2-c2ccc(-c3ccc(N(c4ccc(-n5c6ccccc6c6ccccc65)cc4)c4ccc(-c5cccc([Si]6(c7ccccc7)c7ccccc7-c7ccccc76)c5)c(-c5ccccc5)c4)cc3)cc21 ; Cc1cc(N(c2ccc(-c3ccc4c(c3)C(C)(C)c3ccccc3-4)cc2)c2cccc([Si]3(c4ccccc4)c4ccccc4-c4ccccc43)c2)cc(C2(C)c3ccccc3-c3ccccc32)c1] 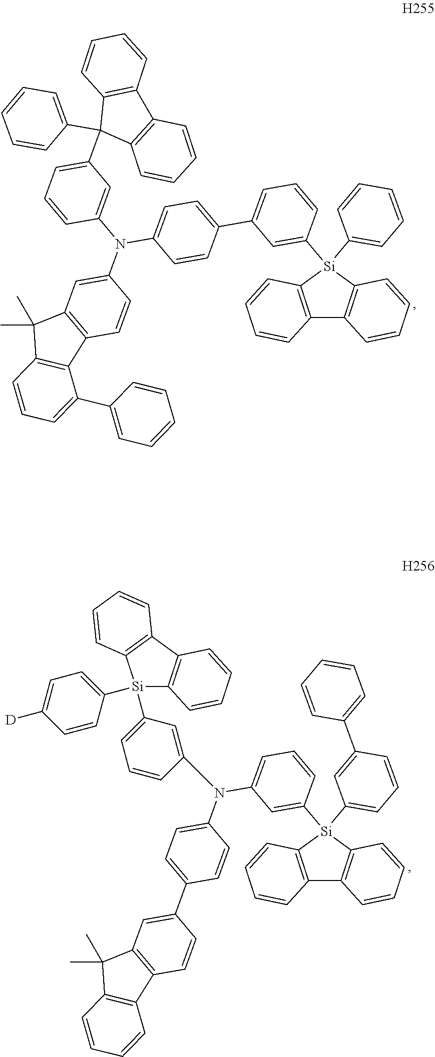 [SMILES: CC1(C)c2cc(N(c3ccc(-c4cccc([Si]5(c6ccccc6)c6ccccc6-c6ccccc65)c4)cc3)c3cccc(C4(c5ccccc5)c5ccccc5-c5ccccc54)c3)ccc2-c2c(-c3ccccc3)cccc21 ; [2H]c1ccc([Si]2(c3cccc(N(c4ccc(-c5ccc6c(c5)C(C)(C)c5ccccc5-6)cc4)c4cccc([Si]5(c6cccc(-c7ccccc7)c6)c6ccccc6-c6ccccc65)c4)c3)c3ccccc3-c3ccccc32)cc1] 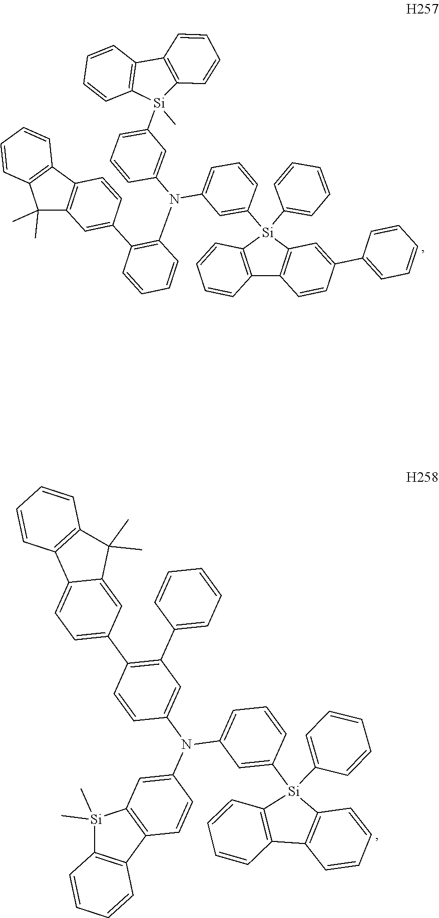 [SMILES: CC1(C)c2ccccc2-c2ccc(-c3ccccc3N(c3cccc([Si]4(C)c5ccccc5-c5ccccc54)c3)c3cccc([Si]4(c5ccccc5)c5ccccc5-c5ccc(-c6ccccc6)cc54)c3)cc21 ; CC1(C)c2ccccc2-c2ccc(-c3ccc(N(c4cccc([Si]5(c6ccccc6)c6ccccc6-c6ccccc65)c4)c4ccc5c(c4)[Si](C)(C)c4ccccc4-5)cc3-c3ccccc3)cc21] 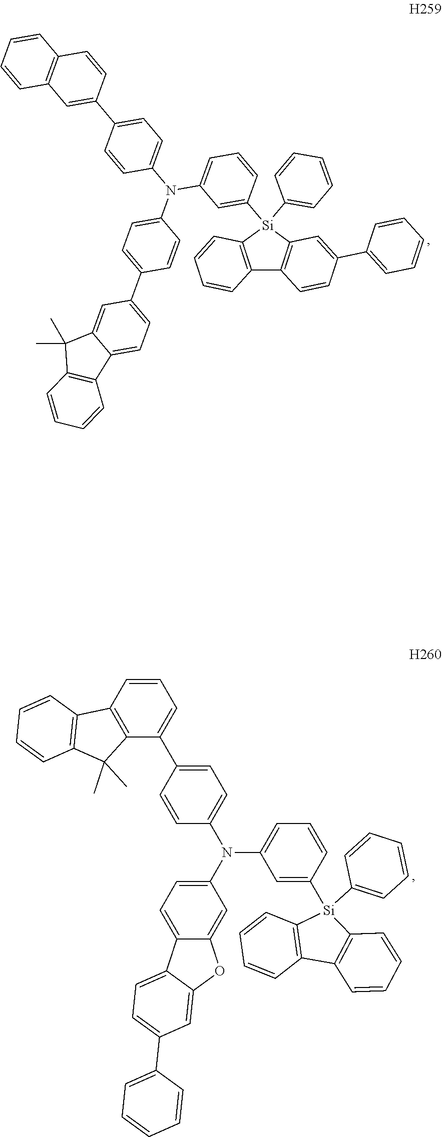 [SMILES: CC1(C)c2ccccc2-c2ccc(-c3ccc(N(c4ccc(-c5ccc6ccccc6c5)cc4)c4cccc([Si]5(c6ccccc6)c6ccccc6-c6ccc(-c7ccccc7)cc65)c4)cc3)cc21 ; CC1(C)c2ccccc2-c2cccc(-c3ccc(N(c4cccc([Si]5(c6ccccc6)c6ccccc6-c6ccccc65)c4)c4ccc5c(c4)oc4cc(-c6ccccc6)ccc45)cc3)c21] 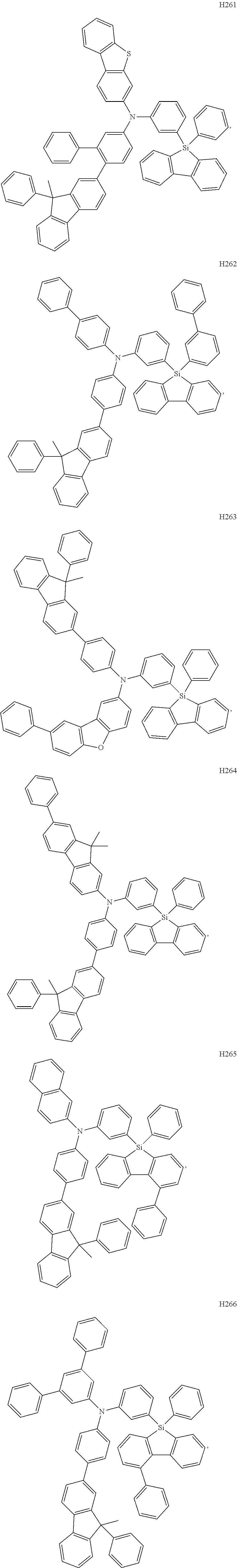 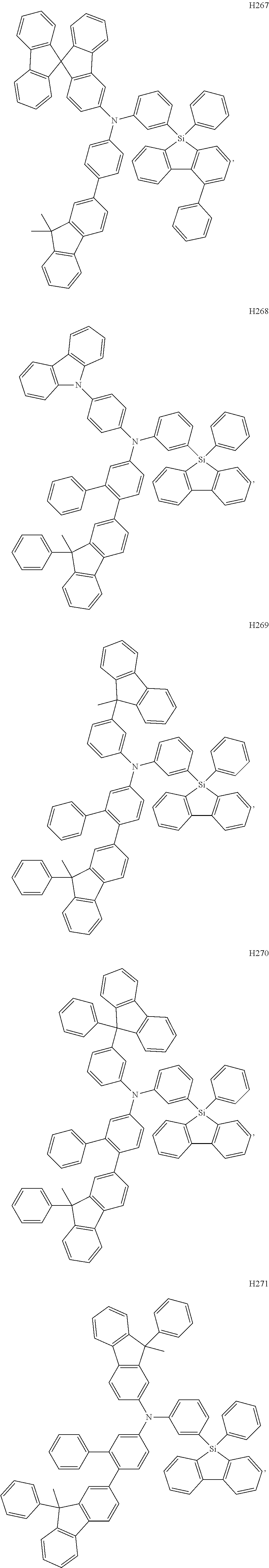 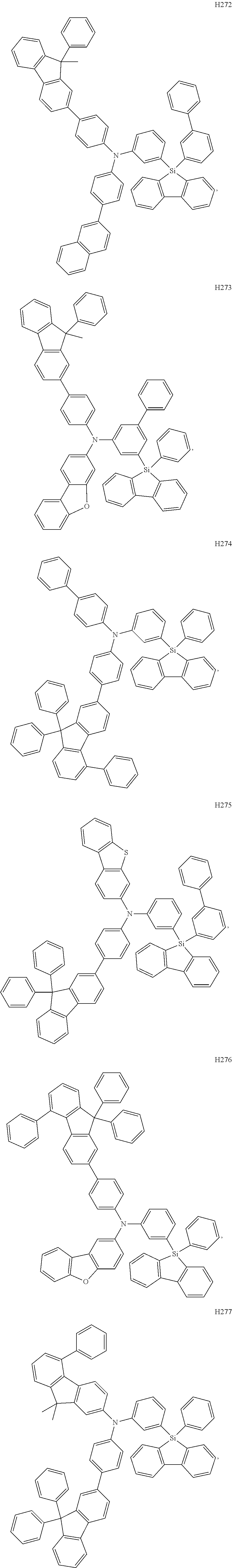 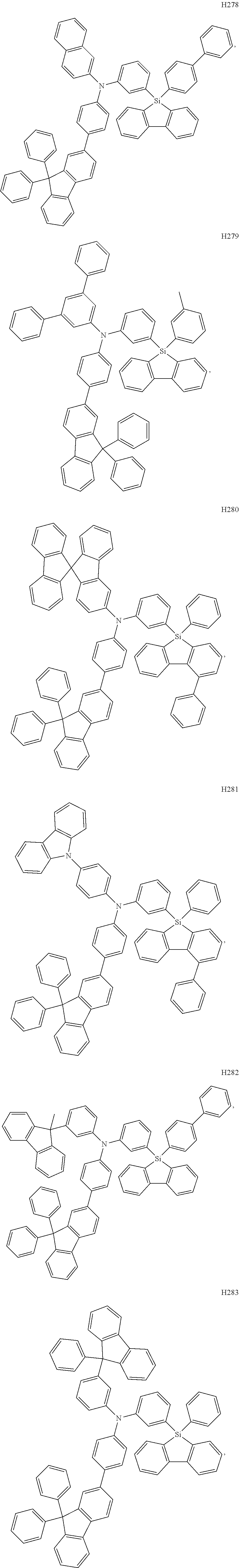 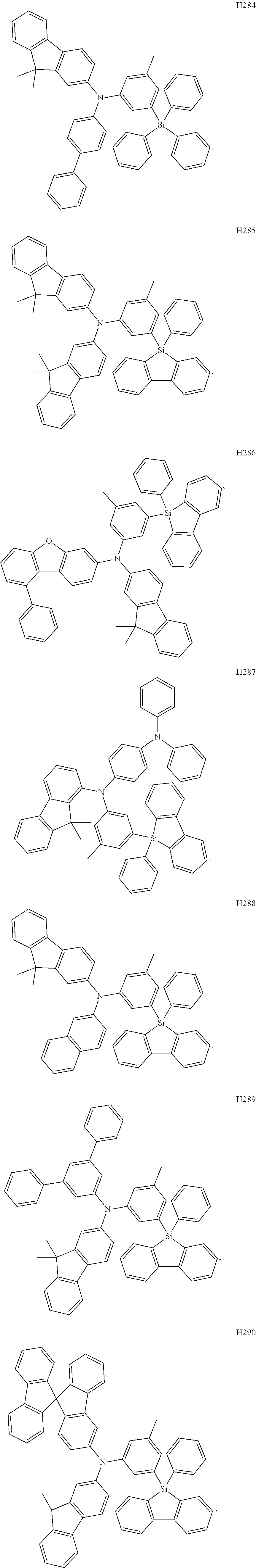 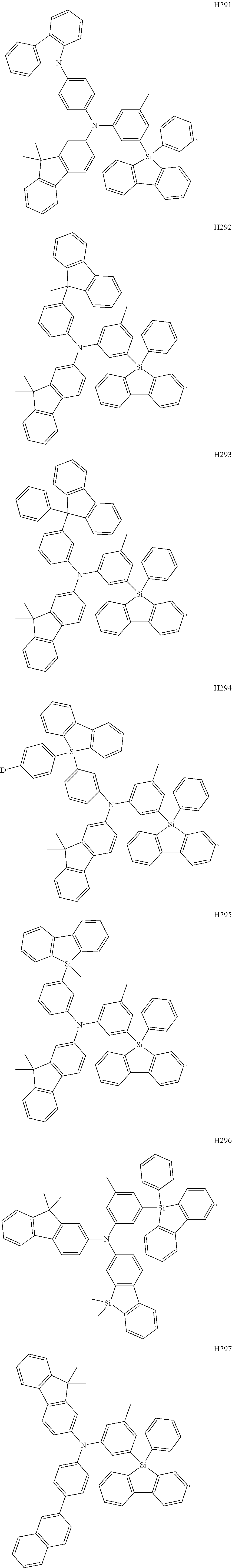 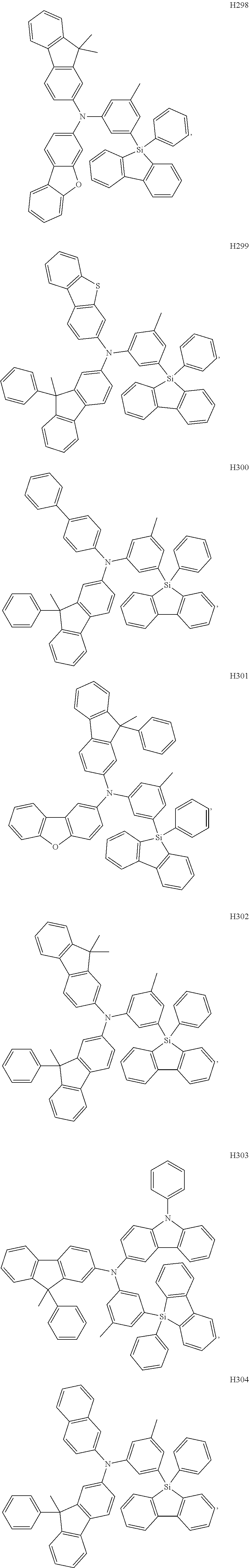 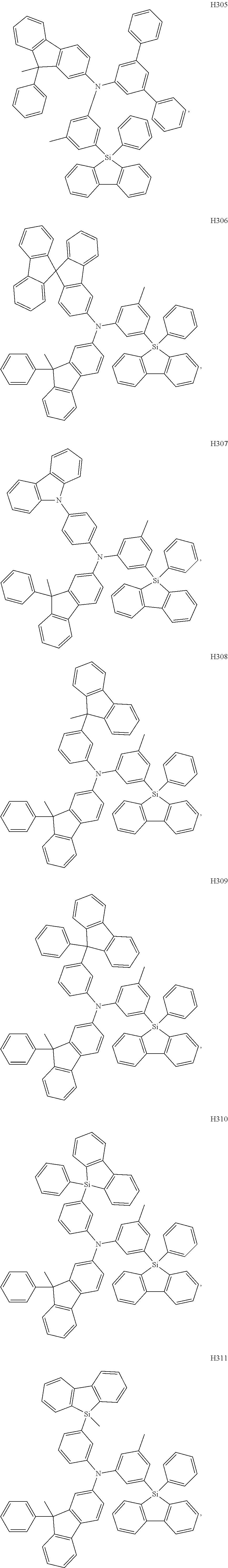 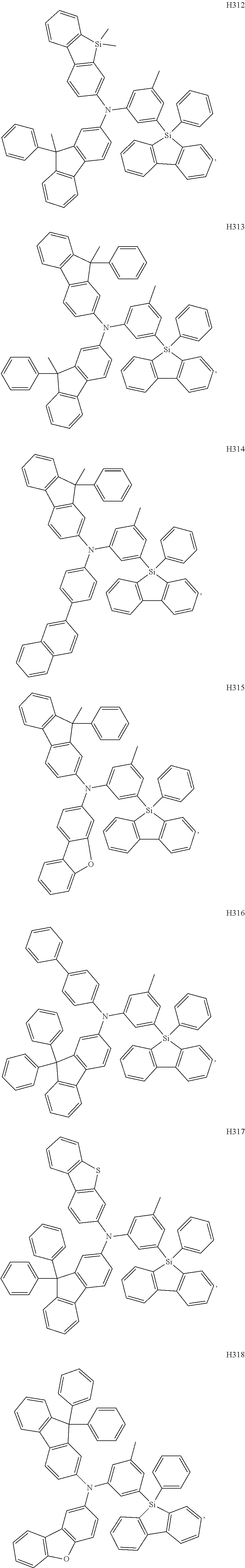 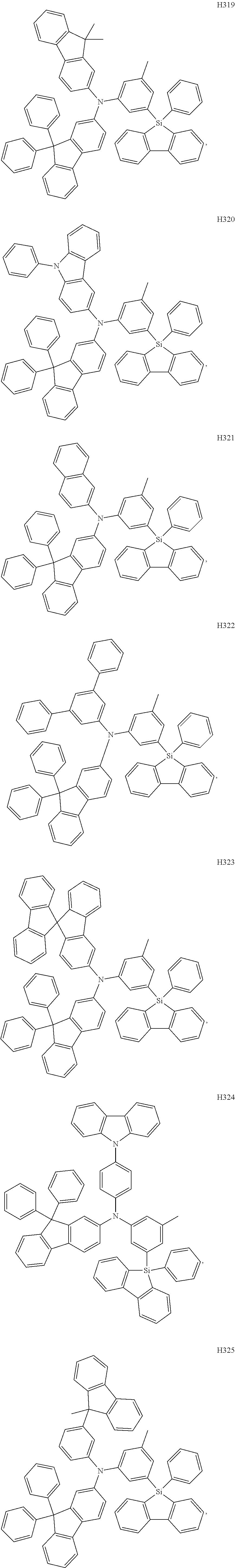 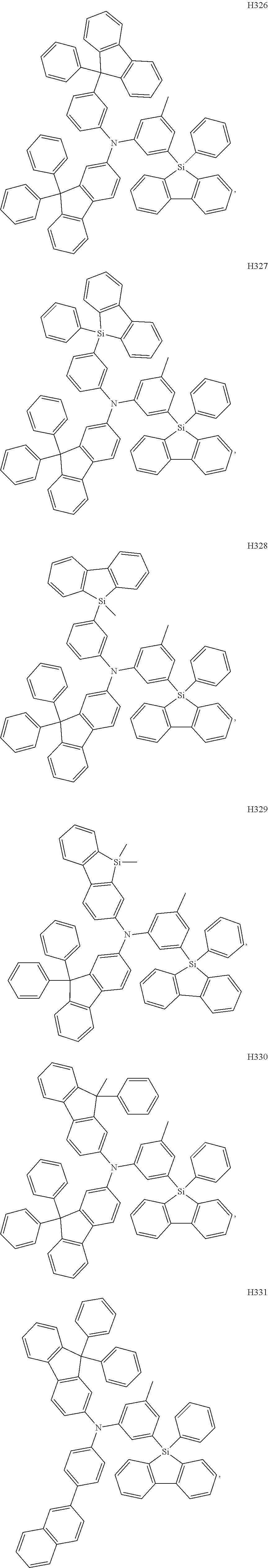 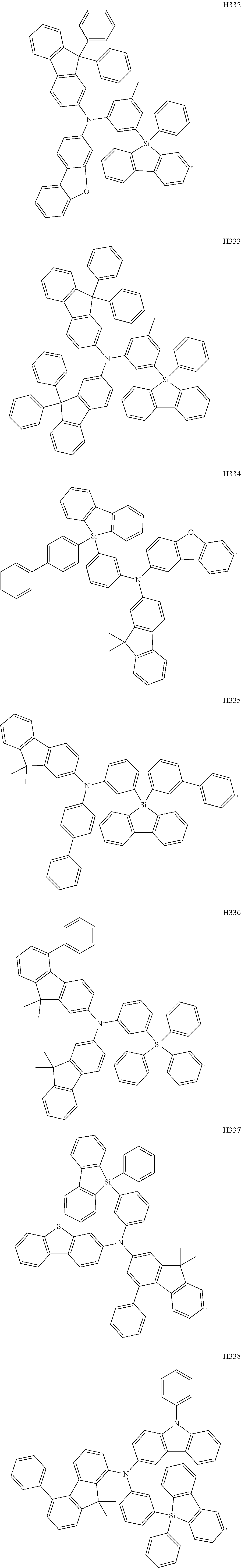 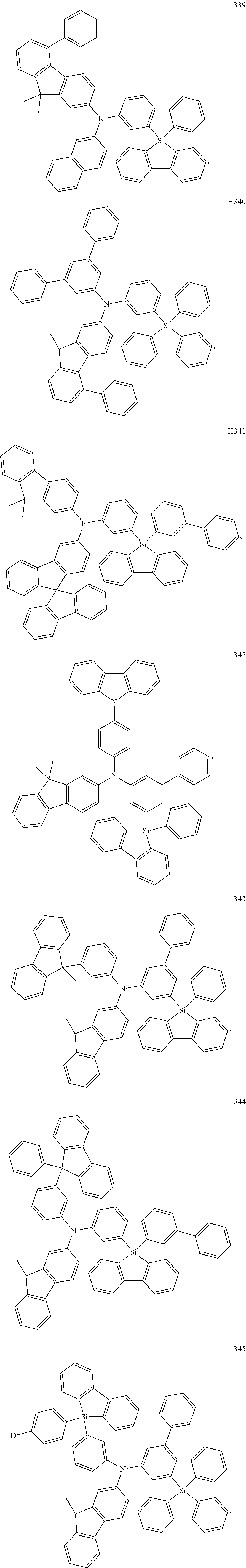 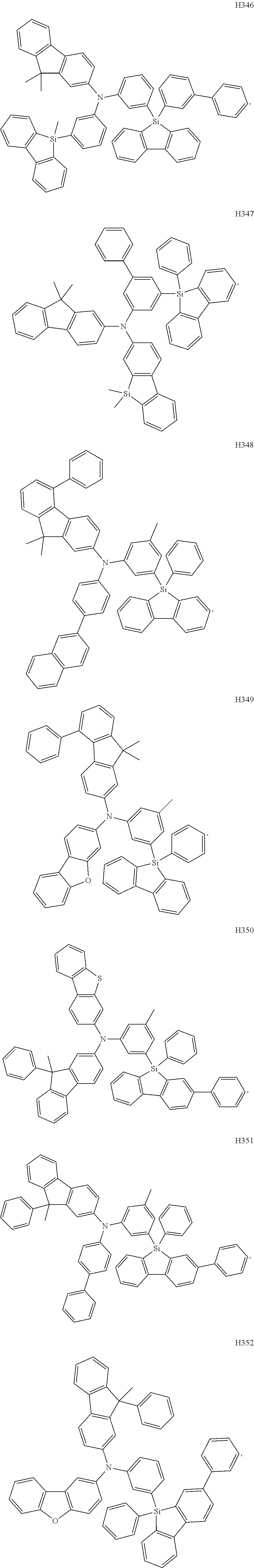 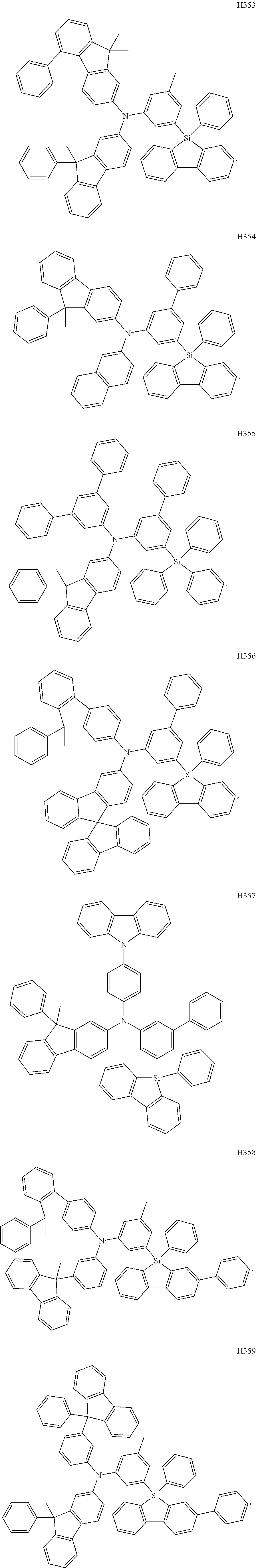 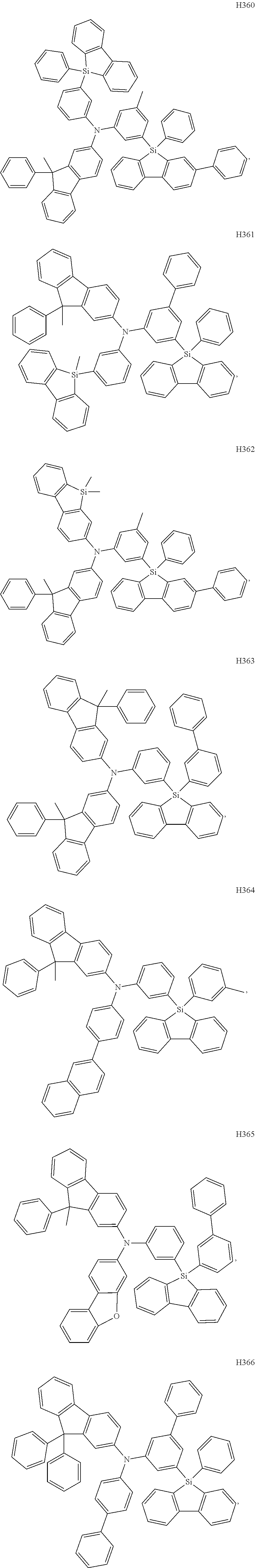 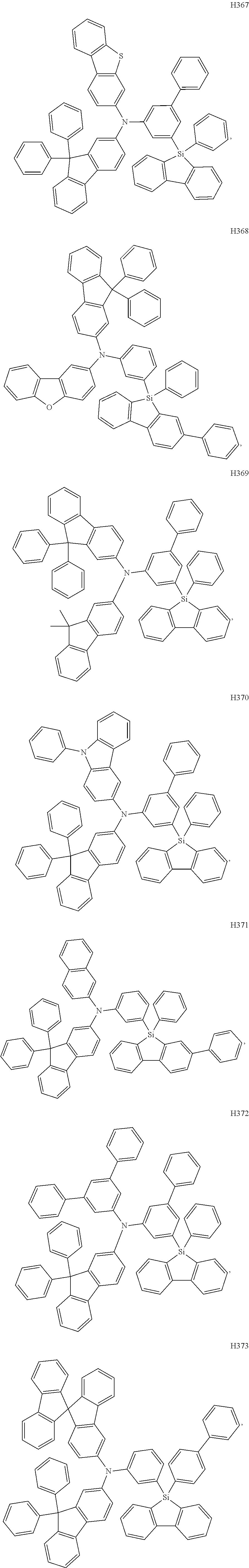 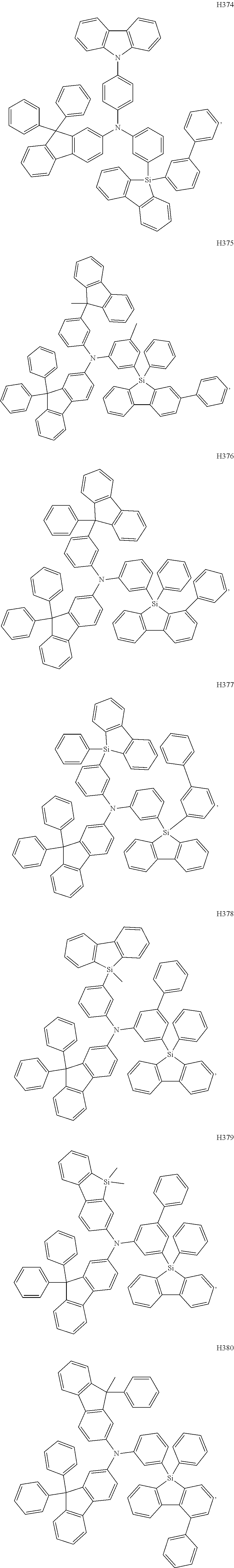 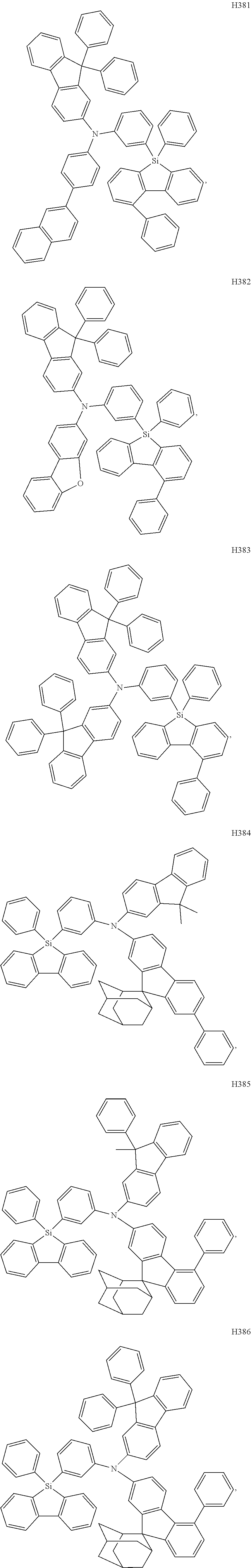 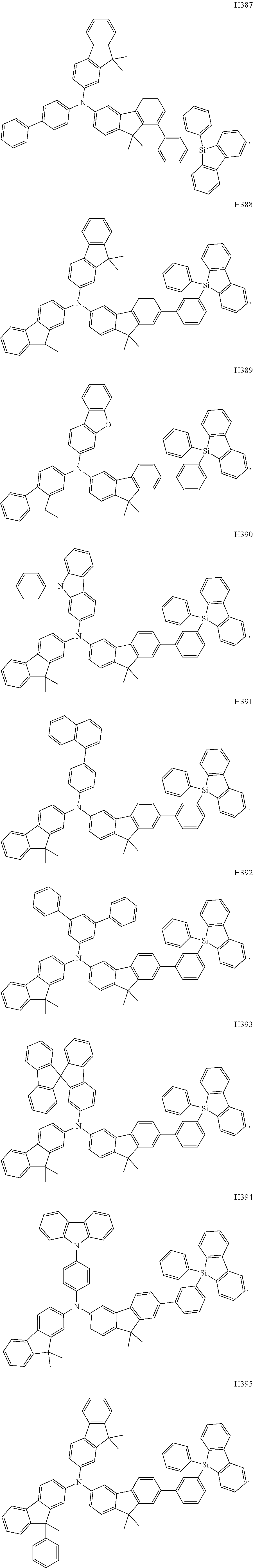 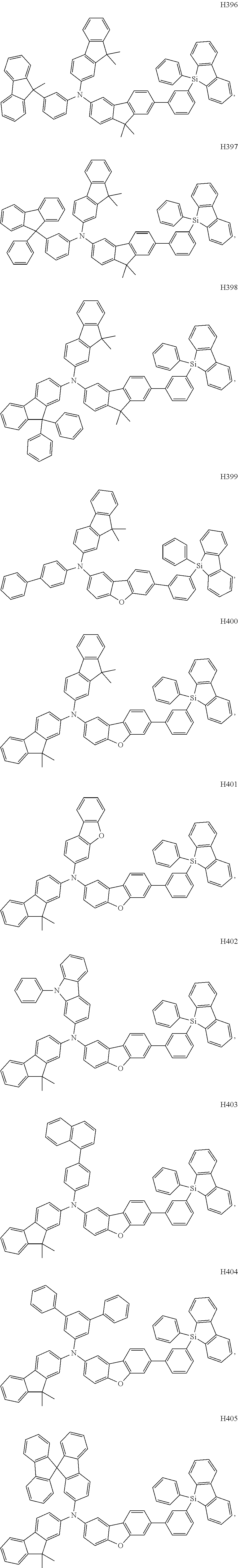 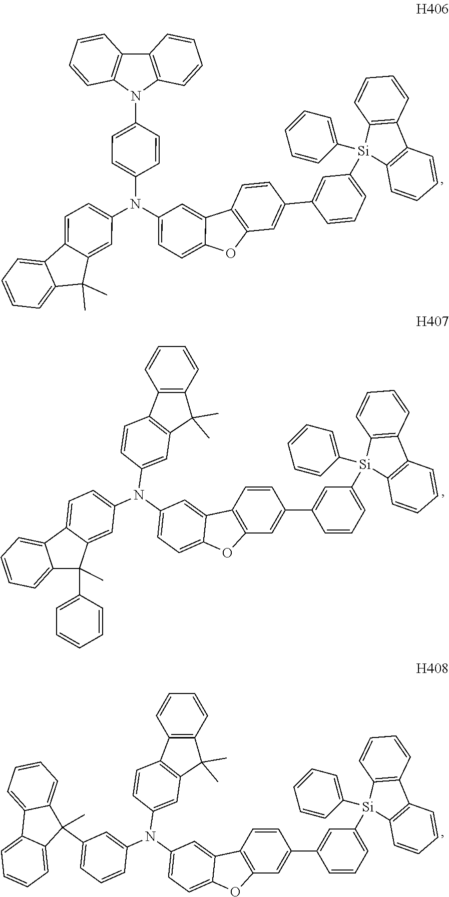 [SMILES: CC1(C)c2ccccc2-c2ccc(N(c3ccc(-n4c5ccccc5c5ccccc54)cc3)c3ccc4oc5cc(-c6cccc([Si]7(c8ccccc8)c8ccccc8-c8ccccc87)c6)ccc5c4c3)cc21 ; CC1(C)c2ccccc2-c2ccc(N(c3ccc4c(c3)C(C)(c3ccccc3)c3ccccc3-4)c3ccc4oc5cc(-c6cccc([Si]7(c8ccccc8)c8ccccc8-c8ccccc87)c6)ccc5c4c3)cc21 ; CC1(C)c2ccccc2-c2ccc(N(c3cccc(C4(C)c5ccccc5-c5ccccc54)c3)c3ccc4oc5cc(-c6cccc([Si]7(c8ccccc8)c8ccccc8-c8ccccc87)c6)ccc5c4c3)cc21] 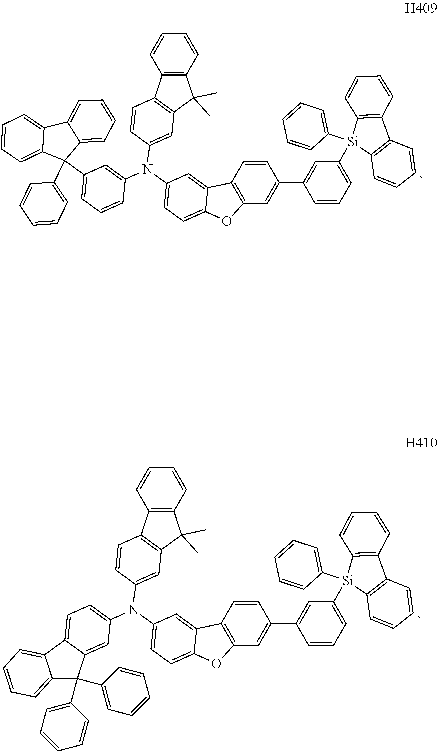 [SMILES: CC1(C)c2ccccc2-c2ccc(N(c3cccc(C4(c5ccccc5)c5ccccc5-c5ccccc54)c3)c3ccc4oc5cc(-c6cccc([Si]7(c8ccccc8)c8ccccc8-c8ccccc87)c6)ccc5c4c3)cc21 ; CC1(C)c2ccccc2-c2ccc(N(c3ccc4c(c3)C(c3ccccc3)(c3ccccc3)c3ccccc3-4)c3ccc4oc5cc(-c6cccc([Si]7(c8ccccc8)c8ccccc8-c8ccccc87)c6)ccc5c4c3)cc21] 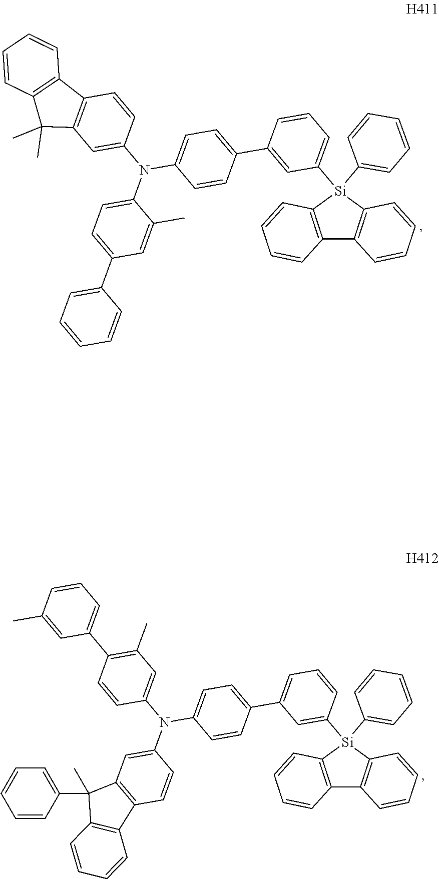 [SMILES: Cc1cc(-c2ccccc2)ccc1N(c1ccc(-c2cccc([Si]3(c4ccccc4)c4ccccc4-c4ccccc43)c2)cc1)c1ccc2c(c1)C(C)(C)c1ccccc1-2 ; Cc1cccc(-c2ccc(N(c3ccc(-c4cccc([Si]5(c6ccccc6)c6ccccc6-c6ccccc65)c4)cc3)c3ccc4c(c3)C(C)(c3ccccc3)c3ccccc3-4)cc2C)c1] 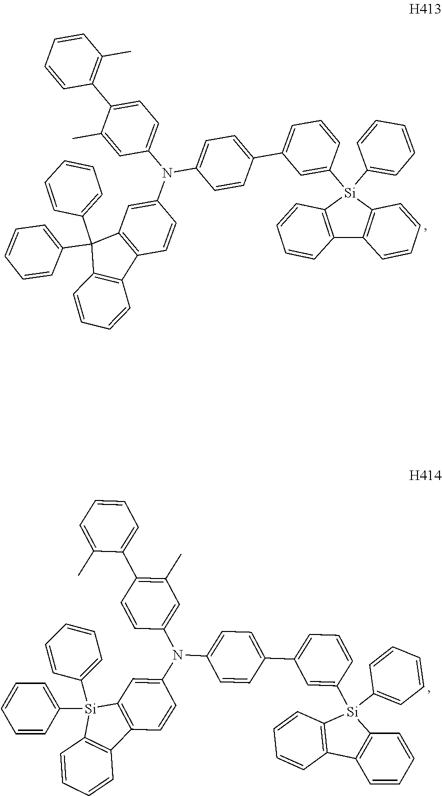 [SMILES: Cc1ccccc1-c1ccc(N(c2ccc(-c3cccc([Si]4(c5ccccc5)c5ccccc5-c5ccccc54)c3)cc2)c2ccc3c(c2)C(c2ccccc2)(c2ccccc2)c2ccccc2-3)cc1C ; Cc1ccccc1-c1ccc(N(c2ccc(-c3cccc([Si]4(c5ccccc5)c5ccccc5-c5ccccc54)c3)cc2)c2ccc3c(c2)[Si](c2ccccc2)(c2ccccc2)c2ccccc2-3)cc1C] 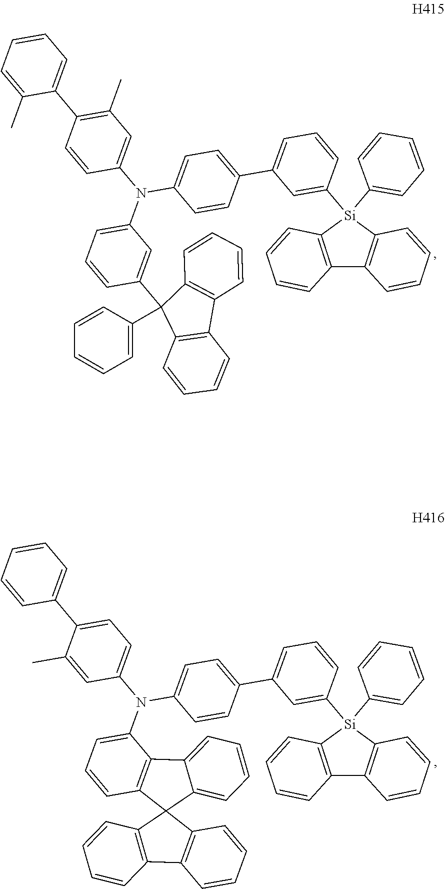 [SMILES: Cc1ccccc1-c1ccc(N(c2ccc(-c3cccc([Si]4(c5ccccc5)c5ccccc5-c5ccccc54)c3)cc2)c2cccc(C3(c4ccccc4)c4ccccc4-c4ccccc43)c2)cc1C ; Cc1cc(N(c2ccc(-c3cccc([Si]4(c5ccccc5)c5ccccc5-c5ccccc54)c3)cc2)c2cccc3c2-c2ccccc2C32c3ccccc3-c3ccccc32)ccc1-c1ccccc1] 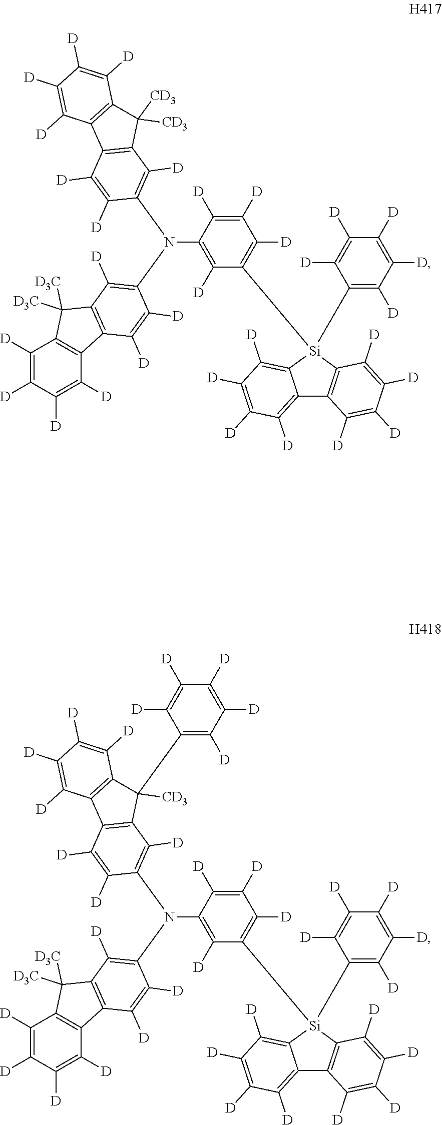 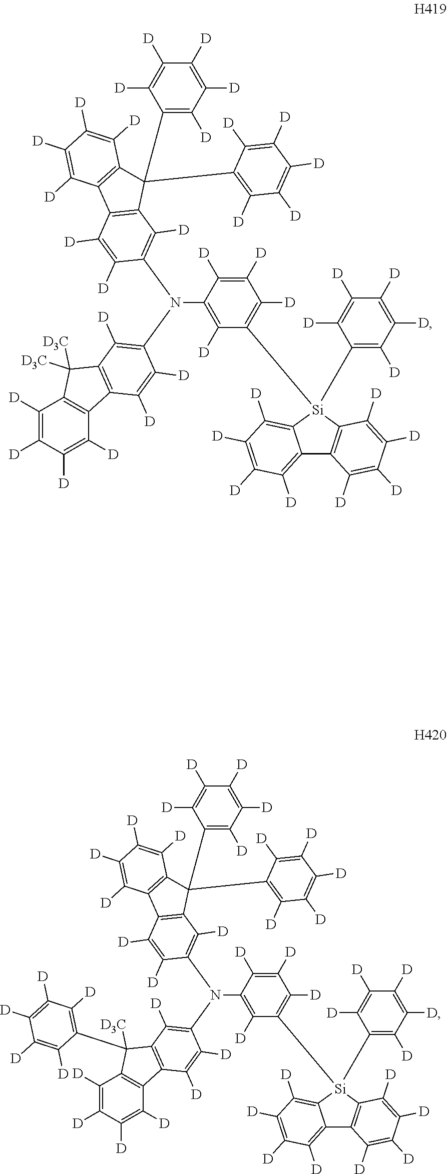 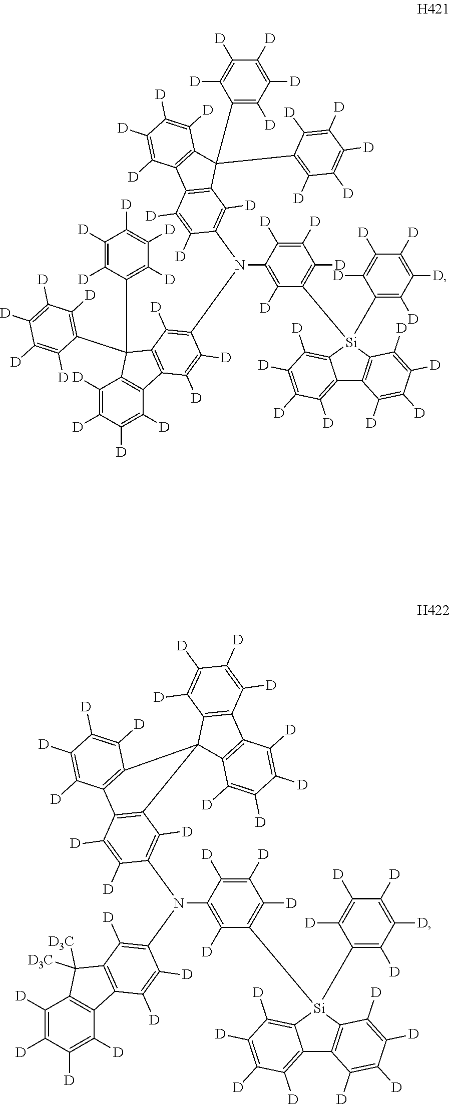 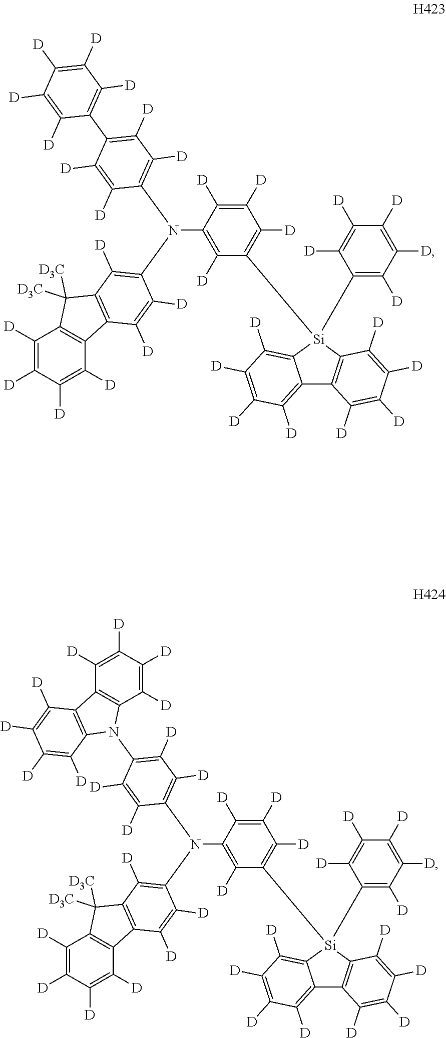 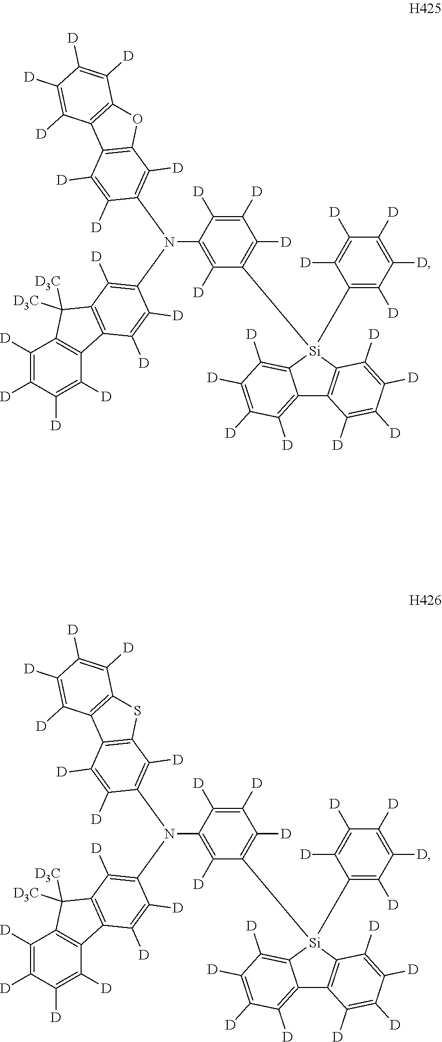 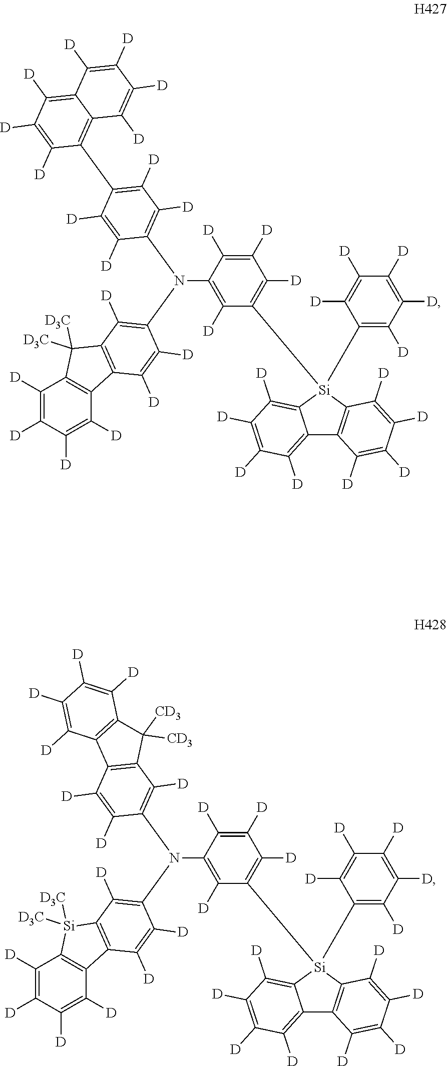 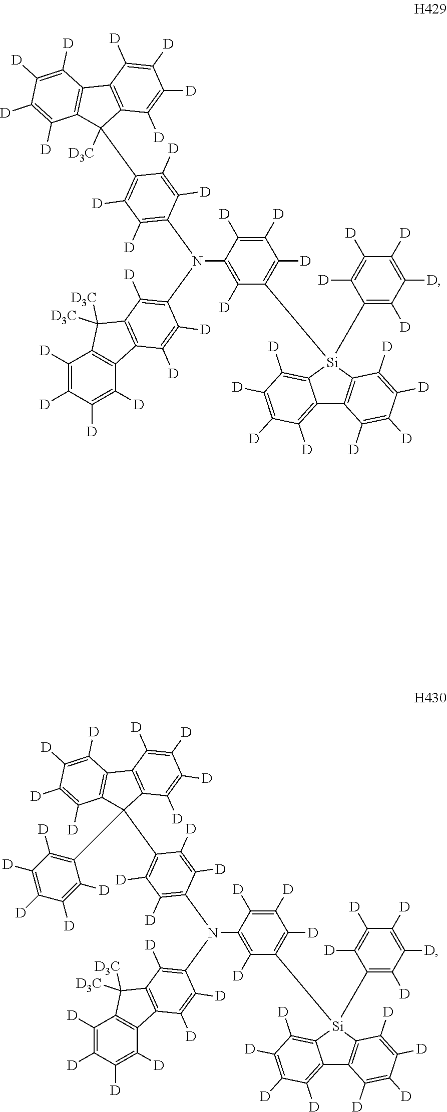 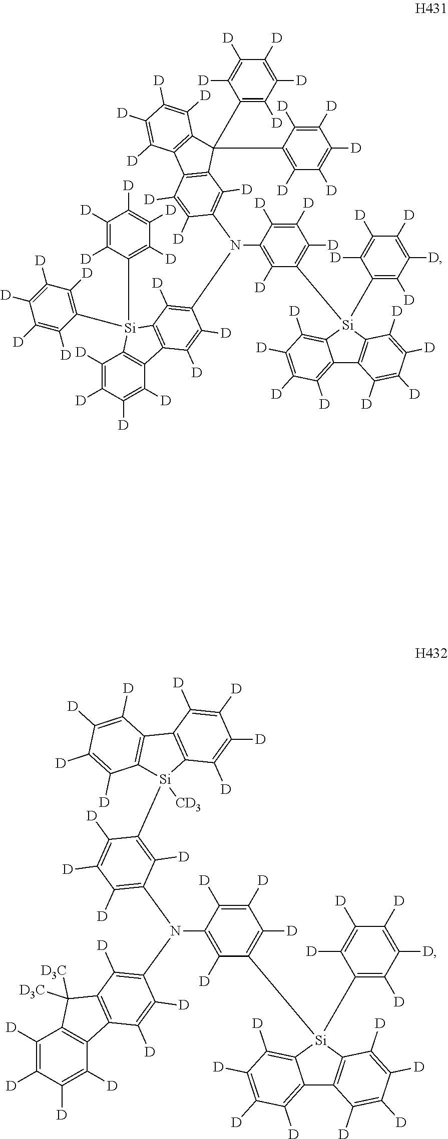 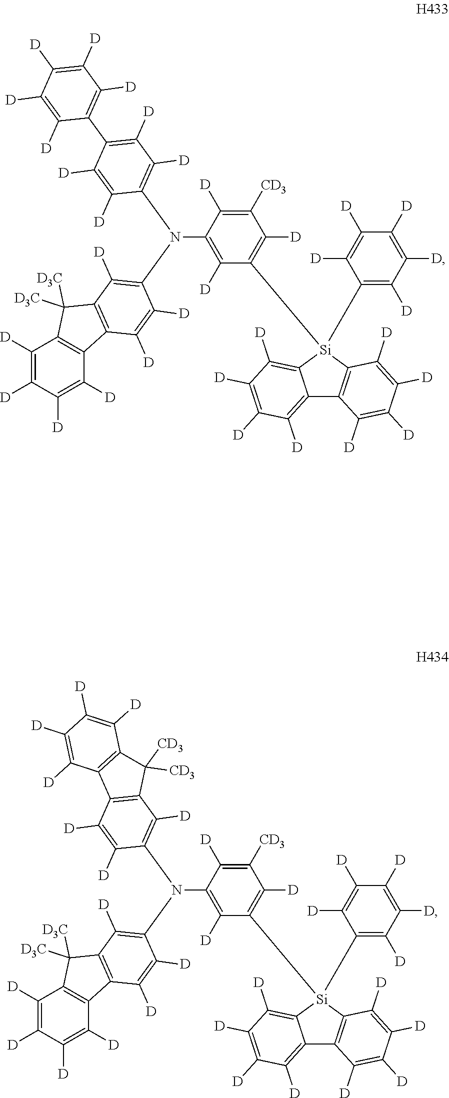 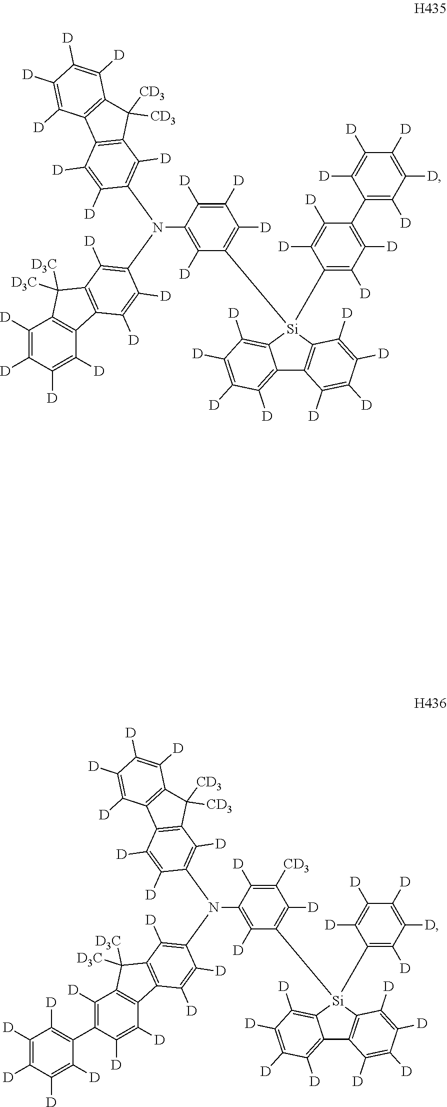 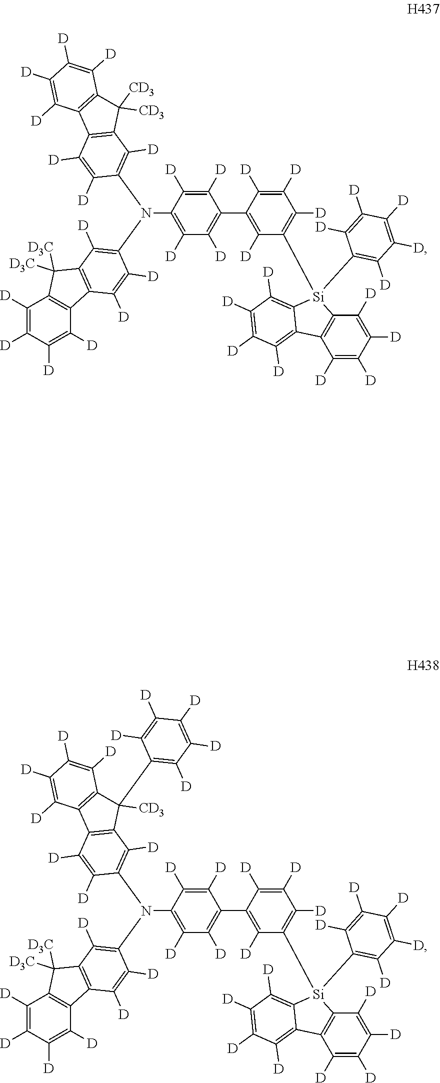 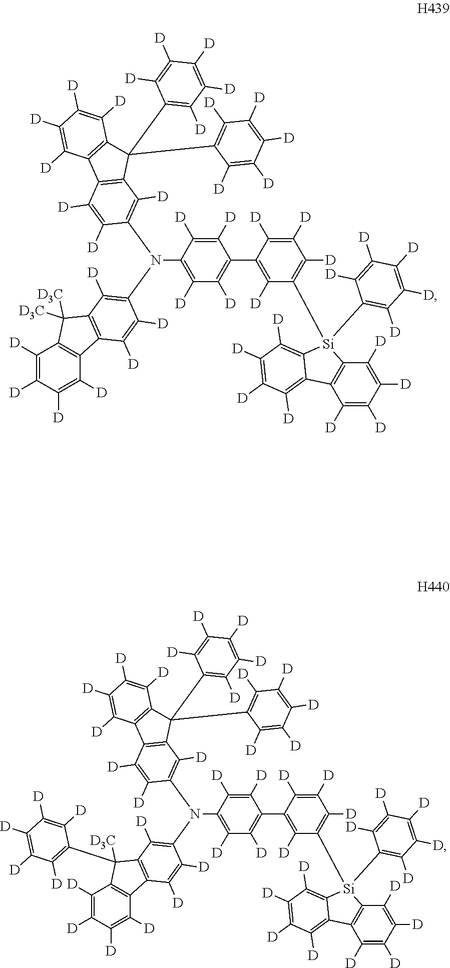 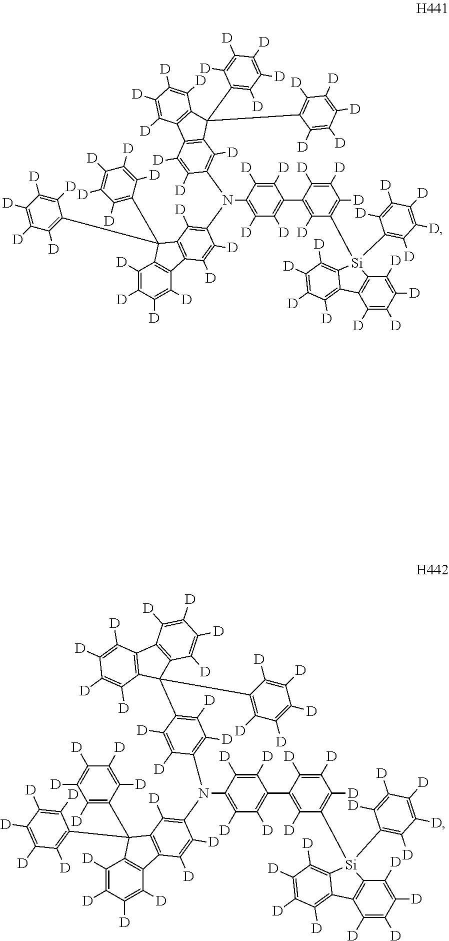 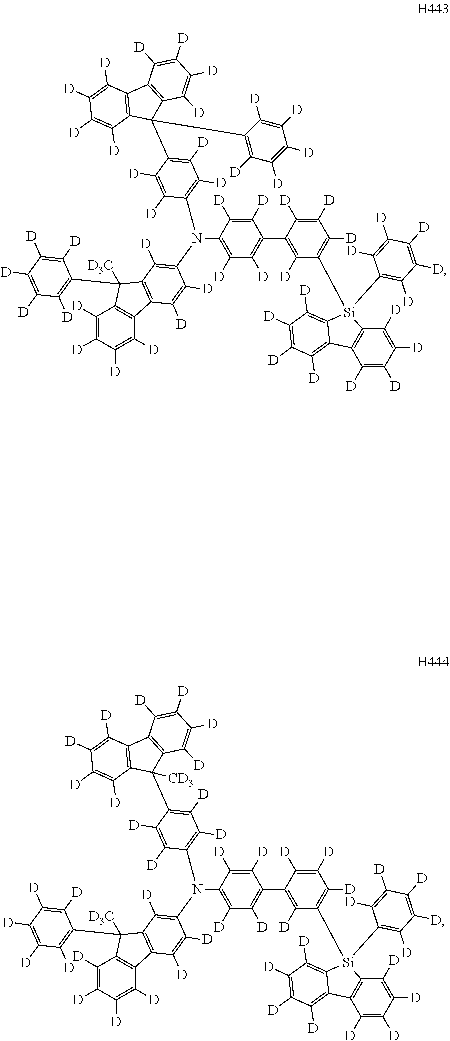 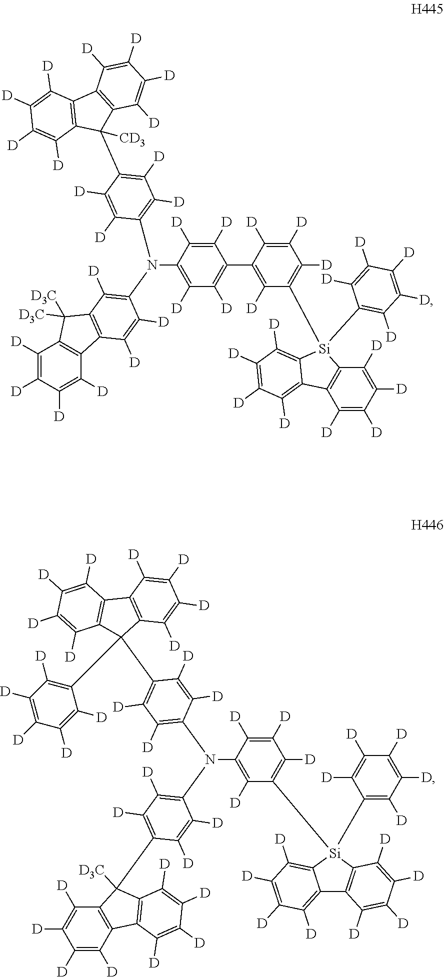 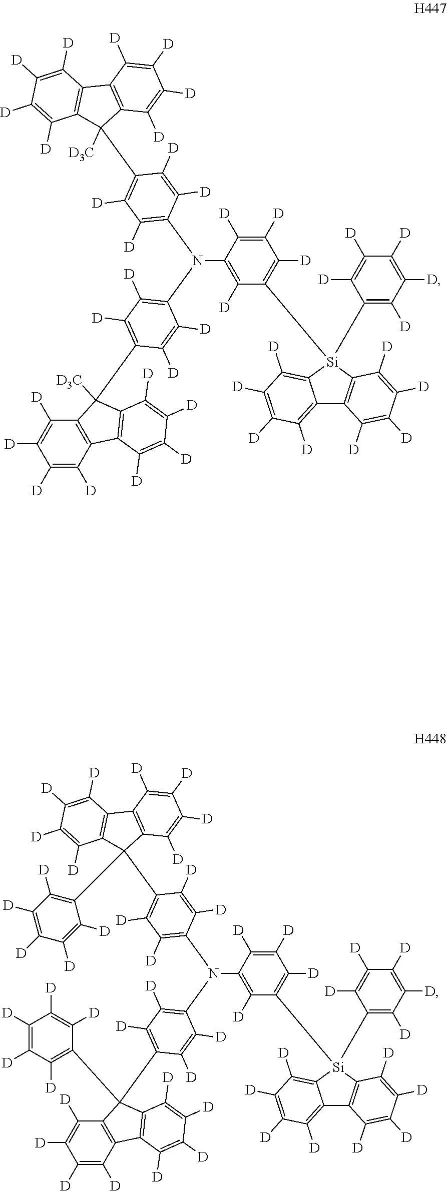 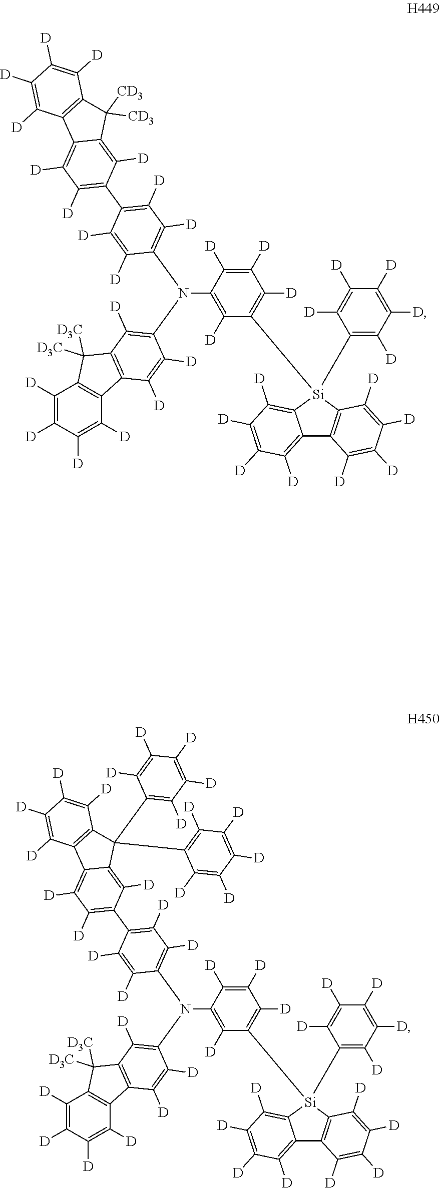 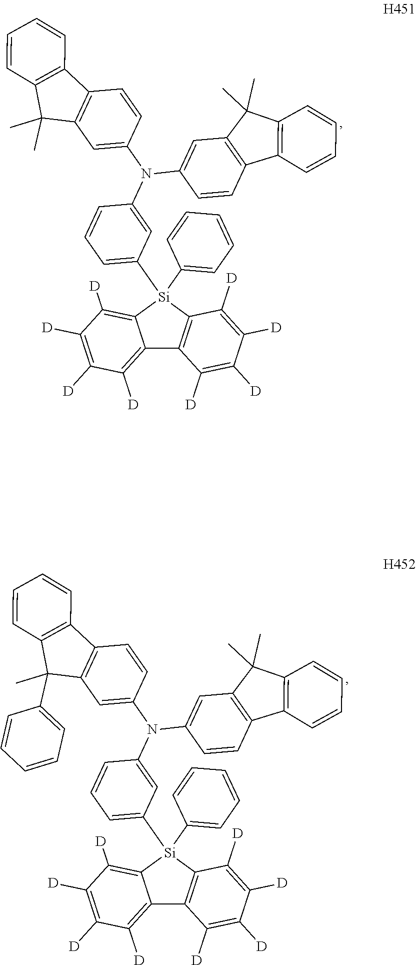 [SMILES: [2H]c1c([2H])c([2H])c2c(c1[2H])-c1c([2H])c([2H])c([2H])c([2H])c1[Si]2(c1ccccc1)c1cccc(N(c2ccc3c(c2)C(C)(C)c2ccccc2-3)c2ccc3c(c2)C(C)(C)c2ccccc2-3)c1 ; [2H]c1c([2H])c([2H])c2c(c1[2H])-c1c([2H])c([2H])c([2H])c([2H])c1[Si]2(c1ccccc1)c1cccc(N(c2ccc3c(c2)C(C)(C)c2ccccc2-3)c2ccc3c(c2)C(C)(c2ccccc2)c2ccccc2-3)c1] 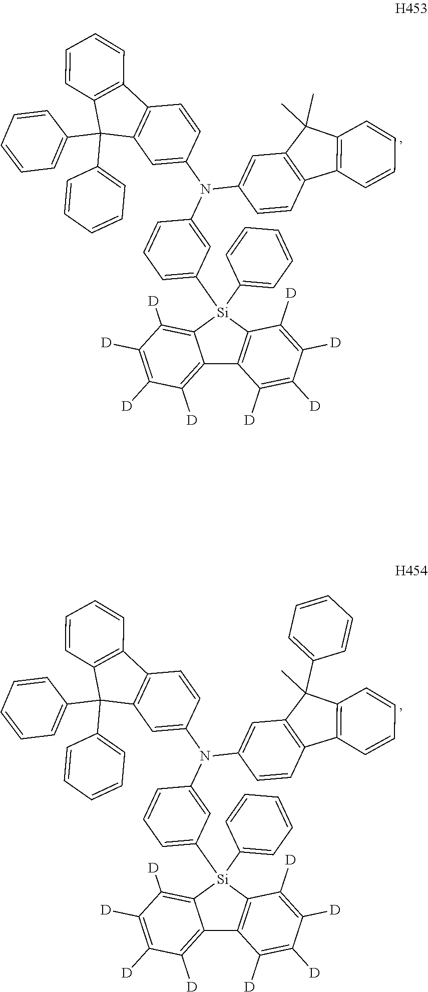 [SMILES: [2H]c1c([2H])c([2H])c2c(c1[2H])-c1c([2H])c([2H])c([2H])c([2H])c1[Si]2(c1ccccc1)c1cccc(N(c2ccc3c(c2)C(C)(C)c2ccccc2-3)c2ccc3c(c2)C(c2ccccc2)(c2ccccc2)c2ccccc2-3)c1 ; [2H]c1c([2H])c([2H])c2c(c1[2H])-c1c([2H])c([2H])c([2H])c([2H])c1[Si]2(c1ccccc1)c1cccc(N(c2ccc3c(c2)C(C)(c2ccccc2)c2ccccc2-3)c2ccc3c(c2)C(c2ccccc2)(c2ccccc2)c2ccccc2-3)c1] 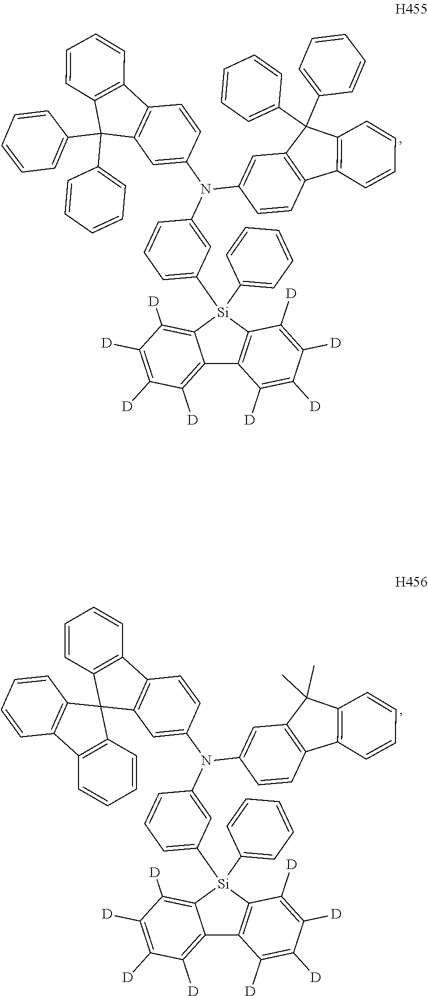 [SMILES: [2H]c1c([2H])c([2H])c2c(c1[2H])-c1c([2H])c([2H])c([2H])c([2H])c1[Si]2(c1ccccc1)c1cccc(N(c2ccc3c(c2)C(c2ccccc2)(c2ccccc2)c2ccccc2-3)c2ccc3c(c2)C(c2ccccc2)(c2ccccc2)c2ccccc2-3)c1 ; [2H]c1c([2H])c([2H])c2c(c1[2H])-c1c([2H])c([2H])c([2H])c([2H])c1[Si]2(c1ccccc1)c1cccc(N(c2ccc3c(c2)C(C)(C)c2ccccc2-3)c2ccc3c(c2)C2(c4ccccc4-c4ccccc42)c2ccccc2-3)c1] 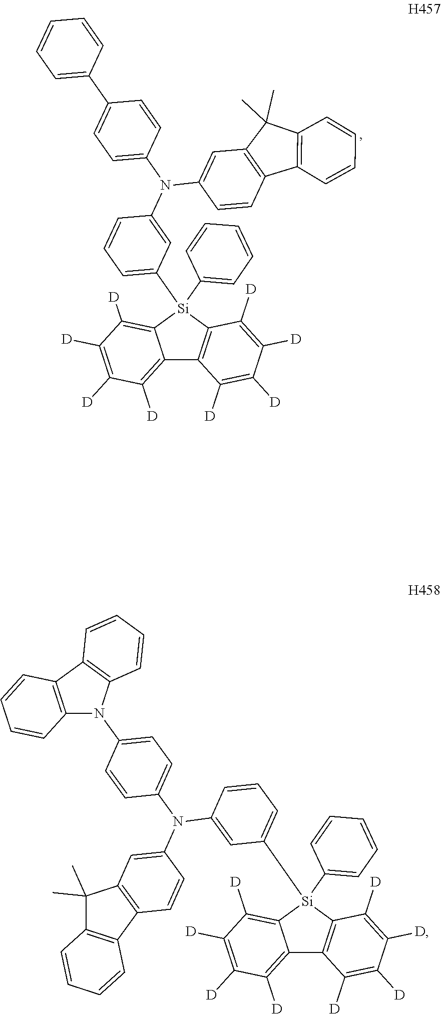 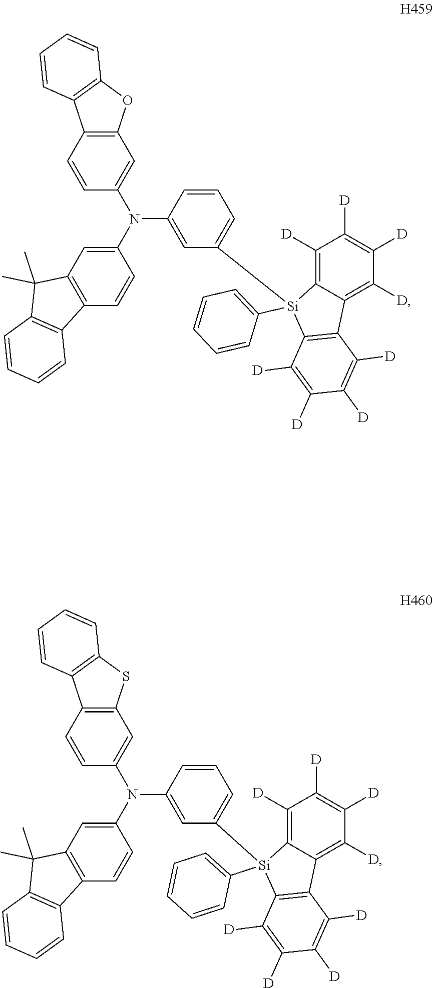 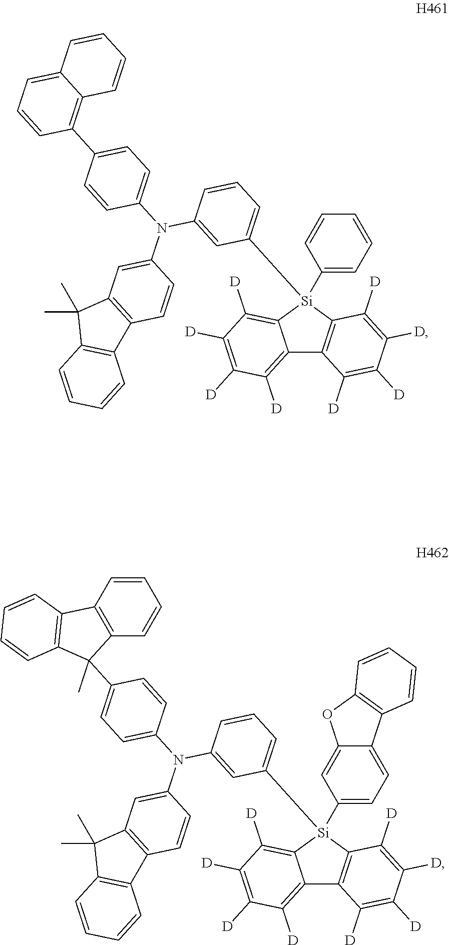 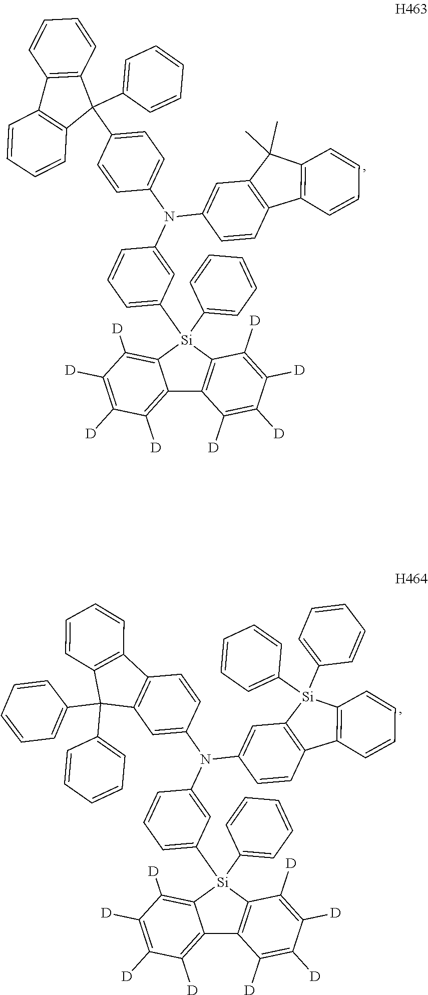 [SMILES: [2H]c1c([2H])c([2H])c2c(c1[2H])-c1c([2H])c([2H])c([2H])c([2H])c1[Si]2(c1ccccc1)c1cccc(N(c2ccc(C3(c4ccccc4)c4ccccc4-c4ccccc43)cc2)c2ccc3c(c2)C(C)(C)c2ccccc2-3)c1 ; [2H]c1c([2H])c([2H])c2c(c1[2H])-c1c([2H])c([2H])c([2H])c([2H])c1[Si]2(c1ccccc1)c1cccc(N(c2ccc3c(c2)C(c2ccccc2)(c2ccccc2)c2ccccc2-3)c2ccc3c(c2)[Si](c2ccccc2)(c2ccccc2)c2ccccc2-3)c1] 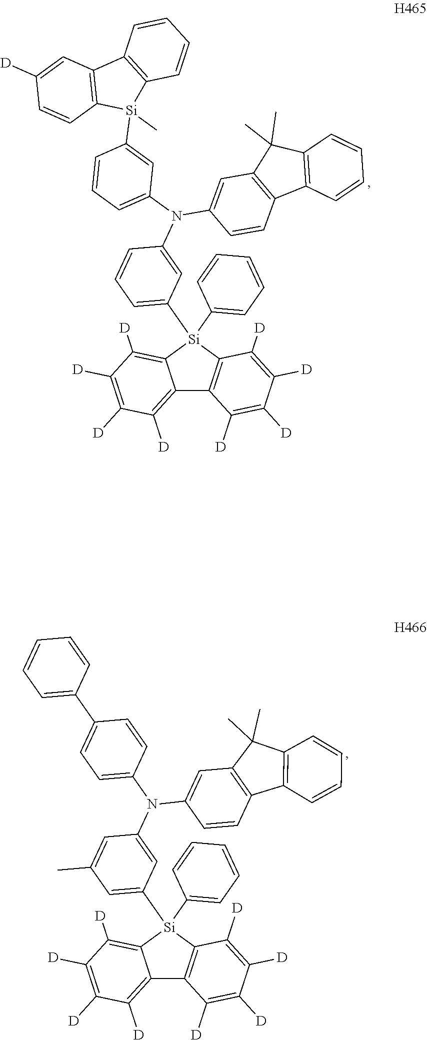 [SMILES: [2H]c1ccc2c(c1)-c1ccccc1[Si]2(C)c1cccc(N(c2cccc([Si]3(c4ccccc4)c4c([2H])c([2H])c([2H])c([2H])c4-c4c([2H])c([2H])c([2H])c([2H])c43)c2)c2ccc3c(c2)C(C)(C)c2ccccc2-3)c1 ; [2H]c1c([2H])c([2H])c2c(c1[2H])-c1c([2H])c([2H])c([2H])c([2H])c1[Si]2(c1ccccc1)c1cc(C)cc(N(c2ccc(-c3ccccc3)cc2)c2ccc3c(c2)C(C)(C)c2ccccc2-3)c1] 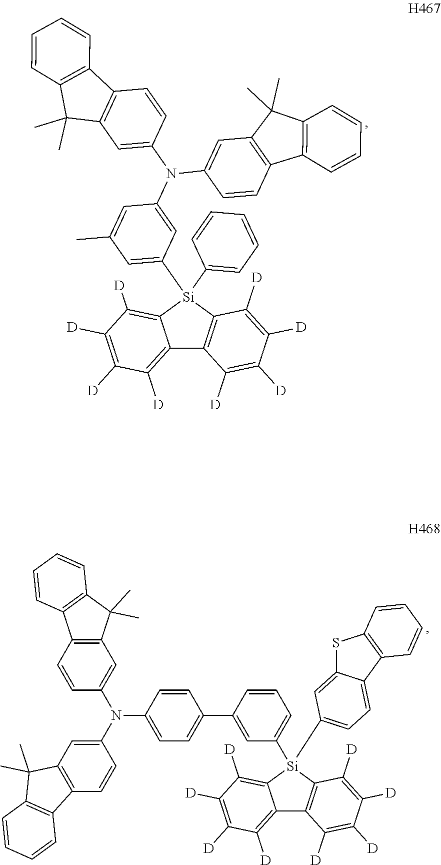 [SMILES: [2H]c1c([2H])c([2H])c2c(c1[2H])-c1c([2H])c([2H])c([2H])c([2H])c1[Si]2(c1ccccc1)c1cc(C)cc(N(c2ccc3c(c2)C(C)(C)c2ccccc2-3)c2ccc3c(c2)C(C)(C)c2ccccc2-3)c1 ; [2H]c1c([2H])c([2H])c2c(c1[2H])-c1c([2H])c([2H])c([2H])c([2H])c1[Si]2(c1cccc(-c2ccc(N(c3ccc4c(c3)C(C)(C)c3ccccc3-4)c3ccc4c(c3)C(C)(C)c3ccccc3-4)cc2)c1)c1ccc2c(c1)sc1ccccc12] 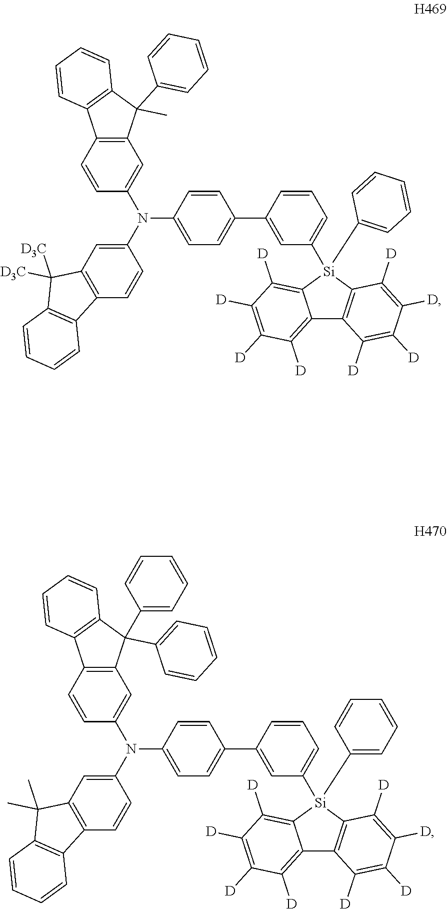 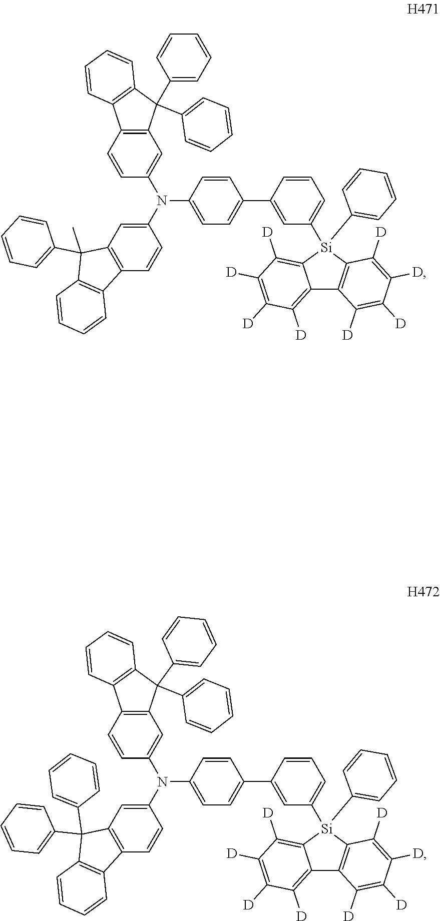 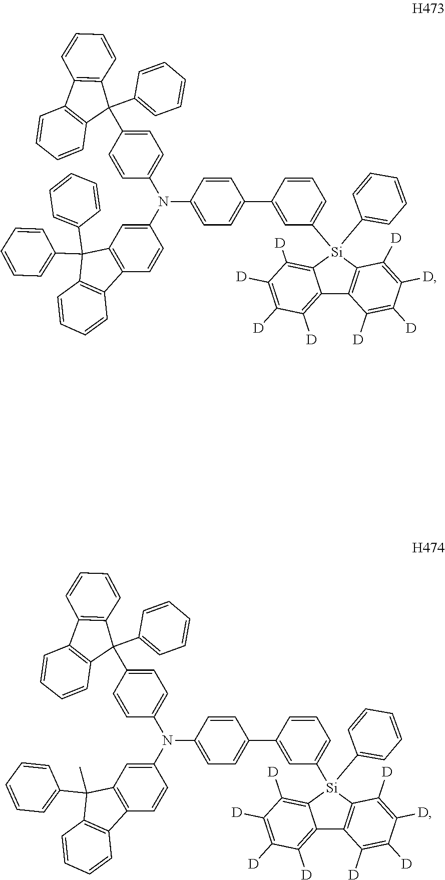 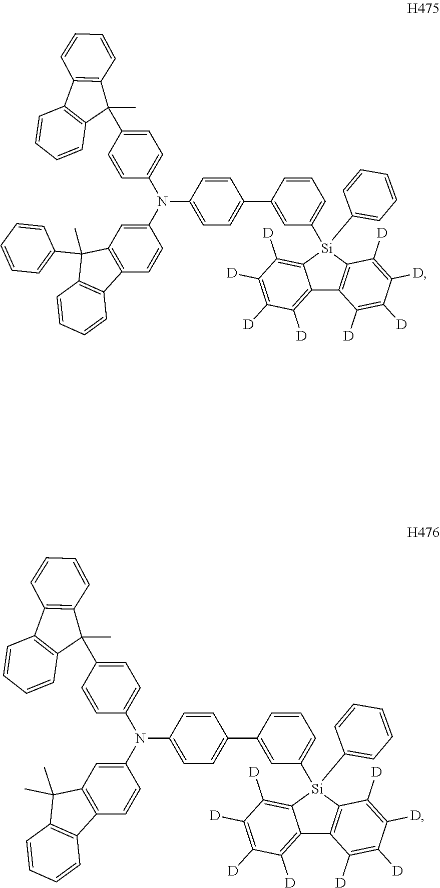 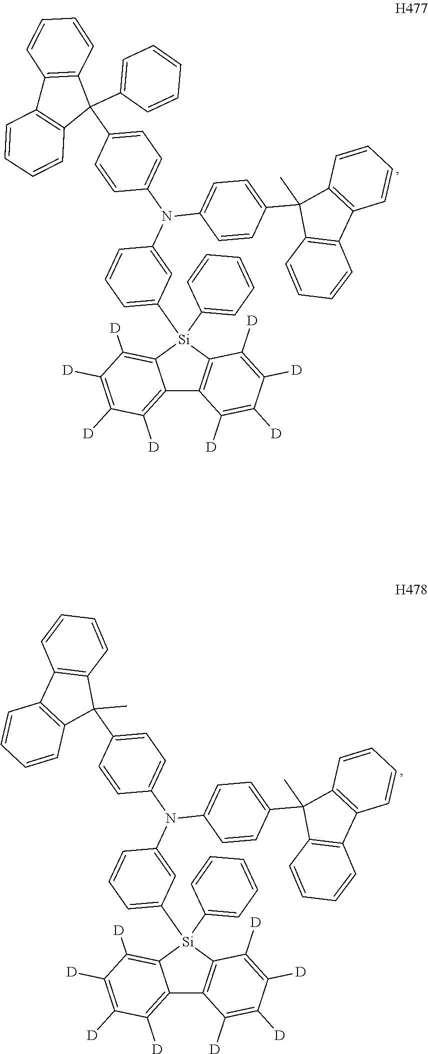 [SMILES: [2H]c1c([2H])c([2H])c2c(c1[2H])-c1c([2H])c([2H])c([2H])c([2H])c1[Si]2(c1ccccc1)c1cccc(N(c2ccc(C3(C)c4ccccc4-c4ccccc43)cc2)c2ccc(C3(c4ccccc4)c4ccccc4-c4ccccc43)cc2)c1 ; [2H]c1c([2H])c([2H])c2c(c1[2H])-c1c([2H])c([2H])c([2H])c([2H])c1[Si]2(c1ccccc1)c1cccc(N(c2ccc(C3(C)c4ccccc4-c4ccccc43)cc2)c2ccc(C3(C)c4ccccc4-c4ccccc43)cc2)c1] 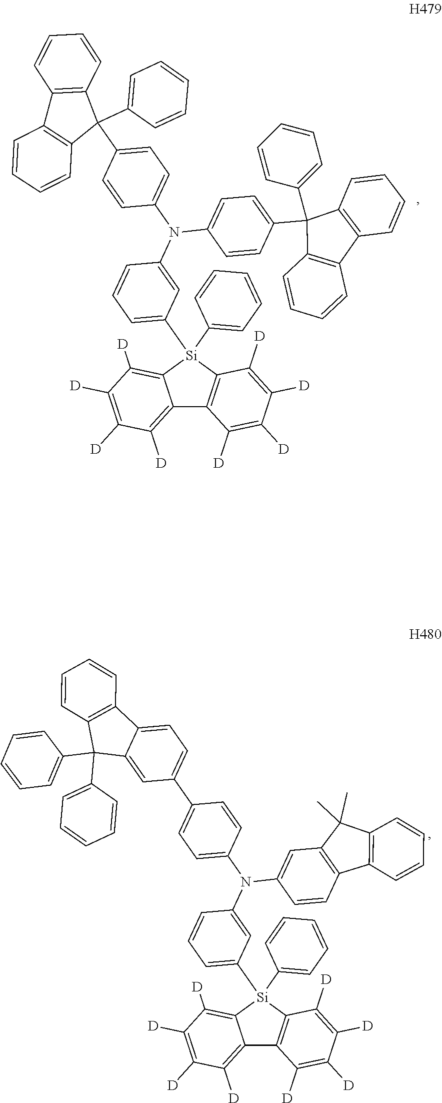 [SMILES: [2H]c1c([2H])c([2H])c2c(c1[2H])-c1c([2H])c([2H])c([2H])c([2H])c1[Si]2(c1ccccc1)c1cccc(N(c2ccc(C3(c4ccccc4)c4ccccc4-c4ccccc43)cc2)c2ccc(C3(c4ccccc4)c4ccccc4-c4ccccc43)cc2)c1 ; [2H]c1c([2H])c([2H])c2c(c1[2H])-c1c([2H])c([2H])c([2H])c([2H])c1[Si]2(c1ccccc1)c1cccc(N(c2ccc(-c3ccc4c(c3)C(c3ccccc3)(c3ccccc3)c3ccccc3-4)cc2)c2ccc3c(c2)C(C)(C)c2ccccc2-3)c1] 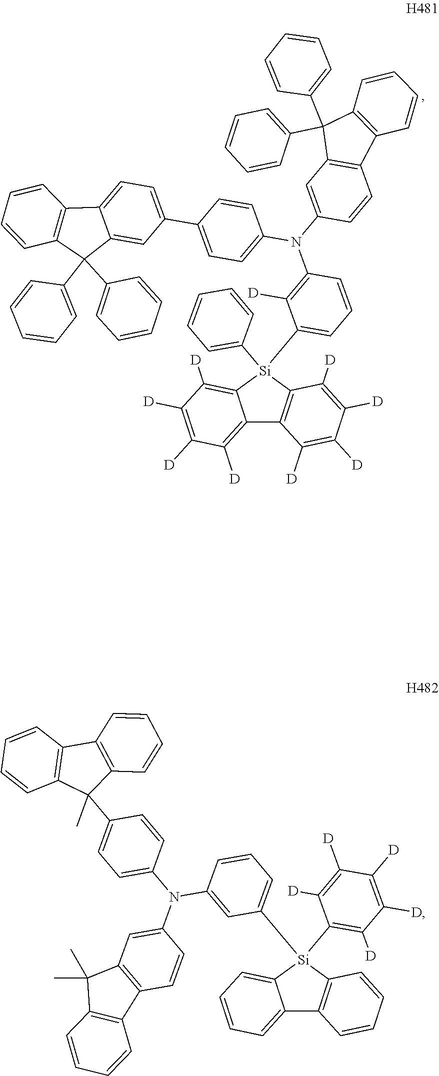 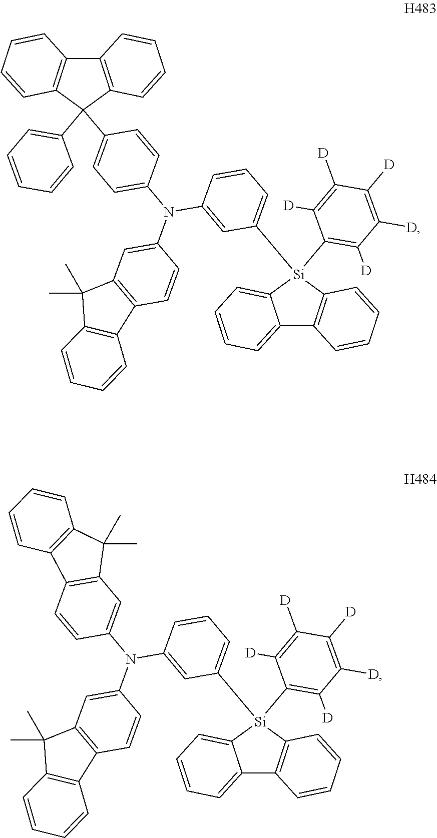 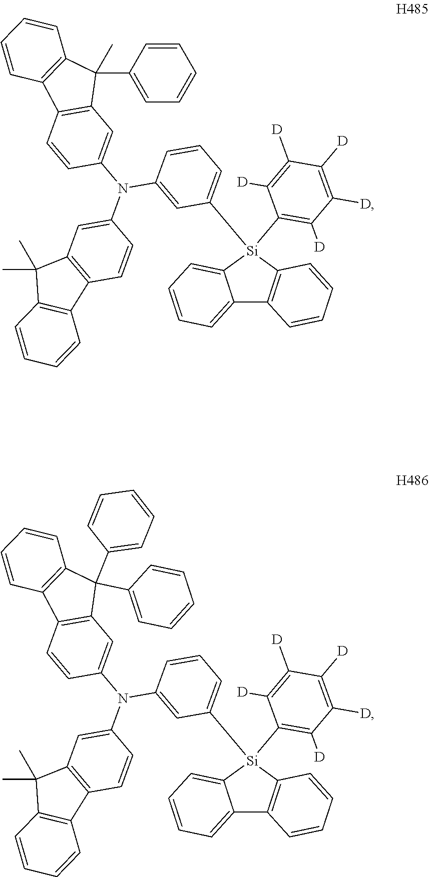 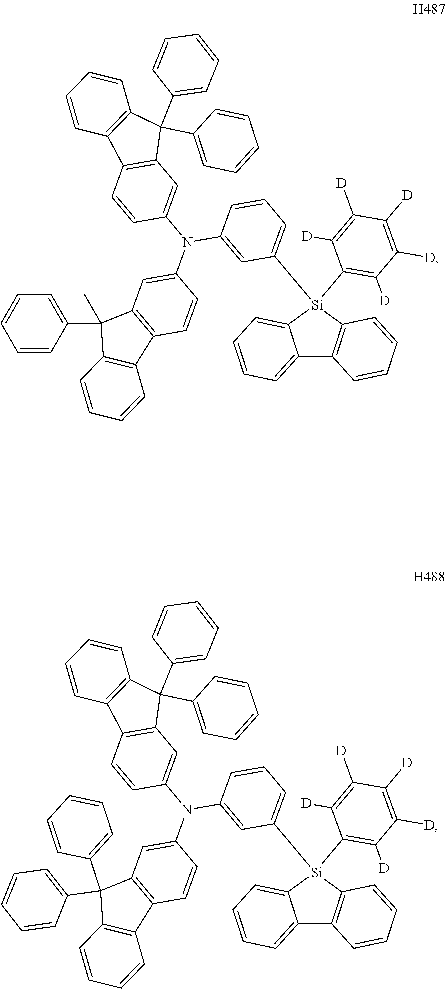 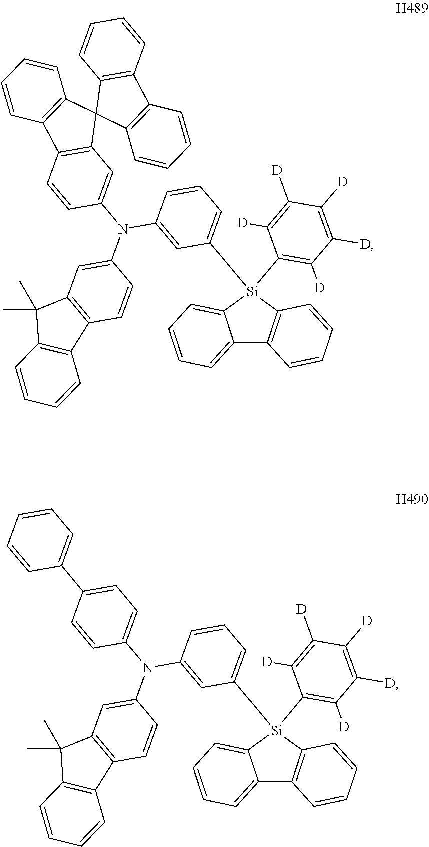 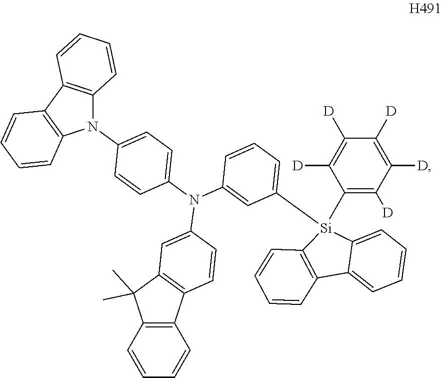 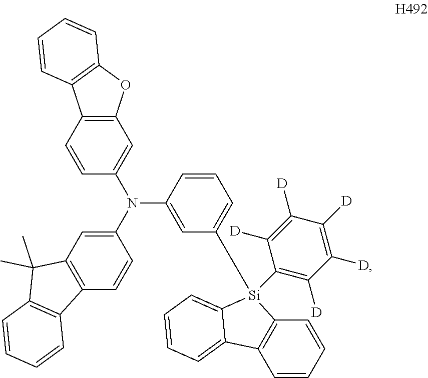 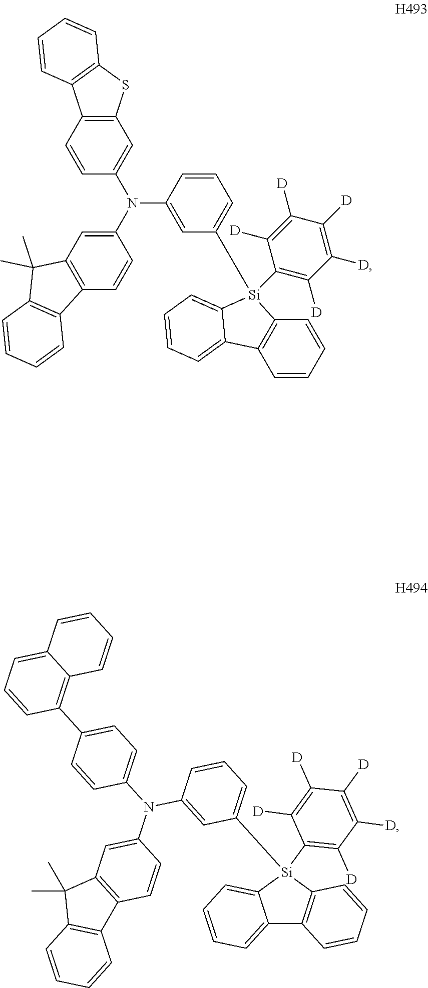 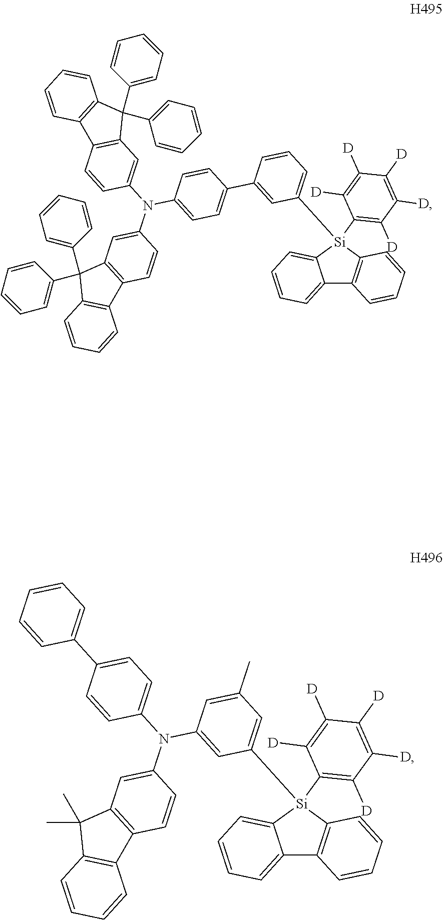 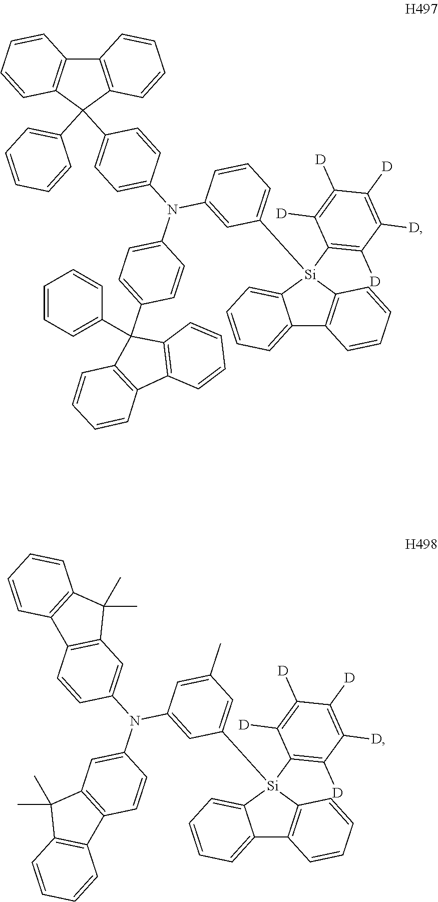 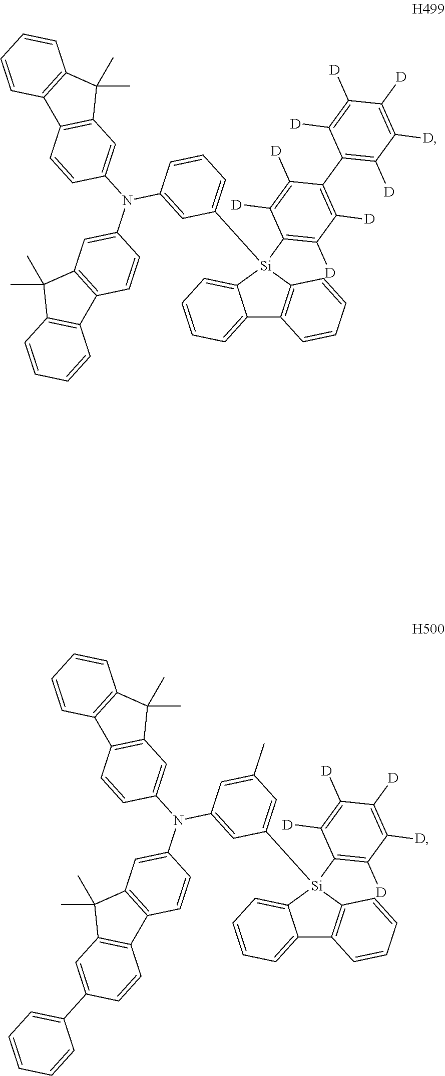 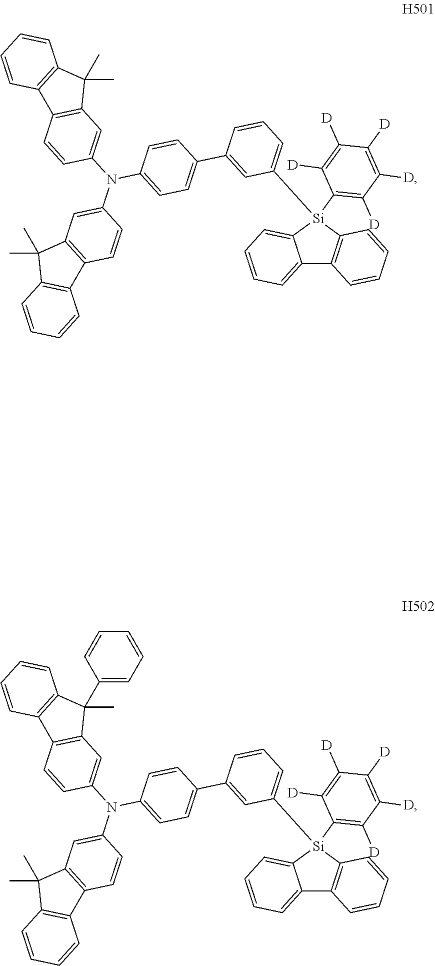 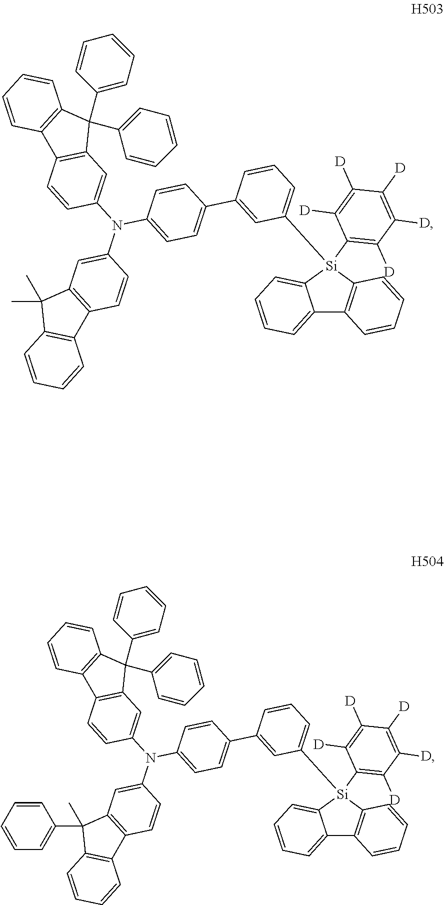 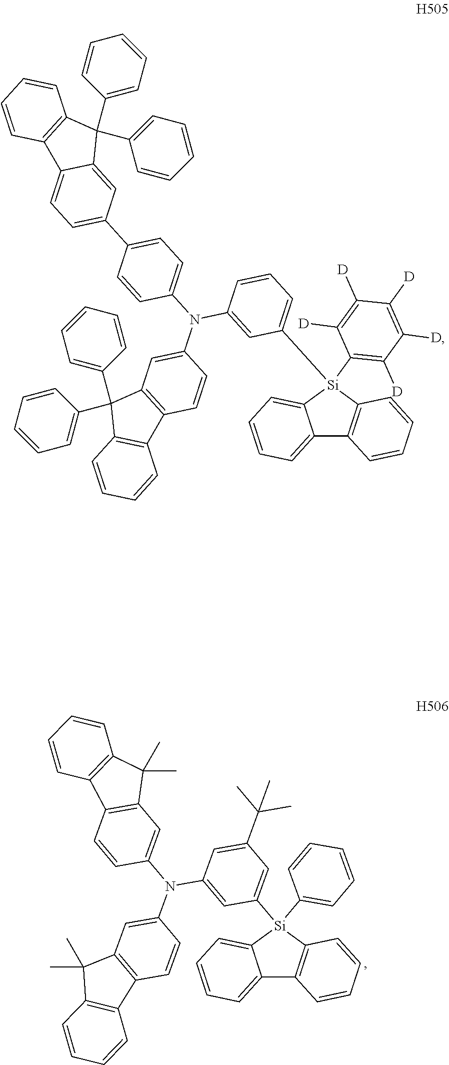 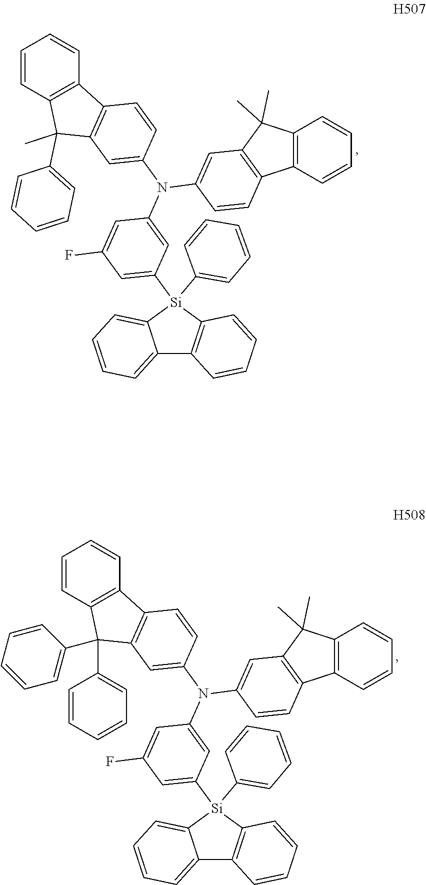 [SMILES: CC1(C)c2ccccc2-c2ccc(N(c3cc(F)cc([Si]4(c5ccccc5)c5ccccc5-c5ccccc54)c3)c3ccc4c(c3)C(C)(c3ccccc3)c3ccccc3-4)cc21 ; CC1(C)c2ccccc2-c2ccc(N(c3cc(F)cc([Si]4(c5ccccc5)c5ccccc5-c5ccccc54)c3)c3ccc4c(c3)C(c3ccccc3)(c3ccccc3)c3ccccc3-4)cc21] 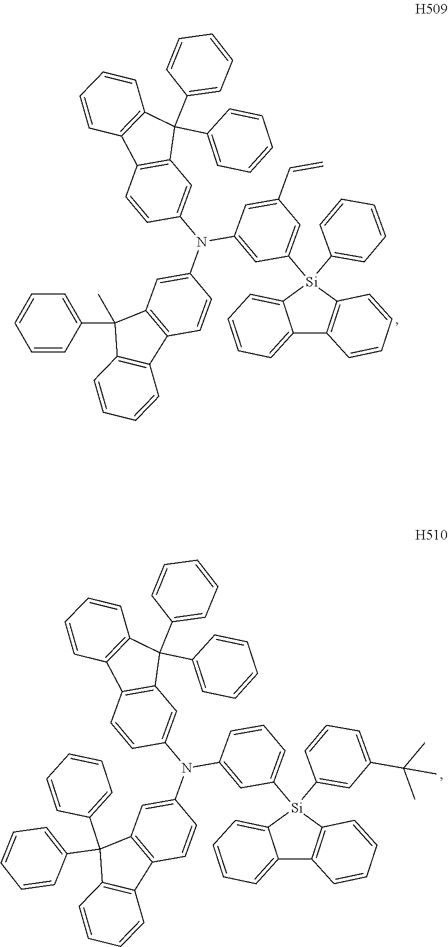 [SMILES: C=Cc1cc(N(c2ccc3c(c2)C(C)(c2ccccc2)c2ccccc2-3)c2ccc3c(c2)C(c2ccccc2)(c2ccccc2)c2ccccc2-3)cc([Si]2(c3ccccc3)c3ccccc3-c3ccccc32)c1 ; CC(C)(C)c1cccc([Si]2(c3cccc(N(c4ccc5c(c4)C(c4ccccc4)(c4ccccc4)c4ccccc4-5)c4ccc5c(c4)C(c4ccccc4)(c4ccccc4)c4ccccc4-5)c3)c3ccccc3-c3ccccc32)c1] 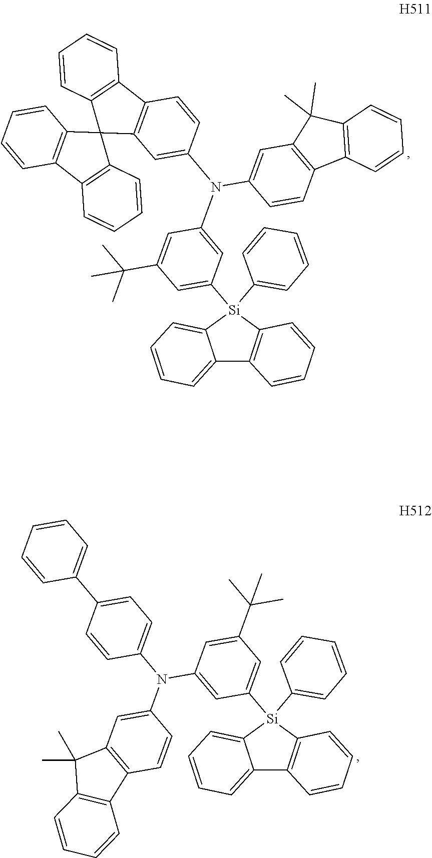 [SMILES: CC(C)(C)c1cc(N(c2ccc3c(c2)C(C)(C)c2ccccc2-3)c2ccc3c(c2)C2(c4ccccc4-c4ccccc42)c2ccccc2-3)cc([Si]2(c3ccccc3)c3ccccc3-c3ccccc32)c1 ; CC(C)(C)c1cc(N(c2ccc(-c3ccccc3)cc2)c2ccc3c(c2)C(C)(C)c2ccccc2-3)cc([Si]2(c3ccccc3)c3ccccc3-c3ccccc32)c1] 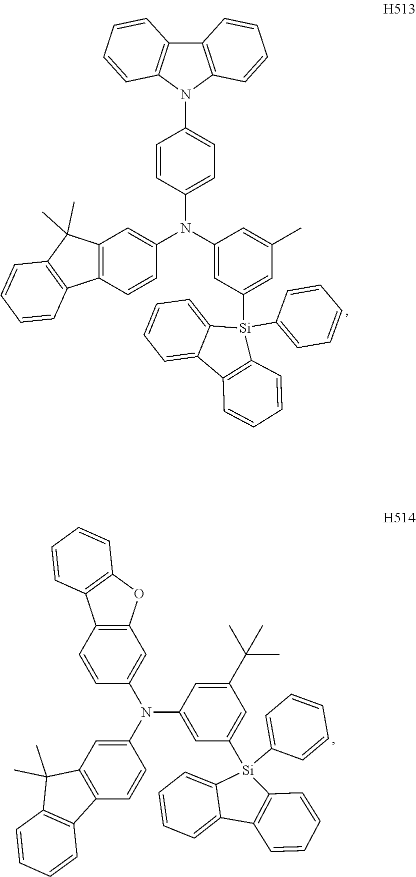 [SMILES: Cc1cc(N(c2ccc(-n3c4ccccc4c4ccccc43)cc2)c2ccc3c(c2)C(C)(C)c2ccccc2-3)cc([Si]2(c3ccccc3)c3ccccc3-c3ccccc32)c1 ; CC(C)(C)c1cc(N(c2ccc3c(c2)C(C)(C)c2ccccc2-3)c2ccc3c(c2)oc2ccccc23)cc([Si]2(c3ccccc3)c3ccccc3-c3ccccc32)c1] 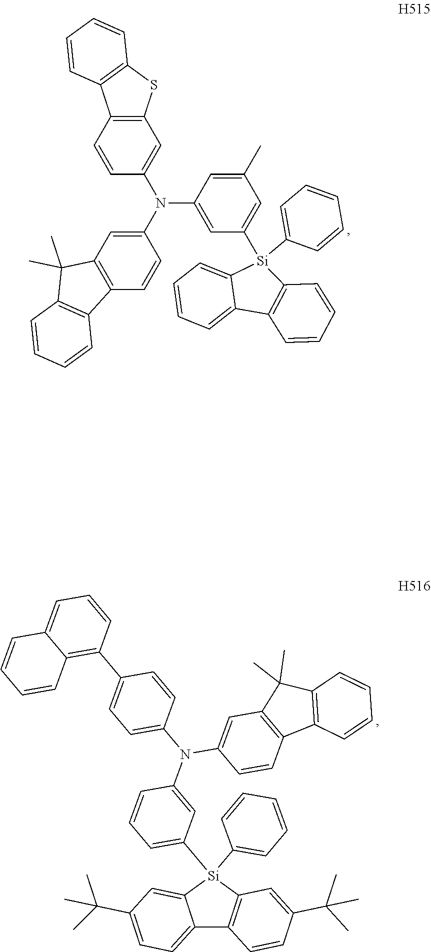 [SMILES: Cc1cc(N(c2ccc3c(c2)C(C)(C)c2ccccc2-3)c2ccc3c(c2)sc2ccccc23)cc([Si]2(c3ccccc3)c3ccccc3-c3ccccc32)c1 ; CC(C)(C)c1ccc2c(c1)[Si](c1ccccc1)(c1cccc(N(c3ccc(-c4cccc5ccccc45)cc3)c3ccc4c(c3)C(C)(C)c3ccccc3-4)c1)c1cc(C(C)(C)C)ccc1-2] 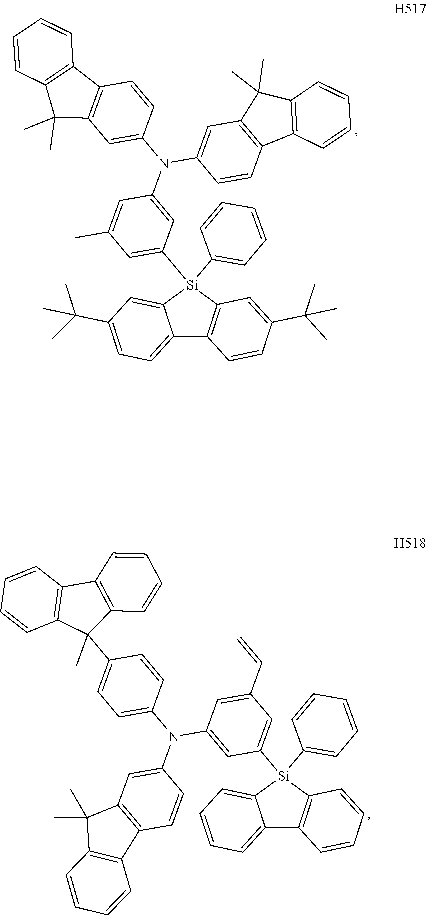 [SMILES: Cc1cc(N(c2ccc3c(c2)C(C)(C)c2ccccc2-3)c2ccc3c(c2)C(C)(C)c2ccccc2-3)cc([Si]2(c3ccccc3)c3cc(C(C)(C)C)ccc3-c3ccc(C(C)(C)C)cc32)c1 ; C=Cc1cc(N(c2ccc(C3(C)c4ccccc4-c4ccccc43)cc2)c2ccc3c(c2)C(C)(C)c2ccccc2-3)cc([Si]2(c3ccccc3)c3ccccc3-c3ccccc32)c1] 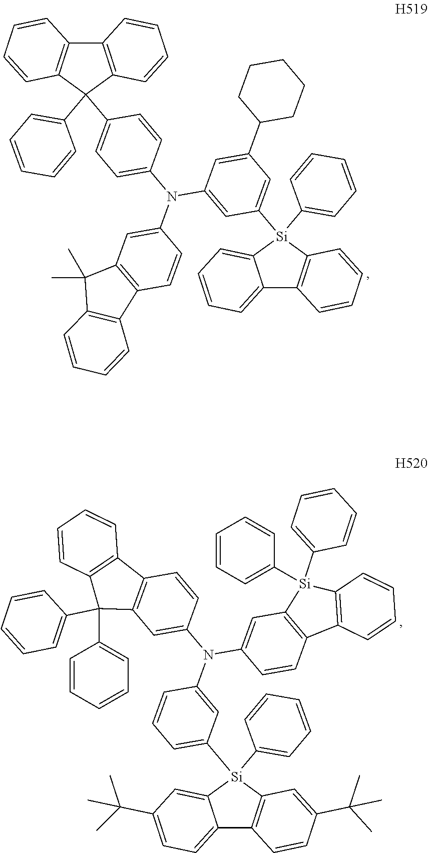 [SMILES: CC1(C)c2ccccc2-c2ccc(N(c3ccc(C4(c5ccccc5)c5ccccc5-c5ccccc54)cc3)c3cc(C4CCCCC4)cc([Si]4(c5ccccc5)c5ccccc5-c5ccccc54)c3)cc21 ; CC(C)(C)c1ccc2c(c1)[Si](c1ccccc1)(c1cccc(N(c3ccc4c(c3)C(c3ccccc3)(c3ccccc3)c3ccccc3-4)c3ccc4c(c3)[Si](c3ccccc3)(c3ccccc3)c3ccccc3-4)c1)c1cc(C(C)(C)C)ccc1-2] 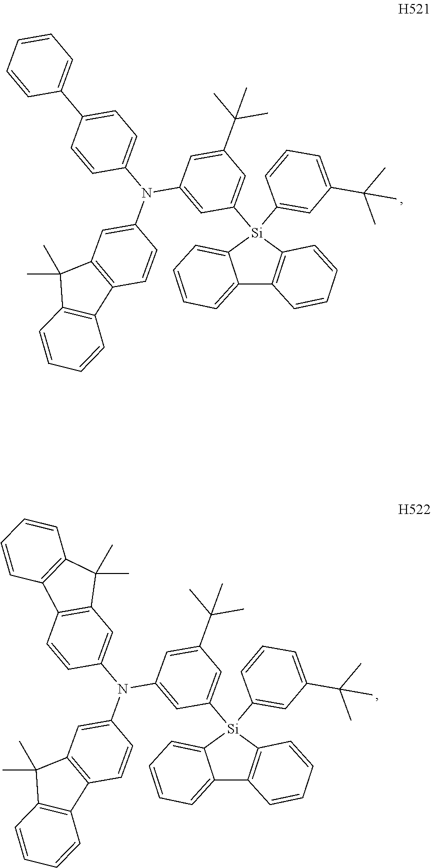 [SMILES: CC(C)(C)c1cccc([Si]2(c3cc(N(c4ccc(-c5ccccc5)cc4)c4ccc5c(c4)C(C)(C)c4ccccc4-5)cc(C(C)(C)C)c3)c3ccccc3-c3ccccc32)c1 ; CC(C)(C)c1cccc([Si]2(c3cc(N(c4ccc5c(c4)C(C)(C)c4ccccc4-5)c4ccc5c(c4)C(C)(C)c4ccccc4-5)cc(C(C)(C)C)c3)c3ccccc3-c3ccccc32)c1] 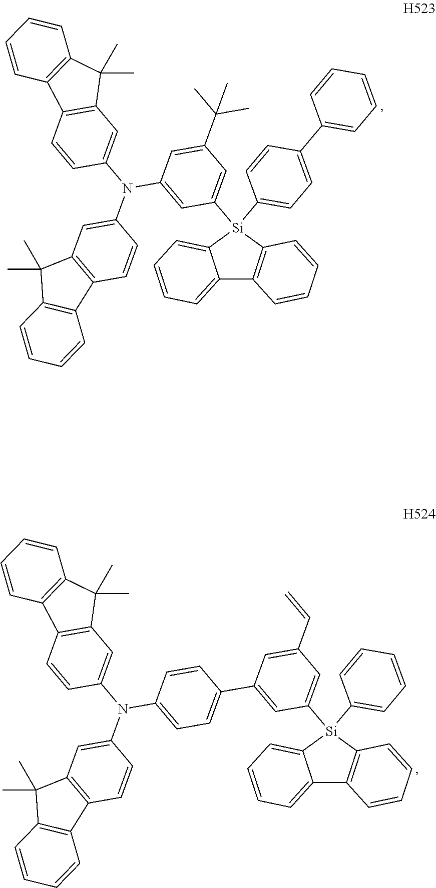 [SMILES: CC(C)(C)c1cc(N(c2ccc3c(c2)C(C)(C)c2ccccc2-3)c2ccc3c(c2)C(C)(C)c2ccccc2-3)cc([Si]2(c3ccc(-c4ccccc4)cc3)c3ccccc3-c3ccccc32)c1 ; C=Cc1cc(-c2ccc(N(c3ccc4c(c3)C(C)(C)c3ccccc3-4)c3ccc4c(c3)C(C)(C)c3ccccc3-4)cc2)cc([Si]2(c3ccccc3)c3ccccc3-c3ccccc32)c1] 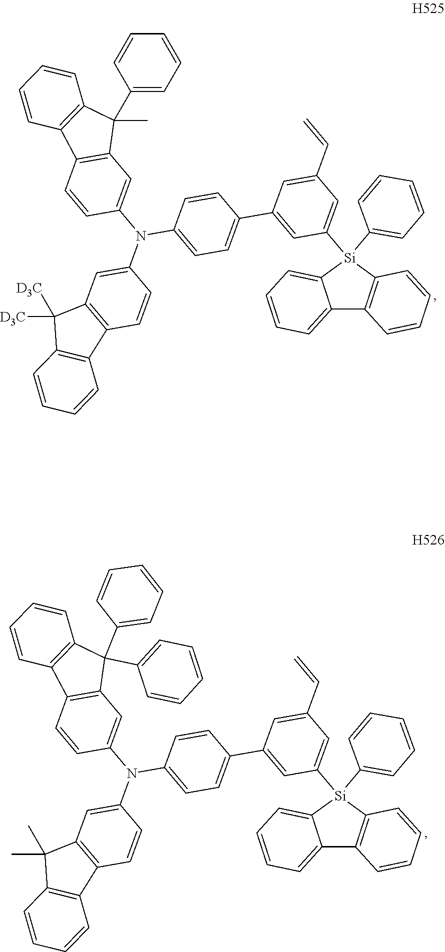 [SMILES: [2H]C([2H])([2H])C1(C([2H])([2H])[2H])c2ccccc2-c2ccc(N(c3ccc(-c4cc(C=C)cc([Si]5(c6ccccc6)c6ccccc6-c6ccccc65)c4)cc3)c3ccc4c(c3)C(C)(c3ccccc3)c3ccccc3-4)cc21 ; C=Cc1cc(-c2ccc(N(c3ccc4c(c3)C(C)(C)c3ccccc3-4)c3ccc4c(c3)C(c3ccccc3)(c3ccccc3)c3ccccc3-4)cc2)cc([Si]2(c3ccccc3)c3ccccc3-c3ccccc32)c1] 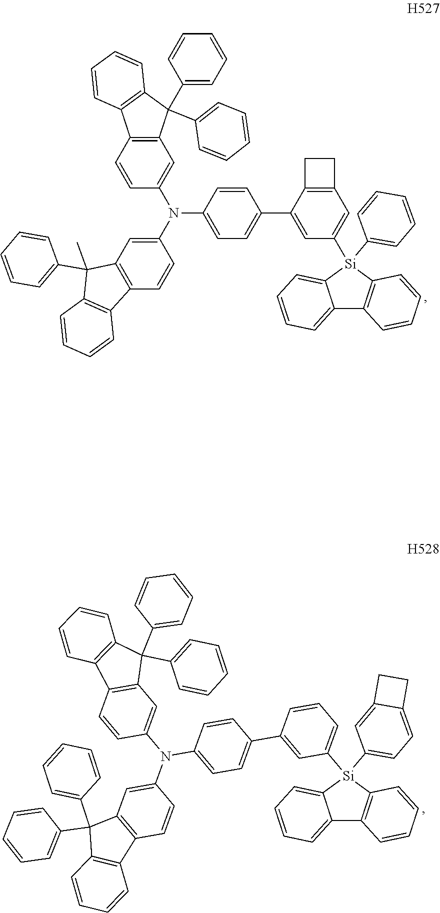 [SMILES: CC1(c2ccccc2)c2ccccc2-c2ccc(N(c3ccc(-c4cc([Si]5(c6ccccc6)c6ccccc6-c6ccccc65)cc5c4CC5)cc3)c3ccc4c(c3)C(c3ccccc3)(c3ccccc3)c3ccccc3-4)cc21 ; c1ccc(C2(c3ccccc3)c3ccccc3-c3ccc(N(c4ccc(-c5cccc([Si]6(c7ccc8c(c7)CC8)c7ccccc7-c7ccccc76)c5)cc4)c4ccc5c(c4)C(c4ccccc4)(c4ccccc4)c4ccccc4-5)cc32)cc1] 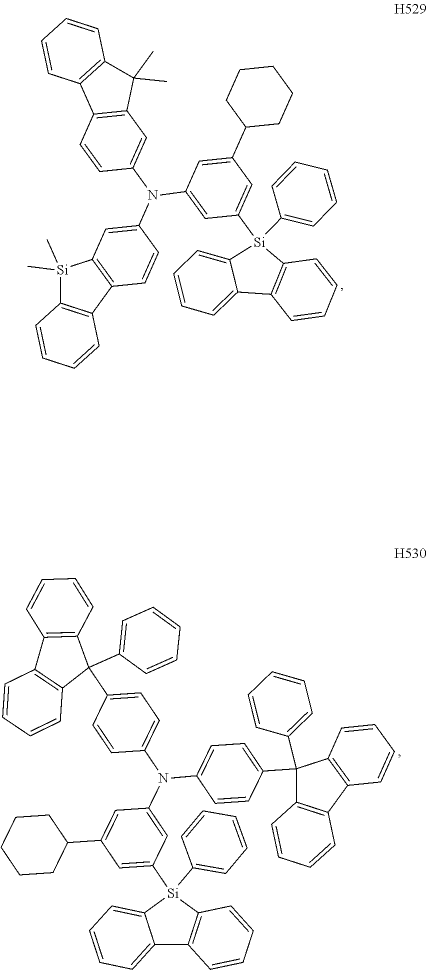 [SMILES: CC1(C)c2ccccc2-c2ccc(N(c3cc(C4CCCCC4)cc([Si]4(c5ccccc5)c5ccccc5-c5ccccc54)c3)c3ccc4c(c3)[Si](C)(C)c3ccccc3-4)cc21 ; c1ccc(C2(c3ccc(N(c4ccc(C5(c6ccccc6)c6ccccc6-c6ccccc65)cc4)c4cc(C5CCCCC5)cc([Si]5(c6ccccc6)c6ccccc6-c6ccccc65)c4)cc3)c3ccccc3-c3ccccc32)cc1] 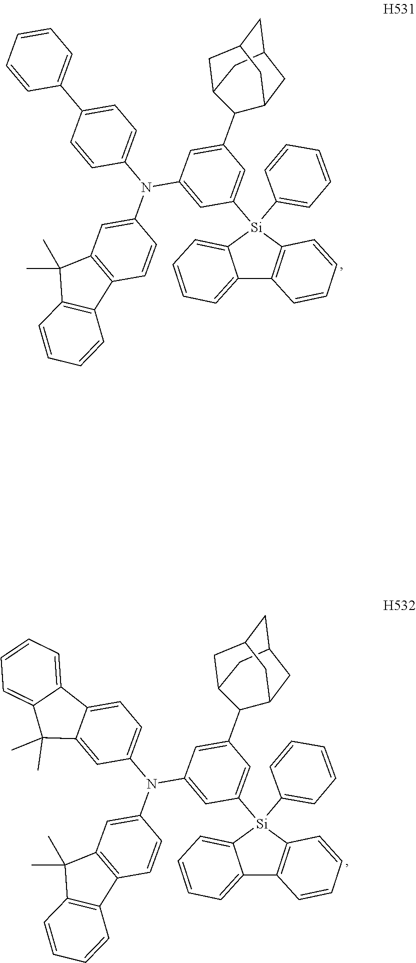 [SMILES: CC1(C)c2ccccc2-c2ccc(N(c3ccc(-c4ccccc4)cc3)c3cc(C4C5CC6CC(C5)CC4C6)cc([Si]4(c5ccccc5)c5ccccc5-c5ccccc54)c3)cc21 ; CC1(C)c2ccccc2-c2ccc(N(c3cc(C4C5CC6CC(C5)CC4C6)cc([Si]4(c5ccccc5)c5ccccc5-c5ccccc54)c3)c3ccc4c(c3)C(C)(C)c3ccccc3-4)cc21] 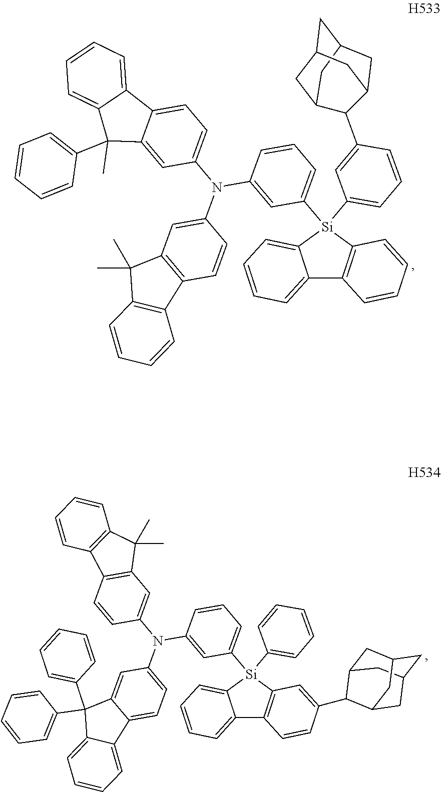 [SMILES: CC1(C)c2ccccc2-c2ccc(N(c3cccc([Si]4(c5cccc(C6C7CC8CC(C7)CC6C8)c5)c5ccccc5-c5ccccc54)c3)c3ccc4c(c3)C(C)(c3ccccc3)c3ccccc3-4)cc21 ; CC1(C)c2ccccc2-c2ccc(N(c3cccc([Si]4(c5ccccc5)c5ccccc5-c5ccc(C6C7CC8CC(C7)CC6C8)cc54)c3)c3ccc4c(c3)C(c3ccccc3)(c3ccccc3)c3ccccc3-4)cc21] 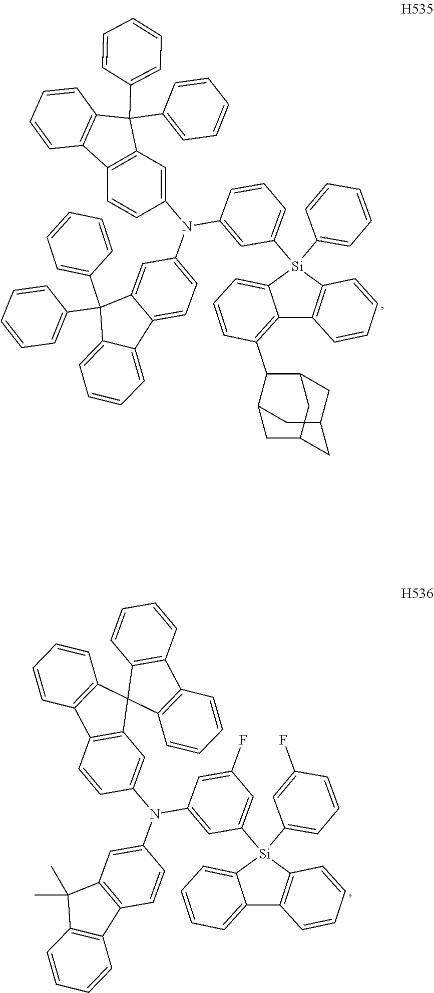 [SMILES: c1ccc(C2(c3ccccc3)c3ccccc3-c3ccc(N(c4cccc([Si]5(c6ccccc6)c6ccccc6-c6c(C7C8CC9CC(C8)CC7C9)cccc65)c4)c4ccc5c(c4)C(c4ccccc4)(c4ccccc4)c4ccccc4-5)cc32)cc1 ; CC1(C)c2ccccc2-c2ccc(N(c3cc(F)cc([Si]4(c5cccc(F)c5)c5ccccc5-c5ccccc54)c3)c3ccc4c(c3)C3(c5ccccc5-c5ccccc53)c3ccccc3-4)cc21] 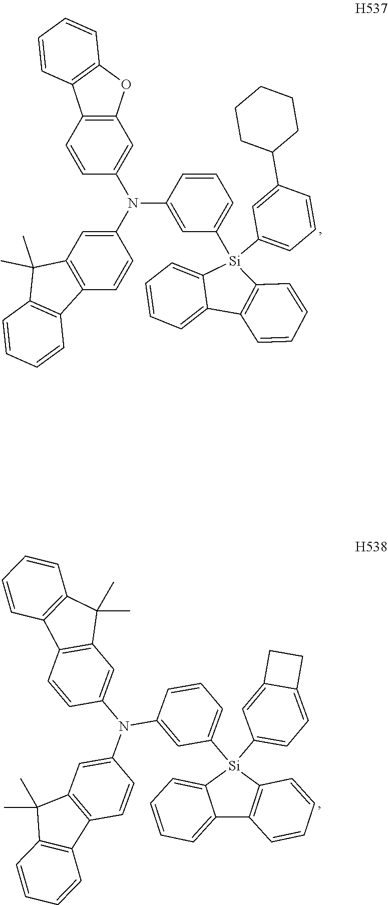 [SMILES: CC1(C)c2ccccc2-c2ccc(N(c3cccc([Si]4(c5cccc(C6CCCCC6)c5)c5ccccc5-c5ccccc54)c3)c3ccc4c(c3)oc3ccccc34)cc21 ; CC1(C)c2ccccc2-c2ccc(N(c3cccc([Si]4(c5ccc6c(c5)CC6)c5ccccc5-c5ccccc54)c3)c3ccc4c(c3)C(C)(C)c3ccccc3-4)cc21] 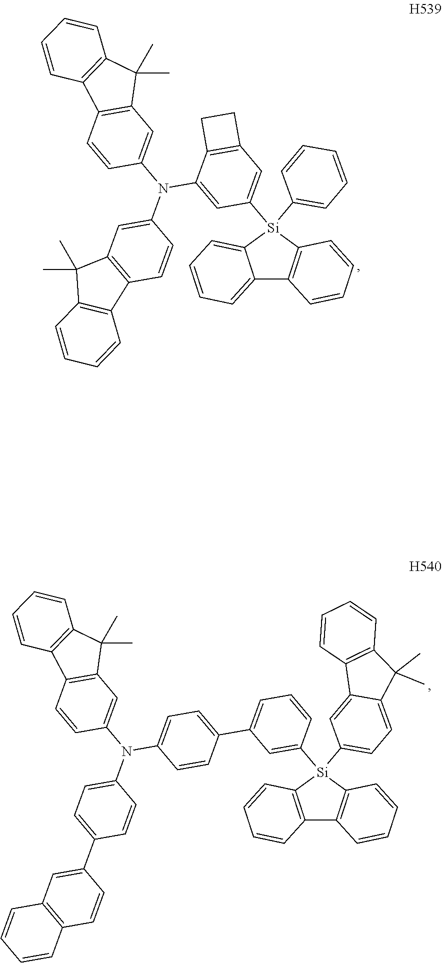 [SMILES: CC1(C)c2ccccc2-c2ccc(N(c3ccc4c(c3)C(C)(C)c3ccccc3-4)c3cc([Si]4(c5ccccc5)c5ccccc5-c5ccccc54)cc4c3CC4)cc21 ; CC1(C)c2ccccc2-c2cc([Si]3(c4cccc(-c5ccc(N(c6ccc(-c7ccc8ccccc8c7)cc6)c6ccc7c(c6)C(C)(C)c6ccccc6-7)cc5)c4)c4ccccc4-c4ccccc43)ccc21] 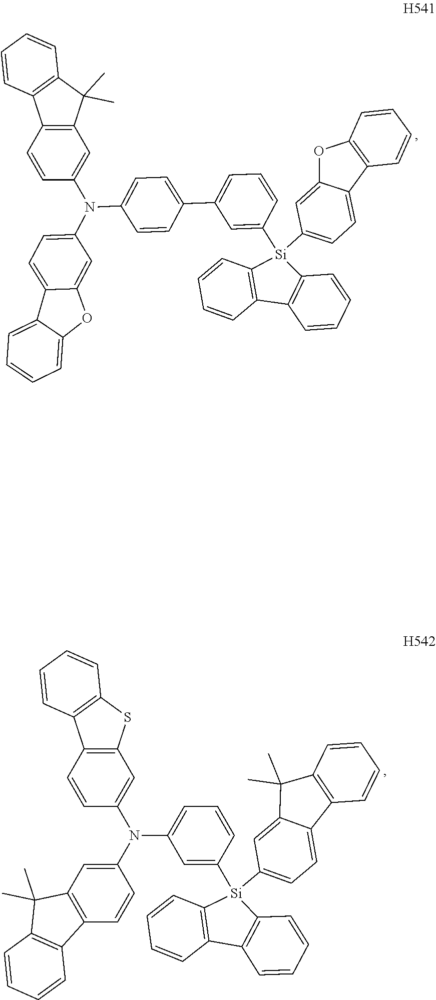 [SMILES: CC1(C)c2ccccc2-c2ccc(N(c3ccc(-c4cccc([Si]5(c6ccc7c(c6)oc6ccccc67)c6ccccc6-c6ccccc65)c4)cc3)c3ccc4c(c3)oc3ccccc34)cc21 ; CC1(C)c2ccccc2-c2ccc(N(c3cccc([Si]4(c5ccc6c(c5)C(C)(C)c5ccccc5-6)c5ccccc5-c5ccccc54)c3)c3ccc4c(c3)sc3ccccc34)cc21] 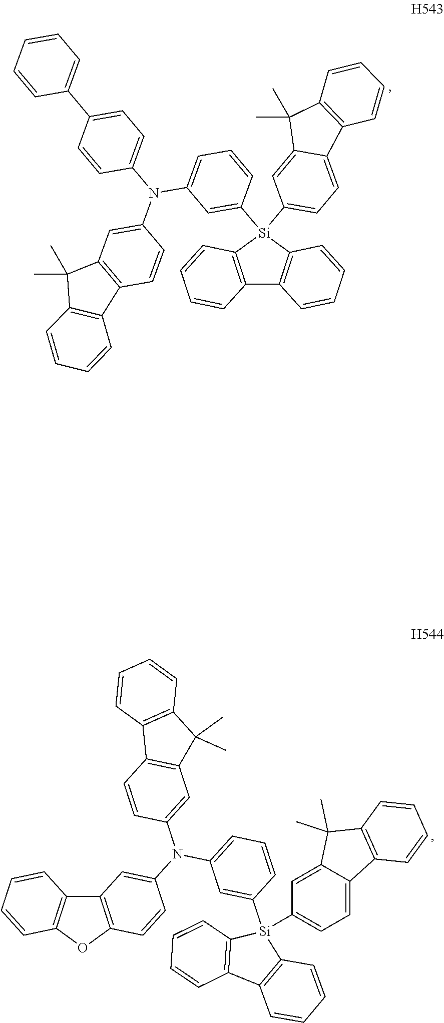 [SMILES: CC1(C)c2ccccc2-c2ccc(N(c3ccc(-c4ccccc4)cc3)c3cccc([Si]4(c5ccc6c(c5)C(C)(C)c5ccccc5-6)c5ccccc5-c5ccccc54)c3)cc21 ; CC1(C)c2ccccc2-c2ccc(N(c3cccc([Si]4(c5ccc6c(c5)C(C)(C)c5ccccc5-6)c5ccccc5-c5ccccc54)c3)c3ccc4oc5ccccc5c4c3)cc21] 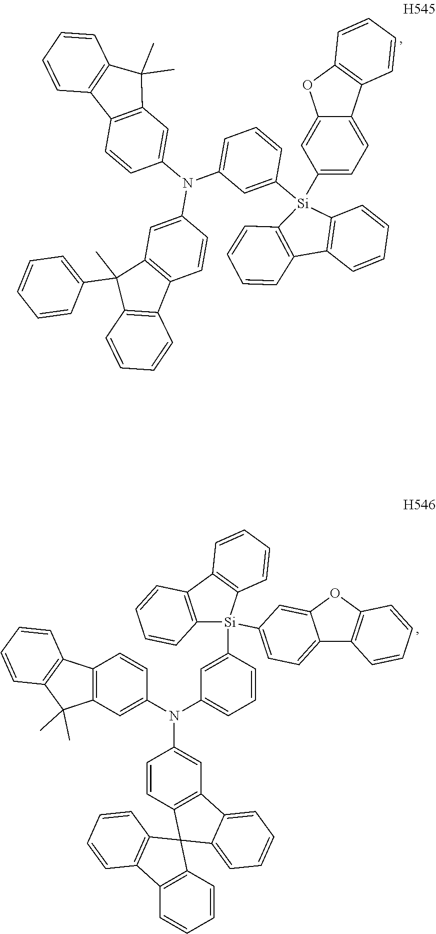 [SMILES: CC1(C)c2ccccc2-c2ccc(N(c3cccc([Si]4(c5ccc6c(c5)oc5ccccc56)c5ccccc5-c5ccccc54)c3)c3ccc4c(c3)C(C)(c3ccccc3)c3ccccc3-4)cc21 ; CC1(C)c2ccccc2-c2ccc(N(c3cccc([Si]4(c5ccc6c(c5)oc5ccccc56)c5ccccc5-c5ccccc54)c3)c3ccc4c(c3)-c3ccccc3C43c4ccccc4-c4ccccc43)cc21] 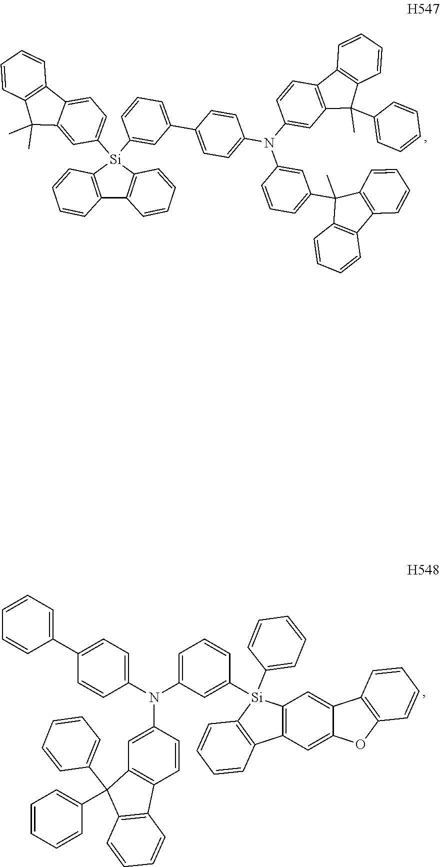 [SMILES: CC1(C)c2ccccc2-c2ccc([Si]3(c4cccc(-c5ccc(N(c6cccc(C7(C)c8ccccc8-c8ccccc87)c6)c6ccc7c(c6)C(C)(c6ccccc6)c6ccccc6-7)cc5)c4)c4ccccc4-c4ccccc43)cc21 ; c1ccc(-c2ccc(N(c3cccc([Si]4(c5ccccc5)c5ccccc5-c5cc6oc7ccccc7c6cc54)c3)c3ccc4c(c3)C(c3ccccc3)(c3ccccc3)c3ccccc3-4)cc2)cc1] 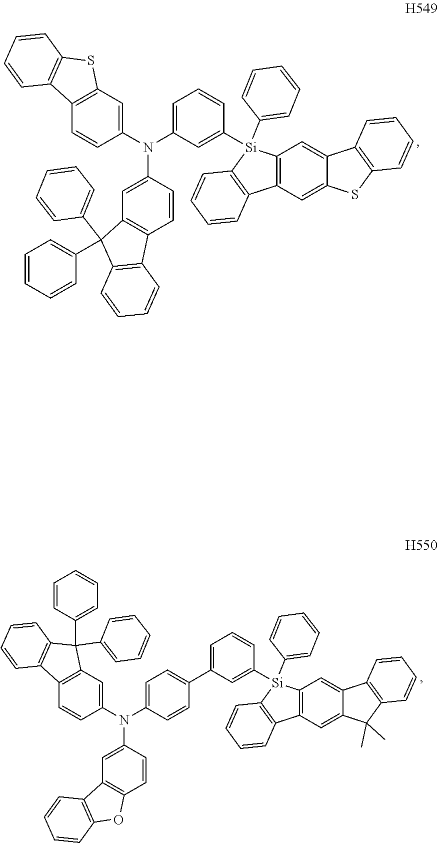 [SMILES: c1ccc(C2(c3ccccc3)c3ccccc3-c3ccc(N(c4cccc([Si]5(c6ccccc6)c6ccccc6-c6cc7sc8ccccc8c7cc65)c4)c4ccc5c(c4)sc4ccccc45)cc32)cc1 ; CC1(C)c2ccccc2-c2cc3c(cc21)-c1ccccc1[Si]3(c1ccccc1)c1cccc(-c2ccc(N(c3ccc4c(c3)C(c3ccccc3)(c3ccccc3)c3ccccc3-4)c3ccc4oc5ccccc5c4c3)cc2)c1] 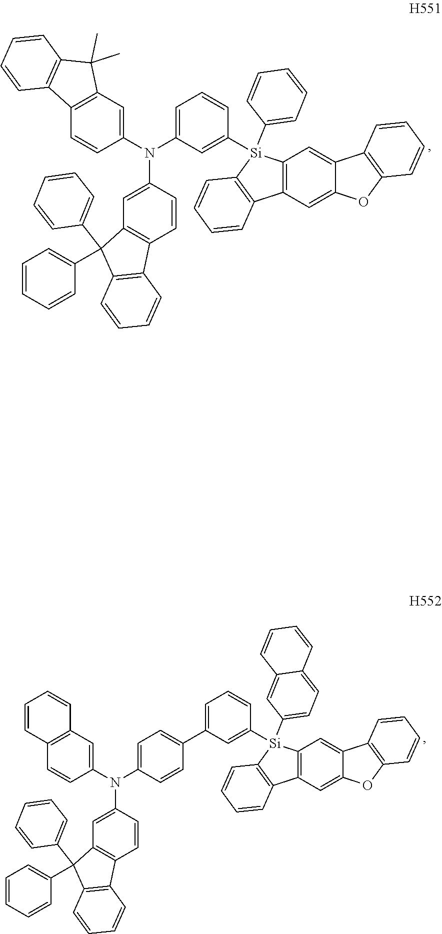 [SMILES: CC1(C)c2ccccc2-c2ccc(N(c3cccc([Si]4(c5ccccc5)c5ccccc5-c5cc6oc7ccccc7c6cc54)c3)c3ccc4c(c3)C(c3ccccc3)(c3ccccc3)c3ccccc3-4)cc21 ; c1ccc(C2(c3ccccc3)c3ccccc3-c3ccc(N(c4ccc(-c5cccc([Si]6(c7ccc8ccccc8c7)c7ccccc7-c7cc8oc9ccccc9c8cc76)c5)cc4)c4ccc5ccccc5c4)cc32)cc1] 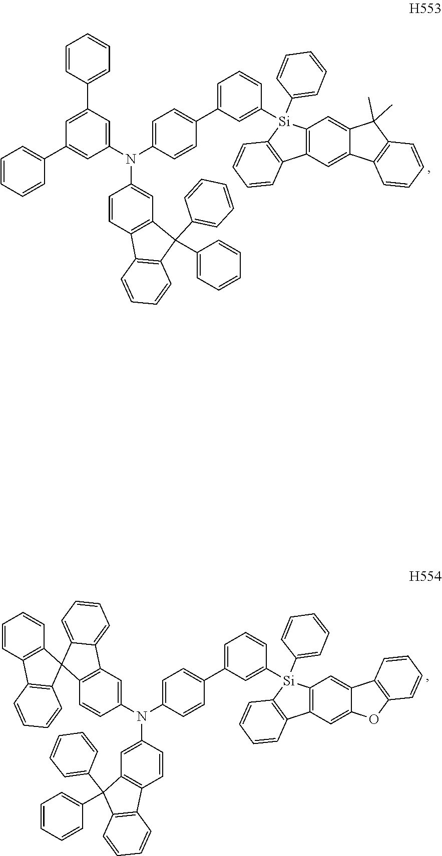 [SMILES: CC1(C)c2ccccc2-c2cc3c(cc21)[Si](c1ccccc1)(c1cccc(-c2ccc(N(c4cc(-c5ccccc5)cc(-c5ccccc5)c4)c4ccc5c(c4)C(c4ccccc4)(c4ccccc4)c4ccccc4-5)cc2)c1)c1ccccc1-3 ; c1ccc(C2(c3ccccc3)c3ccccc3-c3ccc(N(c4ccc(-c5cccc([Si]6(c7ccccc7)c7ccccc7-c7cc8oc9ccccc9c8cc76)c5)cc4)c4ccc5c(c4)-c4ccccc4C54c5ccccc5-c5ccccc54)cc32)cc1] 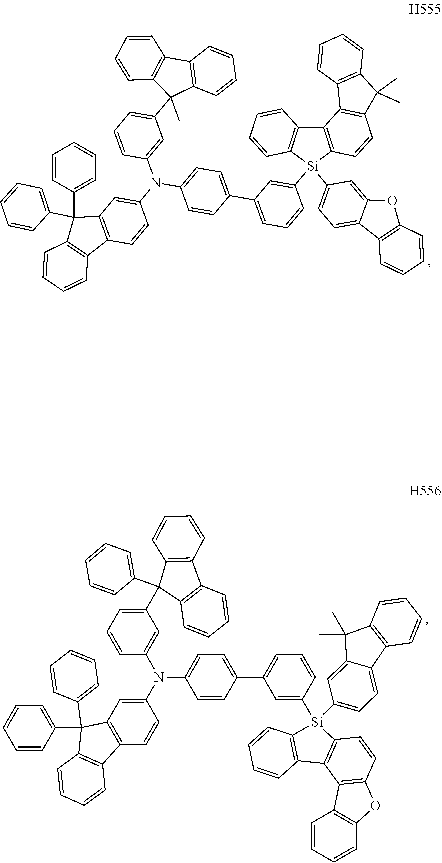 [SMILES: CC1(C)c2ccccc2-c2c1ccc1c2-c2ccccc2[Si]1(c1cccc(-c2ccc(N(c3cccc(C4(C)c5ccccc5-c5ccccc54)c3)c3ccc4c(c3)C(c3ccccc3)(c3ccccc3)c3ccccc3-4)cc2)c1)c1ccc2c(c1)oc1ccccc12 ; CC1(C)c2ccccc2-c2ccc([Si]3(c4cccc(-c5ccc(N(c6cccc(C7(c8ccccc8)c8ccccc8-c8ccccc87)c6)c6ccc7c(c6)C(c6ccccc6)(c6ccccc6)c6ccccc6-7)cc5)c4)c4ccccc4-c4c3ccc3oc5ccccc5c43)cc21] 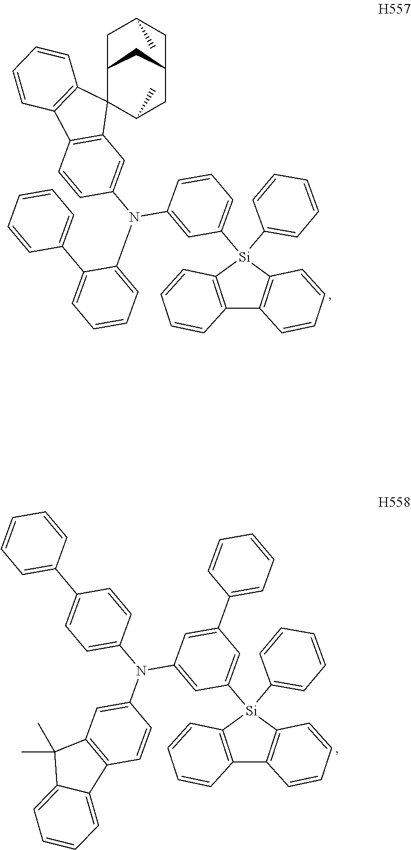 [SMILES: C[C@@H]1C[C@H]2C[C@@H](C1)C1(c3ccccc3-c3ccc(N(c4cccc([Si]5(c6ccccc6)c6ccccc6-c6ccccc65)c4)c4ccccc4-c4ccccc4)cc31)[C@@H](C)C2 ; CC1(C)c2ccccc2-c2ccc(N(c3ccc(-c4ccccc4)cc3)c3cc(-c4ccccc4)cc([Si]4(c5ccccc5)c5ccccc5-c5ccccc54)c3)cc21] 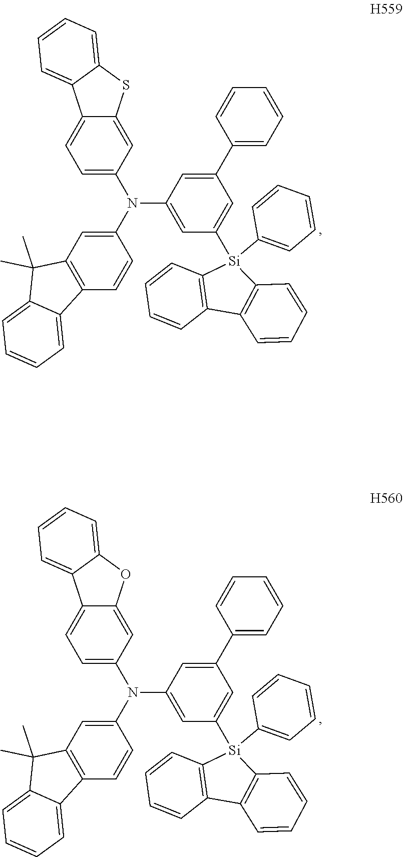 [SMILES: CC1(C)c2ccccc2-c2ccc(N(c3cc(-c4ccccc4)cc([Si]4(c5ccccc5)c5ccccc5-c5ccccc54)c3)c3ccc4c(c3)sc3ccccc34)cc21 ; CC1(C)c2ccccc2-c2ccc(N(c3cc(-c4ccccc4)cc([Si]4(c5ccccc5)c5ccccc5-c5ccccc54)c3)c3ccc4c(c3)oc3ccccc34)cc21] 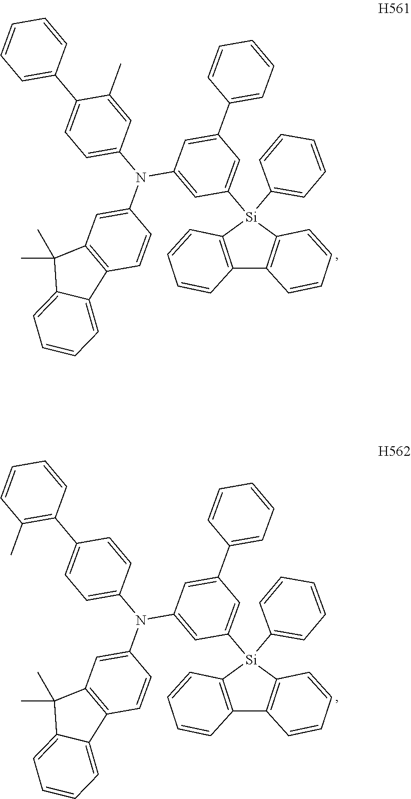 [SMILES: Cc1cc(N(c2cc(-c3ccccc3)cc([Si]3(c4ccccc4)c4ccccc4-c4ccccc43)c2)c2ccc3c(c2)C(C)(C)c2ccccc2-3)ccc1-c1ccccc1 ; Cc1ccccc1-c1ccc(N(c2cc(-c3ccccc3)cc([Si]3(c4ccccc4)c4ccccc4-c4ccccc43)c2)c2ccc3c(c2)C(C)(C)c2ccccc2-3)cc1] 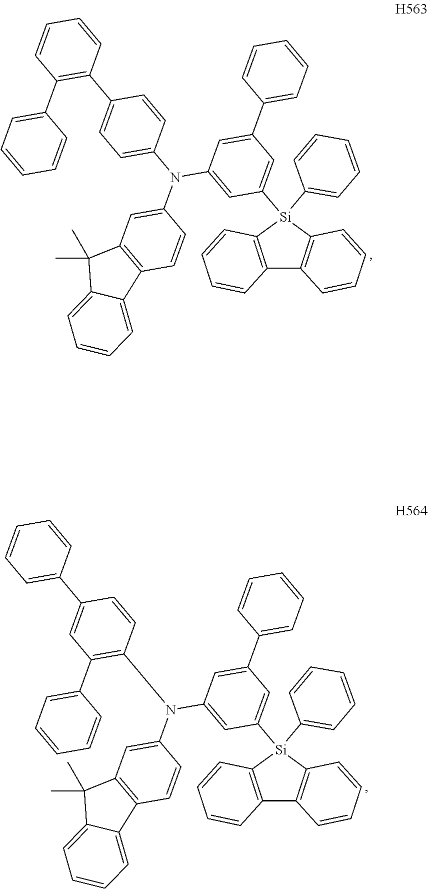 [SMILES: CC1(C)c2ccccc2-c2ccc(N(c3ccc(-c4ccccc4-c4ccccc4)cc3)c3cc(-c4ccccc4)cc([Si]4(c5ccccc5)c5ccccc5-c5ccccc54)c3)cc21 ; CC1(C)c2ccccc2-c2ccc(N(c3cc(-c4ccccc4)cc([Si]4(c5ccccc5)c5ccccc5-c5ccccc54)c3)c3ccc(-c4ccccc4)cc3-c3ccccc3)cc21] 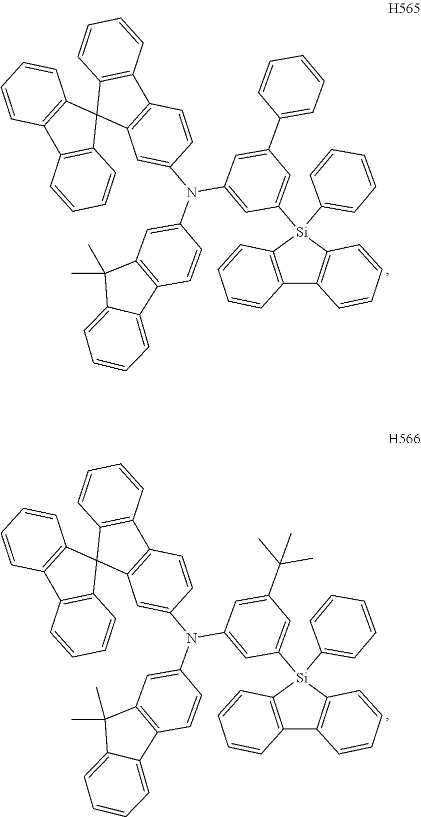 [SMILES: CC1(C)c2ccccc2-c2ccc(N(c3cc(-c4ccccc4)cc([Si]4(c5ccccc5)c5ccccc5-c5ccccc54)c3)c3ccc4c(c3)C3(c5ccccc5-c5ccccc53)c3ccccc3-4)cc21 ; CC(C)(C)c1cc(N(c2ccc3c(c2)C(C)(C)c2ccccc2-3)c2ccc3c(c2)C2(c4ccccc4-c4ccccc42)c2ccccc2-3)cc([Si]2(c3ccccc3)c3ccccc3-c3ccccc32)c1] 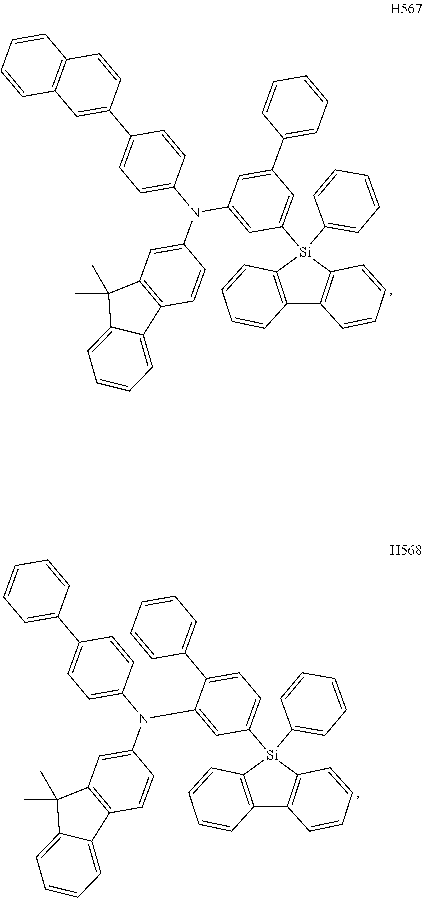 [SMILES: CC1(C)c2ccccc2-c2ccc(N(c3ccc(-c4ccc5ccccc5c4)cc3)c3cc(-c4ccccc4)cc([Si]4(c5ccccc5)c5ccccc5-c5ccccc54)c3)cc21 ; CC1(C)c2ccccc2-c2ccc(N(c3ccc(-c4ccccc4)cc3)c3cc([Si]4(c5ccccc5)c5ccccc5-c5ccccc54)ccc3-c3ccccc3)cc21] 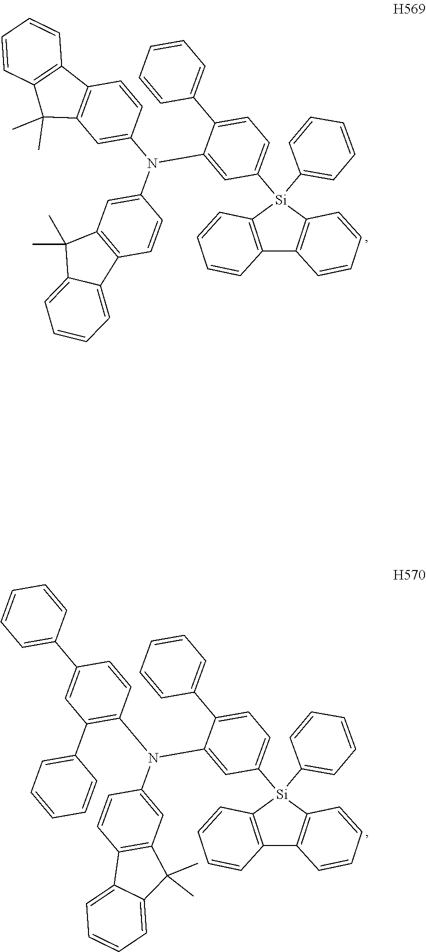 [SMILES: CC1(C)c2ccccc2-c2ccc(N(c3ccc4c(c3)C(C)(C)c3ccccc3-4)c3cc([Si]4(c5ccccc5)c5ccccc5-c5ccccc54)ccc3-c3ccccc3)cc21 ; CC1(C)c2ccccc2-c2ccc(N(c3ccc(-c4ccccc4)cc3-c3ccccc3)c3cc([Si]4(c5ccccc5)c5ccccc5-c5ccccc54)ccc3-c3ccccc3)cc21] 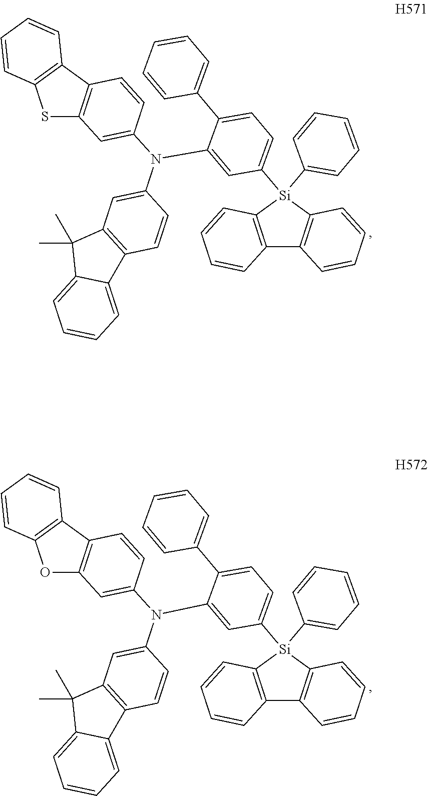 [SMILES: CC1(C)c2ccccc2-c2ccc(N(c3ccc4c(c3)sc3ccccc34)c3cc([Si]4(c5ccccc5)c5ccccc5-c5ccccc54)ccc3-c3ccccc3)cc21 ; CC1(C)c2ccccc2-c2ccc(N(c3ccc4c(c3)oc3ccccc34)c3cc([Si]4(c5ccccc5)c5ccccc5-c5ccccc54)ccc3-c3ccccc3)cc21] 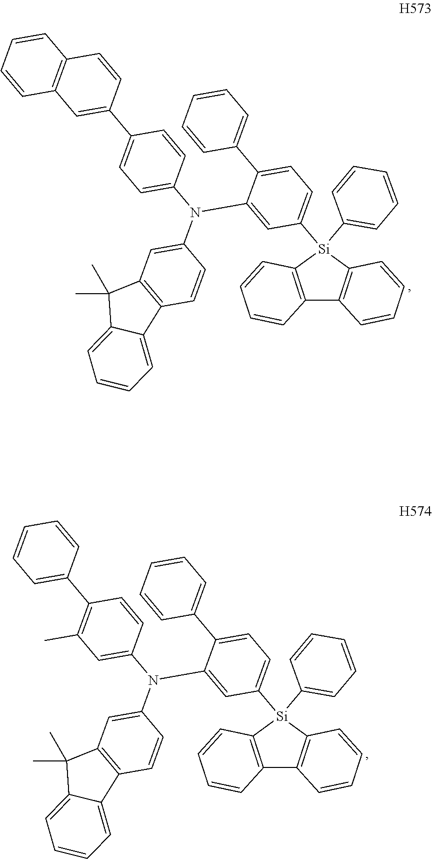 [SMILES: CC1(C)c2ccccc2-c2ccc(N(c3ccc(-c4ccc5ccccc5c4)cc3)c3cc([Si]4(c5ccccc5)c5ccccc5-c5ccccc54)ccc3-c3ccccc3)cc21 ; Cc1cc(N(c2ccc3c(c2)C(C)(C)c2ccccc2-3)c2cc([Si]3(c4ccccc4)c4ccccc4-c4ccccc43)ccc2-c2ccccc2)ccc1-c1ccccc1] 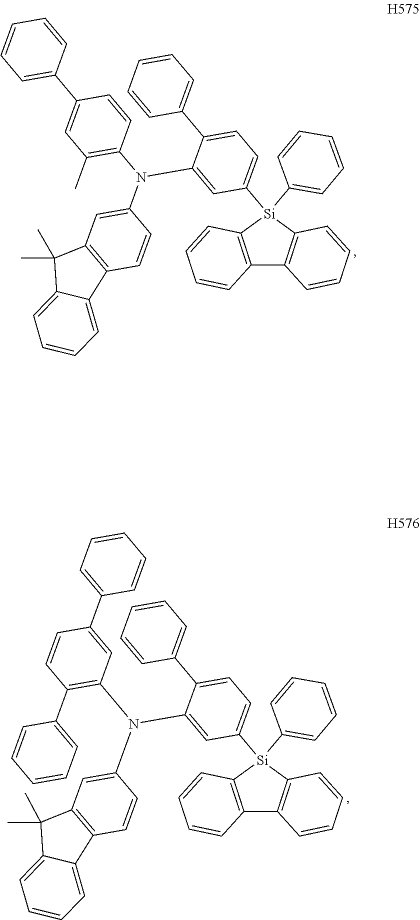 [SMILES: Cc1cc(-c2ccccc2)ccc1N(c1ccc2c(c1)C(C)(C)c1ccccc1-2)c1cc([Si]2(c3ccccc3)c3ccccc3-c3ccccc32)ccc1-c1ccccc1 ; CC1(C)c2ccccc2-c2ccc(N(c3cc(-c4ccccc4)ccc3-c3ccccc3)c3cc([Si]4(c5ccccc5)c5ccccc5-c5ccccc54)ccc3-c3ccccc3)cc21] 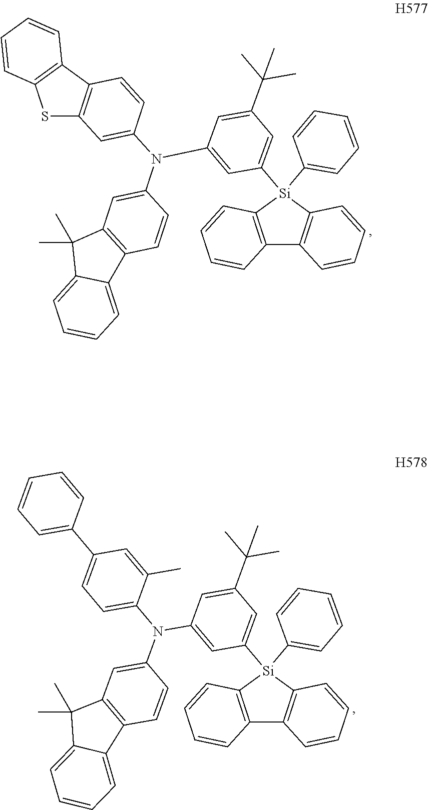 [SMILES: CC(C)(C)c1cc(N(c2ccc3c(c2)C(C)(C)c2ccccc2-3)c2ccc3c(c2)sc2ccccc23)cc([Si]2(c3ccccc3)c3ccccc3-c3ccccc32)c1 ; Cc1cc(-c2ccccc2)ccc1N(c1cc(C(C)(C)C)cc([Si]2(c3ccccc3)c3ccccc3-c3ccccc32)c1)c1ccc2c(c1)C(C)(C)c1ccccc1-2] 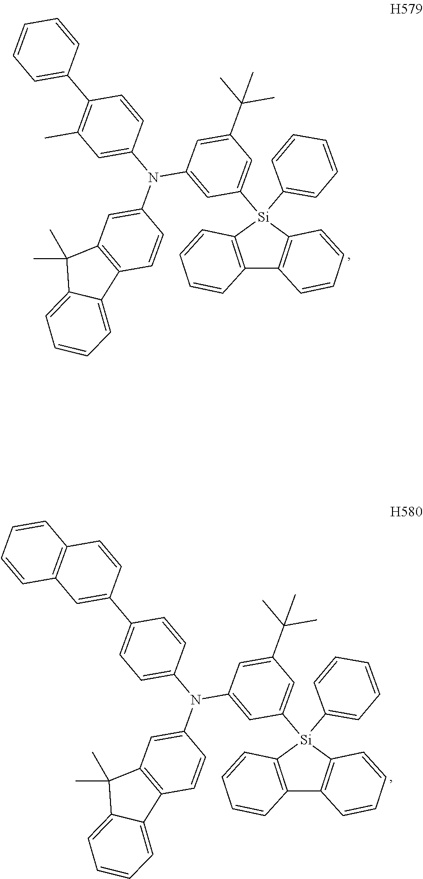 [SMILES: Cc1cc(N(c2cc(C(C)(C)C)cc([Si]3(c4ccccc4)c4ccccc4-c4ccccc43)c2)c2ccc3c(c2)C(C)(C)c2ccccc2-3)ccc1-c1ccccc1 ; CC(C)(C)c1cc(N(c2ccc(-c3ccc4ccccc4c3)cc2)c2ccc3c(c2)C(C)(C)c2ccccc2-3)cc([Si]2(c3ccccc3)c3ccccc3-c3ccccc32)c1] 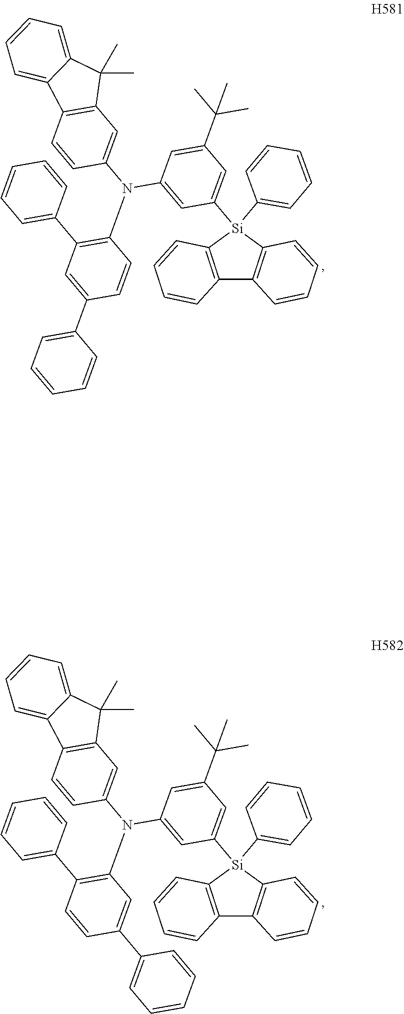 [SMILES: CC(C)(C)c1cc(N(c2ccc3c(c2)C(C)(C)c2ccccc2-3)c2ccc(-c3ccccc3)cc2-c2ccccc2)cc([Si]2(c3ccccc3)c3ccccc3-c3ccccc32)c1 ; CC(C)(C)c1cc(N(c2ccc3c(c2)C(C)(C)c2ccccc2-3)c2cc(-c3ccccc3)ccc2-c2ccccc2)cc([Si]2(c3ccccc3)c3ccccc3-c3ccccc32)c1] 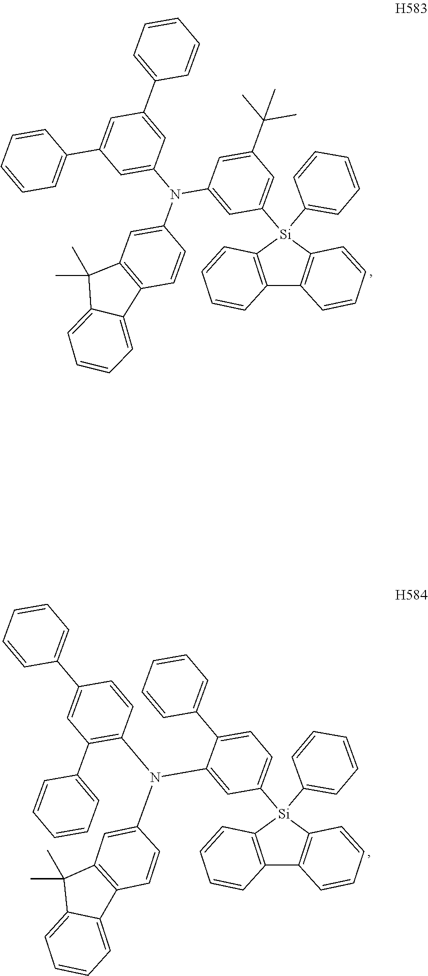 [SMILES: CC(C)(C)c1cc(N(c2cc(-c3ccccc3)cc(-c3ccccc3)c2)c2ccc3c(c2)C(C)(C)c2ccccc2-3)cc([Si]2(c3ccccc3)c3ccccc3-c3ccccc32)c1 ; CC1(C)c2ccccc2-c2ccc(N(c3ccc(-c4ccccc4)cc3-c3ccccc3)c3cc([Si]4(c5ccccc5)c5ccccc5-c5ccccc54)ccc3-c3ccccc3)cc21] 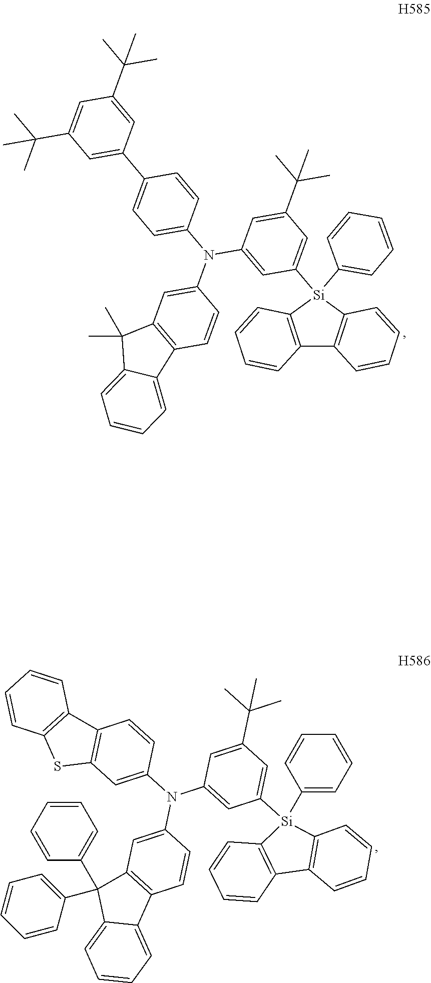 [SMILES: CC(C)(C)c1cc(-c2ccc(N(c3cc(C(C)(C)C)cc([Si]4(c5ccccc5)c5ccccc5-c5ccccc54)c3)c3ccc4c(c3)C(C)(C)c3ccccc3-4)cc2)cc(C(C)(C)C)c1 ; CC(C)(C)c1cc(N(c2ccc3c(c2)C(c2ccccc2)(c2ccccc2)c2ccccc2-3)c2ccc3c(c2)sc2ccccc23)cc([Si]2(c3ccccc3)c3ccccc3-c3ccccc32)c1] 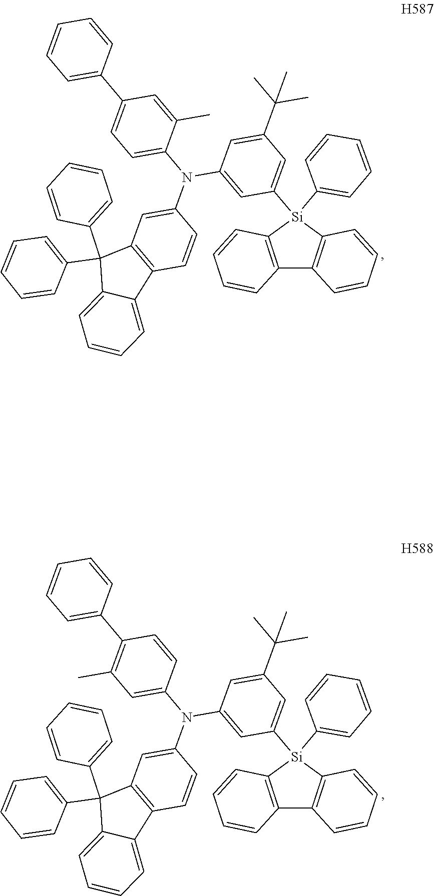 [SMILES: Cc1cc(-c2ccccc2)ccc1N(c1cc(C(C)(C)C)cc([Si]2(c3ccccc3)c3ccccc3-c3ccccc32)c1)c1ccc2c(c1)C(c1ccccc1)(c1ccccc1)c1ccccc1-2 ; Cc1cc(N(c2cc(C(C)(C)C)cc([Si]3(c4ccccc4)c4ccccc4-c4ccccc43)c2)c2ccc3c(c2)C(c2ccccc2)(c2ccccc2)c2ccccc2-3)ccc1-c1ccccc1] 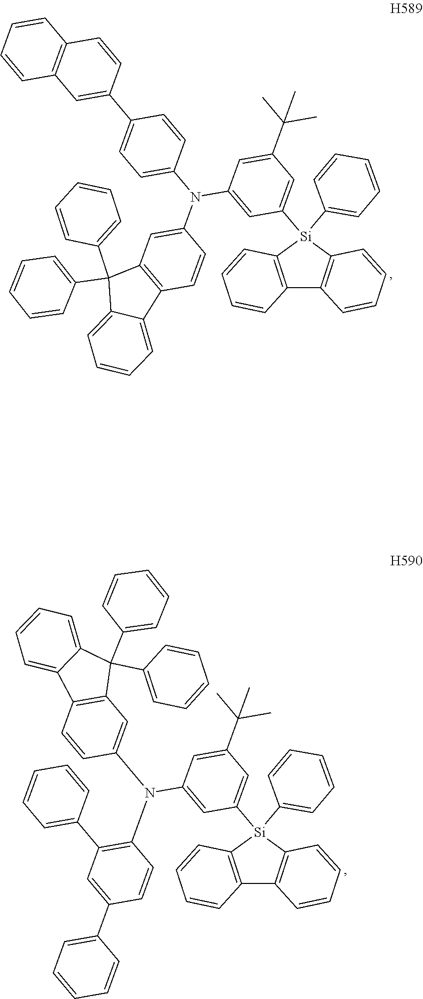 [SMILES: CC(C)(C)c1cc(N(c2ccc(-c3ccc4ccccc4c3)cc2)c2ccc3c(c2)C(c2ccccc2)(c2ccccc2)c2ccccc2-3)cc([Si]2(c3ccccc3)c3ccccc3-c3ccccc32)c1 ; CC(C)(C)c1cc(N(c2ccc3c(c2)C(c2ccccc2)(c2ccccc2)c2ccccc2-3)c2ccc(-c3ccccc3)cc2-c2ccccc2)cc([Si]2(c3ccccc3)c3ccccc3-c3ccccc32)c1] 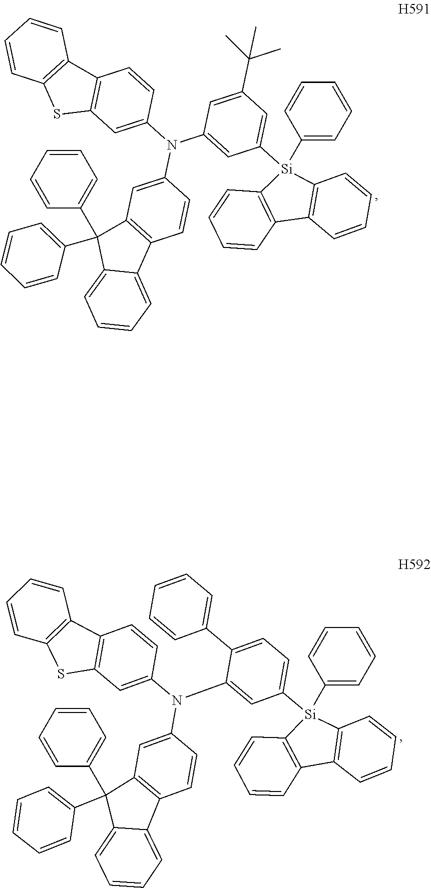 [SMILES: CC(C)(C)c1cc(N(c2ccc3c(c2)C(c2ccccc2)(c2ccccc2)c2ccccc2-3)c2ccc3c(c2)sc2ccccc23)cc([Si]2(c3ccccc3)c3ccccc3-c3ccccc32)c1 ; c1ccc(-c2ccc([Si]3(c4ccccc4)c4ccccc4-c4ccccc43)cc2N(c2ccc3c(c2)C(c2ccccc2)(c2ccccc2)c2ccccc2-3)c2ccc3c(c2)sc2ccccc23)cc1] 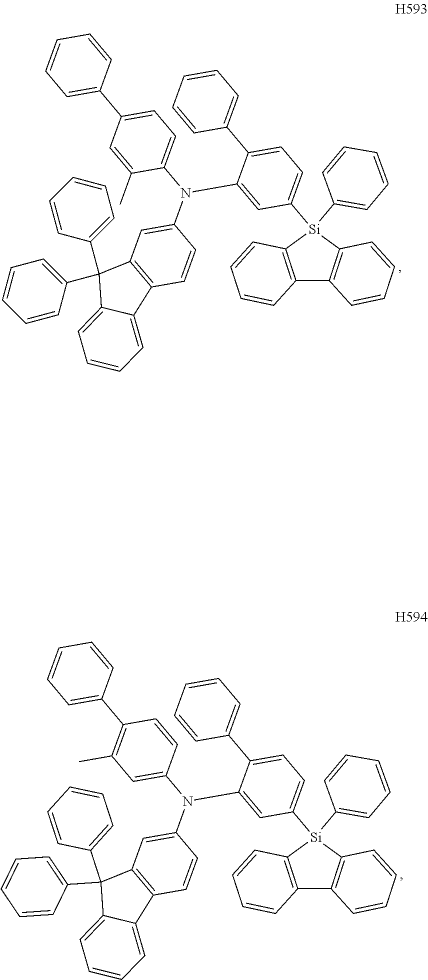 [SMILES: Cc1cc(-c2ccccc2)ccc1N(c1ccc2c(c1)C(c1ccccc1)(c1ccccc1)c1ccccc1-2)c1cc([Si]2(c3ccccc3)c3ccccc3-c3ccccc32)ccc1-c1ccccc1 ; Cc1cc(N(c2ccc3c(c2)C(c2ccccc2)(c2ccccc2)c2ccccc2-3)c2cc([Si]3(c4ccccc4)c4ccccc4-c4ccccc43)ccc2-c2ccccc2)ccc1-c1ccccc1] 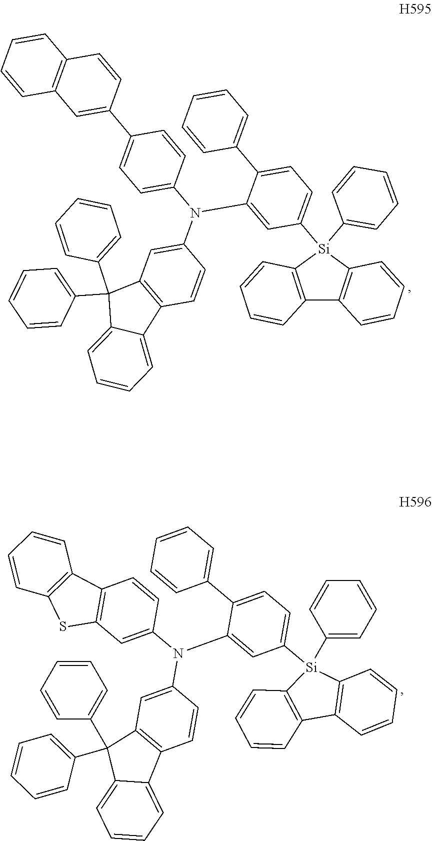 [SMILES: c1ccc(-c2ccc([Si]3(c4ccccc4)c4ccccc4-c4ccccc43)cc2N(c2ccc(-c3ccc4ccccc4c3)cc2)c2ccc3c(c2)C(c2ccccc2)(c2ccccc2)c2ccccc2-3)cc1 ; c1ccc(-c2ccc([Si]3(c4ccccc4)c4ccccc4-c4ccccc43)cc2N(c2ccc3c(c2)C(c2ccccc2)(c2ccccc2)c2ccccc2-3)c2ccc3c(c2)sc2ccccc23)cc1] 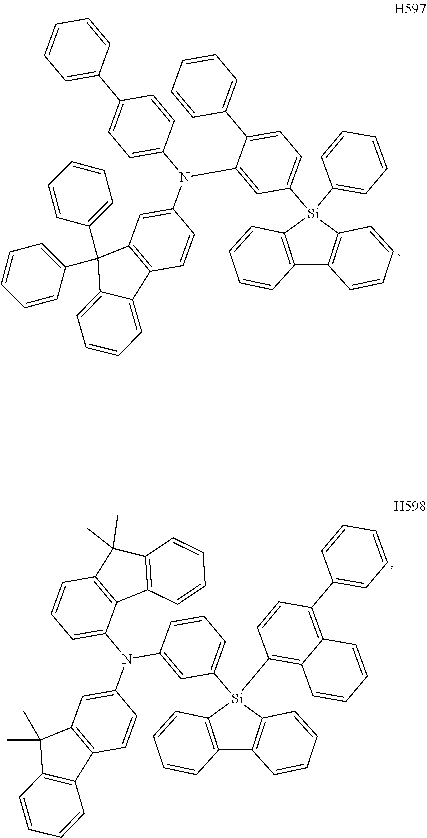 [SMILES: c1ccc(-c2ccc(N(c3ccc4c(c3)C(c3ccccc3)(c3ccccc3)c3ccccc3-4)c3cc([Si]4(c5ccccc5)c5ccccc5-c5ccccc54)ccc3-c3ccccc3)cc2)cc1 ; CC1(C)c2ccccc2-c2ccc(N(c3cccc([Si]4(c5ccc(-c6ccccc6)c6ccccc56)c5ccccc5-c5ccccc54)c3)c3cccc4c3-c3ccccc3C4(C)C)cc21] 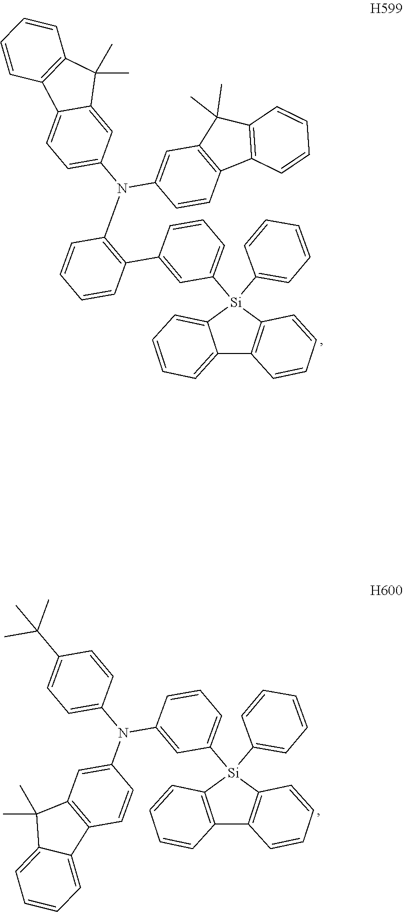 [SMILES: CC1(C)c2ccccc2-c2ccc(N(c3ccc4c(c3)C(C)(C)c3ccccc3-4)c3ccccc3-c3cccc([Si]4(c5ccccc5)c5ccccc5-c5ccccc54)c3)cc21 ; CC(C)(C)c1ccc(N(c2cccc([Si]3(c4ccccc4)c4ccccc4-c4ccccc43)c2)c2ccc3c(c2)C(C)(C)c2ccccc2-3)cc1] 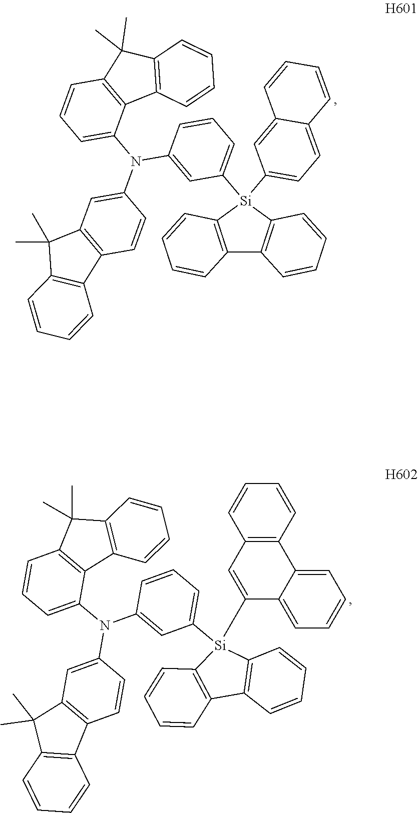 [SMILES: CC1(C)c2ccccc2-c2ccc(N(c3cccc([Si]4(c5ccc6ccccc6c5)c5ccccc5-c5ccccc54)c3)c3cccc4c3-c3ccccc3C4(C)C)cc21 ; CC1(C)c2ccccc2-c2ccc(N(c3cccc([Si]4(c5cc6ccccc6c6ccccc56)c5ccccc5-c5ccccc54)c3)c3cccc4c3-c3ccccc3C4(C)C)cc21] 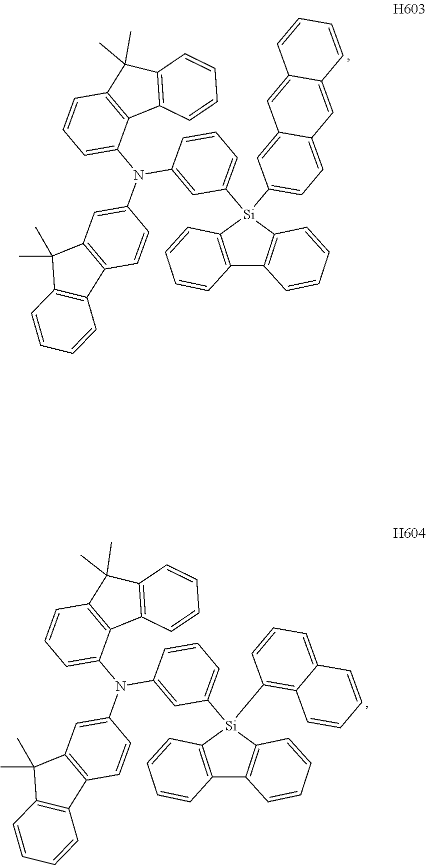 [SMILES: CC1(C)c2ccccc2-c2ccc(N(c3cccc([Si]4(c5ccc6cc7ccccc7cc6c5)c5ccccc5-c5ccccc54)c3)c3cccc4c3-c3ccccc3C4(C)C)cc21 ; CC1(C)c2ccccc2-c2ccc(N(c3cccc([Si]4(c5cccc6ccccc56)c5ccccc5-c5ccccc54)c3)c3cccc4c3-c3ccccc3C4(C)C)cc21] 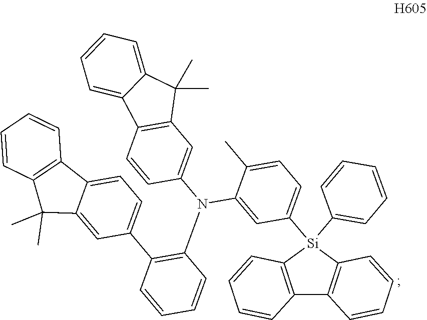 [SMILES: Cc1ccc([Si]2(c3ccccc3)c3ccccc3-c3ccccc32)cc1N(c1ccc2c(c1)C(C)(C)c1ccccc1-2)c1ccccc1-c1ccc2c(c1)C(C)(C)c1ccccc1-2]
optionally, hydrogens in the structures of Compound 1 to Compound 3816, Compound H1 to Compound H416 and Compound H451 to Compound H605 can be partially or fully substituted with deuterium.

10. An organic electroluminescent device, comprising:
an anode,
a cathode and
an organic layer disposed between the anode and the cathode, wherein the organic layer comprises the compound according to claim 1.

11. The organic electroluminescent device according to claim 10, wherein the organic layer is an electron blocking layer, a hole transporting layer or a light-emitting layer; and
preferably, the organic layer is the electron blocking layer.

12. The organic electroluminescent device according to claim 11, wherein the organic electroluminescent device is a stacked device.

13. A compound composition, comprising the compound according to claim 1.
